(19) United States
(12) Patent Application Publication
(10) Pub. No.: US 2024/0196724 A1
(43) Pub. Date: Jun. 13, 2024

(54) EMITTERS BASED ON OCTAHEDRAL METAL COMPLEXES

(71) Applicant: Arizona Board of Regents on behalf of Arizona State University, Scottsdale, AZ (US)

(72) Inventors: Jian Li, Tempe, AZ (US); Guijie Li, Hangzhou (CN)

(21) Appl. No.: 18/393,497

(22) Filed: Dec. 21, 2023

Related U.S. Application Data
(63) Continuation of application No. 17/212,144, filed on Mar. 25, 2021, now Pat. No. 11,856,840.
Application No. 17/212,144 is a continuation of application No. 16/171,026, filed on Oct. 25, 2018, now Pat. No. 10,991,897.
Application No. 16/171,026 is a continuation of application No. 15/795,615, filed on Oct. 27, 2017, now abandoned.
Application No. 15/795,615 is a continuation of application No. 14/937,136, filed on Nov. 10, 2015, now Pat. No. 9,865,825.
(60) Provisional application No. 62/077,443, filed on Nov. 10, 2014.

(51) Int. Cl. H10K 85/30; C07F 15/00; C09K 11/06; H05B 33/14

(52) U.S. Cl. CPC H10K 85/342; C07F 15/0033; C07F 15/0073; C07F 15/0086; C09K 11/06; H05B 33/14; C09K 2211/1007; C09K 2211/1011; C09K 2211/1022; C09K 2211/1029; C09K 2211/1044; C09K 2211/1088; C09K 2211/1092; C09K 2211/1096; C09K 2211/185; H10K 50/11

(57) ABSTRACT

Iridium, rhodium, and platinum complexes suitable for use as phosphorescent emitters or as delayed fluorescent and phosphorescent emitters having the following structures:

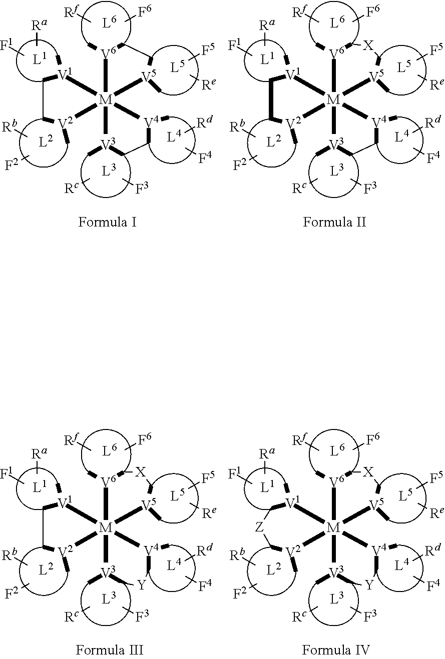

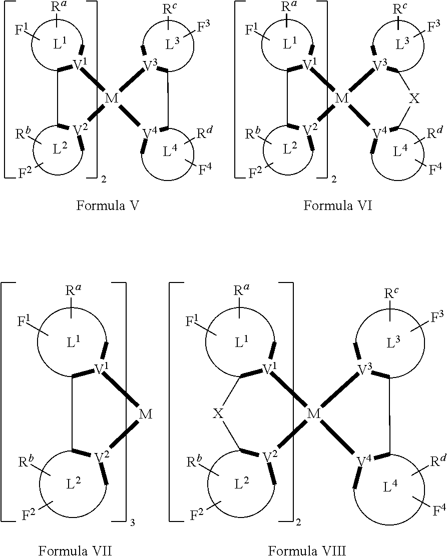

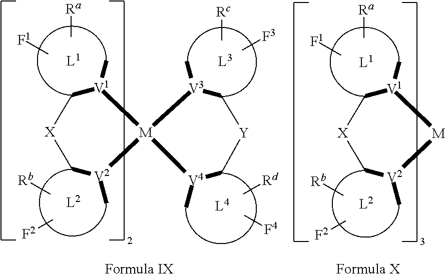

### CROSS-REFERENCE TO RELATED APPLICATION

This application is a continuation of U.S. patent application Ser. No. 15/795,615 entitled “EMITTERS BASED ON OCTAHEDRAL METAL COMPLEXES” filed on Oct. 27, 2017, which is a continuation of U.S. patent application Ser. No. 14/937,136 entitled “EMITTERS BASED ON OCTAHEDRAL METAL COMPLEXES” filed on Nov. 10, 2015, now U.S. Pat. No. 9,865,825, which claims priority to U.S. Provisional Patent Application No. 62/077,443 entitled “EMITTERS BASED ON OCTAHEDRAL METAL COMPLEXES” filed on Nov. 10, 2014, the disclosures of which are incorporated by reference herein in their entirety.

### TECHNICAL FIELD

The present disclosure relates to multidentate iridium, rhodium, and platinum complexes suitable for use as phosphorescent or delayed fluorescent and phosphorescent emitters in display and lighting applications.

### BACKGROUND

Compounds capable of absorbing and/or emitting light can be ideally suited for use in a wide variety of optical and electroluminescent devices, including, for example, photo-absorbing devices such as solar- and photo-sensitive devices, organic light emitting diodes (OLEDs), photo-emitting devices, or devices capable of both photo-absorption and emission and as markers for bio-applications. Much research has been devoted to the discovery and optimization of organic and organometallic materials for using in optical and electroluminescent devices. Generally, research in this area aims to accomplish a number of goals, including improvements in absorption and emission efficiency and improvements in the stability of devices, as well as improvements in processing ability.

Despite significant advances in research devoted to optical and electro-optical materials (e.g., red and green phosphorescent organometallic materials are commercially available and have been used as phosphors in organic light emitting diodes (OLEDs), lighting and advanced displays), many currently available materials exhibit a number of disadvantages, including poor processing ability, inefficient emission or absorption, and less than ideal stability, among others.

Good blue emitters are particularly scarce, with one challenge being the stability of the blue devices. The choice of the host materials has an impact on the stability and the efficiency of the devices. The lowest triplet excited state energy of the blue phosphors is very high compared with that of the red and green phosphors, which means that the lowest triplet excited state energy of host materials for the blue devices should be even higher. Thus, one of the problems is that there are limited host materials to be used for the blue devices. Accordingly, a need exists for new materials which exhibit improved performance in optical emitting and absorbing applications.

### SUMMARY

The present disclosure relates to iridium, rhodium and platinum complexes suitable for use as emitters in organic light emitting diodes (OLEDs), display and lighting applications.

Disclosed herein are complexes of Formula I, Formula II, Formula III, Formula IV, Formula V, Formula VI, Formula VII, Formula VIII, Formula IX, and Formula X:

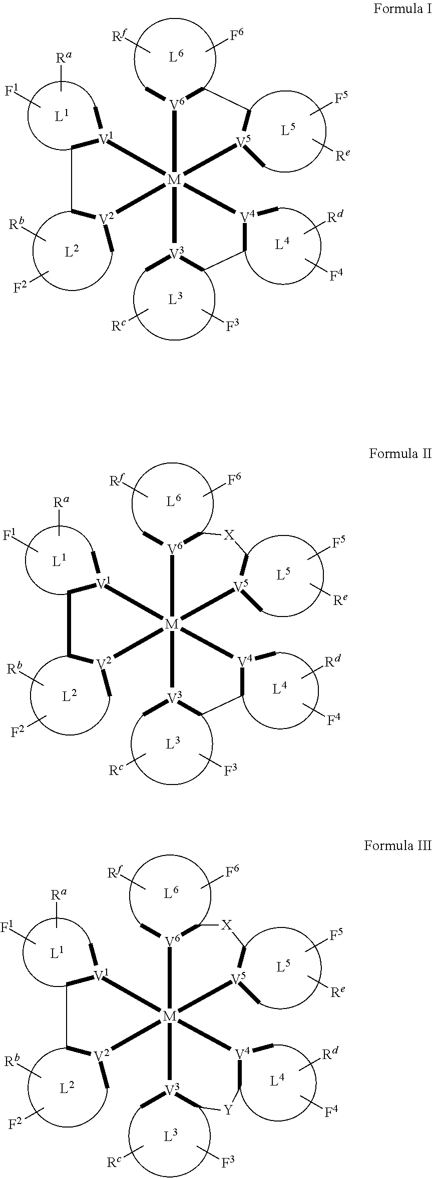

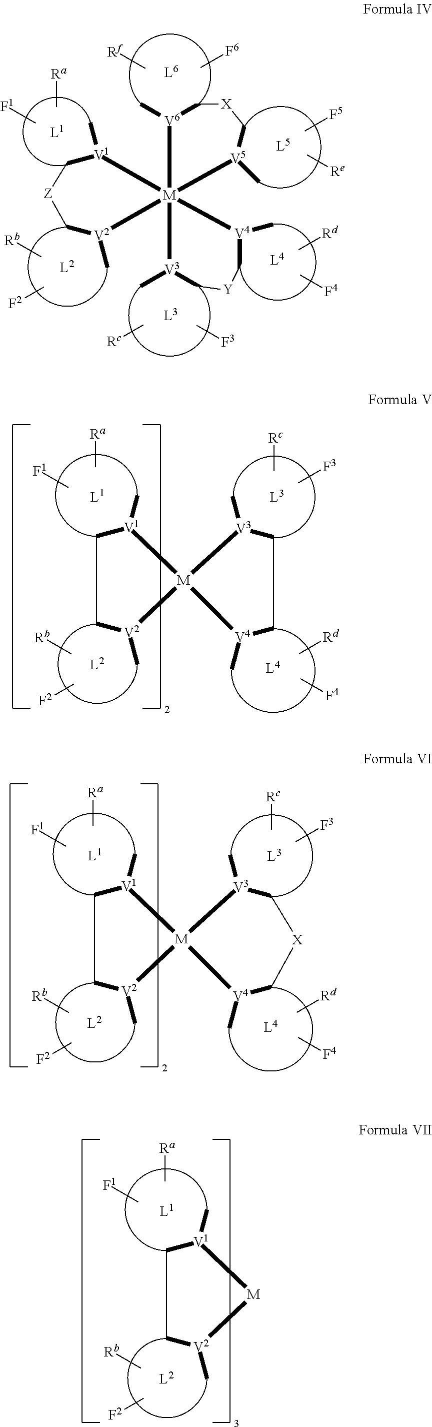

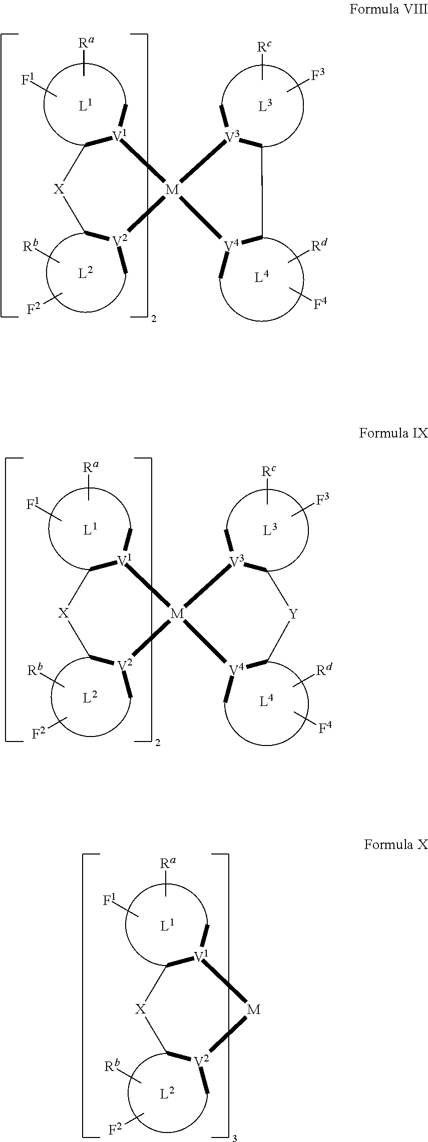

wherein:
M is Ir(III), Rh(III), or Pt(IV),
each of L¹, L², L³, L⁴, L⁵, and L⁶ is independently a substituted or unsubstituted aryl, cycloalkyl, cycloalkenyl, heteroaryl, heterocyclyl, carbene, or N-heterocyclic carbene, dione, cyanogen, or phosphine,
each of V¹, V², V³, V⁴, V⁵, and V⁶ is coordinated with M and is independently N, C, P, B, or Si,
each of X, Y, and Z is independently CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³,
each of F¹, F², F³, F⁴, F⁵, and F⁶ is independently present or absent, wherein at least one of F¹, F², F³, F⁴, F⁵, and F⁶ is present, and each F¹, F², F³, F⁴, F⁵, and F⁶ present is a fluorescent luminophore,
each of R^{a}, R^{b}, R^{c}, R^{d}, R^{e}, and R^{f} is independently present or absent, and if present each of R^{a}, R^{b}, R^{c}, R^{d}, R^{e} and R^{f} independently represents mono-, di-, or ti-substitutions, and wherein each of R^{a}, R^{b}, R^{c}, R^{d}, R^{e} and R^{f} present is independently deuterium, halogen, hydroxyl, thiol, nitro, cyano, nitrile, isonitrile, sulfinyl, mercapto, sulfo, carboxyl, hydrazino; substituted or unsubstituted aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and
each of R¹, R², and R³ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

Also disclosed herein are compositions including one or more compounds disclosed herein.

Also disclosed herein are devices, such as OLEDs, including one or more compounds or compositions disclosed herein.

### BRIEF DESCRIPTION OF THE FIGURES

FIG. 1 depicts a Jablonski energy diagram for metal complexes disclosed herein.

FIG. 2 depicts a device including a metal complex as disclosed herein.

FIG. 3 shows emission spectra of mer-(fppy)₂Ir(1a) in CH₂Cl₂ at room temperature and in 2-methyltetrahydrofuran at 77K.

FIG. 4 shows emission spectra of fac-(fppy)₂Ir(1a) in CH₂Cl₂ at room temperature and in 2-methyltetrahydrofuran at 77K.

FIG. 5 shows emission spectra of mer-(fppy)Ir(1a)₂ in CH₂Cl₂ at room temperature and in 2-methyltetrahydrofuran at 77K.

FIG. 6 shows emission spectra of fac-(fppy)Ir(1a)₂ in CH₂Cl₂ at room temperature and in 2-methyltetrahydrofuran at 77K.

FIG. 7 shows emission spectra of mer-(fppy)Ir(1b)₂ in CH₂Cl₂ at room temperature and in 2-methyltetrahydrofuran at 77K.

FIG. 8 shows emission spectra of fac-(fppy)Ir(1b)₂ in CH₂Cl₂ at room temperature and in 2-methyltetrahydrofuran at 77K.

Additional aspects will be set forth in the description which follows. Advantages will be realized and attained by means of the elements and combinations particularly pointed out in the claims. It is to be understood that both the foregoing general description and the following detailed description are exemplary and explanatory only and are not restrictive.

### DETAILED DESCRIPTION

The present disclosure can be understood more readily by reference to the following detailed description and the Examples included therein.

Before the present compounds, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting. Although any methods and materials similar or equivalent to those described herein can be used in the practice or testing, example methods and materials are now described.

As used in the specification and the appended claims, the singular forms “a”, “an”, and “the” include plural referents unless the context clearly dictates otherwise. Thus, for example, reference to “a component” includes mixtures of two or more components.

As used herein, the terms “optional” and “optionally” mean that the subsequently described event or circumstance can or cannot occur, and that the description includes instances where said event or circumstance occurs and instances where it does not.

Disclosed are the components to be used to prepare the compositions described herein as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions. Thus, if there are a variety of additional steps that can be performed it is understood that each of these additional steps can be performed with any specific embodiment or combination of embodiments of the methods.

As referred to herein, a linking atom or group connects two atoms such as, for example, a N atom and a C atom. A linking group is in one aspect disclosed as X, Y, or Z herein. The linking atom can optionally, if valency permits, have other chemical moieties attached. For example, in one aspect, an oxygen would not have any other chemical groups attached as the valency is satisfied once it is bonded to two atoms (e.g., N or C atoms). In another aspect, when carbon is the linking atom, two additional chemical moieties such as amine, amide, thiol, aryl, heteroaryl, cycloalkyl, and heterocyclyl moieties may be attached to the carbon.

The term “cyclic structure” or the like terms used herein refer to any cyclic chemical structure which includes, but is not limited to, aryl, heteroaryl, cycloalkyl, cycloalkenyl, heterocyclyl, carbene, and N-heterocyclic carbene.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

In defining various terms, “A,” “A¹,” “A²,” “A³,” and “A⁴” are used herein as generic symbols to represent various specific substituents. These symbols can be any substituent, not limited to those disclosed herein, and when they are defined to be certain substituents in one instance, they can, in another instance, be defined as some other substituents.

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g. an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is anon-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “polyalkylene group” as used herein is a group having two or more CH₂ groups linked to one another. The polyalkylene group can be represented by the formula-(CH₂)ₐ—, where “a” is an integer of from 2 to 500.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a polyether such as —OA¹-OA² or —OA¹-(OA²)ₐ-OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is anon-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “aldehyde” as used herein is represented by the formula —C(O)H. Throughout this specification “C(O)” is a short hand notation for a carbonyl group, i.e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyl)amino group, pentylamino group, isopentylamino group, (tert-pentyl)amino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl-N-methylamino group, N-methyl-N-propylamino group, N-ethyl-N-propylamino group and the like.

The term “carboxylic acid” as used herein is represented by the formula —C(O)OH.

The term “ester” as used herein is represented by the formula —OC(O)A¹ or —C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula -(A¹O(O)C-A²-C(O)O)ₐ— or -(A¹O(O)C-A²-OC(O))ₐ—, where A¹ and A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “polymeric” includes polyalkylene, polyether, polyester, and other groups with repeating units, such as, but not limited to —(CH₂O)ₙ—CH₃, —(CH₂CH₂O)ₙ—CH₃, —[CH₂CH(CH₃)]ₙ—CH₃, —[CH₂CH(COOCH₃)]ₙ—CH₃, —[CH₂CH(COO CH₂CH₃)]ₙ—CH₃, and —[CH₂CH(COO^{t}Bu)]ₙ—CH₃, where n is an integer (e.g., n>1 or n>2).

The term “halide” as used herein refers to the halogens fluorine, chlorine, bromine, and iodine.

The term “heterocyclyl,” as used herein refers to single and multi-cyclic non-aromatic ring systems and “heteroaryl as used herein refers to single and multi-cyclic aromatic ring systems: in which at least one of the ring members is other than carbon. The terms includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula —N₃.

The term “nitro” as used herein is represented by the formula —NO₂.

The term “nitrile” as used herein is represented by the formula —CN.

The term “silyl” as used herein is represented by the formula —SiA¹A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas —S(O)A¹, —S(O)₂A¹, —OS(O)₂A¹, or —OS(O)₂OA¹, where A¹ can be hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O. The term “sulfonyl” is used herein to refer to the sulfo-oxo group represented by the formula —S(O)₂A¹, where A¹ can be hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where A¹ and A² can be, independently, an alkyl, cycloalkyl, alkenyl, cycloalkenyl, alkynyl, cycloalkynyl, aryl, or heteroaryl group as described herein.

The term “thiol” as used herein is represented by the formula —SH.

“R,” “R¹,” “R²,” “R³,” “Rⁿ,” where n is an integer, as used herein can, independently, possess one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

Compounds described herein may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this invention are preferably those that result in the formation of stable or chemically feasible compounds. In is also contemplated that, in certain aspects, unless expressly indicated to the contrary, individual substituents can be further optionally substituted (i.e., further substituted or unsubstituted).

In some aspects, a structure of a compound can be represented by a formula:

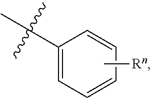

which is understood to be equivalent to a formula:

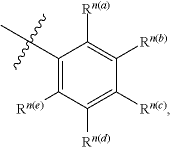

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance R^{n(a)} is halogen, then R^{n(b)} is not necessarily halogen in that instance.

Several references to R, R¹, R², R³, R⁴, R⁵, R⁶, etc. are made in chemical structures and moieties disclosed and described herein. Any description of R, R¹, R², R³, R⁴, R⁵, R⁶, etc. in the specification is applicable to any structure or moiety reciting R, R¹, R², R³, R⁴, R⁵, R⁶, etc. respectively.

### 1. Compounds

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

Excitons decay from singlet excited states to ground state to yield prompt luminescence, which is fluorescence. Excitons decay from triplet excited states to ground state to generate luminescence, which is phosphorescence. Because the strong spin-orbit coupling of the heavy metal atom enhances intersystem crossing (ISC) very efficiently between singlet and triplet excited states, phosphorescent metal complexes, such as platinum complexes, have demonstrated their potential to harvest both the singlet and triplet excitons to achieve 100% internal quantum efficiency. Thus phosphorescent metal complexes are good dopants in the emissive layer of organic light emitting devices (OLEDs). Much achievement has been made in the past decade to lead to the lucrative commercialization of the technology, for example, OLEDs have been used in advanced displays in smart phones, televisions, and digital cameras.

However, to date, blue electroluminescent devices remain the most challenging area of this technology, due at least in part to instability of the blue devices. It is generally understood that the choice of host materials is a factor in the stability of the blue devices. But the lowest triplet excited state (T₁) energy of the blue phosphors is high, which generally means that the lowest triplet excited state (T₁) energy of host materials for the blue devices should be even higher. This leads to difficulty in the development of the host materials for the blue devices.

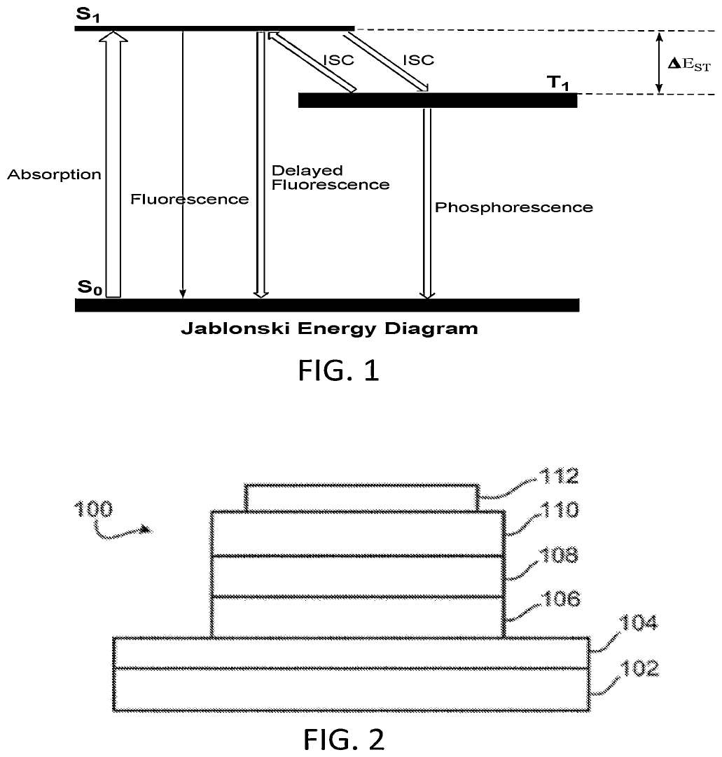

This disclosure provides a materials design route by introducing fluorescent luminophore(s) to the ligand of the metal complexes. Thereby chemical structures of the fluorescent luminophores and the ligands may be modified, and also the metal may be changed to adjust the singlet states energy and the triplet states energy of the metal complexes, which all may affect the optical properties of the complexes, for example, emission and absorption spectra. Accordingly, the energy gap (ΔE_{ST}) between the lowest triplet excited state (T₁) and the lowest singlet excited state (S₁) may be also adjusted. When the ΔE_{ST} becomes small enough, intersystem crossing (ISC) from the lowest triplet excited state (T₁) to the lowest singlet excited state (S₁) may occur efficiently, such that the excitons undergo non-radiative relaxation via ISC from T₁ to S₁, then relax from S₁ to S₀, which leads to delayed fluorescence, as depicted in the Jablonski Energy Diagram in FIG. 1. Through this pathway, higher energy excitons may be obtained from lower excited state (from T₁→S₁), which means more host materials may be available for the dopants. This approach offers a solution to problems associated with blue devices.

The metal complexes described herein can be tailored or tuned to a specific application that requires a particular emission or absorption characteristic. The optical properties of the metal complexes in this disclosure can be tuned by varying the structure of the ligand surrounding the metal center or varying the structure of fluorescent luminophore(s) on the ligands. For example, the metal complexes having a ligand with electron donating substituents or electron withdrawing substituents can generally exhibit different optical properties, including emission and absorption spectra. The color of the metal complexes can be tuned by modifying the conjugated groups on the fluorescent luminophores and ligands.

The emission of such complexes can be tuned (e.g., from the ultraviolet to near-infrared), by, for example, modifying the ligand or fluorescent luminophore structure. A fluorescent luminophore is a group of atoms in an organic molecule, which can absorb energy to generate singlet excited state(s), and the singlet exciton(s) produced decay rapidly to yield prompt luminescence. In another aspect, the complexes provide emission over a majority of the visible spectrum. In one example, the complexes described herein emit light over a range of from about 400 nm to about 700 nm. In another aspect, the complexes have improved stability and efficiency over traditional emission complexes. In yet another aspect, the complexes are suitable for luminescent labels in, for example, bio-applications, anti-cancer agents, emitters in organic light emitting diodes (OLED), or a combination thereof. In another aspect, the complexes described herein are suitable for light emitting devices, such as, for example, compact fluorescent lamps (CFL), light emitting diodes (LED), incandescent lamps, and combinations thereof.

Disclosed herein are compounds or compound complexes comprising iridium, rhodium and platinum compounds. The terms compound, compound complex, and complex are used interchangeably herein. In one aspect, the compounds disclosed herein have a neutral charge.

The compounds disclosed herein can exhibit desirable properties and have emission and/or absorption spectra that can be tuned via the selection of appropriate ligands. In another aspect, any one or more of the compounds, structures, or portions thereof, specifically recited herein may be excluded.

The compounds disclosed herein are suited for use in a wide variety of optical and electro-optical devices, including, but not limited to, photo-absorbing devices such as solar- and photo-sensitive devices, organic light emitting diodes (OLEDs), photo-emitting devices, or devices capable of both photo-absorption and emission and as markers for bio-applications.

As briefly described above, the disclosed compounds are iridium, rhodium, and platinum complexes. In one aspect, the compounds disclosed herein can be used as host materials for OLED applications, such as full color displays.

The compounds disclosed herein are useful in a variety of applications. As light emitting materials, the compounds can be useful in organic light emitting diodes (OLEDs), luminescent devices and displays, and other light emitting devices.

In another aspect, the compounds can provide improved efficiency and/or operational lifetimes in lighting devices, such as, for example, organic light emitting devices, as compared to conventional materials.

Compounds described herein can be made using a variety of methods, including, but not limited to those recited in the examples.

In one aspect, the compounds disclosed herein are delayed fluorescent emitters. In another aspect, the compounds disclosed herein are phosphorescent emitters. In yet another aspect, the compounds disclosed herein are delayed fluorescent emitters and phosphorescent emitters.

Disclosed herein are complexes of Formula I, Formula II, Formula III, Formula IV, Formula V, Formula VI, Formula VII, Formula VIII, Formula IX, and Formula X:

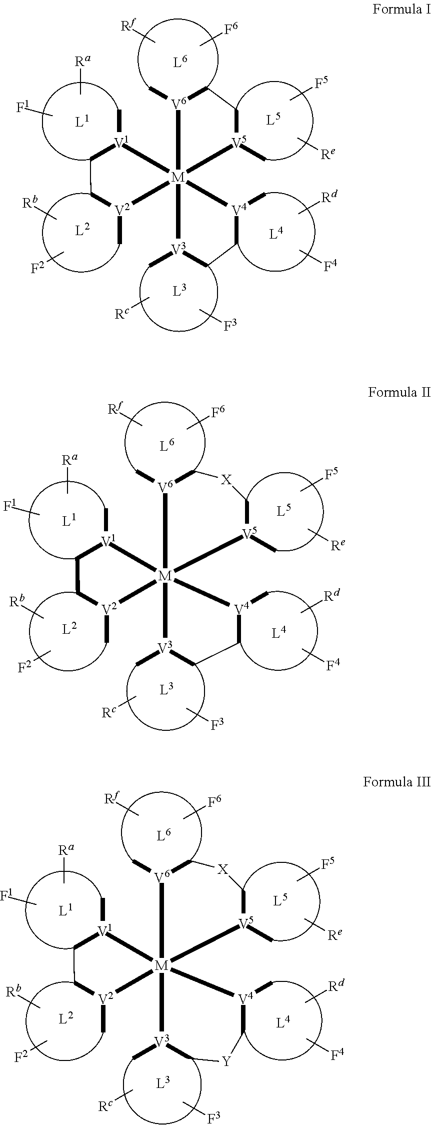

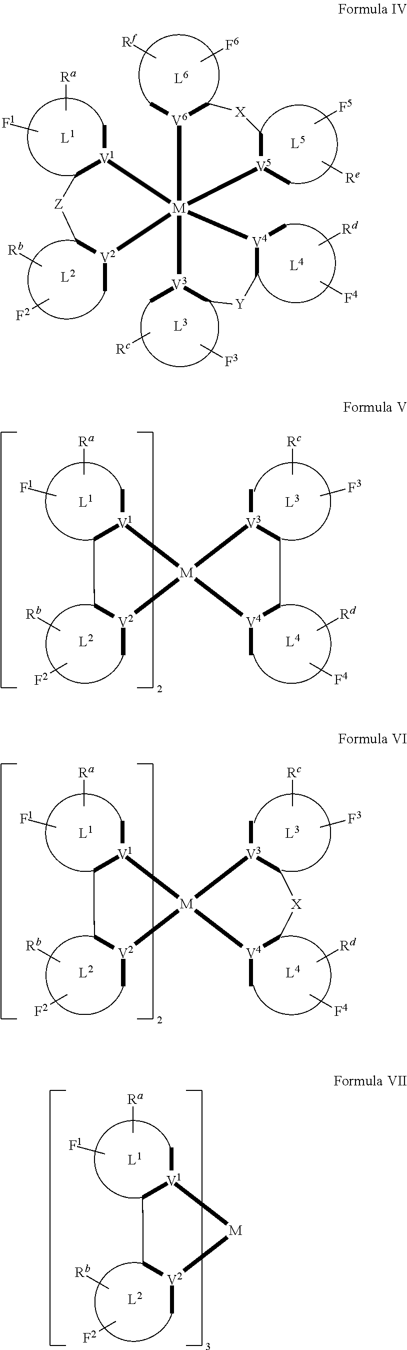

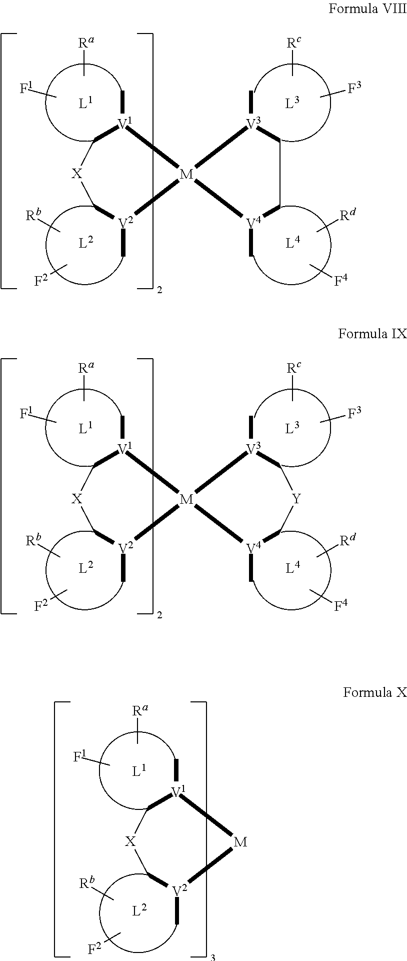

wherein:
M is Ir(III), Rh(III), or Pt(IV),
each of L¹, L², L³, L⁴, L⁵ and L⁶ is independently a substituted or unsubstituted aryl, cycloalkyl, cycloalkenyl, heteroaryl, heterocyclyl, carbene, or N-heterocyclic carbene, dione, cyanogen, or phosphine,
each of V¹, V², V³, V⁴, V⁵, and V⁶ is coordinated with M and is independently N, C, P, B, or Si,
each of X, Y, and Z is independently CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³,
each of F¹, F², F³, F⁴, F⁵, and F⁶ is independently present or absent, wherein at least one of F¹, F², F³, F⁴, F⁵, and F⁶ is present, and each F¹, F², F³, F⁴, F⁵, and F⁶ present is a fluorescent luminophore,
each of R^{a}, R^{b}, R^{c}, R^{d}, R^{e}, and R^{f} is independently present or absent, and if present each of R^{a}, R^{b}, R^{c}, R^{d}, R^{e}, and R^{f} independently represents mono-, di-, or tri-substitutions, and wherein each of R^{a}, R^{b}, R^{c}, R^{d}, R^{e} and R^{f} present is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and
each of R¹, R², and R³ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

For Formulas I-X as described herein, groups may be defined as described below.

A. M Groups

In one aspect, M is Ir(III).

In another aspect, M is Rh(III).

In yet another aspect, M is Pt(IV).

B. V Groups

In one aspect, each of V¹, V², V³, V⁴, V⁵, and V⁶ is coordinated with M and is independently N, C, P, B, or Si.

In another aspect, each of V¹, V², V³, V⁴, V⁵, and V⁶ is independently N or C.

In yet another aspect, each of V¹, V², V³, V⁴, V⁵, and V⁶ is independently P or B.

In yet another aspect, each of V¹, V², V³, V⁴, V⁵, and V⁶ is Si.

C. Linking Groups

In one aspect, each of X, Y, and Z is independently present or absent, and each X, Y, and Z present is independently CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³.

In another aspect, each of X, Y, and Z, if present, is independently O, S, or CH₂.

D. L Groups

In one aspect, L¹ is aryl, cycloalkyl, cycloalkenyl, heteroaryl, heterocyclyl, carbene, or N-heterocyclic carbene. In one example, L¹ is aryl, cycloalkyl, cycloalkenyl, heteroaryl, or N-heterocyclyl. In another example, L¹ is aryl or heteroaryl. In yet another example, L¹ is aryl.

In one aspect, L² is aryl, cycloalkyl, cycloalkenyl, heteroaryl, heterocyclyl, carbene, or N-heterocyclic carbene. In one example, L² is aryl, cycloalkyl, cycloalkenyl, heteroaryl, or N-heterocyclyl. In another example, L² is aryl or heteroaryl. In yet another example, L² is aryl.

In one aspect, L³ is aryl, cycloalkyl, cycloalkenyl, heteroaryl, heterocyclyl, carbene, or N-heterocyclic carbene. In one example, L³ is aryl, cycloalkyl, cycloalkenyl, heteroaryl, or heterocyclyl. In another example, L³ is aryl or heteroaryl. In yet another example, L³ is aryl.

In one aspect, L⁴ is aryl, cycloalkyl, cycloalkenyl, heteroaryl, heterocyclyl, carbene, or N-heterocyclic carbene. In one example, L⁴ is aryl, cycloalkyl, cycloalkenyl, heteroaryl, or heterocyclyl. In another example, L⁴ is aryl or heteroaryl. In yet another example, L⁴ is aryl.

In one aspect, L⁵ is aryl, cycloalkyl, cycloalkenyl, heteroaryl, heterocyclyl, carbene, or N-heterocyclic carbene. In one example, L⁵ is aryl, cycloalkyl, cycloalkenyl, heteroaryl, or heterocyclyl. In another example, L⁵ is aryl or heteroaryl. In yet another example, L⁵ is aryl.

In one aspect, L⁶ is aryl, cycloalkyl, cycloalkenyl, heteroaryl, heterocyclyl, carbene, or N-heterocyclic carbene. In one example, L⁶ is aryl, cycloalkyl, cycloalkenyl, heteroaryl, or heterocyclyl. In another example, L⁶ is aryl or heteroaryl. In yet another example, L⁶ is heteroaryl. In yet another example, L⁶ is heterocyclyl.

It is understood that Vⁿ can be a part of Lⁿ, where n=1 to 6, and is intended to be included the descriptions of Lⁿ above.

In one aspect, for any of the formulas disclosed herein, each of

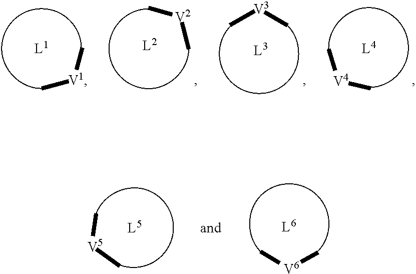

is independently one following structures:

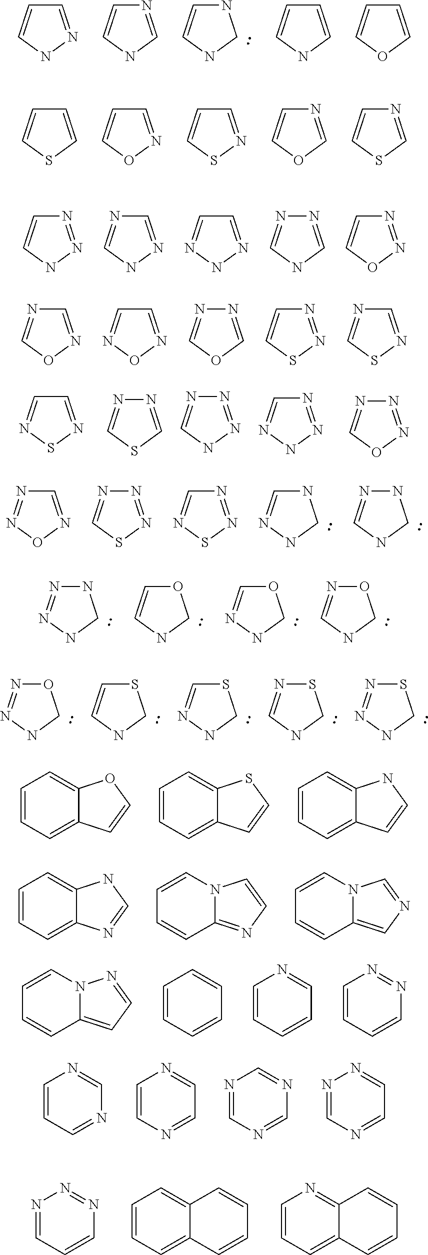

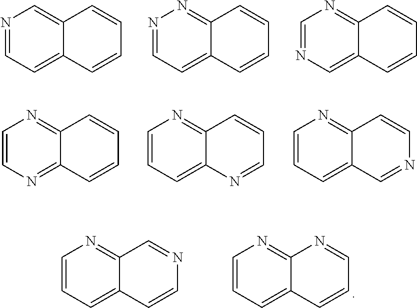

It is understood that one or more of R^{a}, R^{b}, R^{c}, R^{d}, R^{e}, and R^{f} as described herein can be bonded to one of the above structures as permitted by valency.

In one aspect,

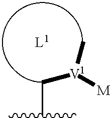

has the structure

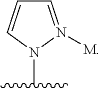

In one aspect, for any of the formulas illustrated in this disclosure, each of

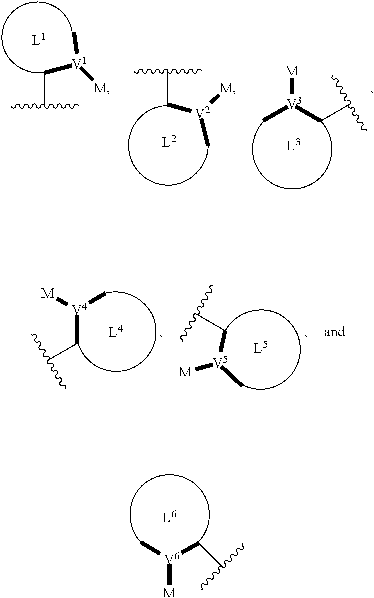

is independently one of following structures:

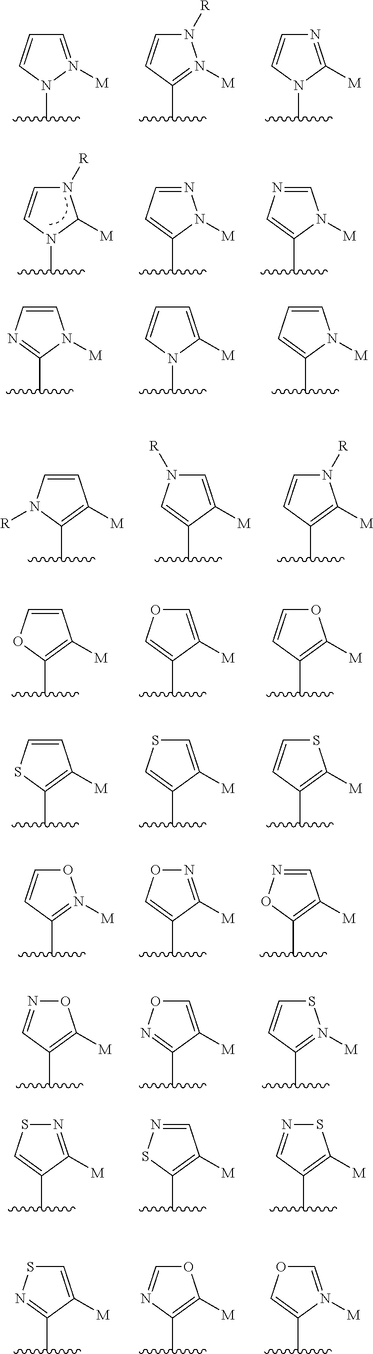

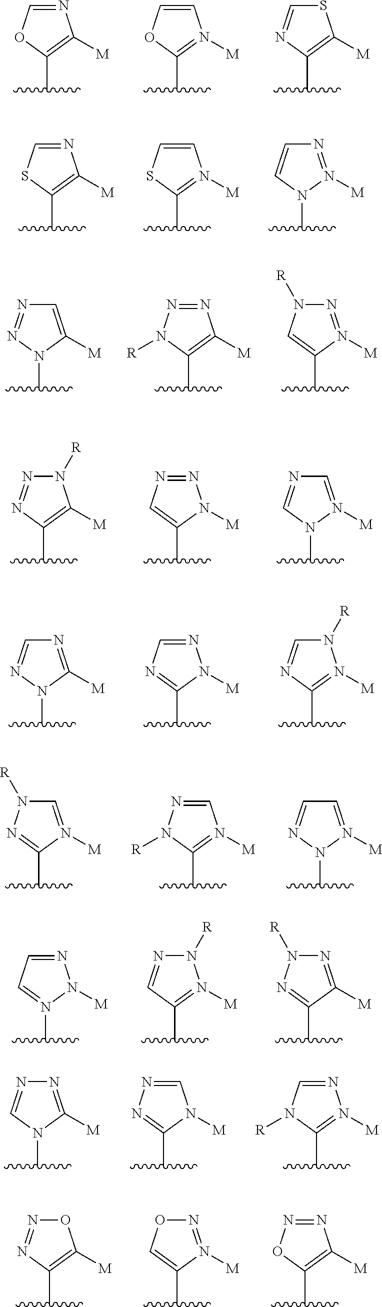

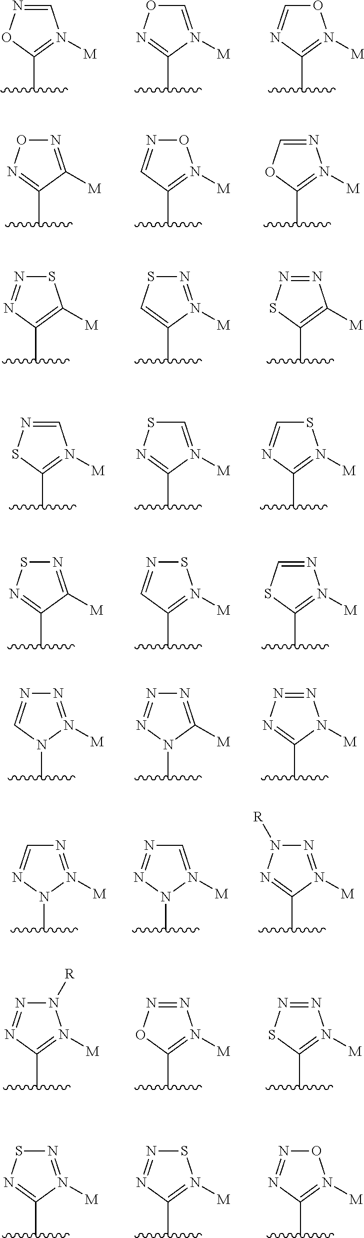

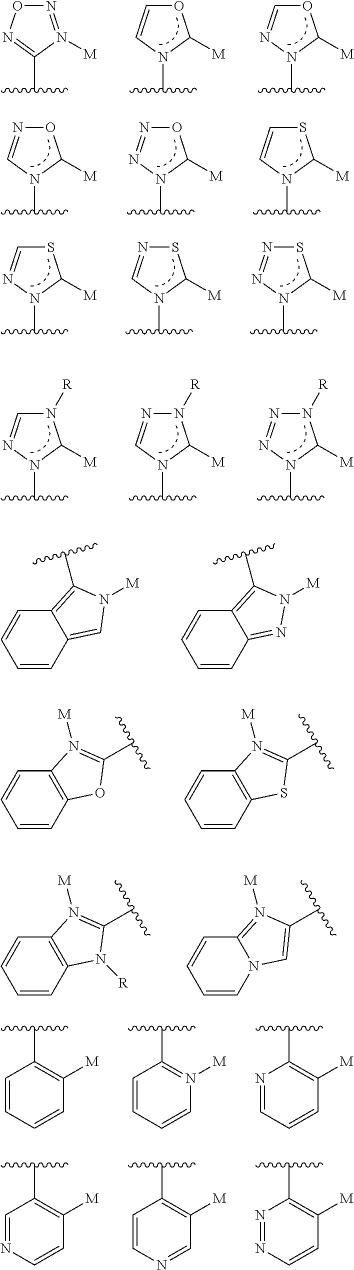

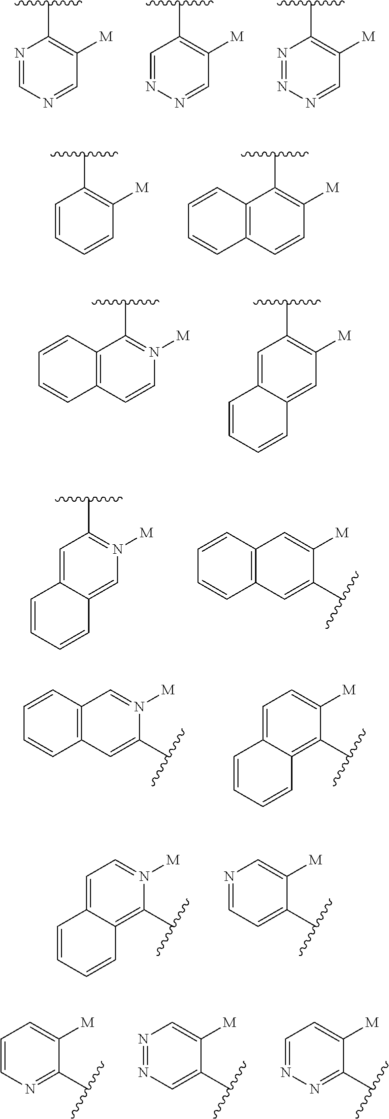

wherein R is hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

E. Fluorescent Luminophore Groups

In one aspect, at least one of F¹, F², F³, F⁴, F⁵, and F⁶ is present. In one example, F¹ is present, and F², F³, F⁴, F⁵, and F⁶ are absent.

In one aspect, each of F¹, F², F³, F⁴, F⁵, and F⁶ present is independently selected from aromatic hydrocarbons and their derivatives, polyphenyl hydrocarbons, hydrocarbons with condensed aromatic nuclei, naphthalene, anthracene, phenanthrene, chrysene, pyrene, triphenylene, perylene, acenapthene, tetracene, pentacene, tetraphene, coronene, fluorene, biphenyl, p-terphenyl, o-diphenylbenzene, m-diphenylbenzene, p-quaterphenyl, benzo[a]tetracene, benzo[k]tetraphene, indeno[1,2,3-cd]fluoranthene, tetrabenzo[de,hi,op,st]pentacene, arylethylene, arylacetylene and their derivatives, diarylethylenes, diarylpolyenes, diaryl-substituted vinylbenzenes, distyrylbenzenes, trivinylbenzenes, arylacetylenes, stilbene, and functional substitution products of stilbene.

In another aspect, each F¹, F², F³, F⁴, F⁵, and F⁶ present is independently selected from substituted or unsubstituted five-, six- or seven-membered heterocyclic compounds, furan, thiophene, pyrrole and their derivatives, aryl-substituted oxazoles, 1,3,4-oxadiazoles, 1,3,4-thiadiazoles, aryl-substituted 2-pyrazolines and pyrazoles, benzazoles, 2H-benzotriazole and its substitution products, heterocycles with one, two or three nitrogen atoms, oxygen-containing heterocycles, coumarins and their derivatives, miscellaneous dyes, acridine dyes, xanthene dyes, oxazines, and thiazines.

In yet another aspect, for any of the formulas disclosed herein, each F¹, F², F³, F⁴, F⁵, and F⁶ present may independently have one of the following structures:

### 1. Aromatic Hydrocarbons and their Derivatives

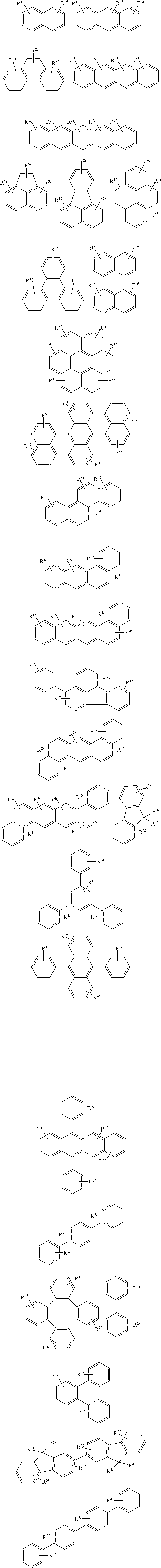

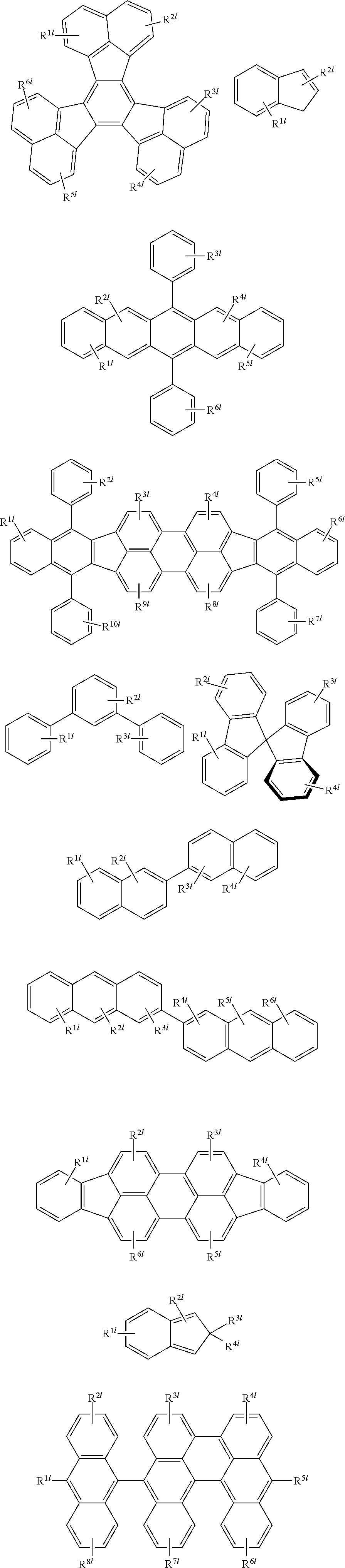

### 2. Arylethylene, Arylacetylene and their Derivatives

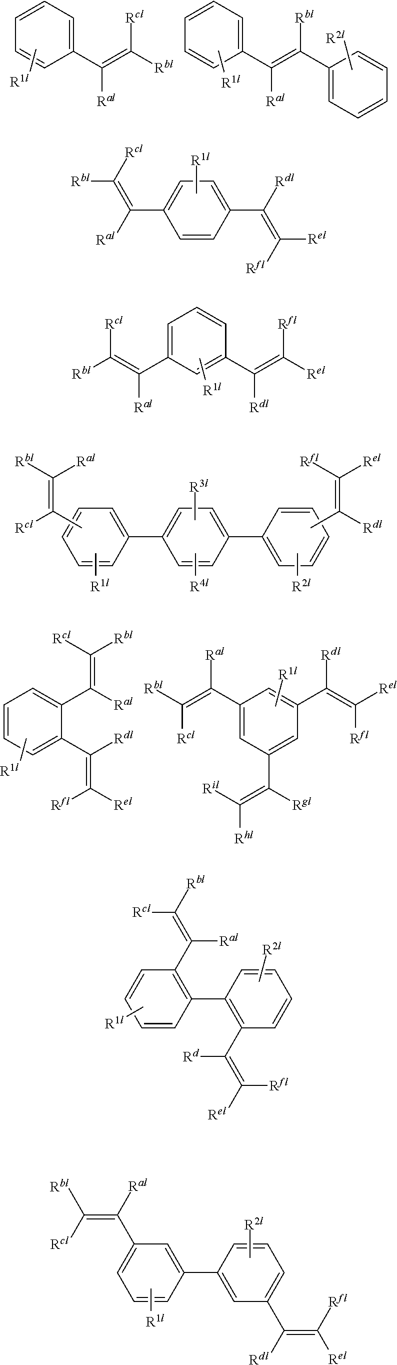

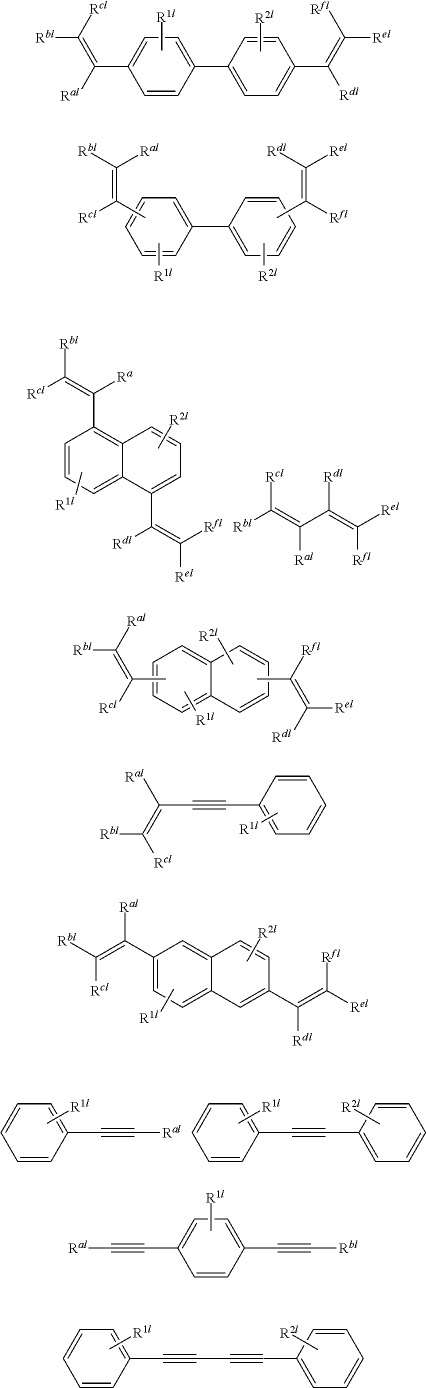

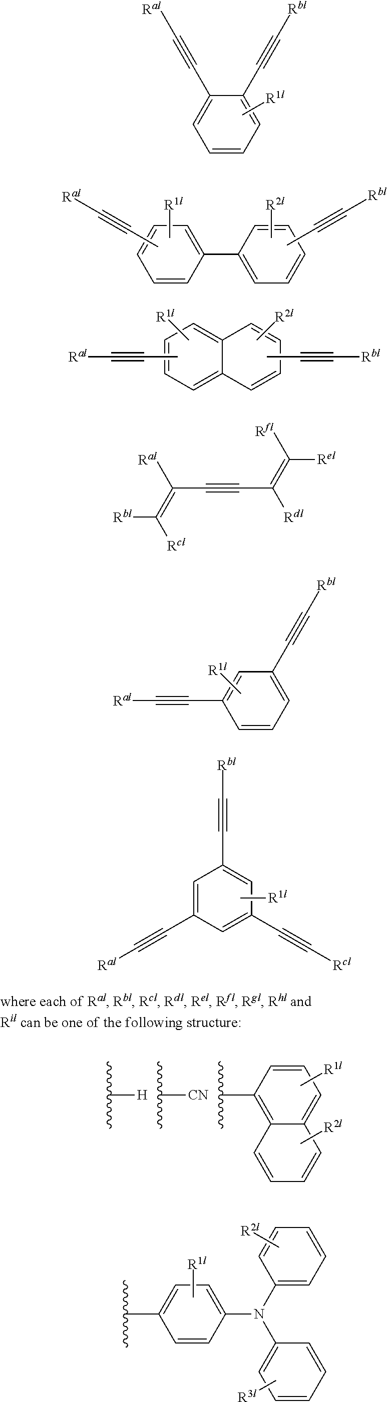

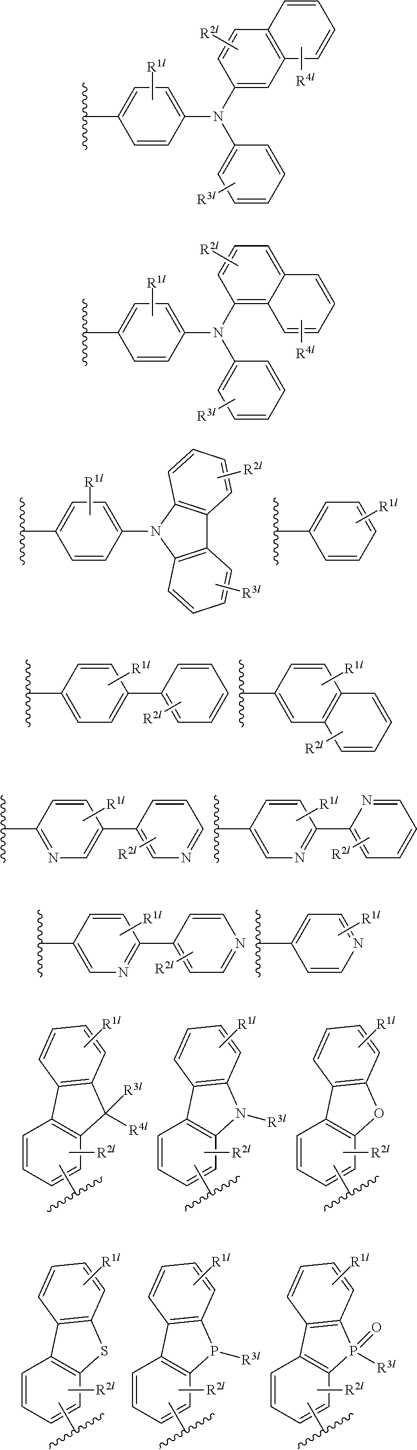

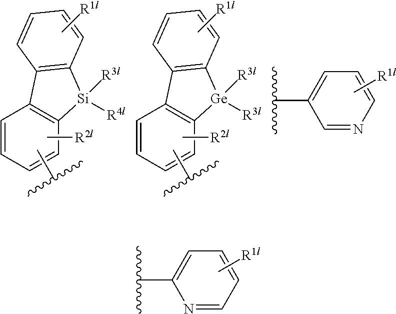

### 3. Heterocyclic Compounds and their Derivatives

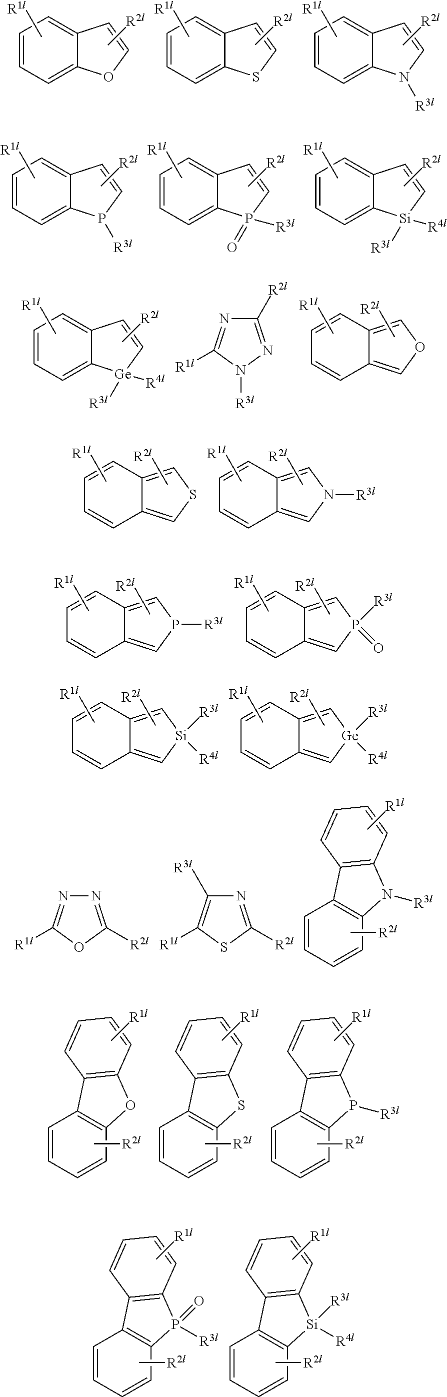

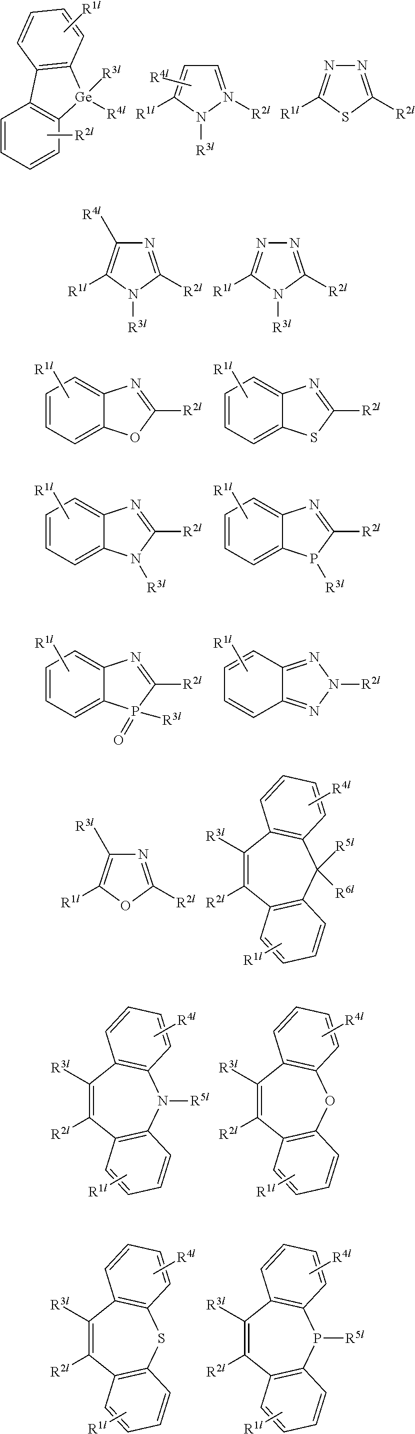

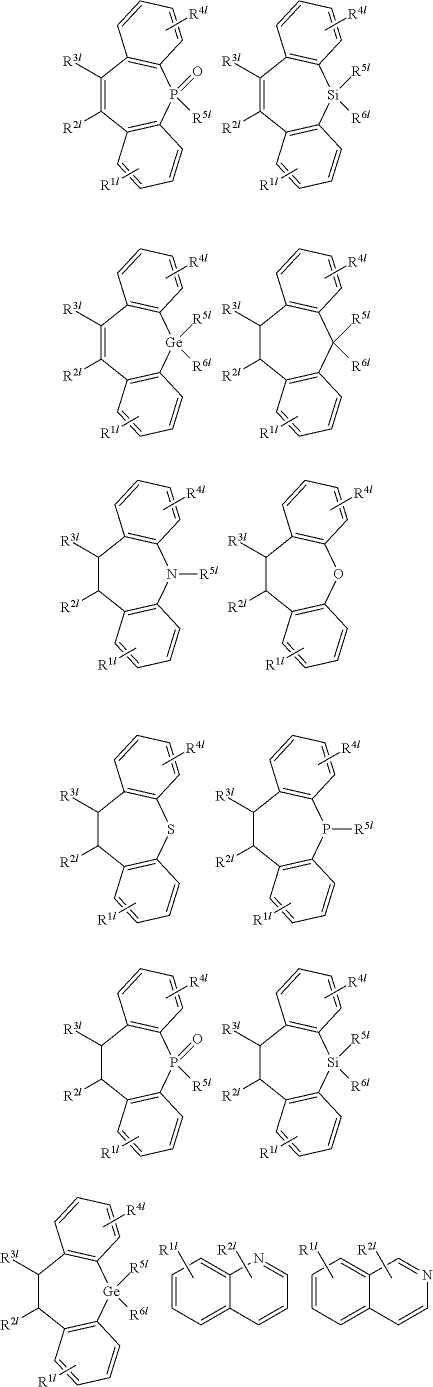

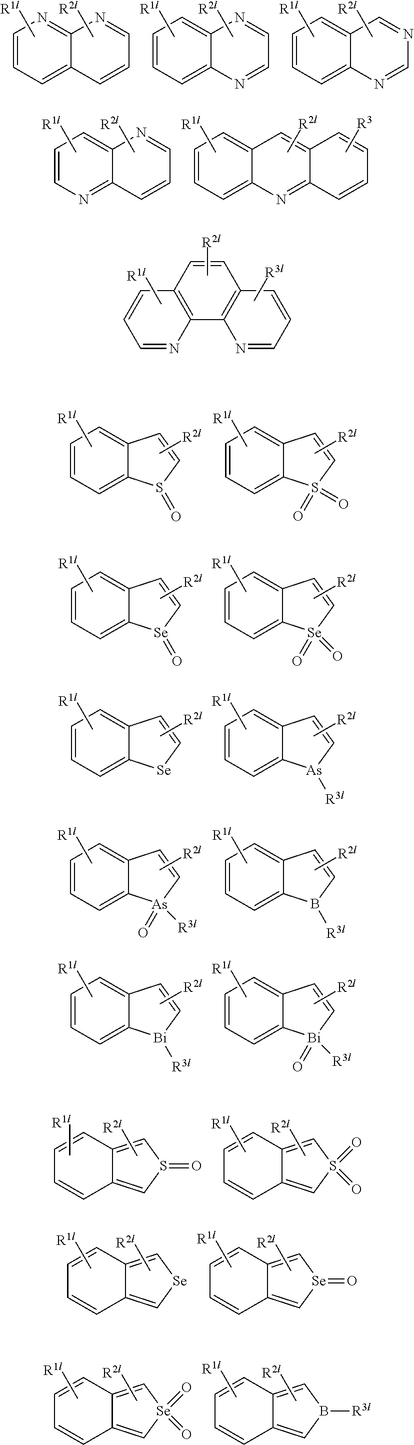

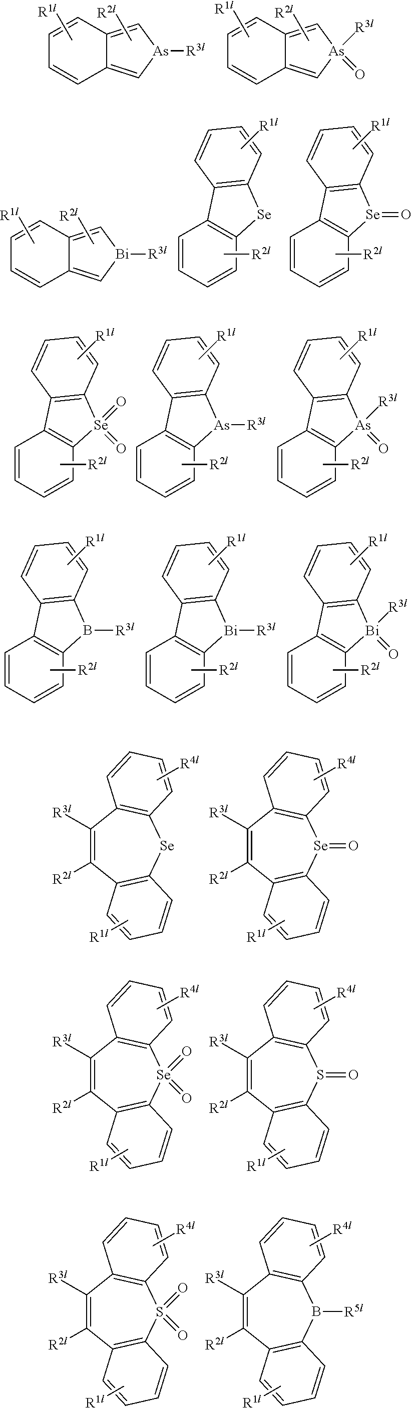

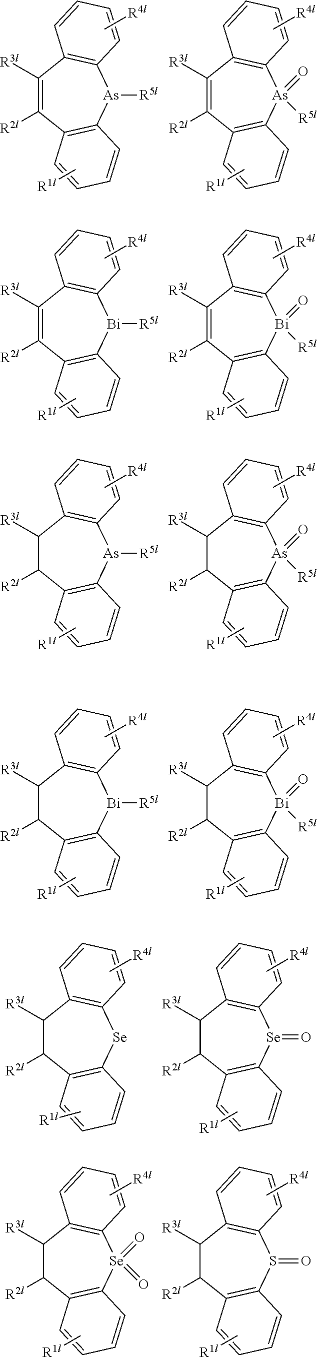

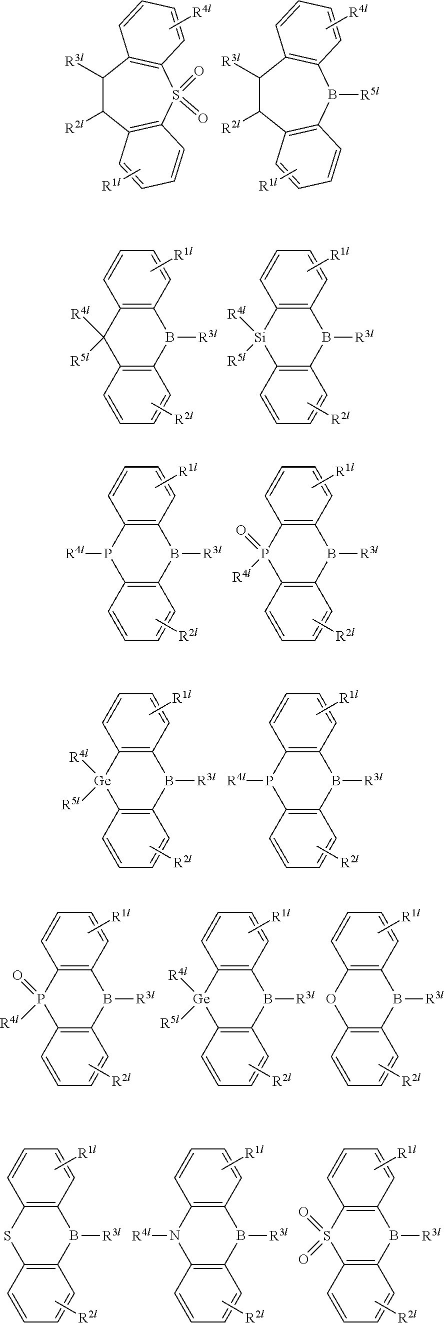

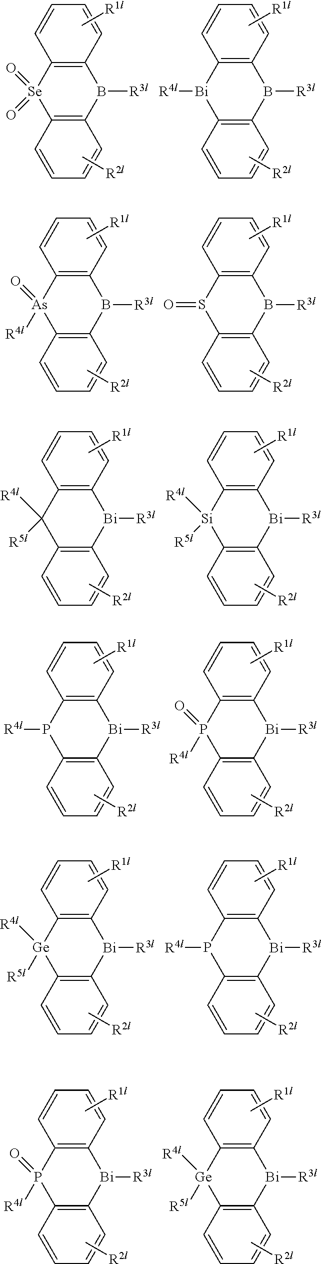

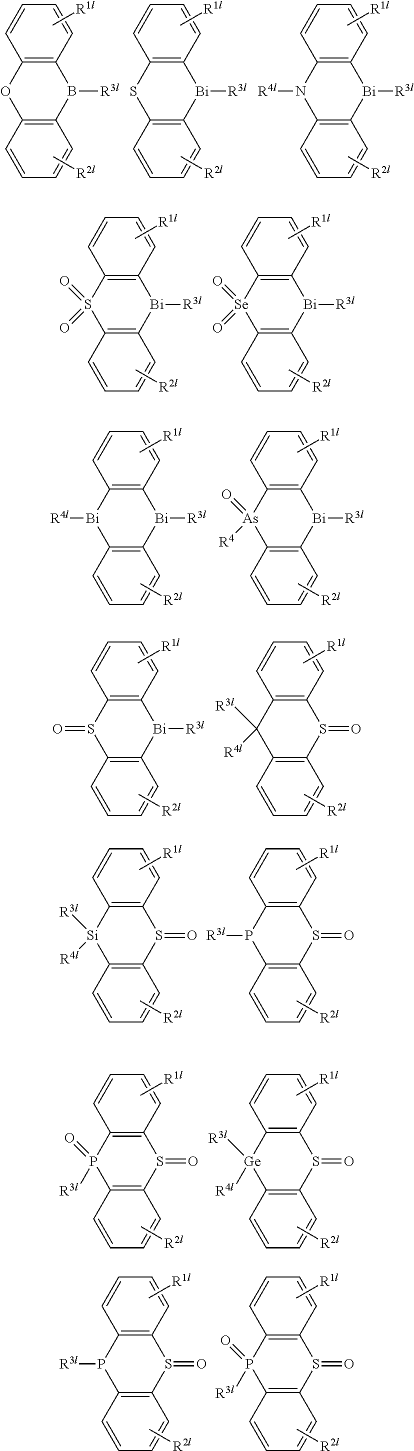

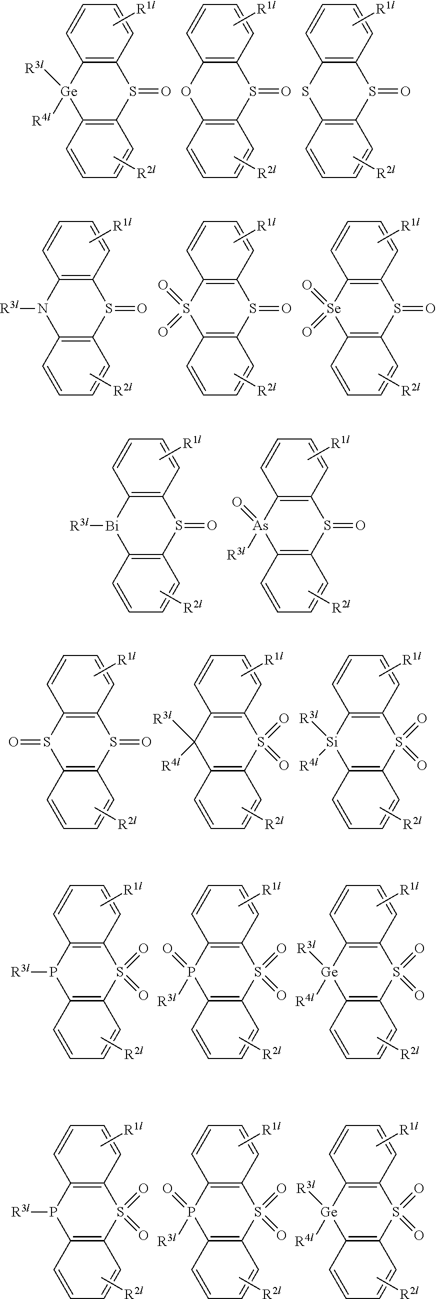

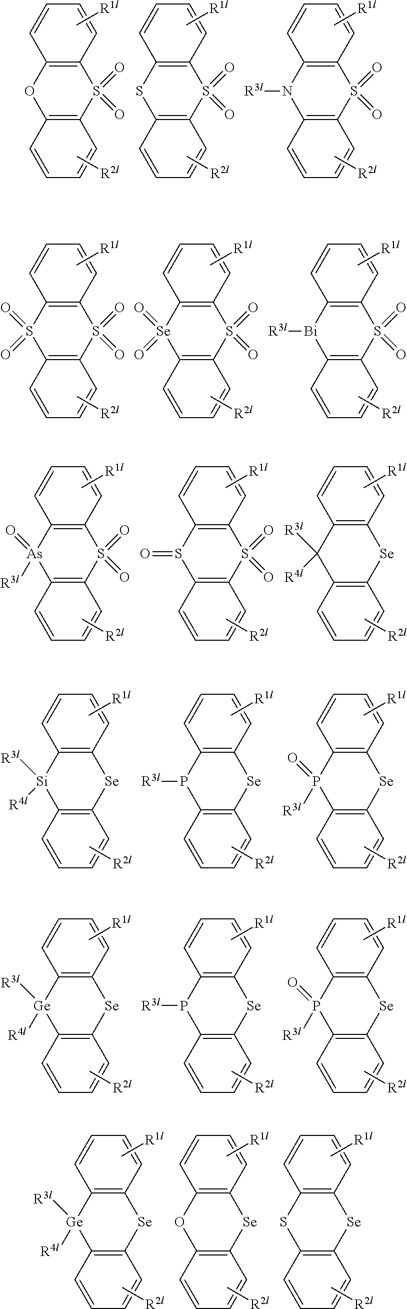

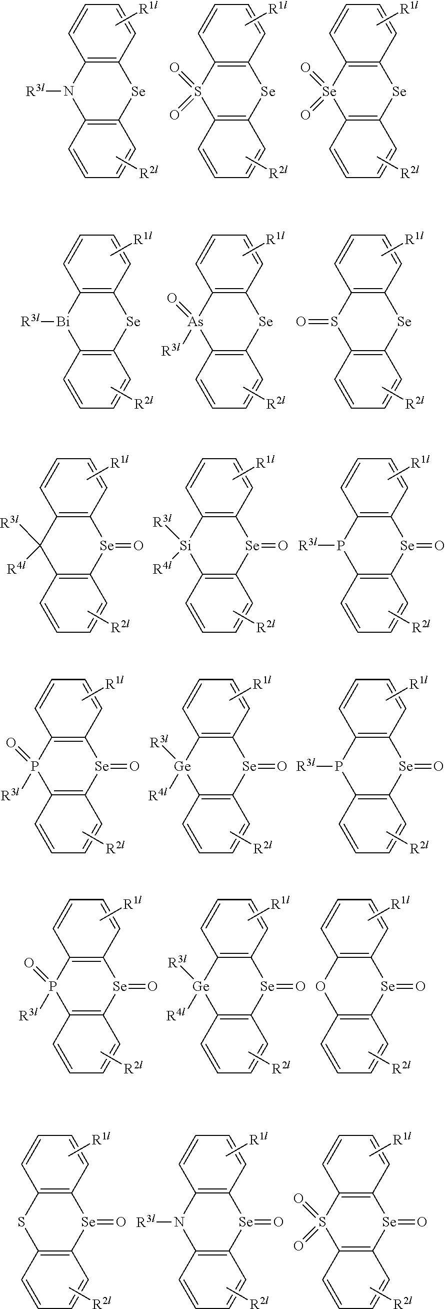

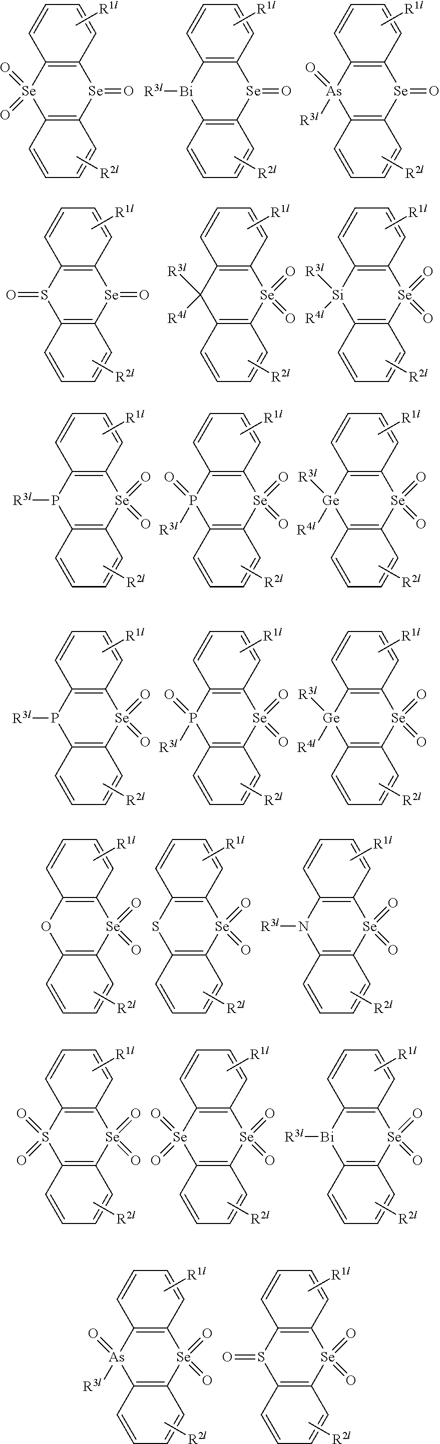

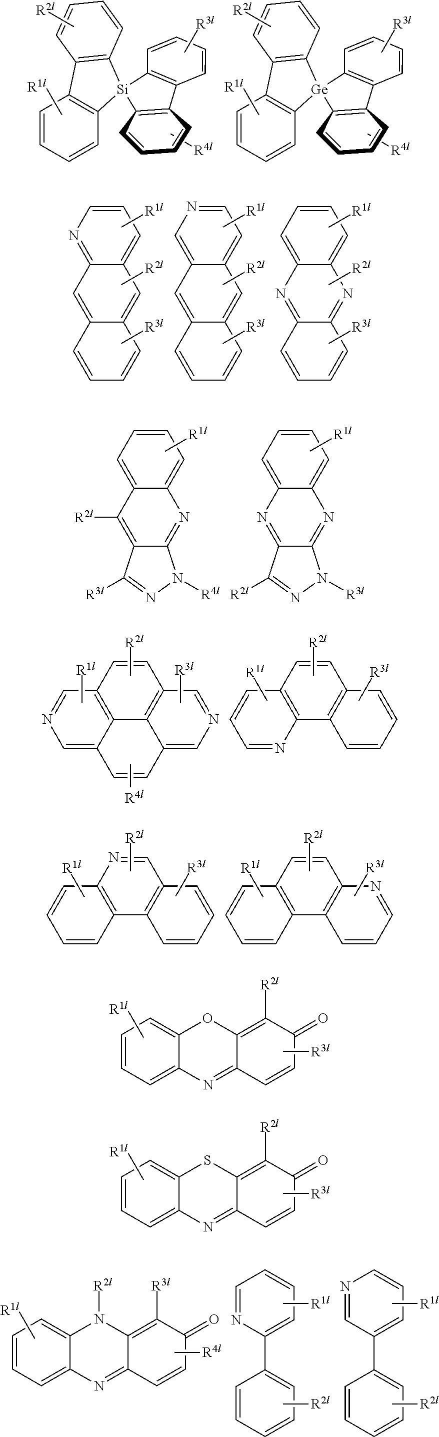

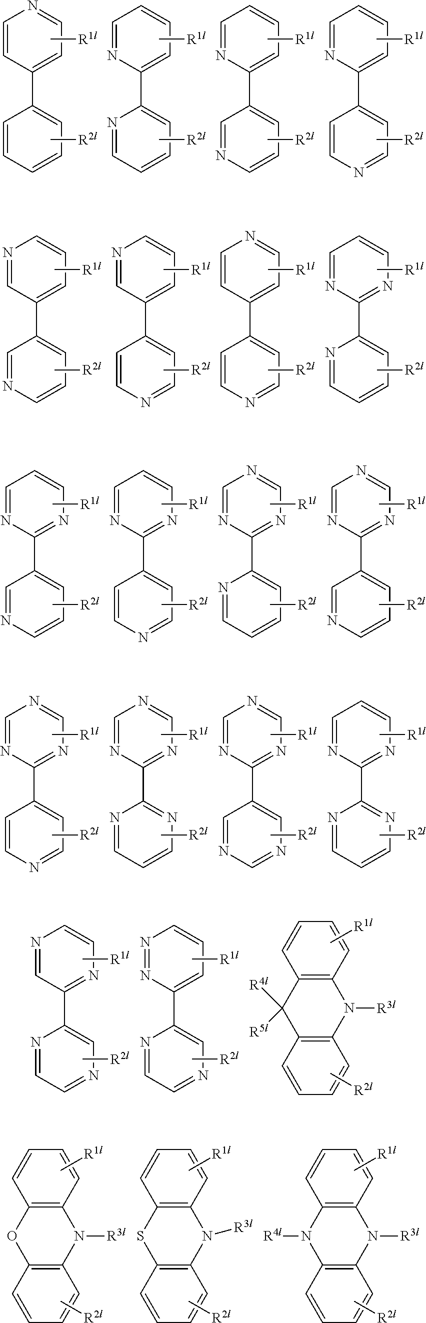

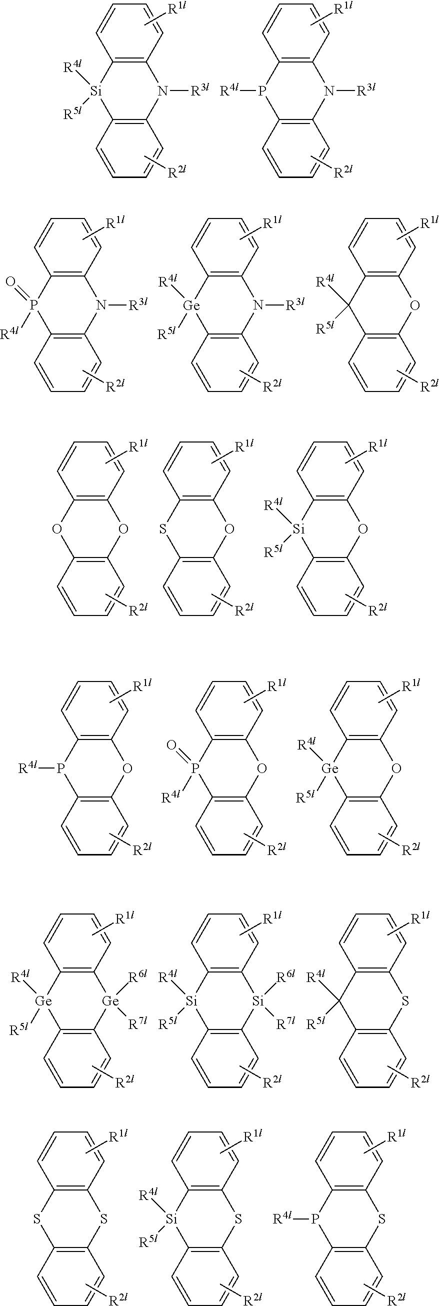

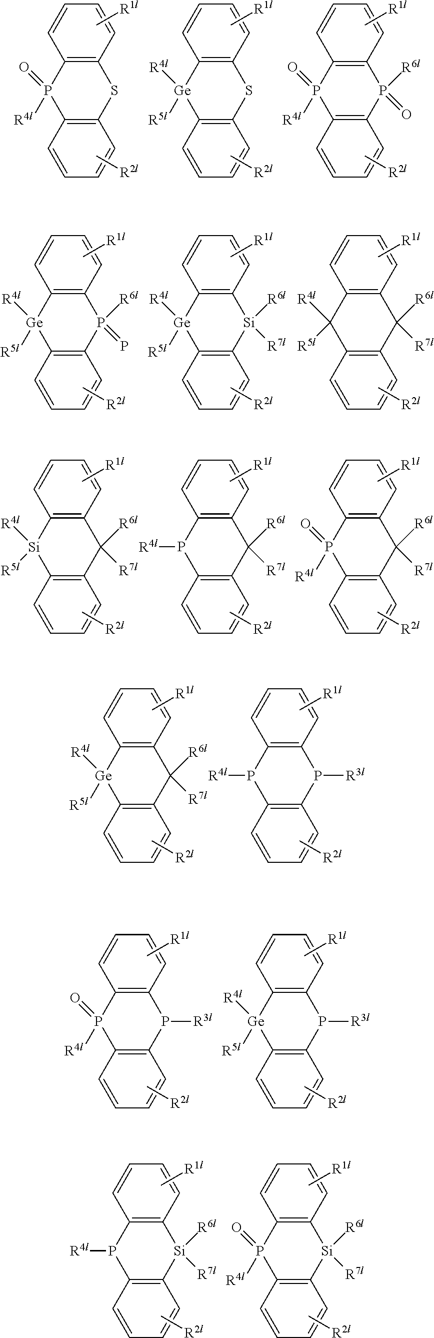

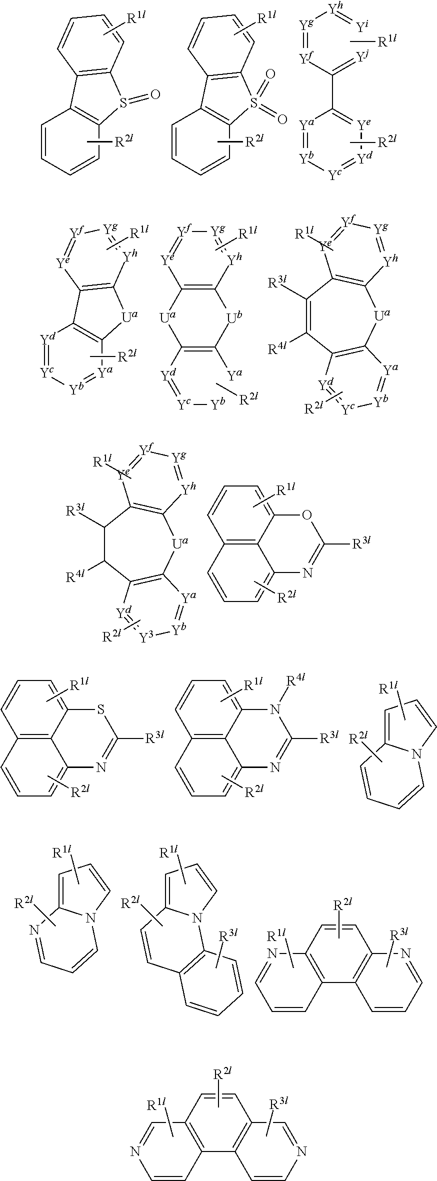

### 4. Other Fluorescent Luminophores

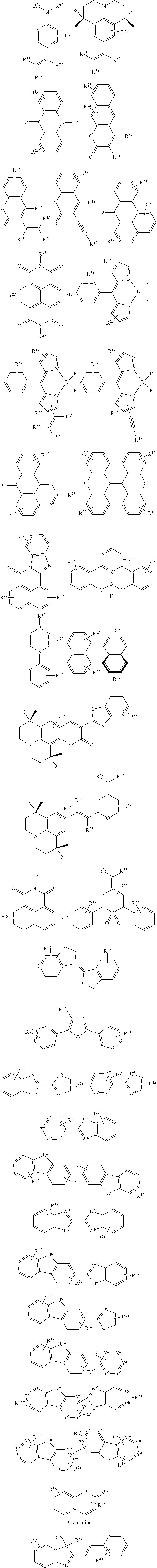 [0129] wherein:
each of R^{1l}, R^{2l}, R^{3l}, R^{4l}, R^{5l}, R^{6l}, R^{7l}, and R^{8l} is independently a mono-, di-, or ti-substitution, and if present each of R^{1l}, R^{2l}, R^{3l}, R^{4l}, R^{5l}, R^{6l}, R^{7l}, and R^{8l} is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, substituted or unsubstituted alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof,
each of Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o}, and Y^{p} is independently C, N, or B,
each of U^{a}, U^{b}, and U^{c} is independently CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³, and
each of W, W^{a}, W^{b}, and W^{c} is independently CH, CR¹, SiR¹, GeH, GeR¹, N, P, B, Bi, or Bi═O.

In one aspect, F¹ is covalently bonded to L¹ directly. In one aspect F² is covalently bonded to L² directly. In one aspect, F³ is covalently bonded to L³ directly. In one aspect, F⁴ is covalently bonded to L⁴ directly. In one aspect, F⁵ is covalently bonded to L⁵ directly. In one aspect, F⁶ is covalently bonded to L⁶ directly.

In another aspect, fluorescent luminophore F¹ is covalently bonded to L¹ by a linking atom or linking group. In another aspect, F² is covalently bonded to L² by a linking atom or linking group. In another aspect, F³ is covalently bonded to L³ by a linking atom or linking group. In another aspect, F⁴ is covalently bonded to L⁴ by a linking atom or linking group. In another aspect, F⁵ is covalently bonded to L⁵ by a linking atom or linking group. In another aspect, F⁶ is covalently bonded to L⁶ by a linking atom or linking group.

F. Linking Atoms or Linking Groups

In some cases, each linking atom or linking group in the structures disclosed herein is independently one of the atoms or groups depicted below:

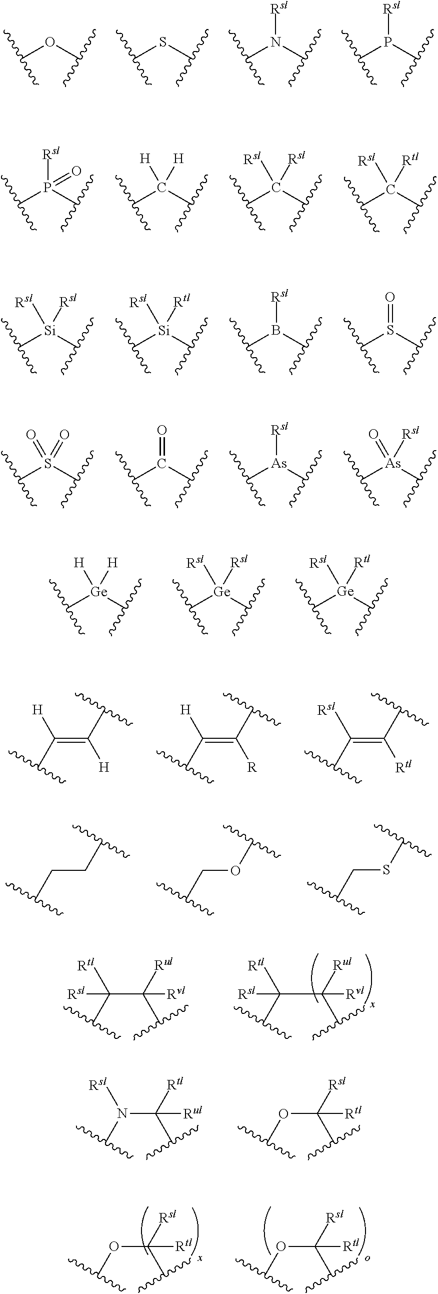

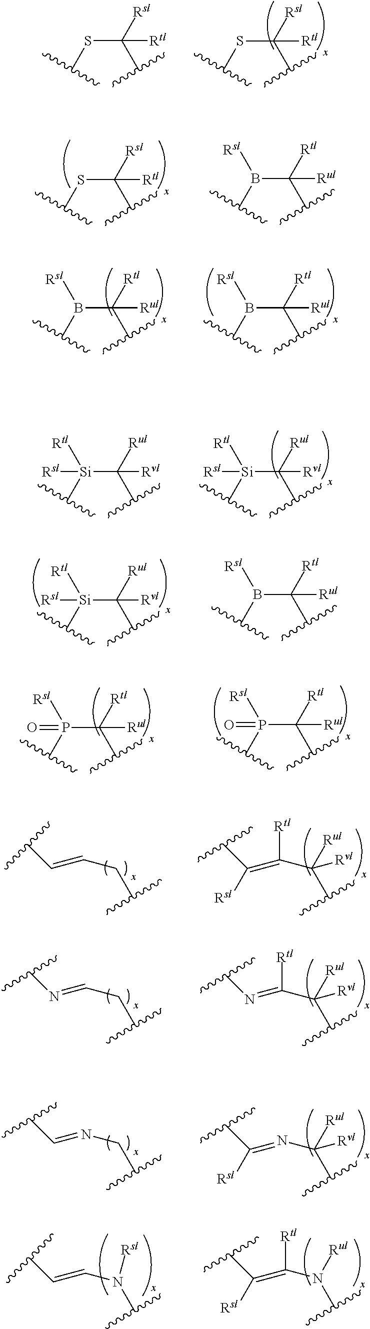

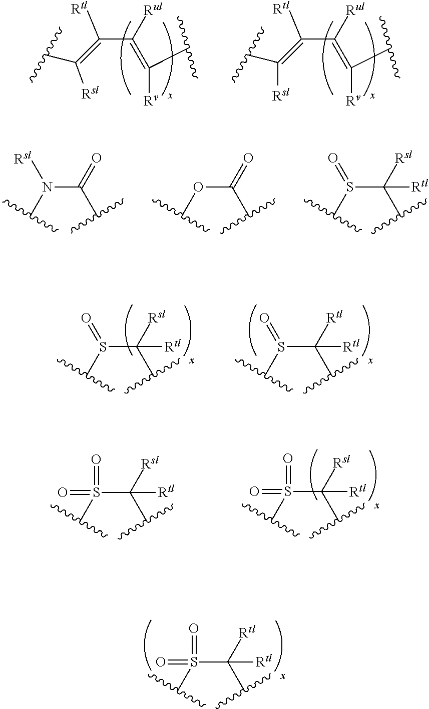

wherein x is from 1 to 10, wherein each of R^{sl}, R^{tl}, R^{ul}, and R^{vl} is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, or polymeric, or any conjugate or combination thereof. In other cases, a linking atom or linking group in the structures disclosed herein includes other structures or portions thereof not specifically recited herein, and the present disclosure is not intended to be limited to those structures or portions thereof specifically recited.

In one aspect, a linking atom and linking group recited above is covalently bonded to any atom of a fluorescent luminophore F¹, F², F³, F⁴, F⁵, and F⁶ if present and if valency permits. In one example example, if F¹ is

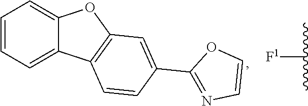

can be

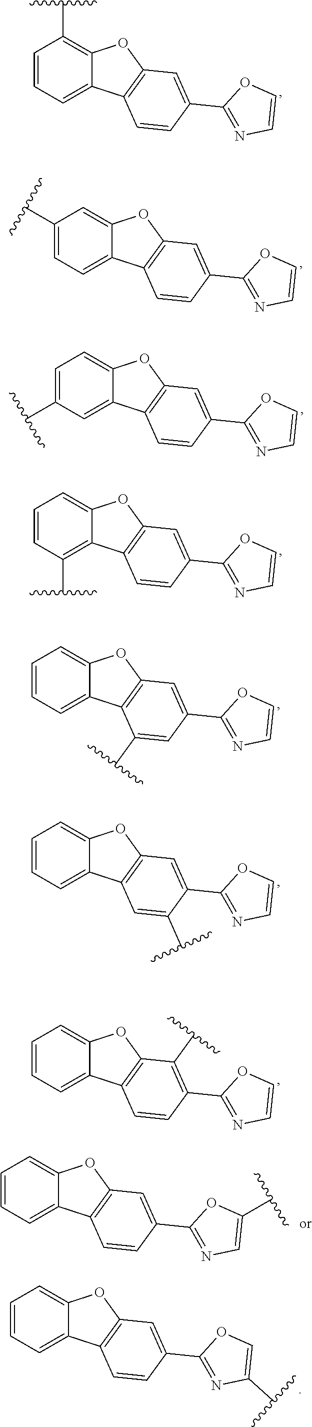

G. R Groups

In one aspect, at least one R^{a} is present. In another aspect, R^{a} is absent.

In one aspect, R^{a} is a mono-substitution. In another aspect, R^{a} is a di-substitution. In yet another aspect, R^{a} is a tri-substitution.

In one aspect, R^{a} is connected to at least L¹. In another aspect, R^{b} is connected to at least L². In yet another aspect, R^{c} is connected to at least L³. In one aspect, R^{d} is connected to at least L⁴. In one aspect, R^{e} is connected to at least L⁵. In one aspect, R^{f} is connected to at least L⁶.

In one aspect, R^{a} is a di-substitution and the R^{a}'s are linked together. When the R^{a}'s are linked together the resulting structure can be a cyclic structure that includes a portion of the five-membered cyclic structure as described herein. For example, a cyclic structure can be formed when the di-substitution is of L¹ and L² and the R^{a}'s are linked together. A cyclic structure can also be formed when the di-substitution is of L³ and L⁴ and the R^{a}'s are linked together. A cyclic structure can also be formed when the di-substitution is of L⁵ and L⁶ and the R^{a}'s are linked together.

In one aspect, each R^{a}, if present, is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and two or more of R^{a} are optionally linked together. In one aspect, at least one R^{a} is halogen, hydroxyl, substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl; or any conjugate or combination thereof, and two or more of R^{a} are optionally linked together.

In one aspect, at least one R^{b} is present. In another aspect, R^{b} is absent.

In one aspect, R^{b} is a mono-substitution. In another aspect, R^{b} is a di-substitution. In yet another aspect, R^{b} is a tri-substitution.

In one aspect, each R^{b}, if present, is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and two or more of R^{b} are optionally linked together. In one aspect, at least one R^{b} is halogen, hydroxyl; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl; or any conjugate or combination thereof, and two or more of R^{b} are optionally linked together.

In one aspect, at least one R^{c} is present. In another aspect, R^{c} is absent.

In one aspect, R^{c} is a mono-substitution. In another aspect, R^{c} is a di-substitution. In yet another aspect, R^{c} is a tri-substitution.

In one aspect, each R^{c}, if present, is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and two or more of R^{c} are optionally linked together. In one aspect, at least one R^{c} is halogen, hydroxyl; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl; or any conjugate or combination thereof, and two or more of R^{c} are optionally linked together.

In one aspect, at least one R^{d} is present. In another aspect, R^{d} is absent.

In one aspect, R^{d} is a mono-substitution. In another aspect, R^{d} is a di-substitution. In yet another aspect, R^{d} is a tri-substitution.

In one aspect, each R^{d}, if present, is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, substituted silyl, polymeric, or any conjugate or combination thereof, and two or more of R^{d} are optionally linked together.

In one aspect, at least one R^{e} is present. In another aspect, R^{e} is absent.

In one aspect, R^{e} is a mono-substitution. In another aspect, R^{e} is a di-substitution. In yet another aspect, R^{e} is a tri-substitution.

In one aspect, each R^{e}, if present, is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and two or more of R^{e} are optionally linked together.

In one aspect, at least one R^{f} is present. In another aspect, R^{f} is absent.

In one aspect, R^{f} is a mono-substitution. In another aspect, R^{f} is a di-substitution. In yet another aspect, R^{f} is a tri-substitution.

In one aspect, each R^{f}, if present, is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and two or more of R^{f} are optionally linked together.

In one aspect, each of R, R¹, R², R³, and R⁴ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

In another aspect, each of R, R¹, R², R³, and R⁴ is independently hydrogen, halogen, hydroxyl, thiol, nitro, cyano; substituted or unsubstituted: aryl, cycloalkyl, cycloalkenyl, heterocyclyl, heteroaryl, alkyl, alkenyl, alkynyl, or amino. In another aspect, each of R, R¹, R², R³ and R⁴ is independently hydrogen; or substituted or unsubstituted: aryl, cycloalkyl, cycloalkenyl, heterocyclyl, heteroaryl, alkyl, alkenyl, or alkynyl.

H. Exemplary Compounds

In one aspect, Formulas I-X of this disclosure include the following structures. In another aspect, Formulas I-X include other structures or portions thereof not specifically recited herein, and the present disclosure is not intended to be limited to those structures or portions thereof specifically recited.

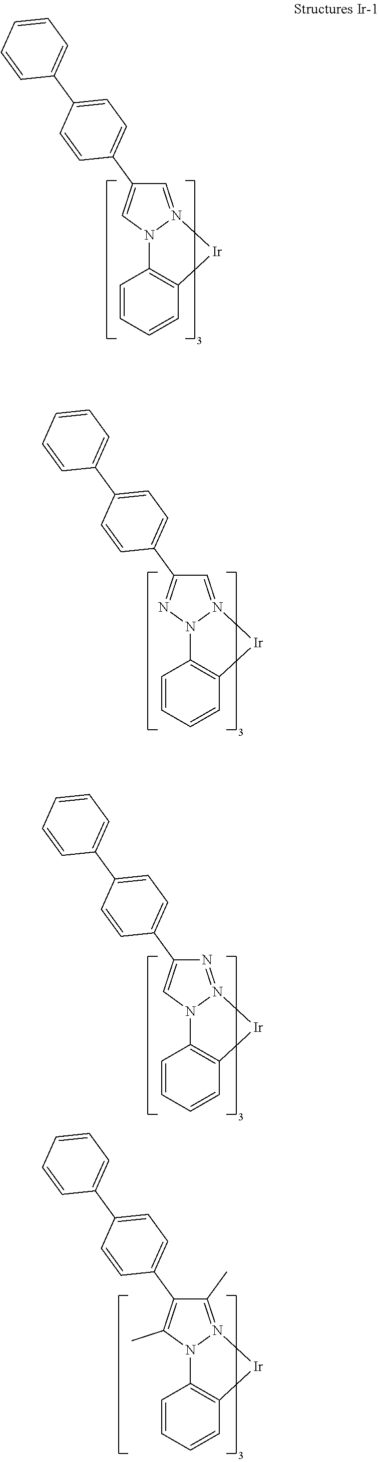

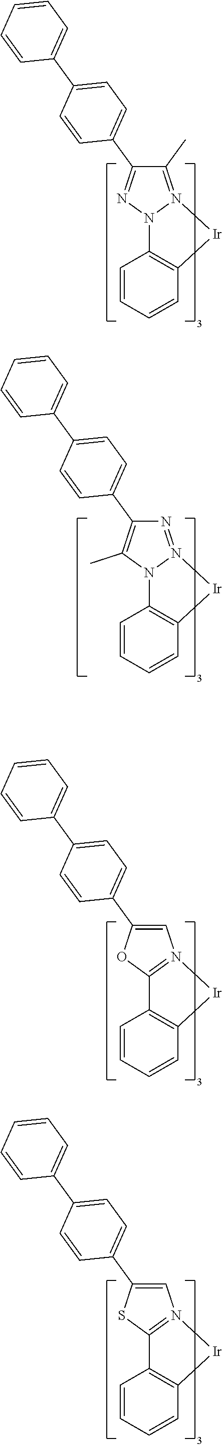

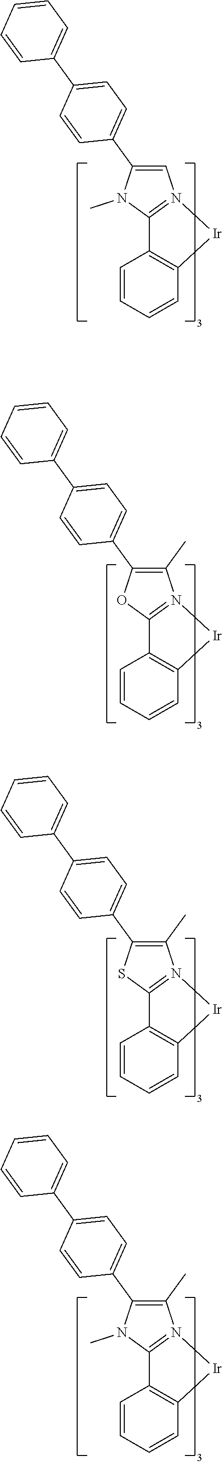

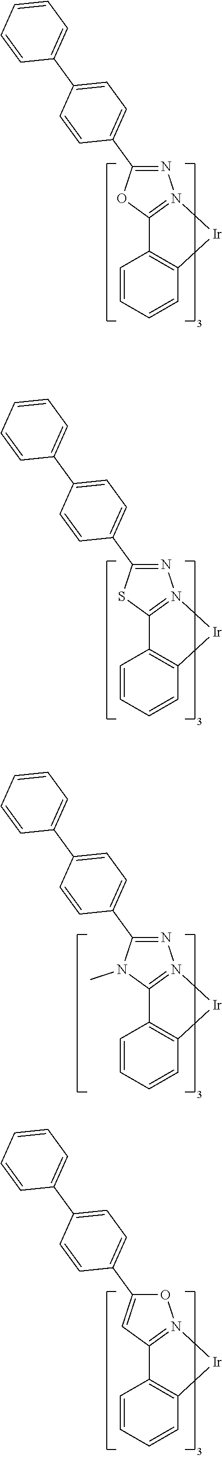

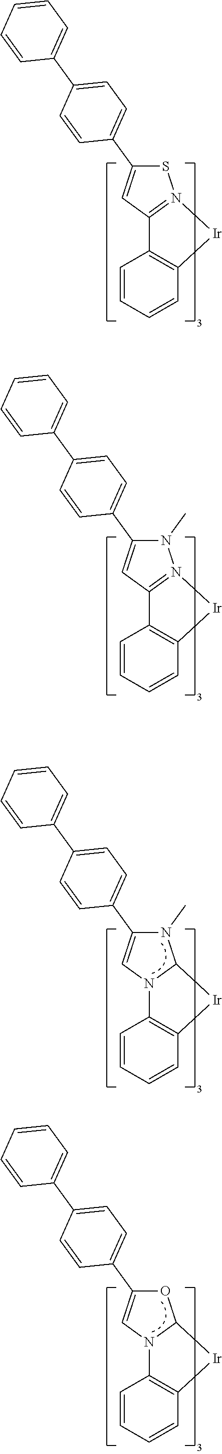

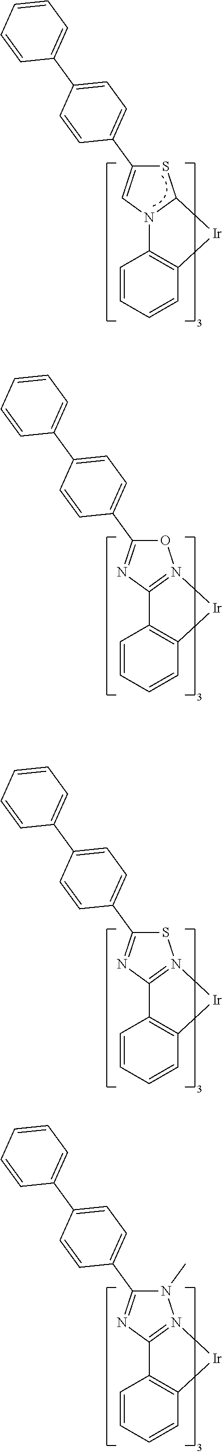

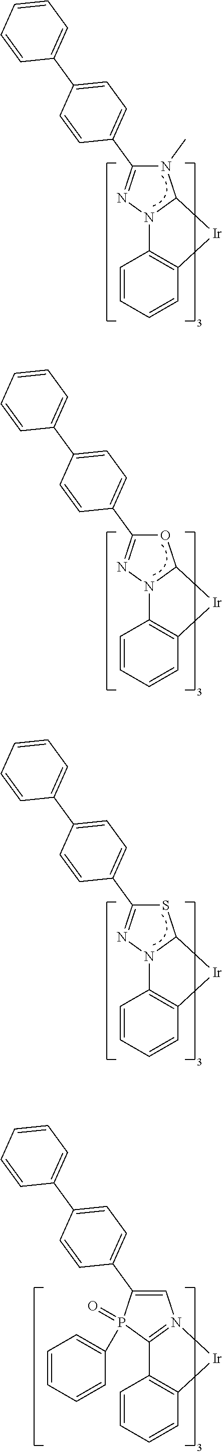

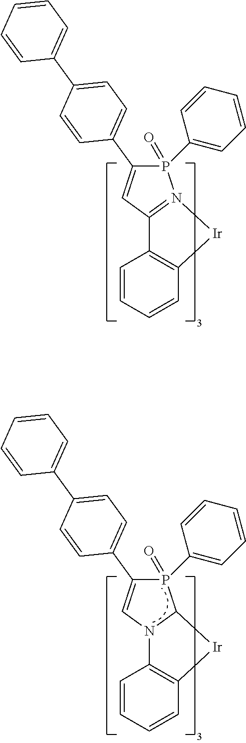

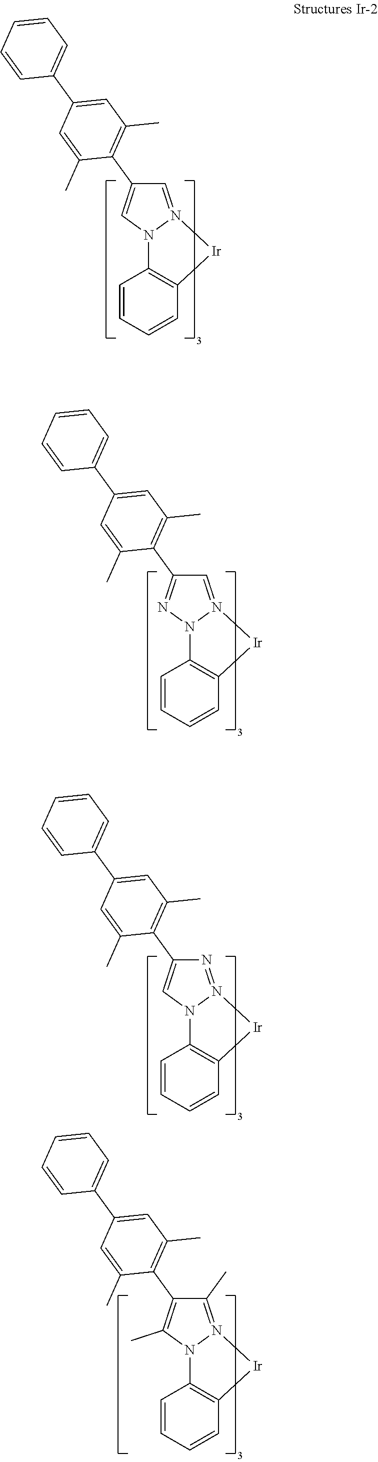

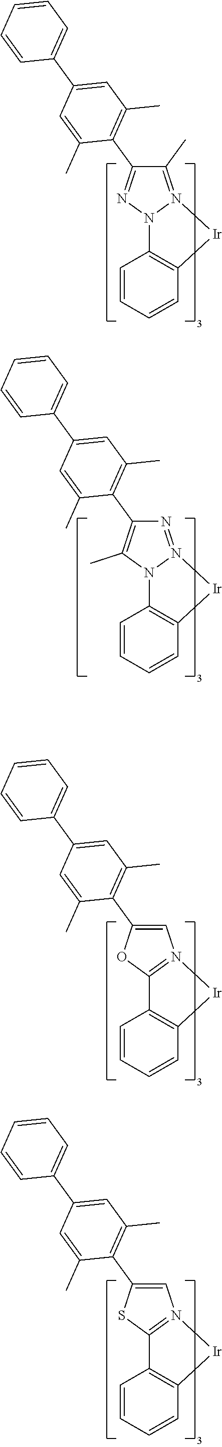

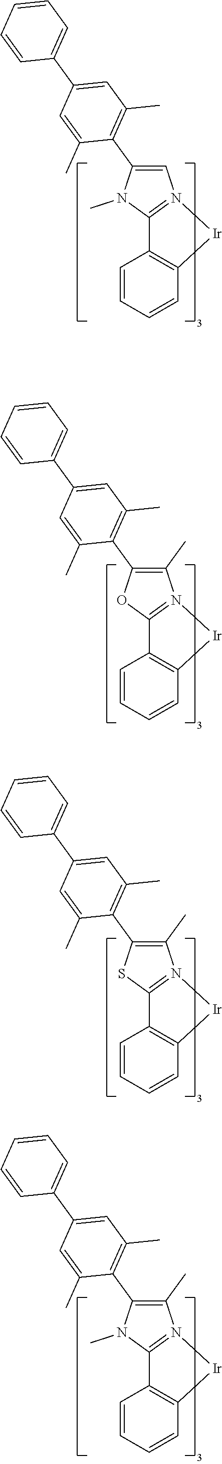

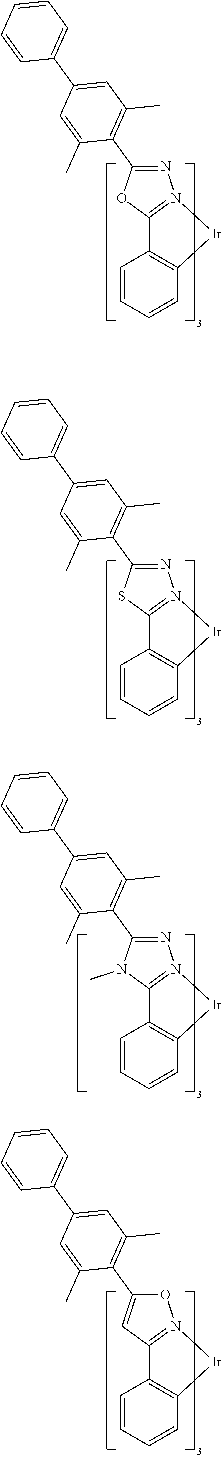

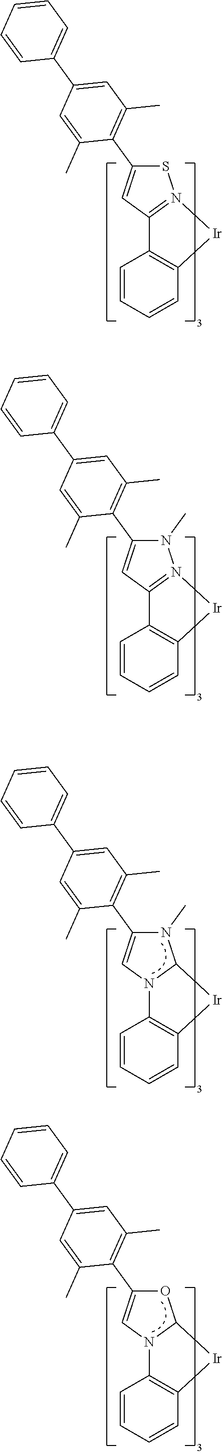

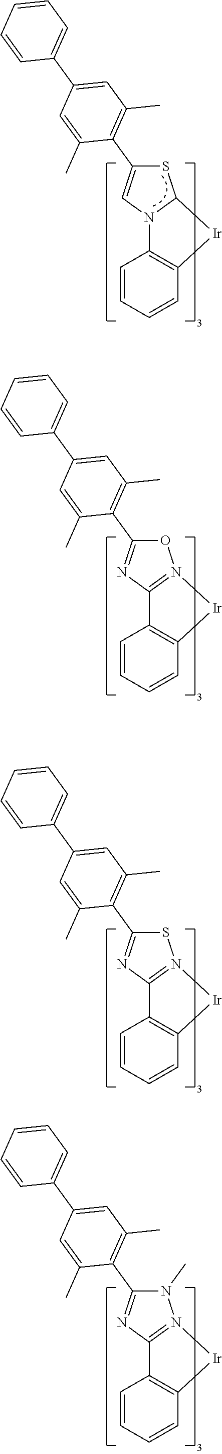

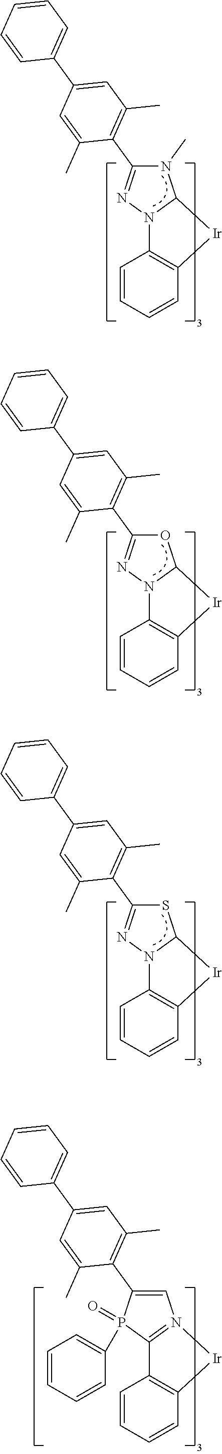

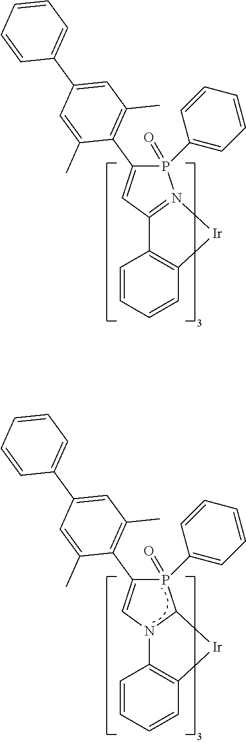

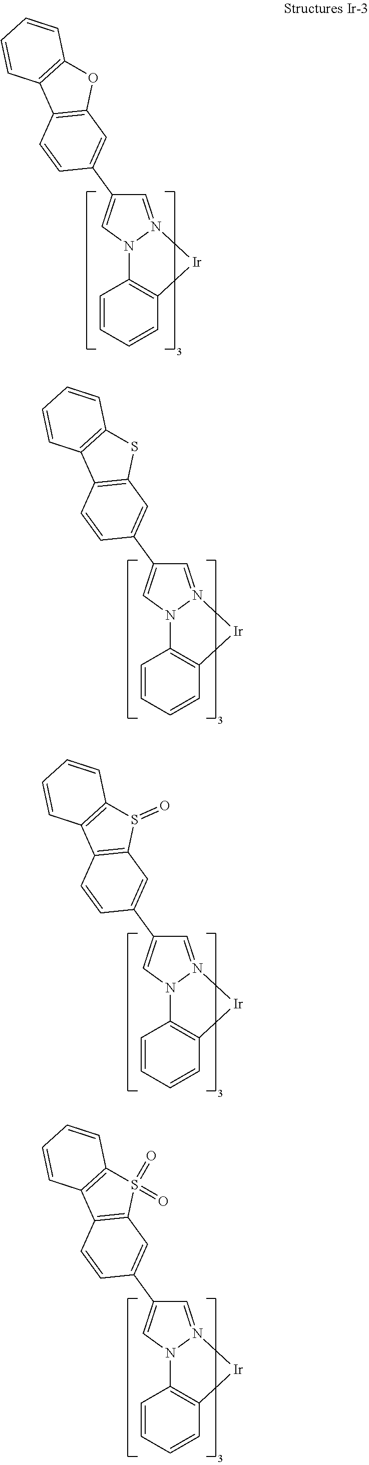

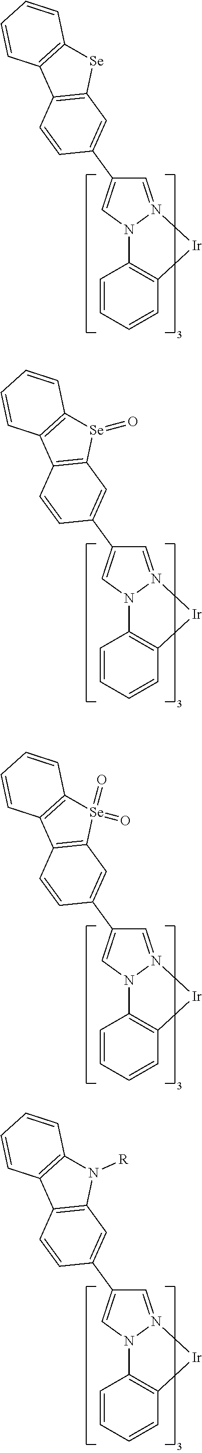

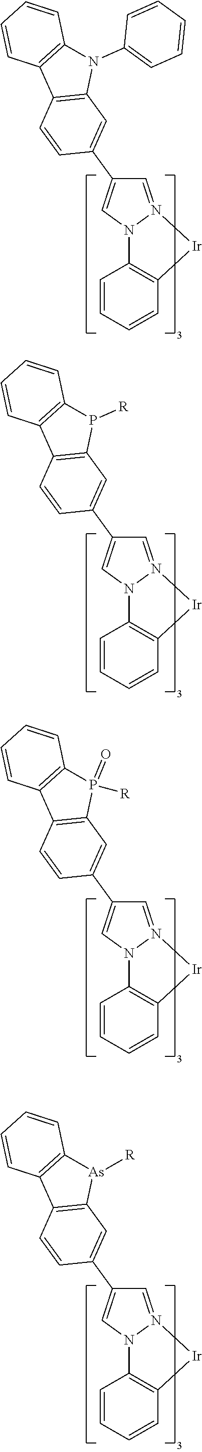

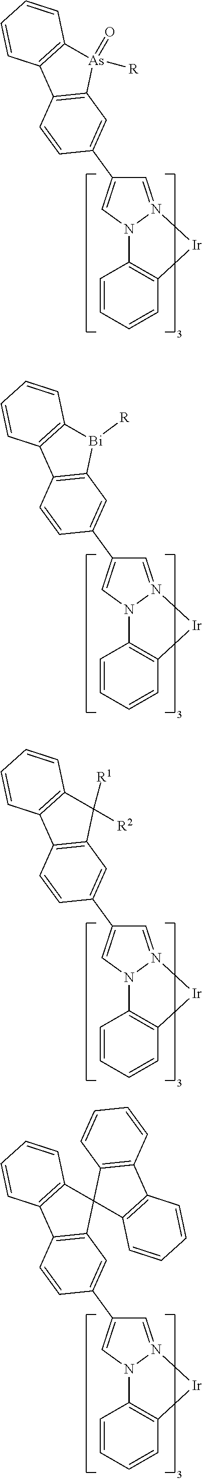

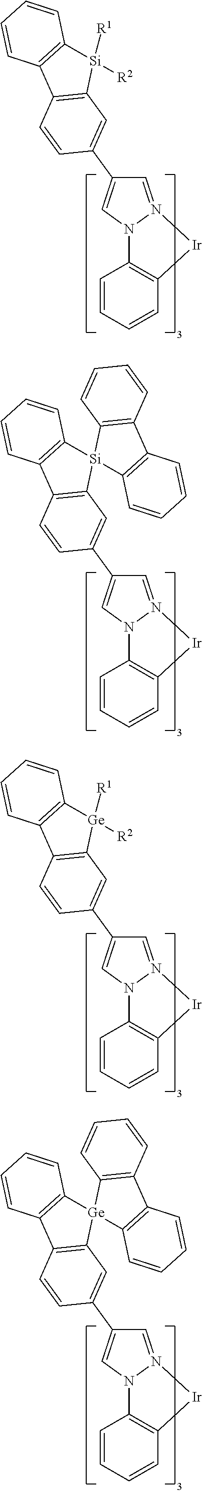

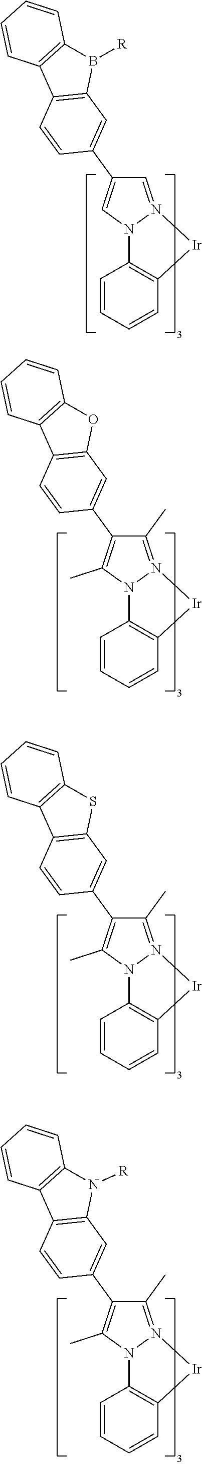

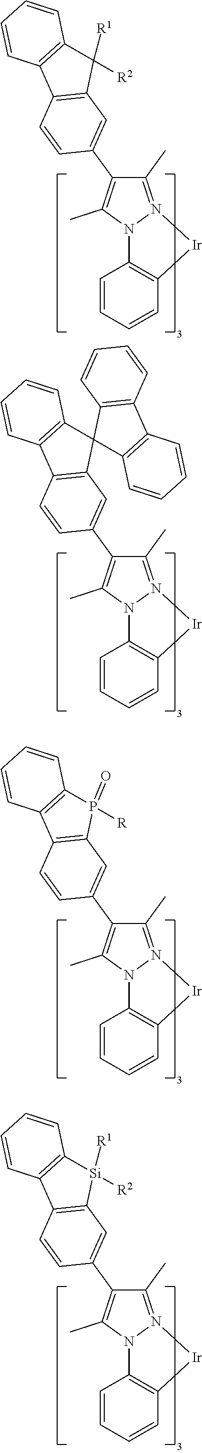

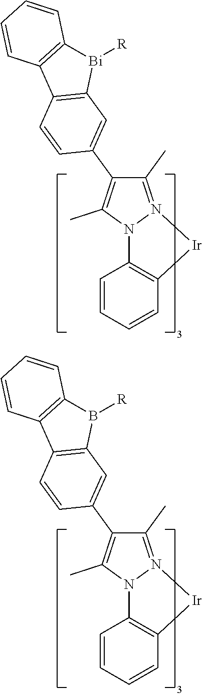

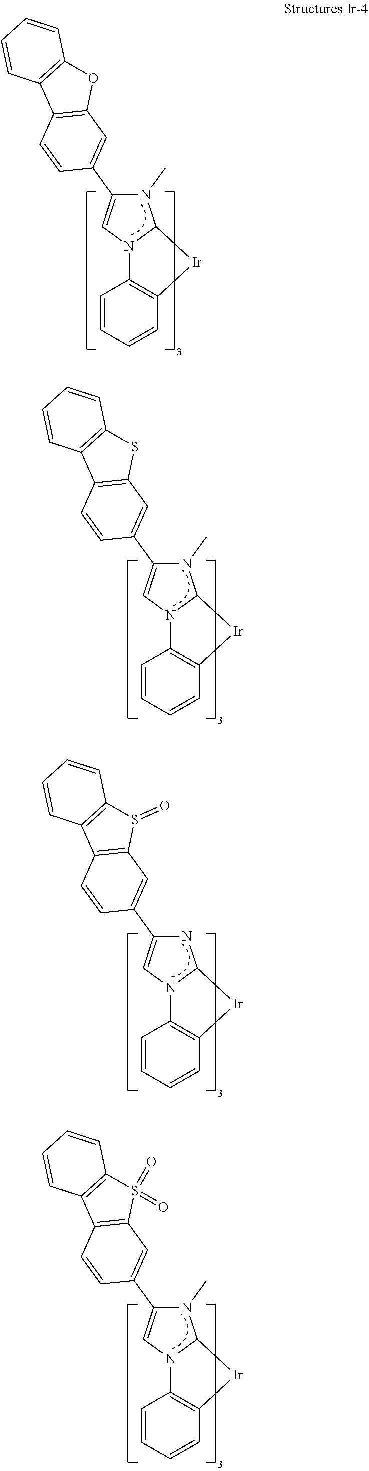

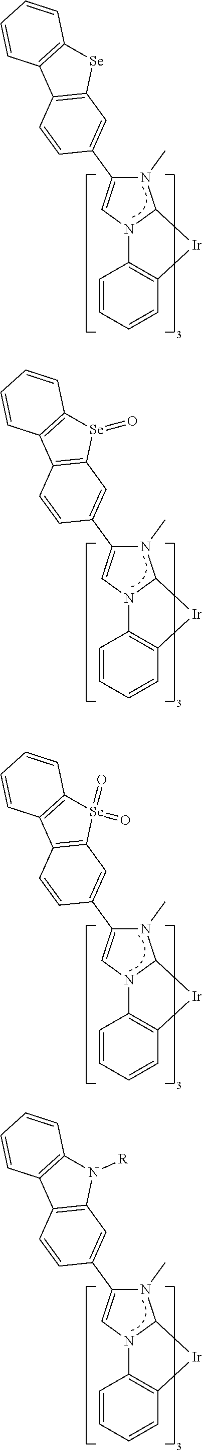

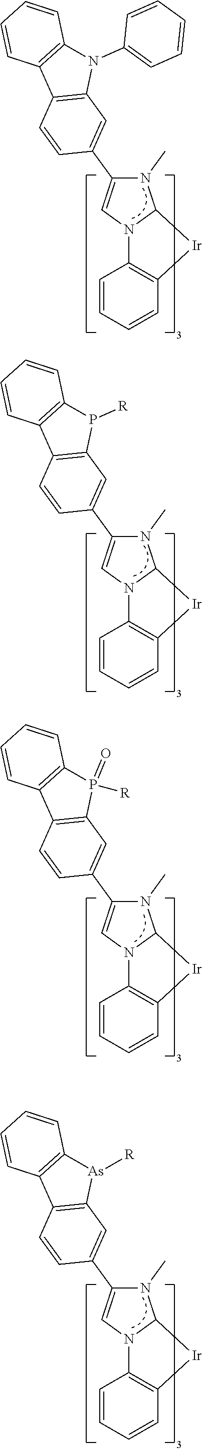

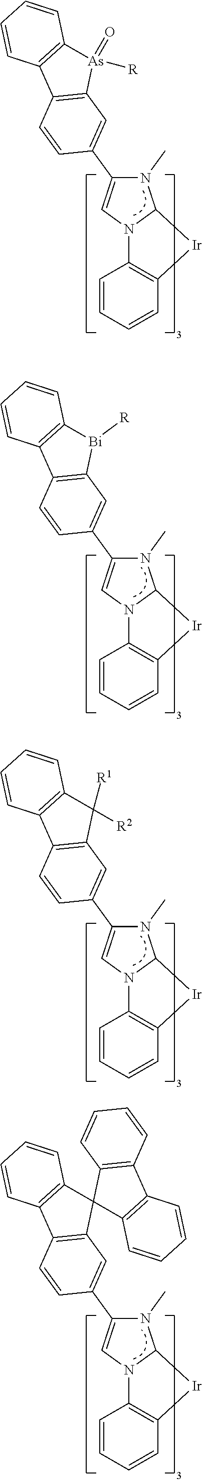

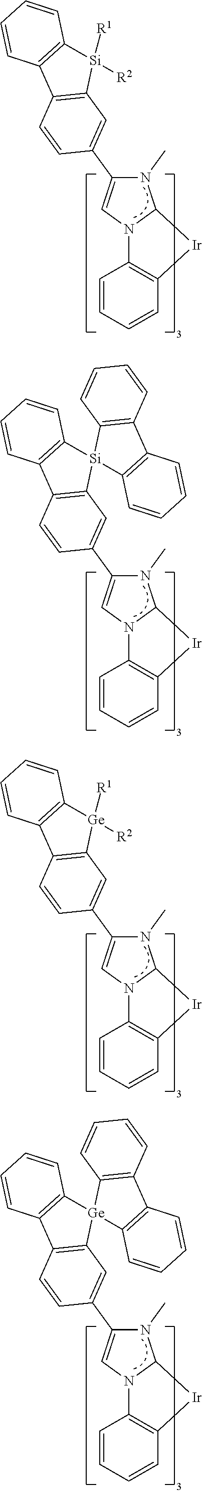

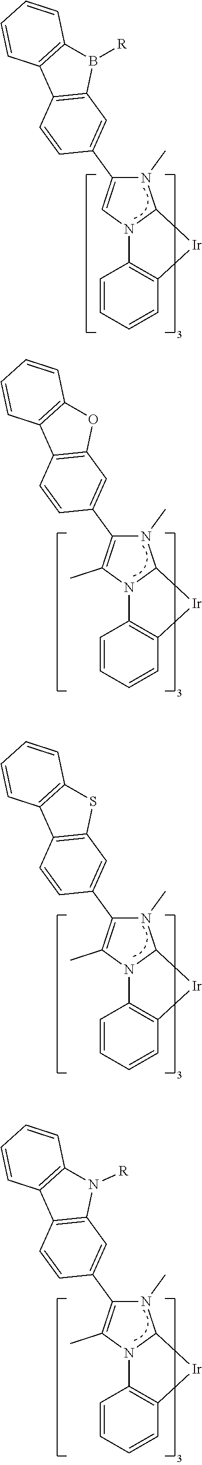

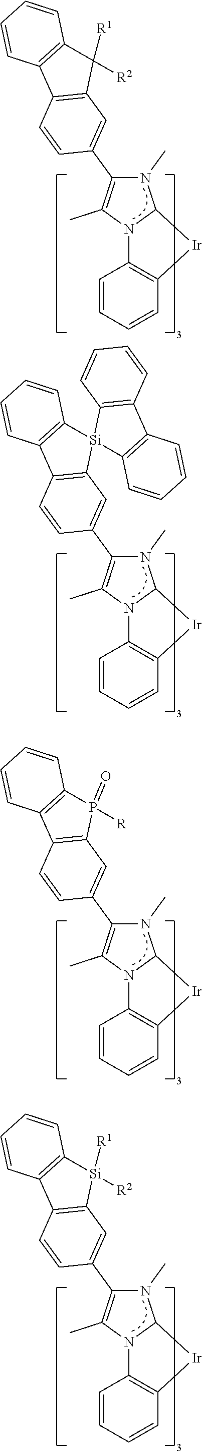

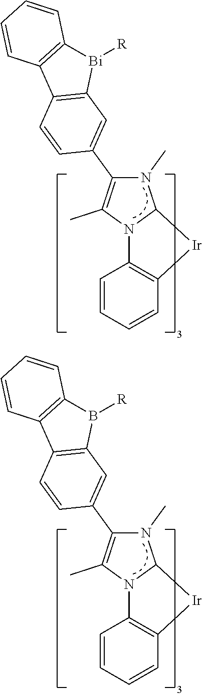

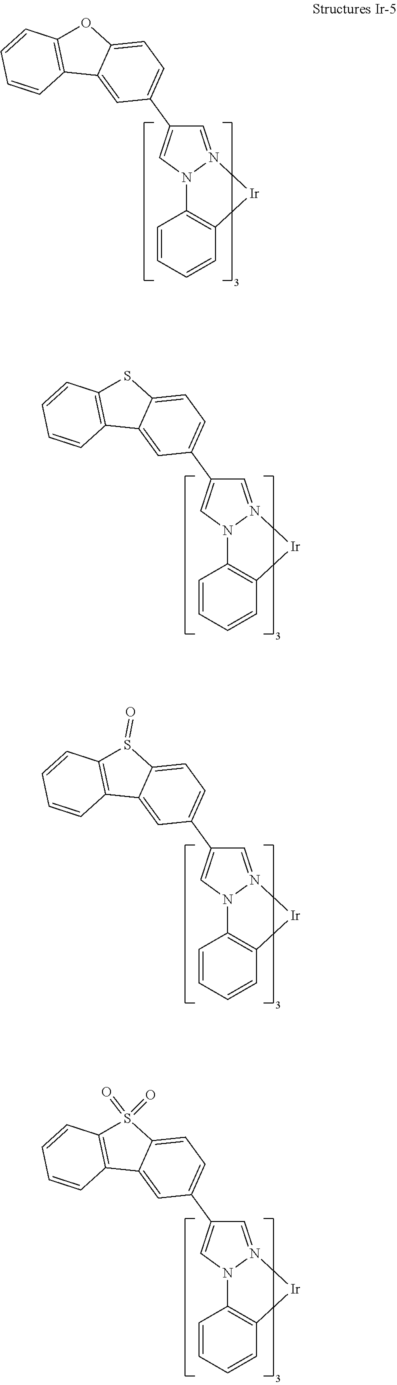

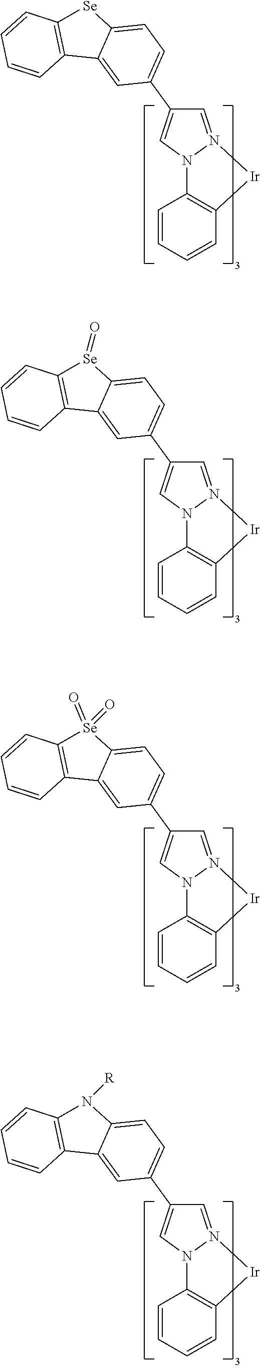

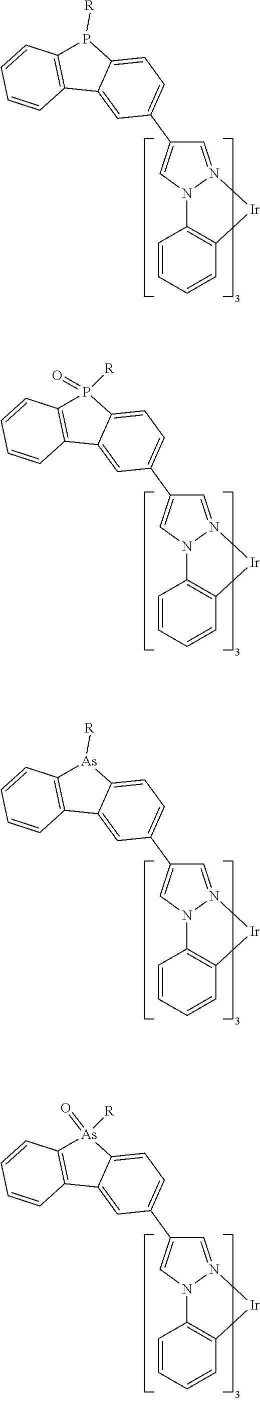

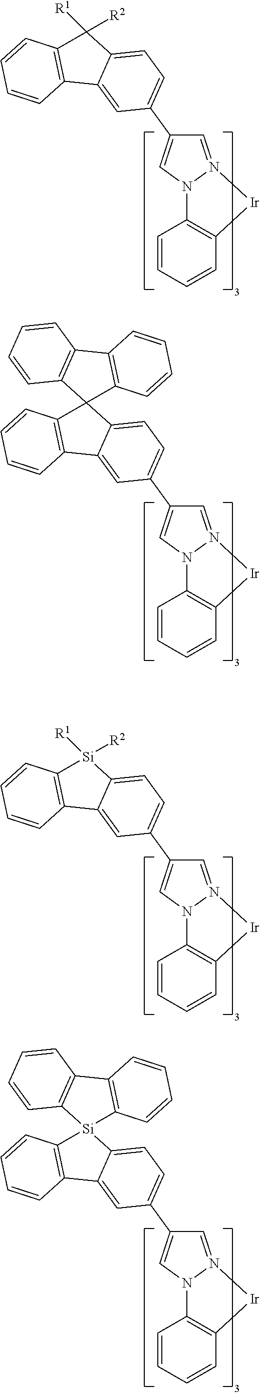

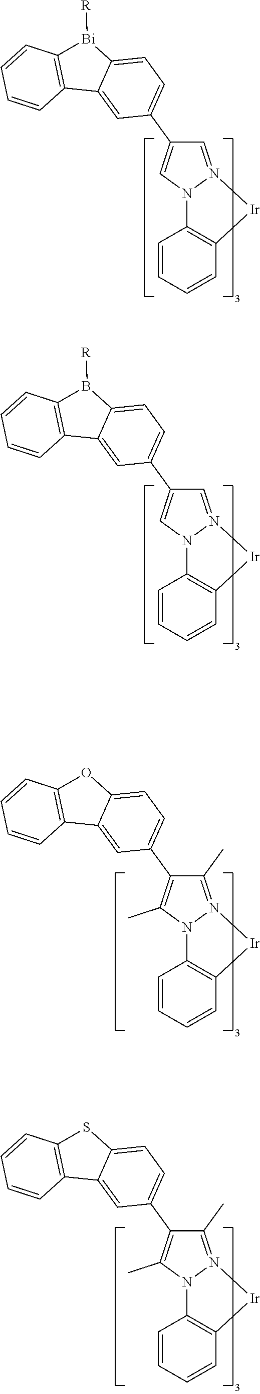

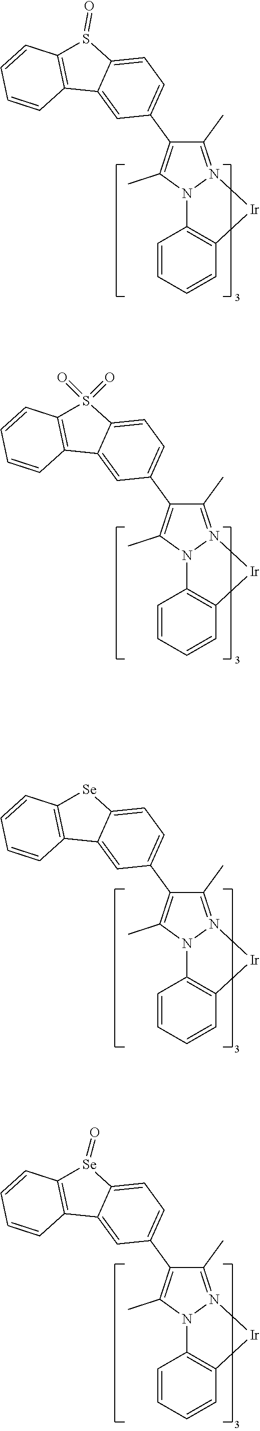

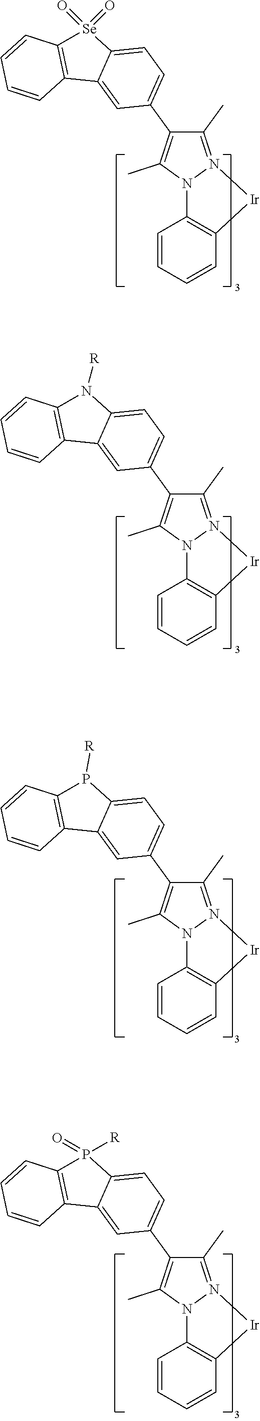

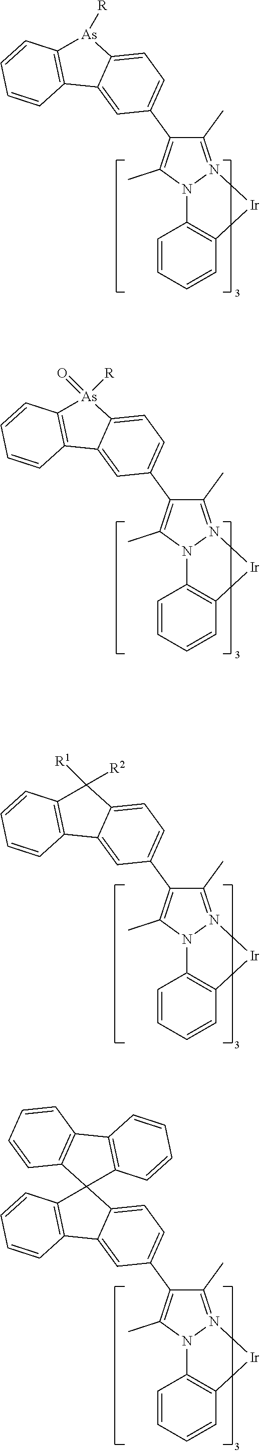

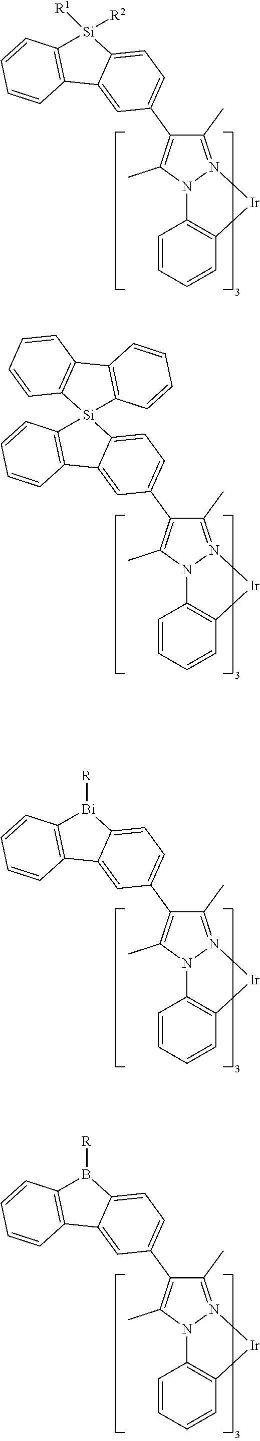

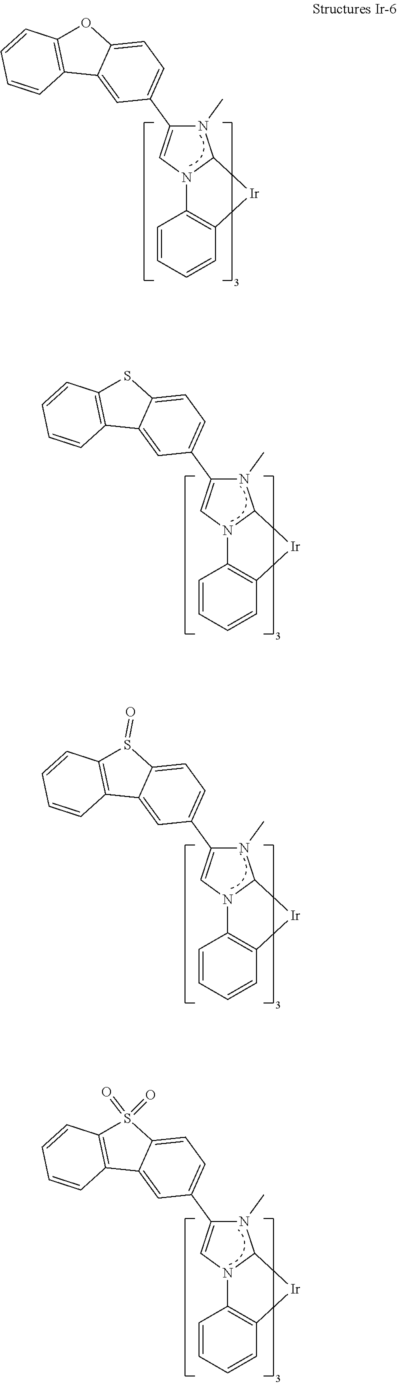

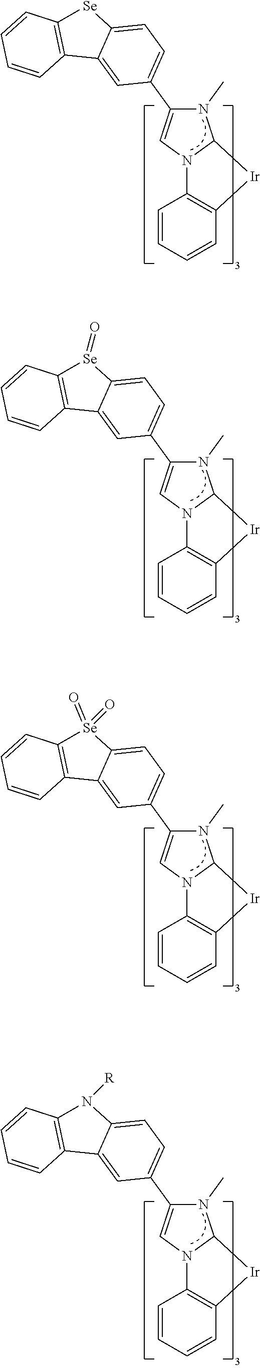

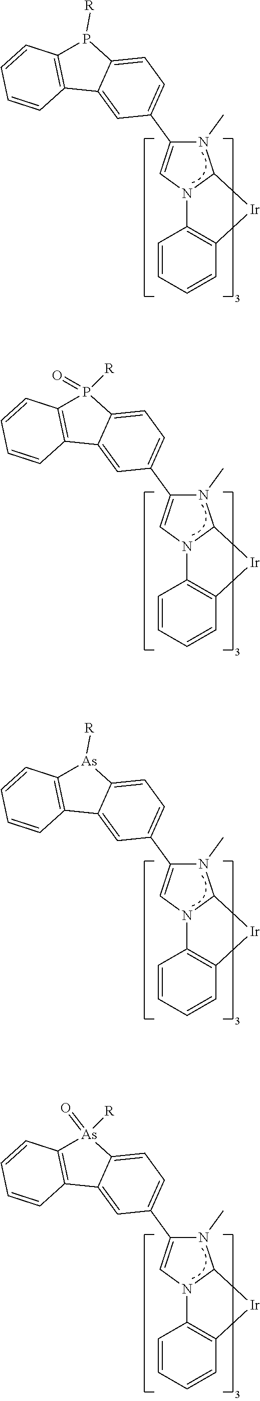

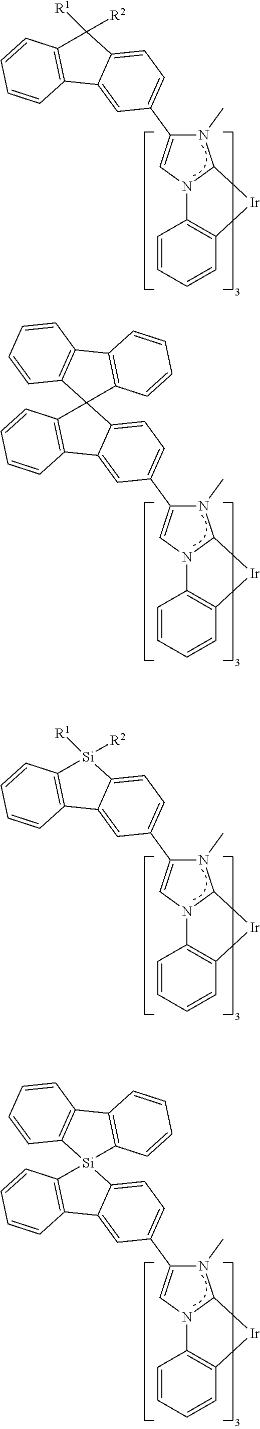

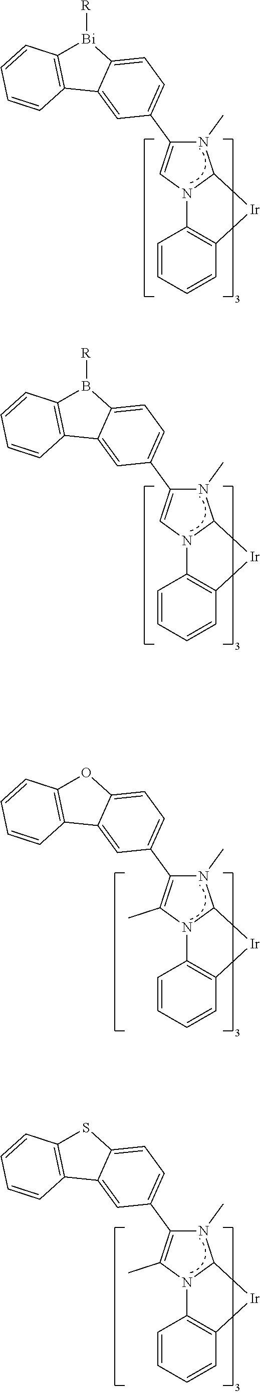

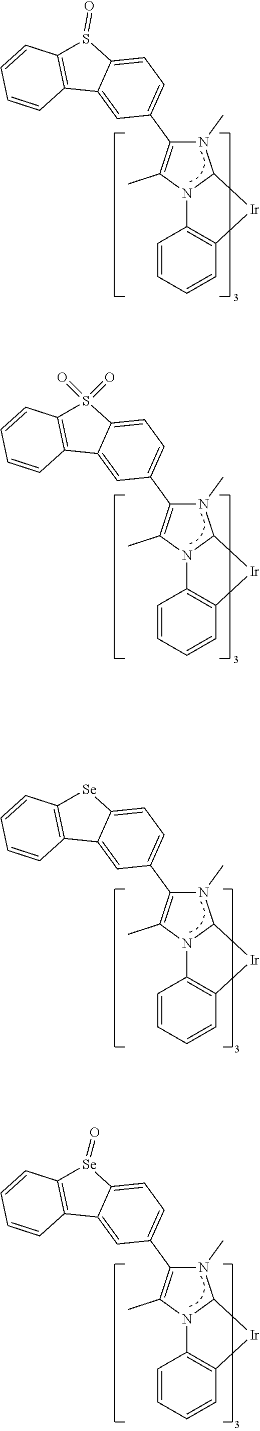

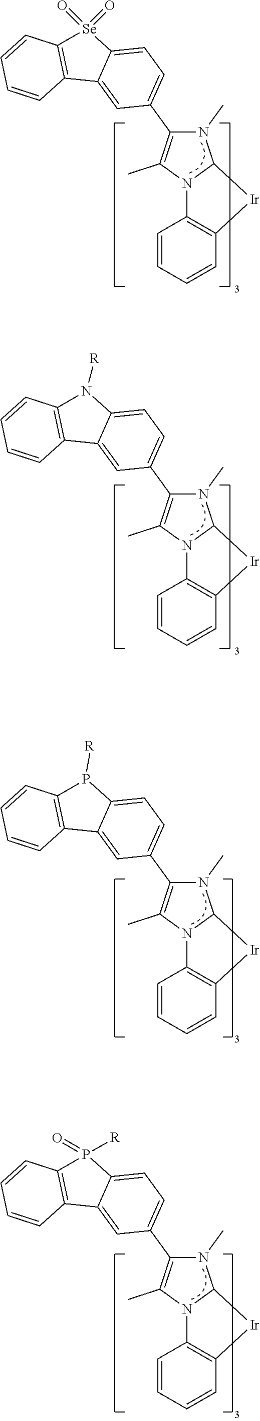

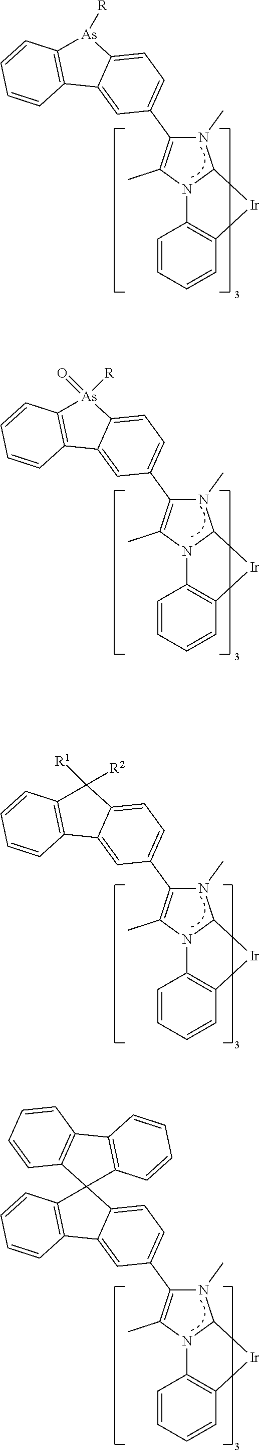

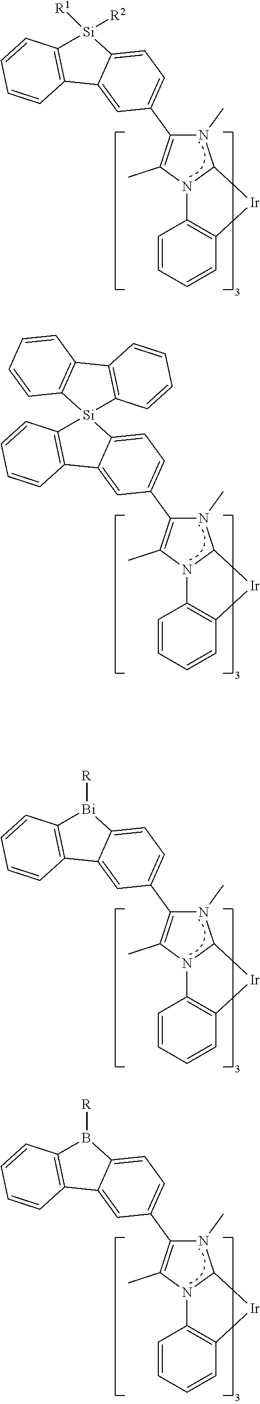

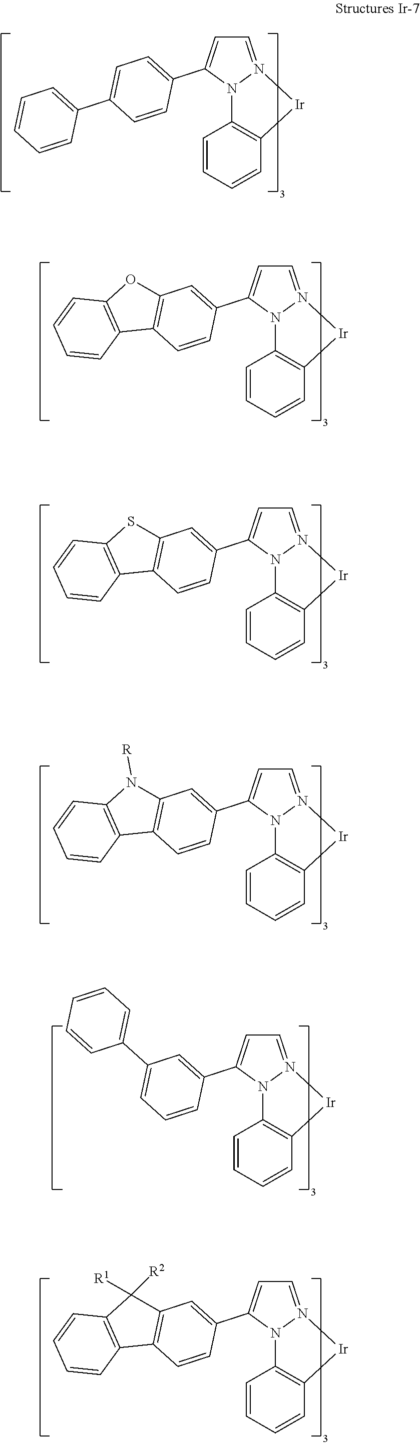

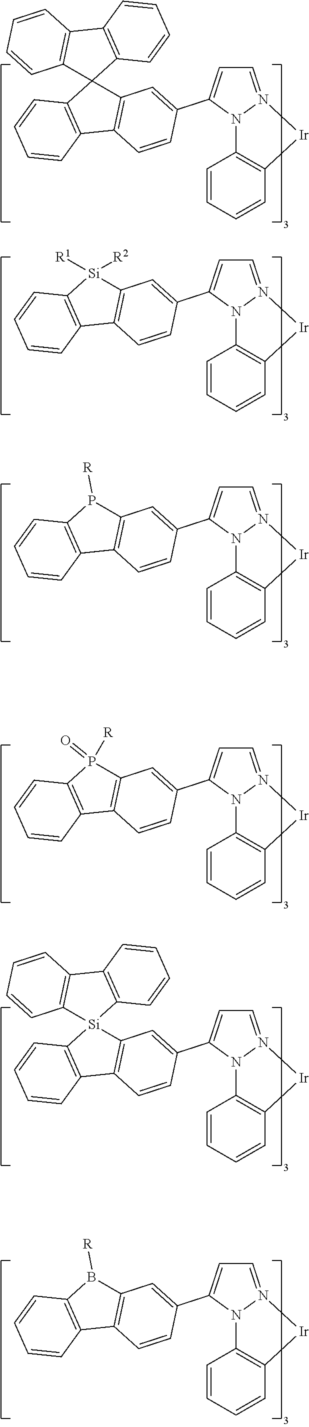

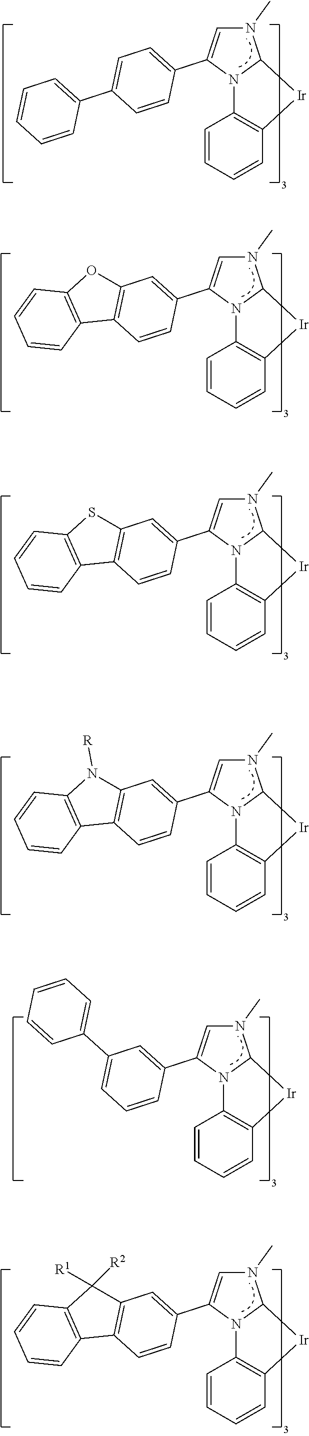

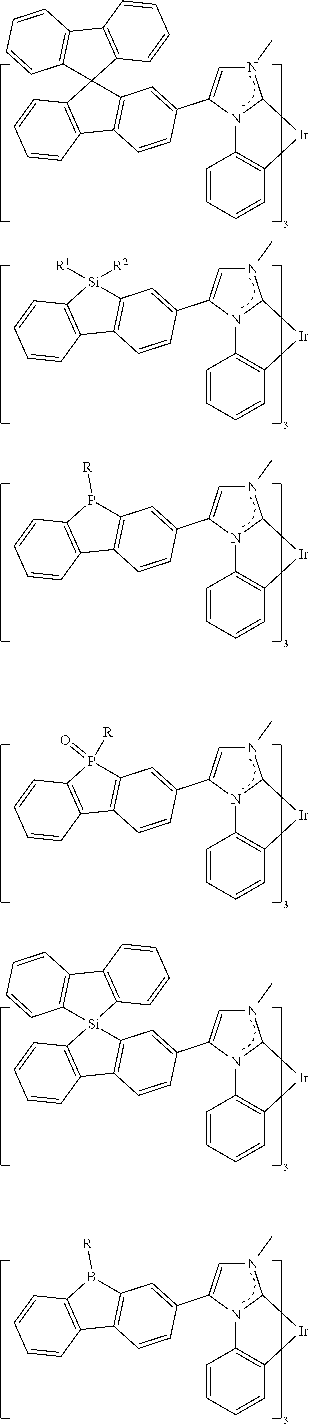

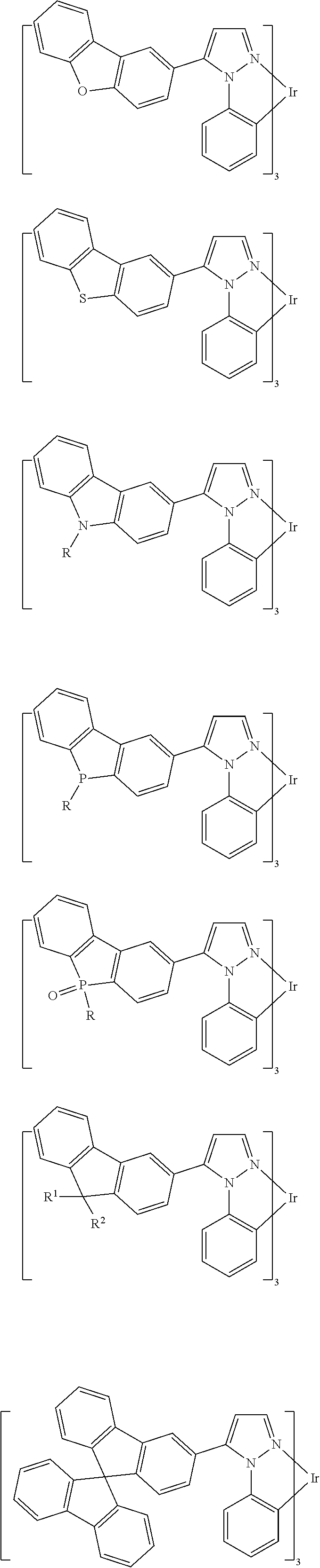

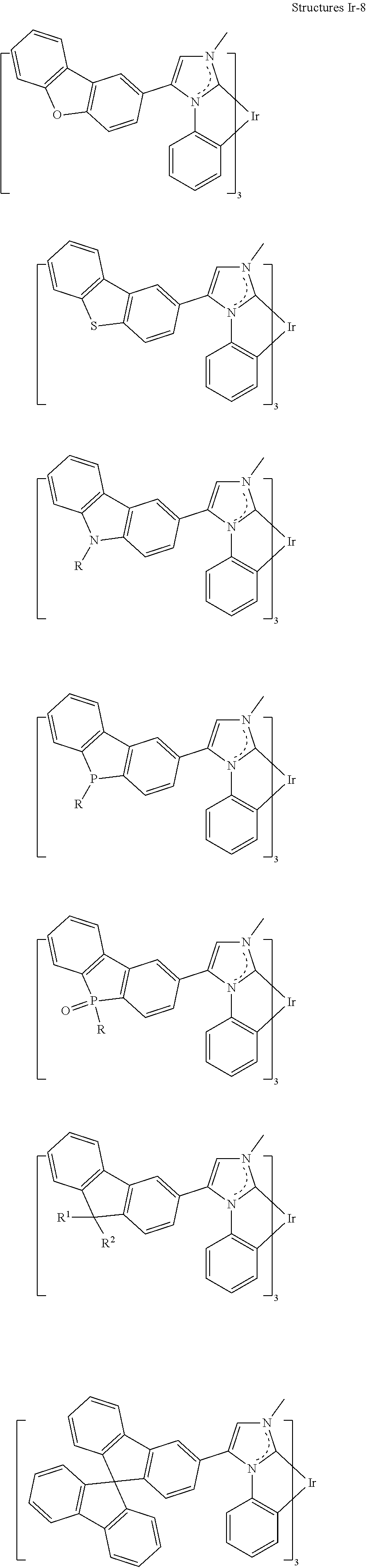

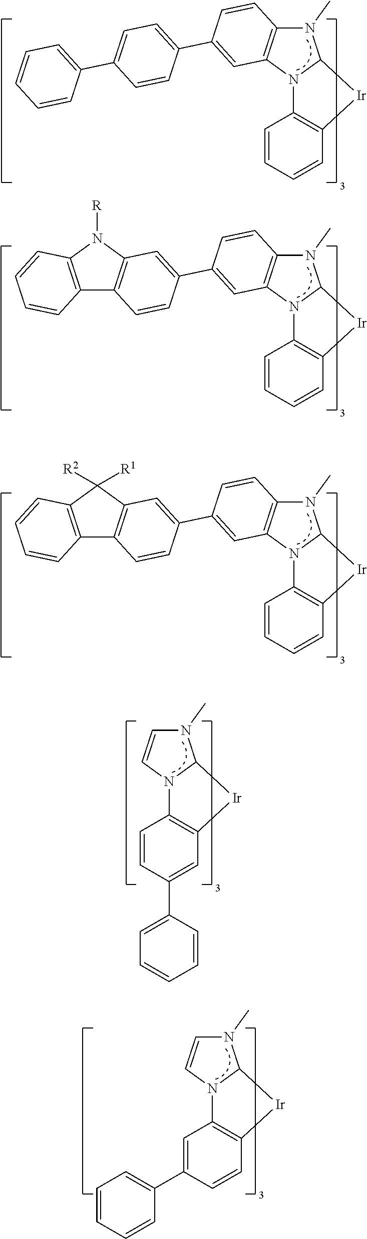

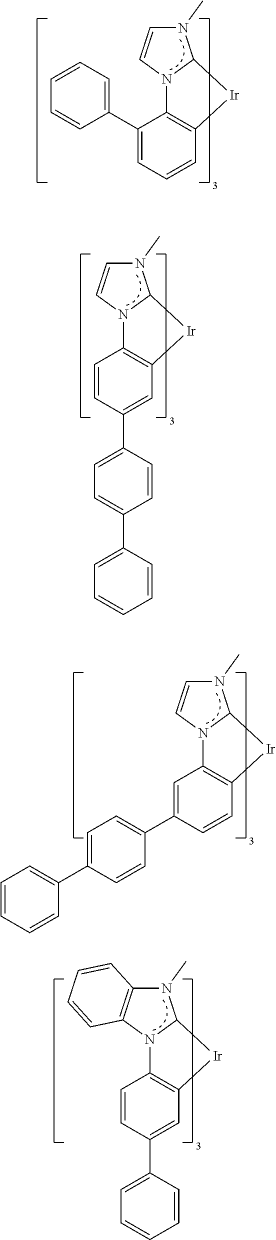

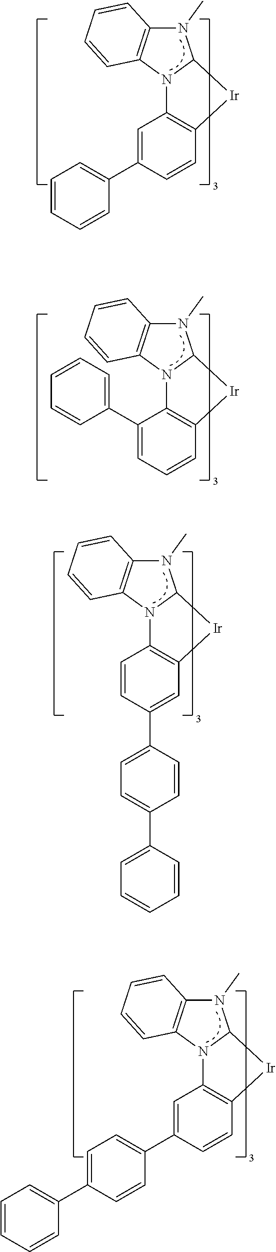

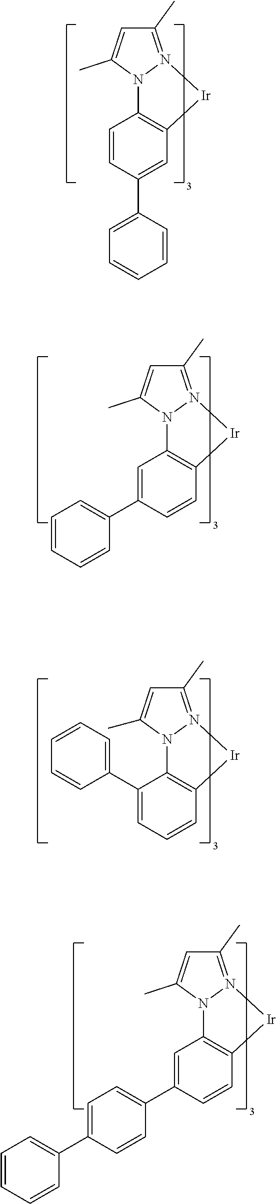

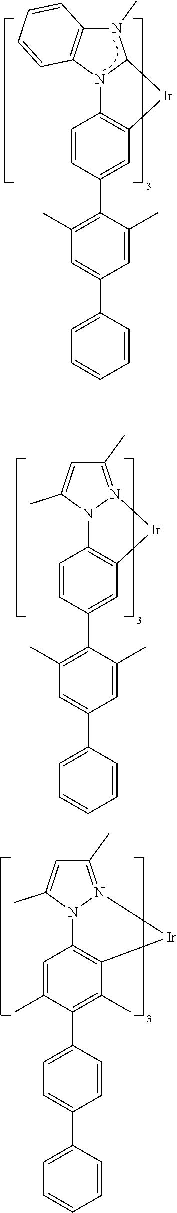

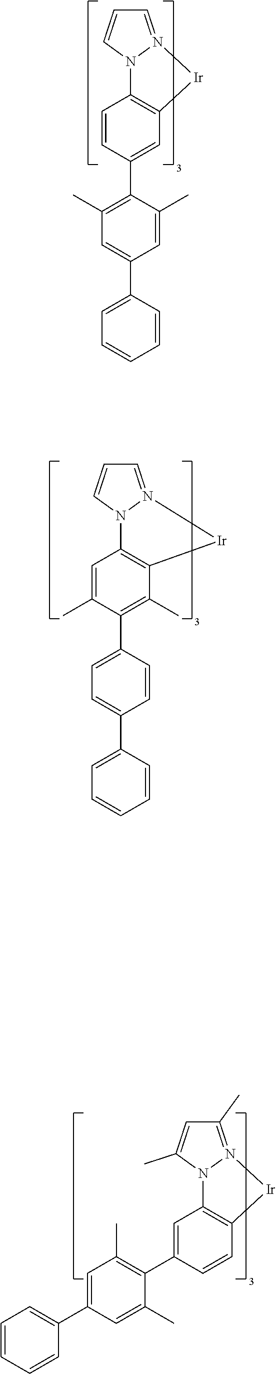

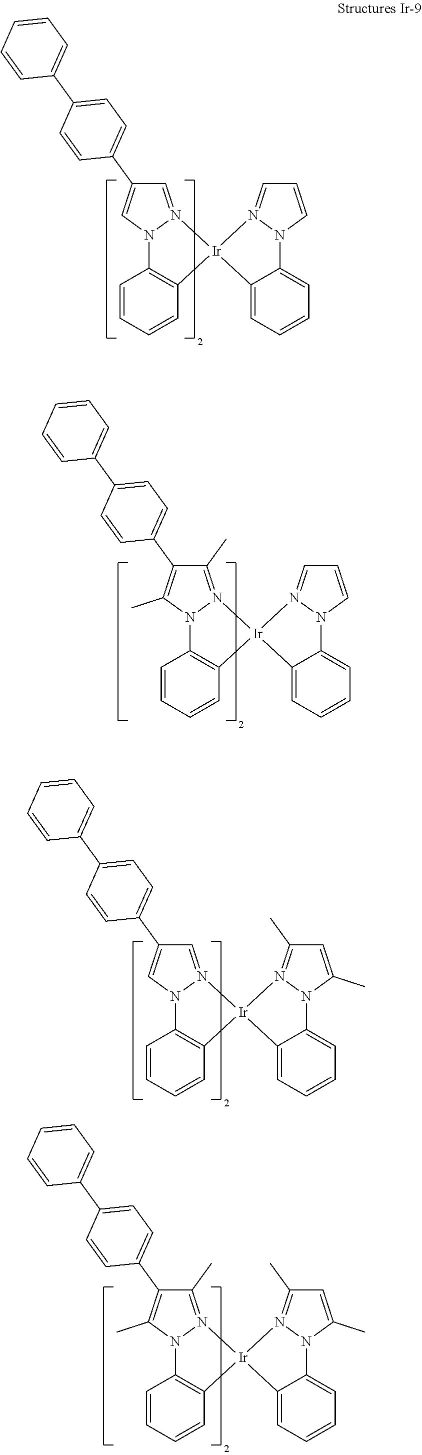

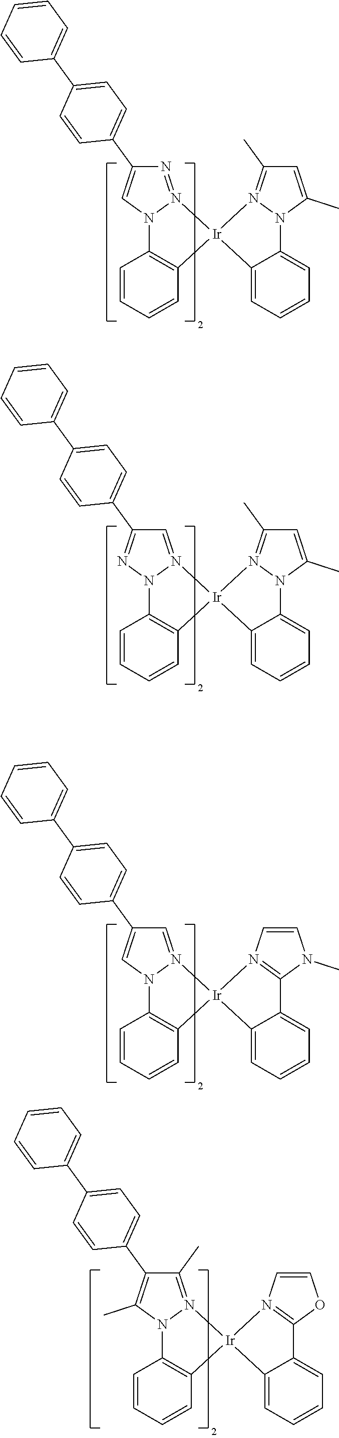

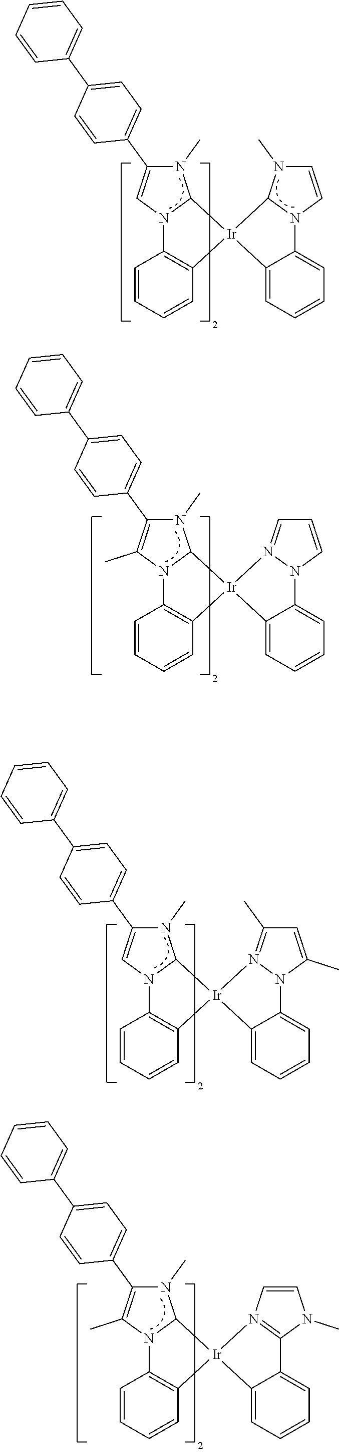

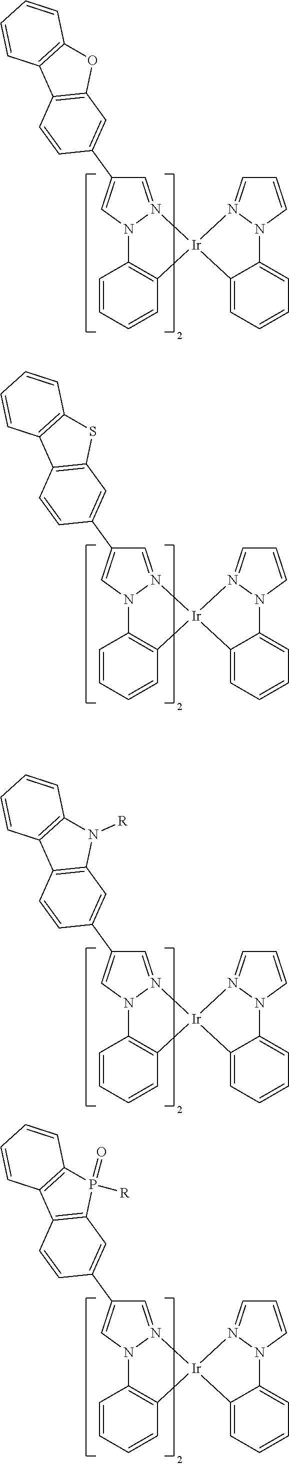

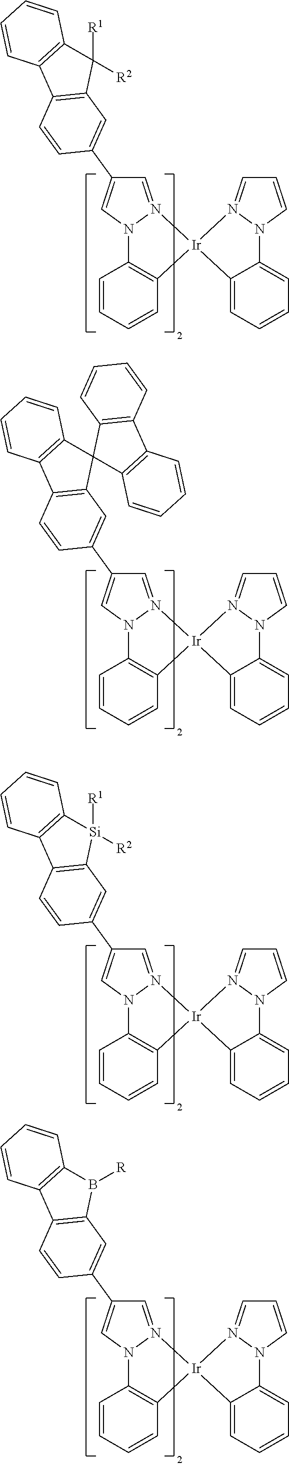

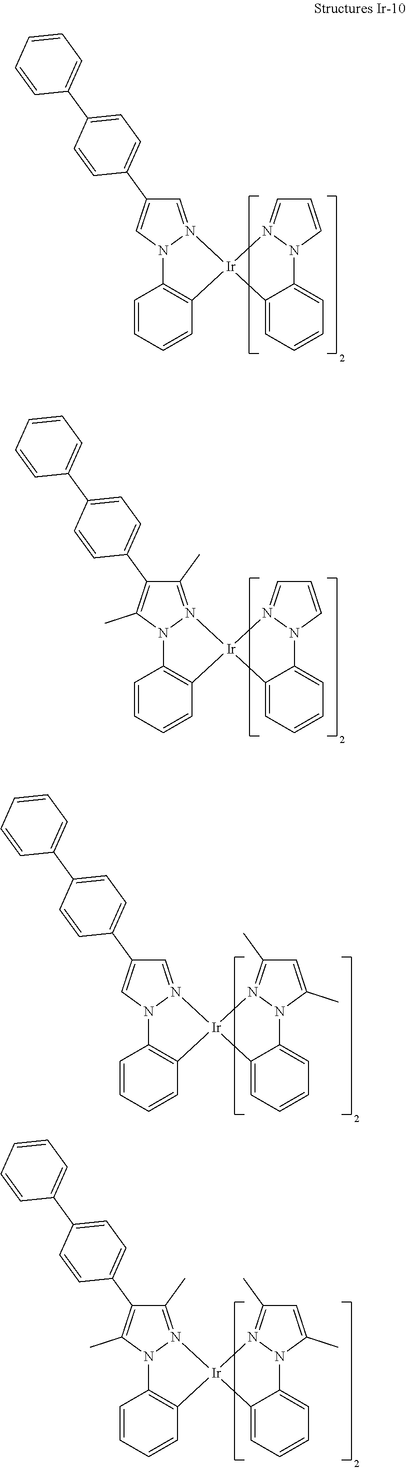

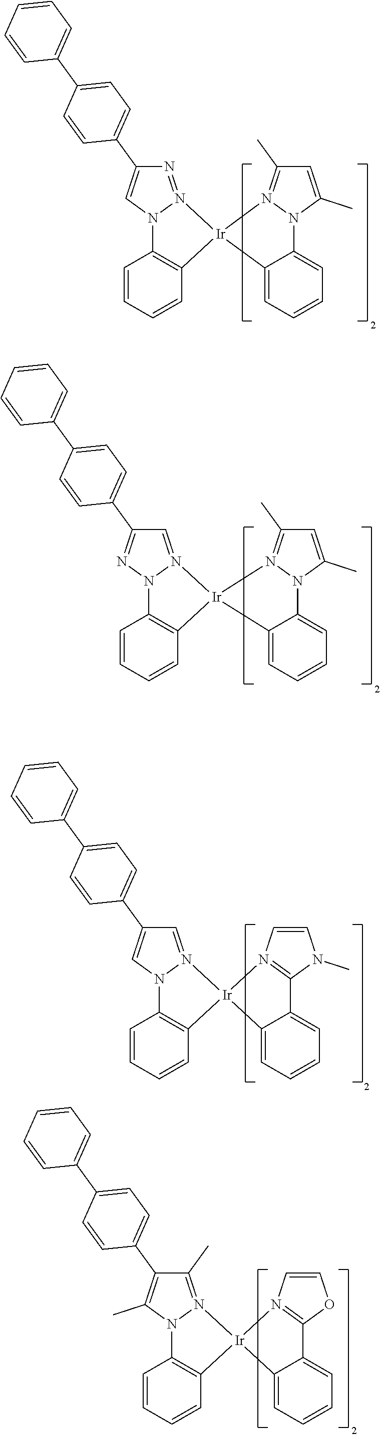

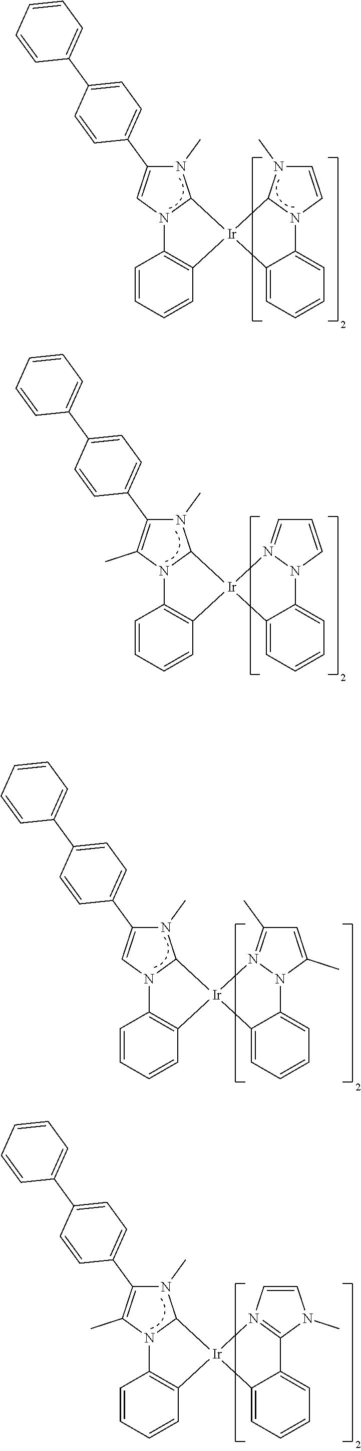

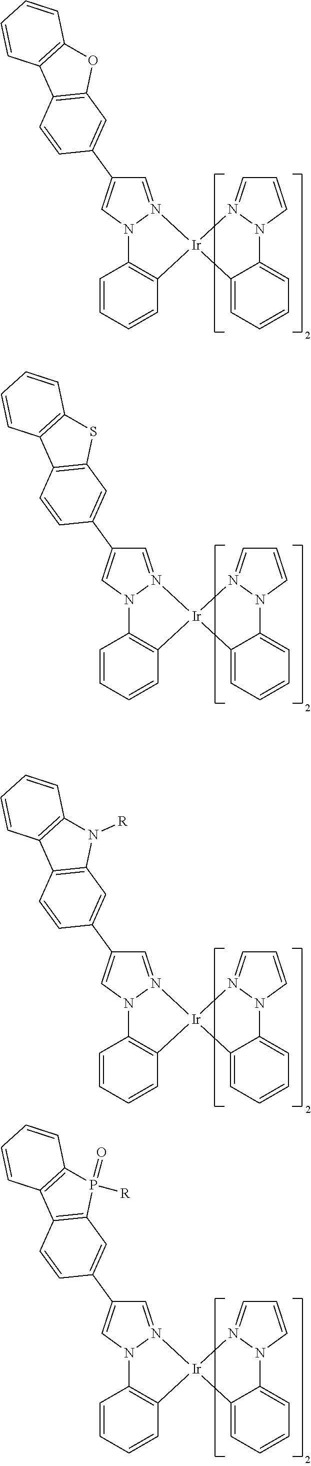

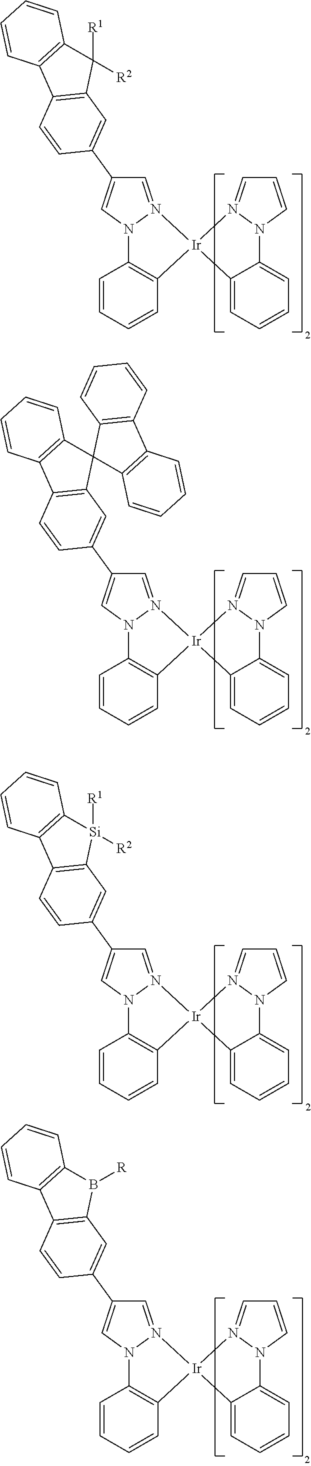

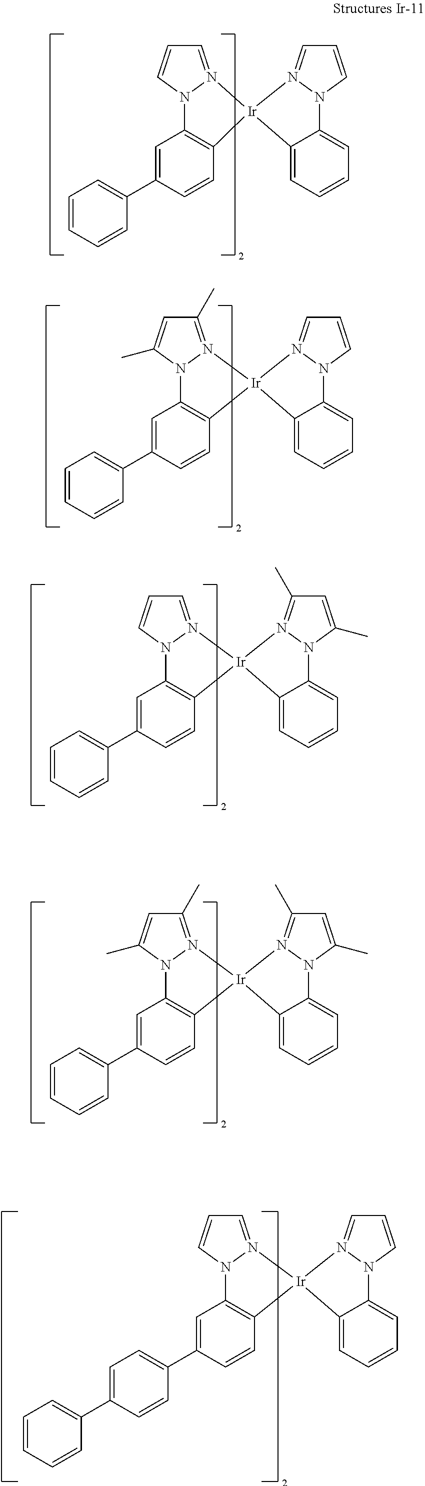

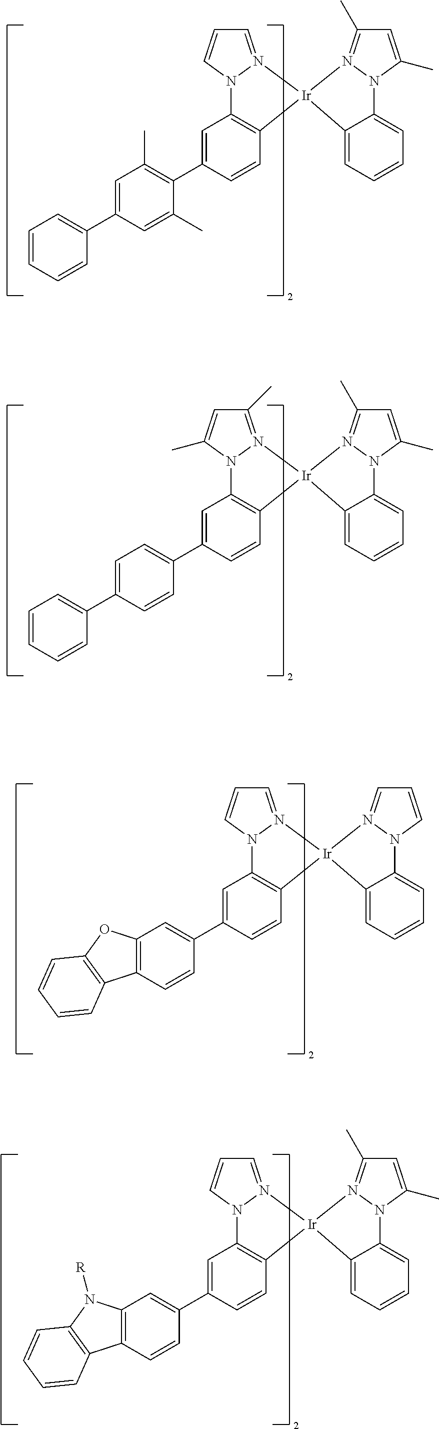

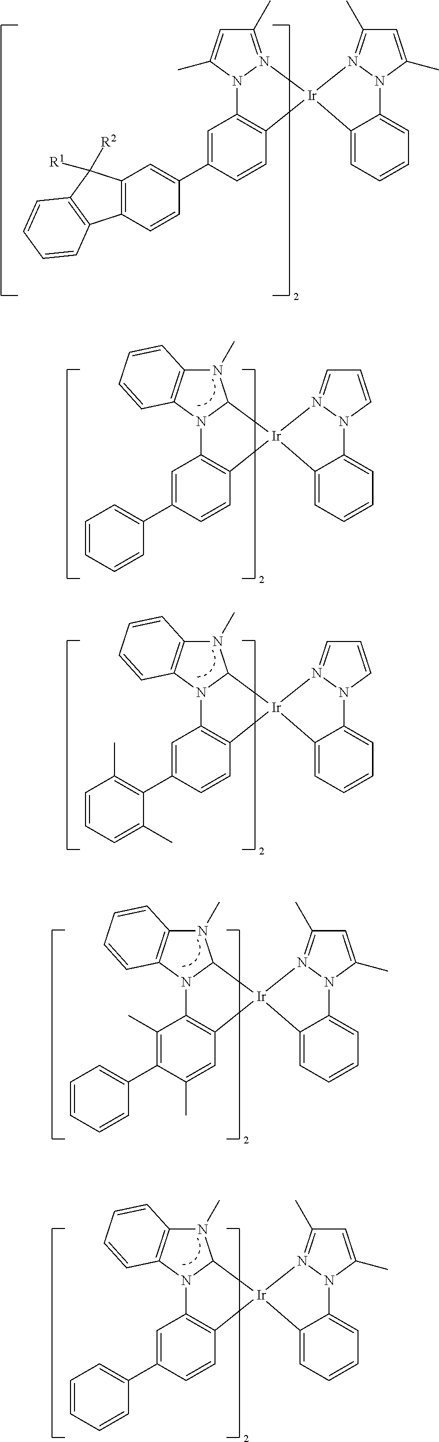

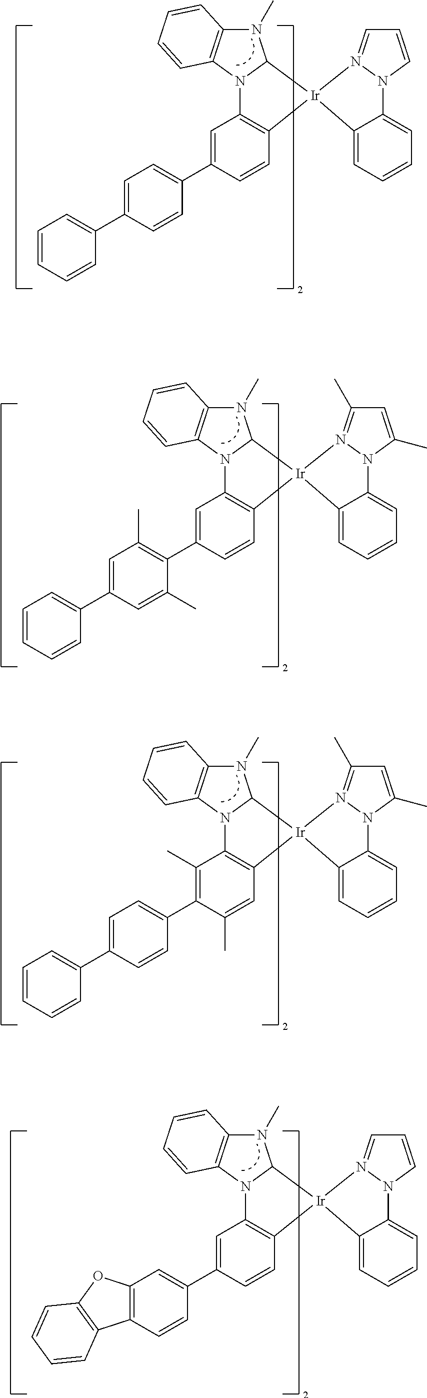

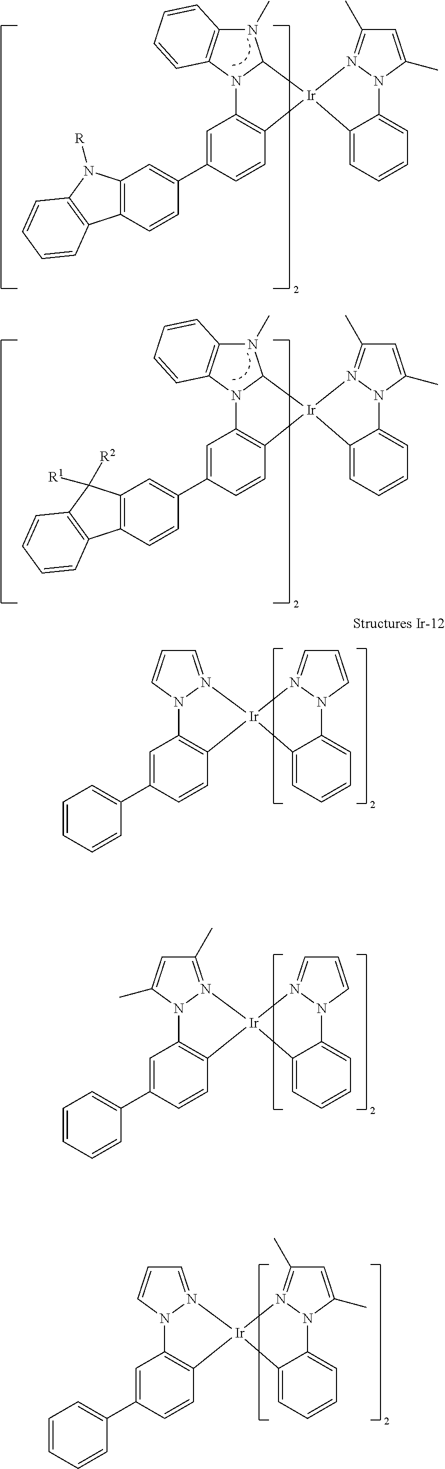

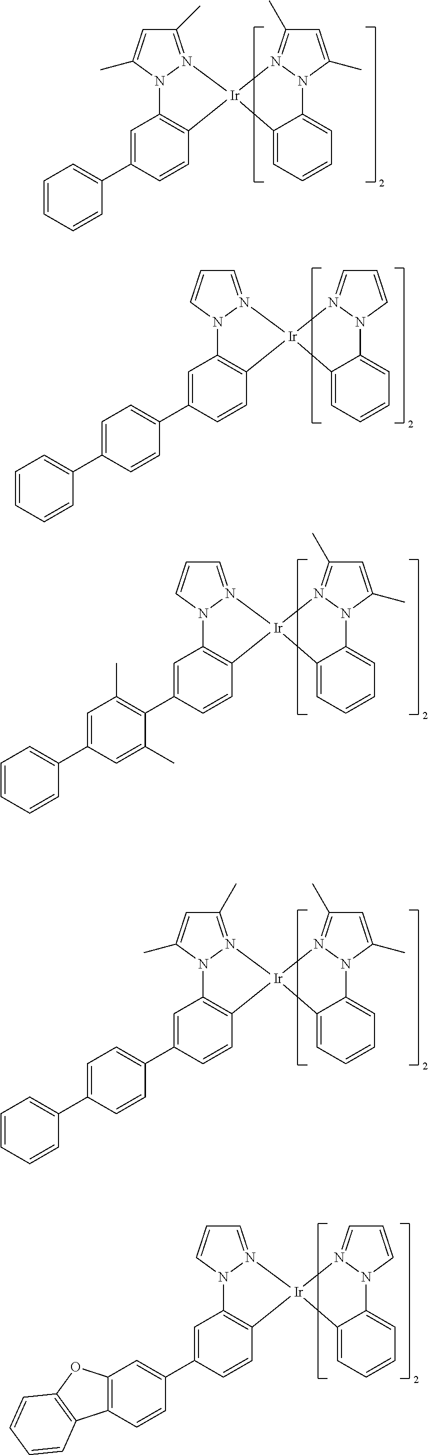

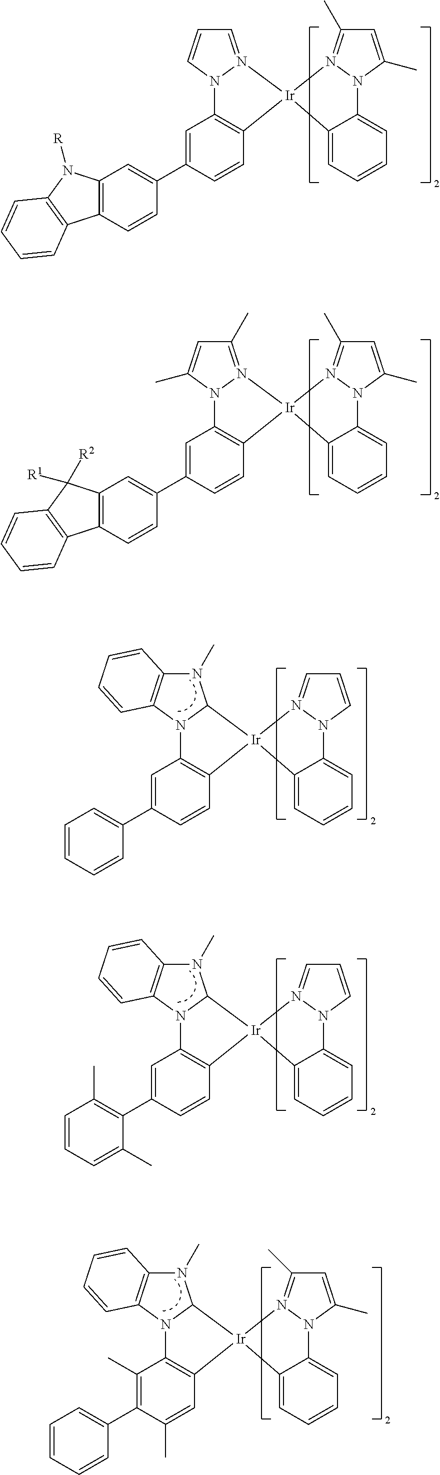

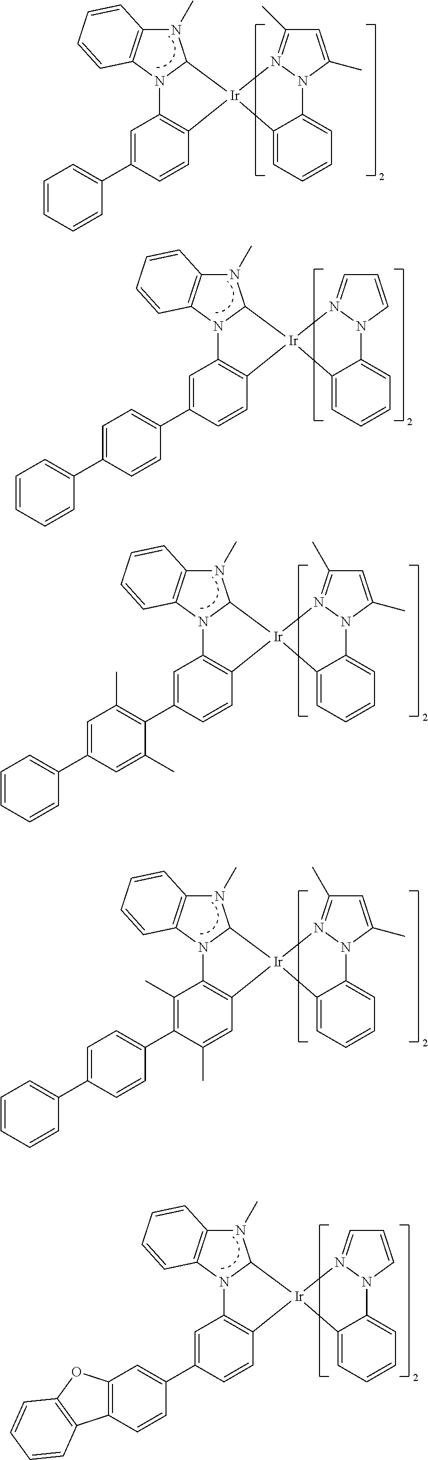

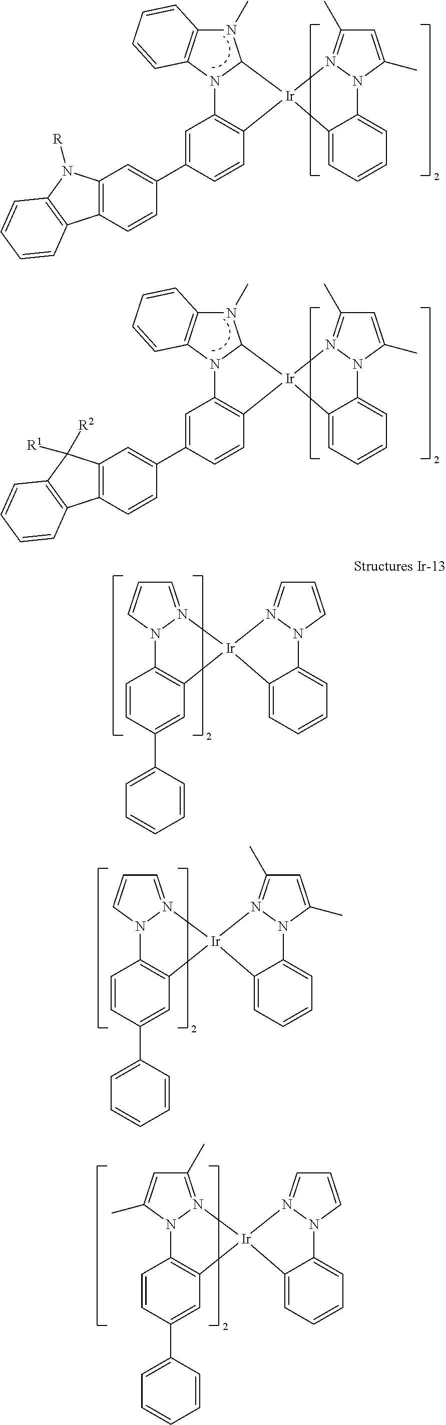

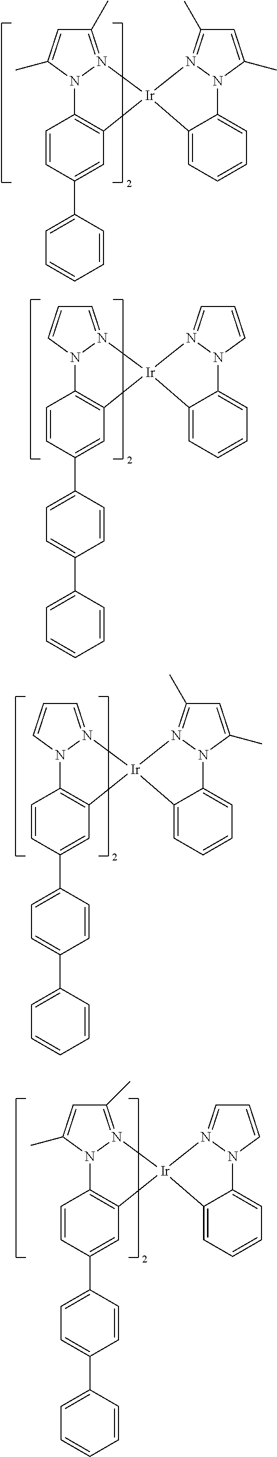

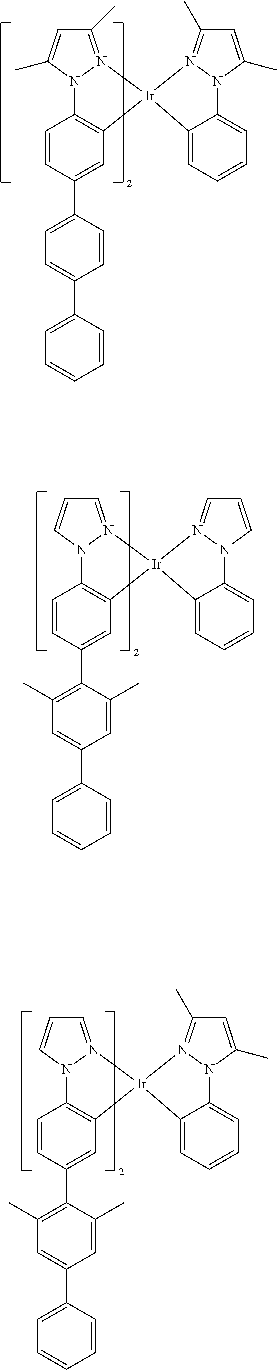

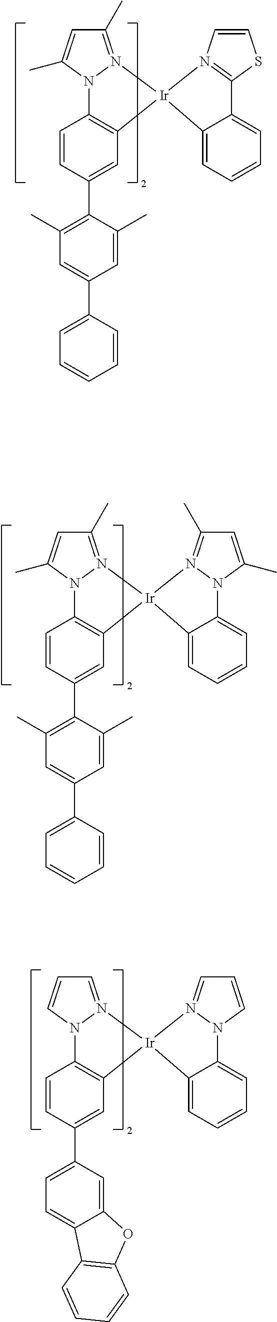

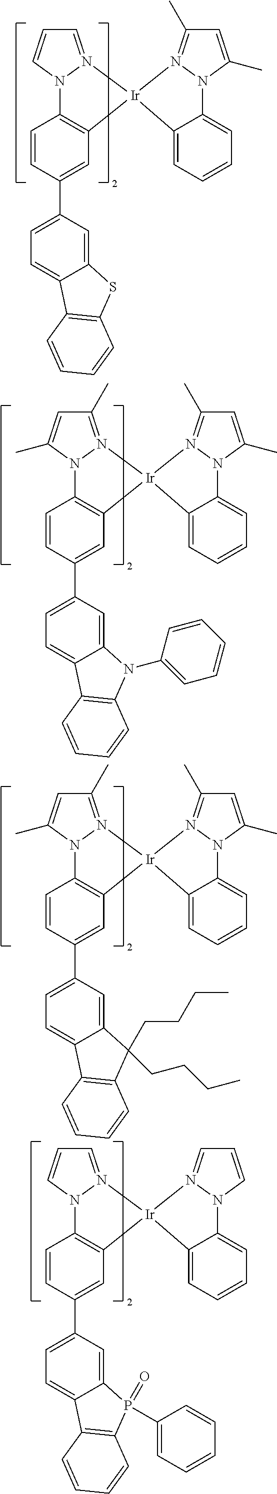

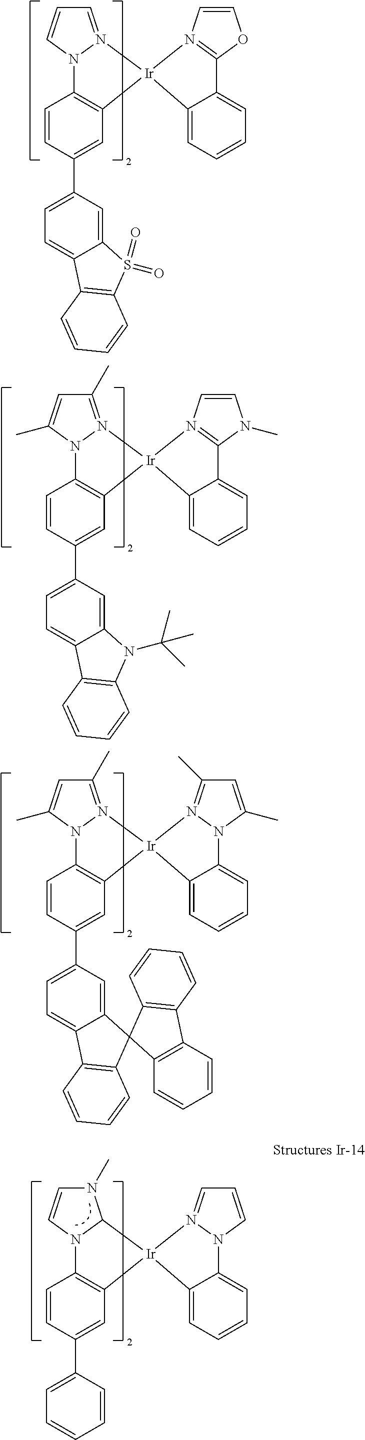

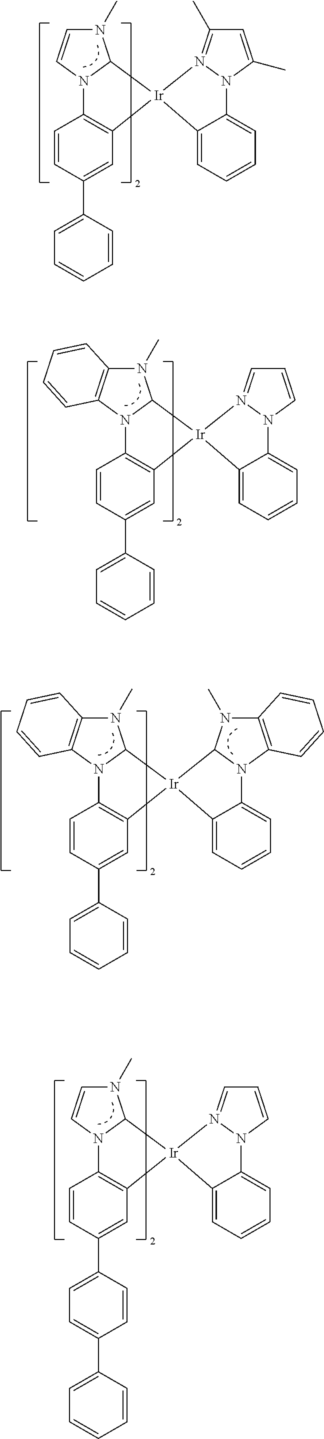

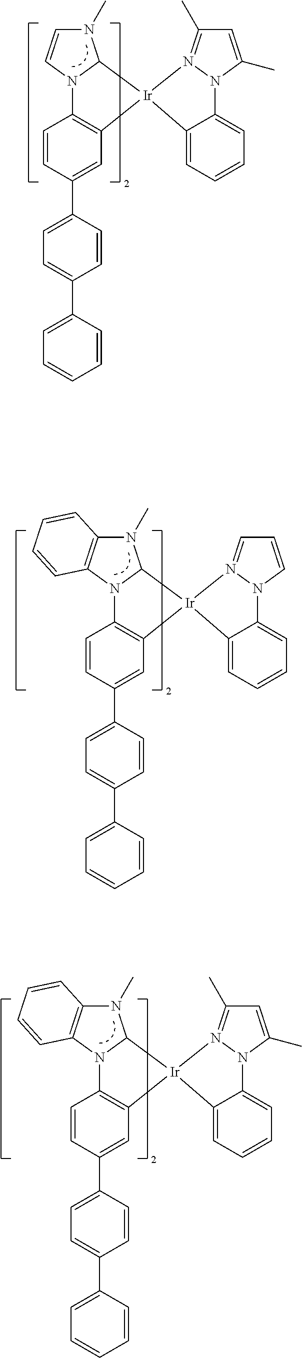

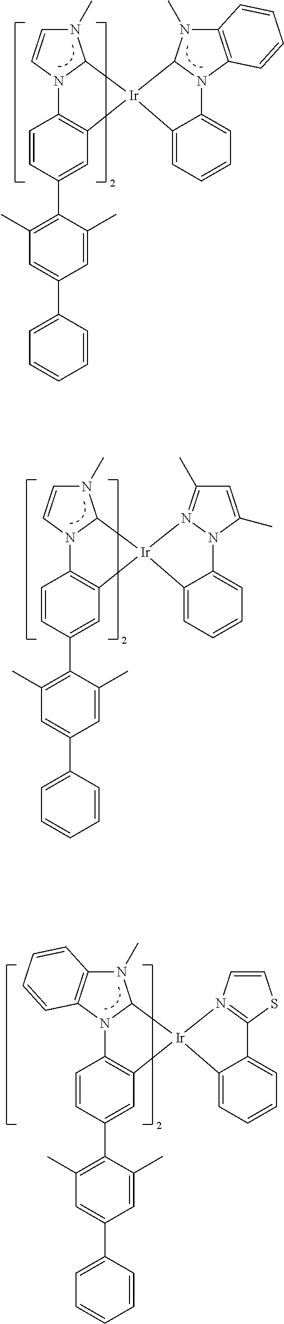

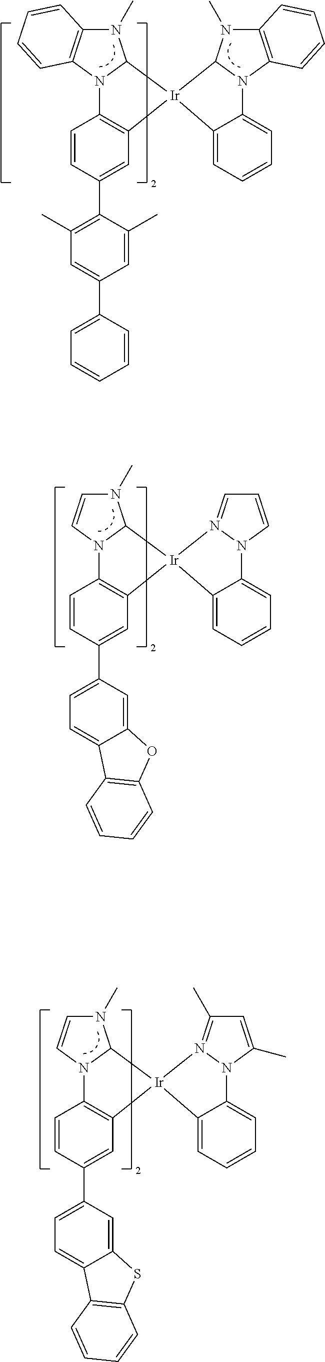

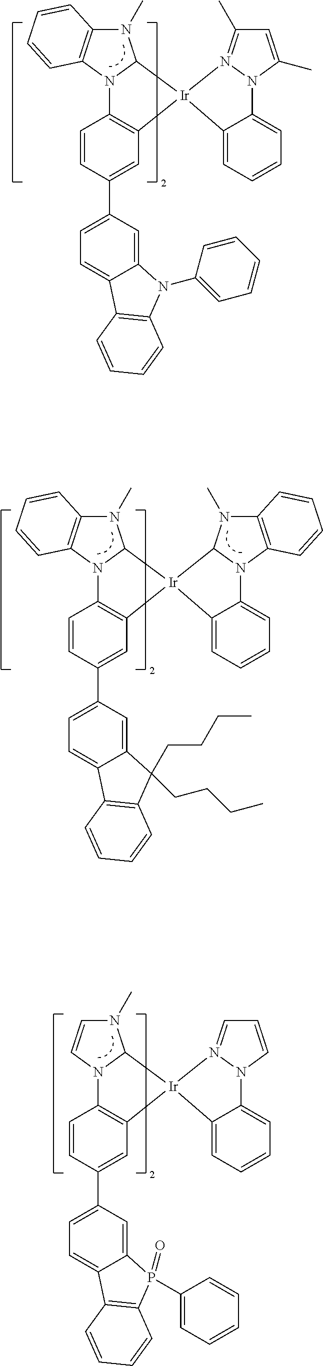

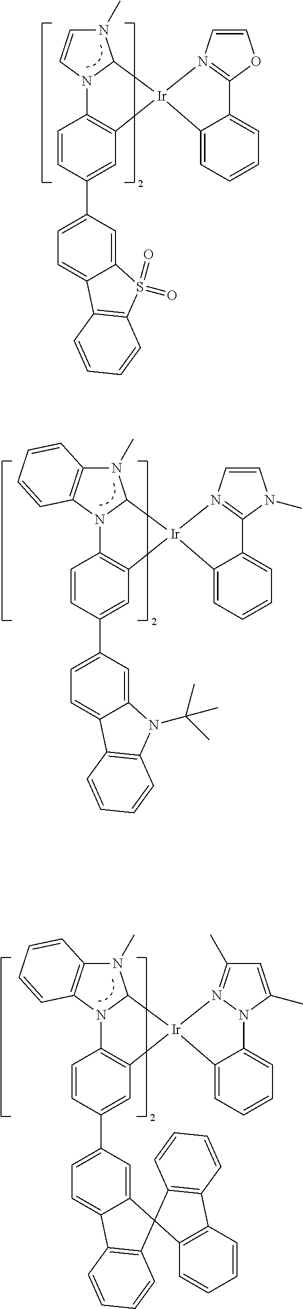

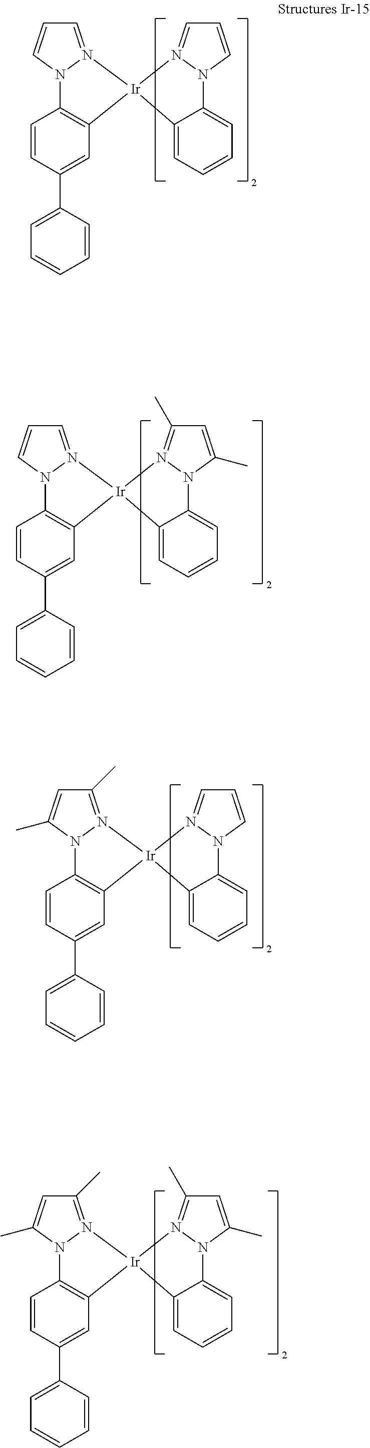

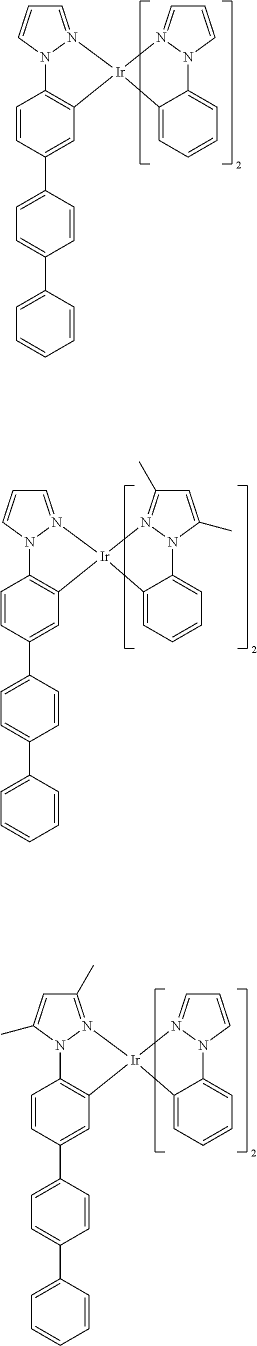

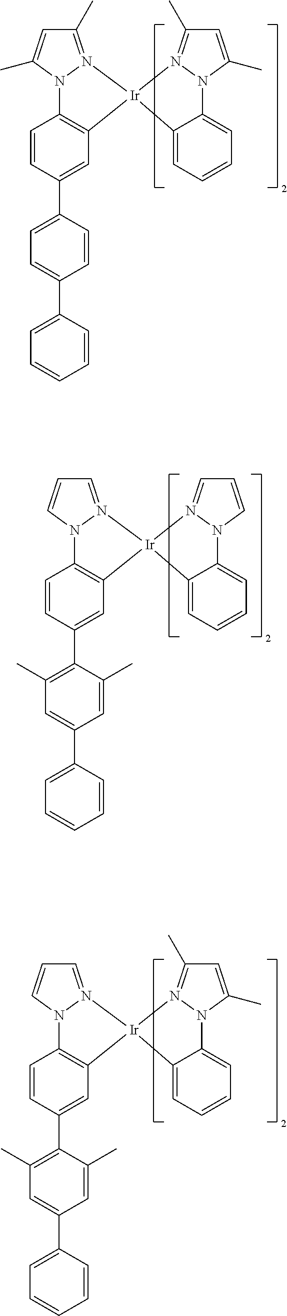

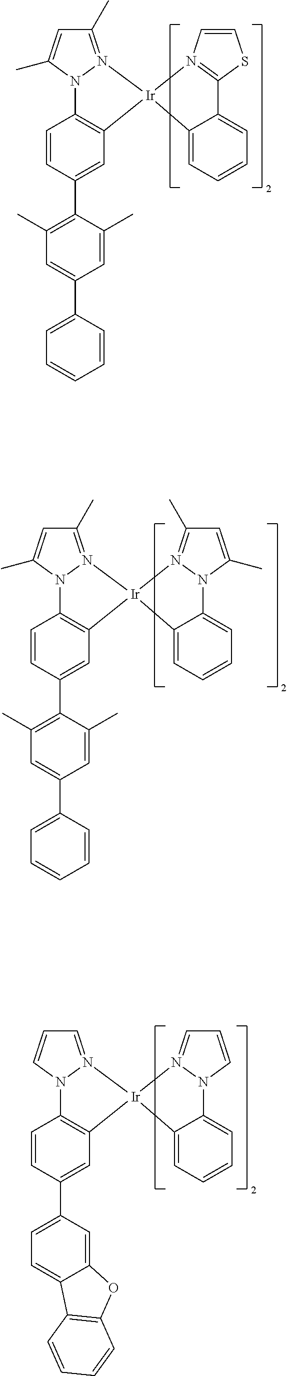

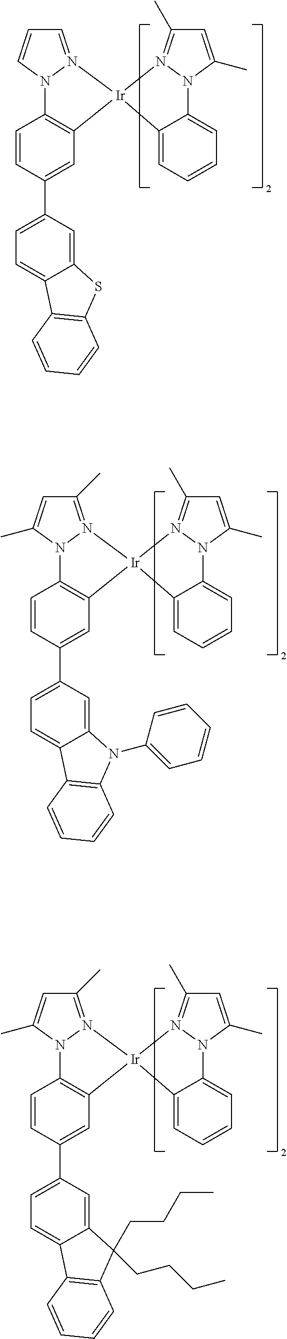

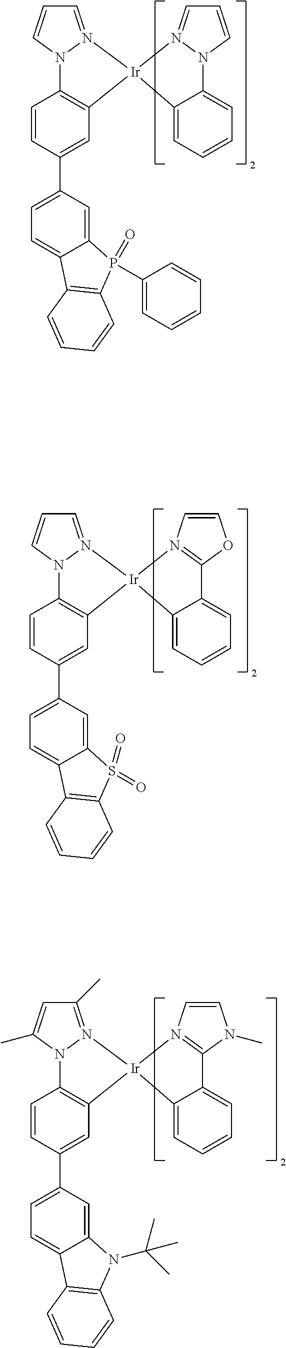

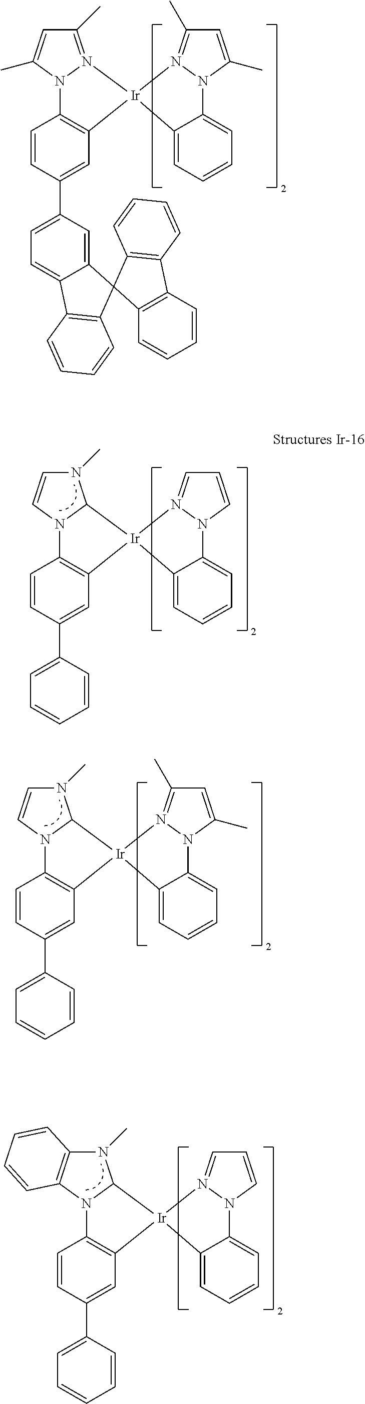

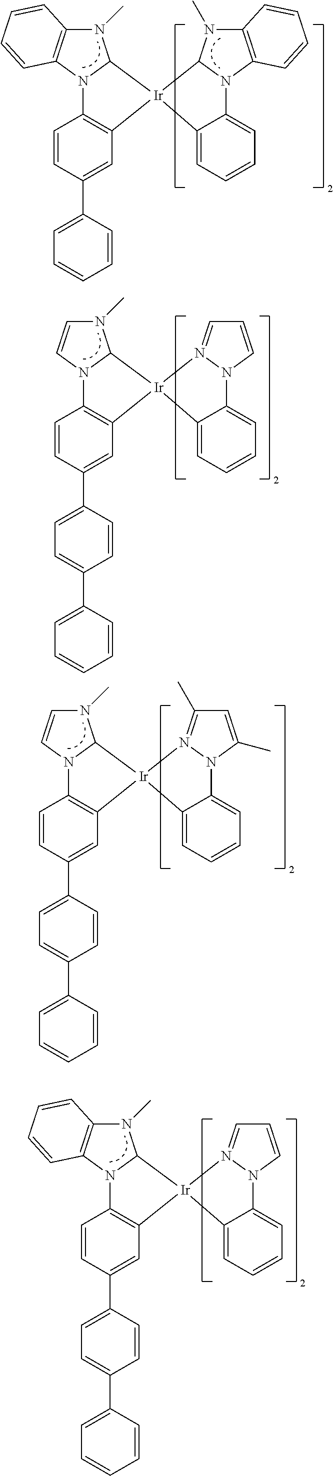

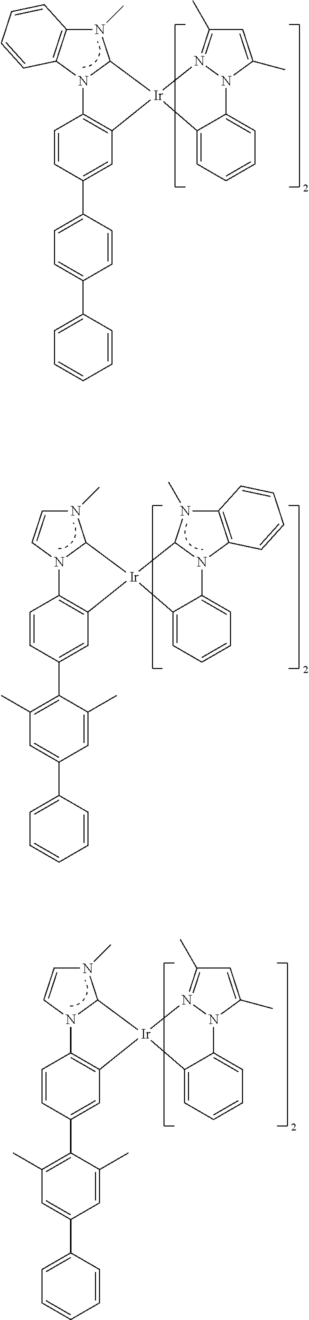

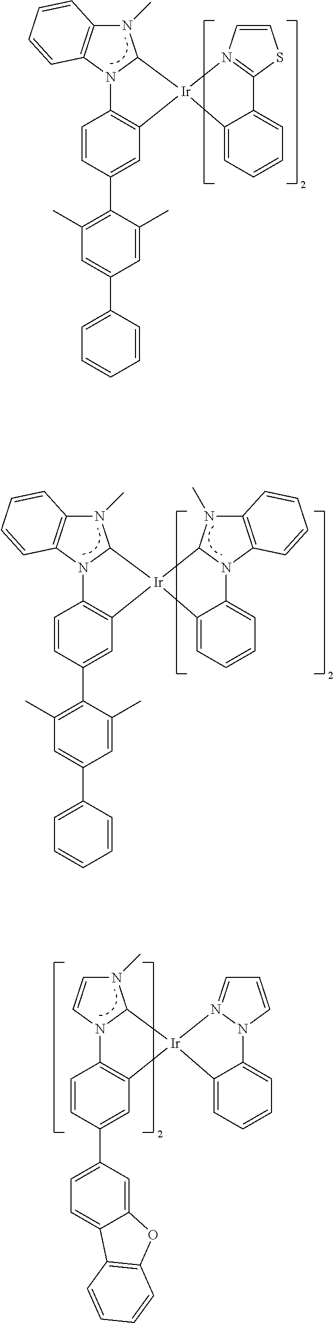

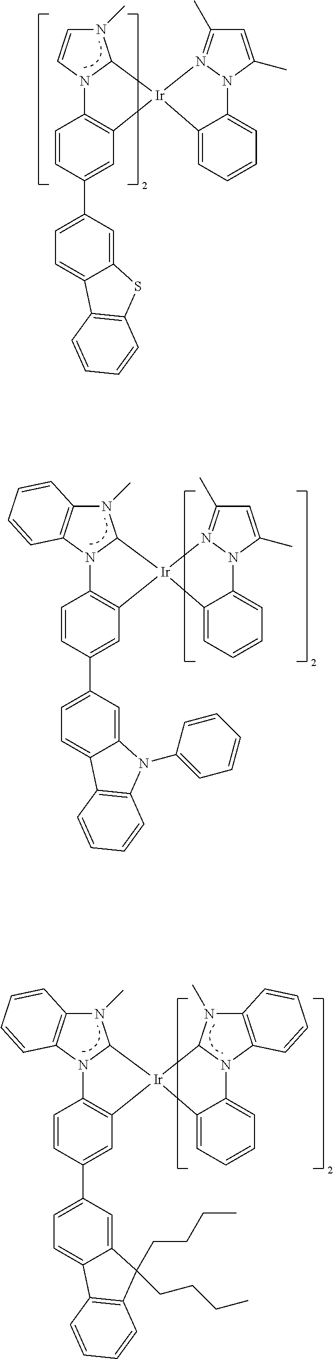

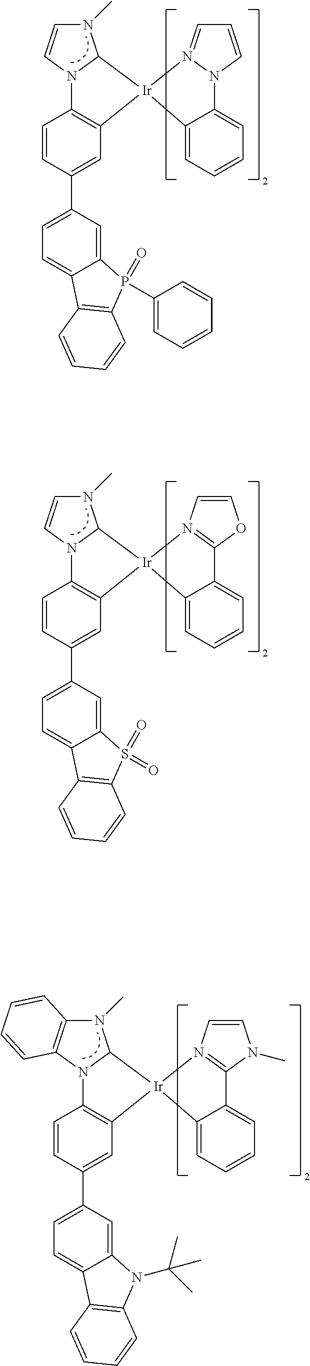

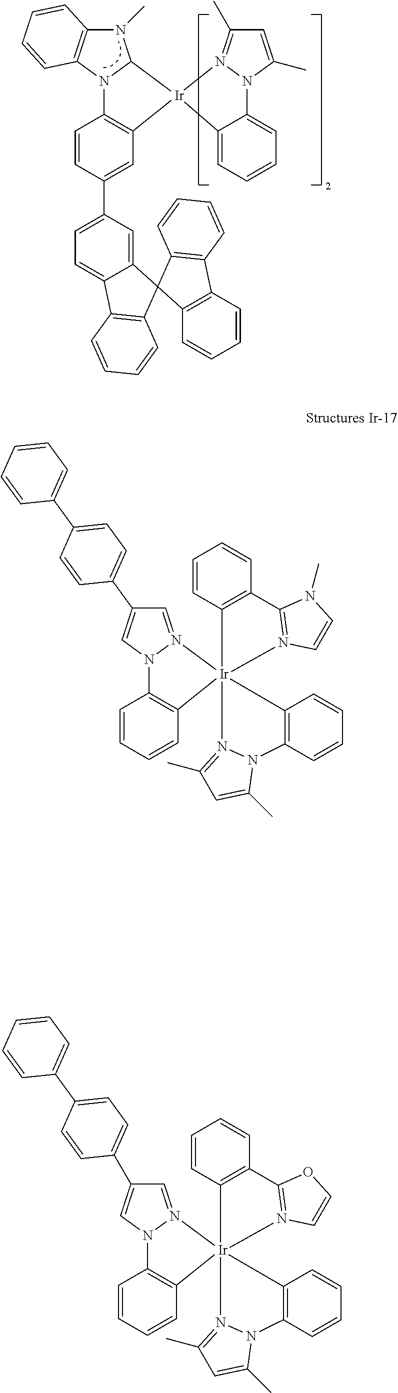

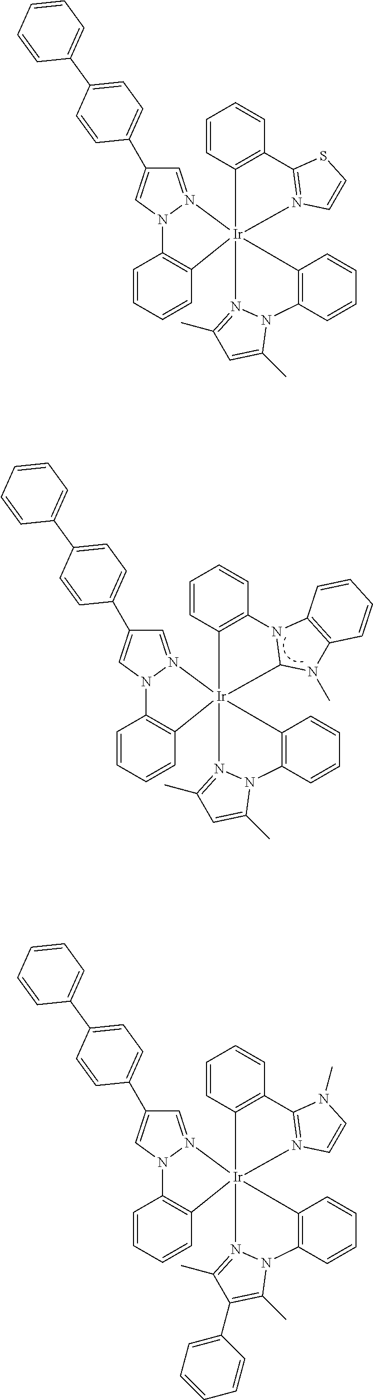

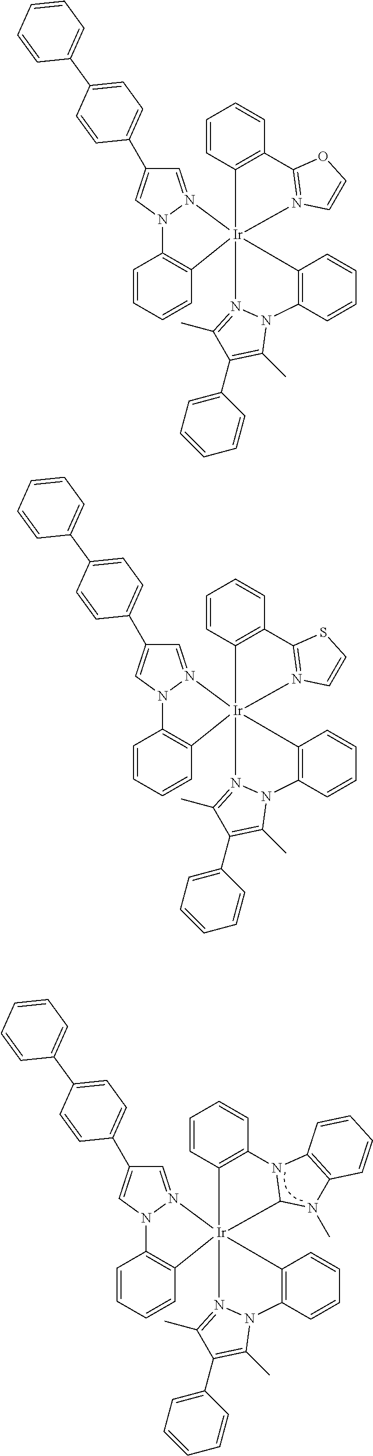

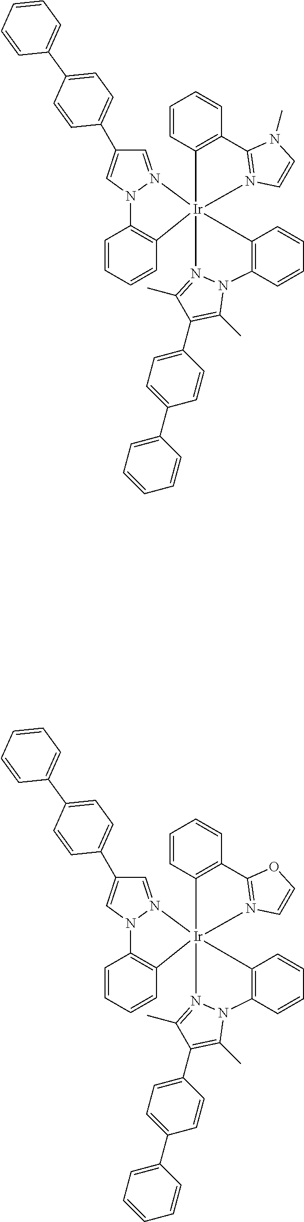

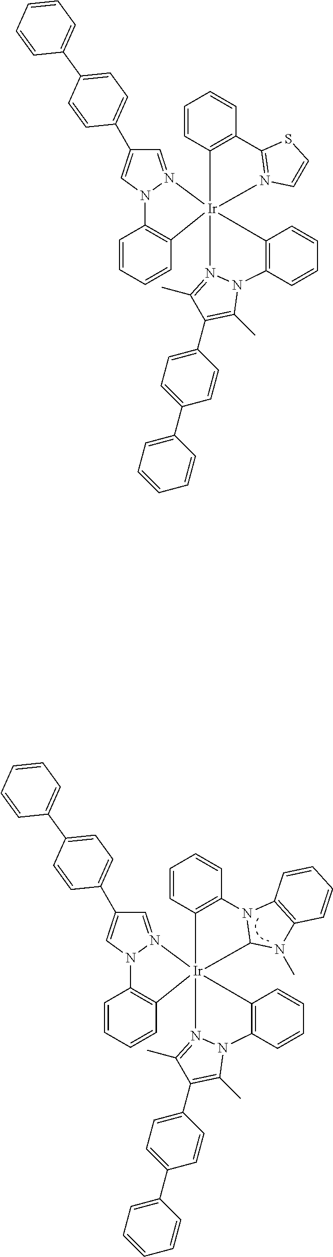

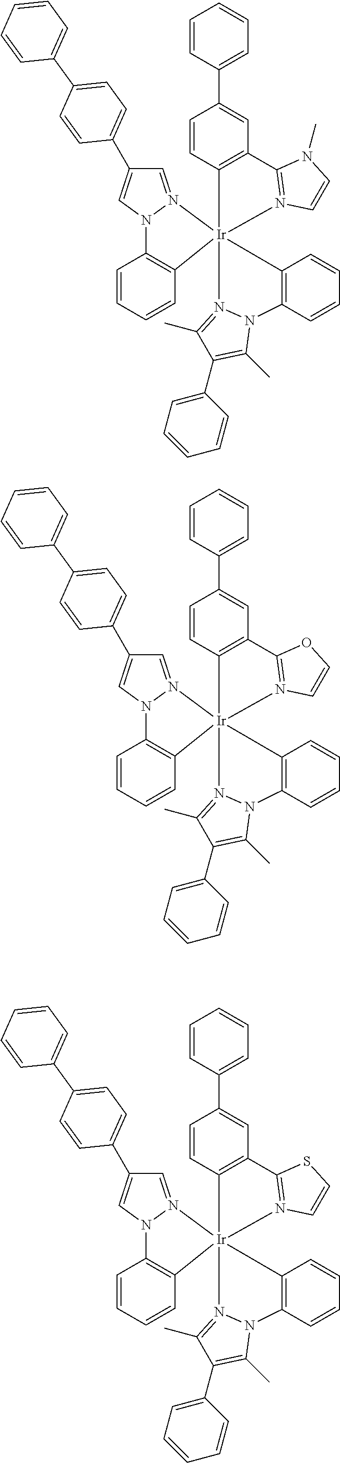

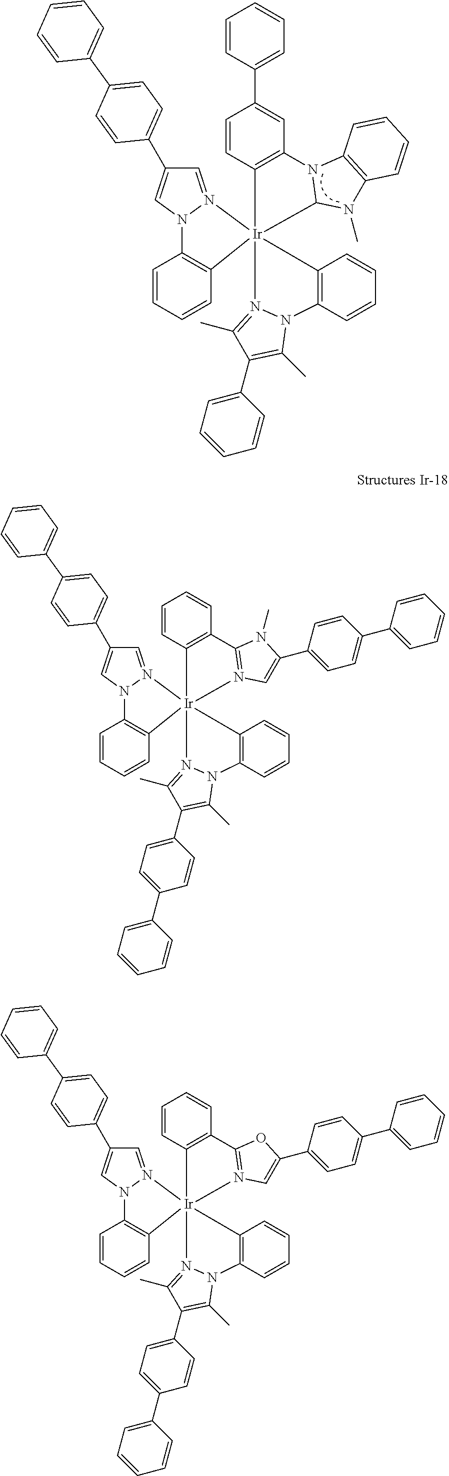

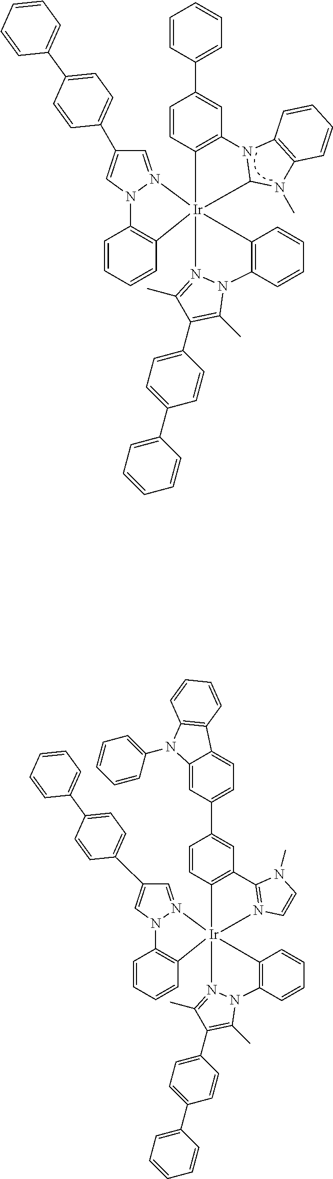

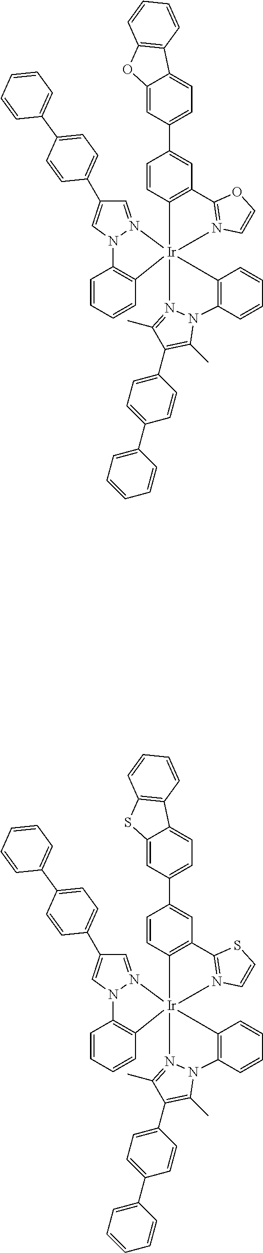

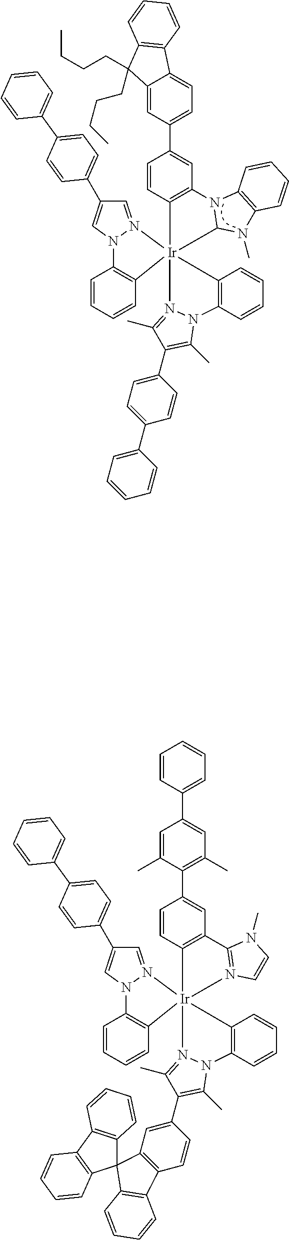

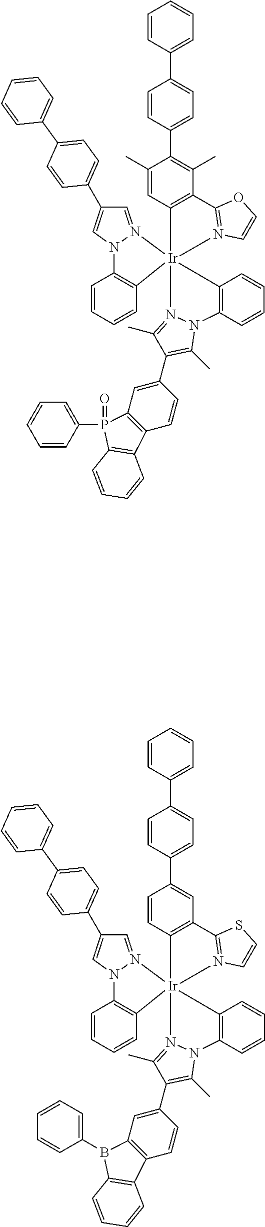

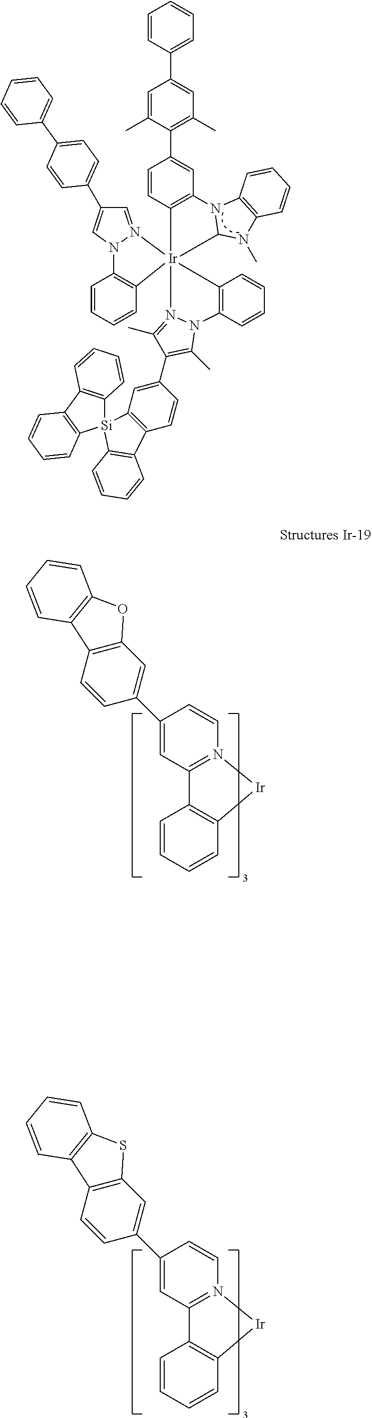

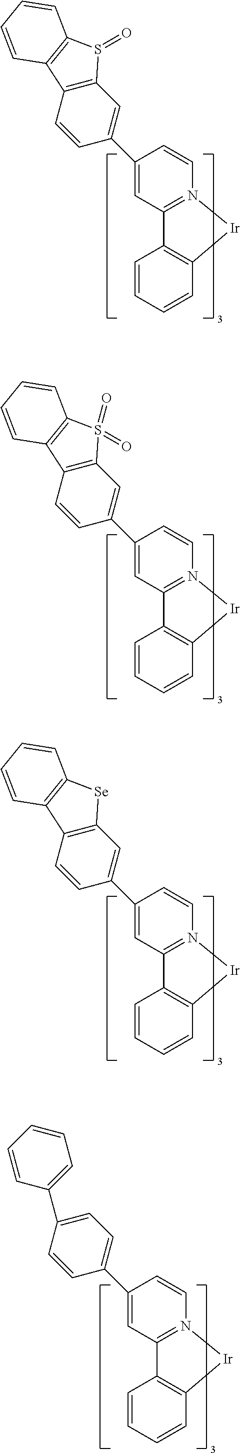

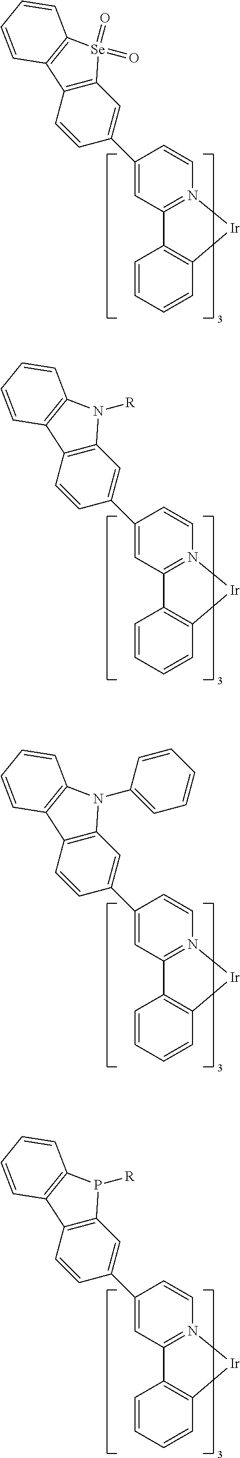

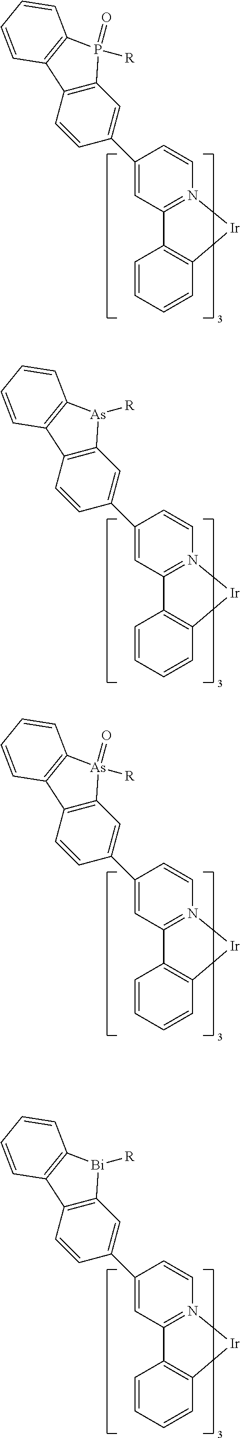

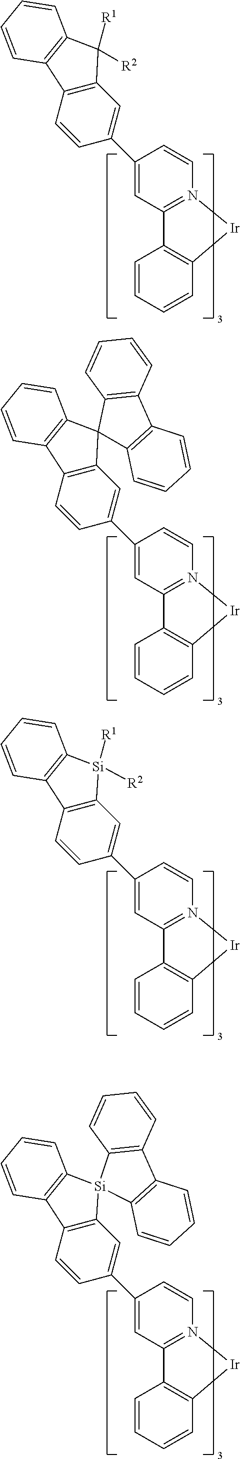

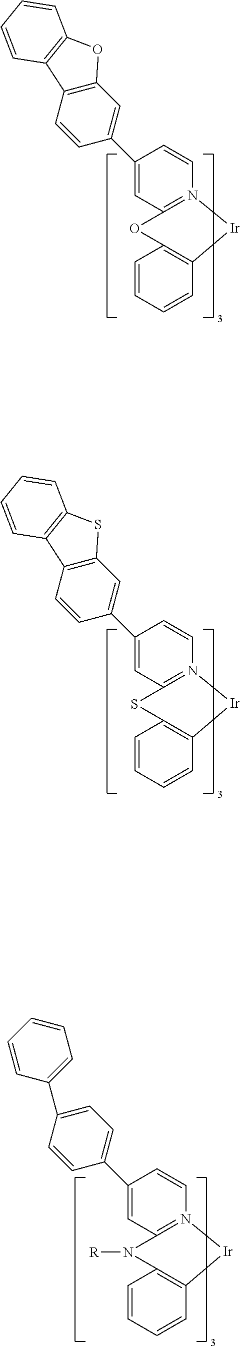

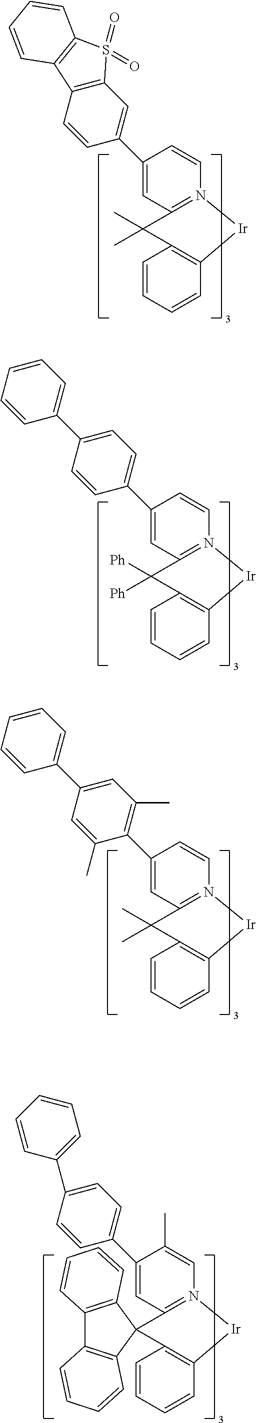

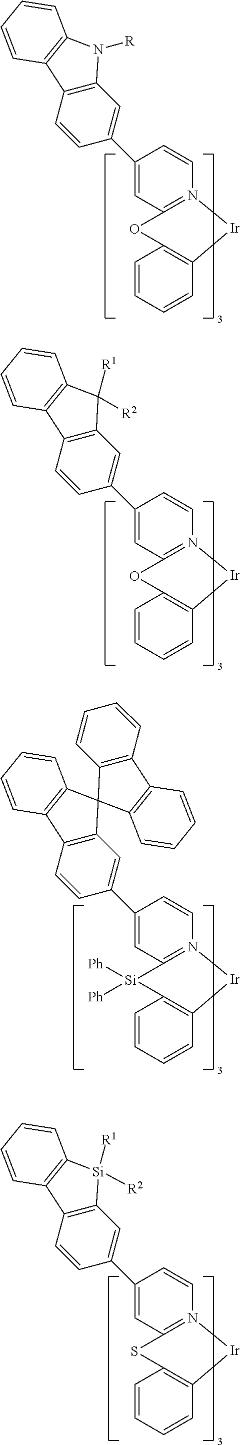

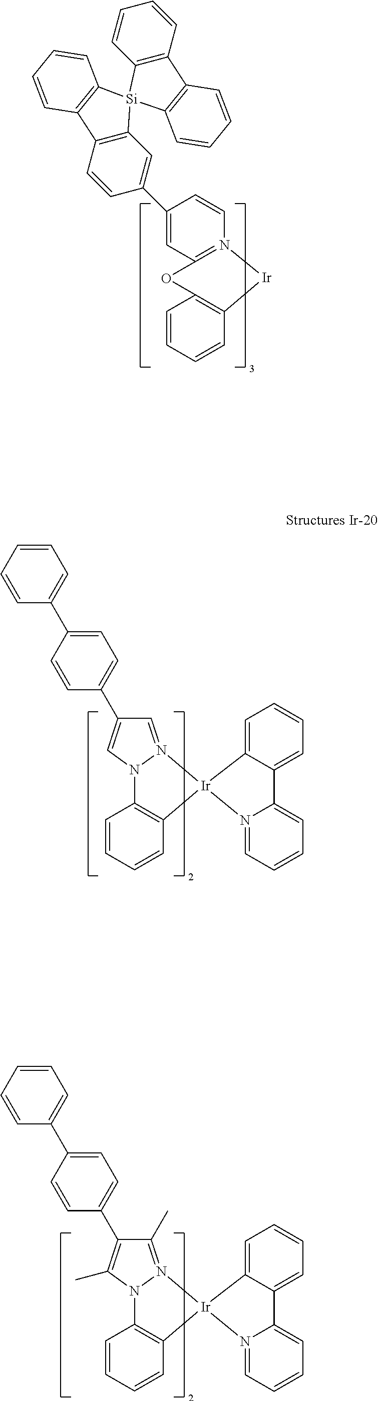

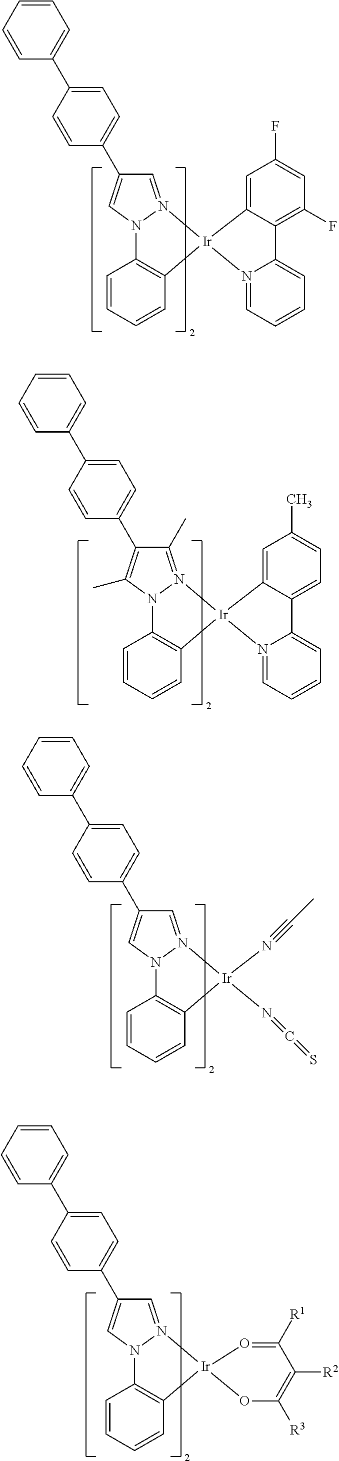

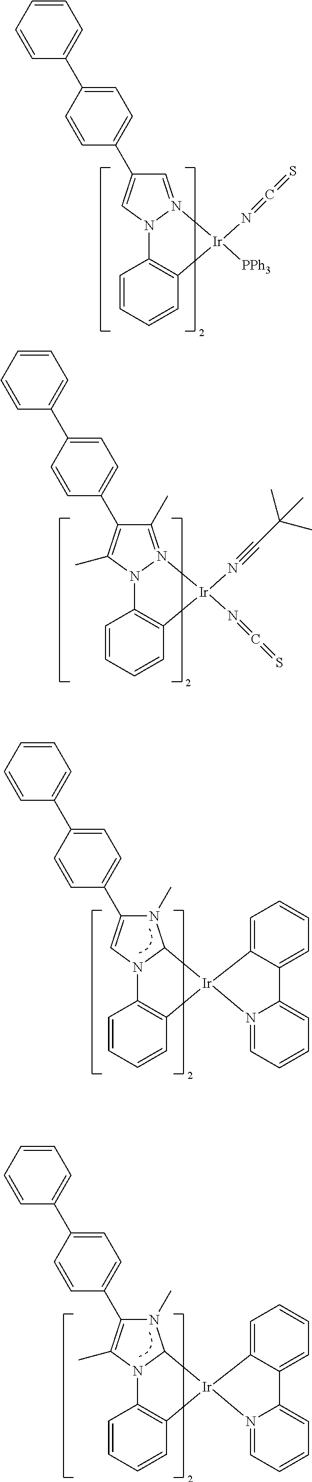

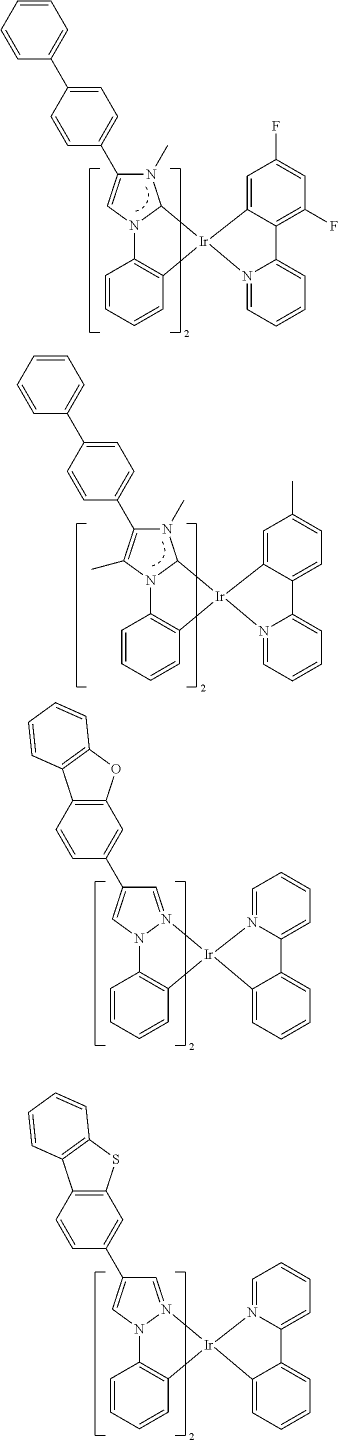

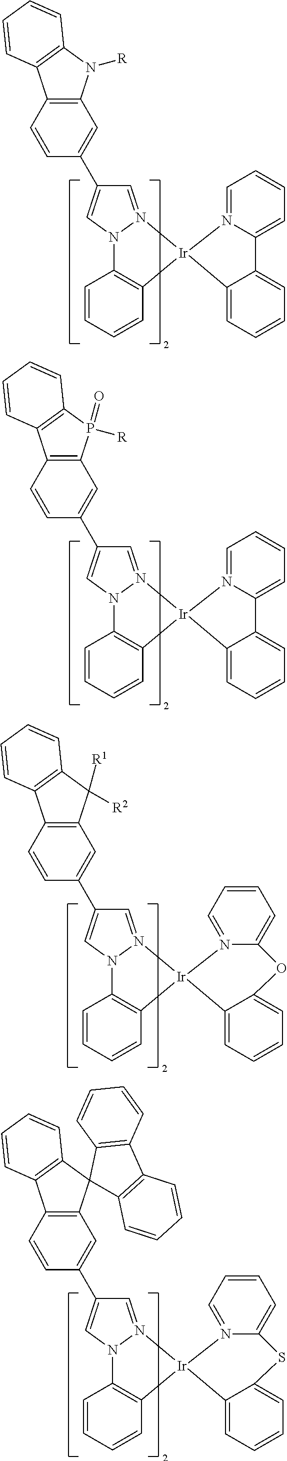

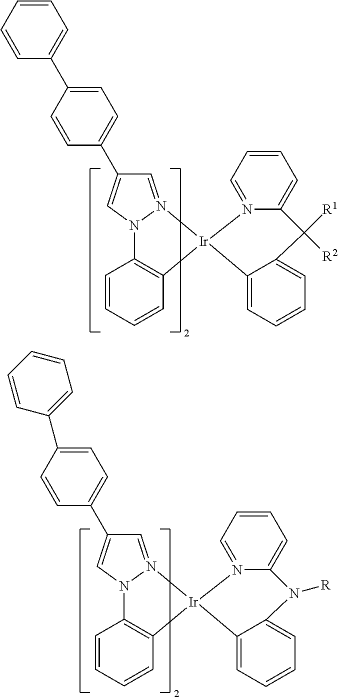

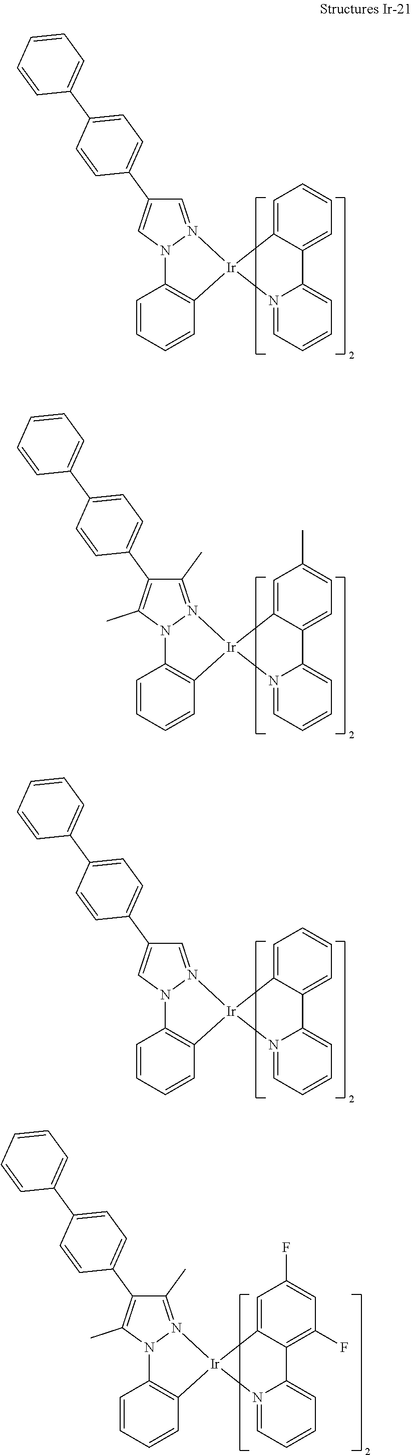

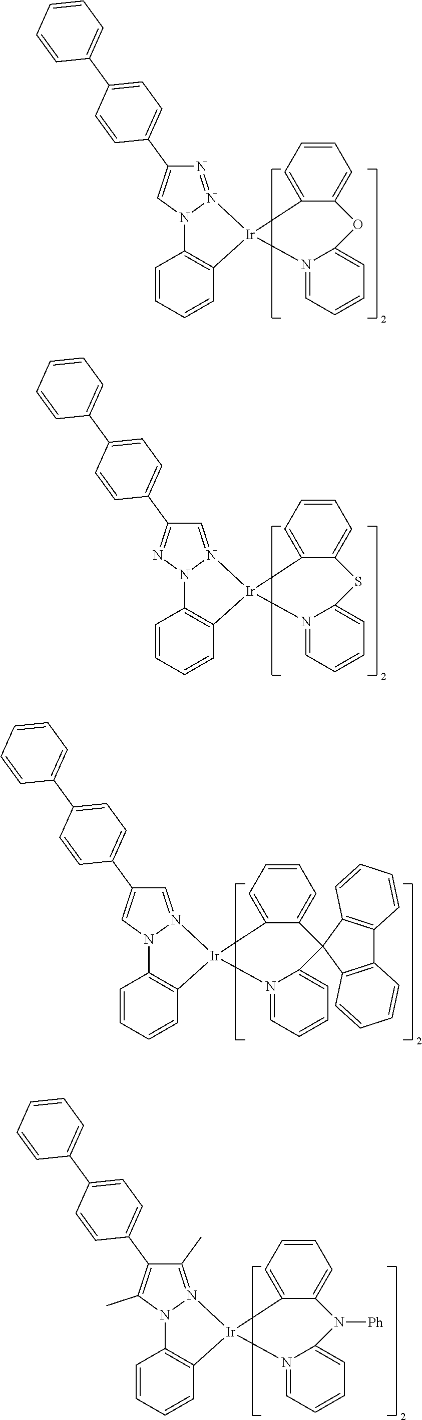

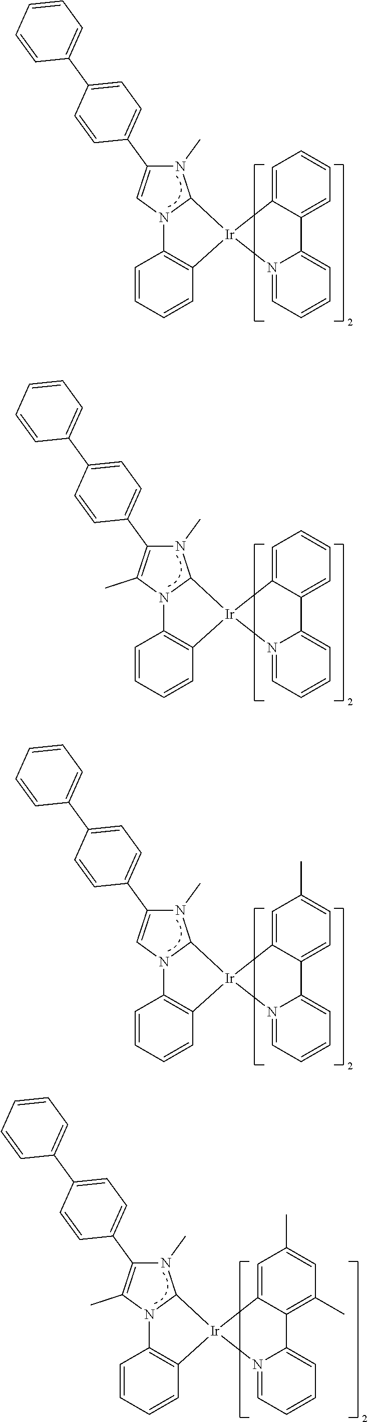

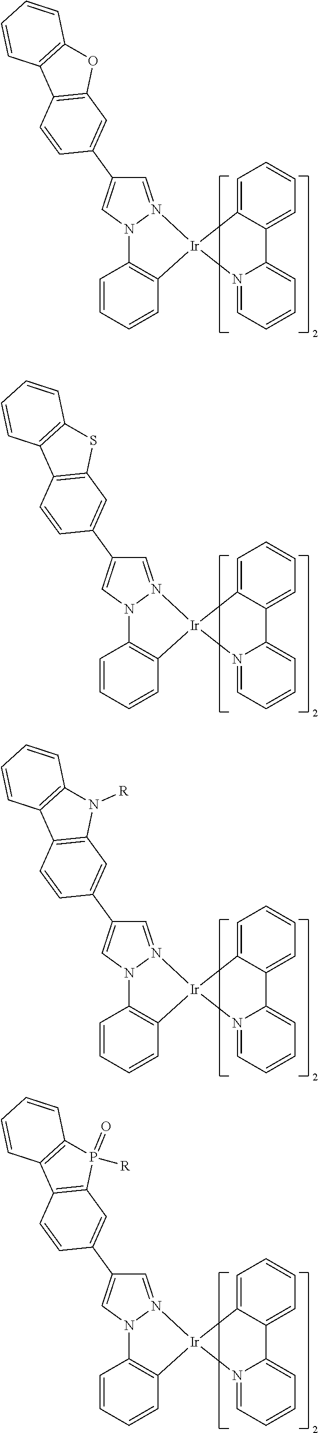

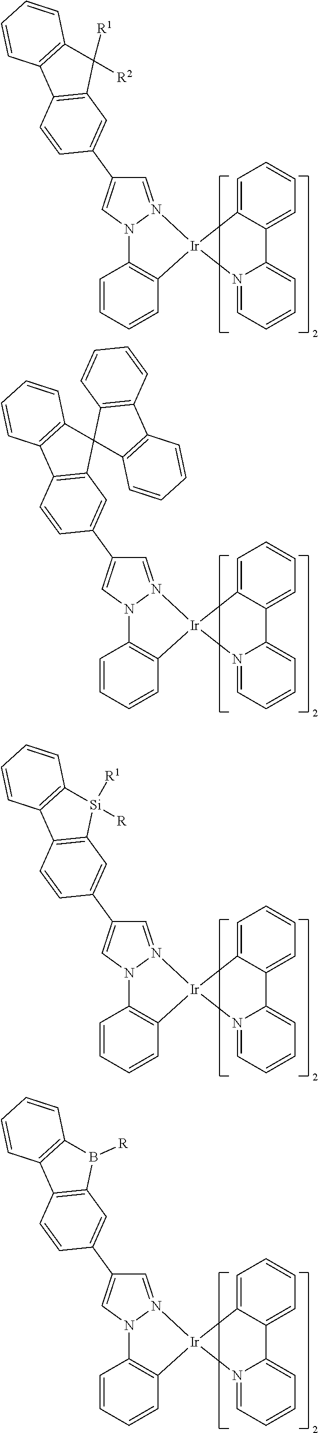

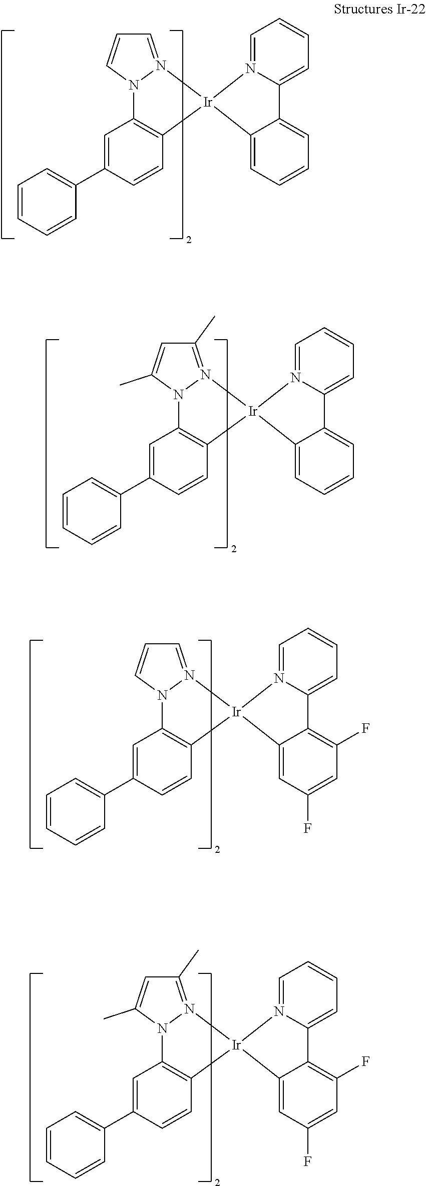

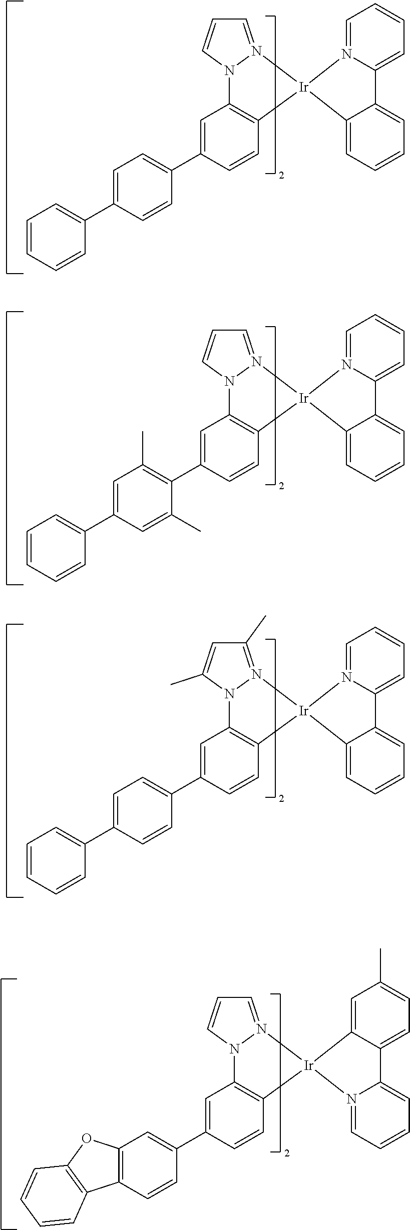

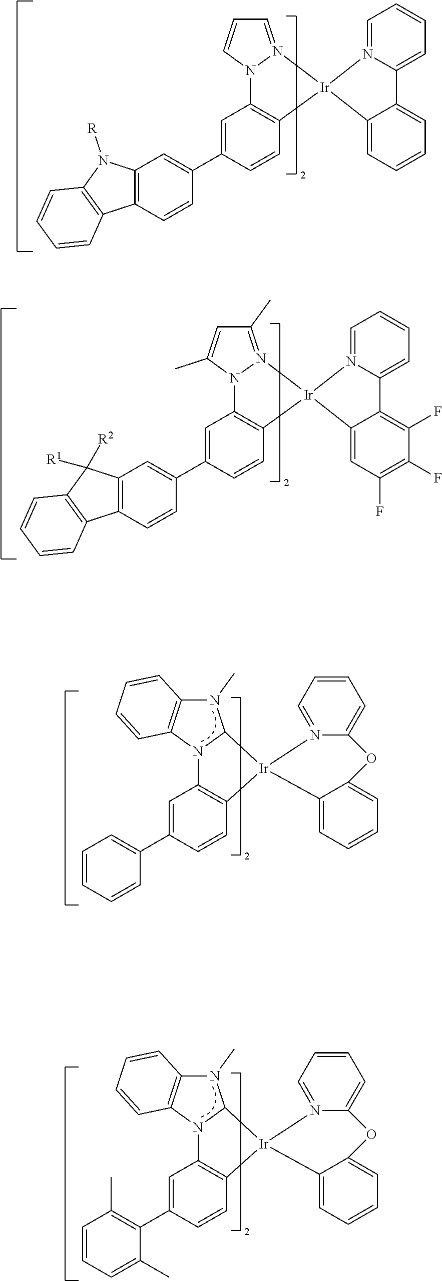

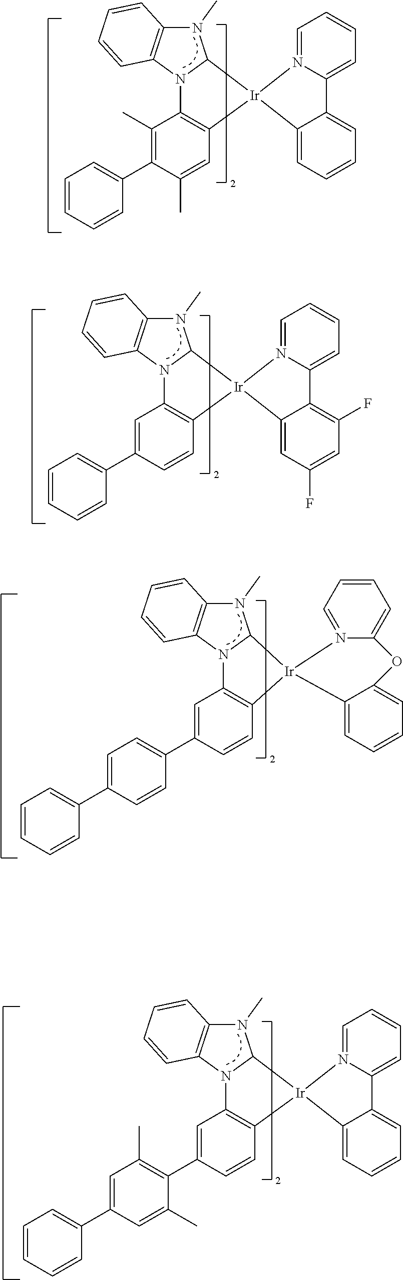

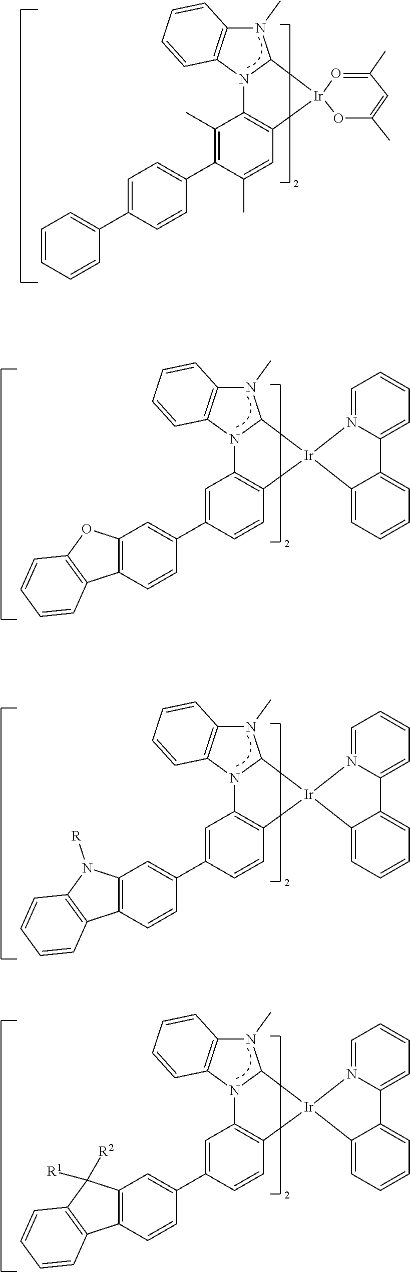

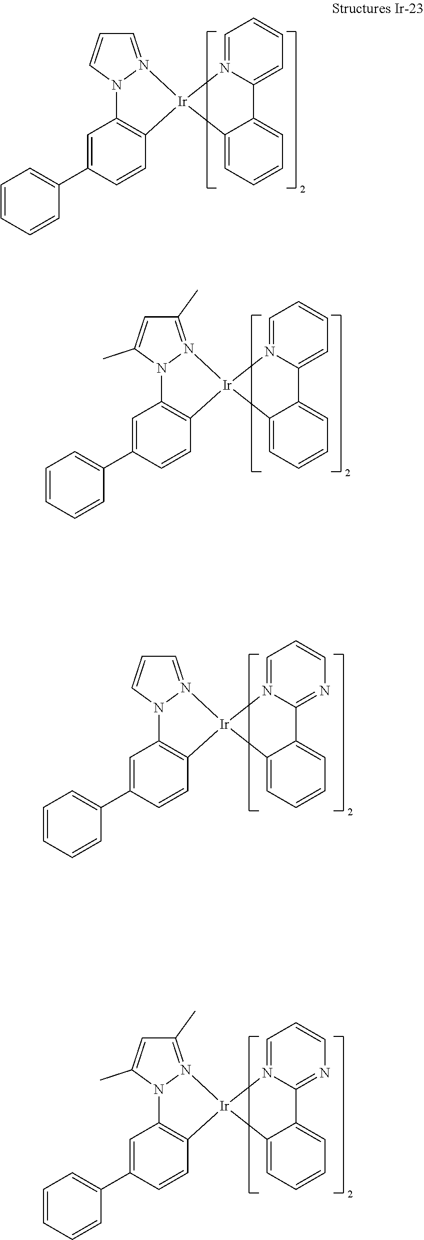

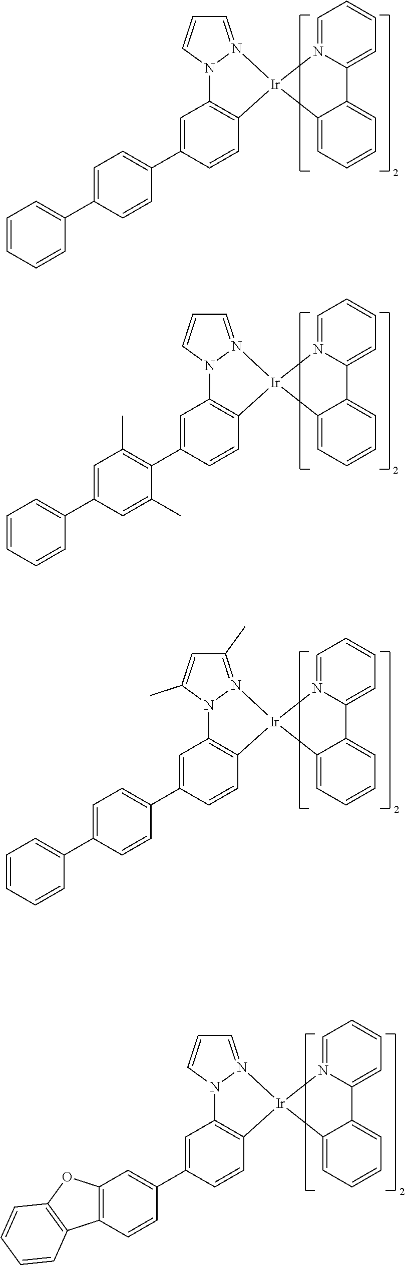

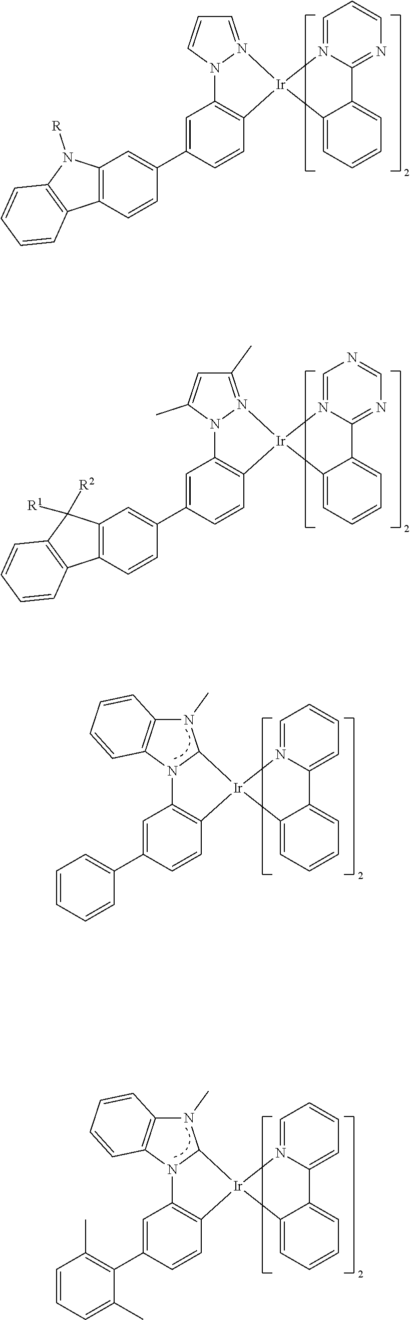

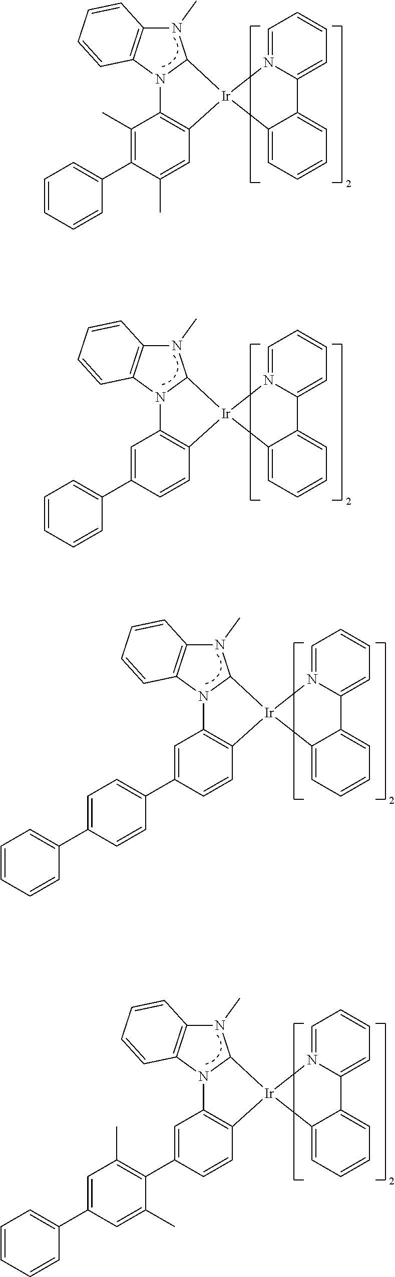

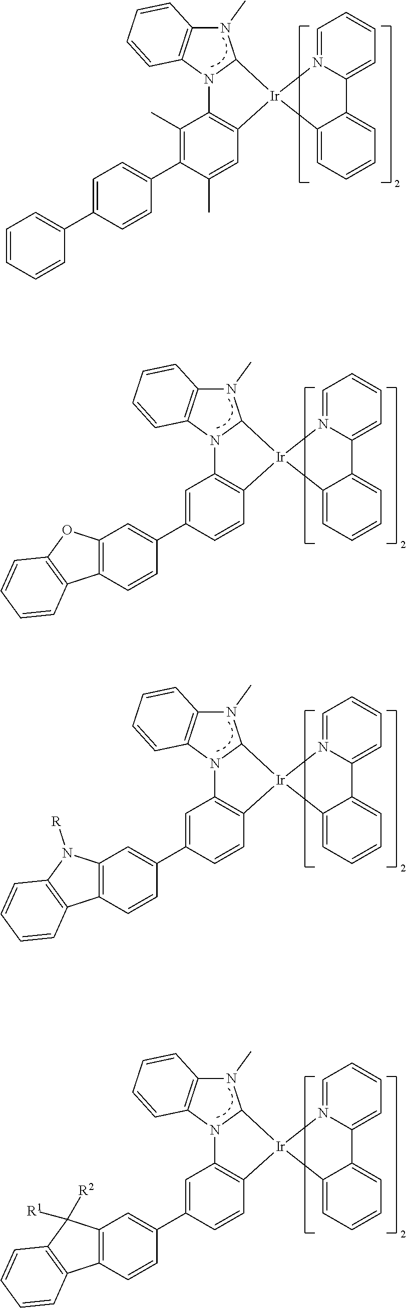

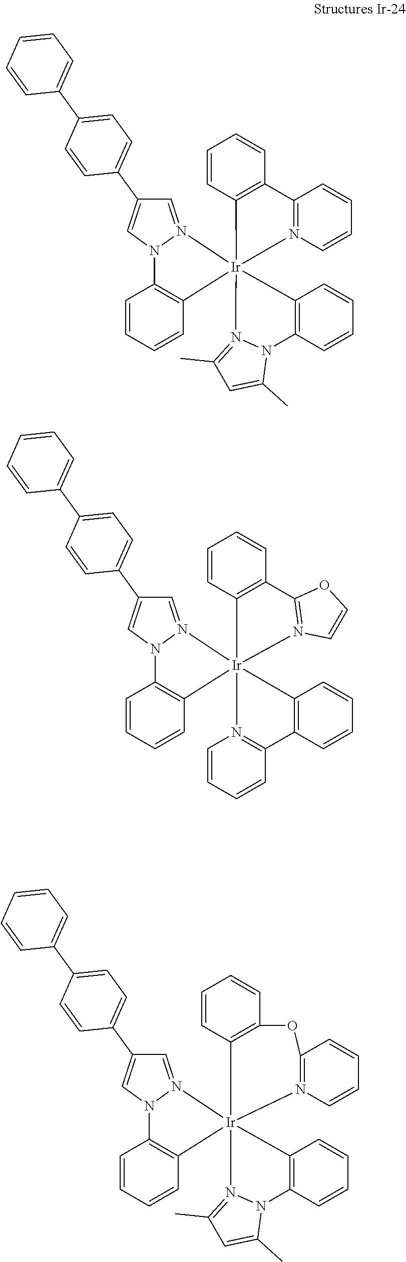

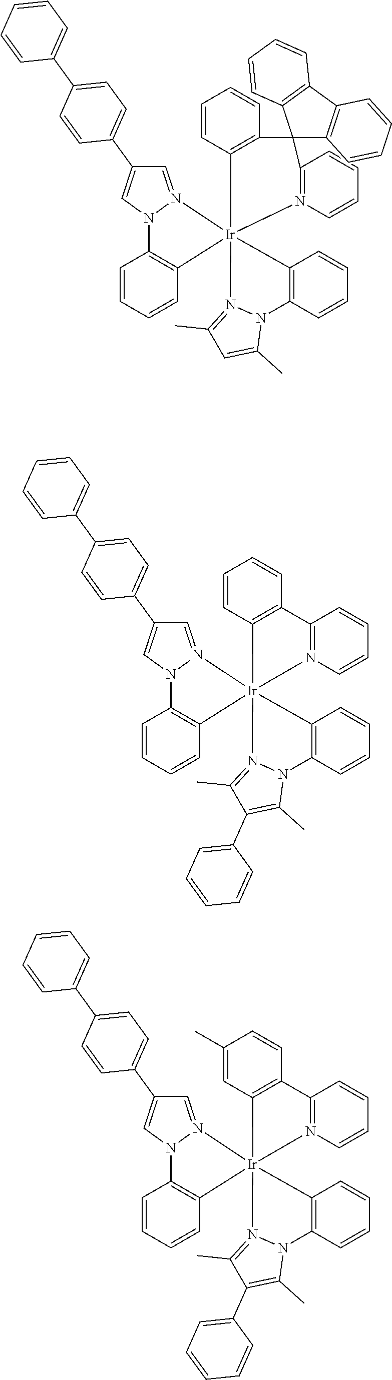

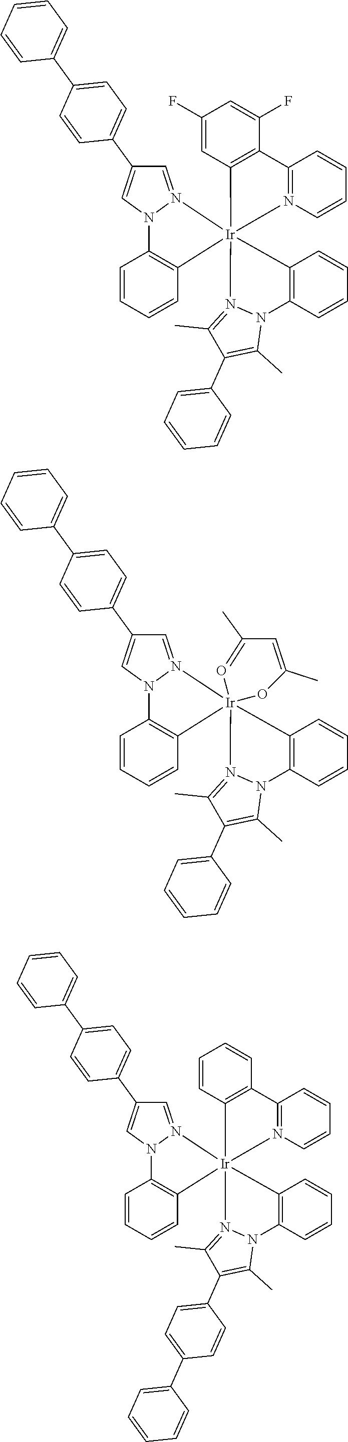

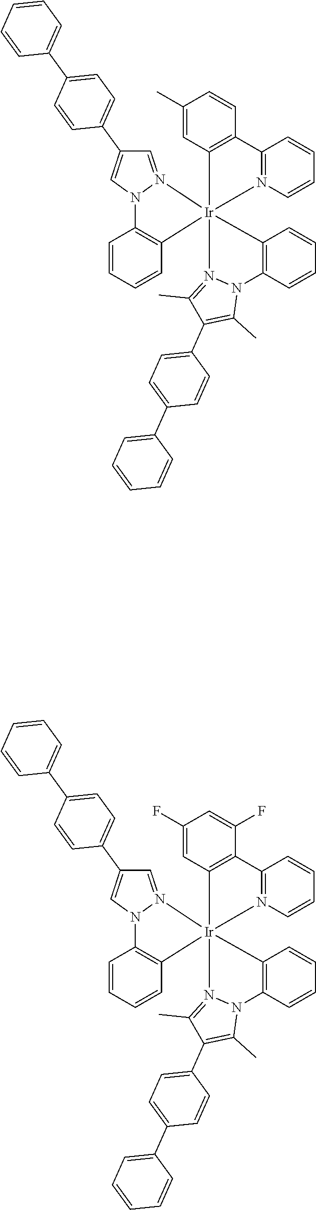

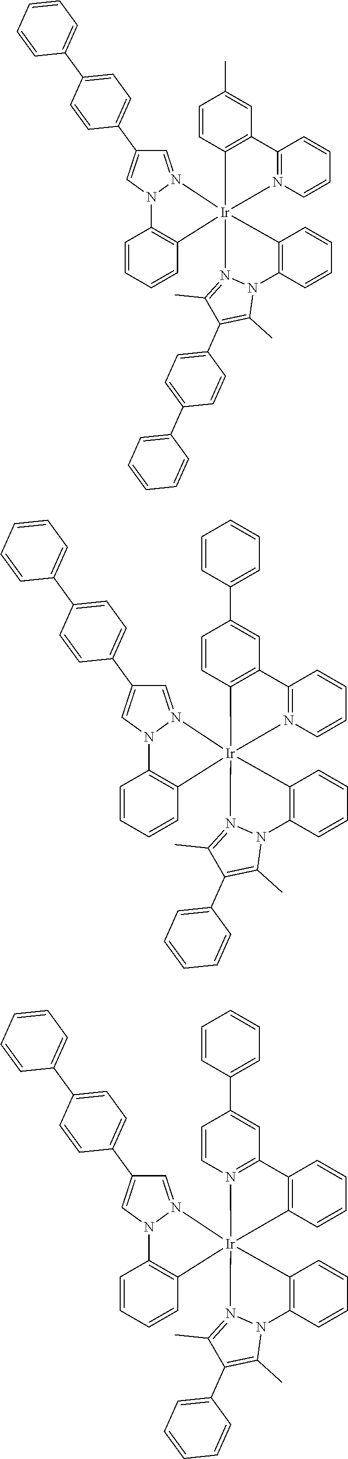

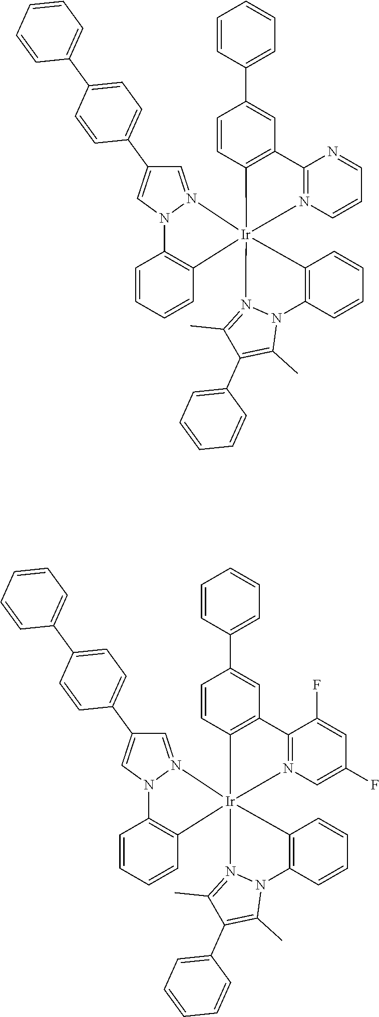

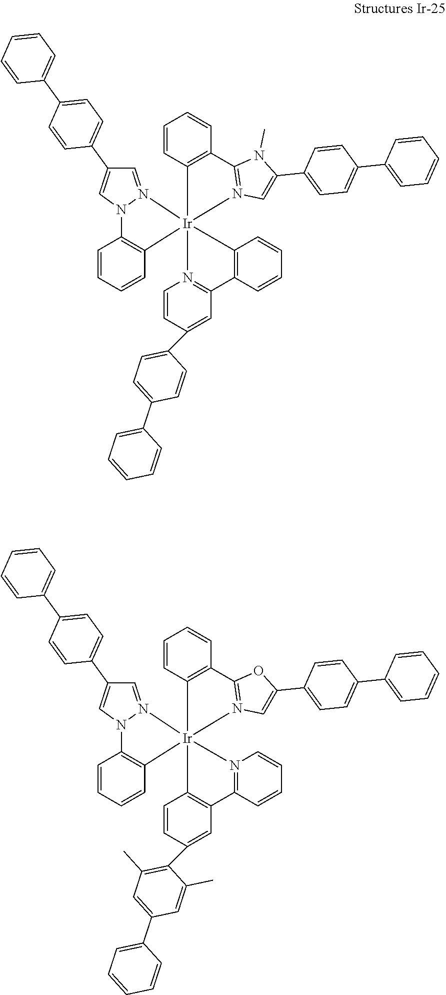

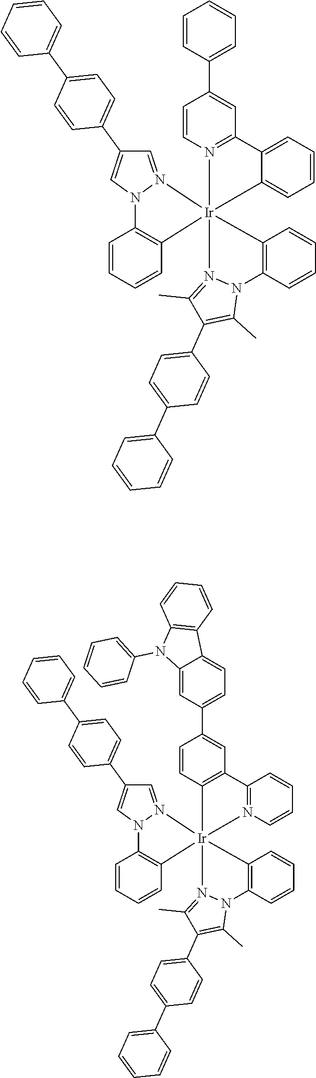

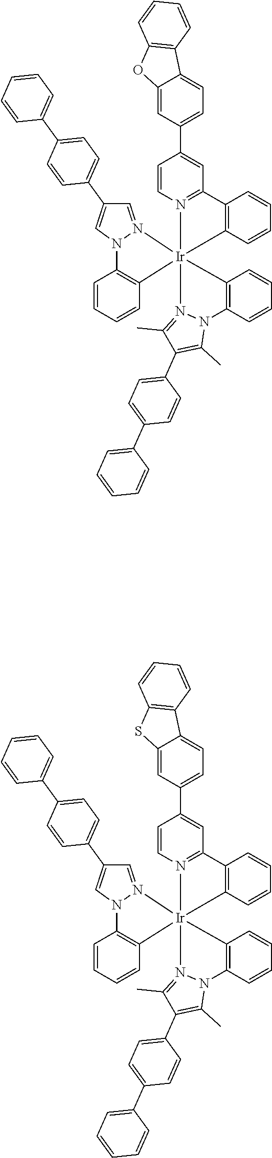

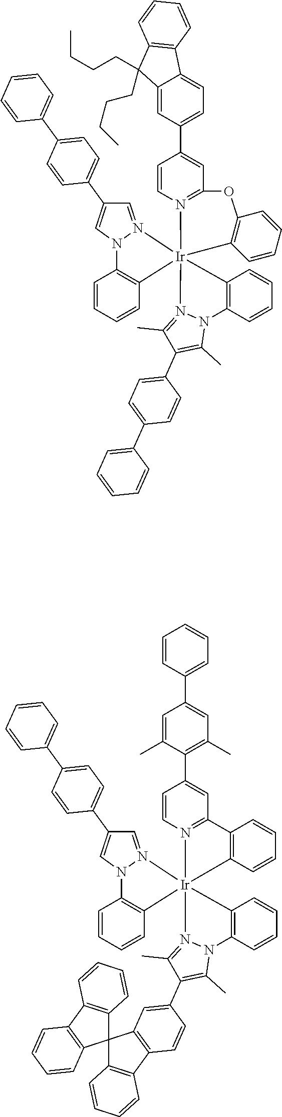

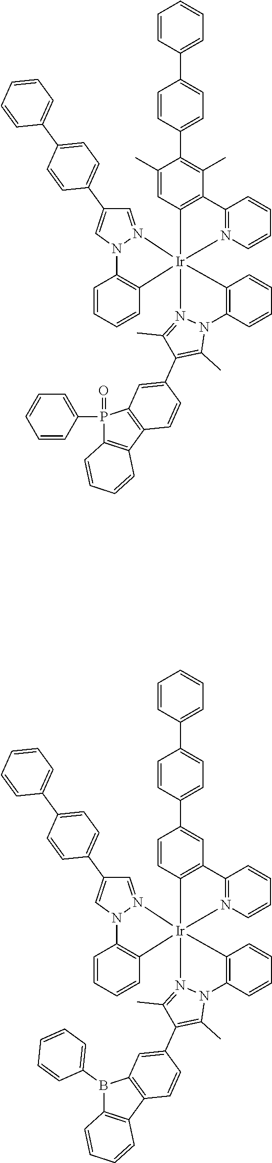

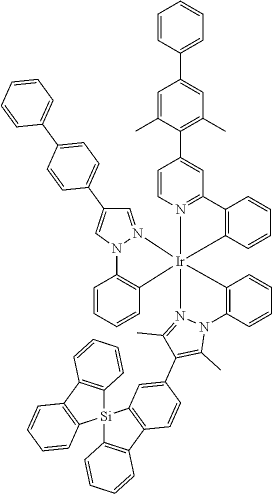

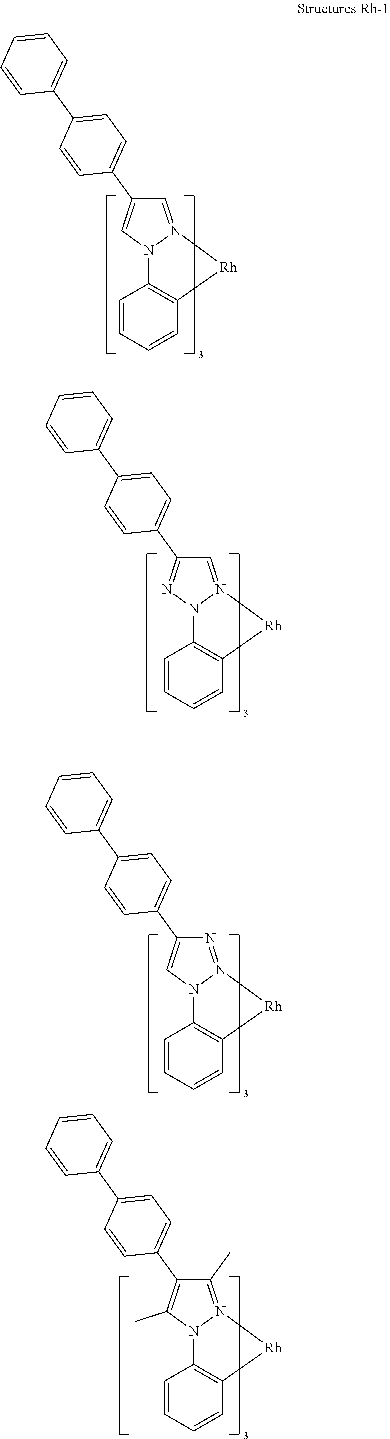

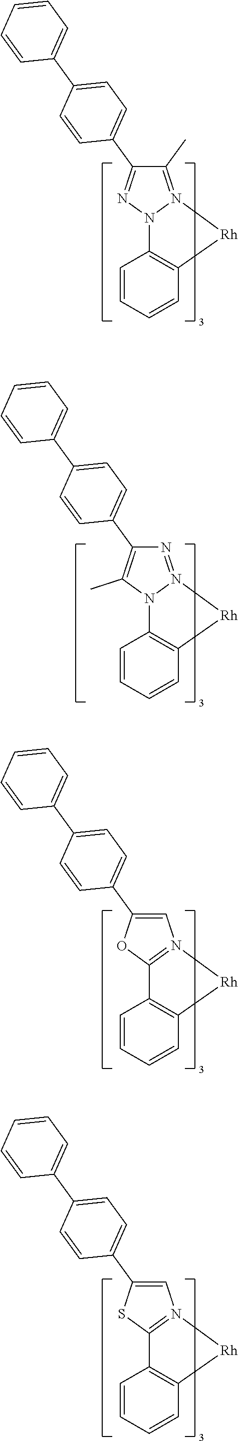

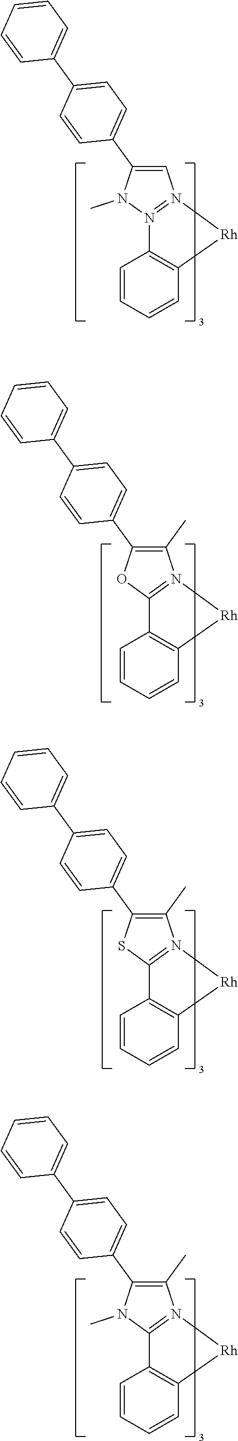

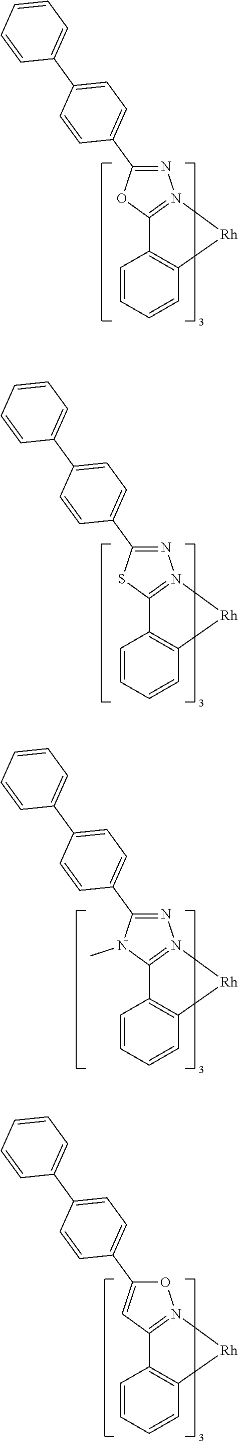

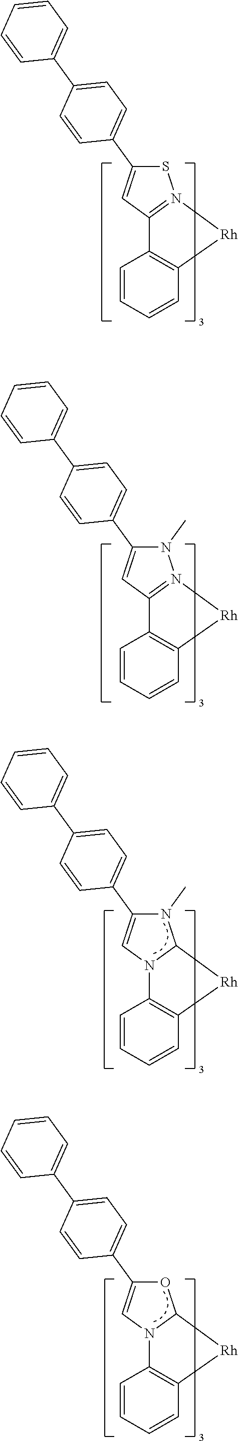

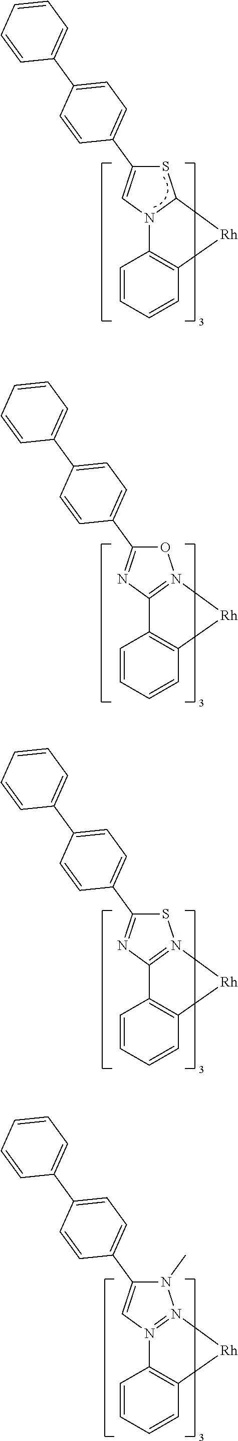

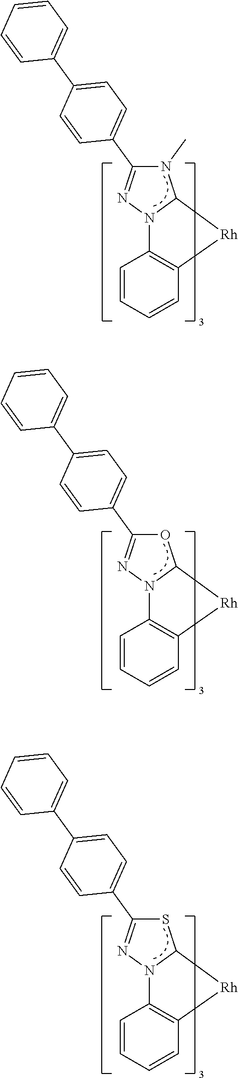

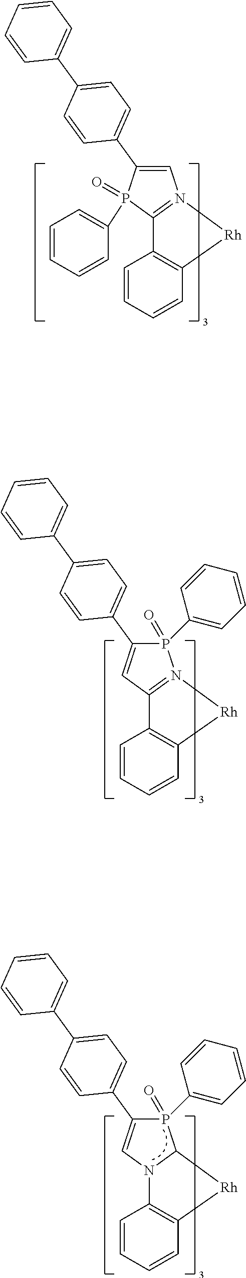

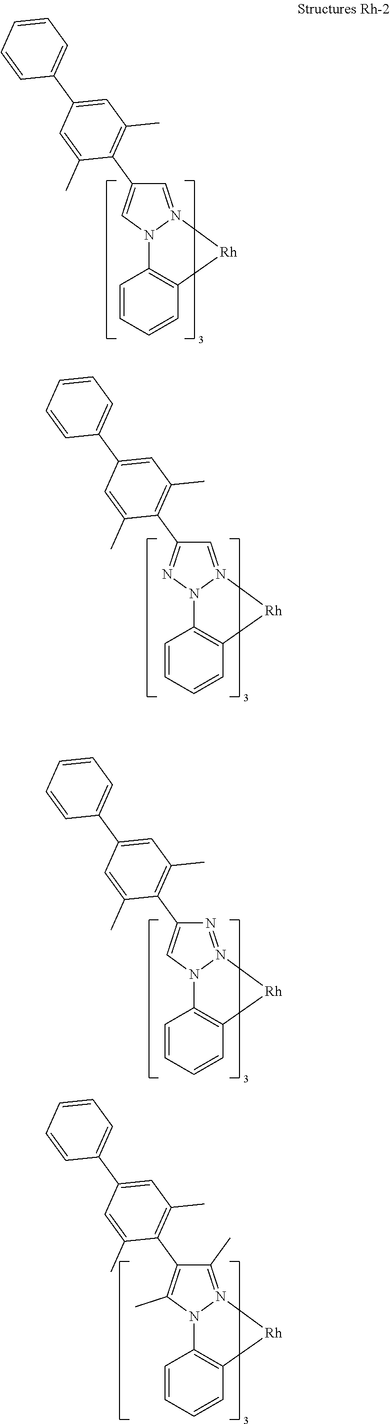

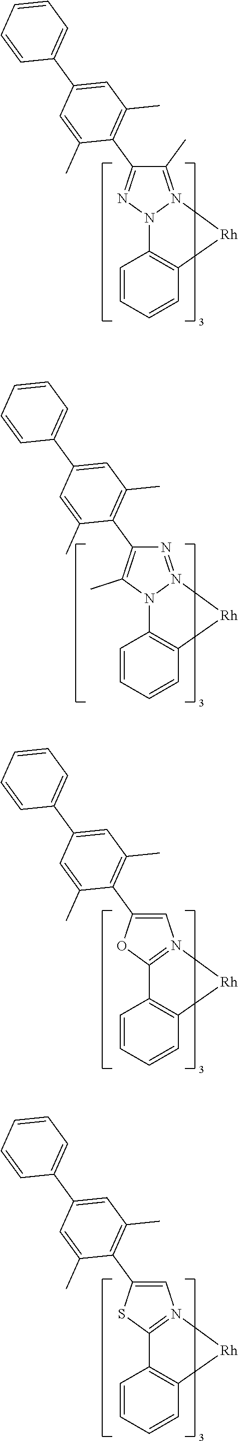

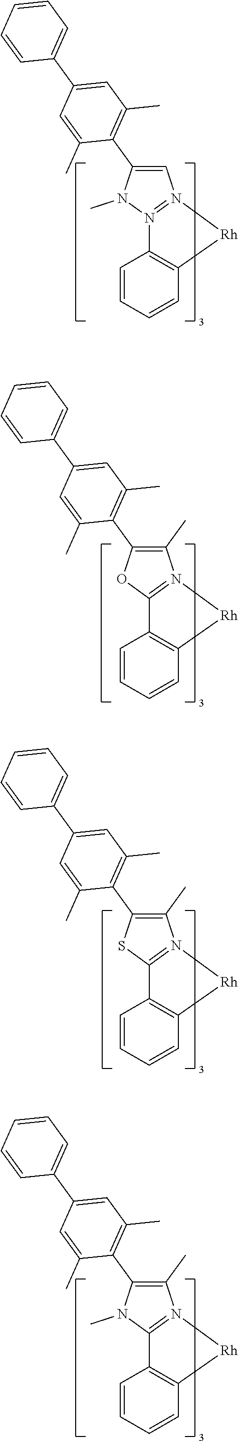

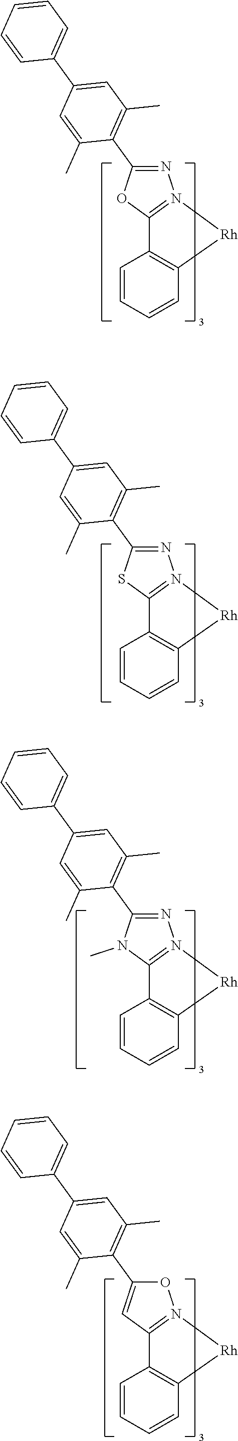

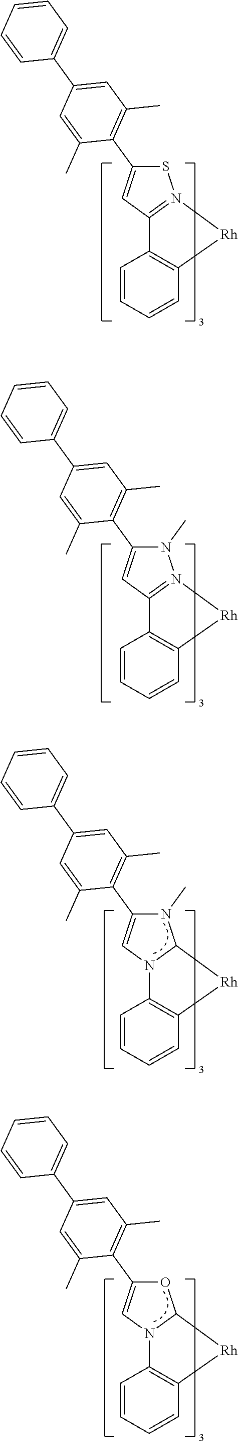

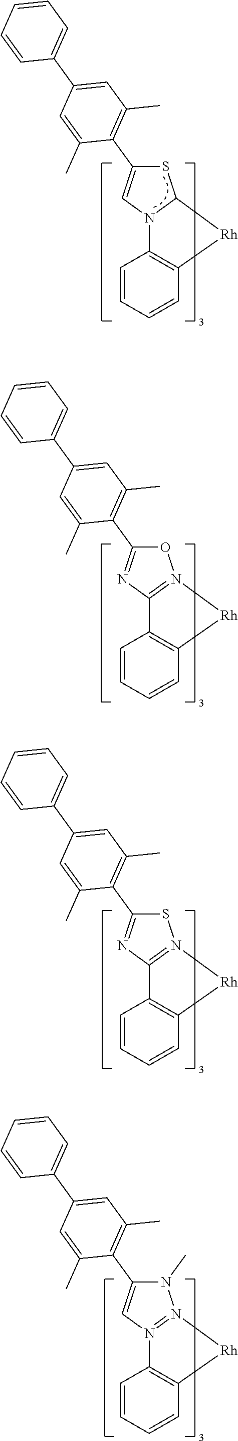

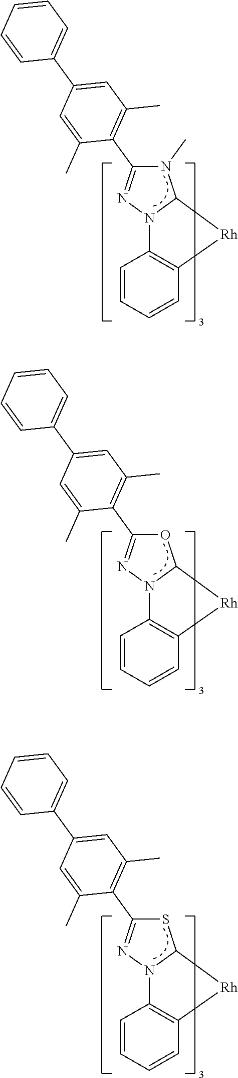

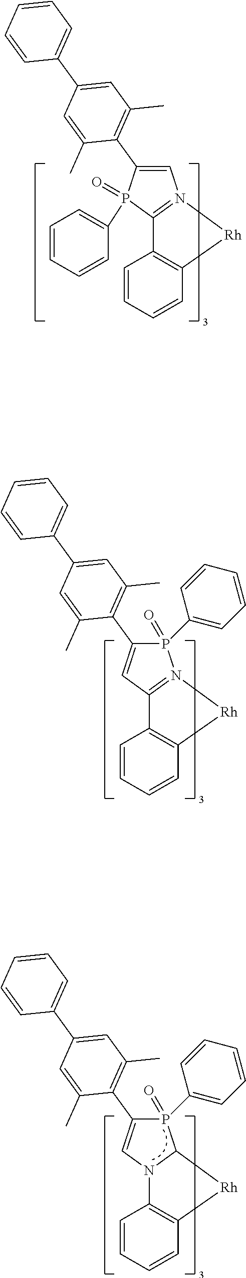

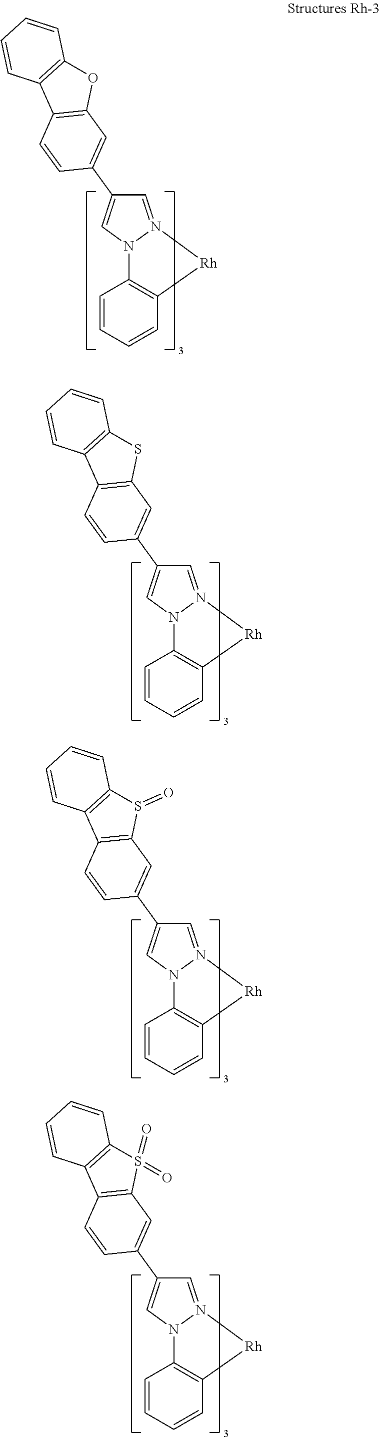

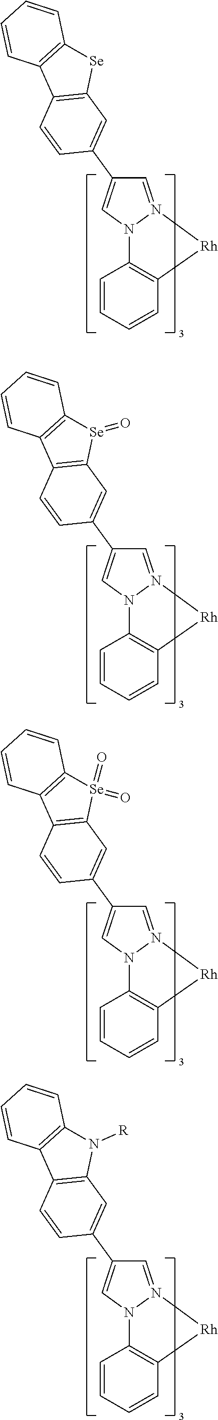

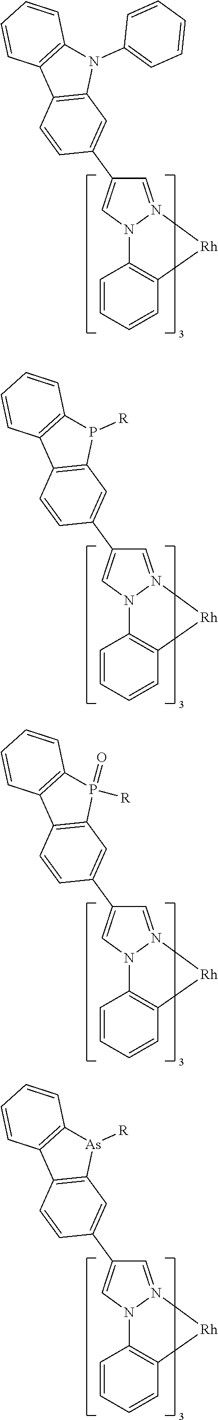

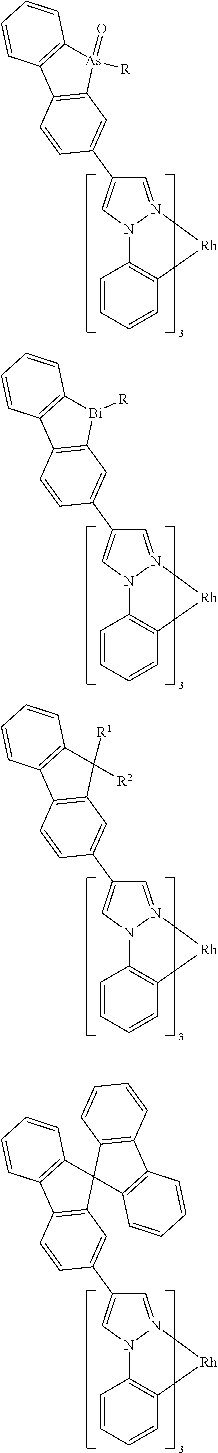

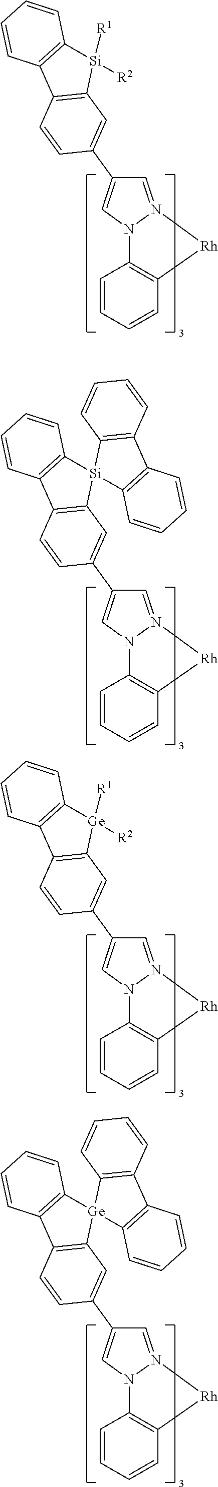

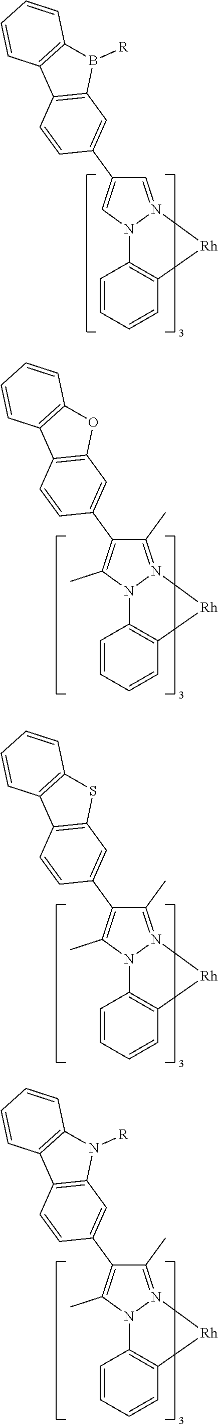

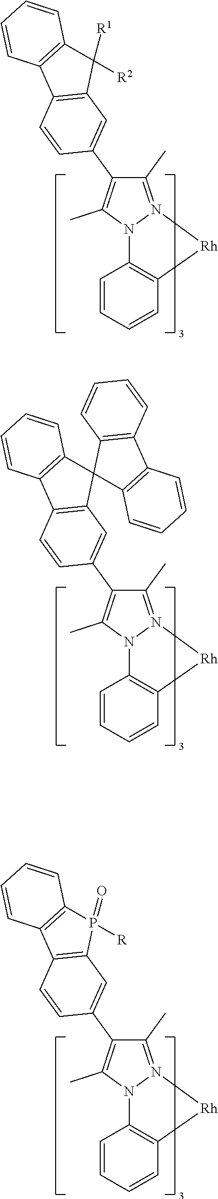

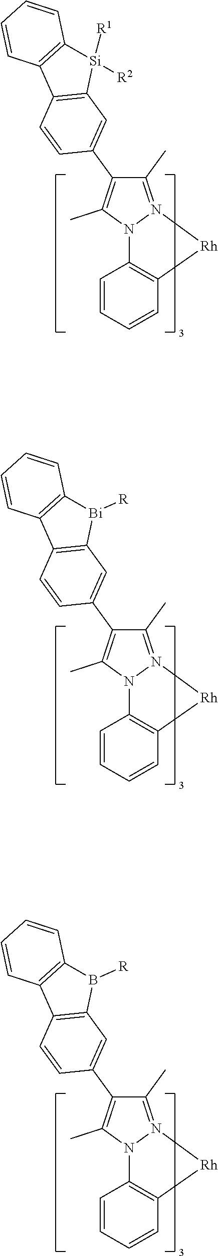

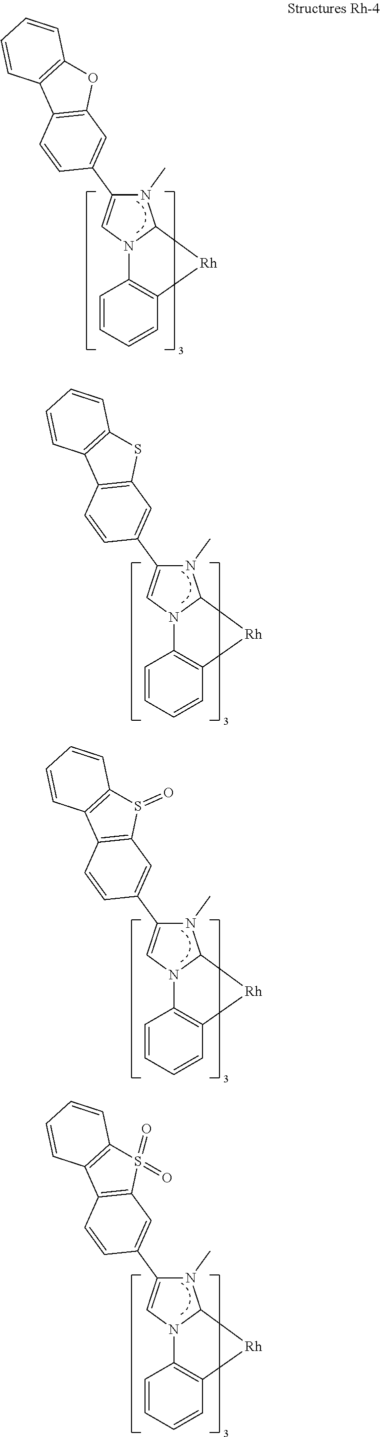

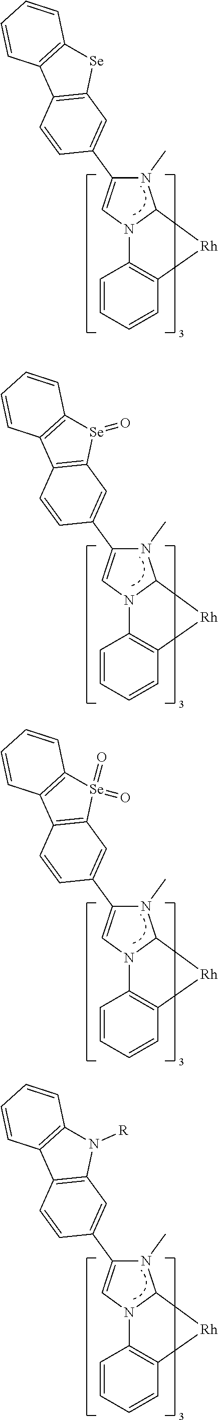

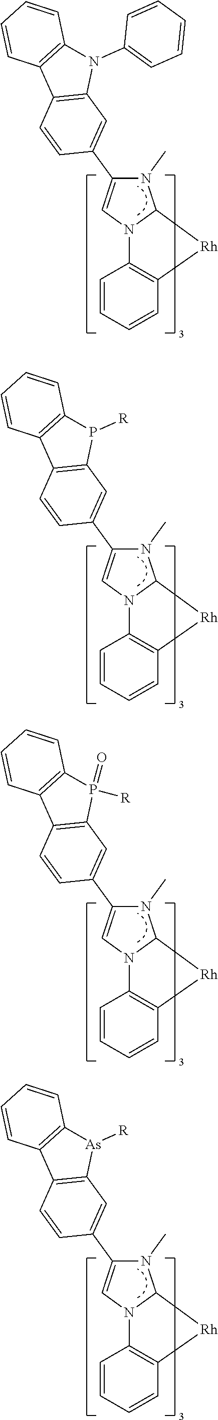

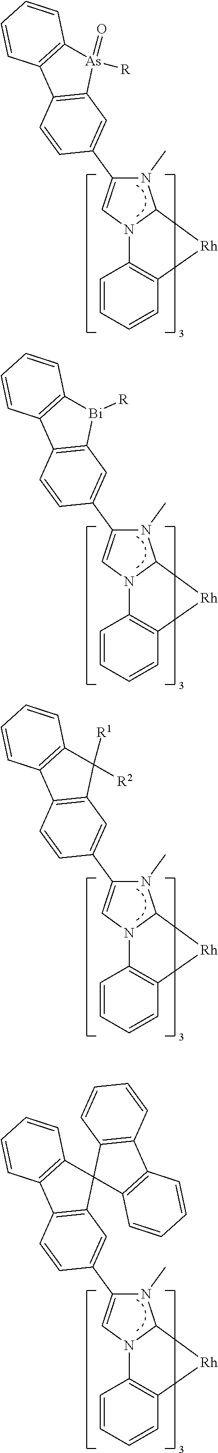

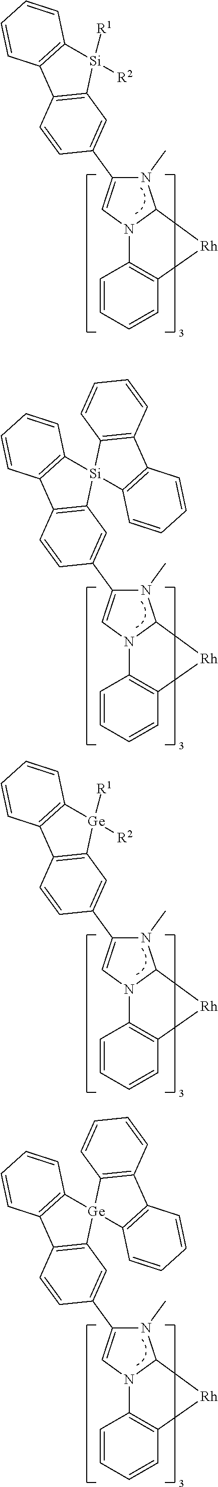

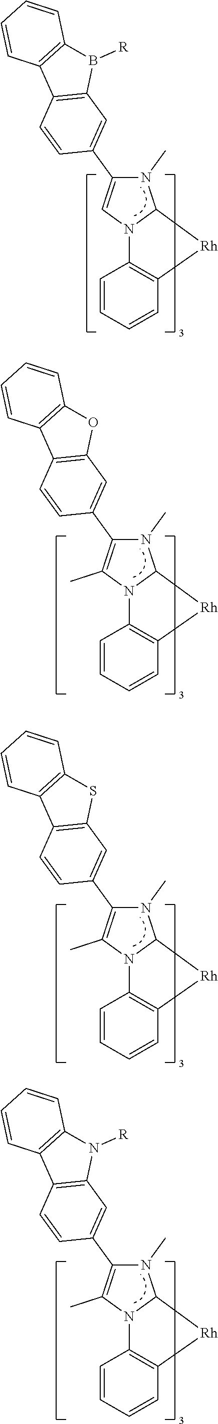

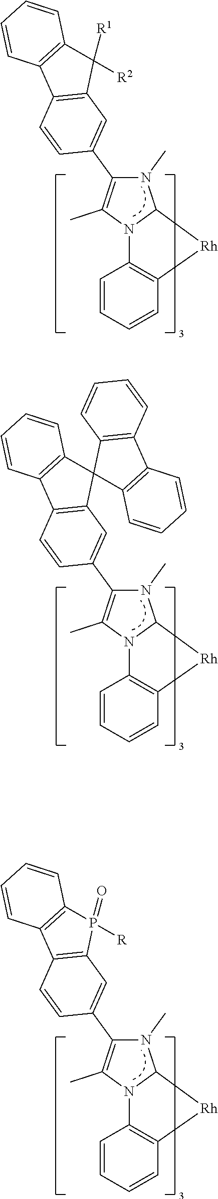

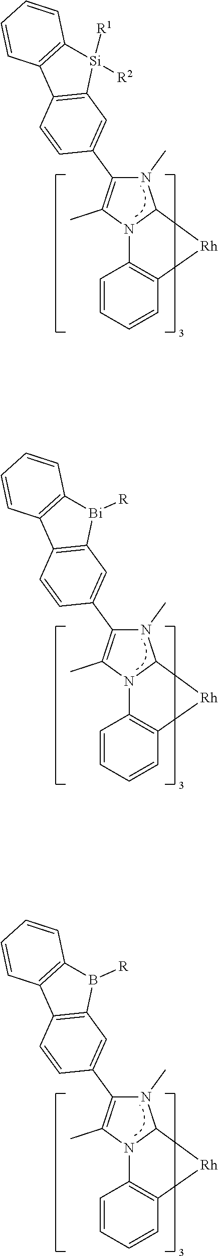

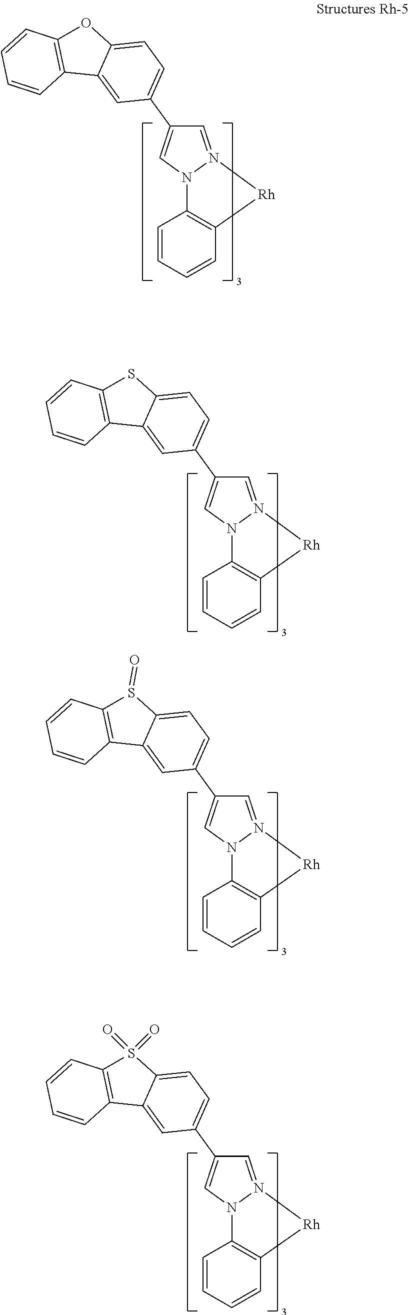

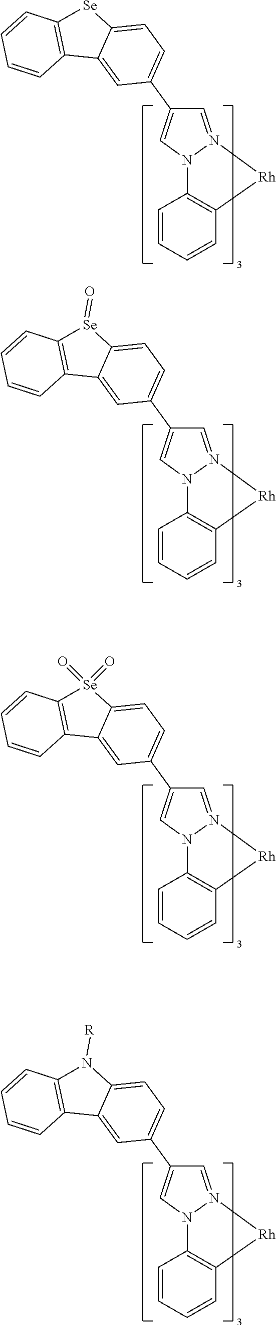

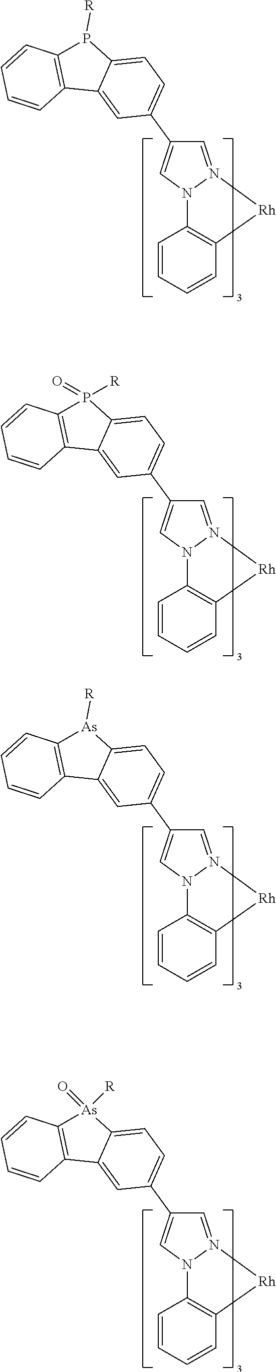

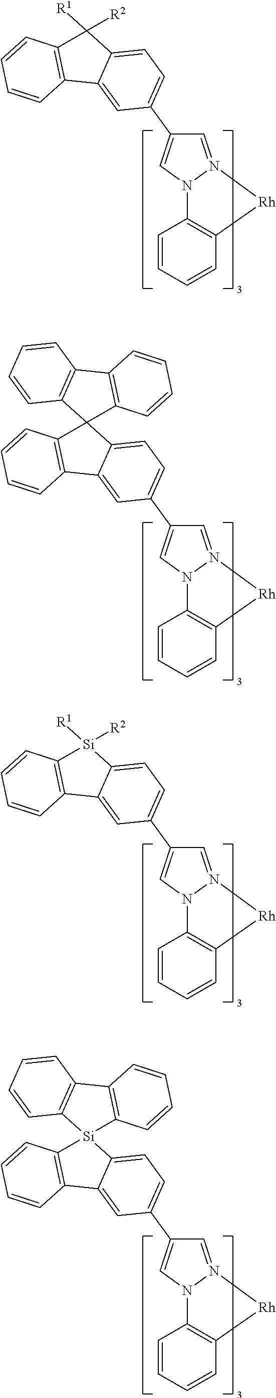

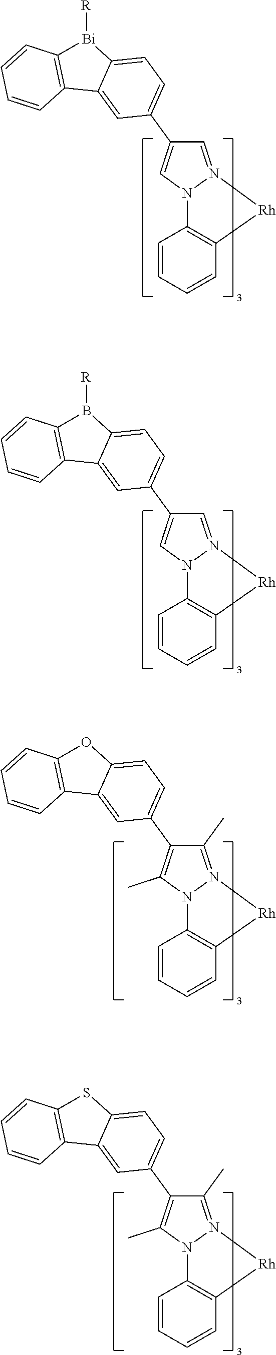

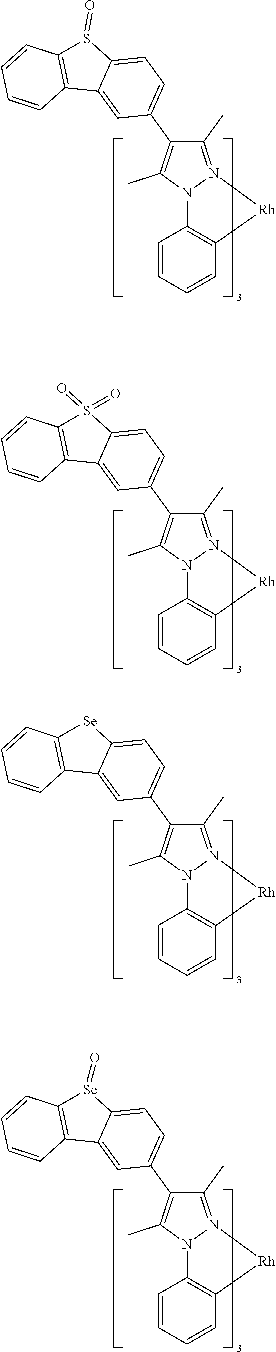

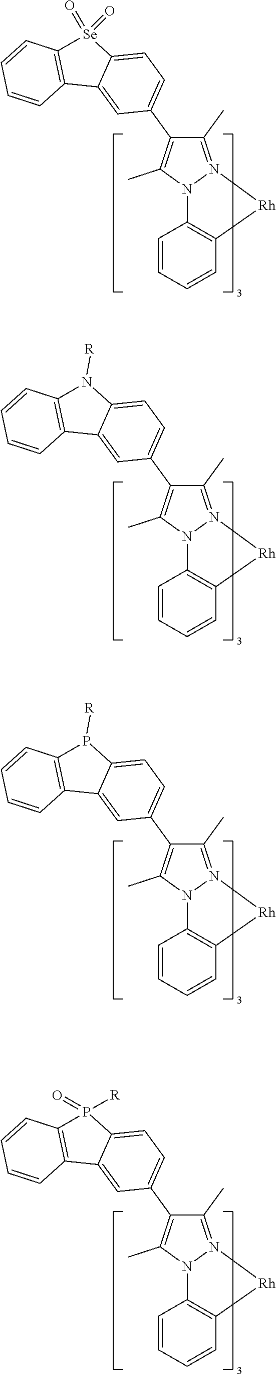

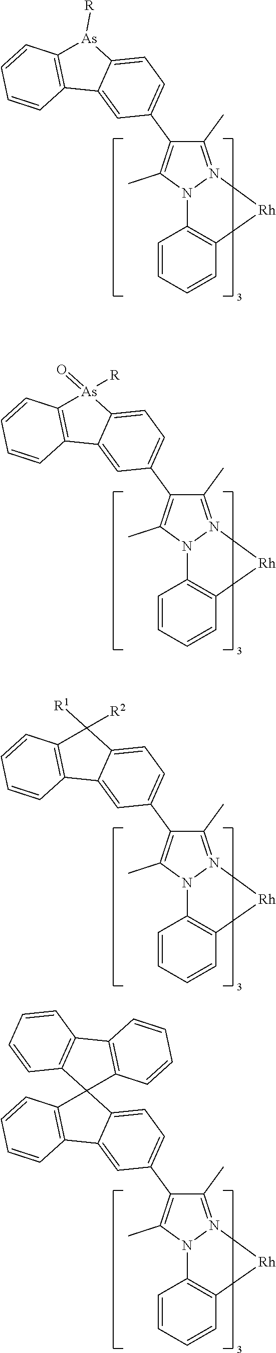

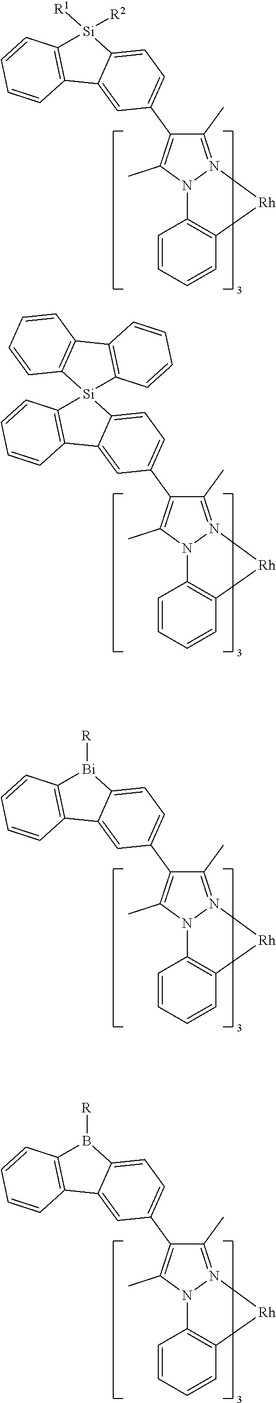

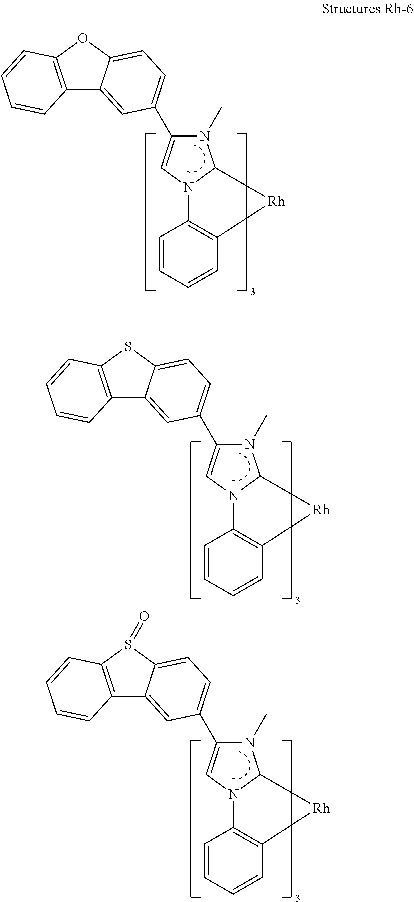

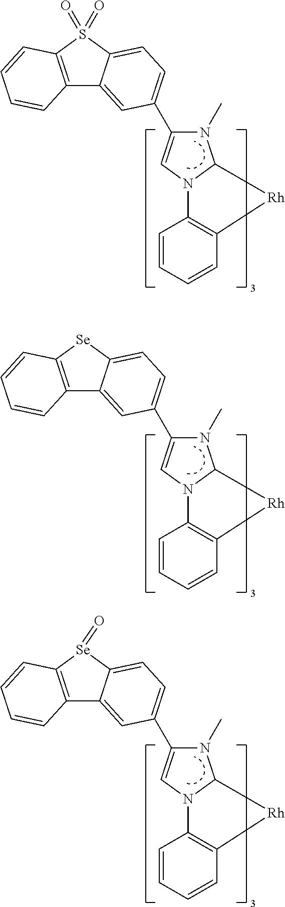

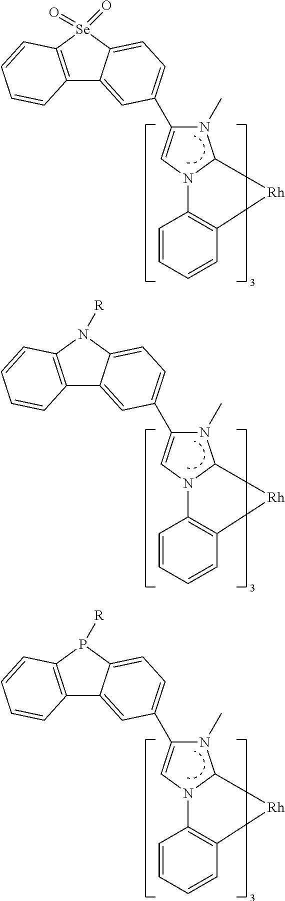

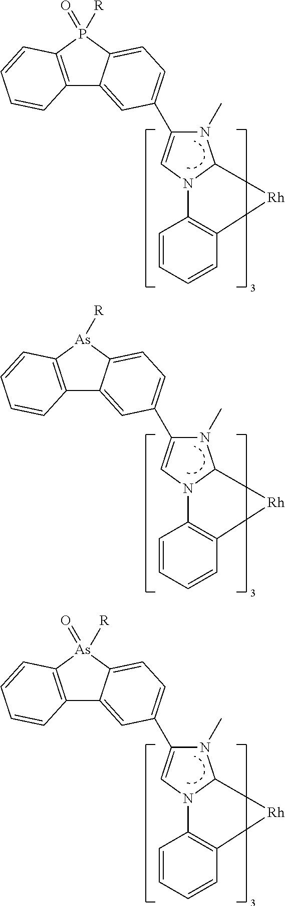

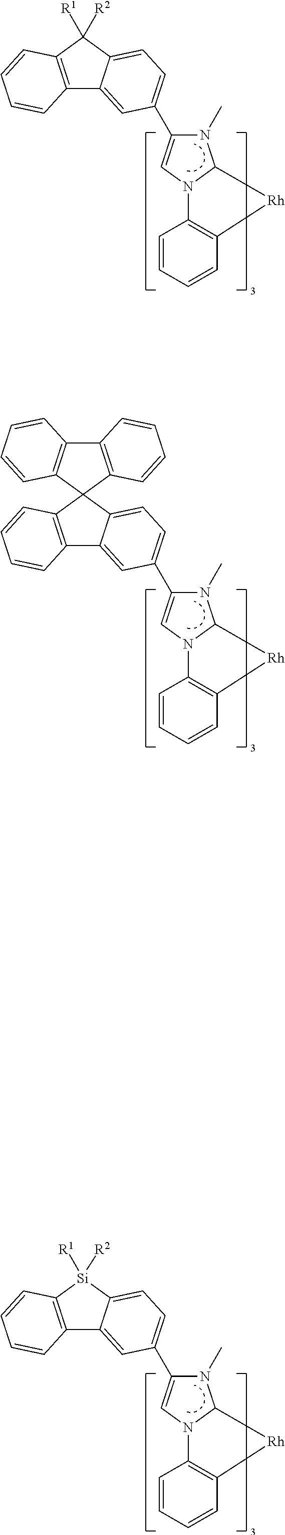

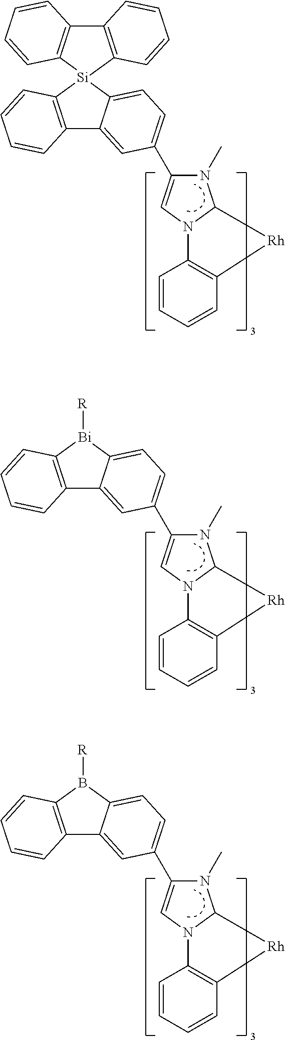

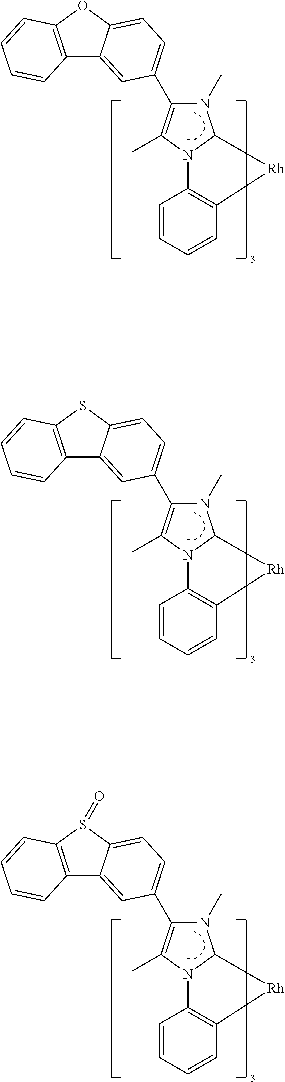

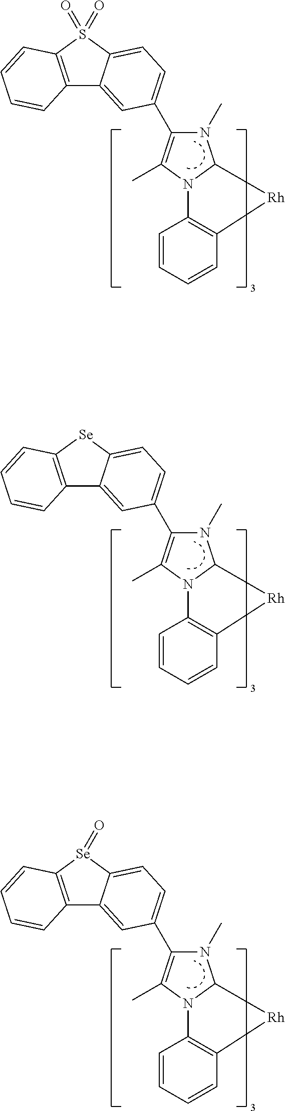

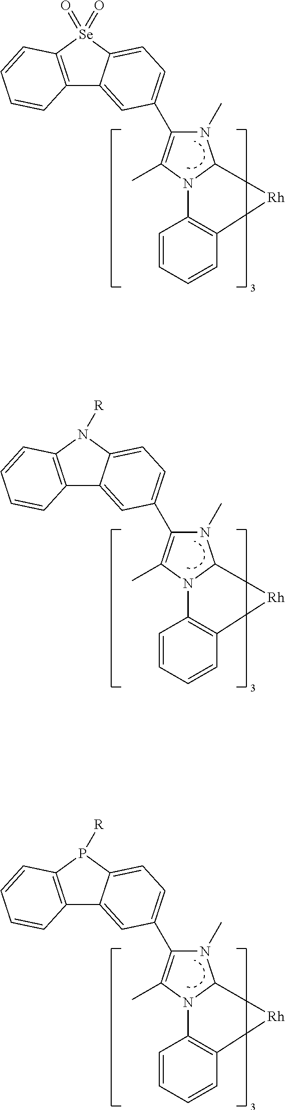

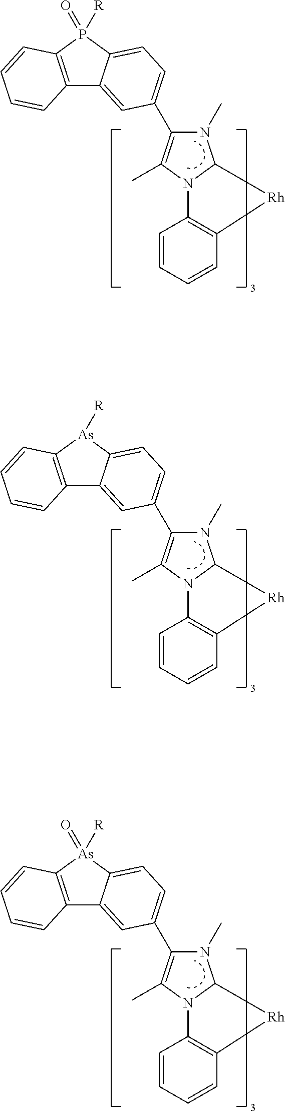

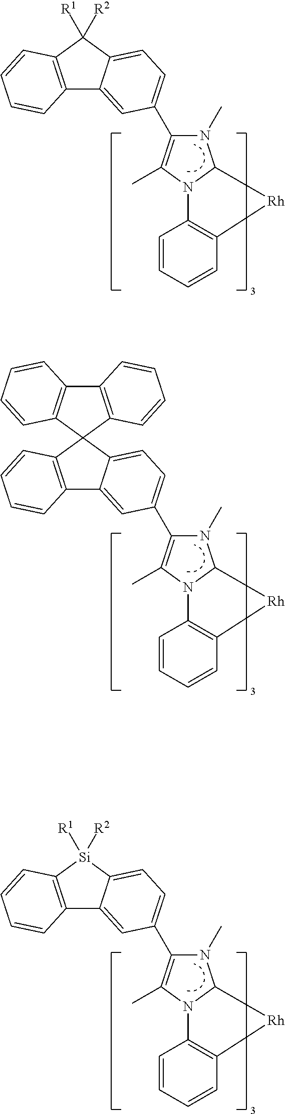

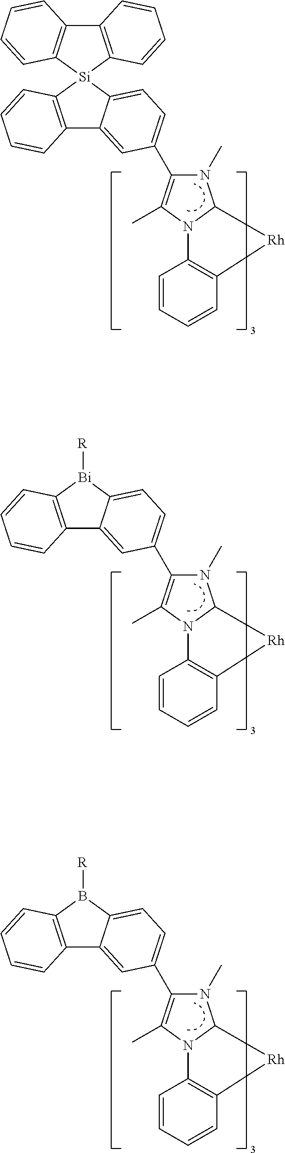

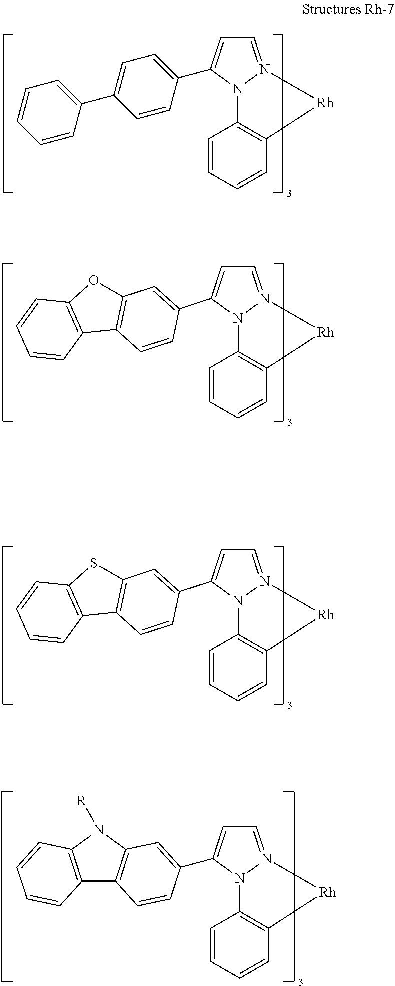

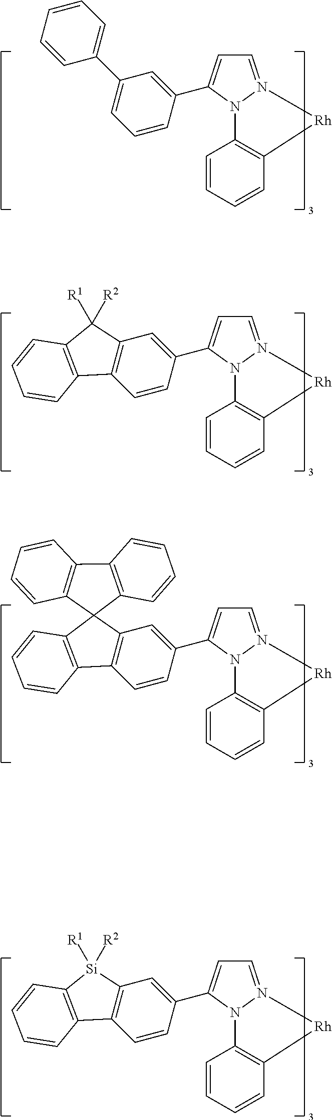

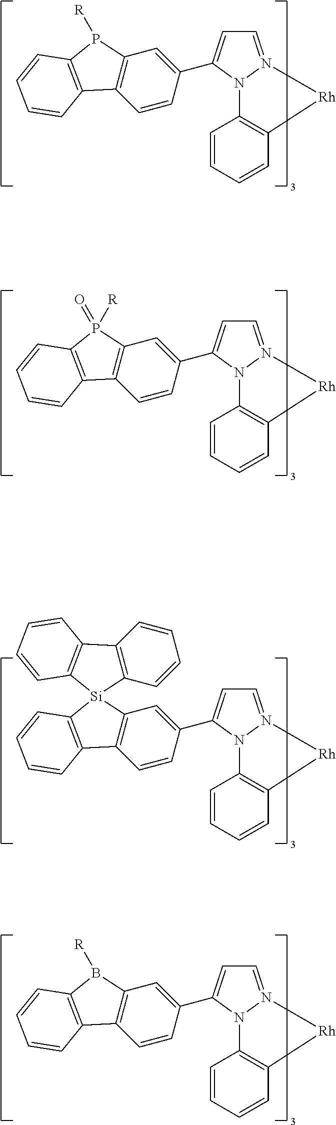

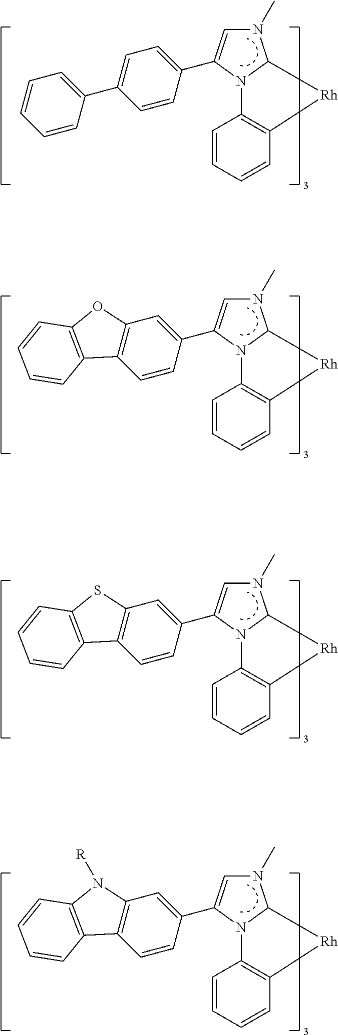

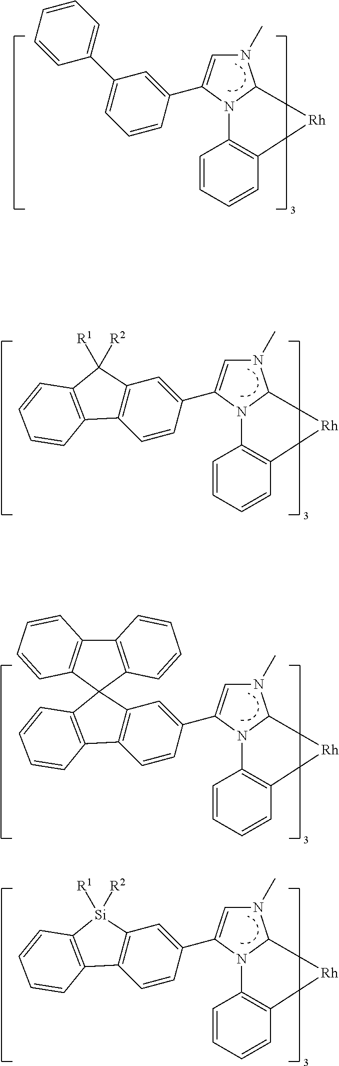

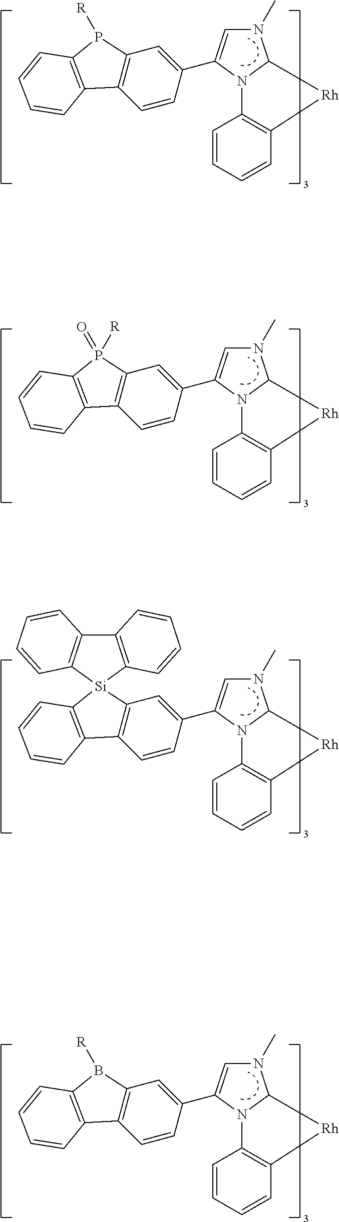

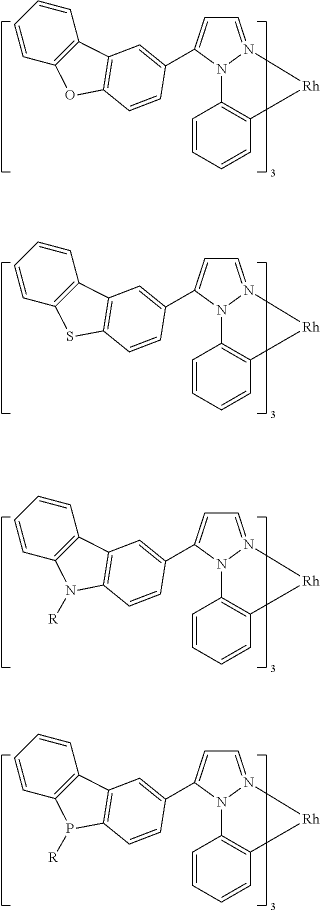

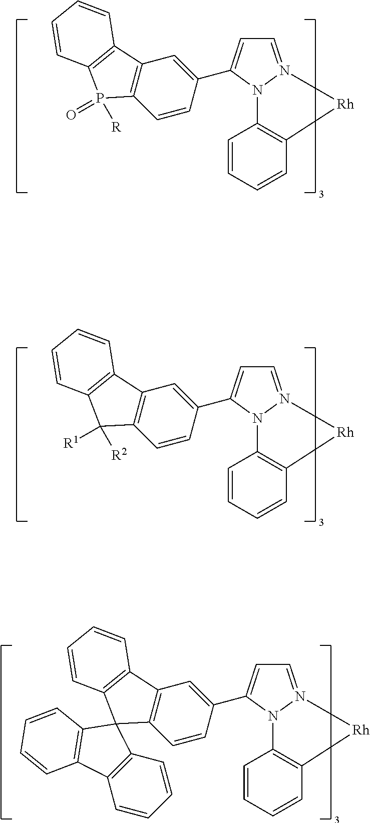

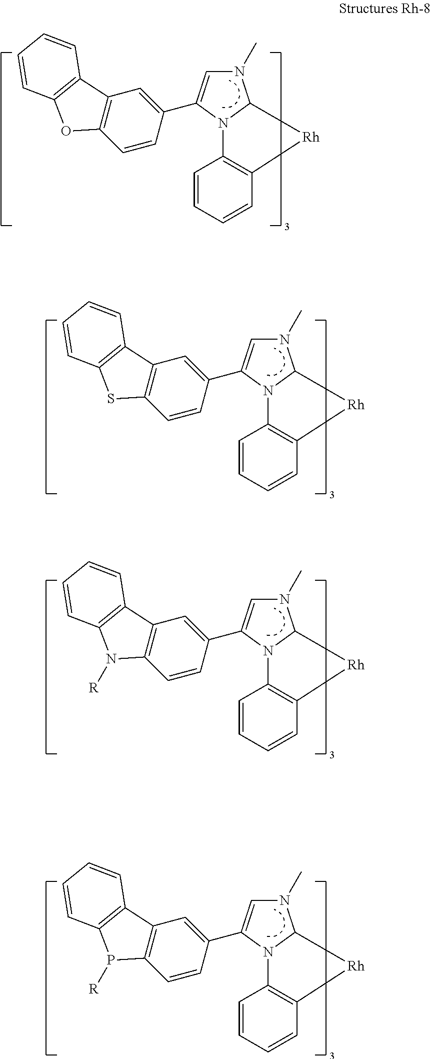

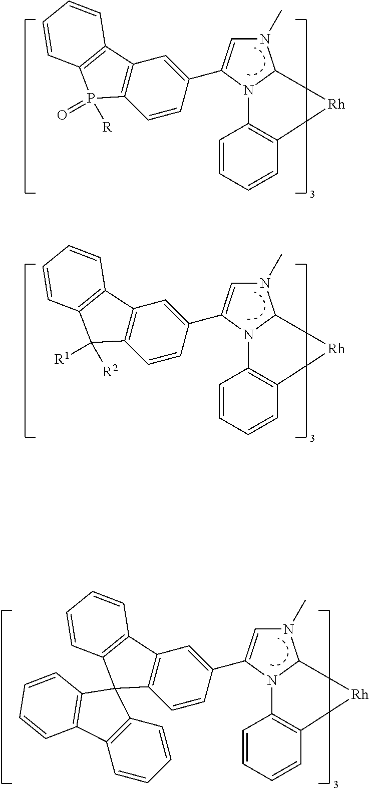

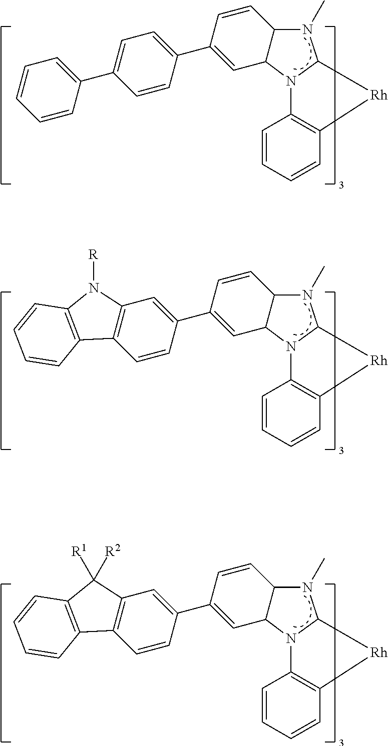

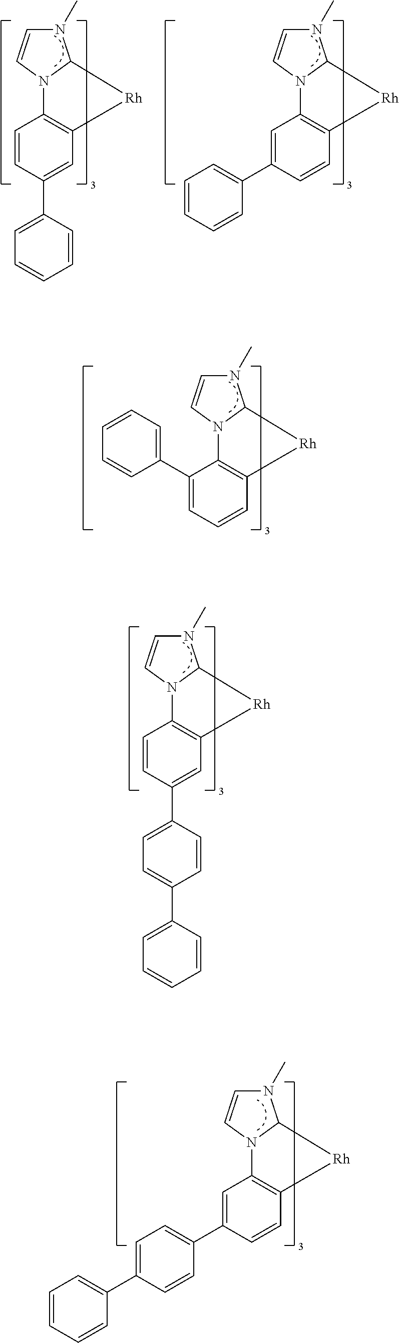

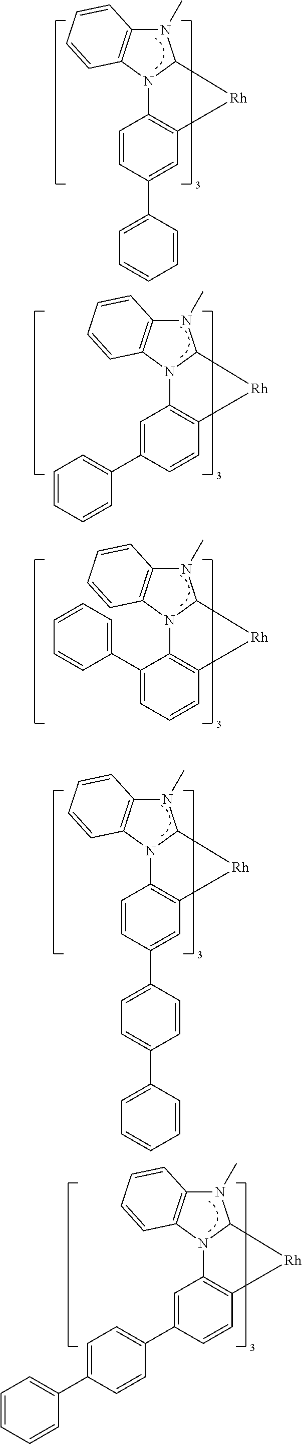

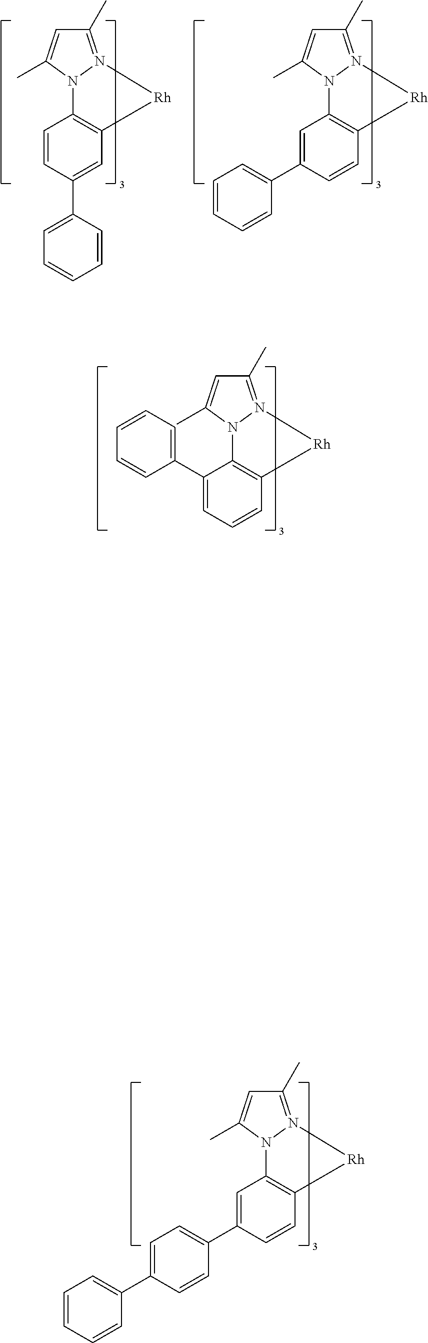

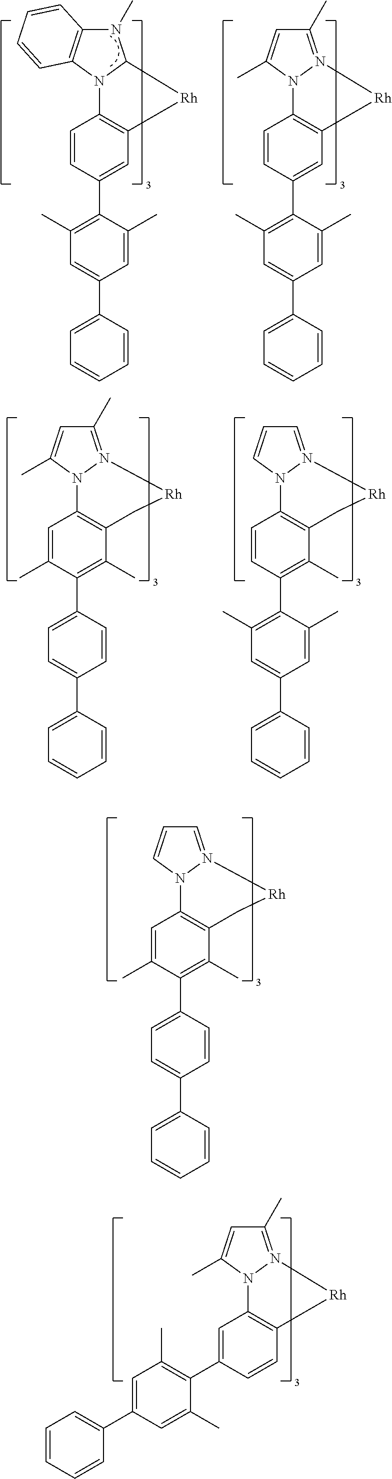

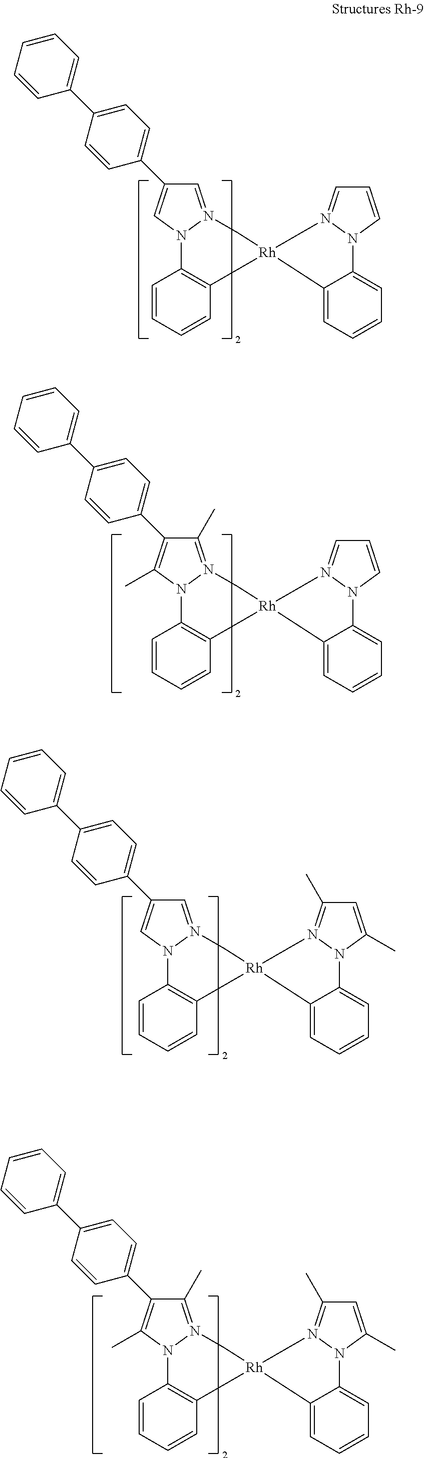

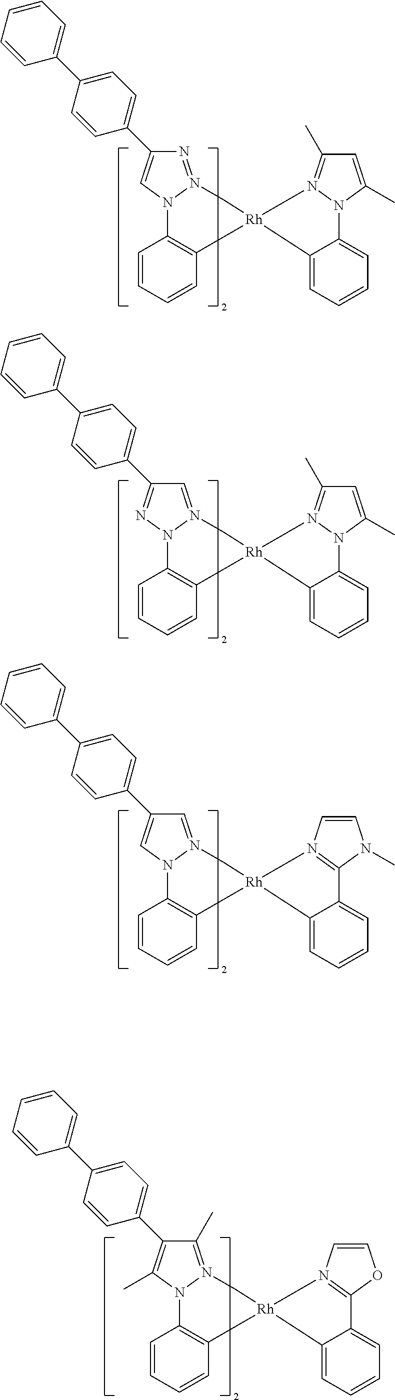

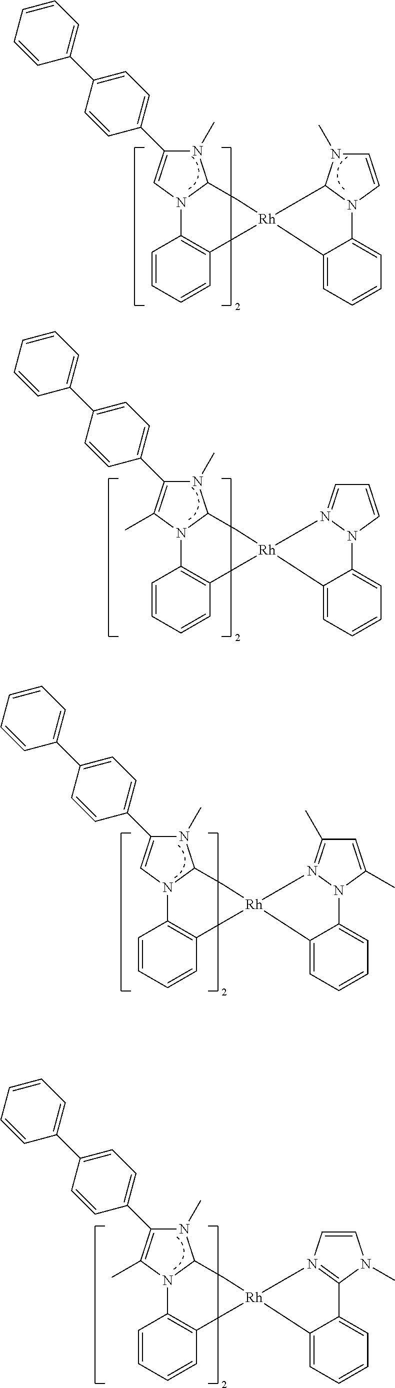

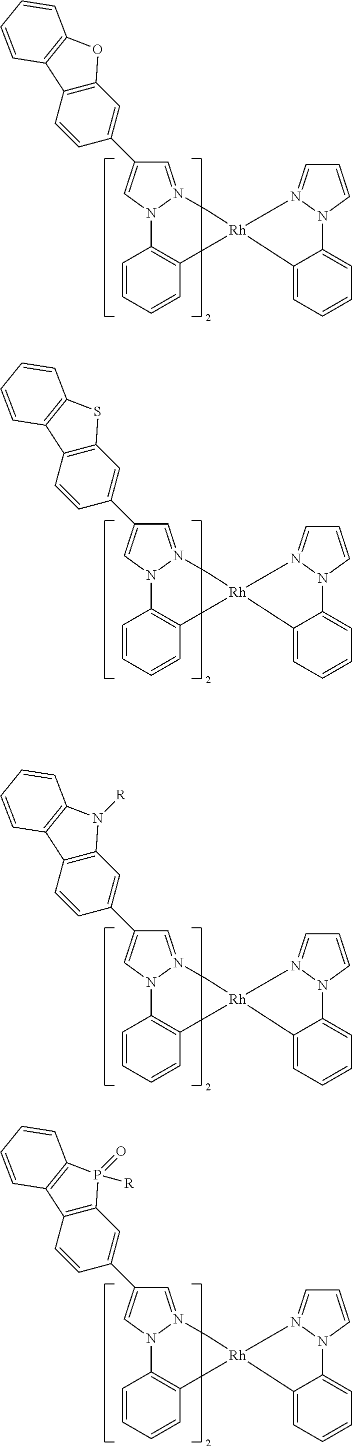

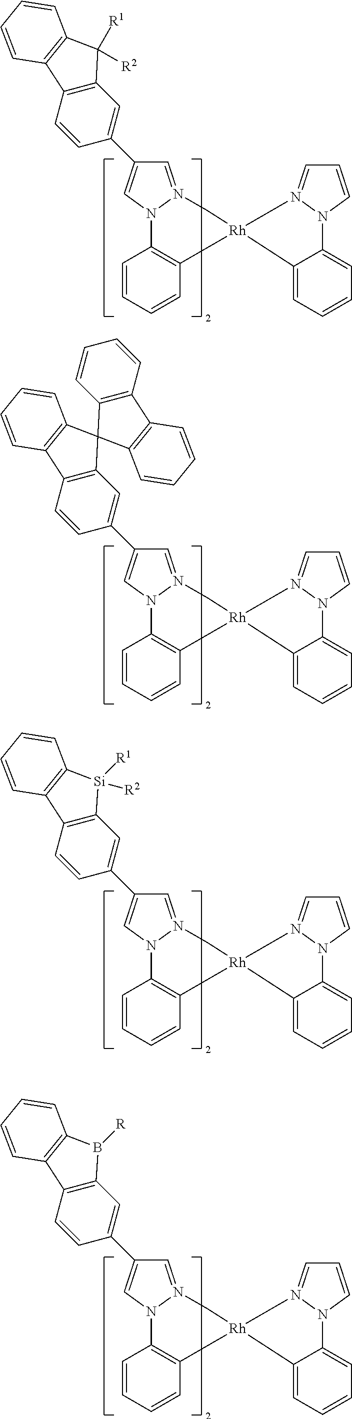

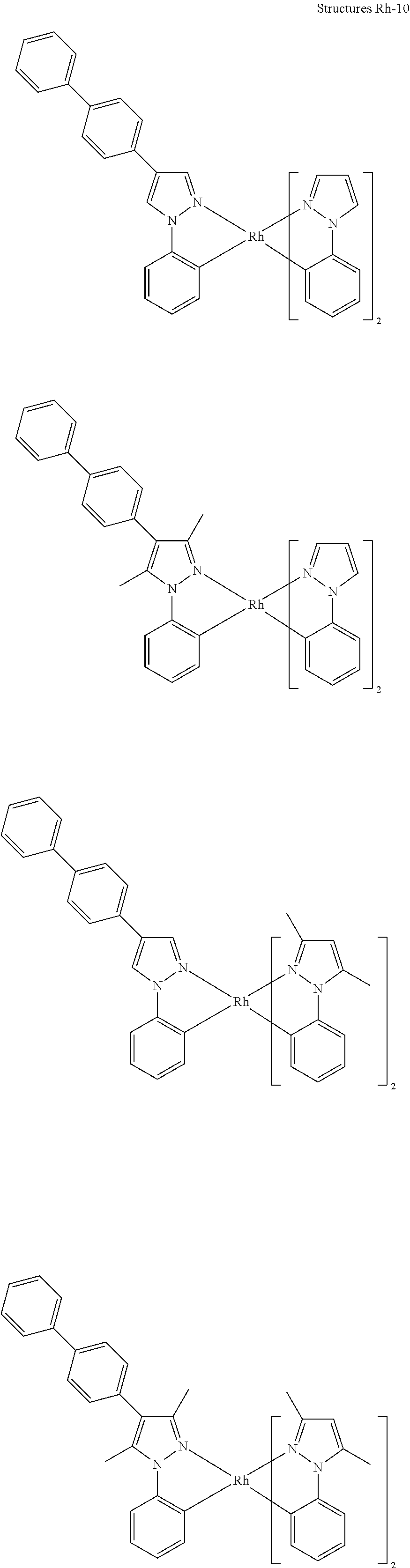

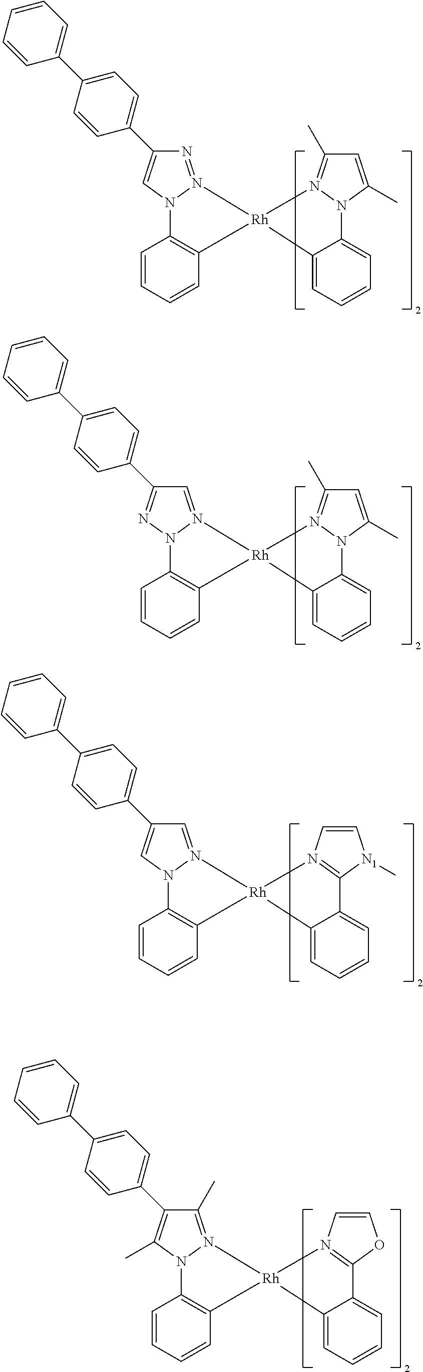

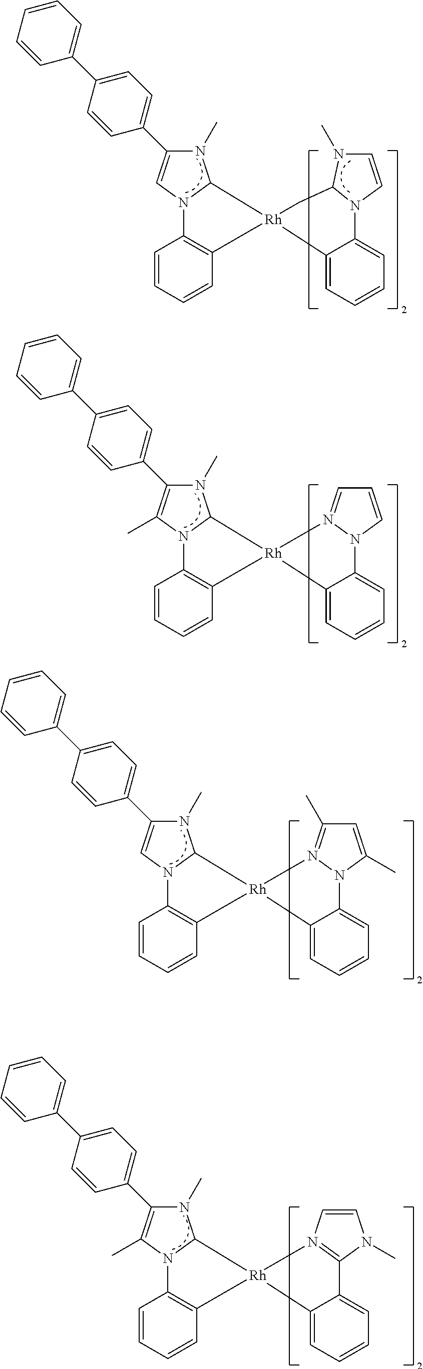

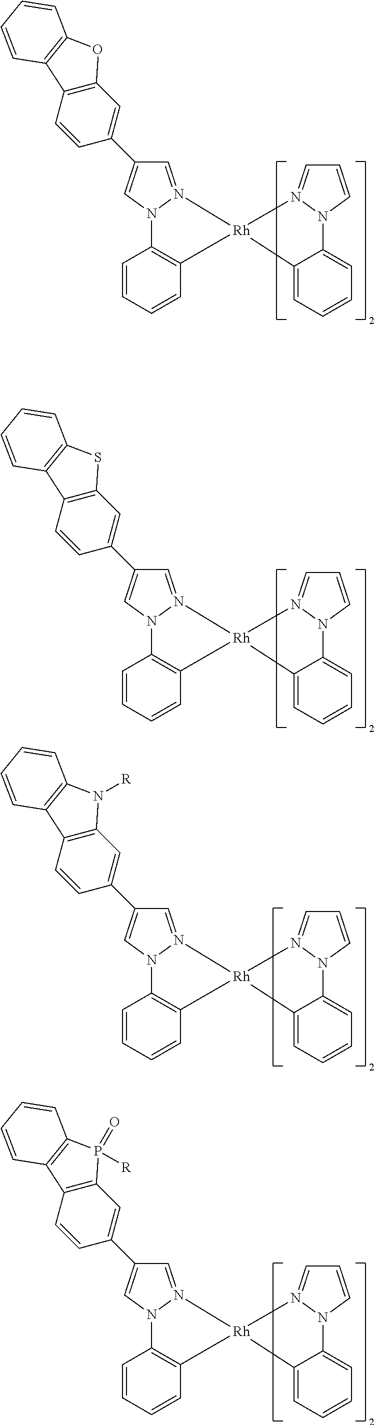

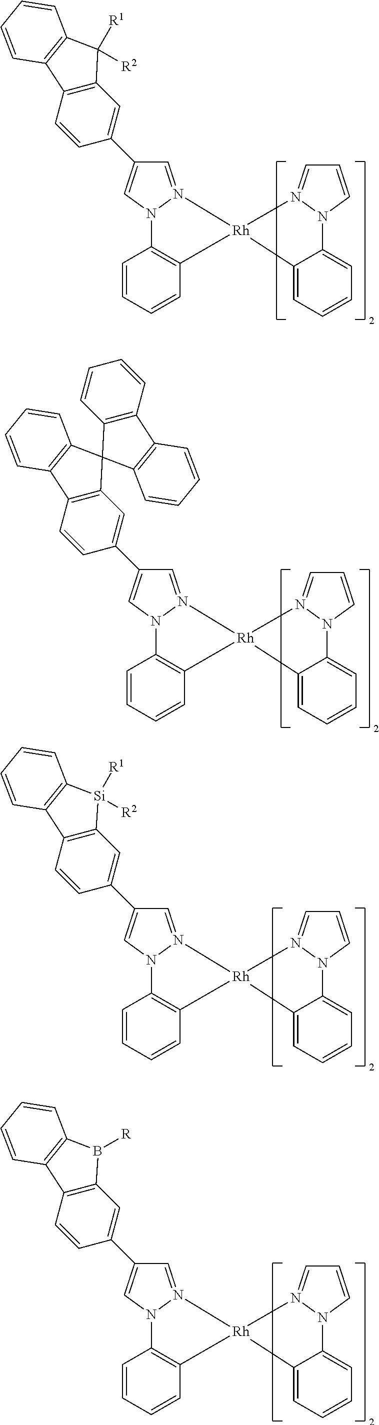

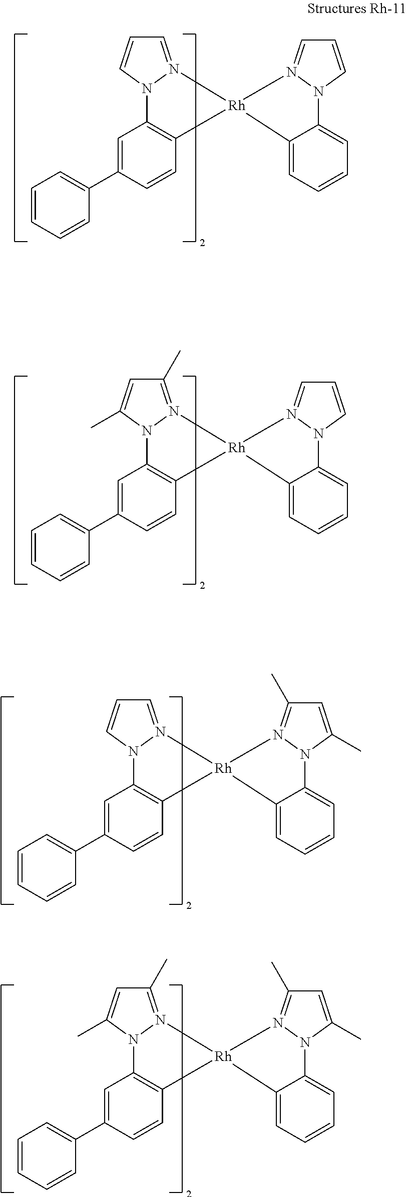

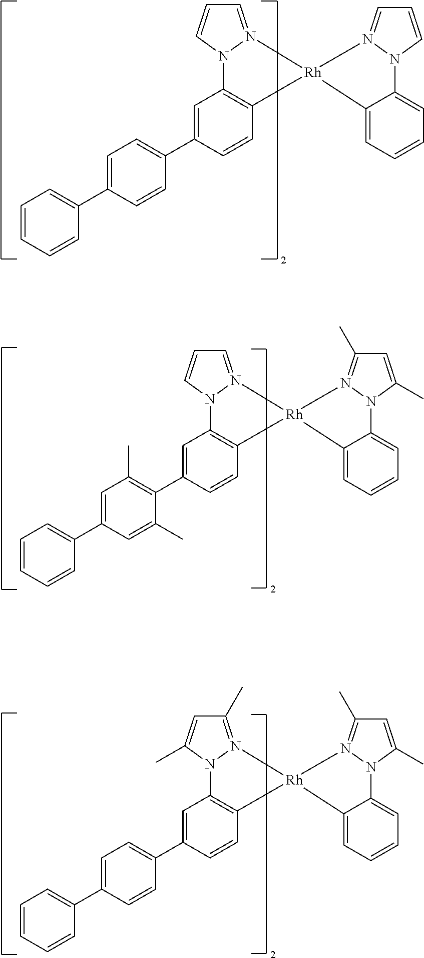

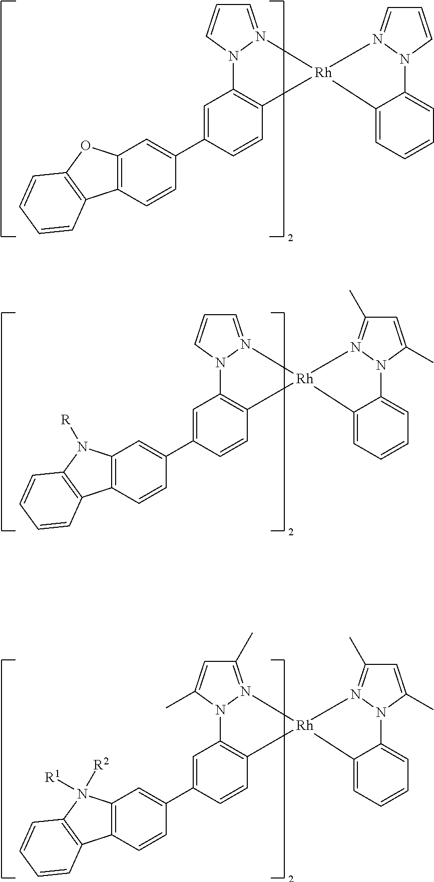

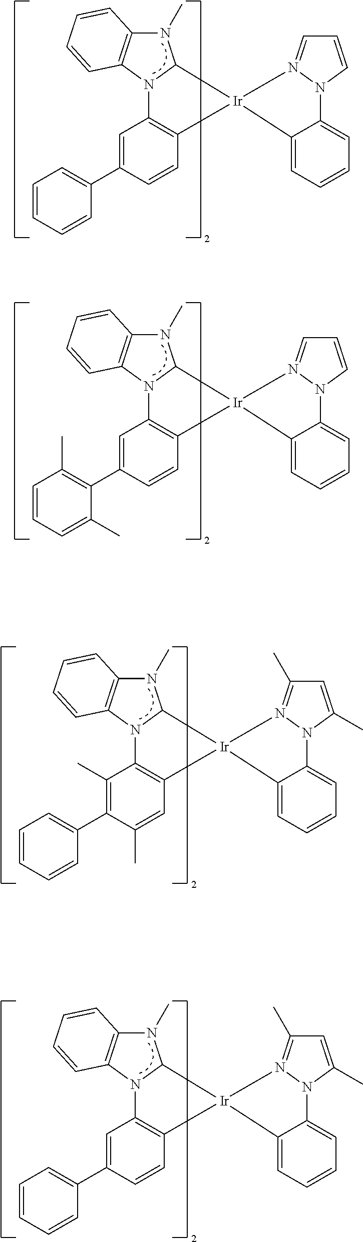

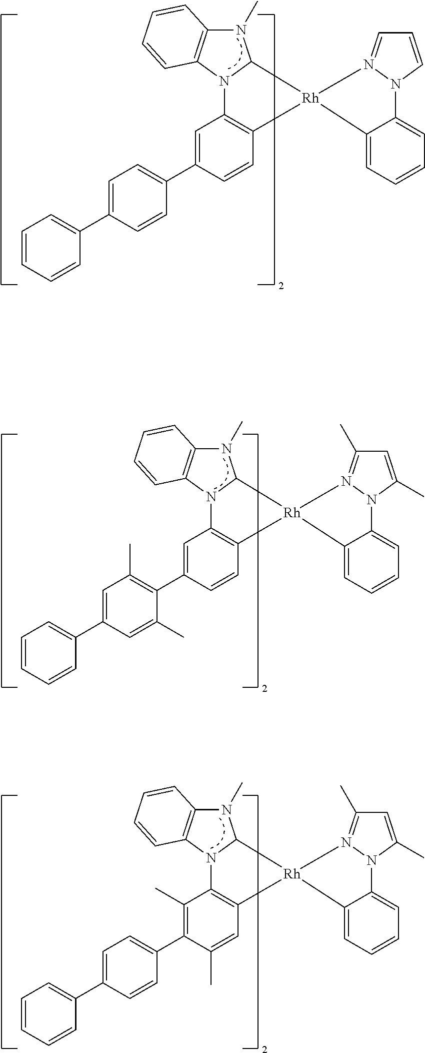

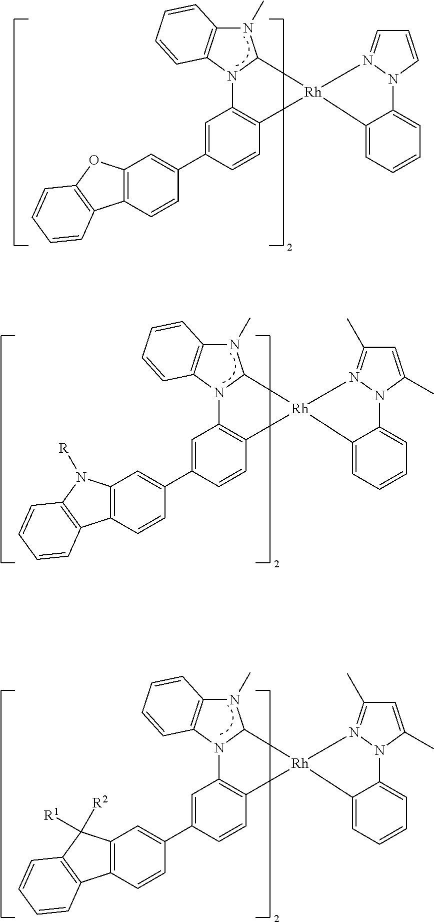

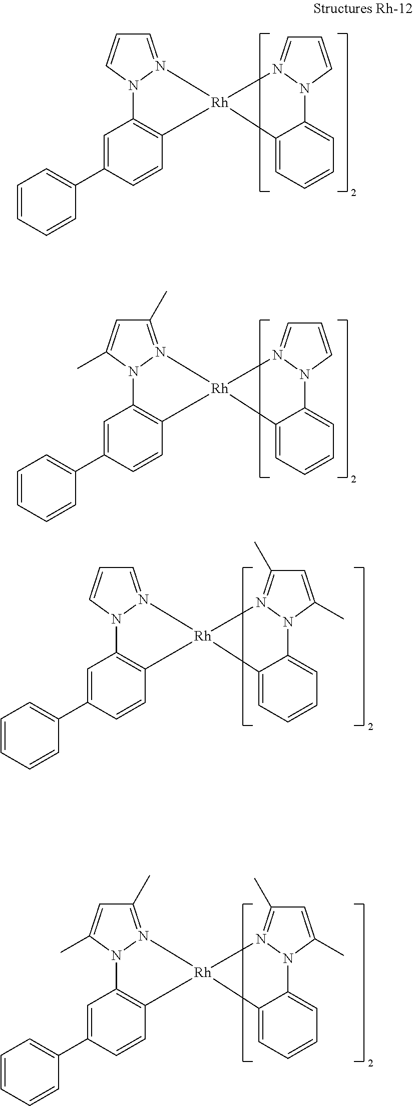

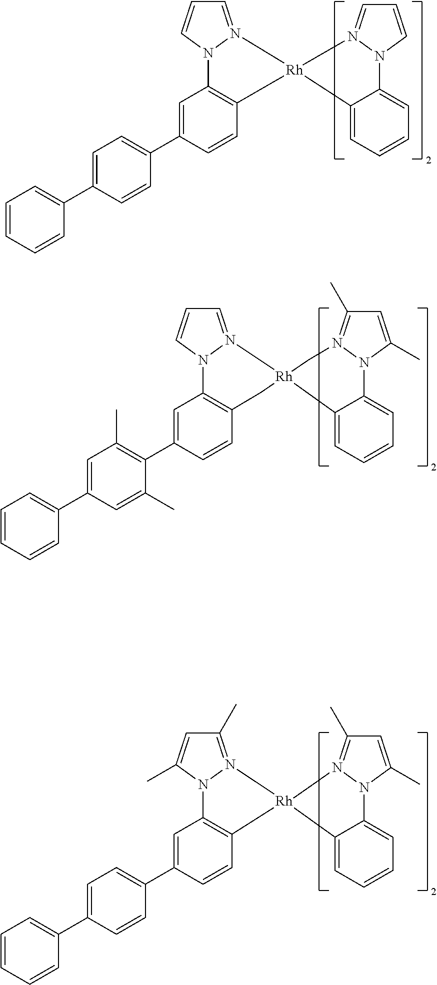

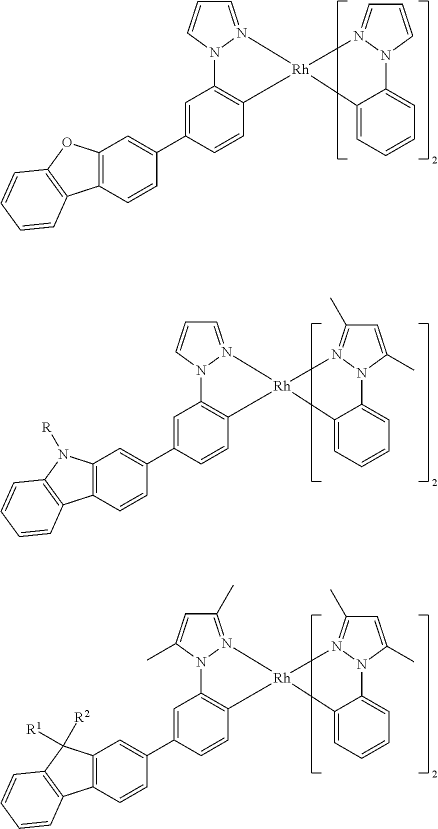

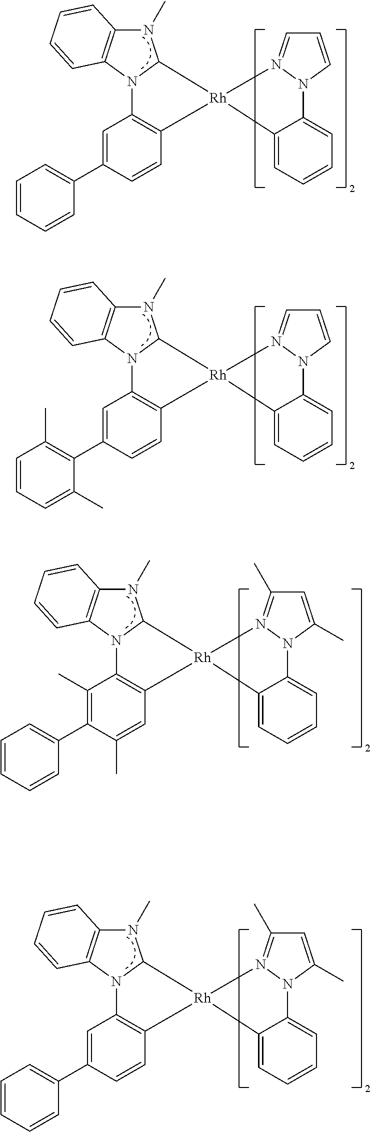

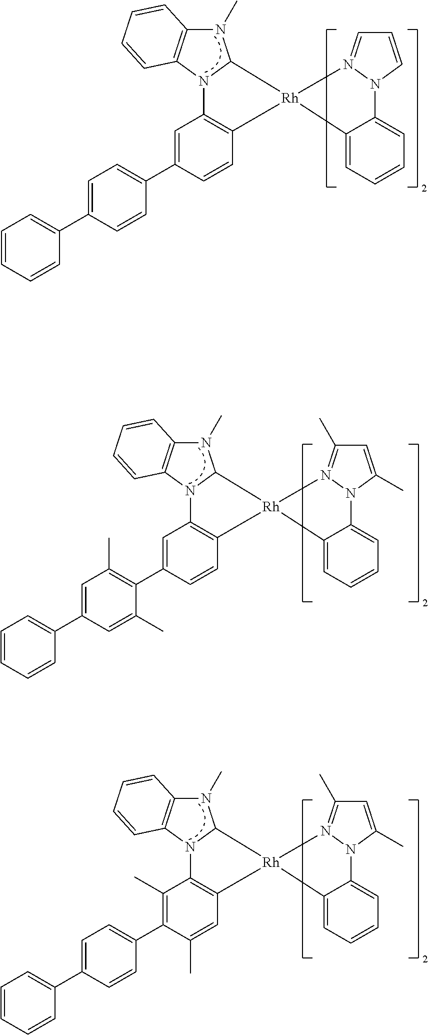

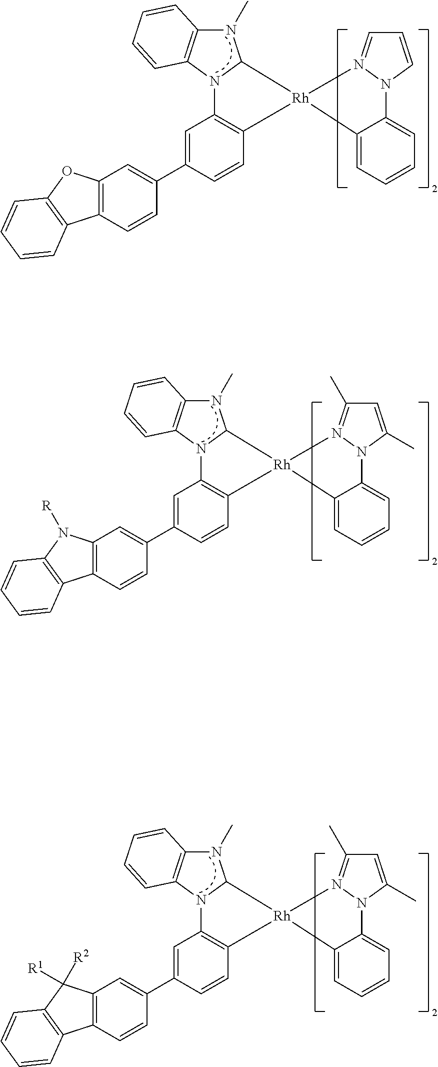

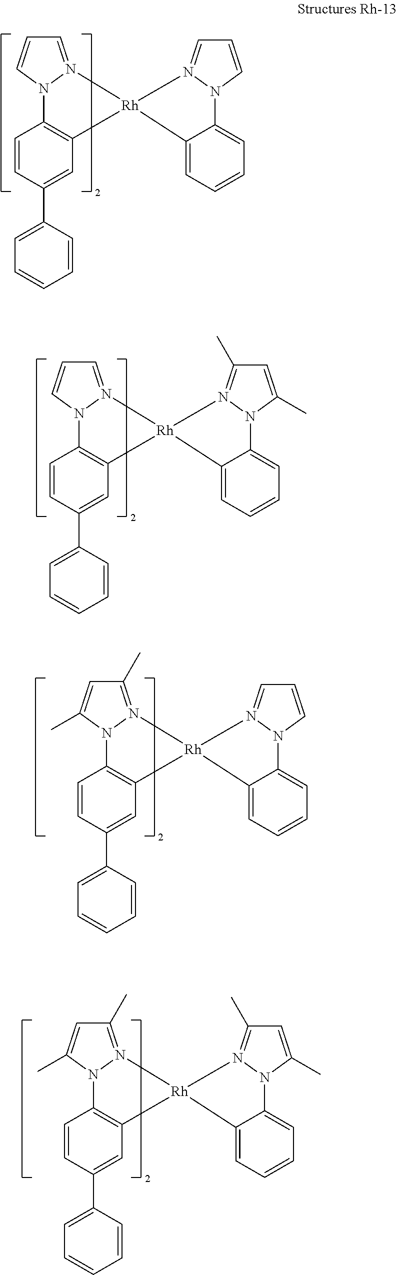

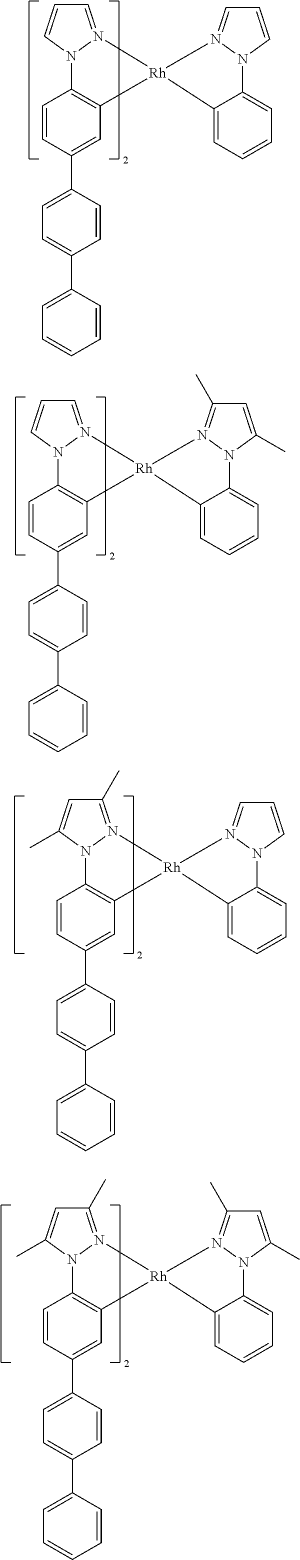

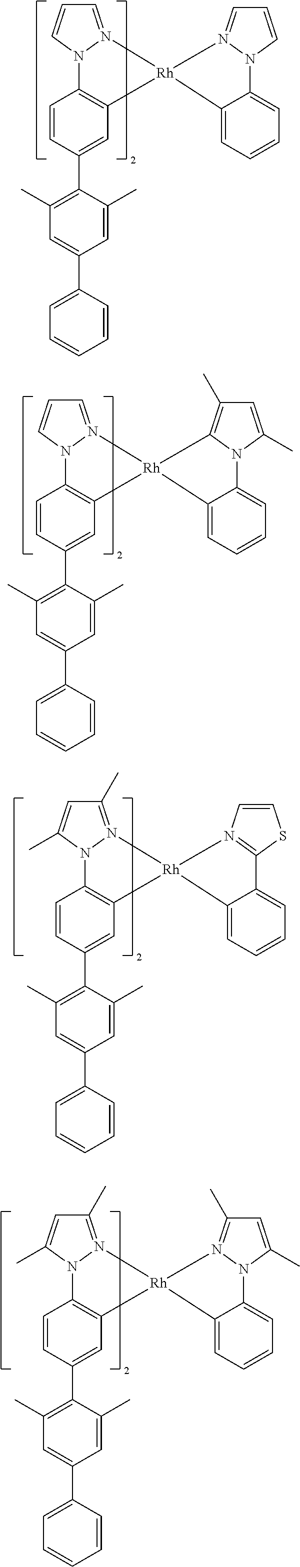

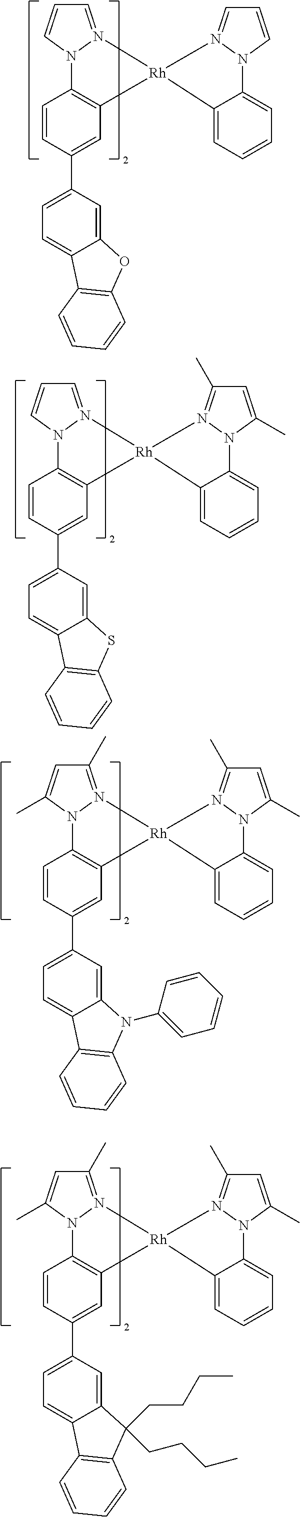

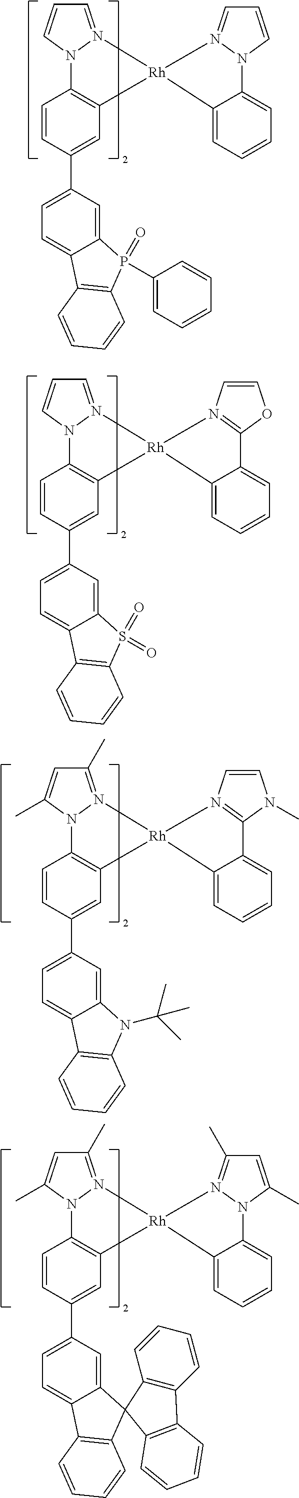

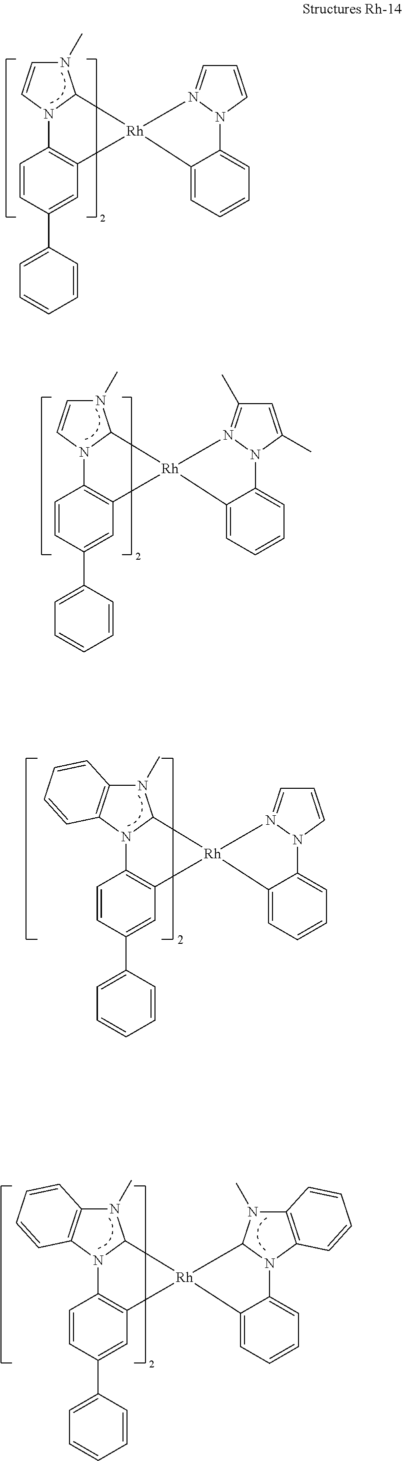

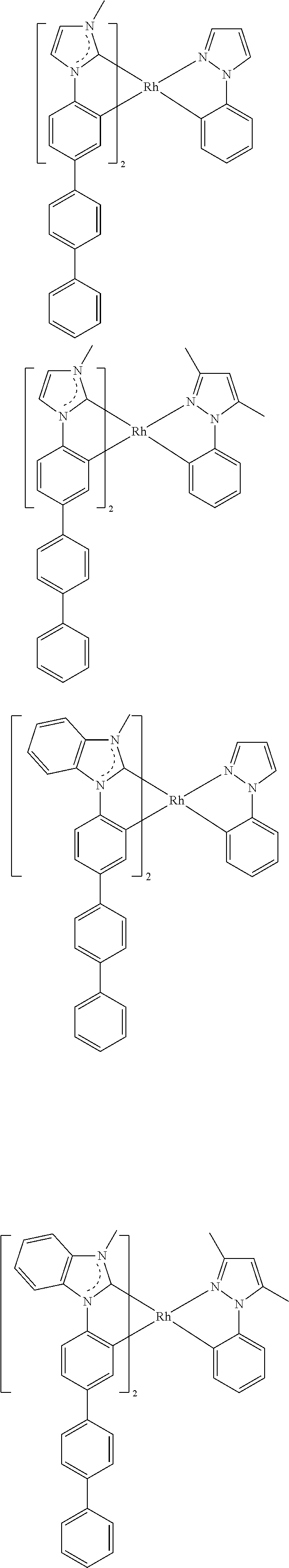

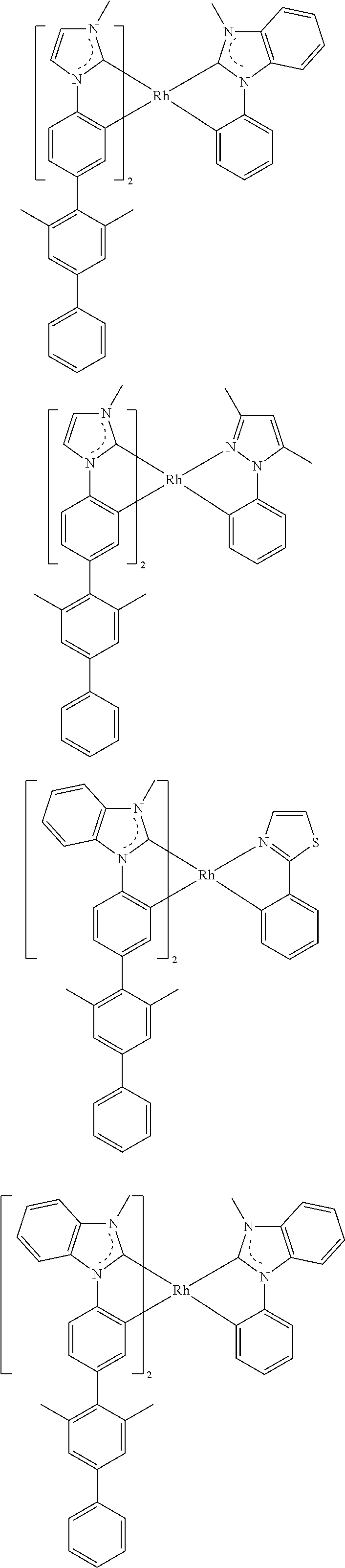

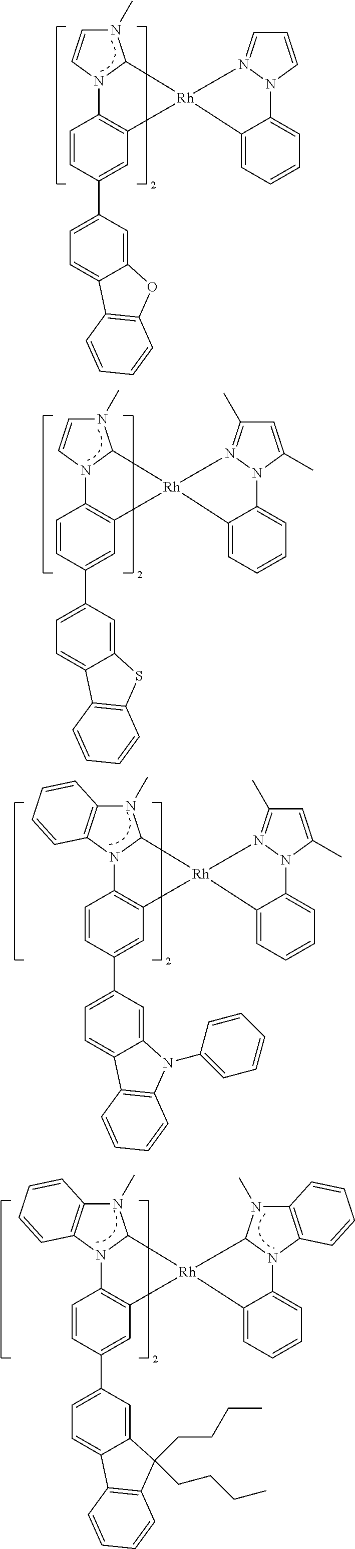

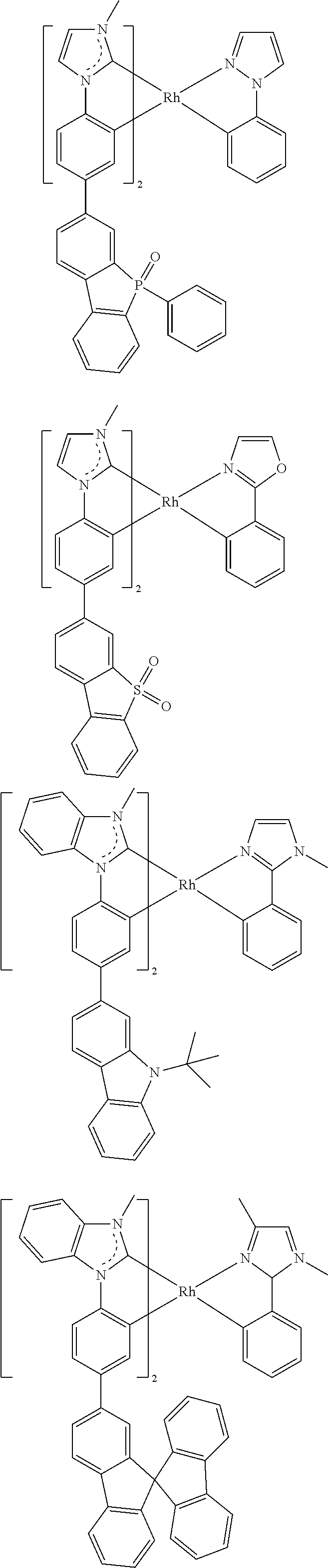

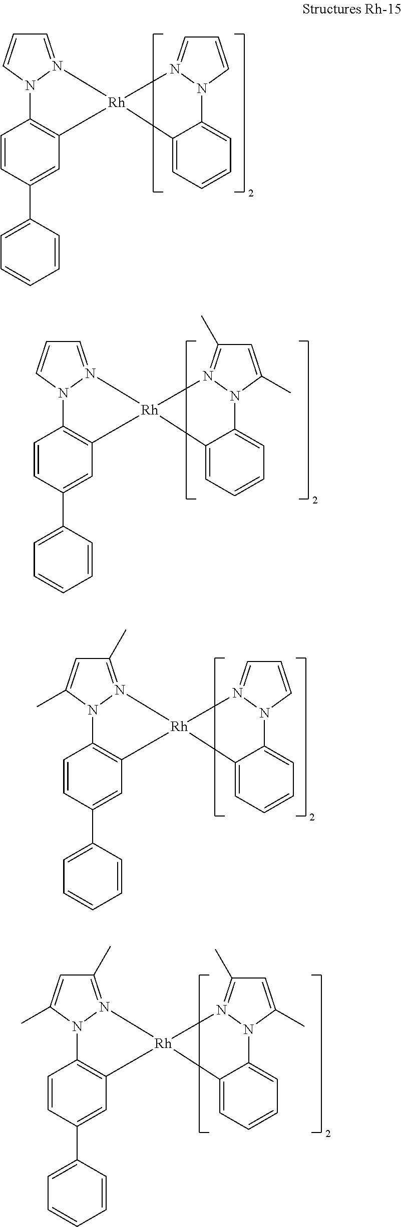

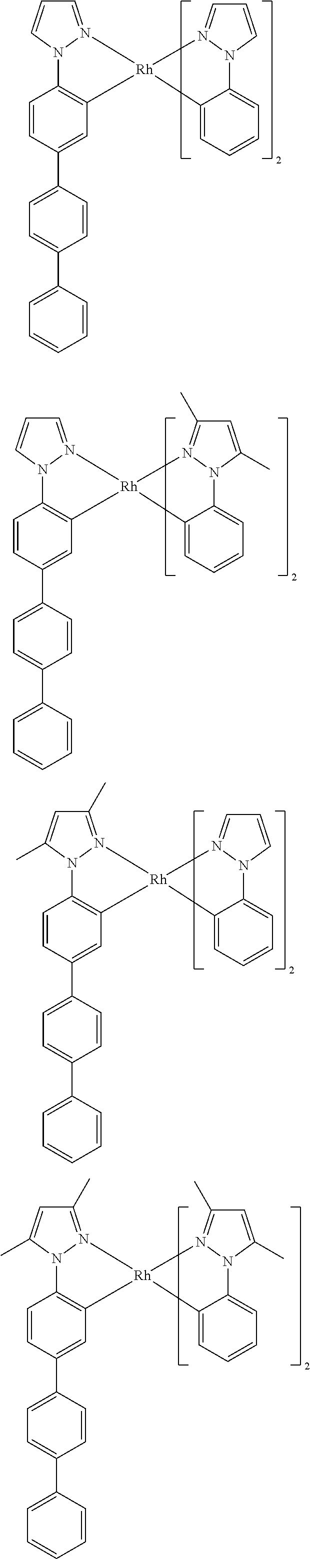

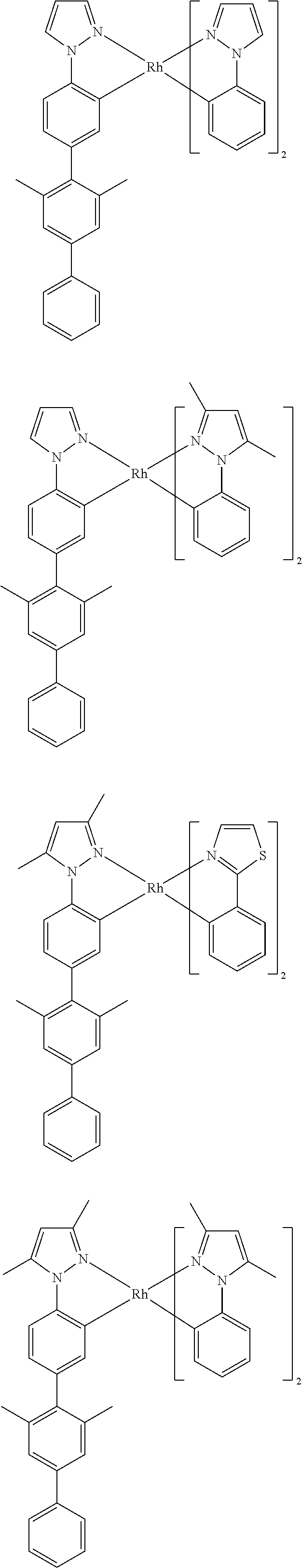

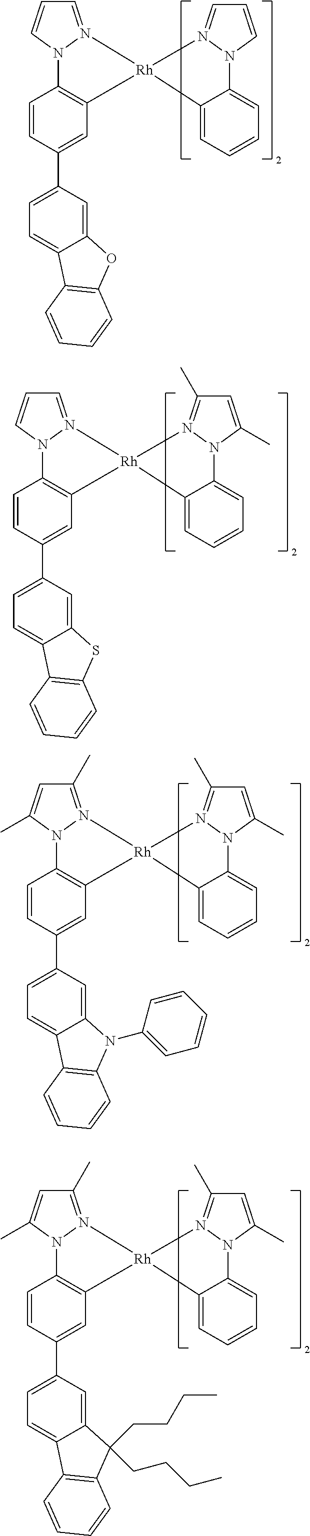

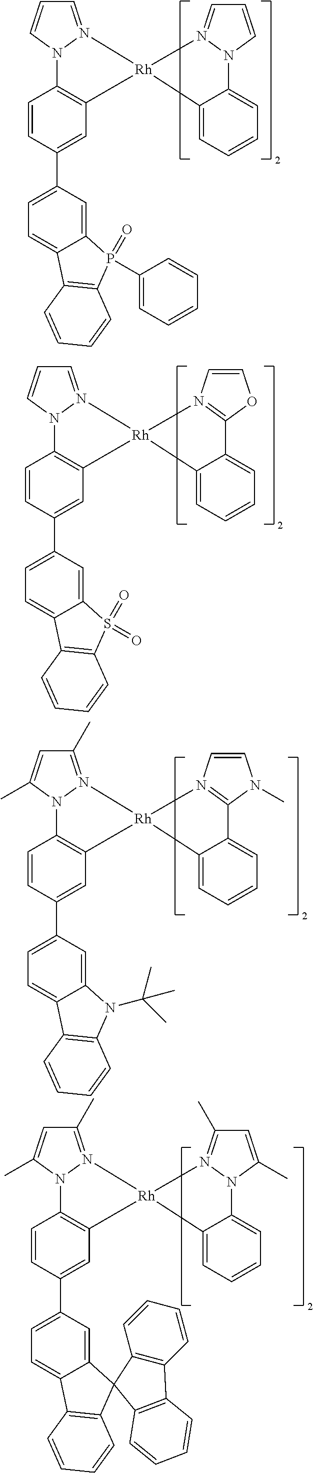

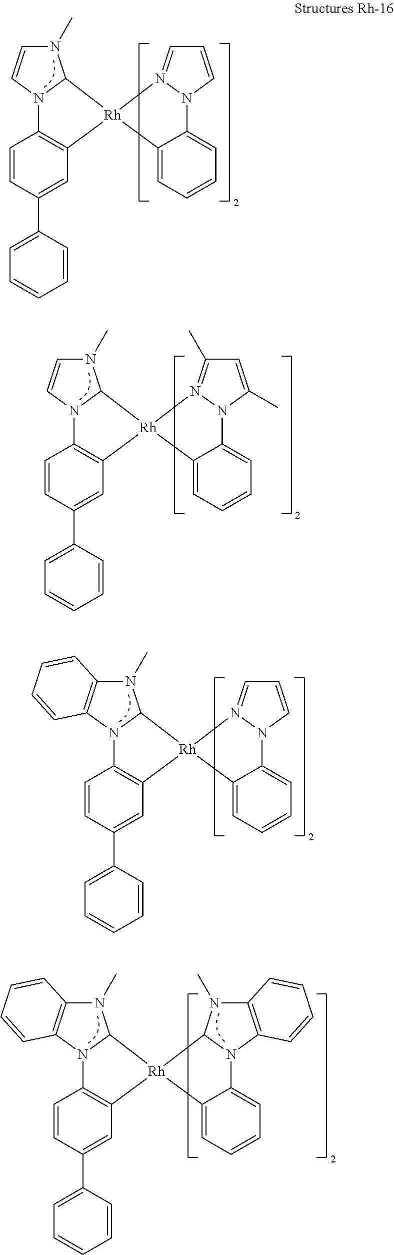

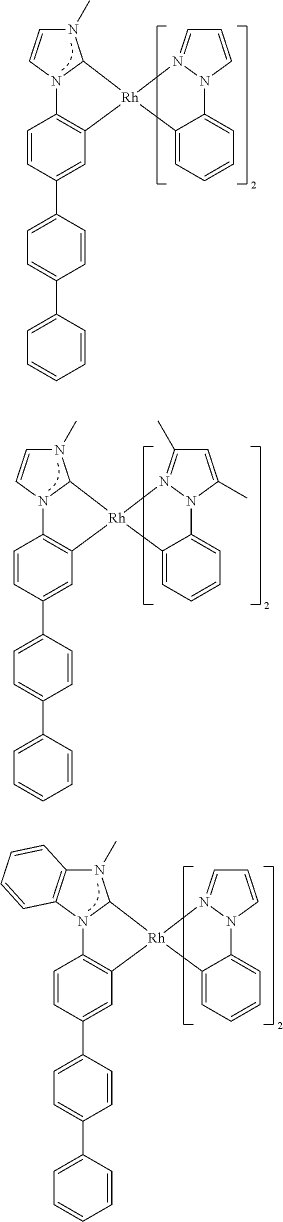

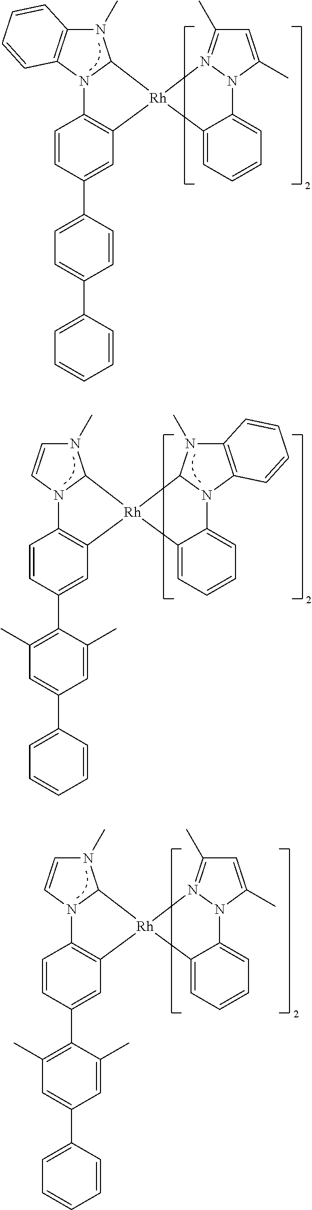

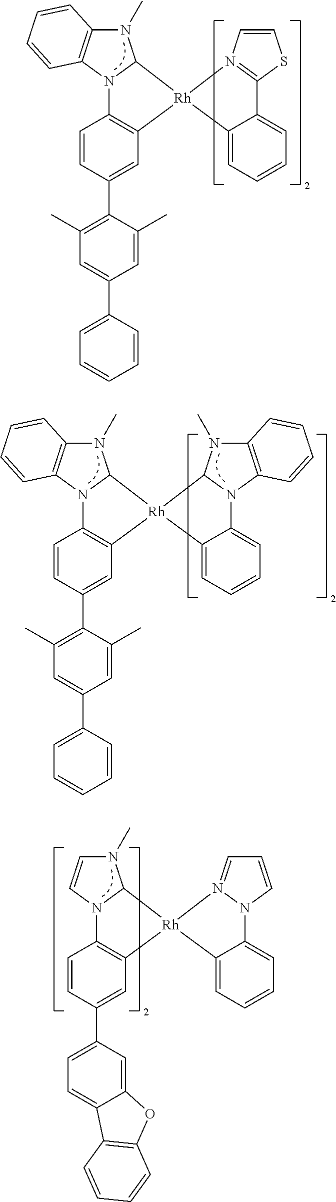

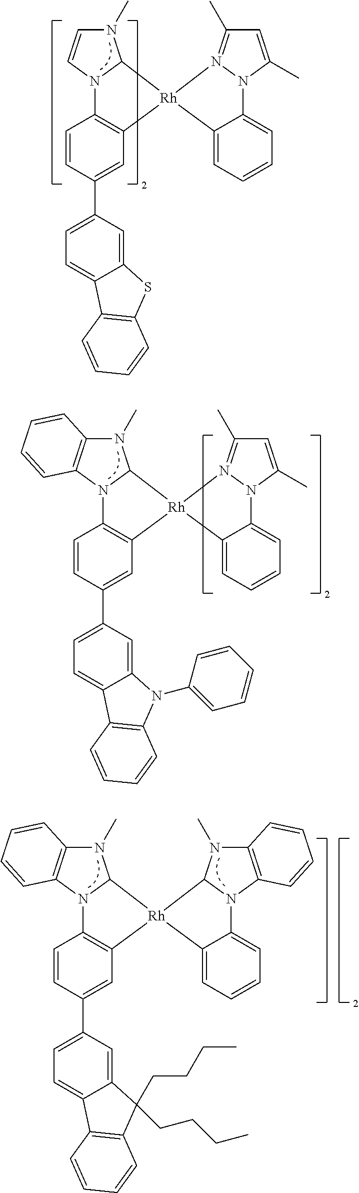

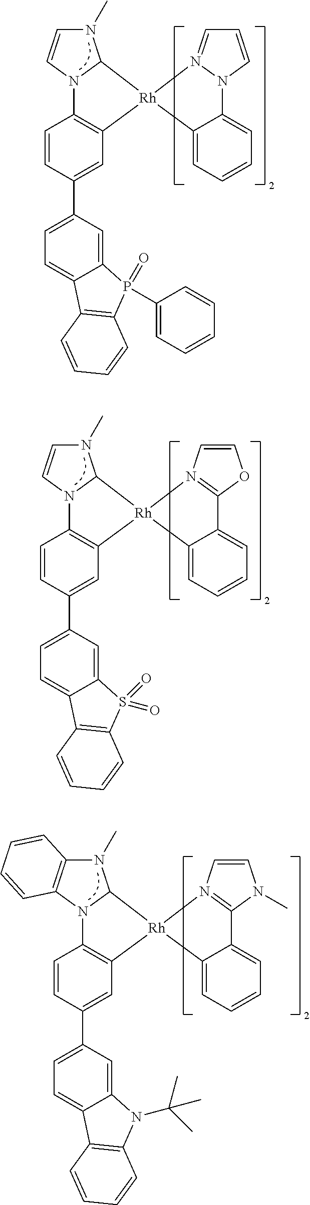

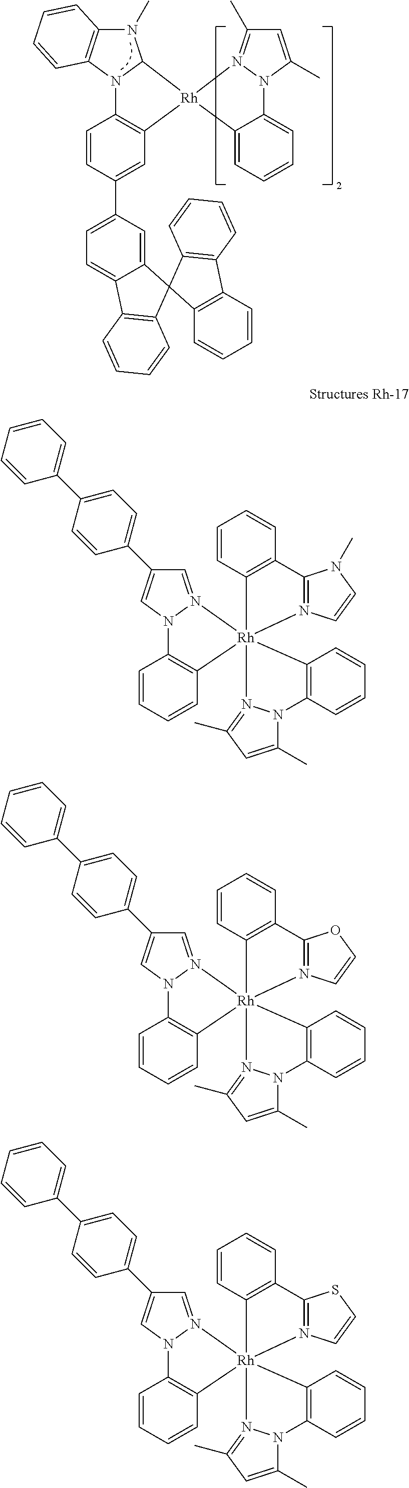

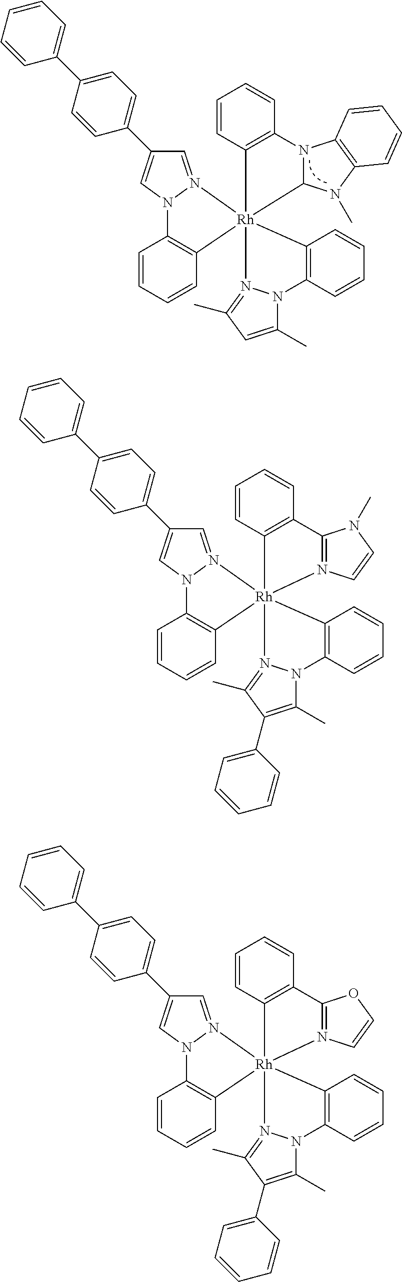

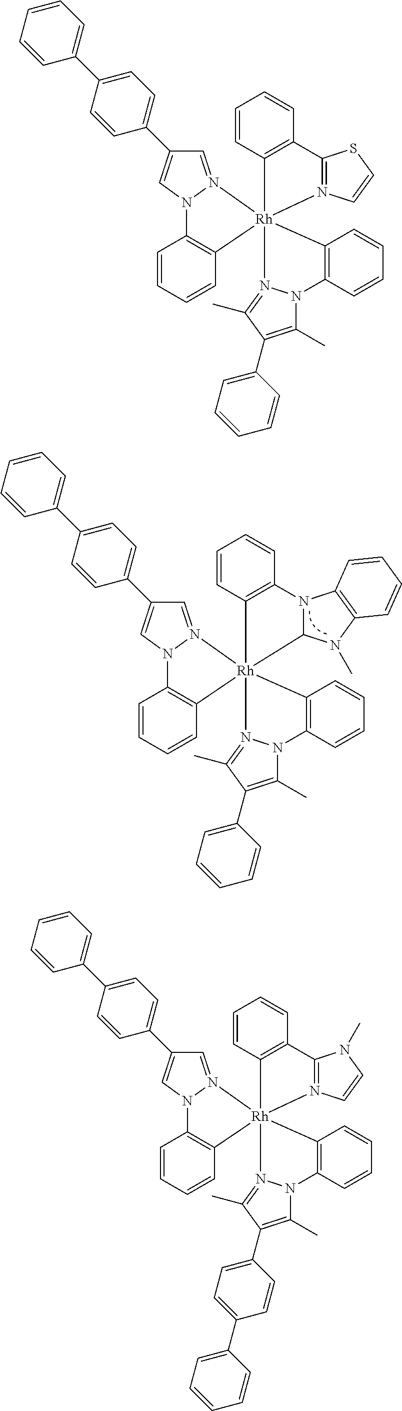

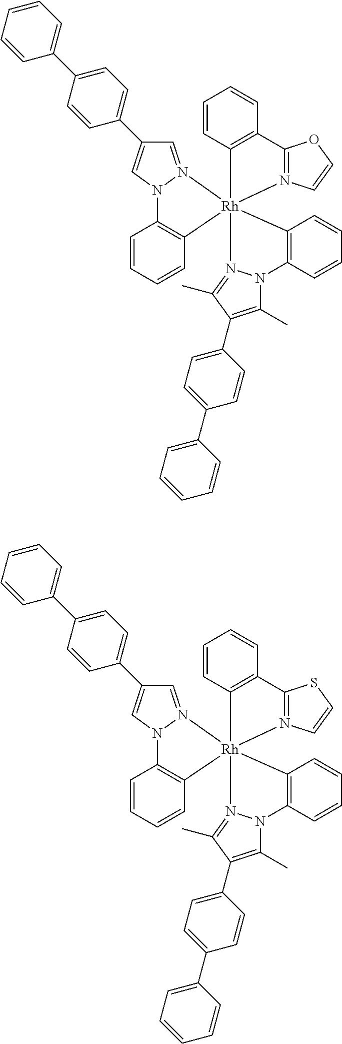

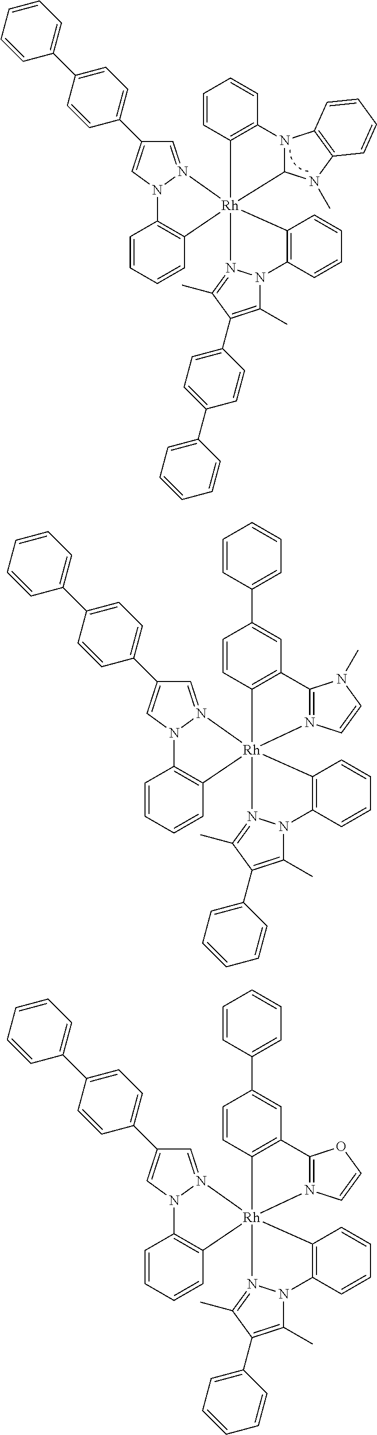

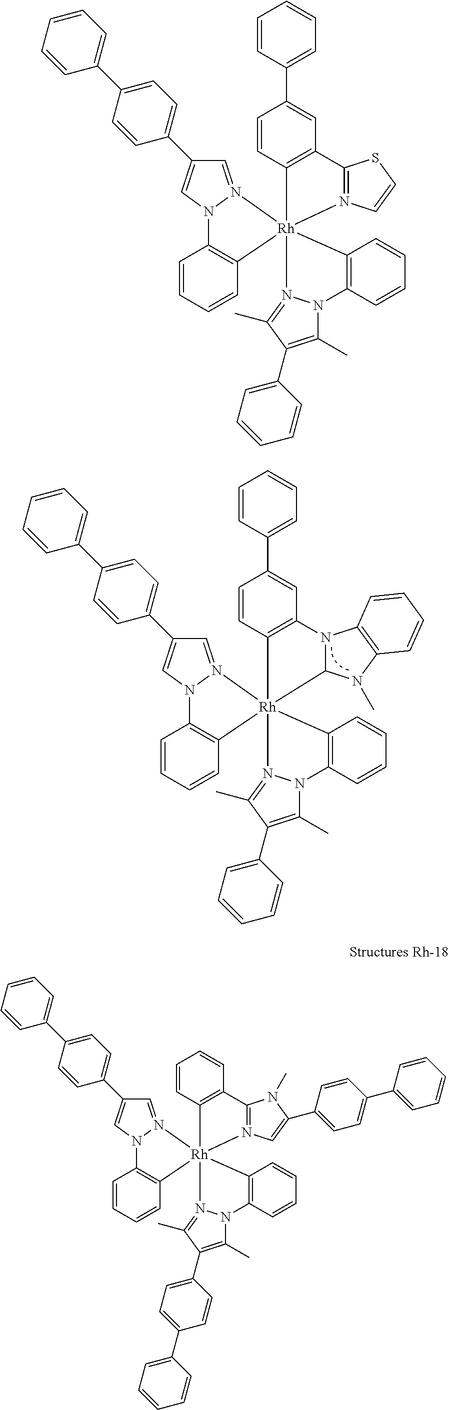

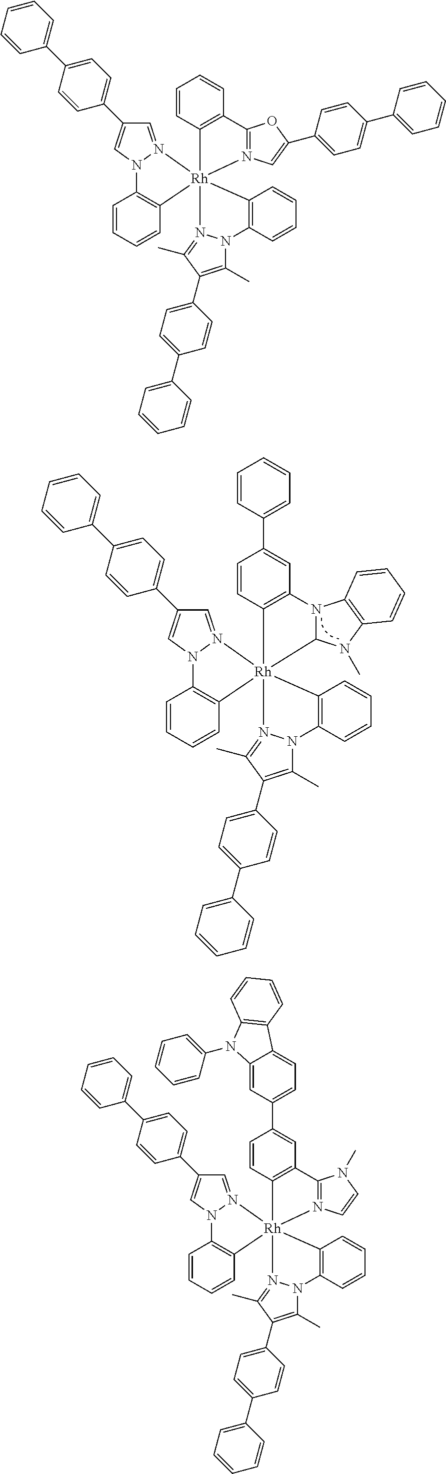

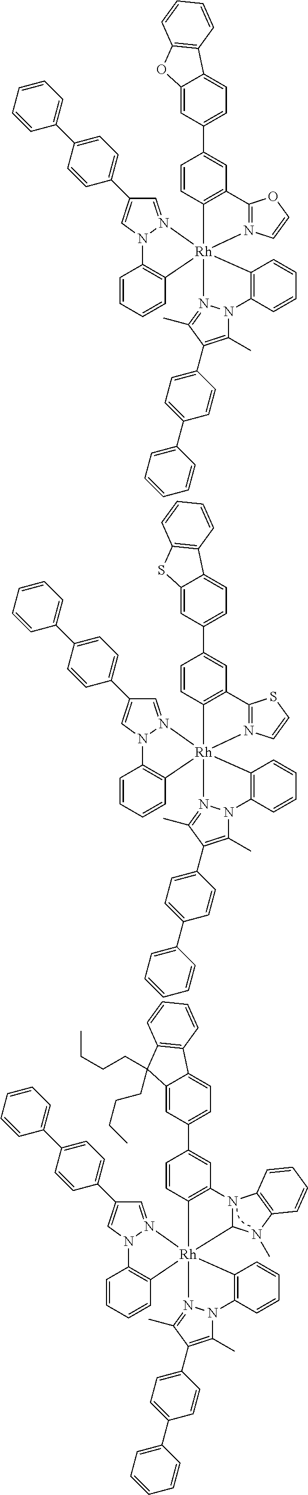

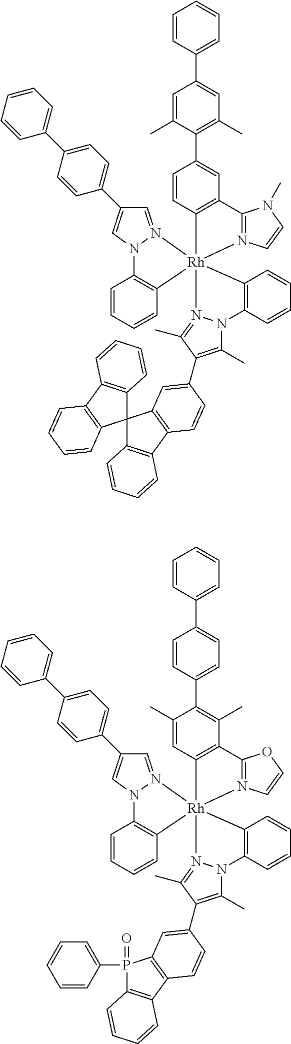

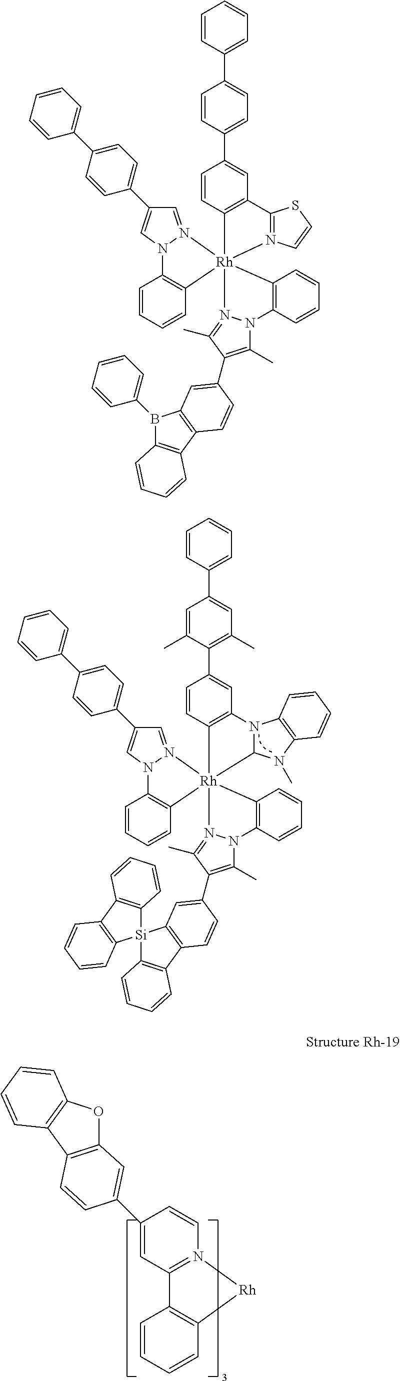

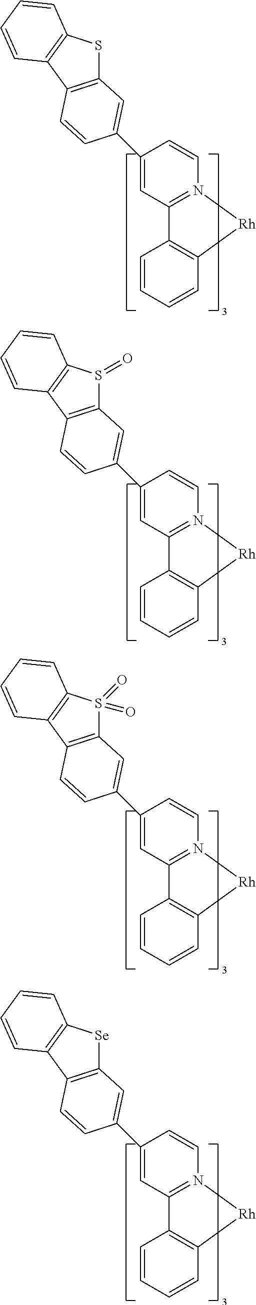

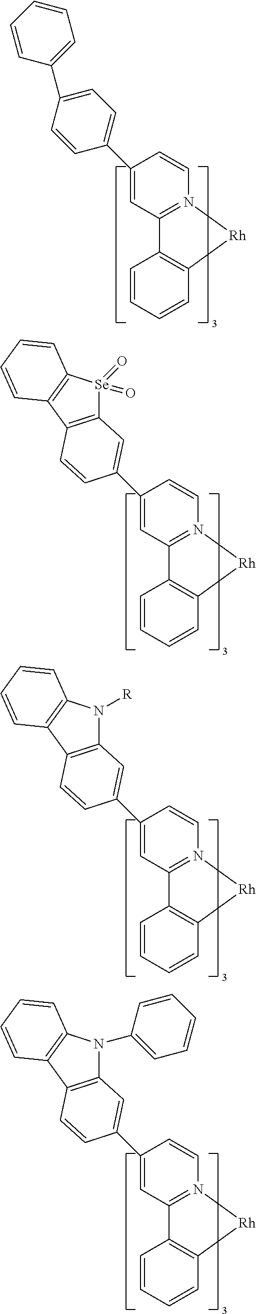

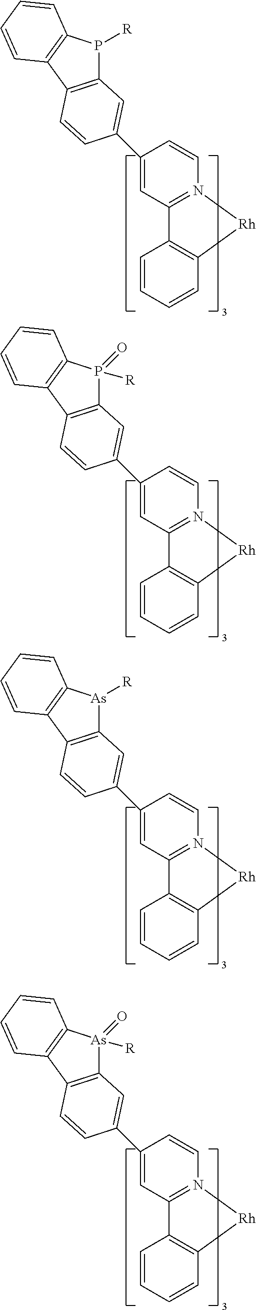

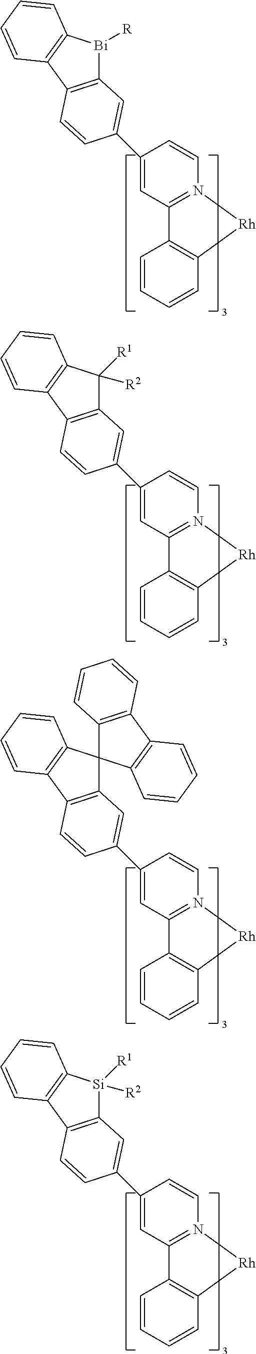

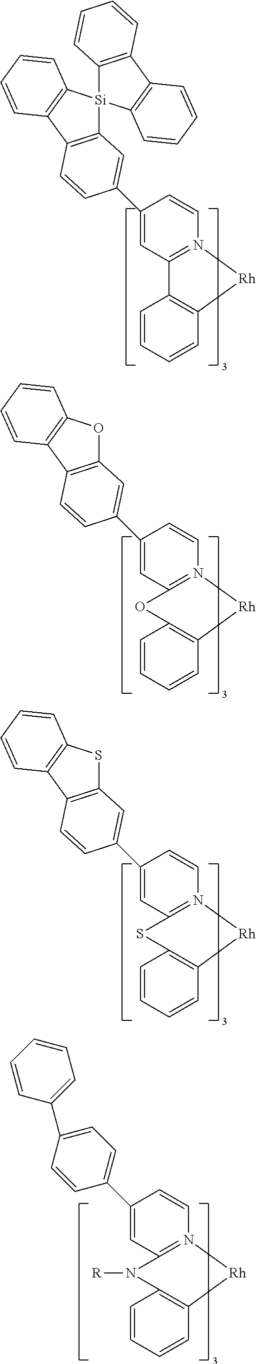

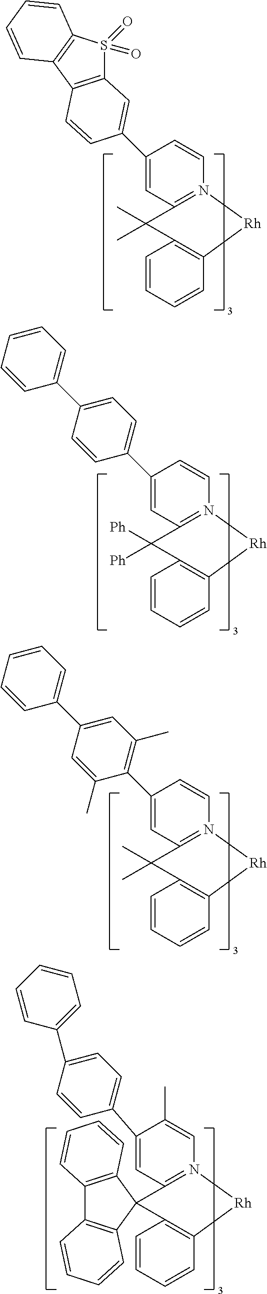

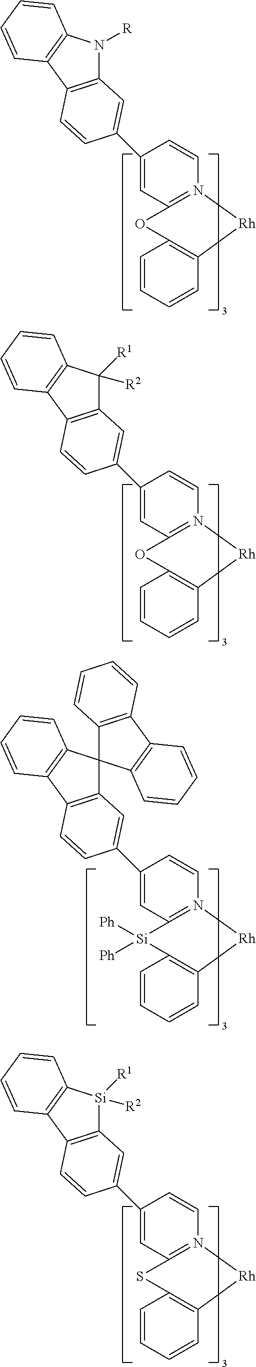

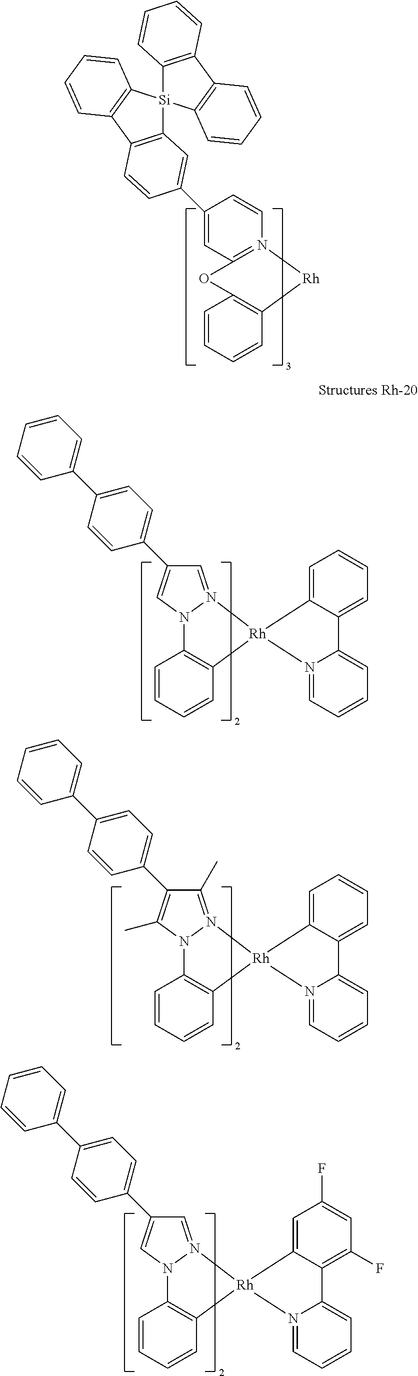

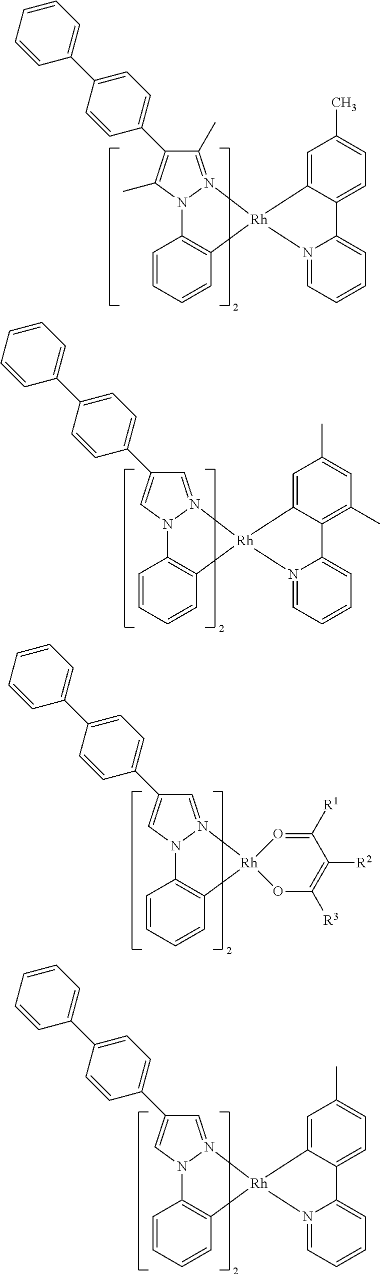

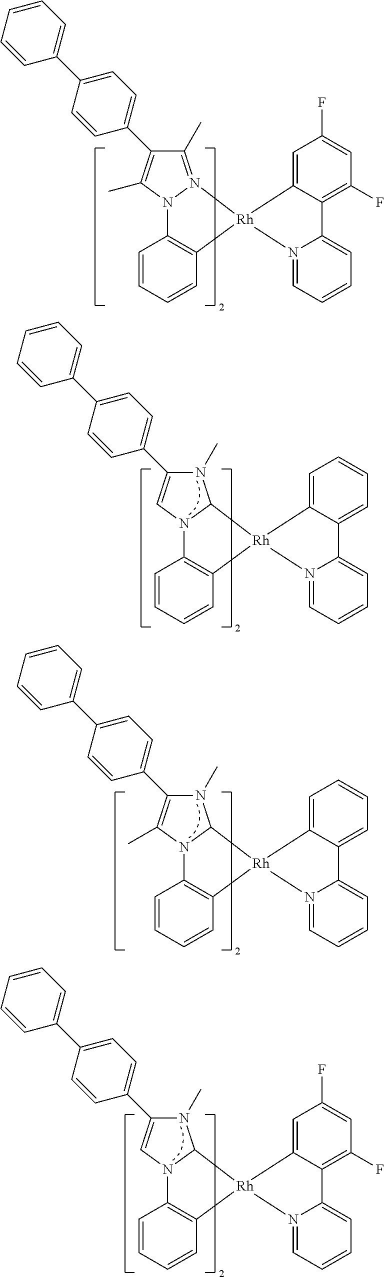

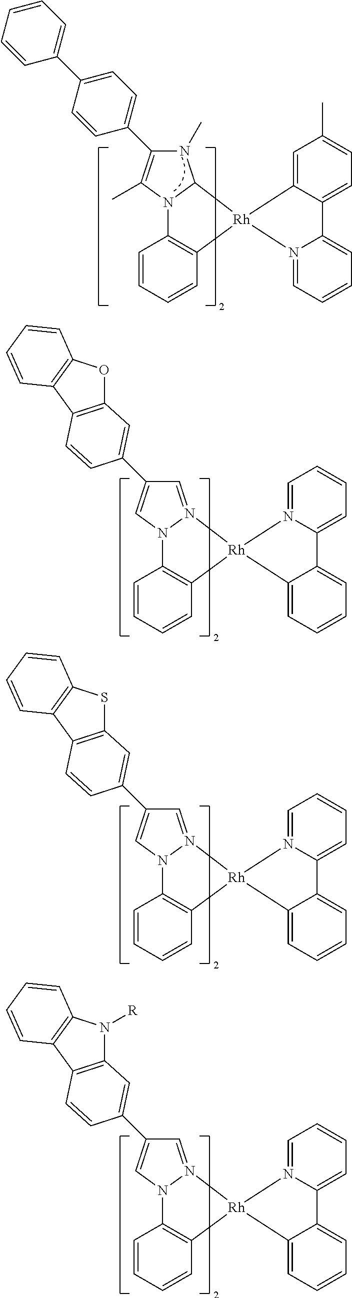

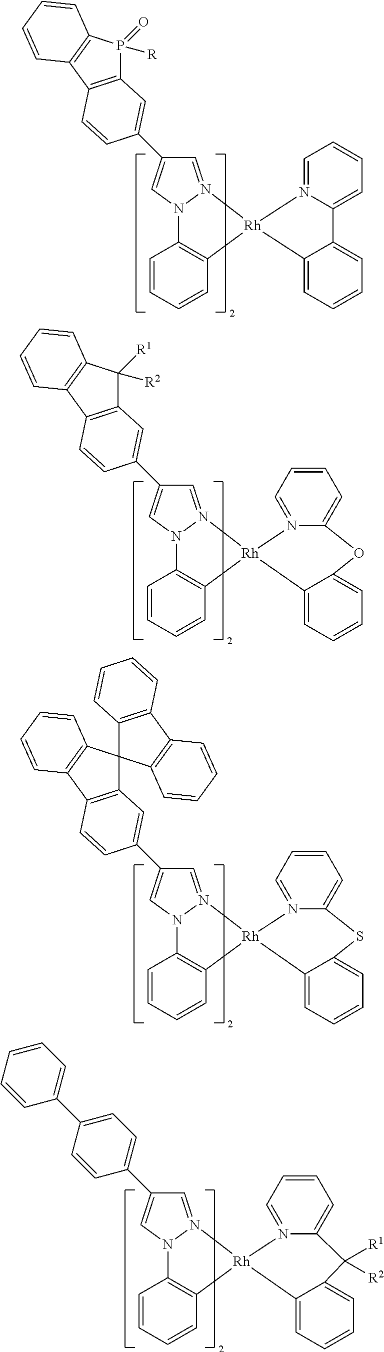

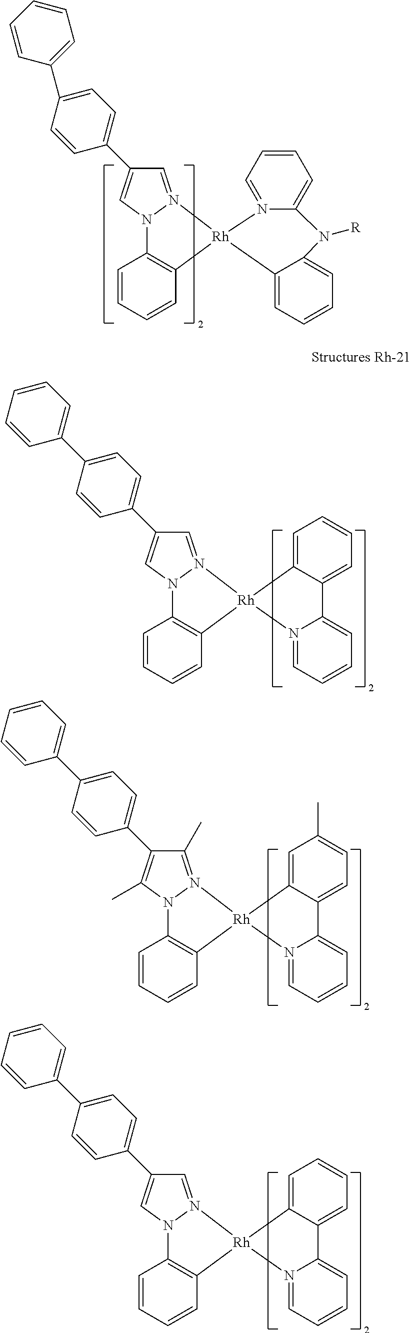

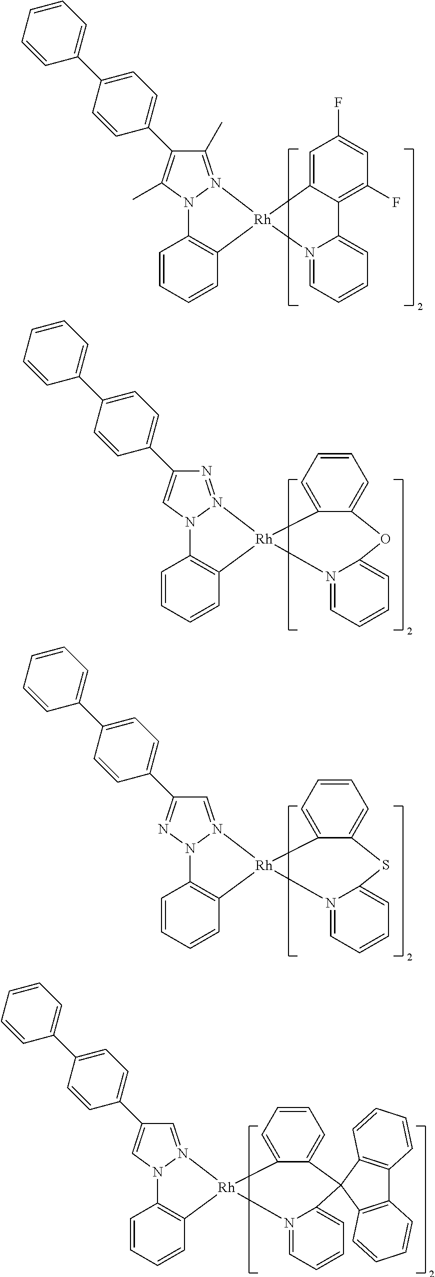

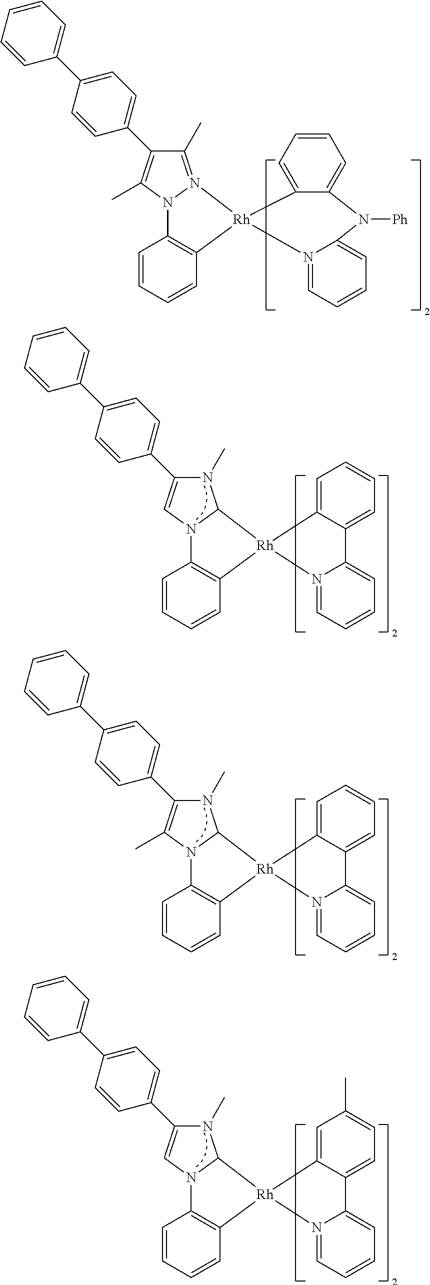

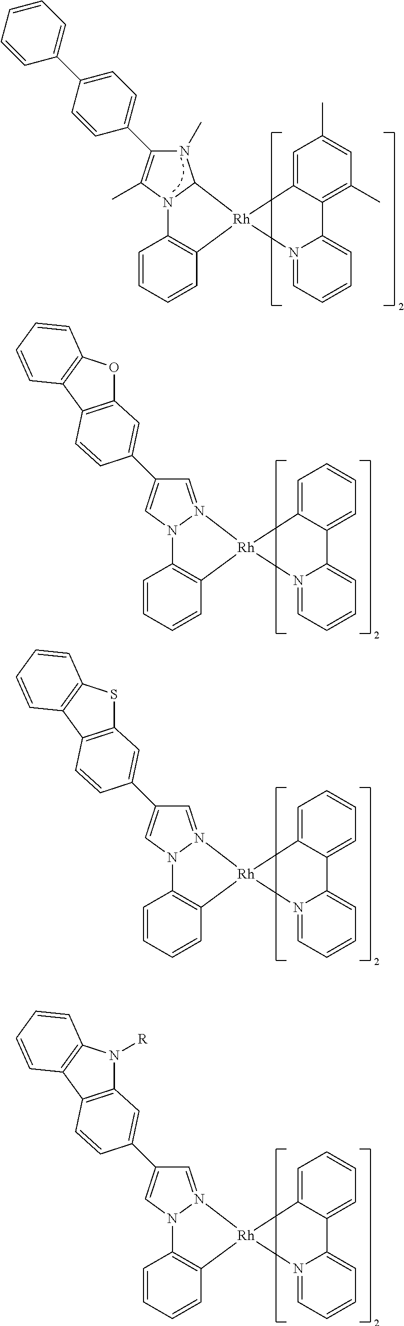

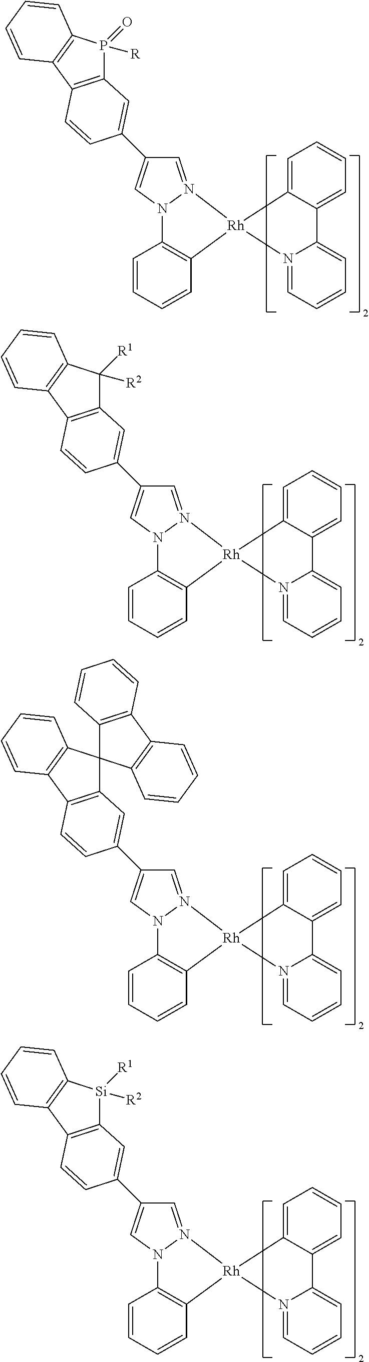

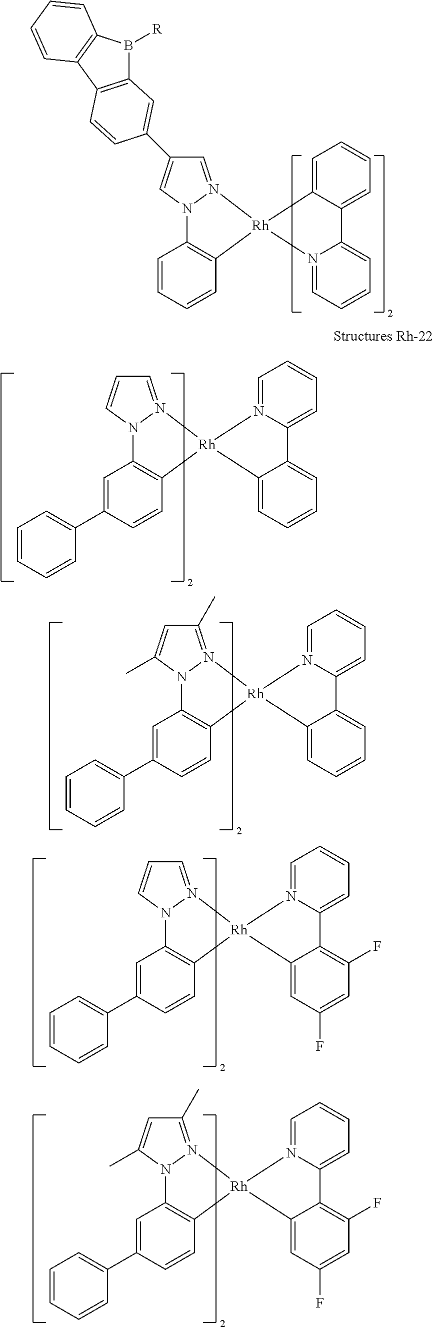

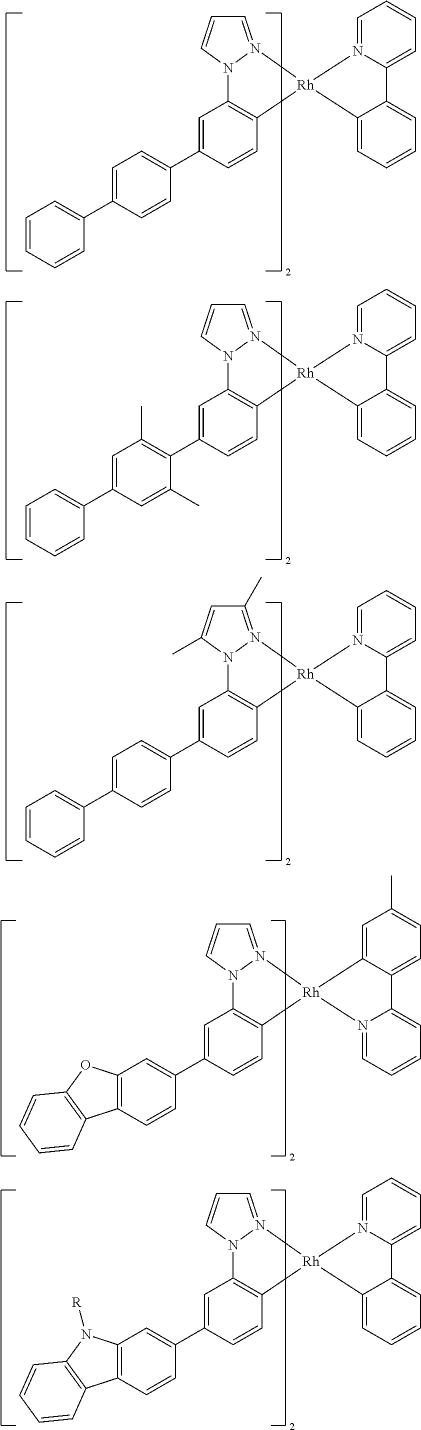

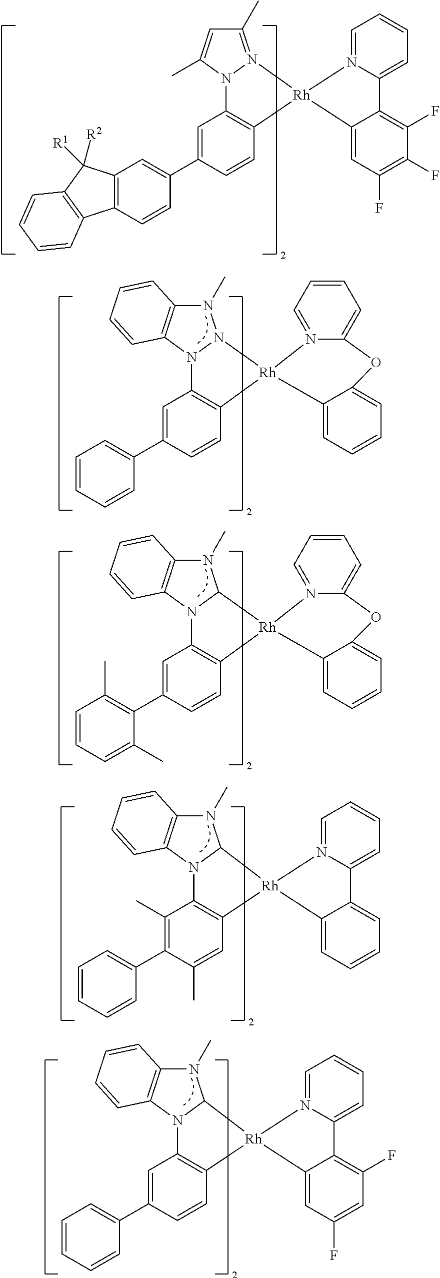

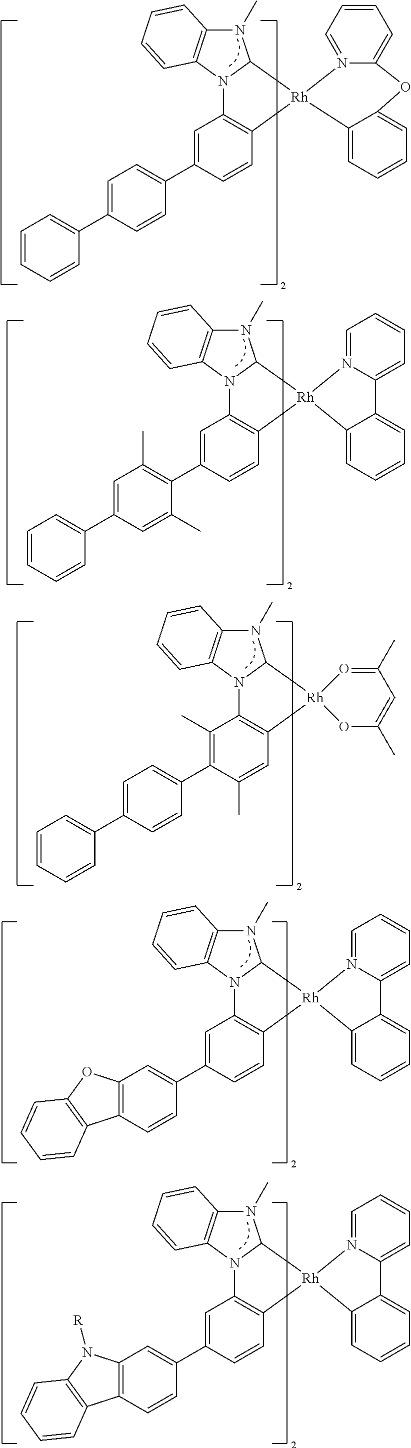

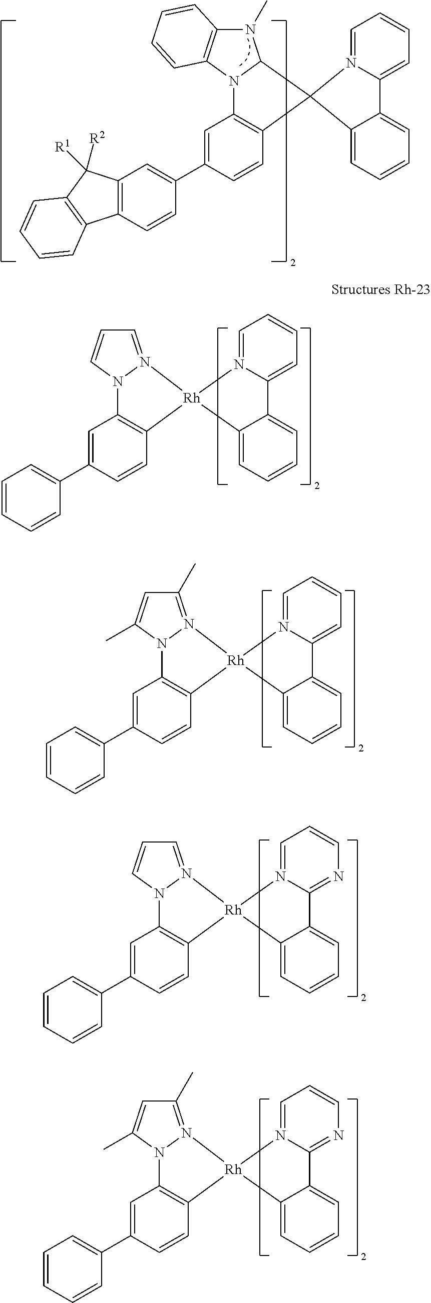

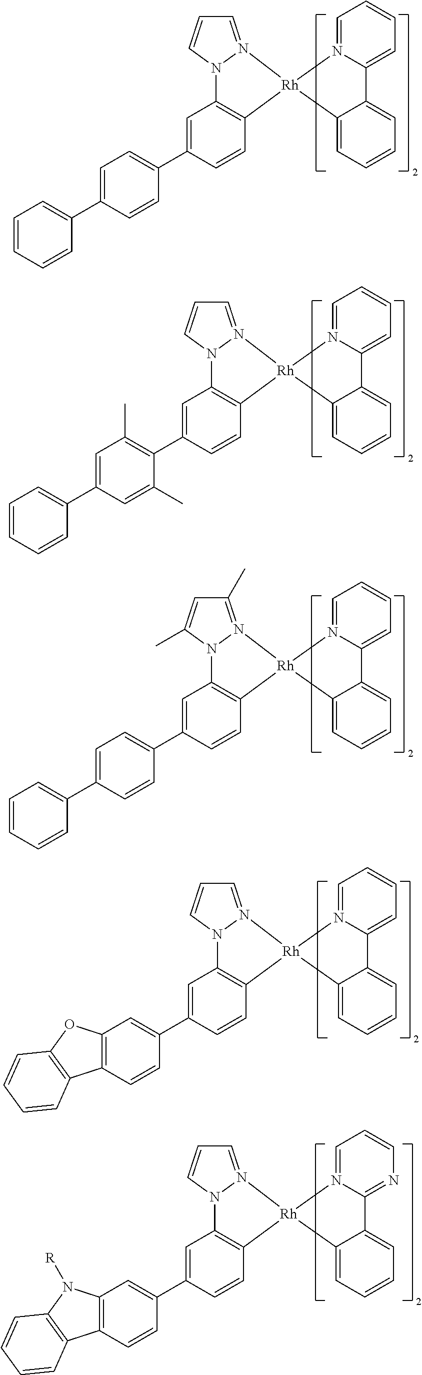

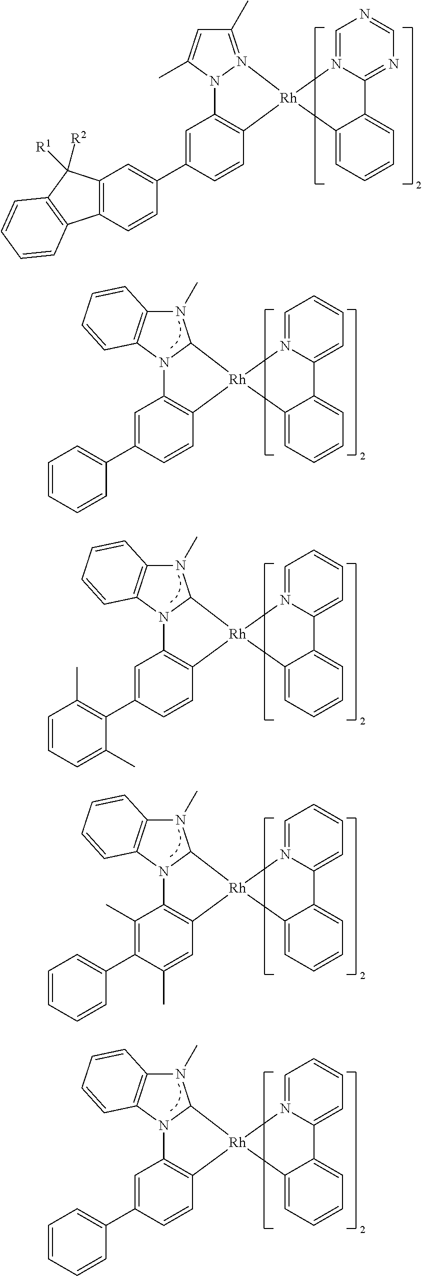

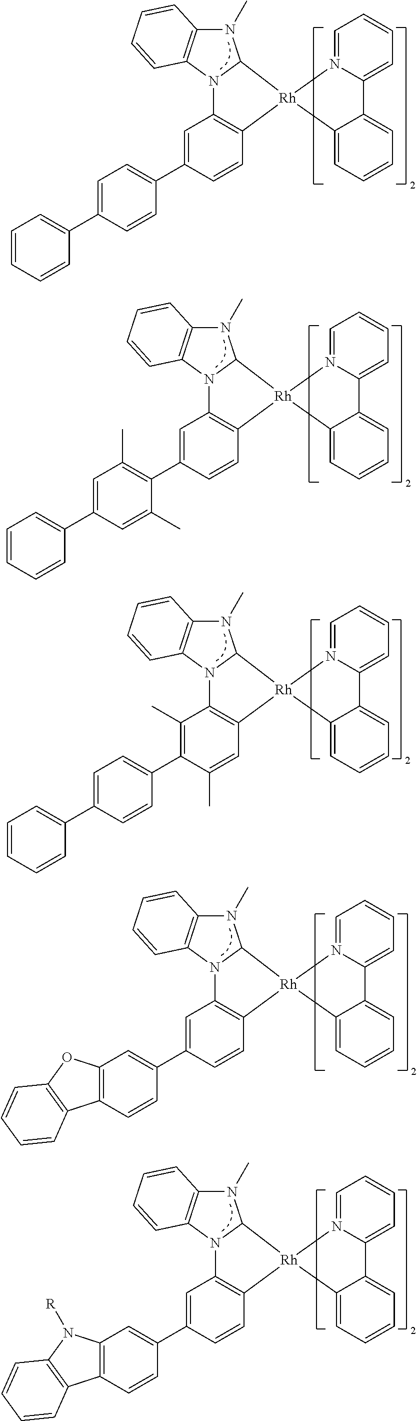

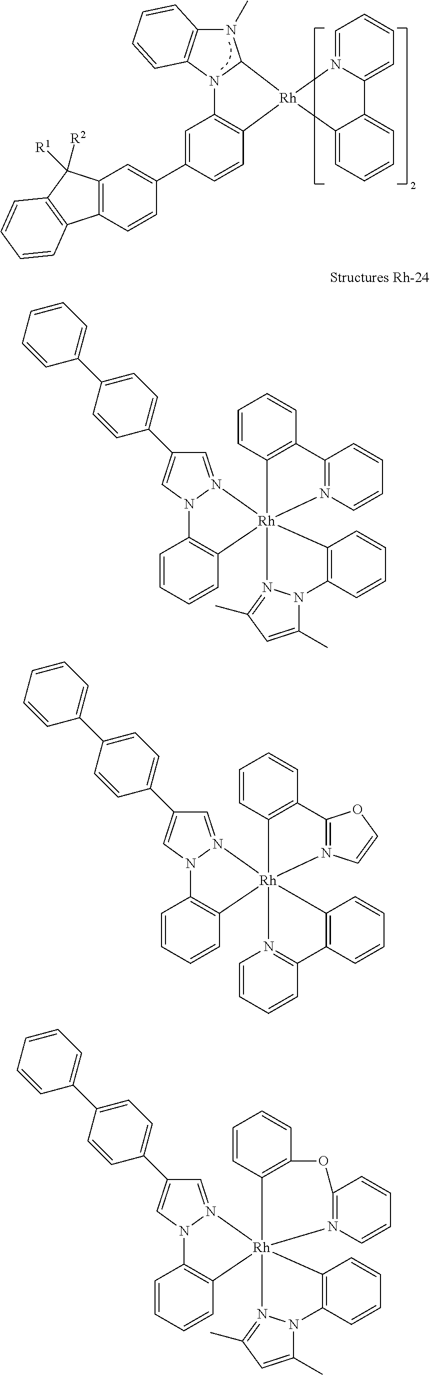

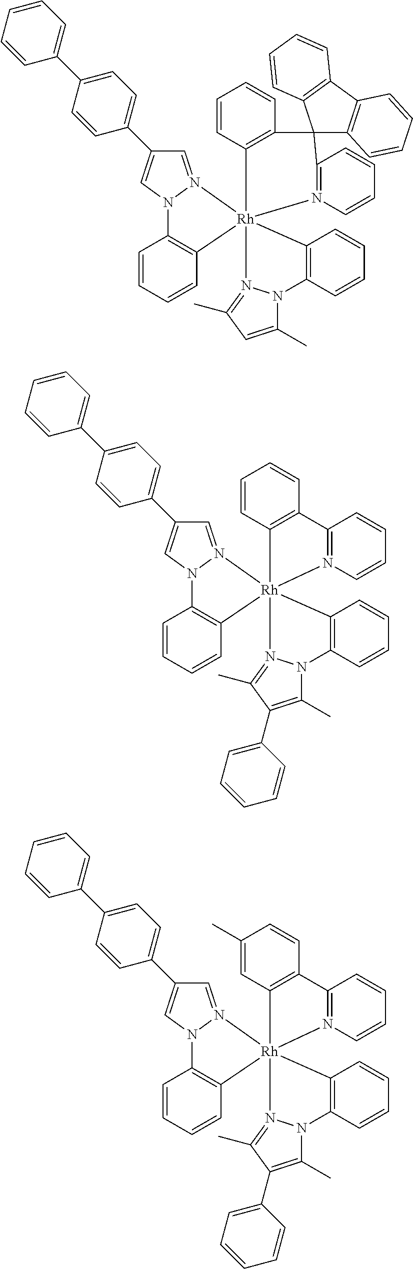

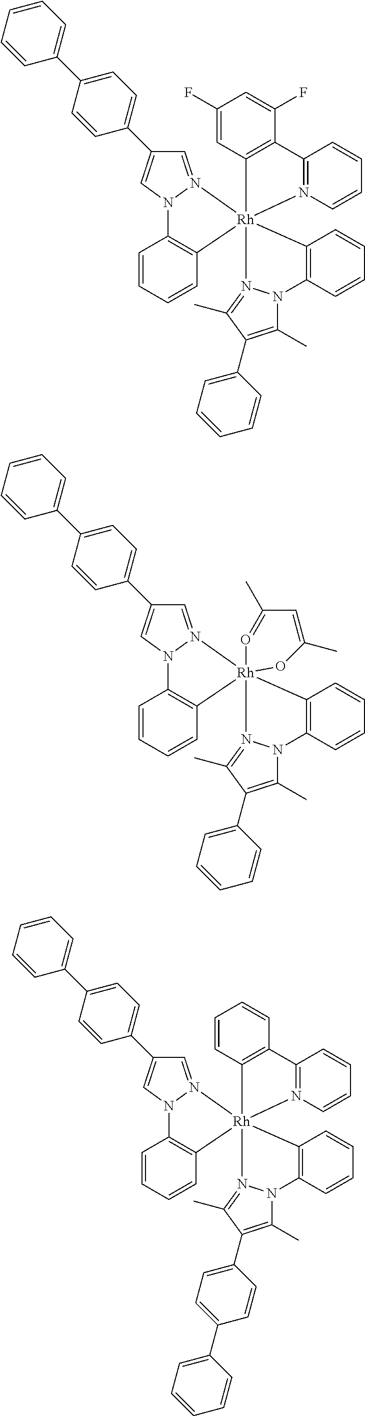

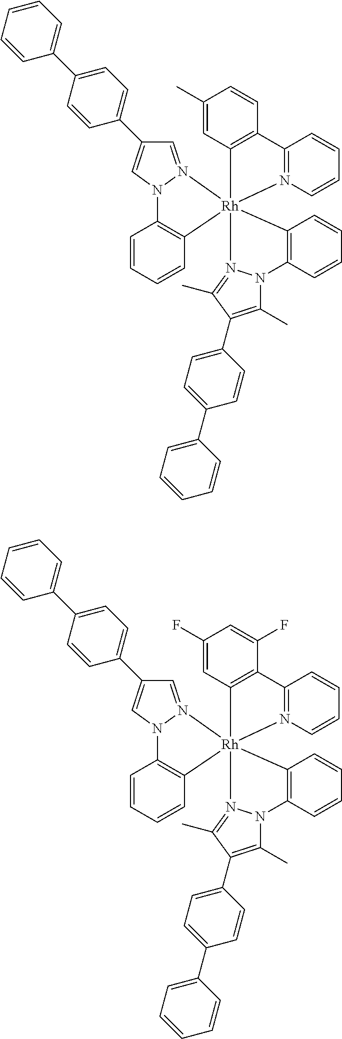

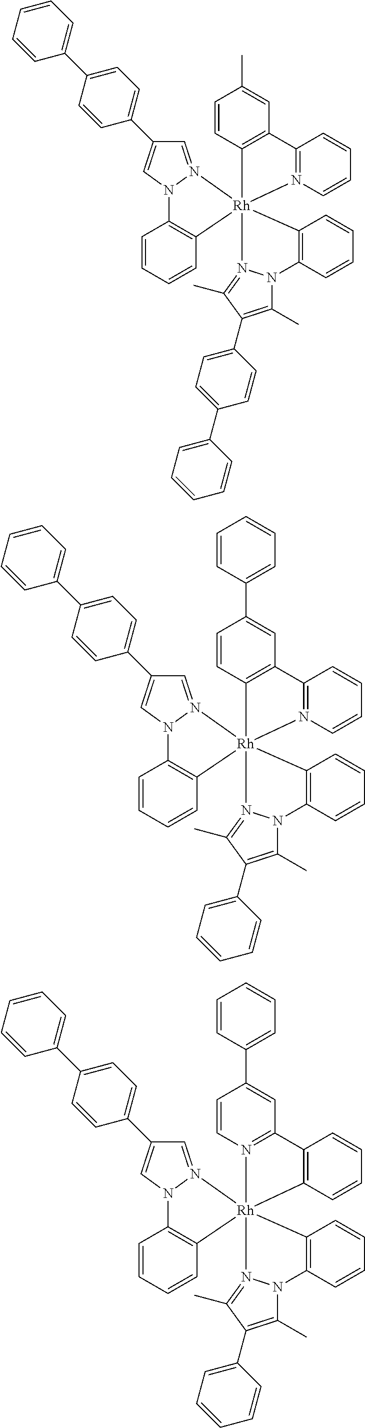

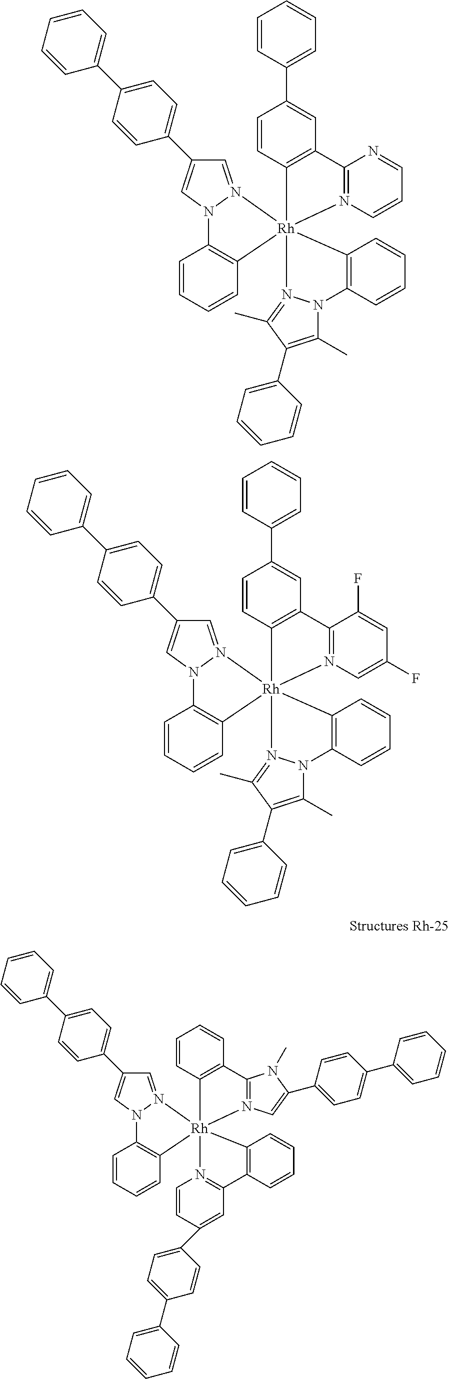

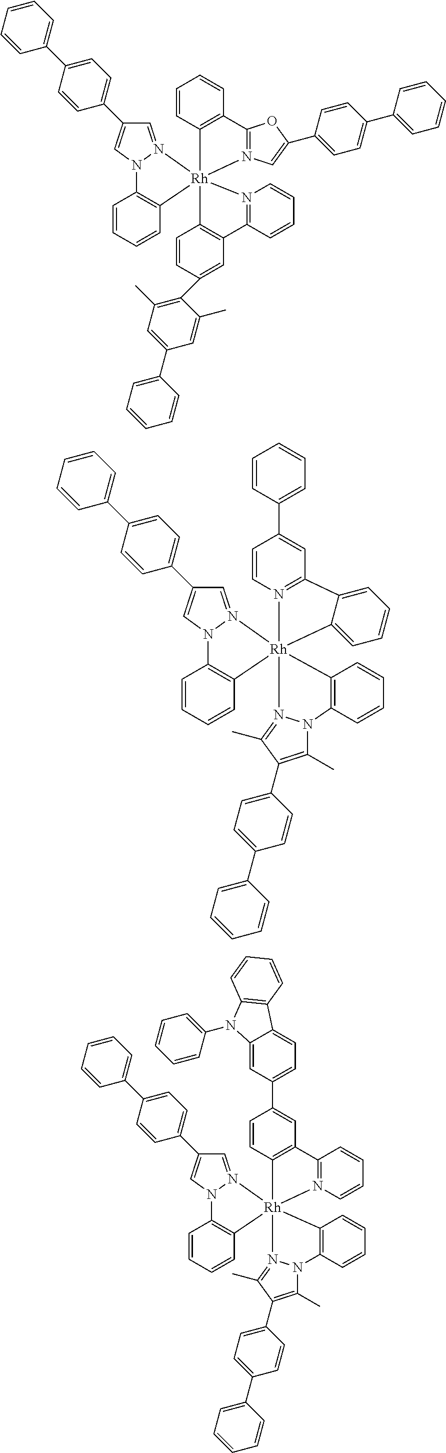

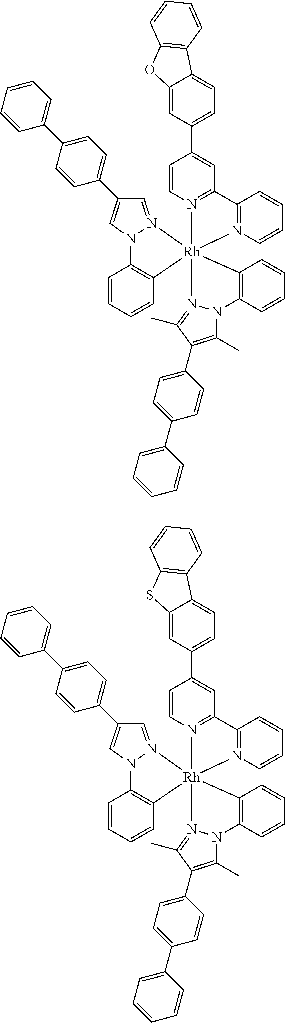

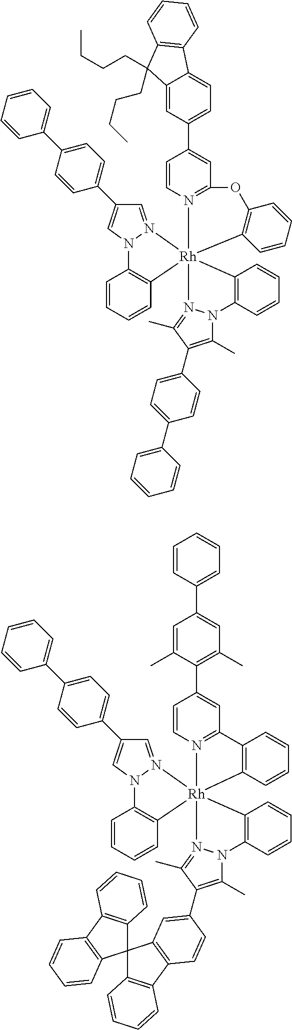

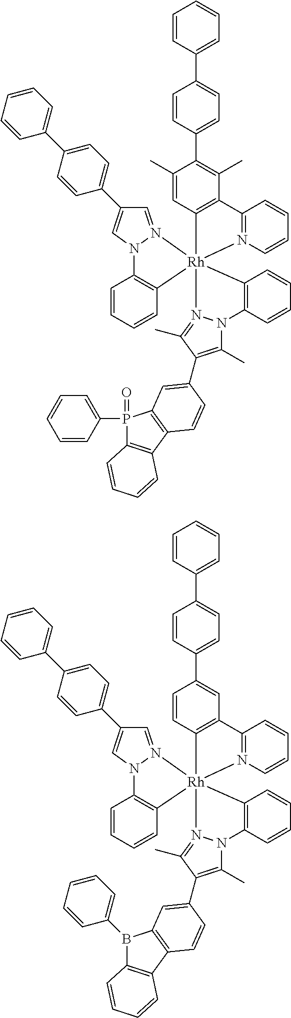

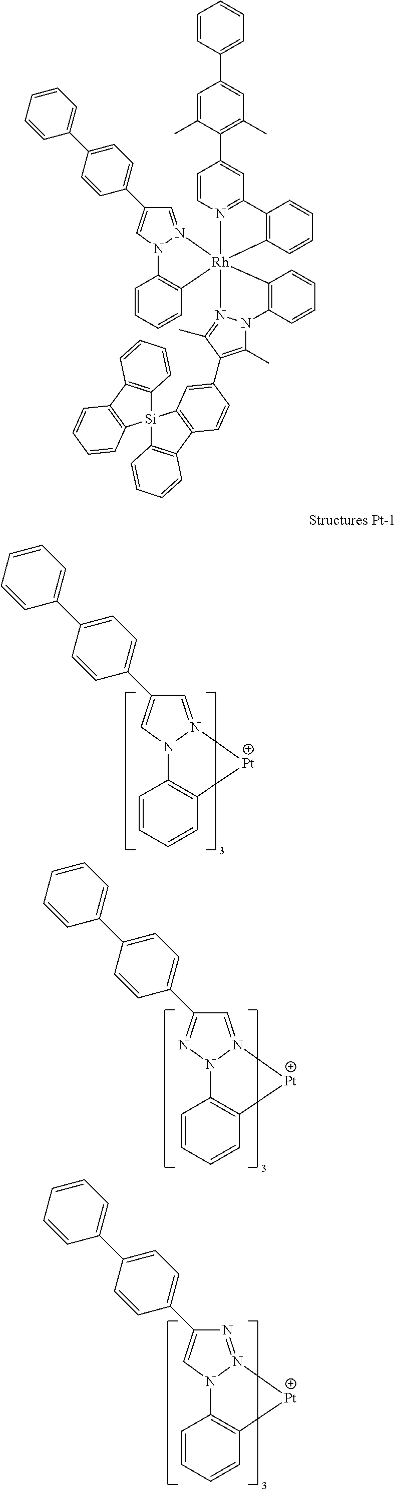

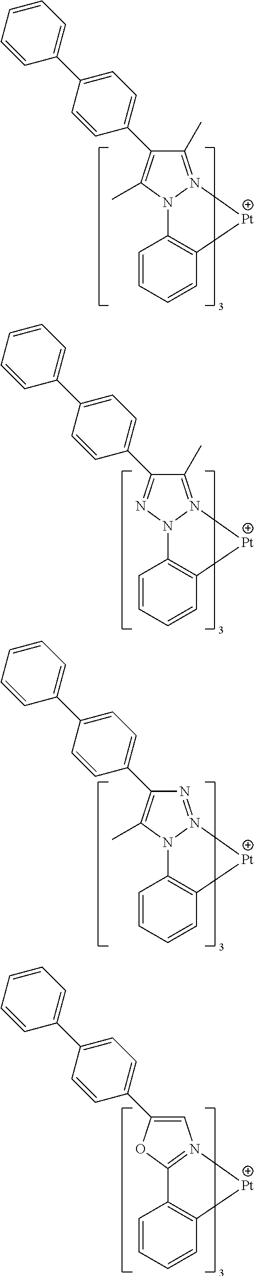

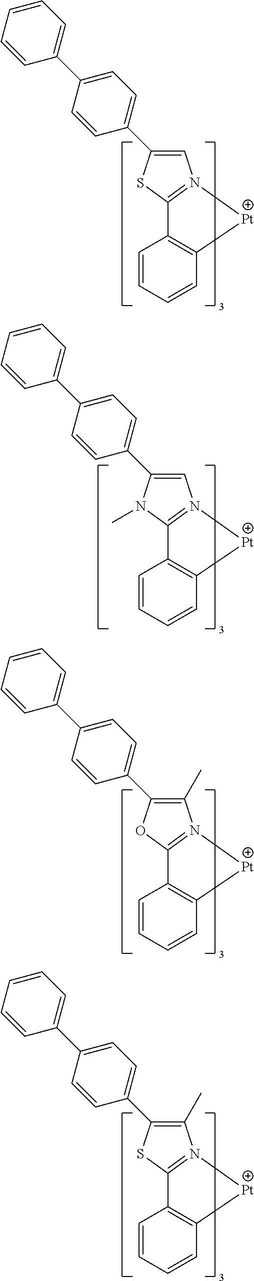

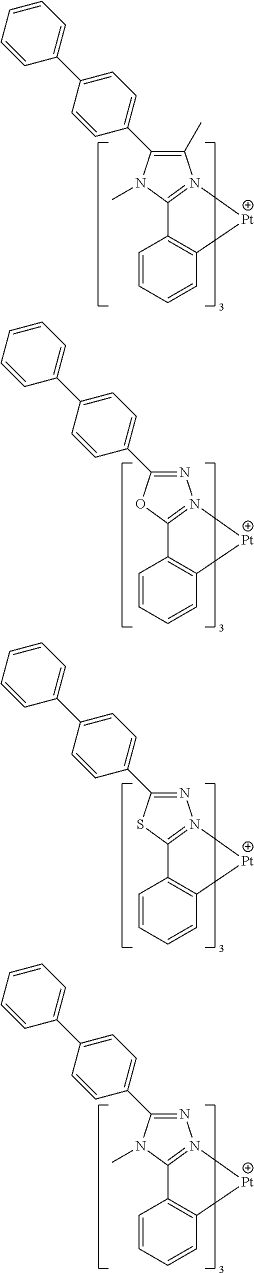

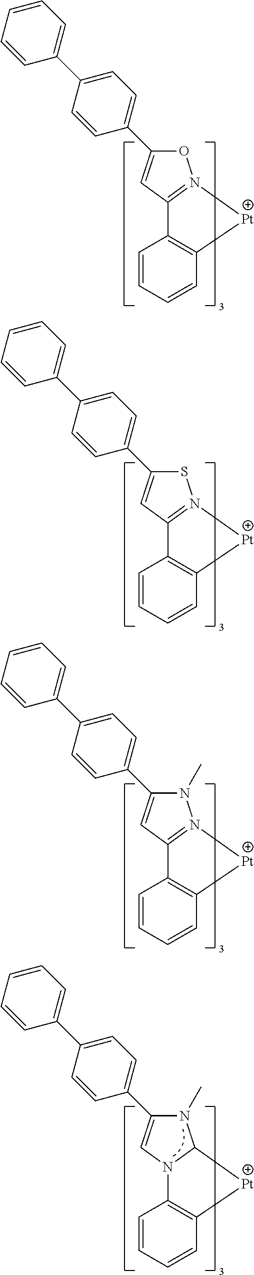

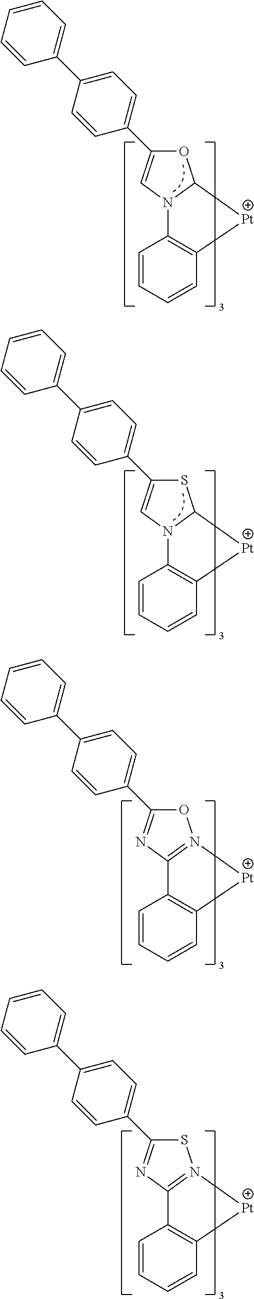

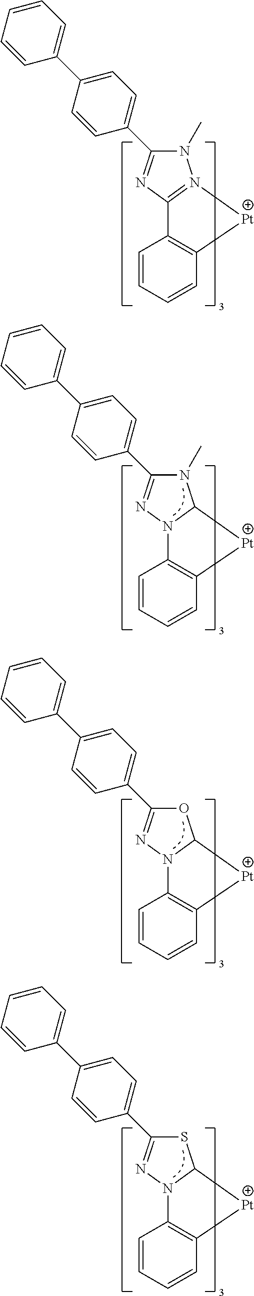

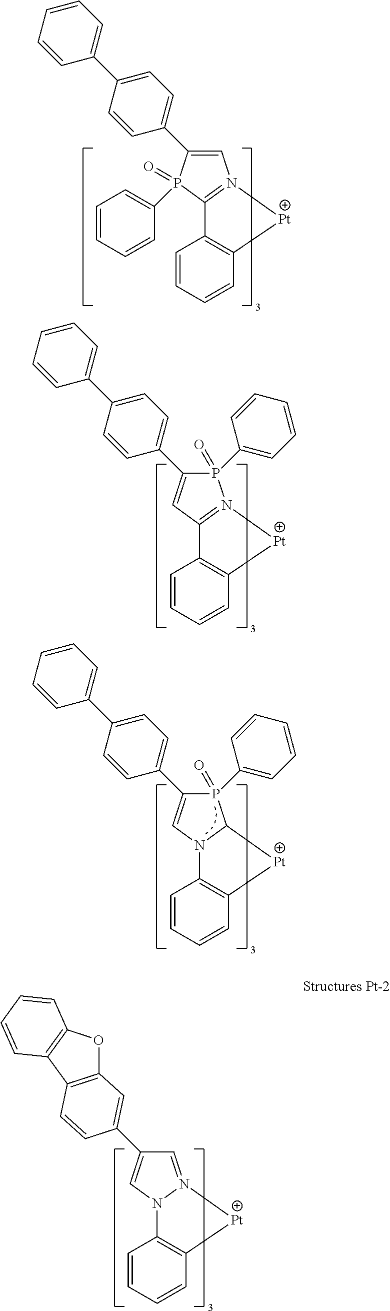

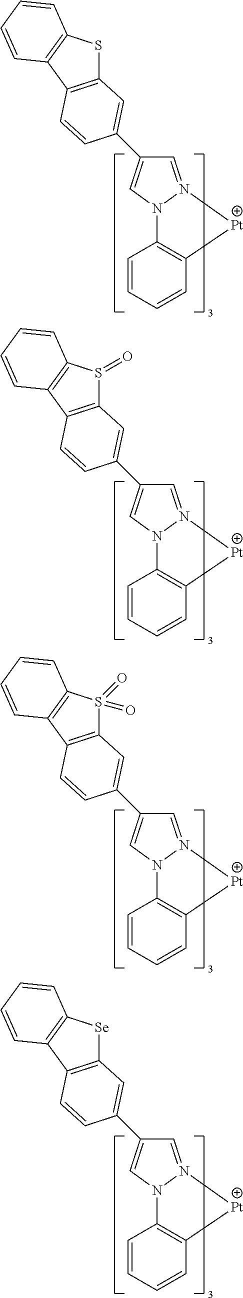

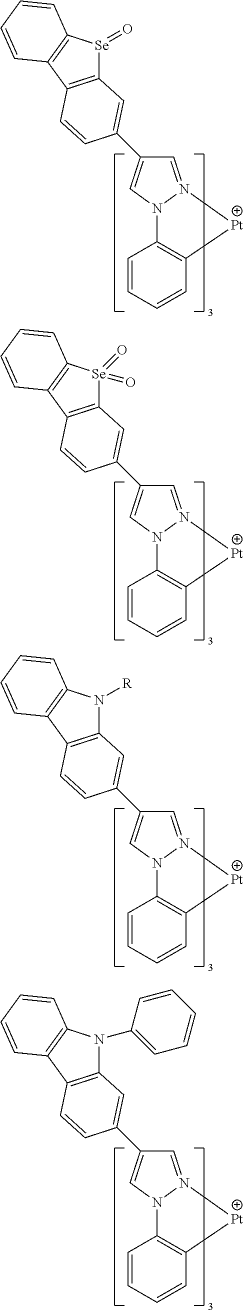

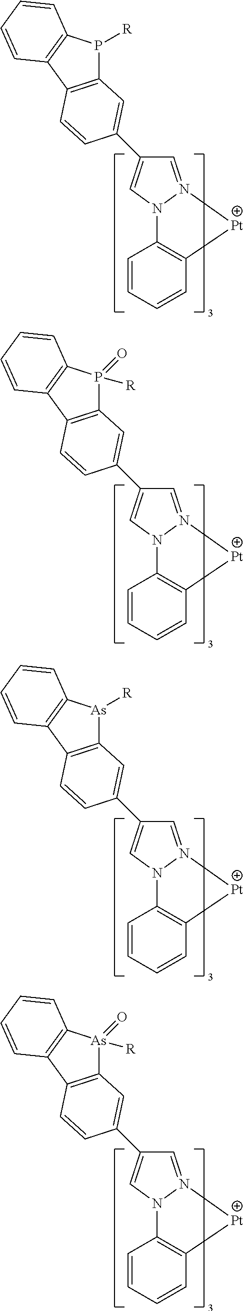

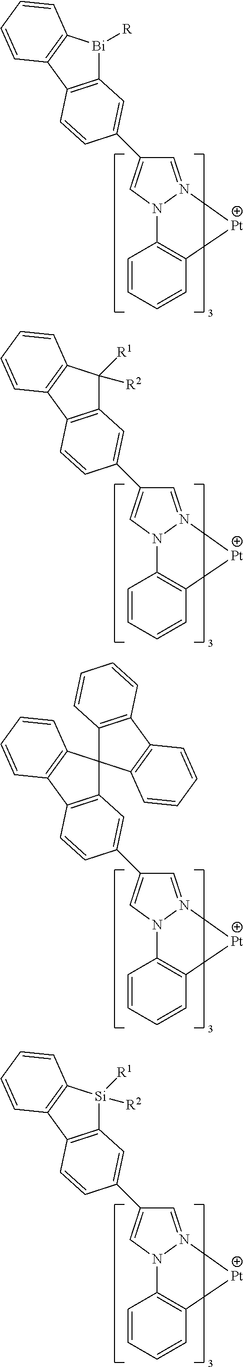

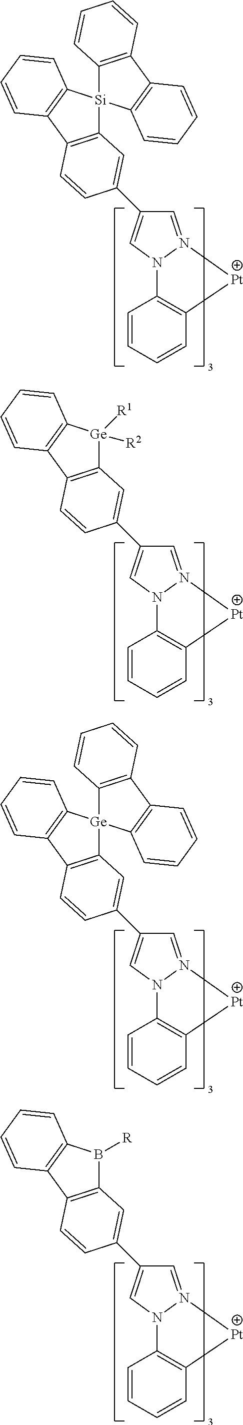

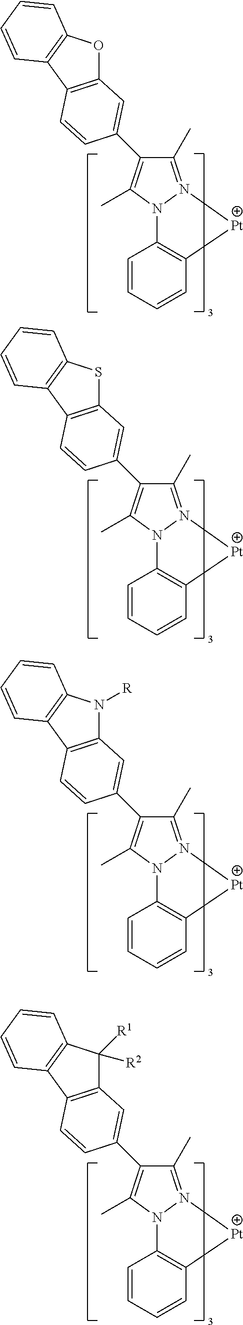

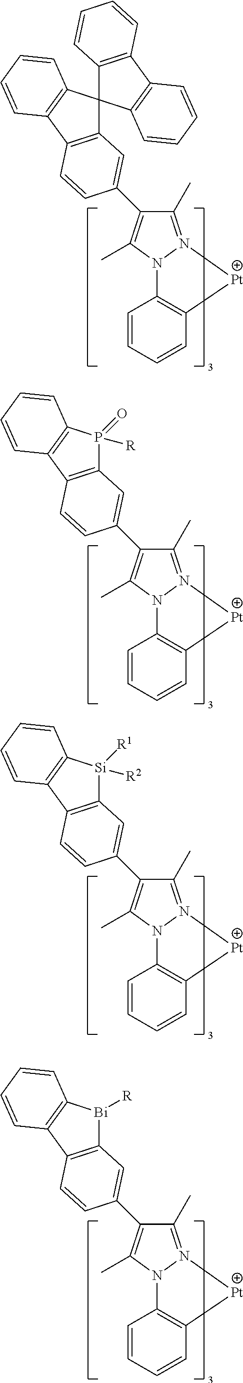

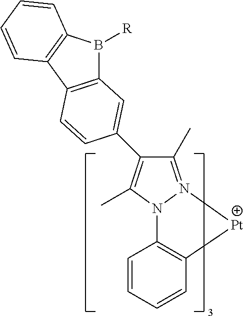

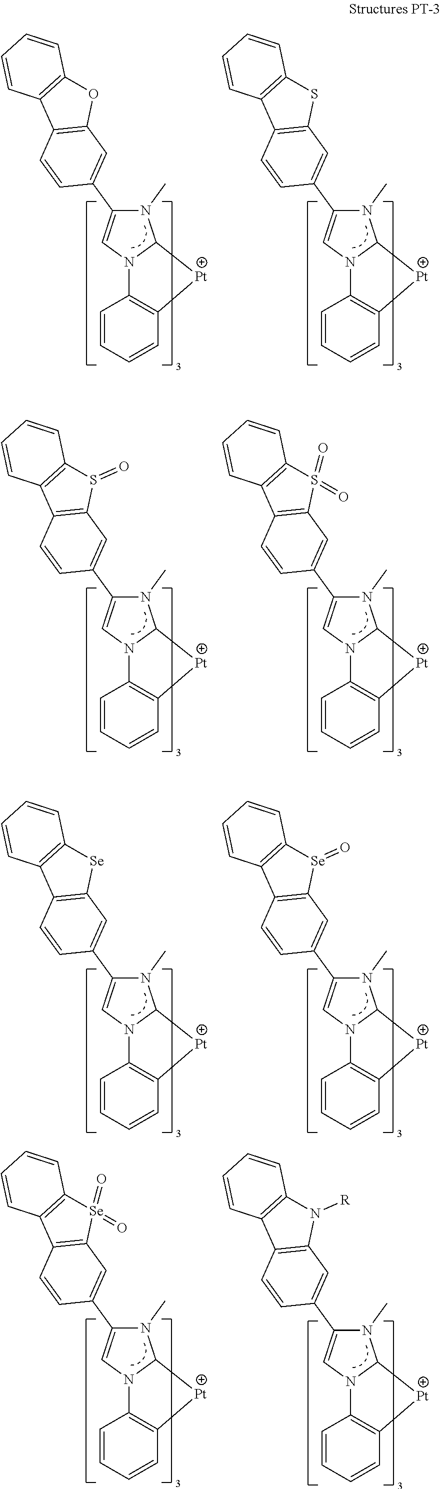

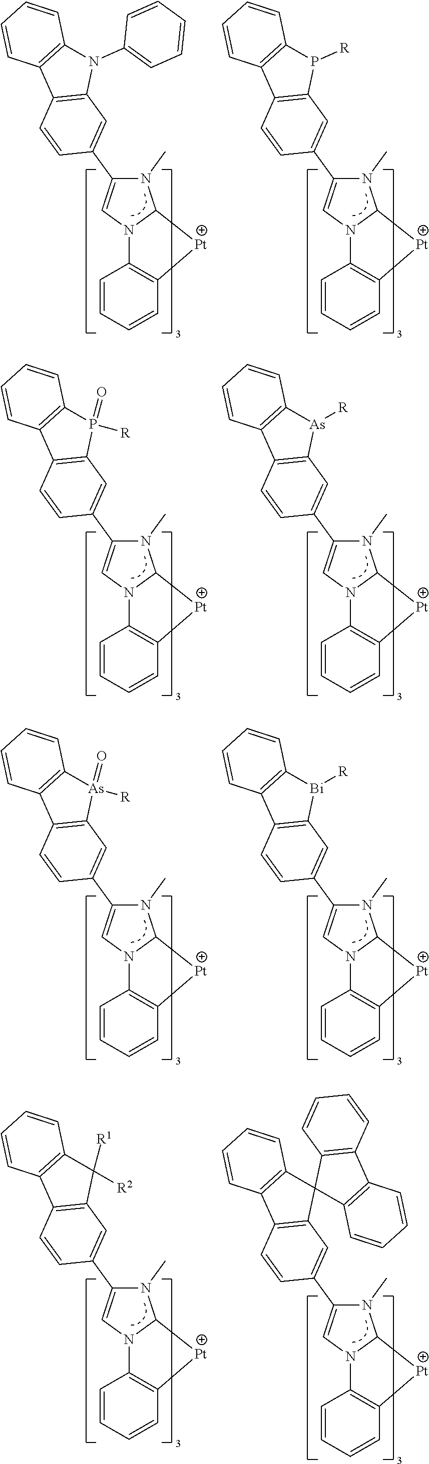

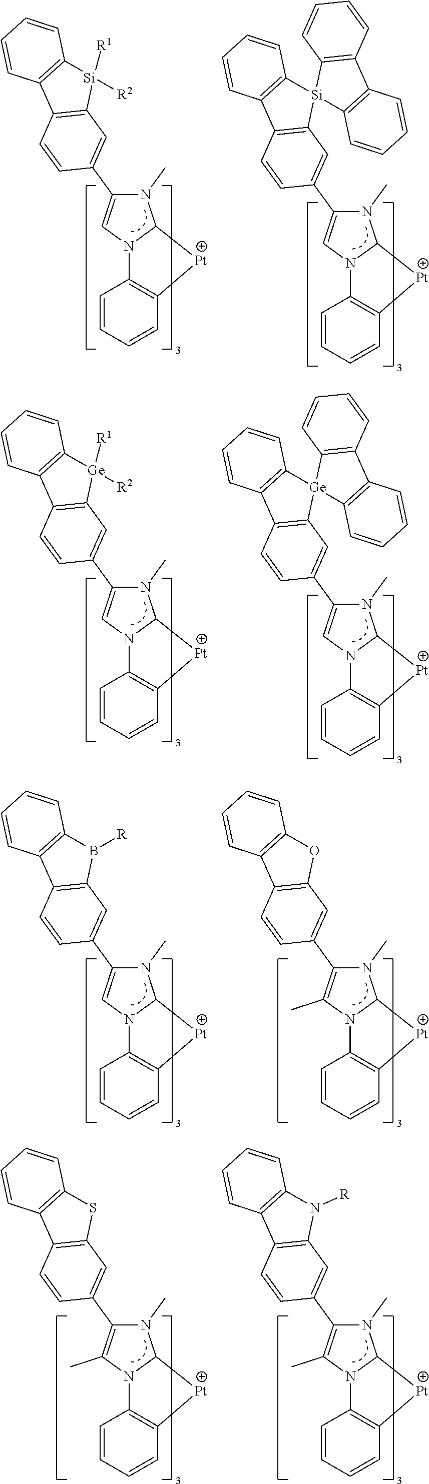

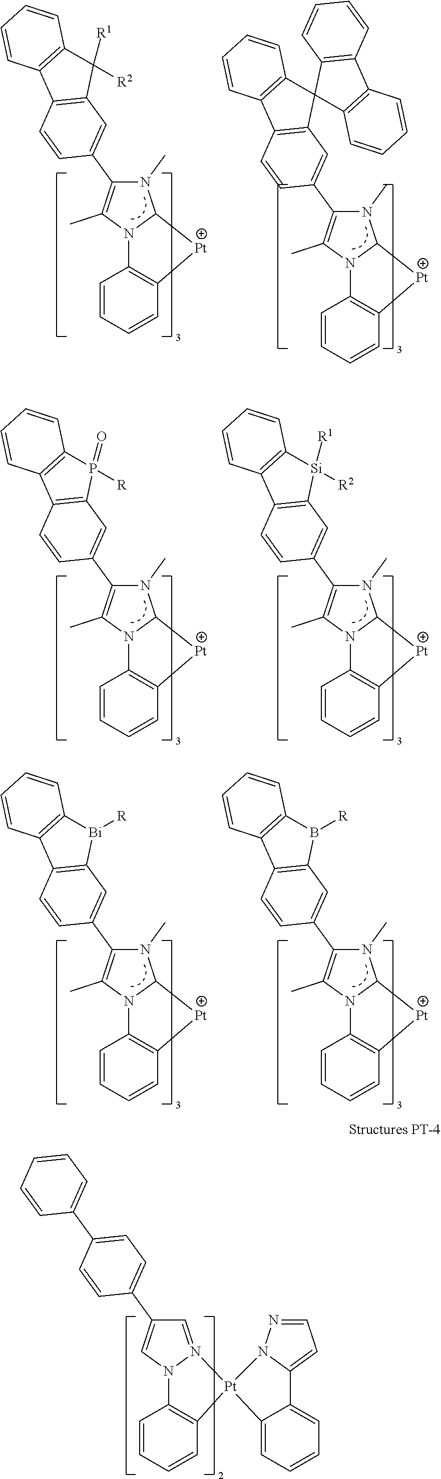

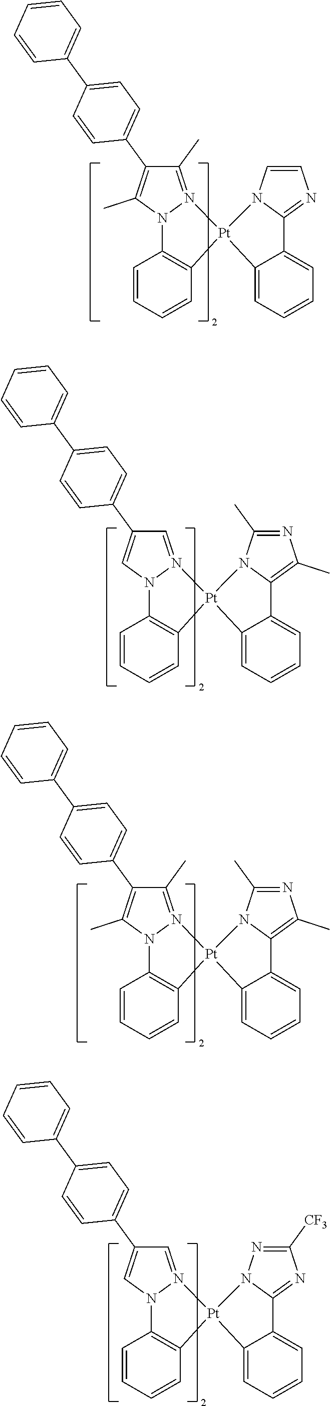

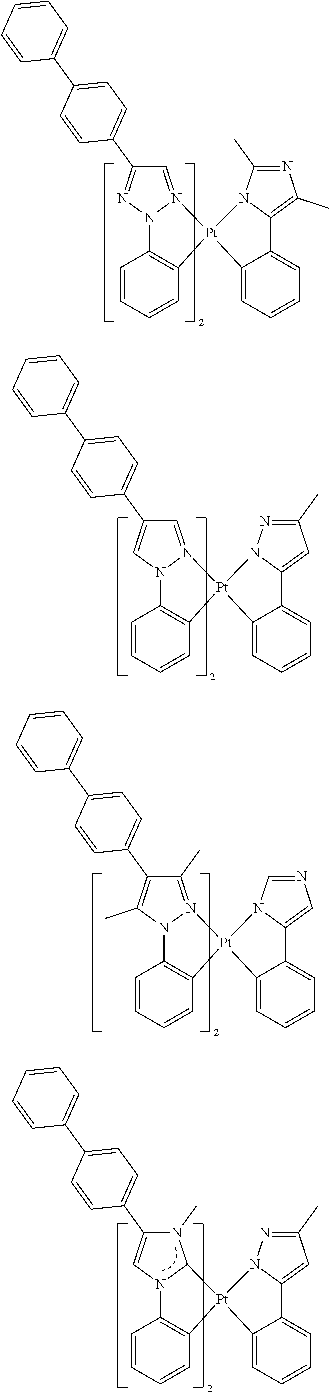

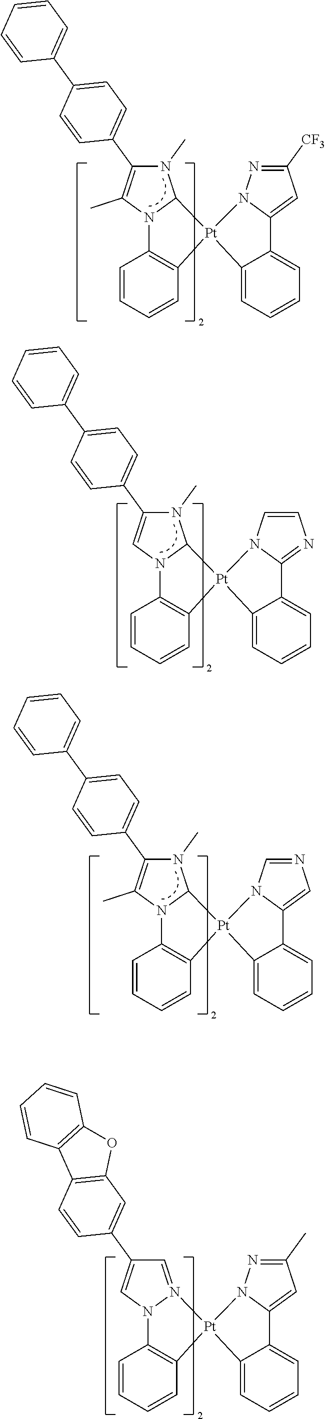

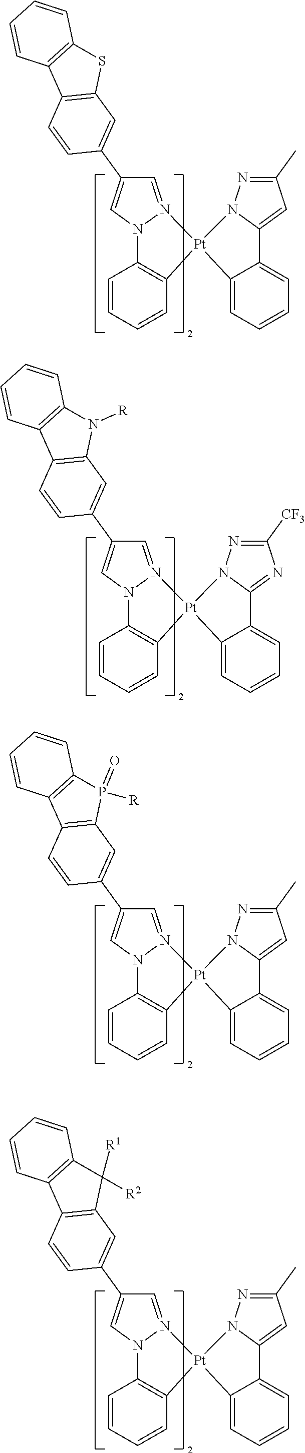

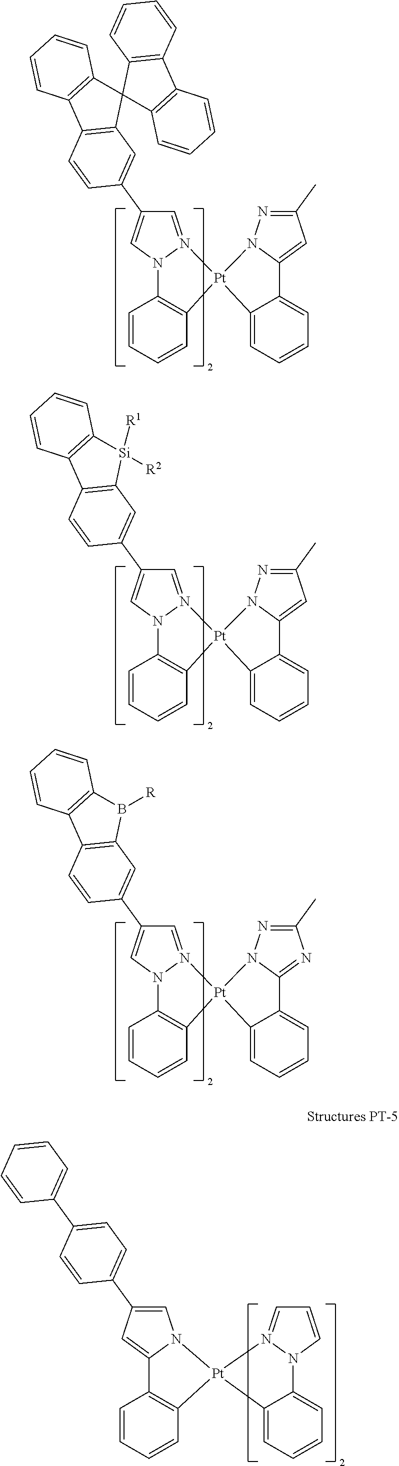

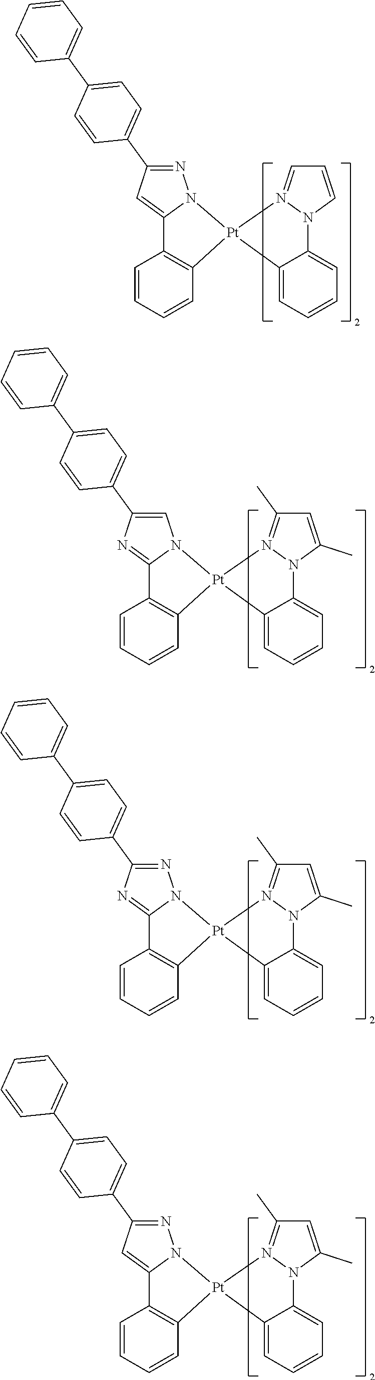

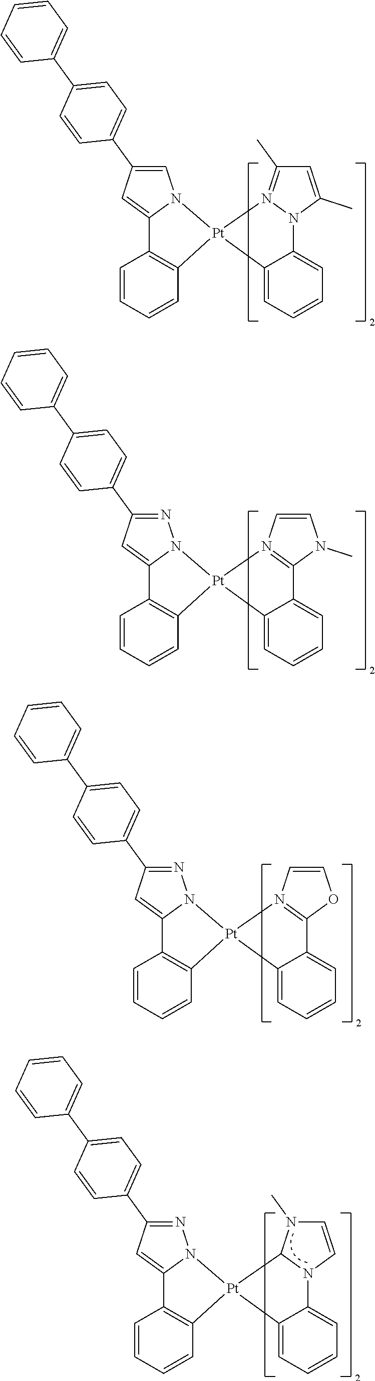

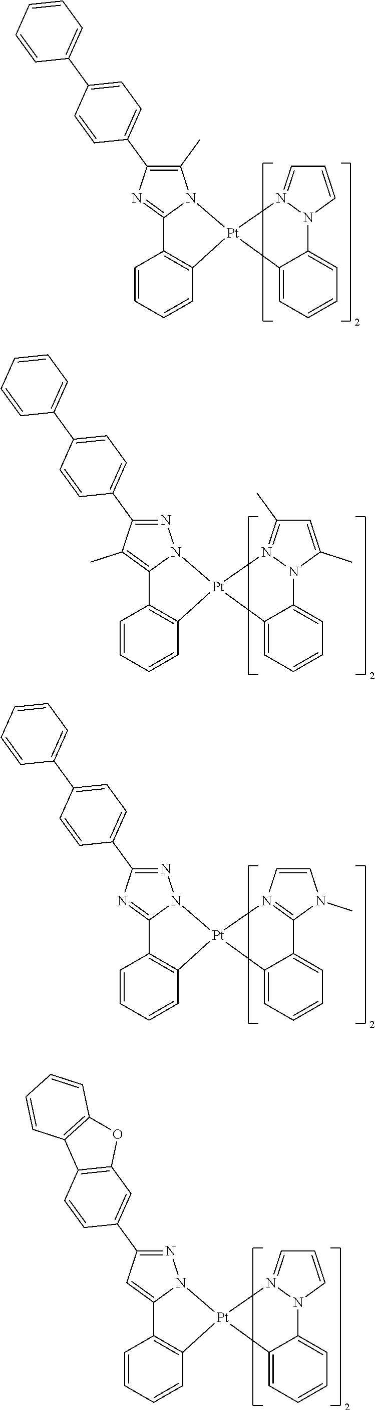

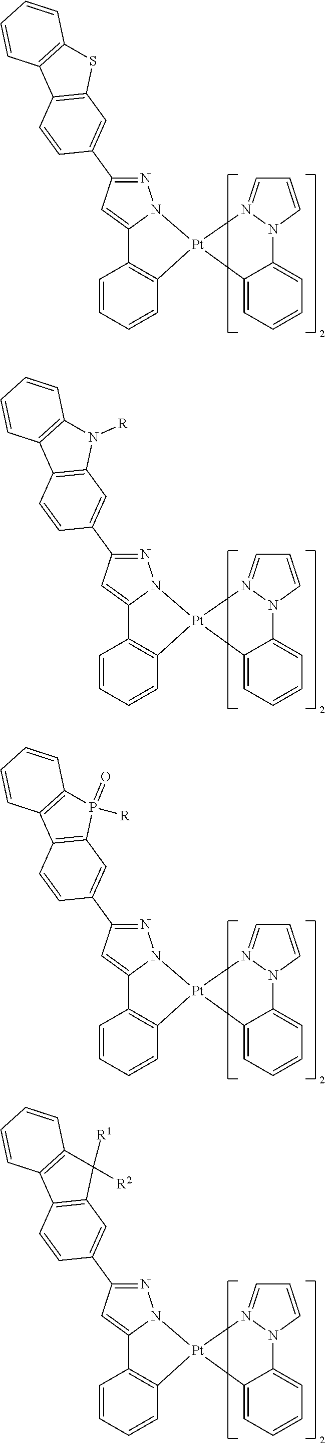

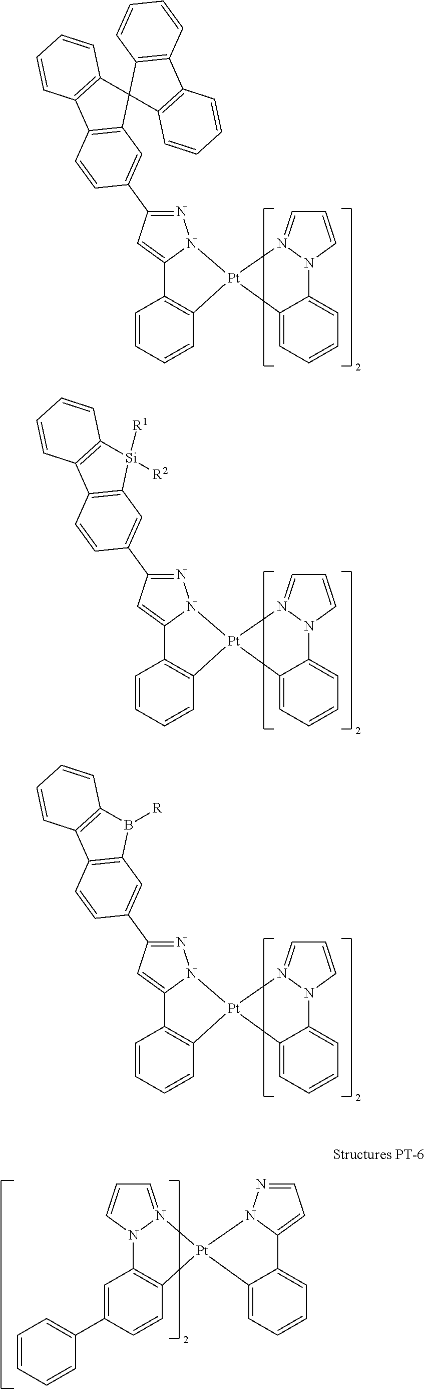

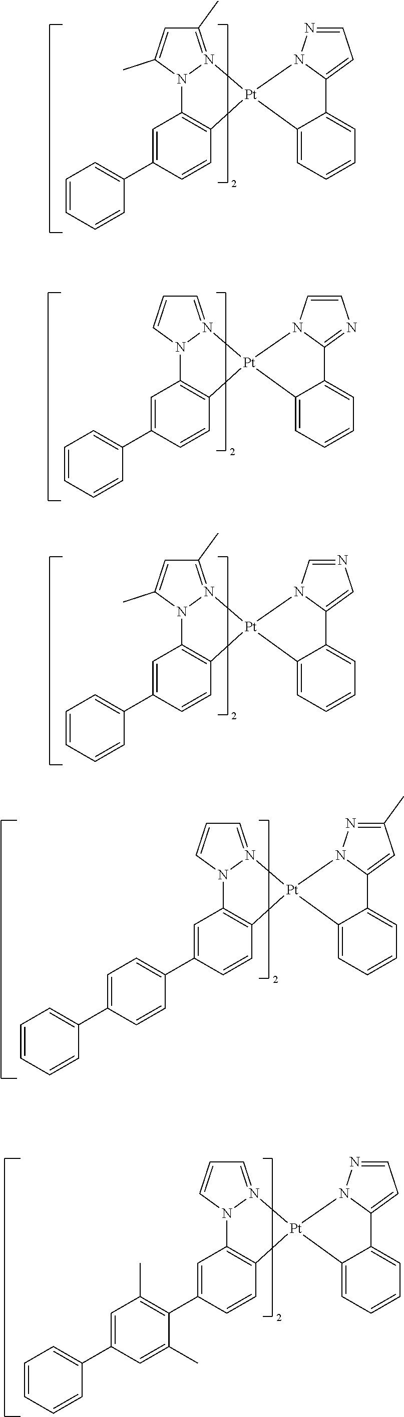

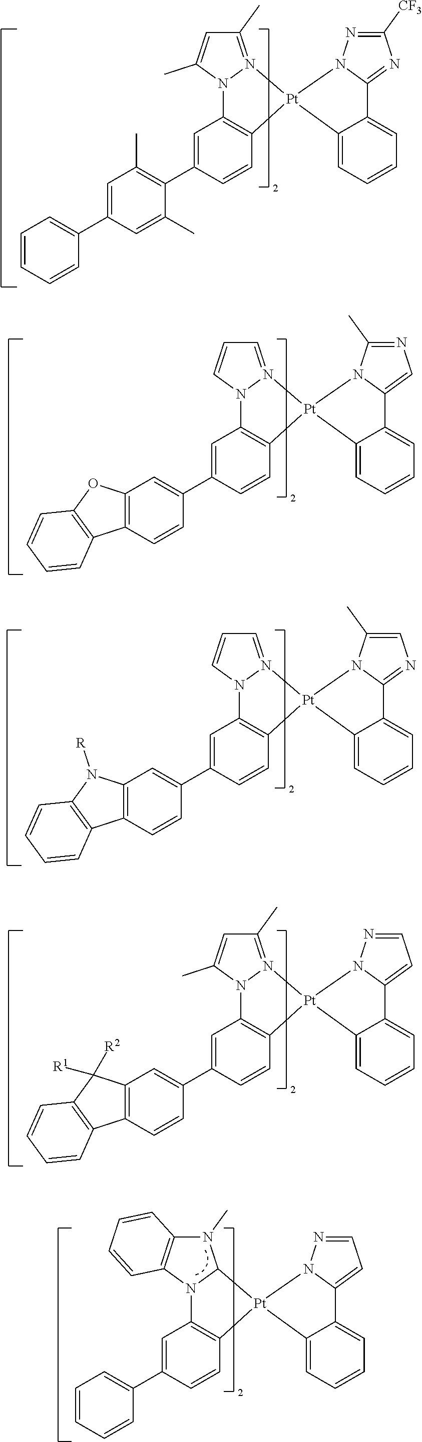

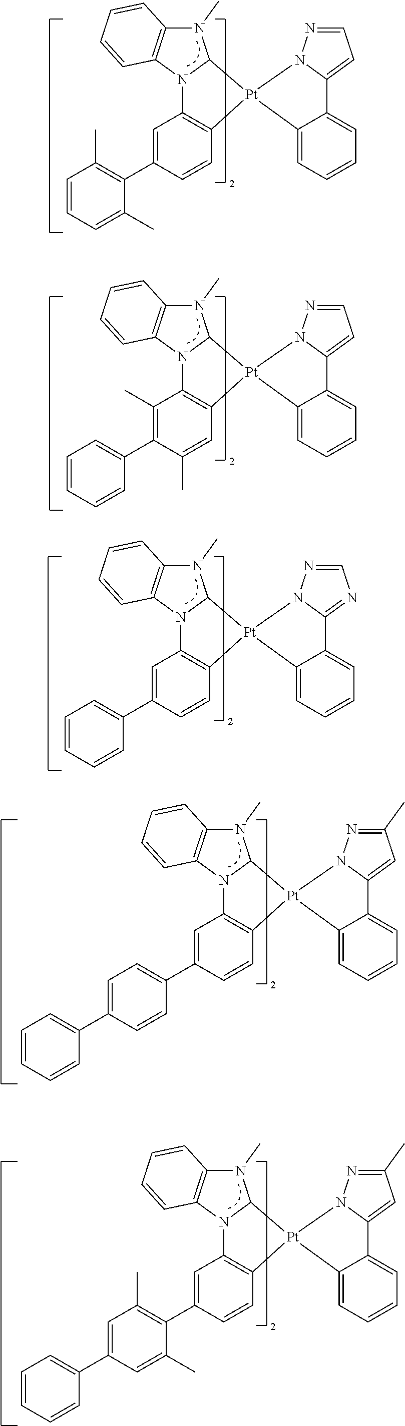

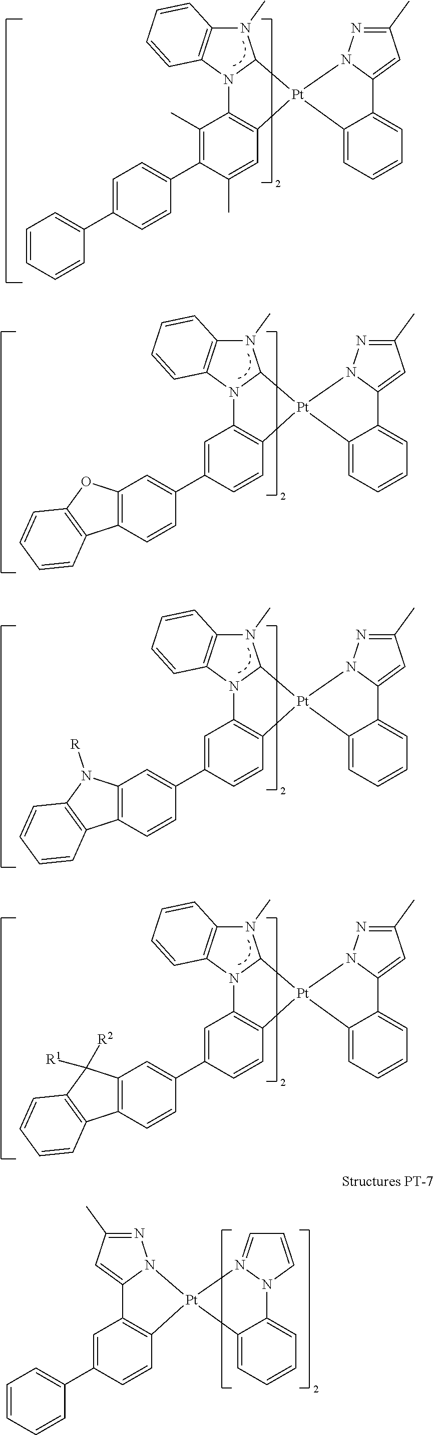

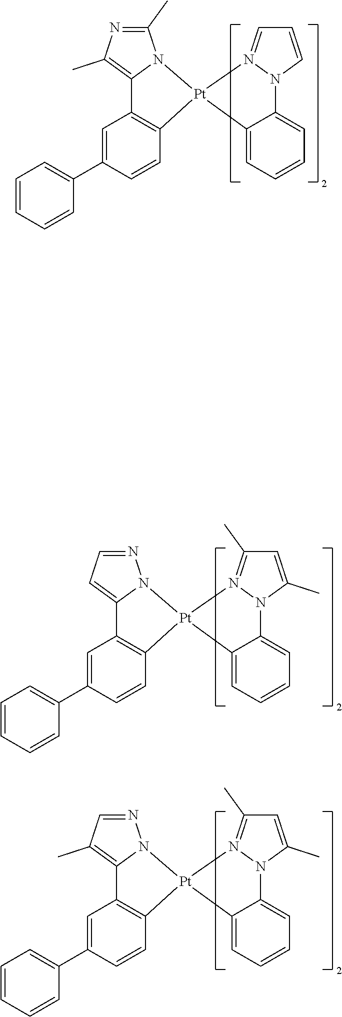

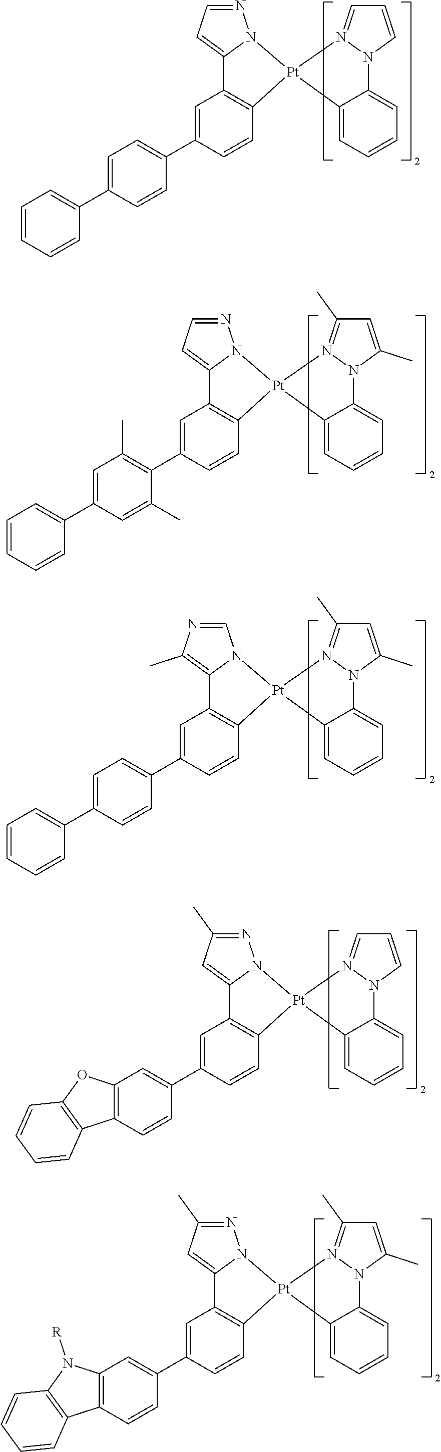

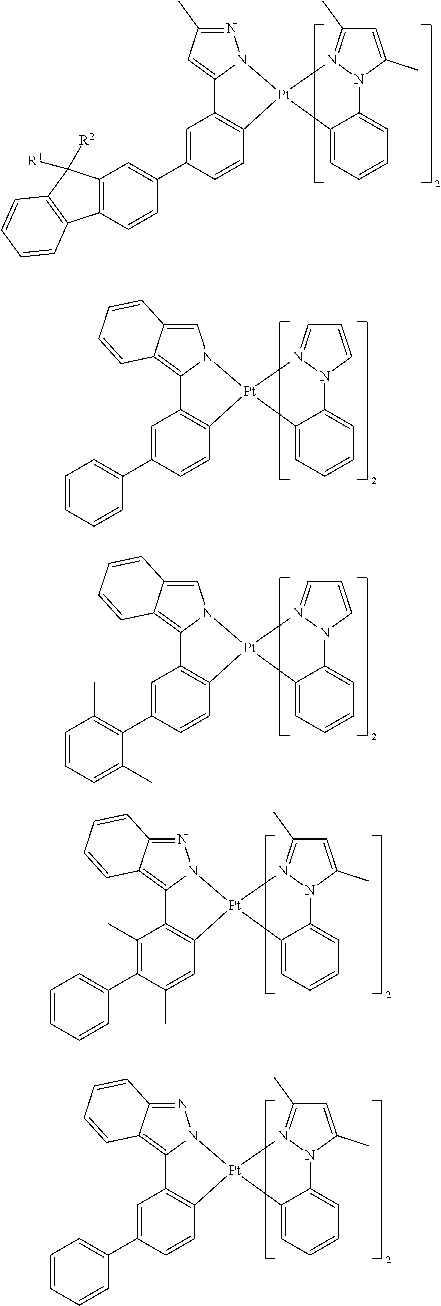

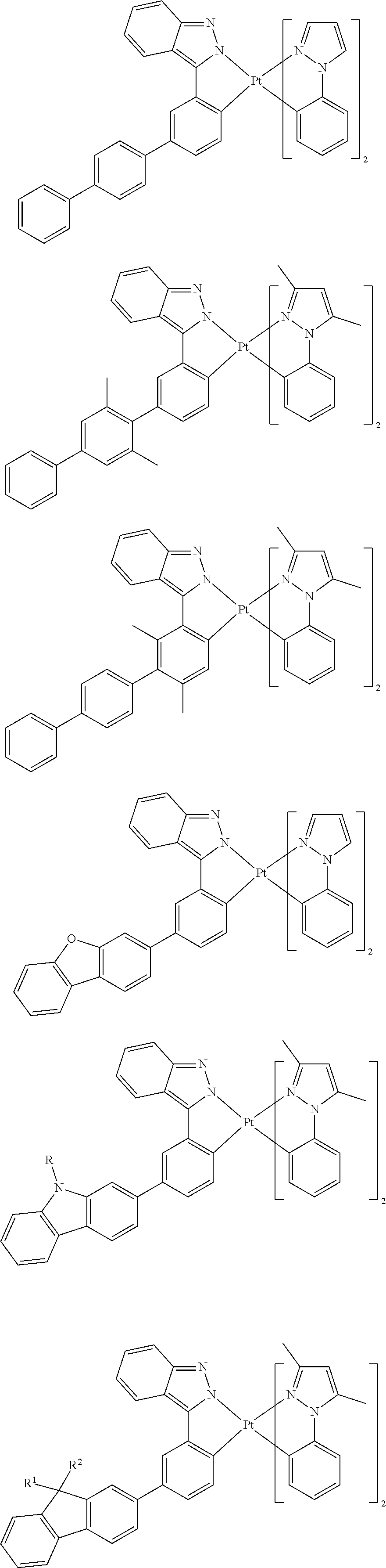

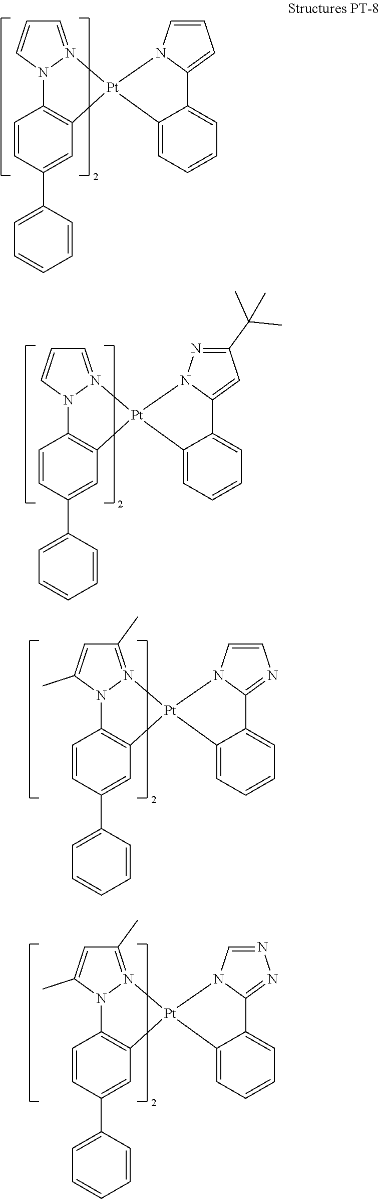

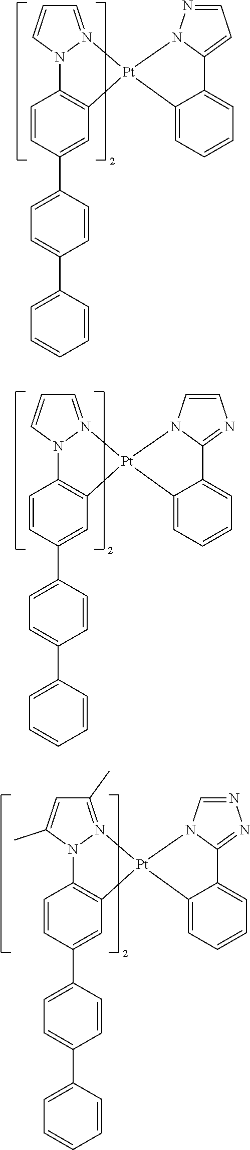

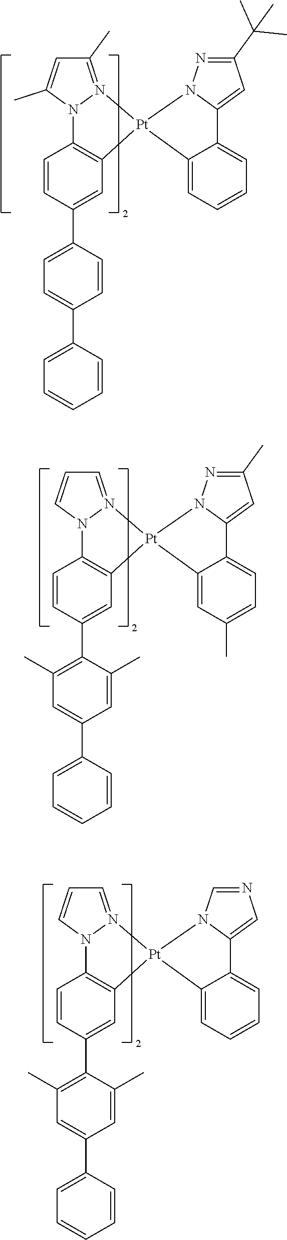

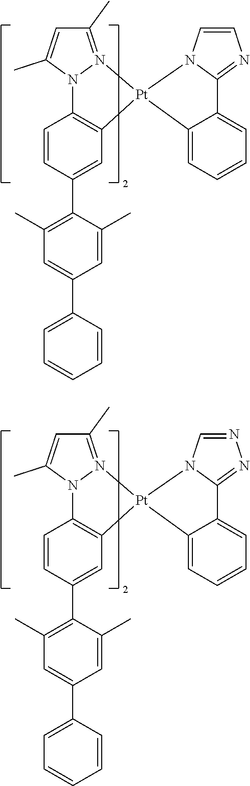

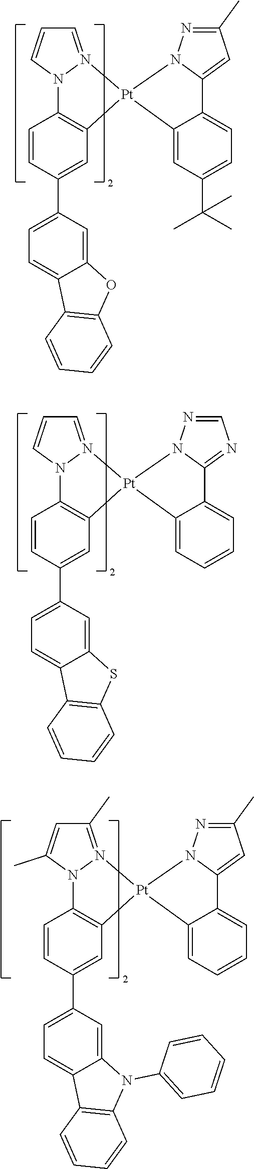

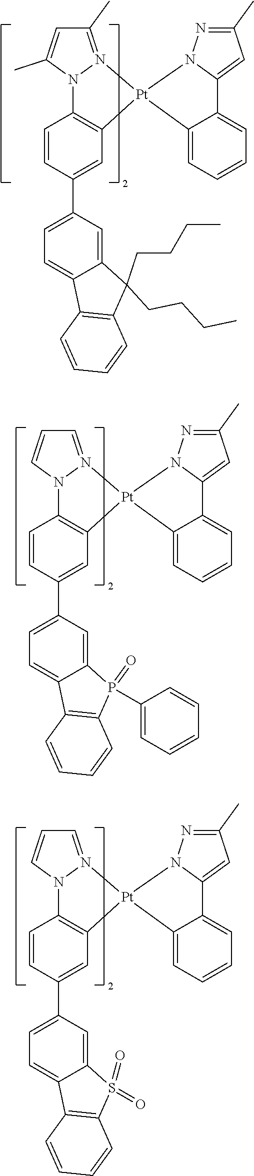

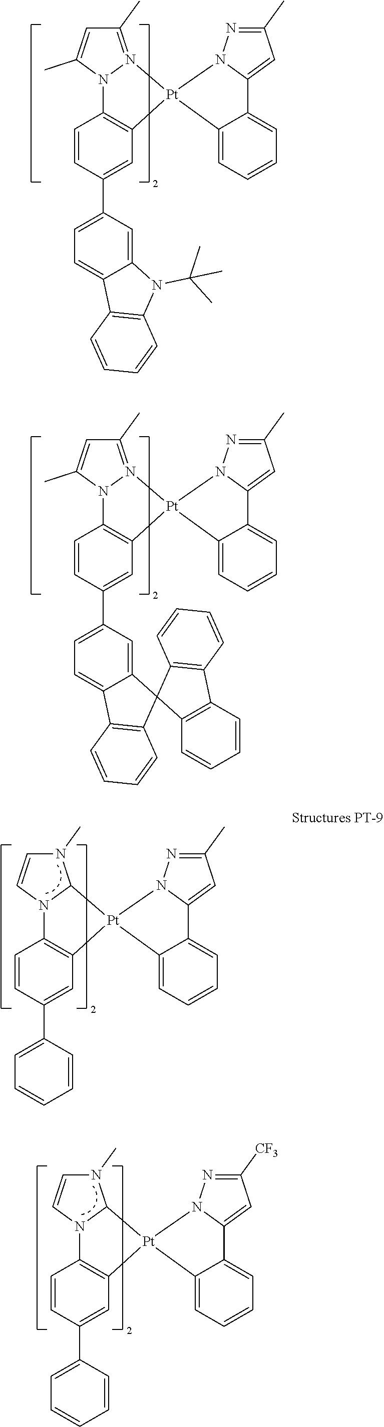

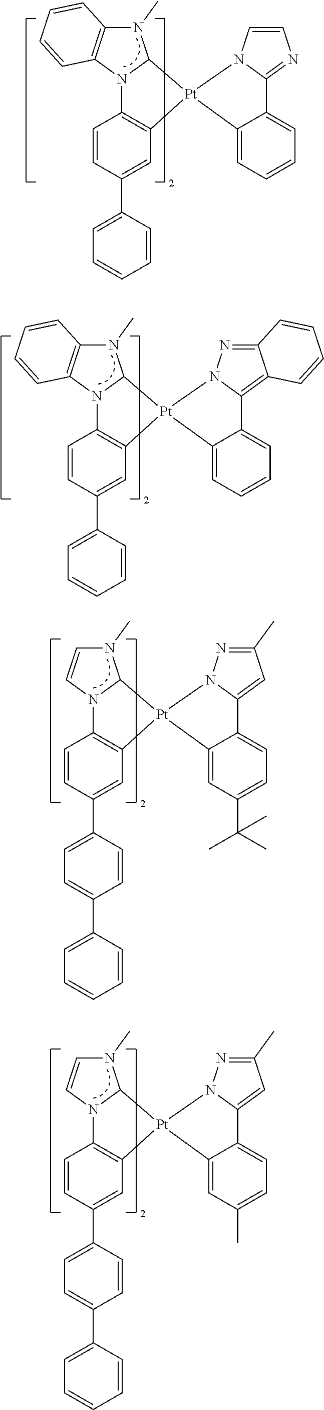

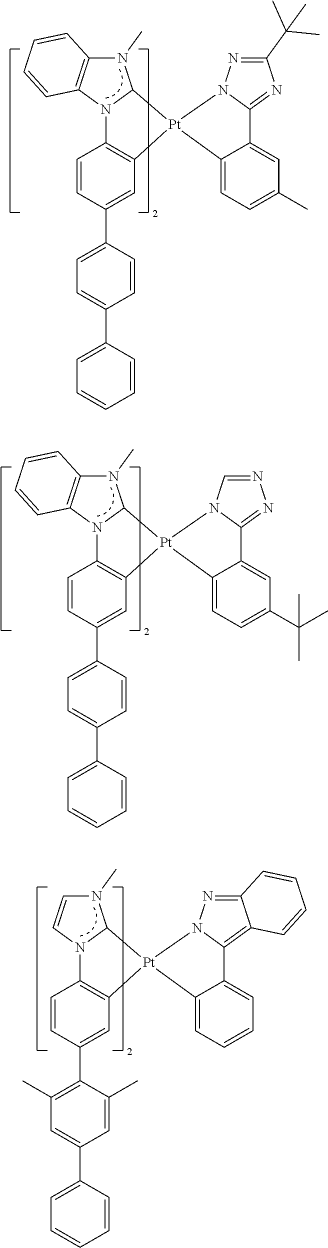

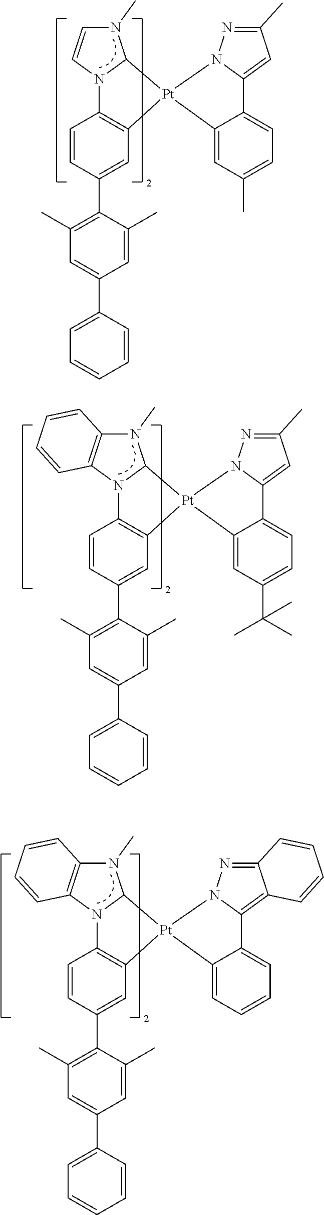

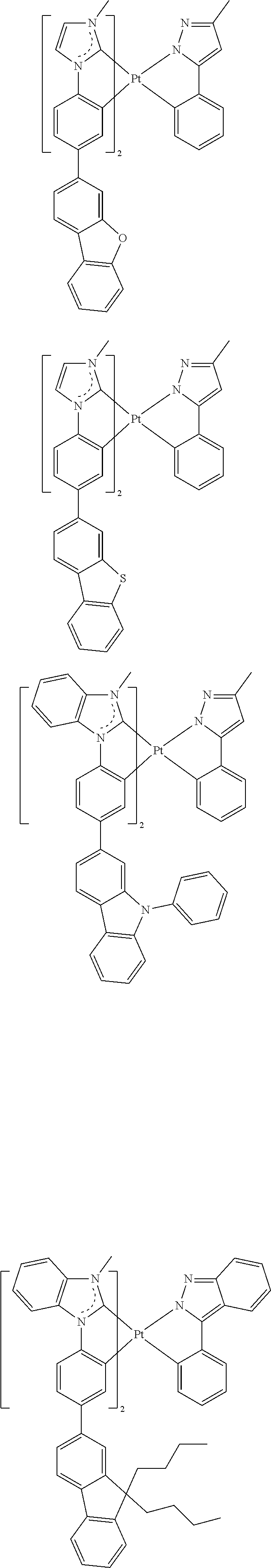

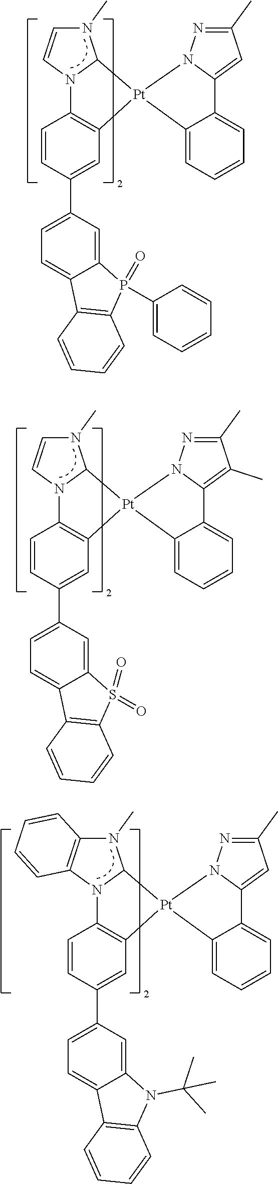

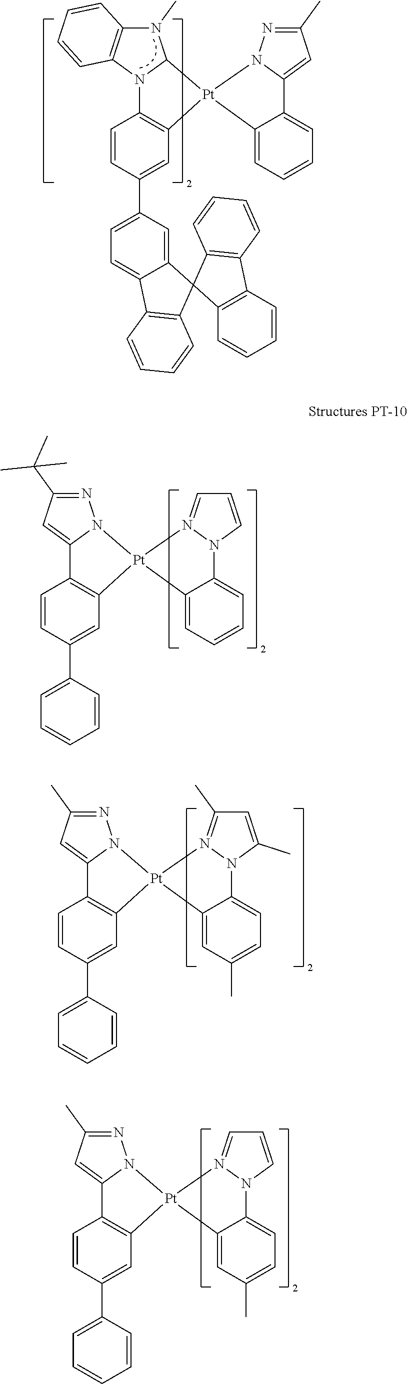

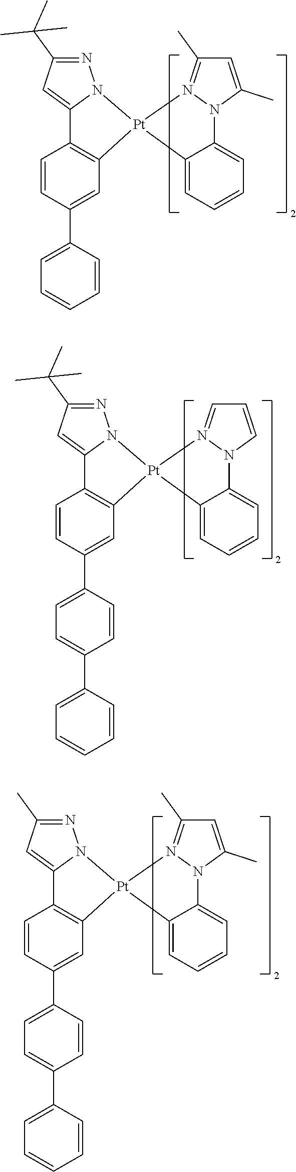

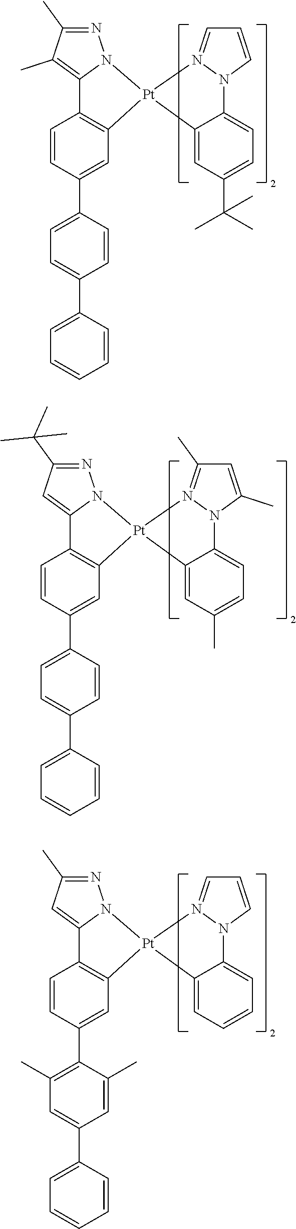

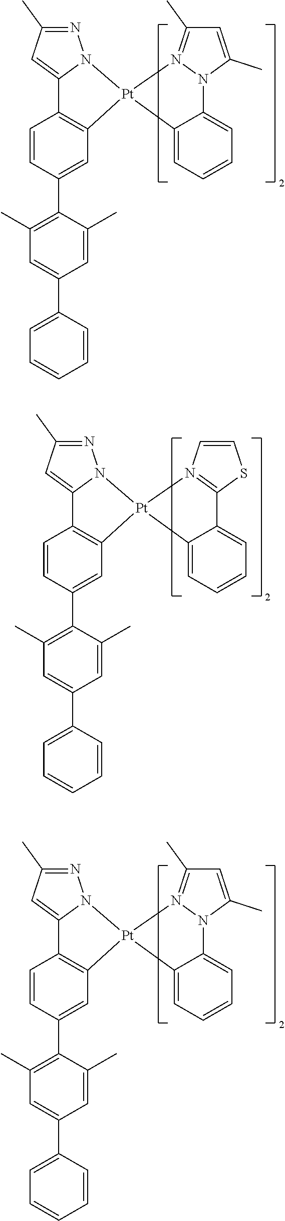

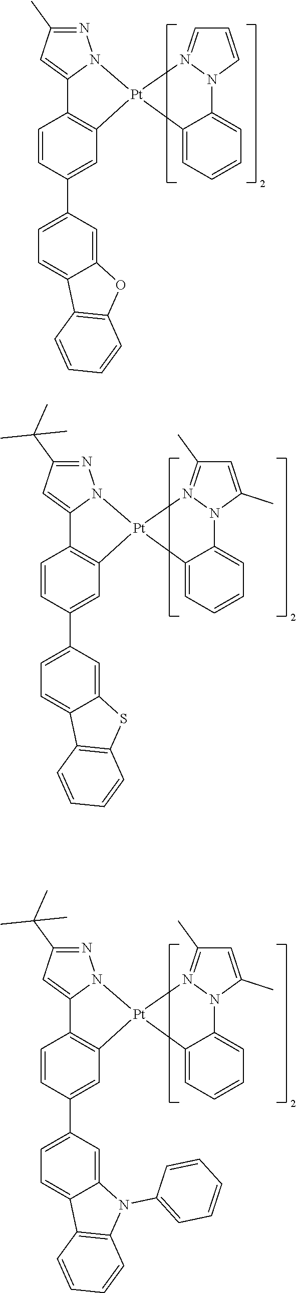

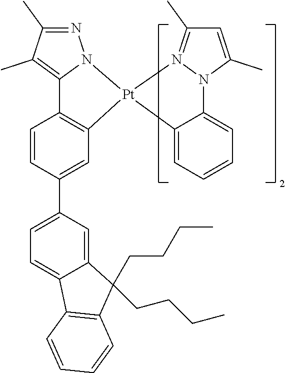

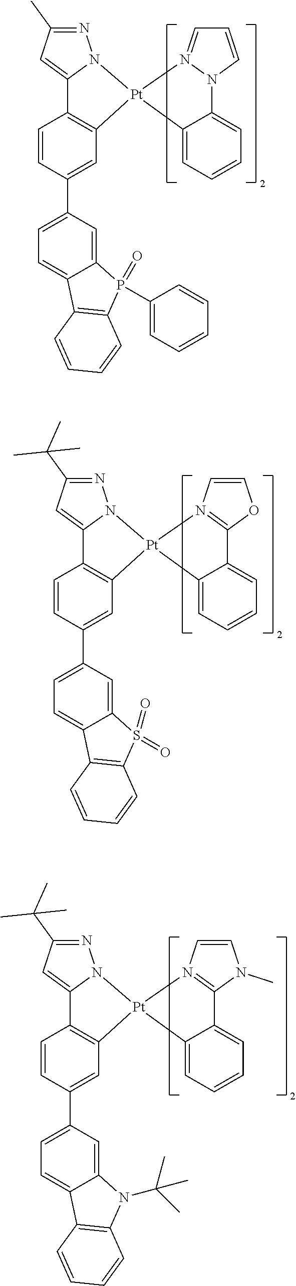

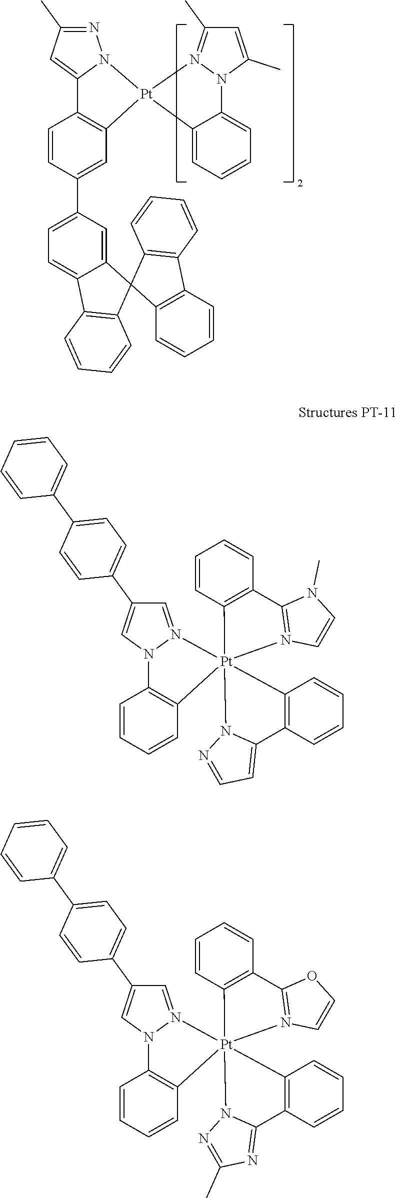

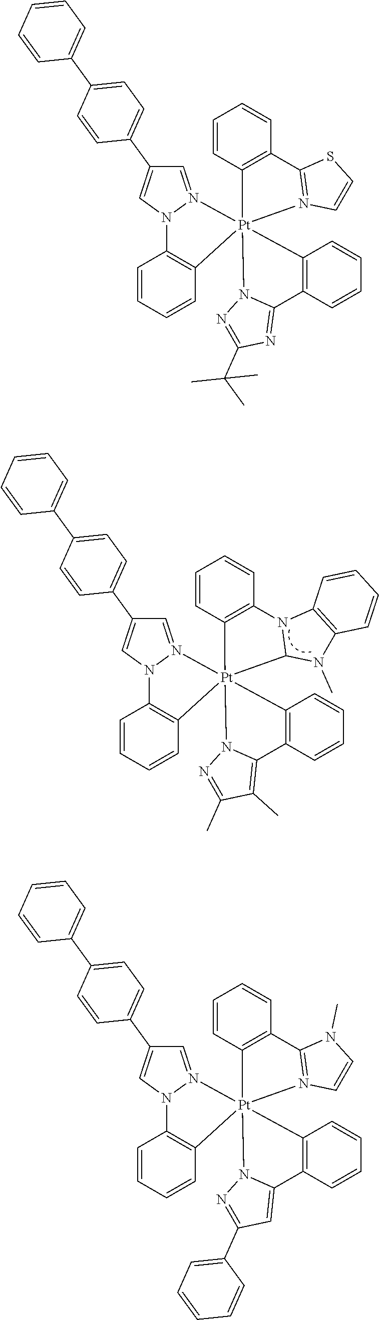

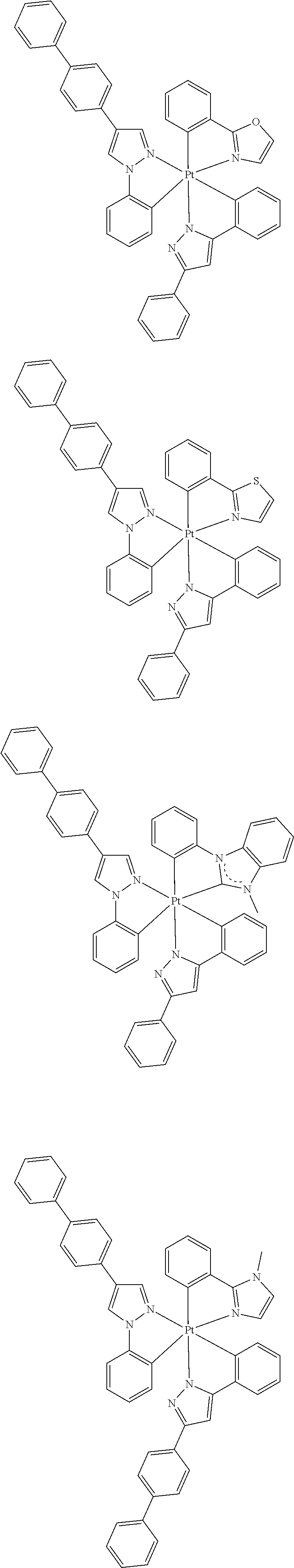

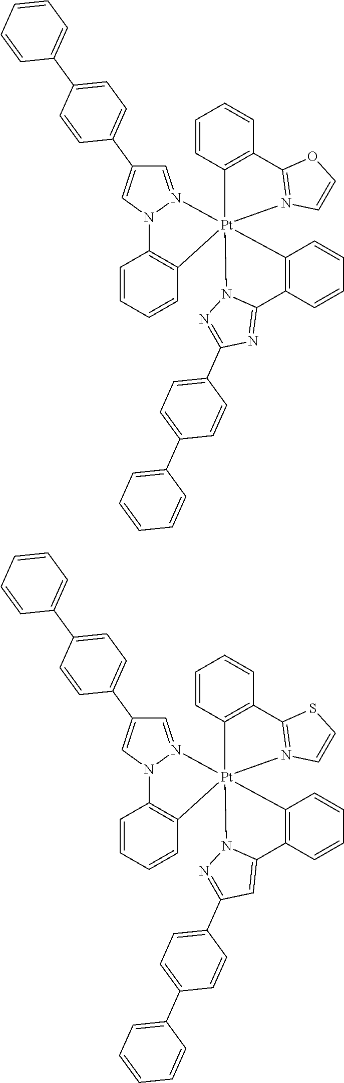

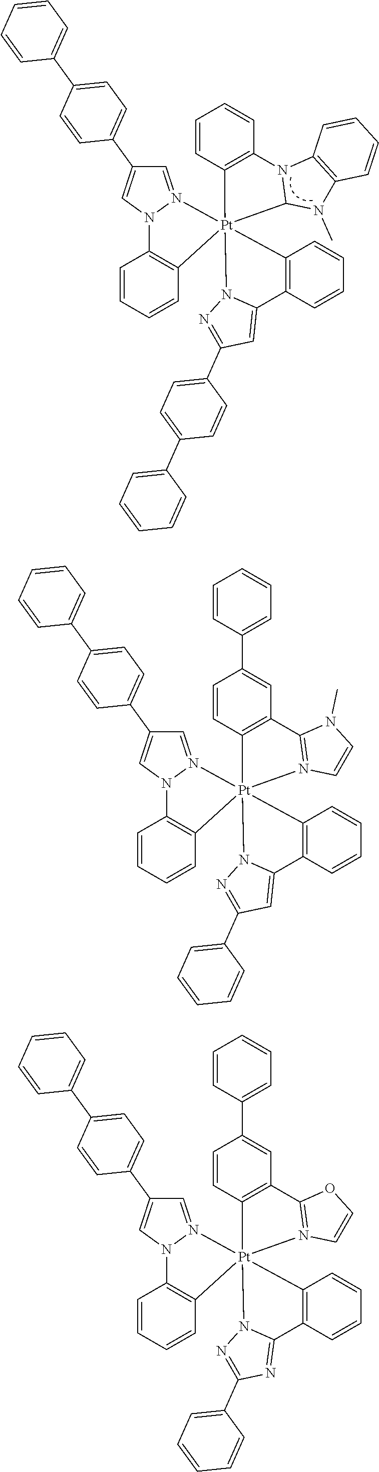

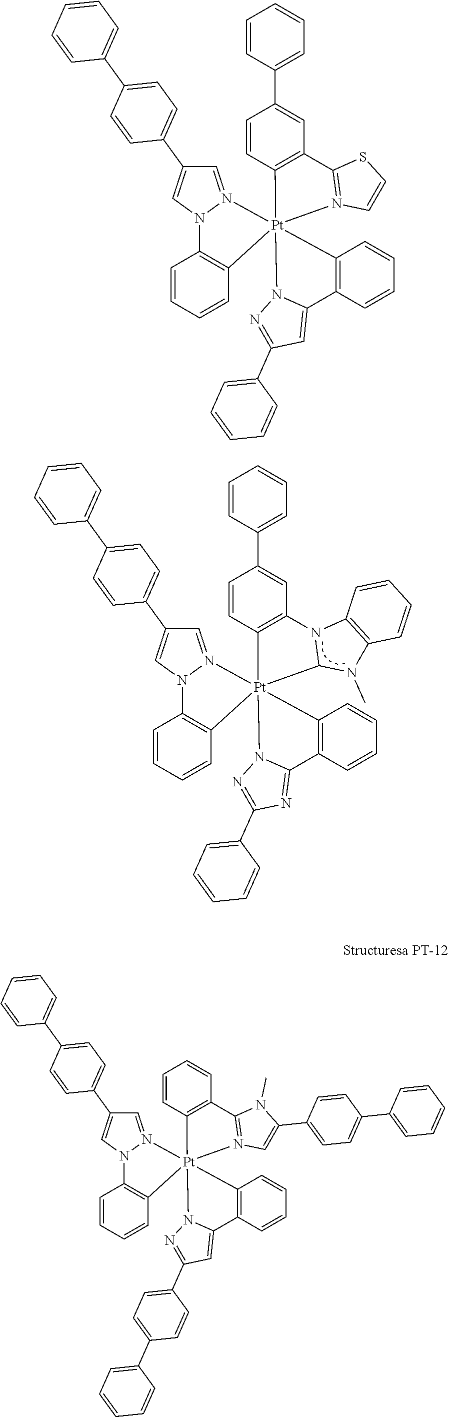

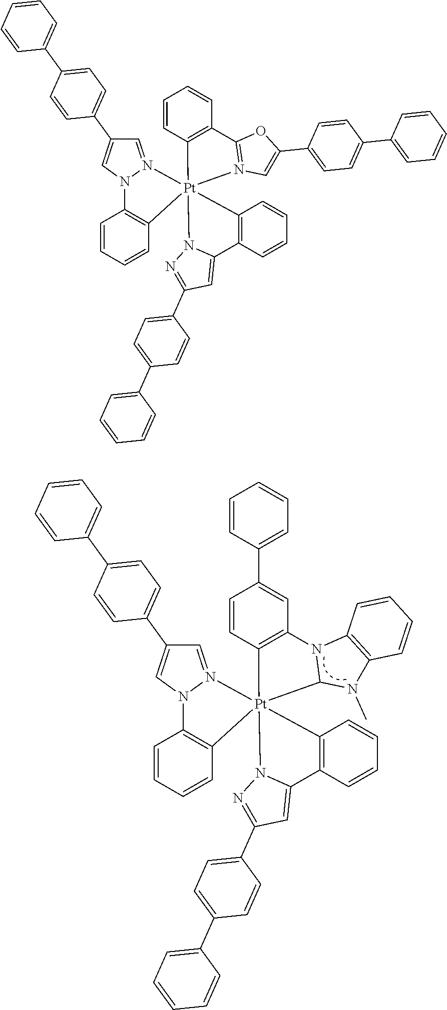

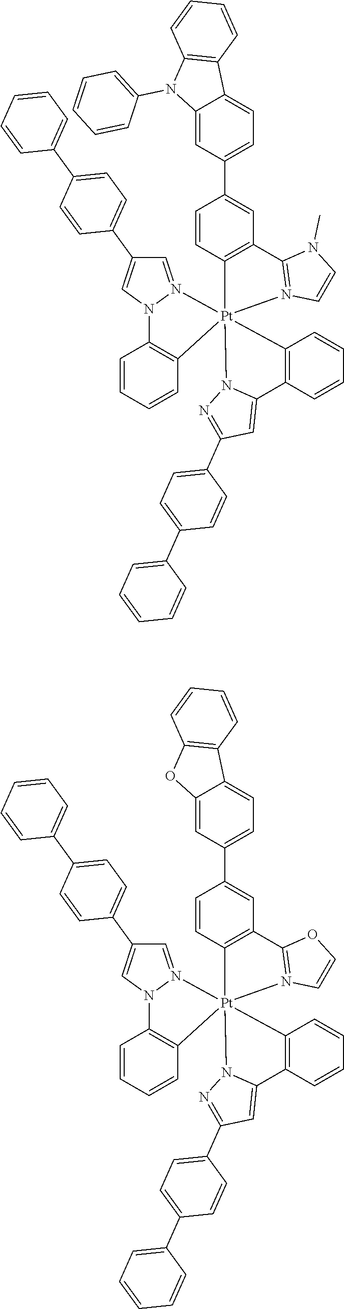

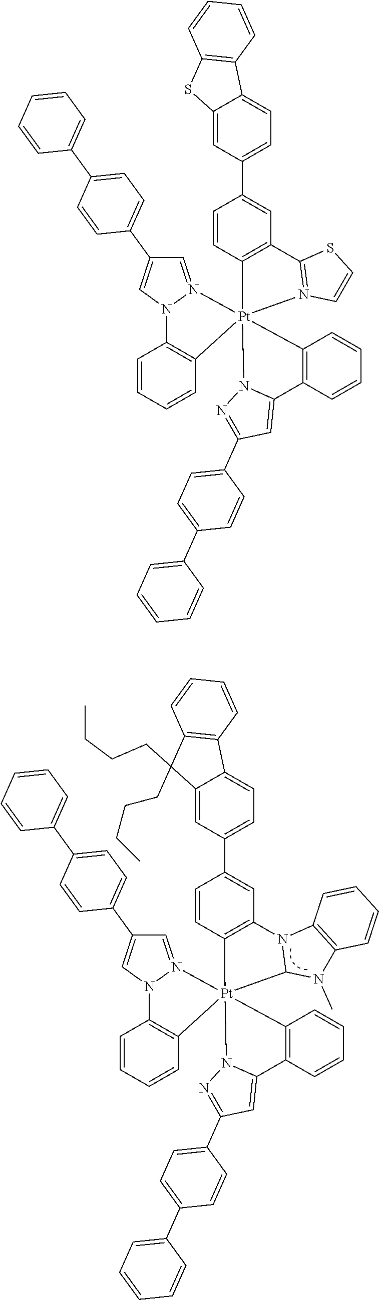

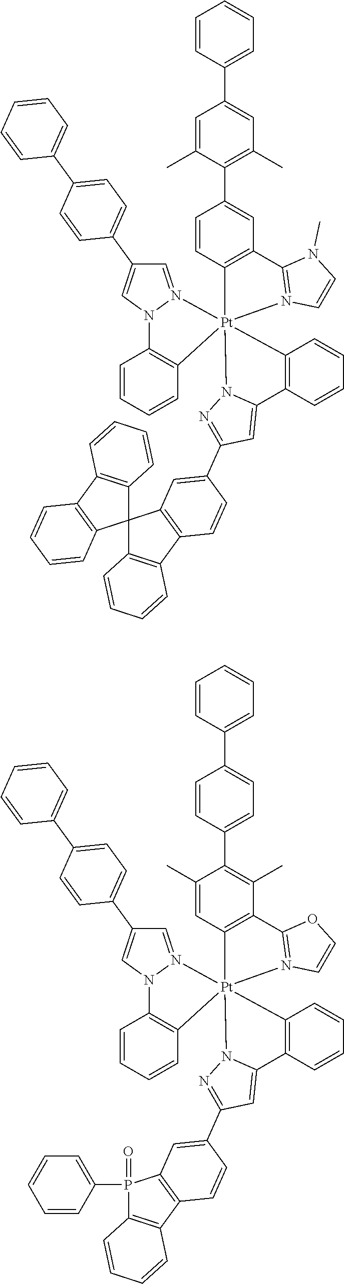

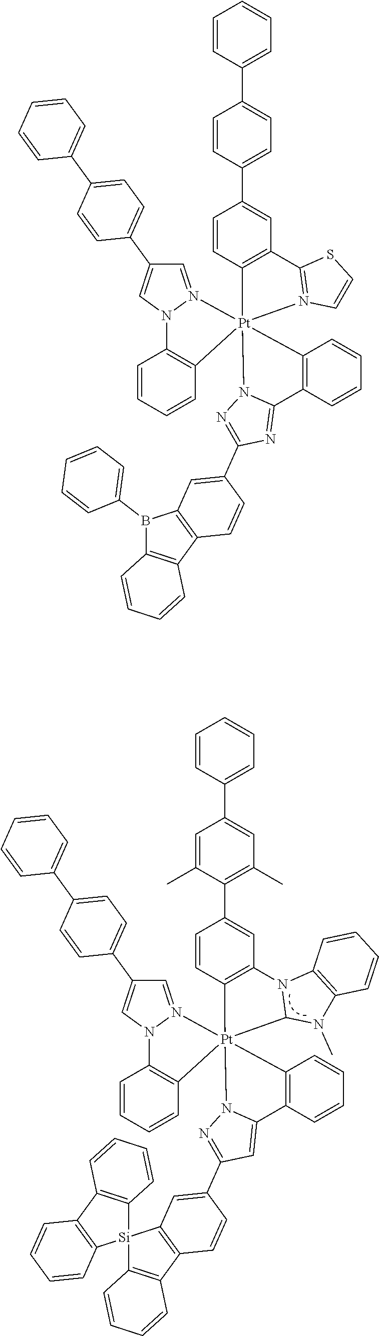

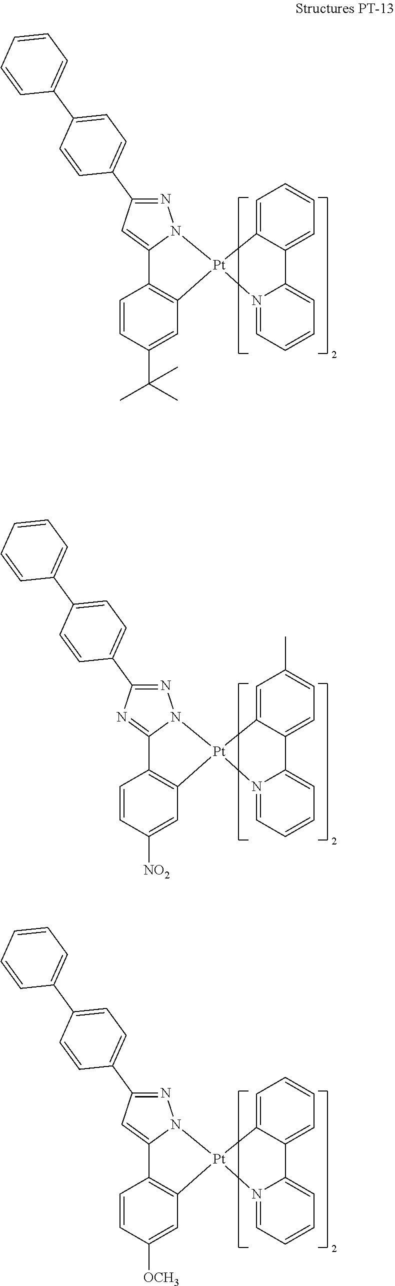

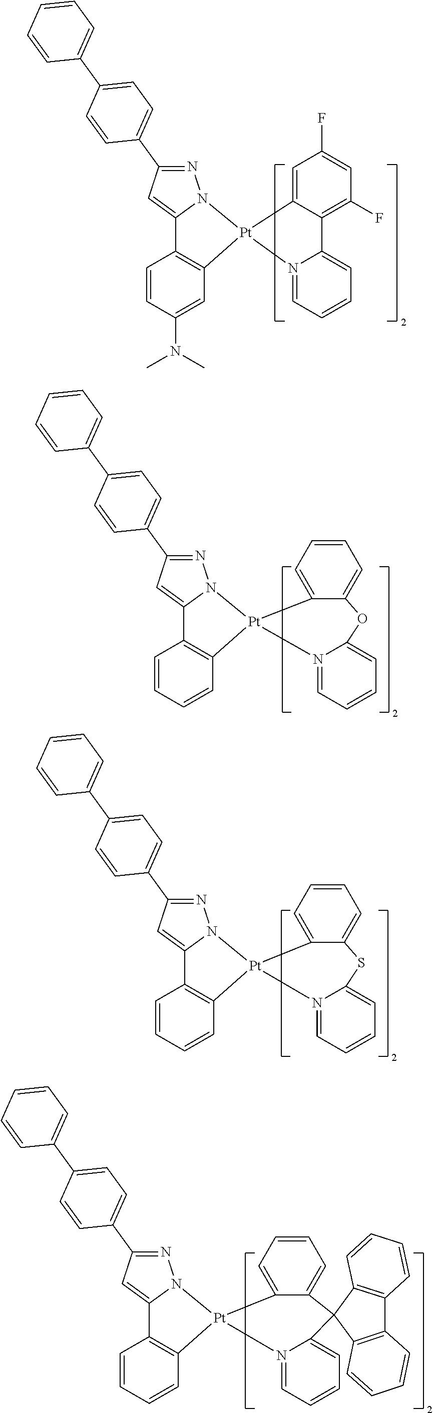

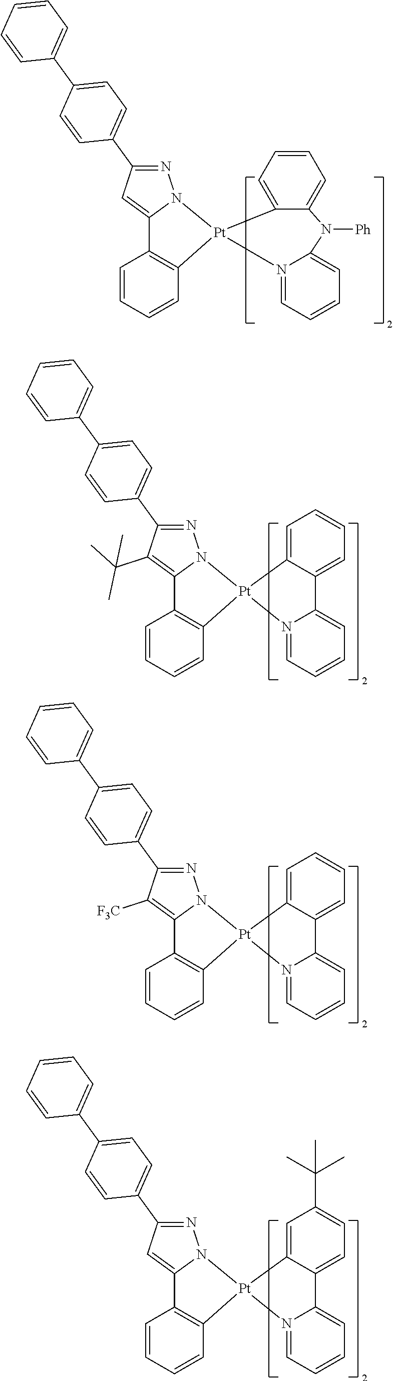

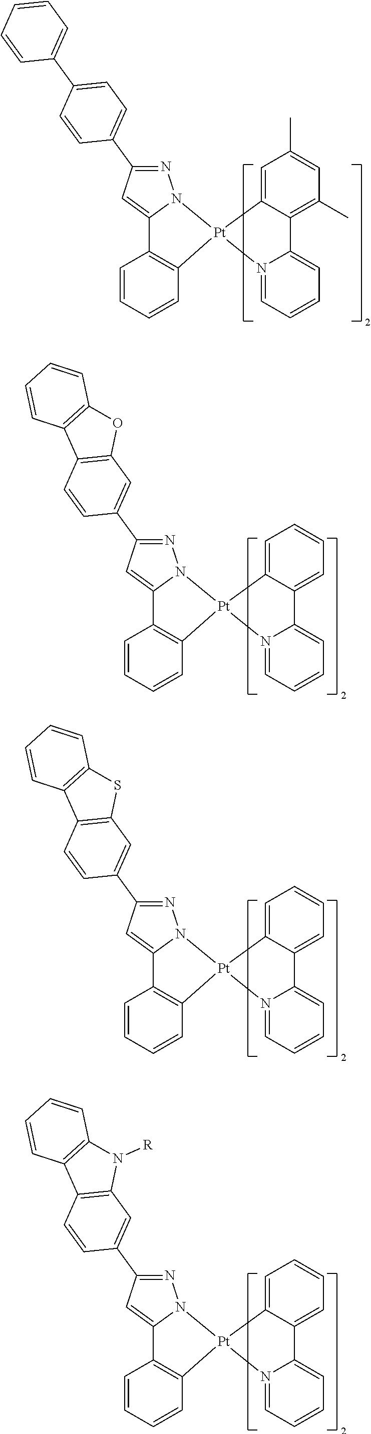

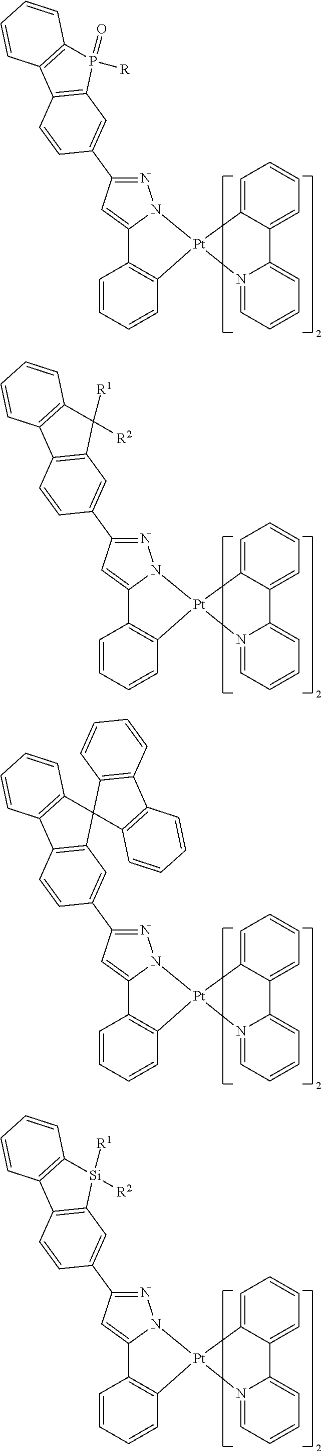

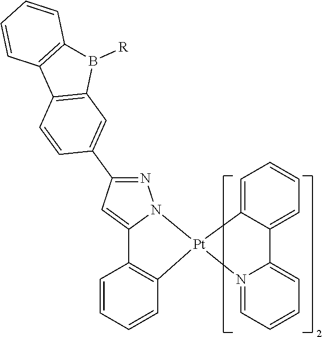

In the compounds shown in Structures Ir-1 to Ir-25, Rh-1 to Rh-25, and Pt-1 to Pt-13 above, each of R, R¹, R², R³, and R⁴ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof. In another aspect, each of R, R¹, R², R³ and R⁴ is independently hydrogen, halogen, hydroxyl, thiol, nitro, cyano; or substituted or unsubstituted: aryl, cycloalkyl, cycloalkenyl, heterocyclyl, heteroaryl, alkyl, alkenyl, alkynyl, or amino. In another aspect, each of R, R¹, R², R³ and R⁴ is independently hydrogen; or substituted or unsubstituted: aryl, cycloalkyl, cycloalkenyl, heterocyclyl, heteroaryl, alkyl, alkenyl, or alkynyl.

### 2. Devices

Also disclosed herein are devices including one or more of the compounds disclosed herein.

The compounds disclosed herein are suited for use in a wide variety of devices, including, for example, optical and electro-optical devices, including, for example, photo-absorbing devices such as solar- and photo-sensitive devices, organic light emitting diodes (OLEDs), photo-emitting devices, or devices capable of both photo-absorption and emission and as markers for bio-applications.

Compounds described herein can be used in a light emitting device such as an OLED. FIG. 2 depicts a cross-sectional view of an OLED 100. OLED 100 includes substrate 102, anode 104, hole-transporting material(s) (HTL) 106, light processing material 108, electron-transporting material(s) (ETL) 110, and a metal cathode layer 112. Anode 104 is typically a transparent material, such as indium tin oxide. Light processing material 108 may be an emissive material (EML) including an emitter and a host.

In various aspects, any of the one or more layers depicted in FIG. 2 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′diamine (NPD), 1,1-bis((di-4-tolylamino)phenyl)cyclohexane (TAPC), 2,6-Bis(N-carbazolyl)pyridine (mCpy), 2,8-bis(diphenylphosphoryl)dibenzothiophene (PO15), LiF, Al, or a combination thereof.

Light processing material 108 may include one or more compounds of the present disclosure optionally together with a host material. The host material can be any suitable host material known in the art. The emission color of an OLED is determined by the emission energy (optical energy gap) of the light processing material 108, which can be tuned by tuning the electronic structure of the emitting compounds, the host material, or both. Both the hole-transporting material in the HTL layer 106 and the electron-transporting material(s) in the ETL layer 110 may include any suitable hole-transporter known in the art.

Compounds described herein may exhibit phosphorescence. Phosphorescent OLEDs (i.e., OLEDs with phosphorescent emitters) typically have higher device efficiencies than other OLEDs, such as fluorescent OLEDs. Light emitting devices based on electrophosphorescent emitters are described in more detail in WO2000/070655 to Baldo et al., which is incorporated herein by this reference for its teaching of OLEDs, and in particular phosphorescent OLEDs.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to be limiting in scope. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

Various methods for the preparation of the compounds described herein are recited in the examples. These methods are provided to illustrate various methods of preparation, but are not intended to limit any of the methods recited herein. Accordingly, one of skill in the art in possession of this disclosure could readily modify a recited method or utilize a different method to prepare one or more of the compounds described herein. The following aspects are only exemplary and are not intended to be limiting in scope. Temperatures, catalysts, concentrations, reactant compositions, and other process conditions can vary, and one of skill in the art, in possession of this disclosure, could readily select appropriate reactants and conditions for a desired complex.

¹H spectra were recorded at 400 MHz, ¹³C NMR spectra were recorded at 100 MHz on Varian Liquid-State NMR instruments in CDCl₃ or DMSO-d₆ solutions and chemical shifts were referenced to residual protiated solvent. If CDCl₃ was used as solvent, ¹H NMR spectra were recorded with tetramethylsilane (δ=0.00 ppm) as internal reference; ¹³C NMR spectra were recorded with CDCl₃ (δ=77.00 ppm) as internal reference. If DMSO-d₆ was used as solvent, ¹H NMR spectra were recorded with residual H₂O (δ=3.33 ppm) as internal reference; ¹³C NMR spectra were recorded with DMSO-d₆ (δ=39.52 ppm) as an internal reference. The following abbreviations (or combinations thereof) were used to explain ¹H NMR multiplicities: s=singlet, d=doublet, t=triplet, q=quartet, p=quintet, m=multiplet, br=broad.

### General Synthetic Routes

A general synthetic route for the compounds disclosed herein includes:

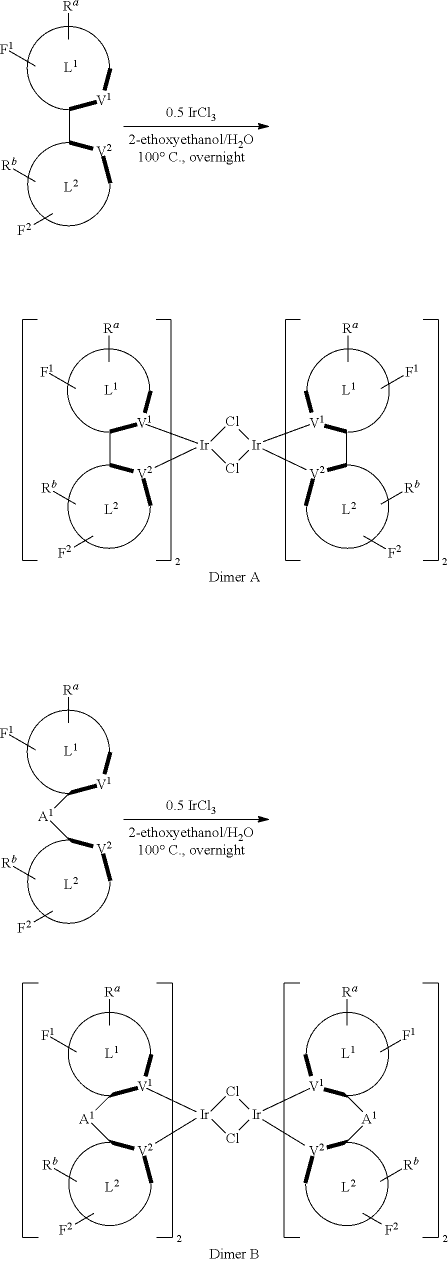

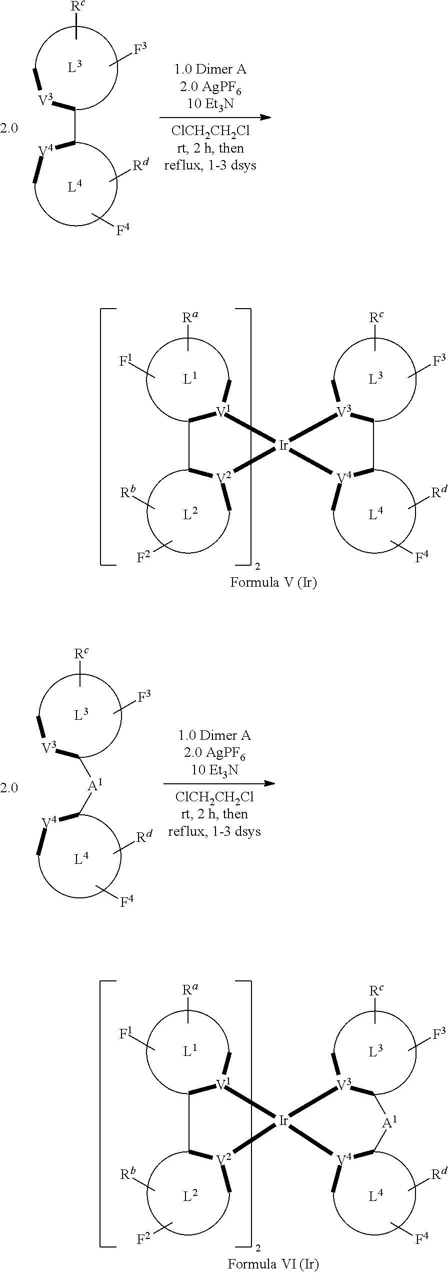

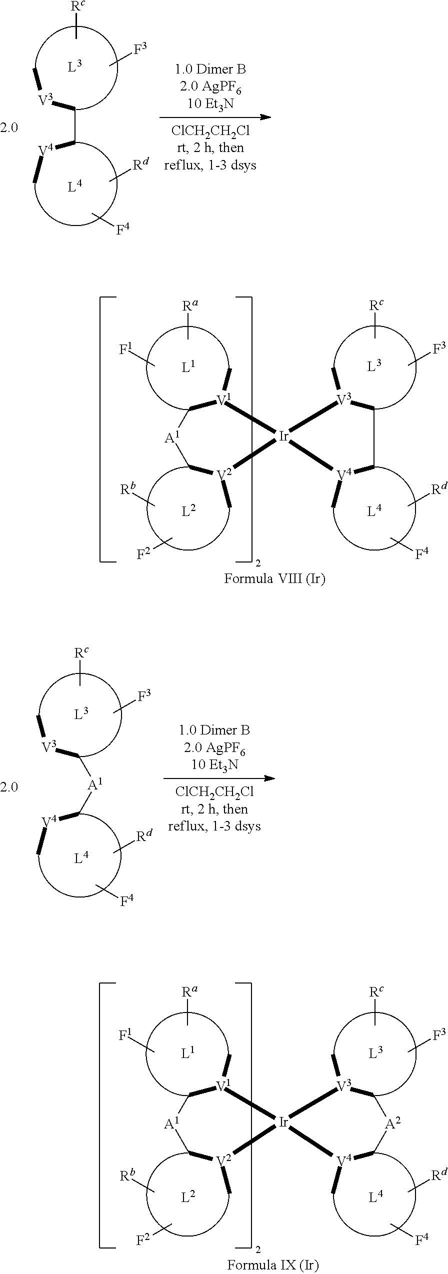

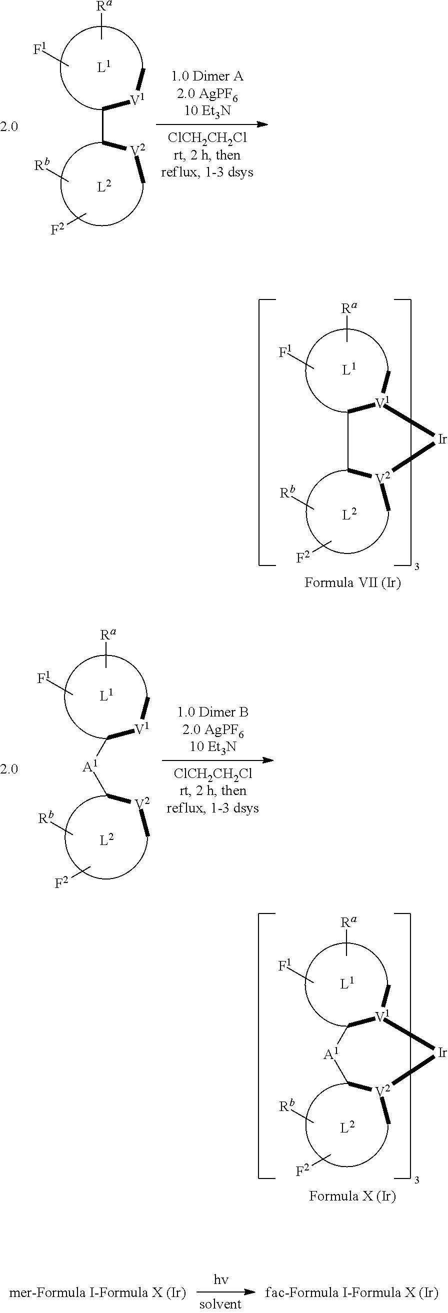

The rhodium complexes Formula I (Rh)-Formula X (Rh) can be synthesized through similar methods.

A synthetic route for the disclosed compounds herein also includes:

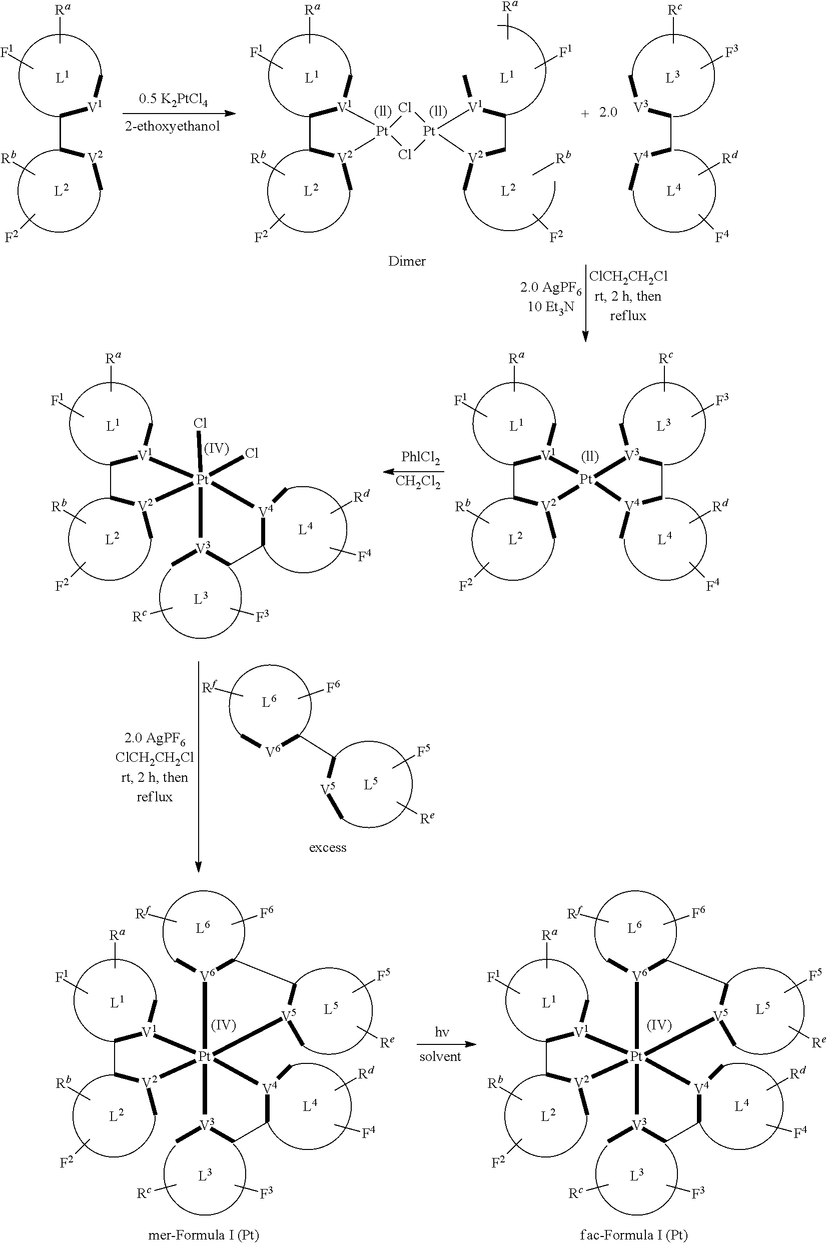

Other mer- or fac-Pt(IV) complexes Formula I (Pt)-Formula X (Pt) can be obtained through similar methods.

### 1. Example 1

The iridium complex mer-(fppy)₂Ir(1a) was prepared according to the following scheme:

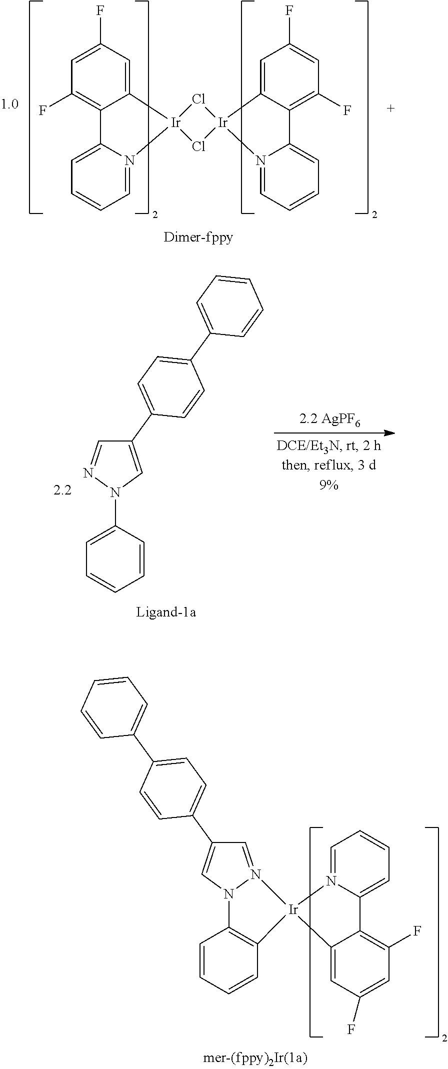

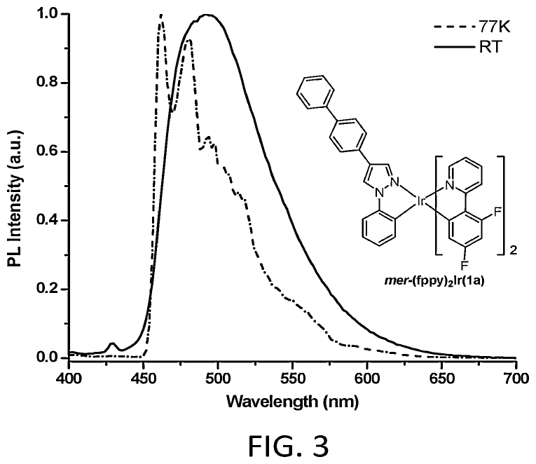

A mixture of Dimer-fppy (230 mg, 0.19 mmol, 1.0 eq), ligand Ligand-1a (124 mg, 0.42 mmol, 2.2 eq) and AgPF₆ (106 mg, 0.42 mmol, 2.2 eq) in ClCH₂CH₂Cl (20 mL) and Et₃N (1 mL) under an atmosphere of nitrogen was stirred at room temperature for 2 hours, then refluxed for 3 days and cooled to ambient temperature. The solvent was removed, and the residue was purified through column chromatography on silica gel using dichloromethane/hexane (1:1) as eluent to obtain the desired product mer-(fppy)₂Ir(1a) 30 mg as a yellow solid in 9% yield. ¹H NMR (DMSO-d₆, 400 MHz): δ 5.73 (d, J=7.2 Hz, 1H), 5.96 (d, J=7.6 Hz, 1H), 6.65-6.81 (m, 3H), 6.89 (t, J=2.0 Hz, 1H), 7.05 (t, J=2.0 Hz, 1H), 7.14-7.19 (m, 2H), 7.36-7.39 (m, 1H), 7.45-7.52 (m, 3H), 7.69-7.93 (m, 10H), 8.13 (d, J=5.6 Hz, 1H), 8.18 (d, J=8.0 Hz, 1H), 8.24 (d, J=8.0 Hz, 1H), 9.38 (s, 1H). Emission spectra of mer-(fppy)₂Ir(1a) at room temperature in CH₂Cl₂ and at 77K in 2-methyltetrahydrofuran are shown in FIG. 3.

### 2. Example 2

The iridium complex fac-(fppy)₂Ir(1a) was prepared according to the following scheme:

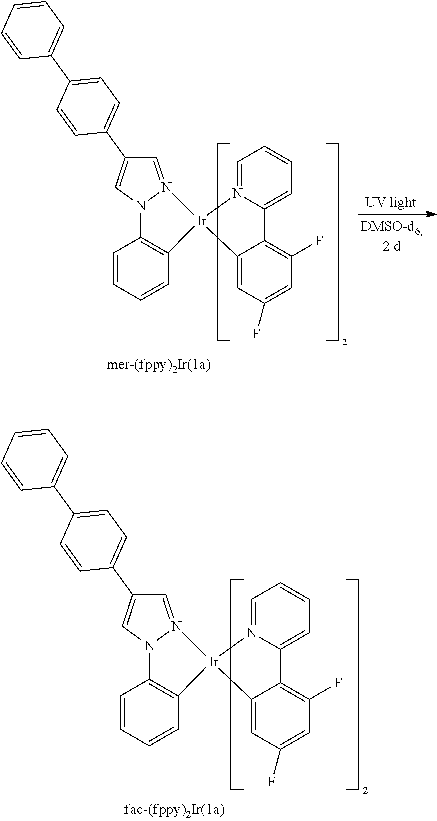

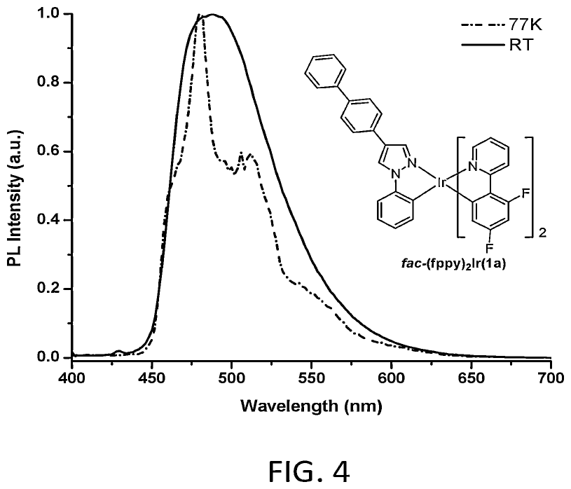

A solution of mer-(fppy)₂Ir(1a) in DMSO-d₆ was kept under UV light for 2 days, monitored by ¹H NMR until the mer-(fppy)₂Ir(1a) was consumed completely to give fac-(fppy)₂Ir(1a). ¹H NMR (DMSO-d₆, 400 MHz): δ 6.00 (dd, J=9.6, 2.4 Hz, 1H), 6.09 (dd, J=9.2, 2.4 Hz, 1H), 6.39 (dd, J=7.6, 0.8 Hz, 1H), 6.56-6.63 (m, 2H), 6.66 (t, J=8.0 Hz, 1H), 6.84-6.88 (m, 1H), 7.14 (t, J=7.6 Hz, 1H), 7.19 (t, J=7.2 Hz, 1H), 7.27 (t, J=7.2 Hz, 1H), 7.37 (t, J=7.6 Hz, 2H), 7.54-7.71 (m, 10H), 7.81-7.86 (m, 2H), 8.15 (t, J=7.2 Hz, 2H), 9.24 (s, 1H). Emission spectra of fac-(fppy)₂Ir(1a) at room temperature in CH₂Cl₂ and at 77K in 2-methyltetrahydrofuran are shown in FIG. 4.

### 3. Example 3

The iridium complex mer-(fppy)Ir(1a)₂ was prepared according to the following scheme:

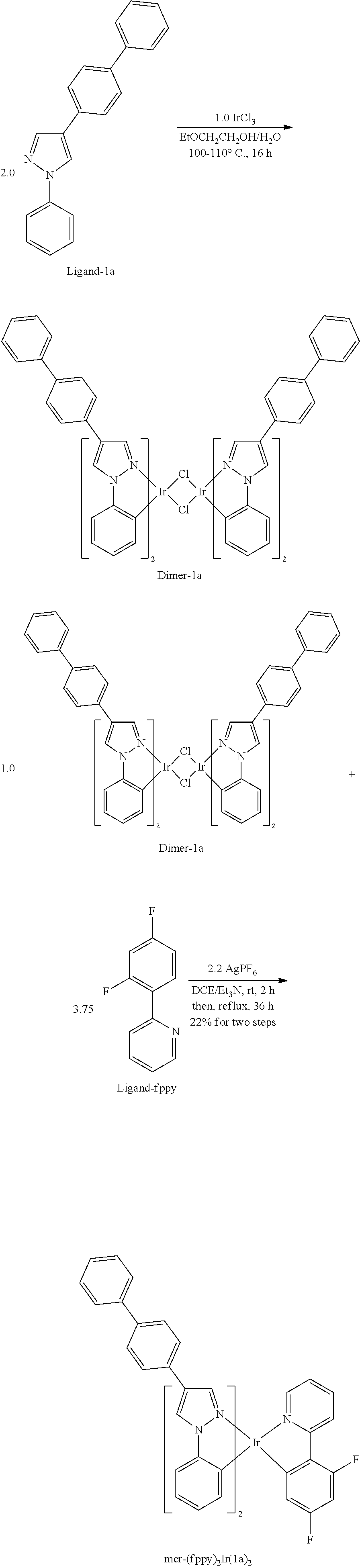

Synthesis of Iridium Complex Dimer-1a:

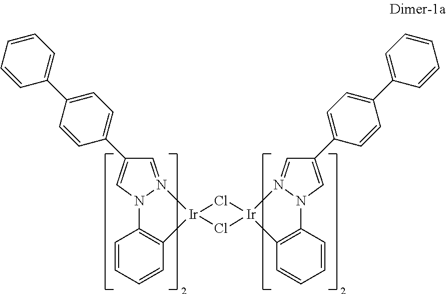

A mixture of Ligand-1a (575 mg, 1.94 mmol, 2.0 eq), IrCl₃ (289 mg, 0.97 mmol, 1.0 eq) in EtCH₂CH₂OH (10 mL) and H₂O (3.3 mL) under an atmosphere of nitrogen was stirred at 100-110° C. for 16 hours and cooled to ambient temperature. The precipitate was filtered off and washed with water, methanol, and Et₂O. Then the collected solid was dried in air to give the desired product Dimer-1a as a light yellow solid (565 mg), which was used directly for the next steps. ¹H NMR (DMSO-d₆, 400 MHz): δ 5.97 (d, J=7.2 Hz, 2H), 6.34 (d, J=7.6 Hz, 2H), 6.68-6.75 (m, 4H), 6.91-6.99 (m, 4H), 7.38 (t, J=7.6 Hz, 4H), 7.49 (t, J=7.6 Hz, 8H), 7.60 (d, J=8.0 Hz, 2H), 7.63 (d, J=8.0 Hz, 2H), 7.74-7.88 (m, 20H), 7.97 (d, J=7.56 Hz, 4H), 8.56 (s, 2H), 8.87 (s, 2H), 9.40 (s, 2H), 9.53 (s, 2H).

Synthesis of Iridium Complex mer-(fppy)Ir(1a)₂:

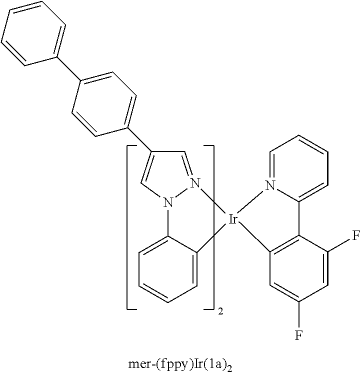

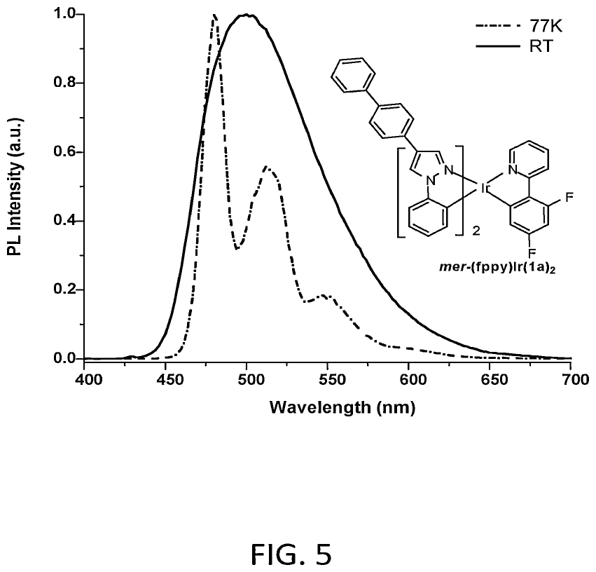

A mixture of Dimer-1a (261 mg, 0.16 mmol, 1.0 eq), ligand Ligand-fppy (115 mg, 0.60 mmol, 3.75 eq) and AgPF₆ (126 mg, 0.50 mmol, 3.1 eq) in ClCH₂CH₂Cl (20 mL) and Et₃N (1 mL) under an atmosphere of nitrogen was stirred at room temperature for 2 hours, then refluxed for 36 hours and cooled to ambient temperature. The solvent was removed and the residue was purified through column chromatography on silica gel using dichloromethane/hexane (1:1) as eluent to obtain the desired product mer-(fppy)Ir(1a)₂ 94 mg as a yellow solid in 22% yield. ¹H NMR (DMSO-d₆, 400 MHz): δ 6.39 (d, J=8.0 Hz, 1H), 6.45 (dd, J=8.0, 3.2 Hz, 1H), 6.68-6.79 (m, 3H), 6.89-6.96 (m, 2H), 7.03 (t, J=8.0 Hz, 1H), 7.25 (t, J=7.2 Hz, 1H), 7.34-7.39 (m, 3H), 7.46-7.50 (m, 5H), 7.61 (d, J=7.6 Hz, 1H), 7.68-7.79 (m, 13H), 7.95 (t, J=8.0 Hz, 1H), 8.19 (d, J=5.6 Hz, 1H), 8.32 (d, J=9.6 Hz, 1H), 9.30 (d, J=8.4 Hz, 2H). Emission spectra of mer-(fppy)Ir(1a)₂ at room temperature in CH₂Cl₂ and at 77K in 2-methyltetrahydrofuran are shown in FIG. 5.

### 4. Example 4

The iridium complex fac-(fppy)Ir(1a)₂ was prepared according to the following scheme:

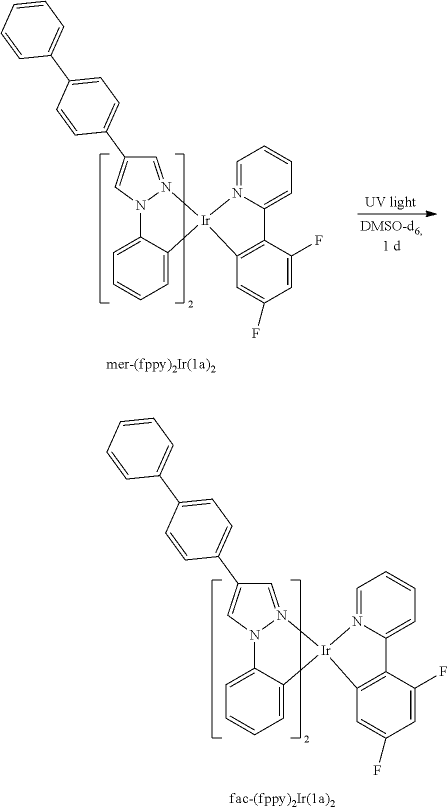

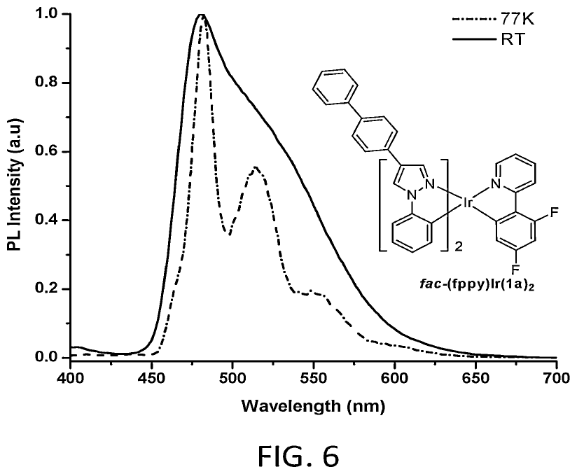

A solution of mer-(fppy)Ir(1a)₂ in DMSO-d₆ was kept under UV light for 1 day, monitored by ¹H NMR until the mer-(fppy)Ir(1a)₂ was consumed completely to give fac-(fppy)Ir(1a)₂. ¹H NMR (DMSO-d₆, 400 MHz): δ 6.18 (dd, J=7.6, 2.0 Hz, 1H), 6.46 (d, J=5.6 Hz, 1H), 6.54 (d, J=6.0 Hz, 1H), 6.57-6.62 (m, 1H), 6.67 (t, J=5.6 Hz, 2H), 6.86-6.91 (m, 2H), 7.20 (t, J=5.6 Hz, 1H), 7.27-7.32 (m, 2H), 7.37-7.43 (m, 4H), 7.54-7.65 (m, 11H), 7.99 (s, 1H), 7.74-7.76 (m, 4H), 7.86 (t, J=6.0 Hz, 1H), 7.90 (d, J=4.4 Hz, 1H), 8.17 (t, J=6.4 Hz, 1H), 9.25 (s, 2H). Emission spectra of fac-(fppy)₂Ir(1a)₂ at room temperature in CH₂Cl₂ and at 77K in 2-methyltetrahydrofuran are shown in FIG. 6.

### 5. Example 5

The iridium complex mer-(fppy)Ir(1b)₂ was prepared according to the following scheme:

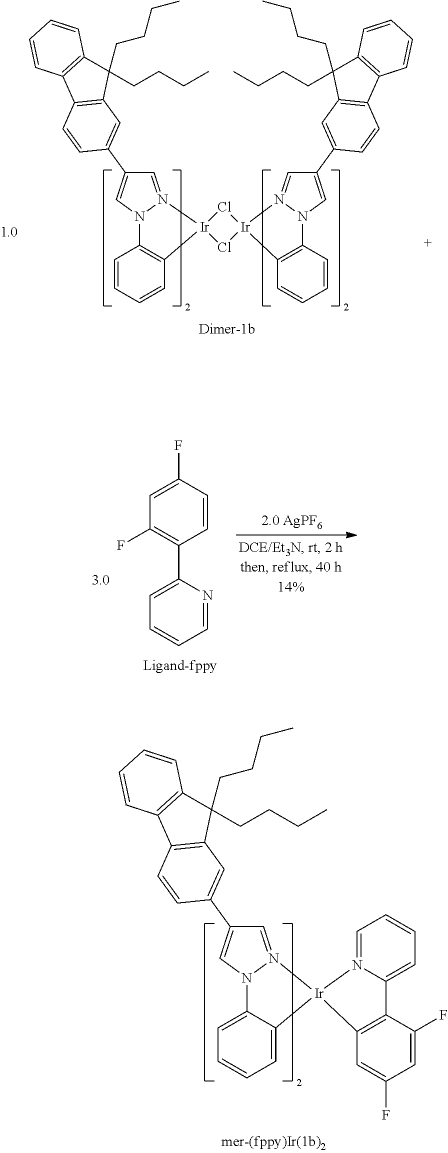

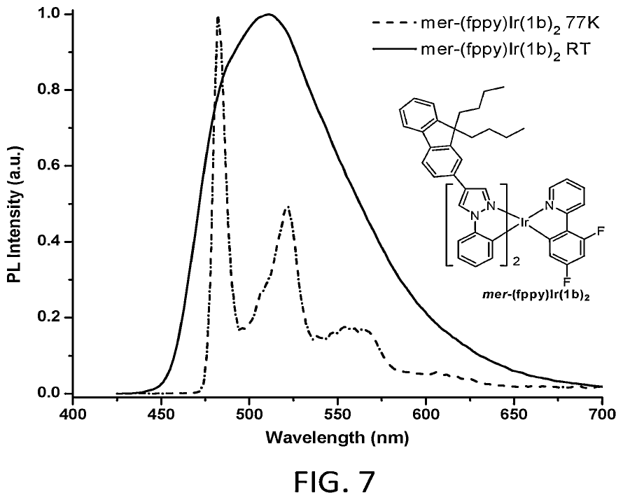

A mixture of Dimer-1b (360 mg, 0.17 mmol, 1.0 eq), ligand Ligand-fppy (81 mg, 0.51 mmol, 3.0 eq) and AgPF₆ (86 mg, 0.34 mmol, 2.0 eq) in ClCH₂CH₂Cl (20 mL) and Et₃N (1 mL) under an atmosphere of nitrogen was stirred at room temperature for 2 hours, then refluxed for 40 hours and cooled to ambient temperature. The solvent was removed and the residue was purified through column chromatography on silica gel using dichloromethane/hexane (1:1) as eluent to obtain the desired product mer-(fppy)Ir(1b)₂ 52 mg as a yellow solid in 14% yield. ¹H NMR (DMSO-d₆, 400 MHz): δ 0.41-0.57 (m, 8H), 0.58-0.65 (m, 12H), 0.96-1.07 (m, 8H), 2.02-2.06 (m, 8H), 6.43-6.45 (m, 2H), 6.68-6.75 (m, 2H), 6.78 (t, J=7.6 Hz, 1H), 6.90-6.97 (m, 2H), 7.04 (td, J=7.6, 2.0 Hz, 1H), 7.25 (t, J=6.8 Hz, 1H), 7.30-7.34 (m, 5H), 7.42-7.44 (m, 2H), 7.47 (s, 1H), 7.55 (d, J=8.0 Hz, 1H), 7.61-7.65 (m, 2H), 7.70 (d, J=7.6 Hz, 1H), 7.74-7.80 (m, 6H), 7.93-7.97 (m, 1H), 8.19 (d, J=5.2 Hz, 1H), 8.31-8.34 (m, 1H), 9.33 (d, J=7.2 Hz, 2H). Emission spectra of mer-(fppy)Ir(1b)₂ at room temperature in CH₂Cl₂ and at 77K in 2-methyltetrahydrofuran are shown in FIG. 7.

### 6. Example 6

The iridium complex fac-(fppy)Ir(1b)₂ was prepared according to the following scheme:

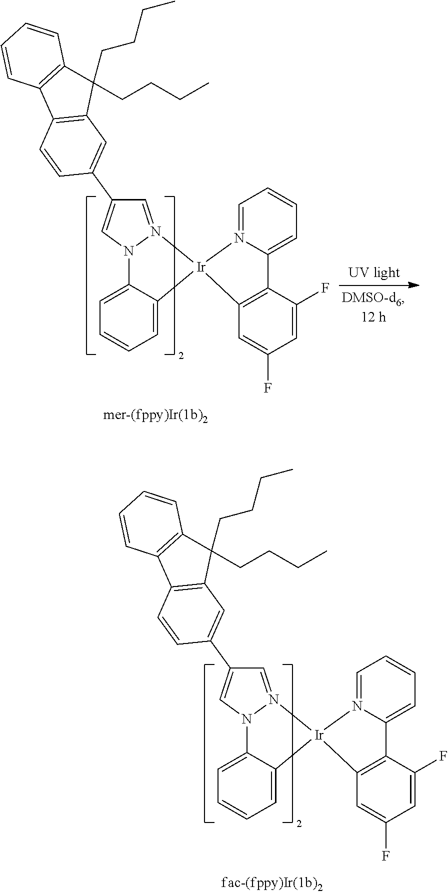

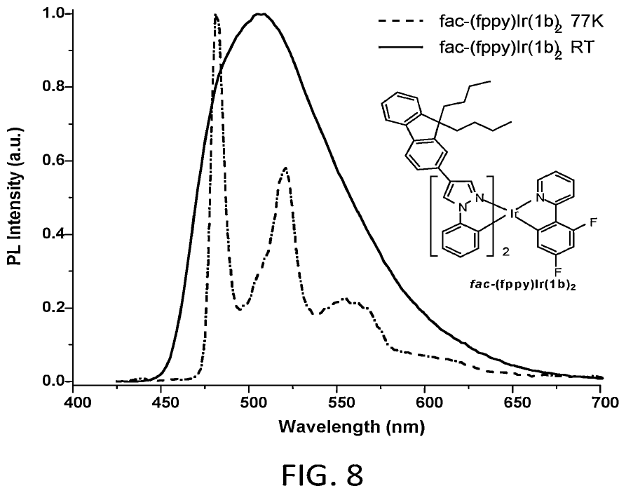

A solution of mer-(fppy)Ir(1b)₂ in DMSO-d₆ was kept under UV light for 1 day, monitored by ¹H NMR until the mer-(fppy)Ir(1b)₂ was consumed completely to give fac-(fppy)Ir(1b)₂. Emission spectra of fac-(fppy)Ir(1b)₂ at room temperature in CH₂Cl₂ and at 77K in 2-methyltetrahydrofuran are shown in FIG. 8.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

1.-15. (canceled)

16. A compound of Formula IV: 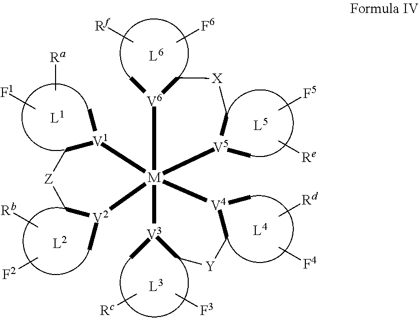
wherein:
M is Ir(III), Rh(III) or Pt(IV),
each of L¹, L², L³, L⁴, L⁵, and L⁶, if present, is independently substituted or unsubstituted aryl, cycloalkyl, cycloalkenyl, heteroaryl, heterocyclyl, carbene, or N-heterocyclic carbene, dione, cyanogen, or phosphine,
each of V¹, V², V³, V⁴, V⁵, and V⁶, if present, is coordinated with M and is independently N, C, P, B, or Si,
each of X, Y, and Z, if present, is independently a direct bond, CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³,
each of F¹, F², F³, F⁴, F⁵, and F⁶ is independently present or absent, wherein at least one of F¹, F², F³, F⁴, F⁵, and F⁶ is present, and each F¹, F², F³, F⁴, F⁵, and F⁶ present is a fluorescent luminophore,
each of R^{a}, R^{b}, R^{c}, R^{d}, R^{e}, and R^{f} is independently present or absent, and if present each R^{a}, R^{b}, R^{c}, R^{d}, R^{e} and R^{f} independently represents mono-, di-, or tri-substitutions, and wherein each R^{a}, R^{b}, R^{c}, R^{d}, R^{e} and R^{f} present is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and
each of R¹, R², and R³, if present, is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

17. The compound of claim 16, wherein X represents a direct bond.

18. The compound of claim 16, wherein X and Y each represent a direct bond.

19. The compound of claim 16, wherein X, Y, and Z each represent a direct bond.

20. The compound of claim 16, wherein none of X, Y, and Z represents a direct bond.

21. The compound of claim 16, wherein the compound is represented by Formula I, Formula II, Formula III, Formula IV′, Formula V, Formula VI, Formula VII, Formula VIII, Formula IX or Formula X: 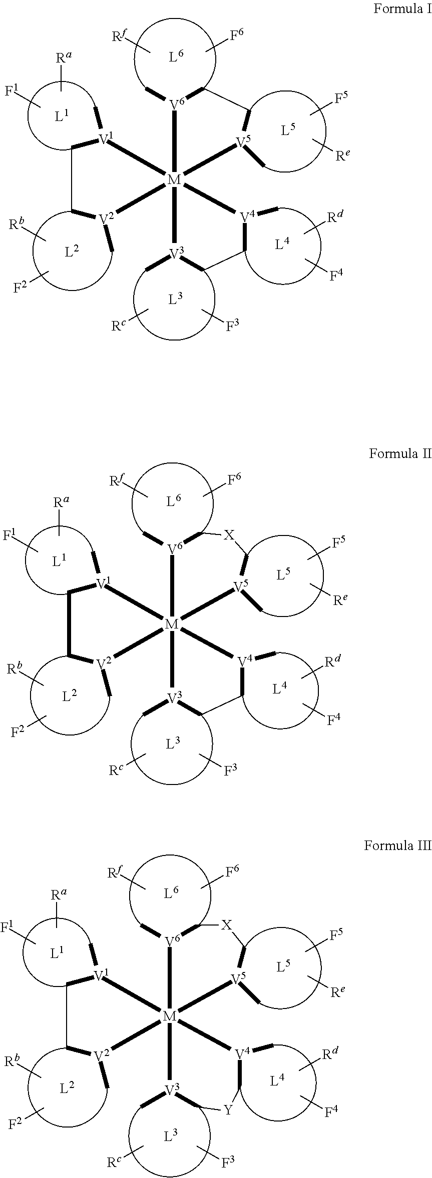 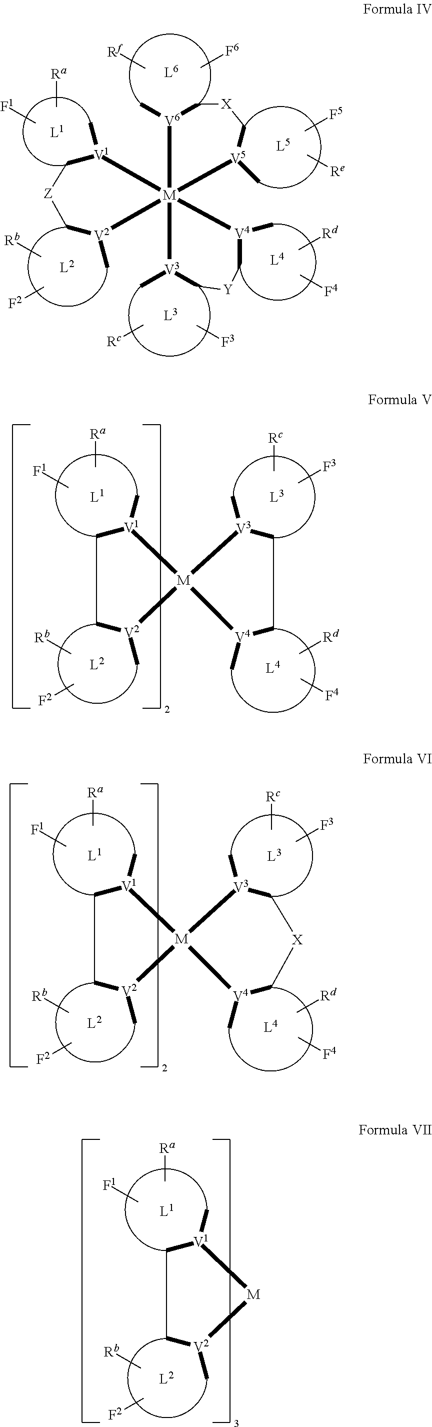 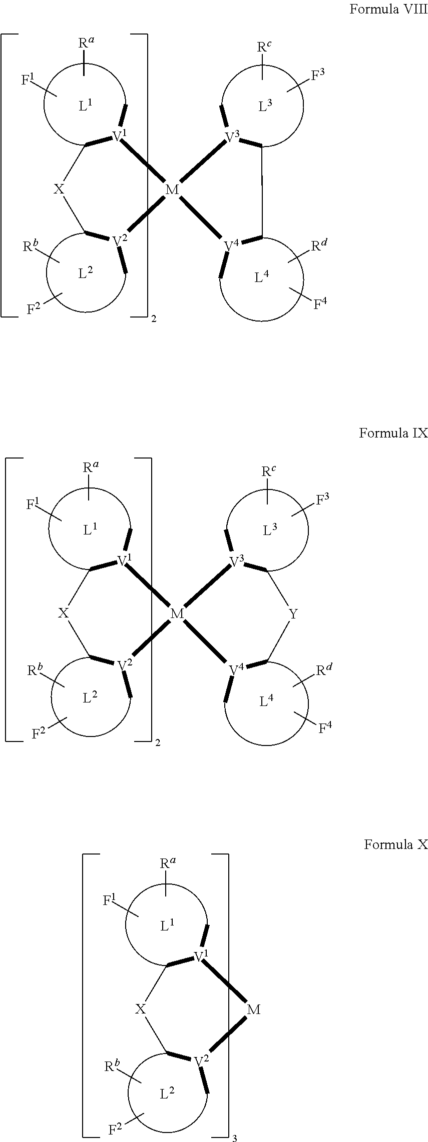
wherein:
M is Ir(III), Rh(III) or Pt(IV),
each of L¹, L², L³, L⁴, L⁵, and L⁶, if present, is independently substituted or unsubstituted aryl, cycloalkyl, cycloalkenyl, heteroaryl, heterocyclyl, carbene, or N-heterocyclic carbene, dione, cyanogen, or phosphine,
each of V¹, V², V³, V⁴, V⁵, and V⁶, if present, is coordinated with M and is independently N, C, P, B, or Si,
each of X, Y, and Z, if present, is independently a direct bond, CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³,
each of F¹, F², F³, F⁴, F⁵, and F⁶ is independently present or absent, wherein at least one of F¹, F², F³, F⁴, F⁵, and F⁶ is present, and each F¹, F², F³, F⁴, F⁵, and F⁶ present is a fluorescent luminophore,
each of R^{a}, R^{b}, R^{c}, R^{d}, R^{e}, and R^{f} is independently present or absent, and if present each R^{a}, R^{b}, R^{c}, R^{d}, R^{e} and R^{f} independently represents mono-, di-, or tri-substitutions, and wherein each R^{a}, R^{b}, R^{c}, R^{d}, R^{e} and R^{f} present is independently deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof, and
each of R¹, R², and R³, if present, is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

22. The compound of claim 16, wherein the compound has a neutral charge.

23. The compound of claim 16, wherein each of 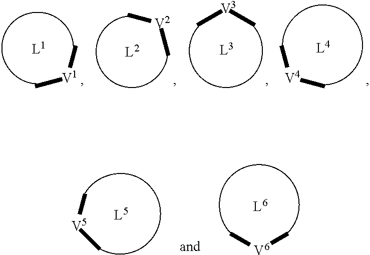
if present, is independently one of the following structures:

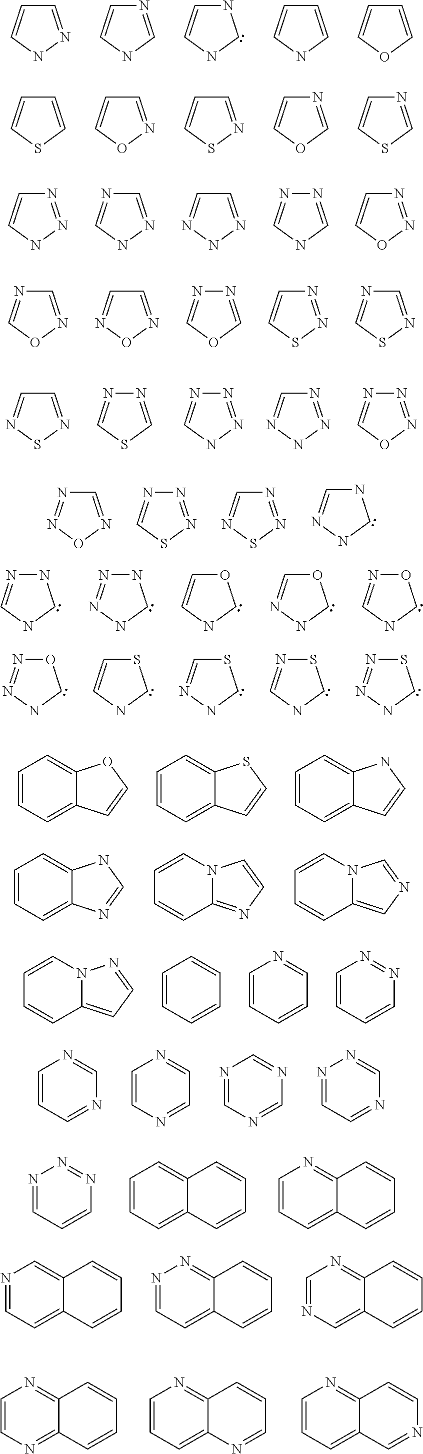

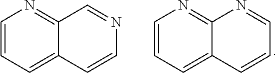

24. The compound of claim 16, wherein each of 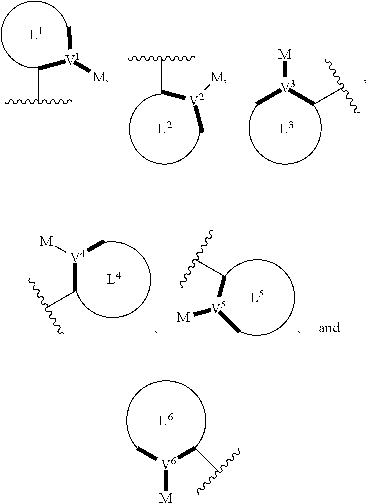
if present, is independently one of the following structures: 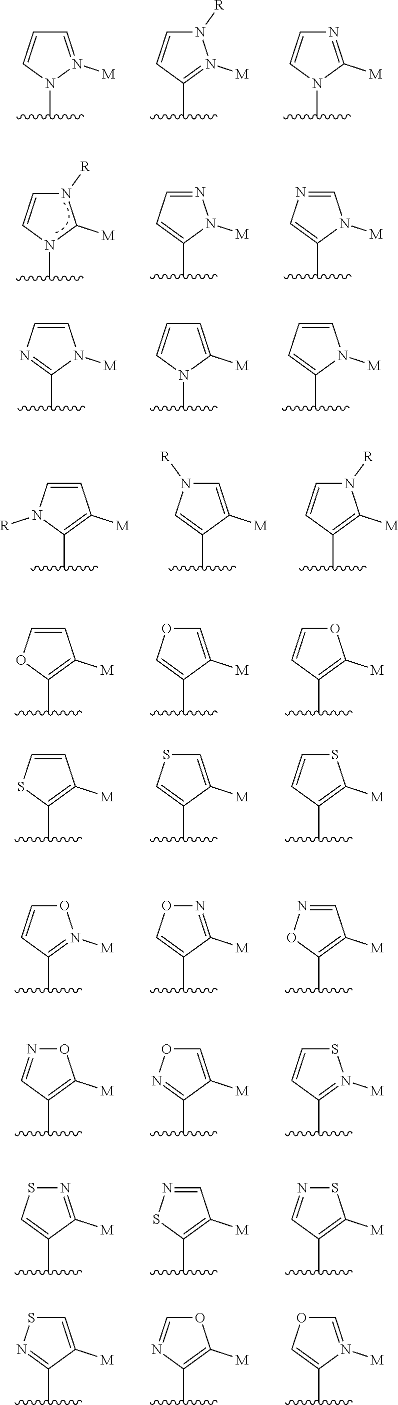 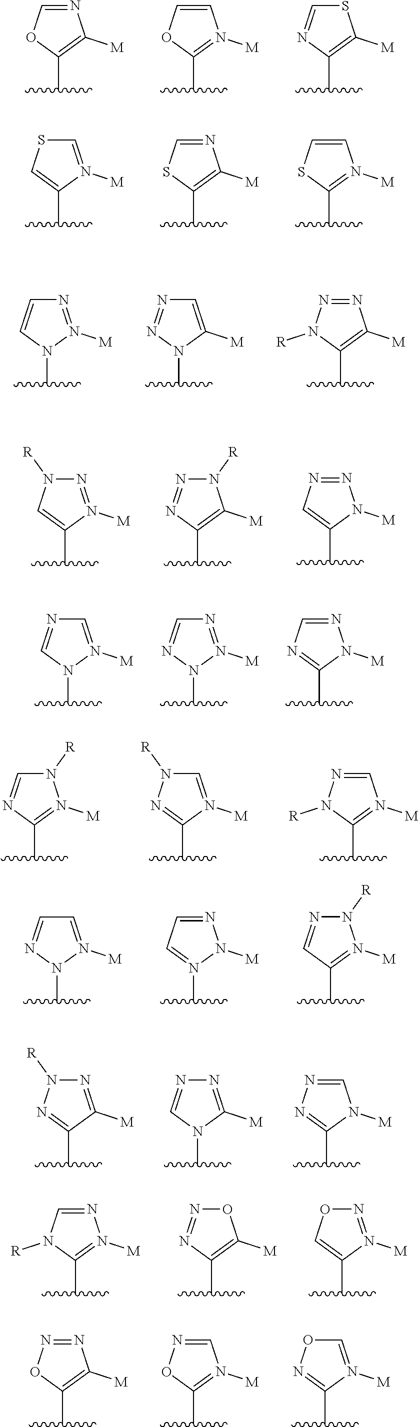 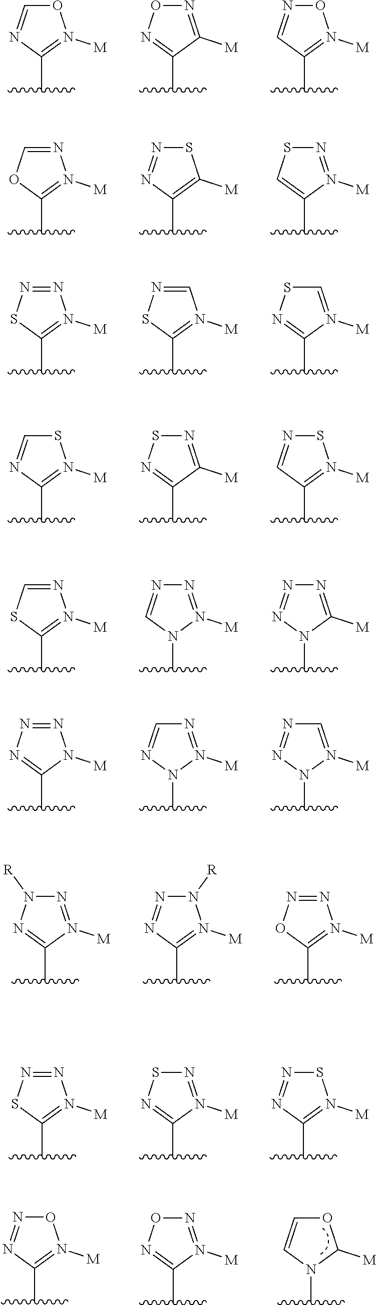 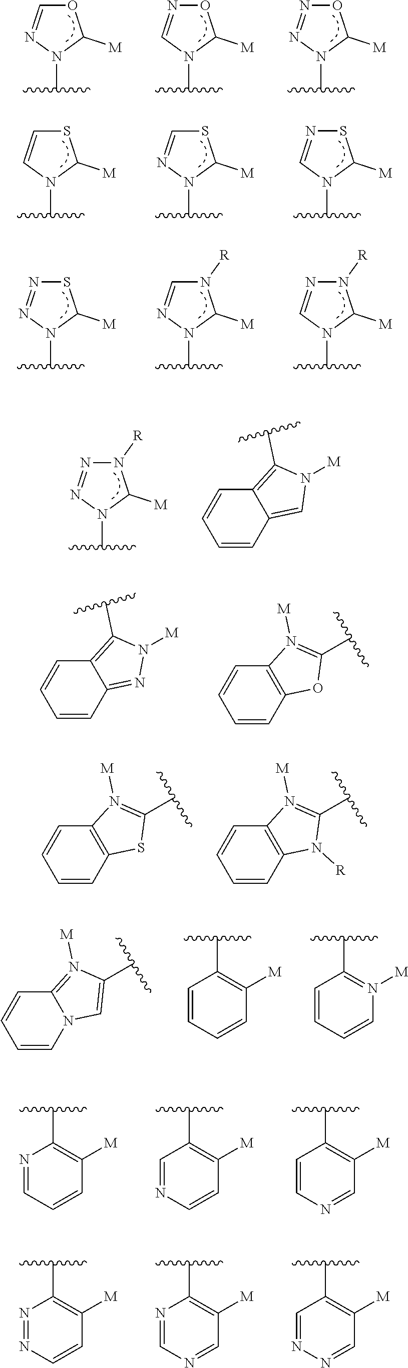 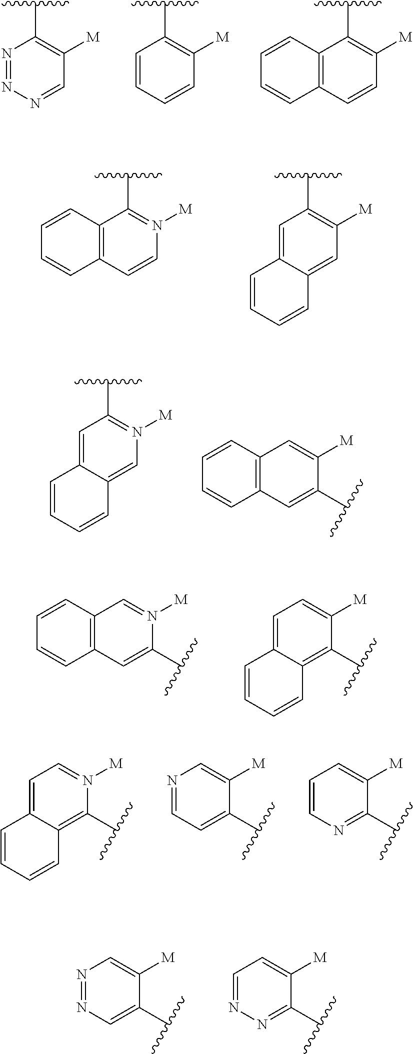
wherein R is deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

25. The compound of claim 16, wherein each of F¹, F², F³, F⁴, F⁵, and F⁶, if present, is independently one of the following structures:
1. Aromatic Hydrocarbons and Their Derivatives 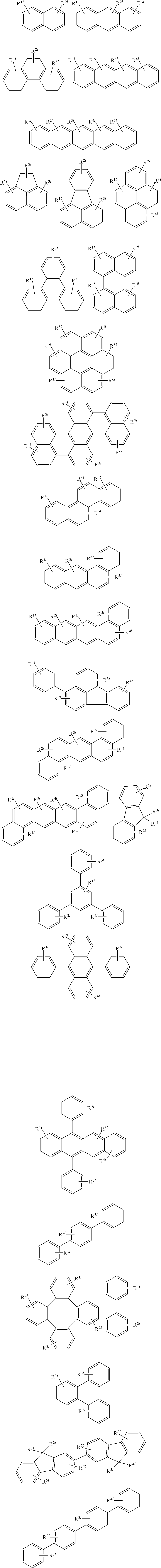 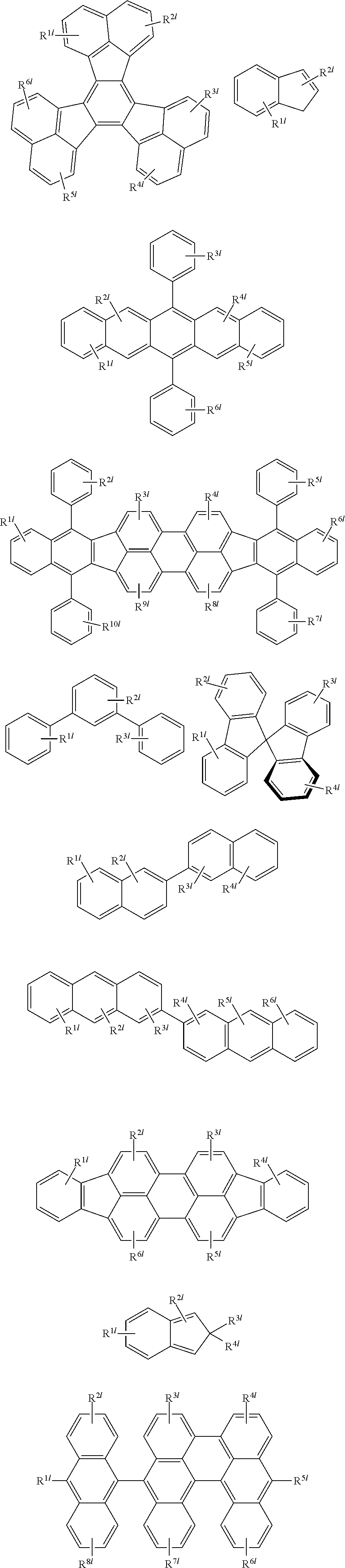
2. Arylethylene, Arylacetylene and Their Derivatives 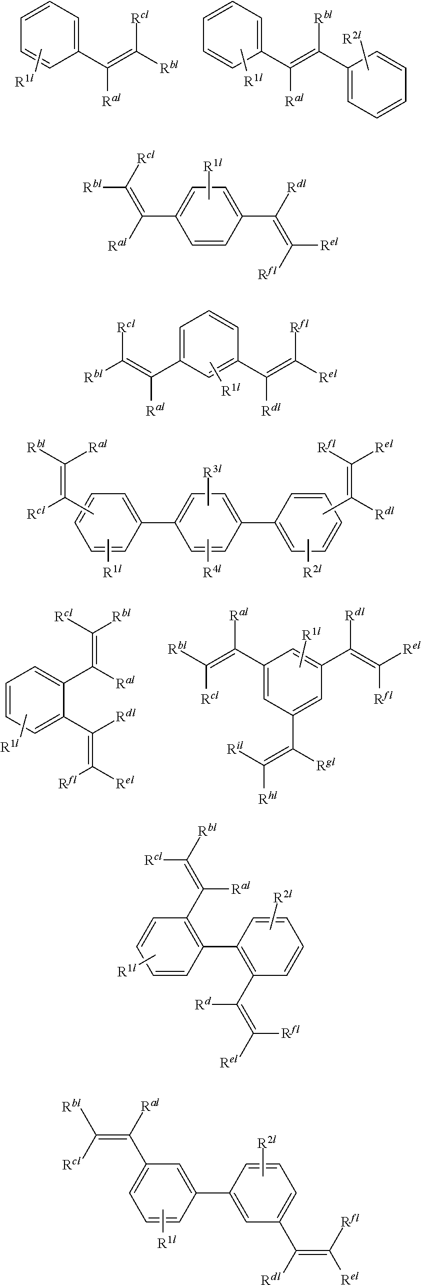 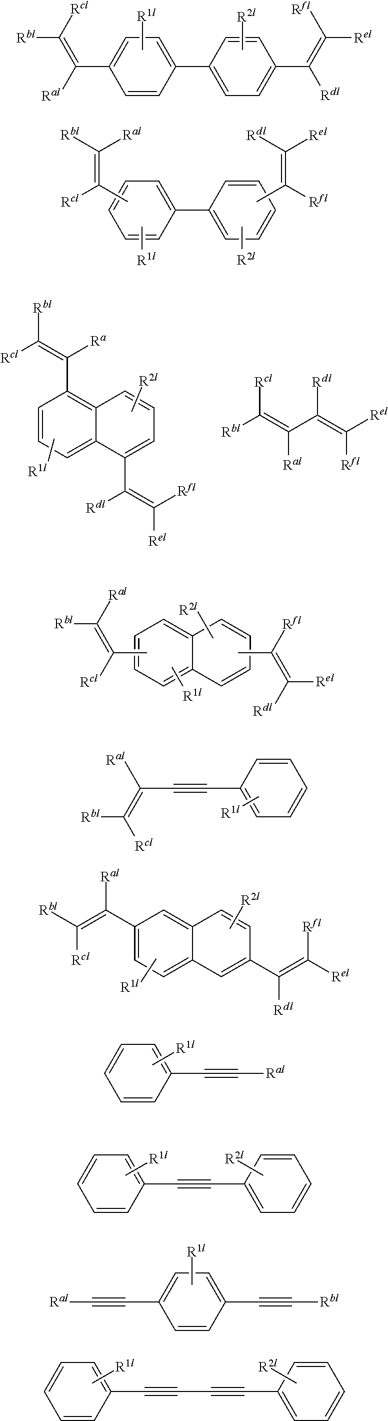 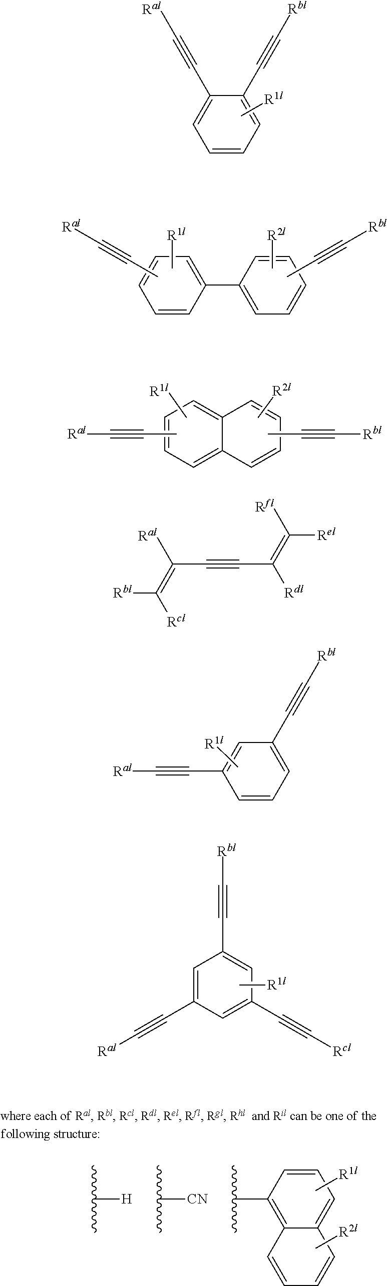 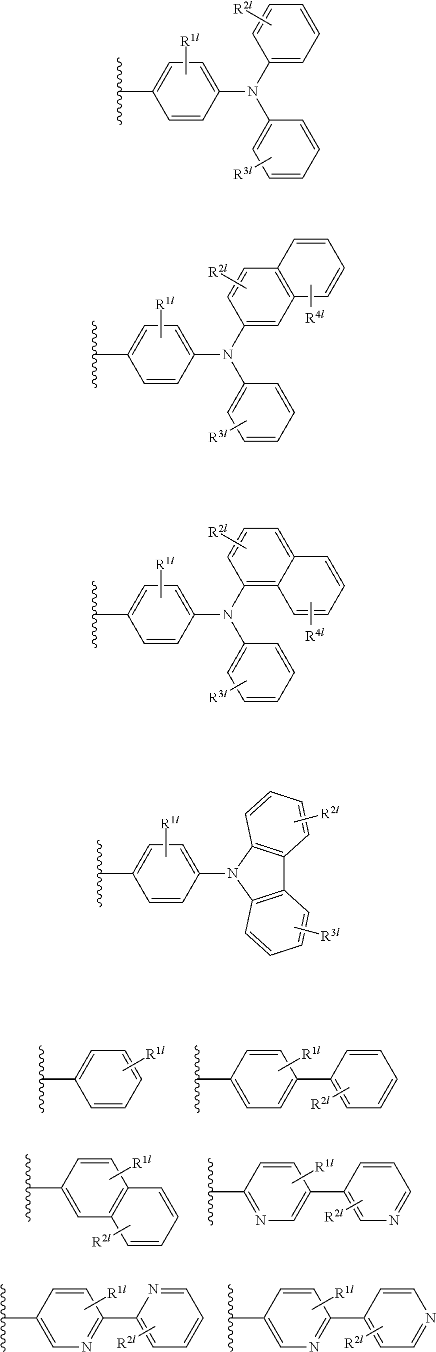 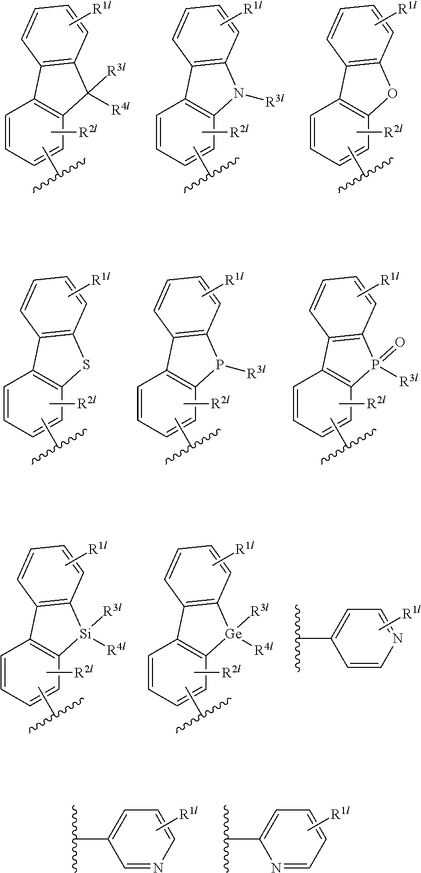
3. Heterocyclic Compounds and Their Derivatives 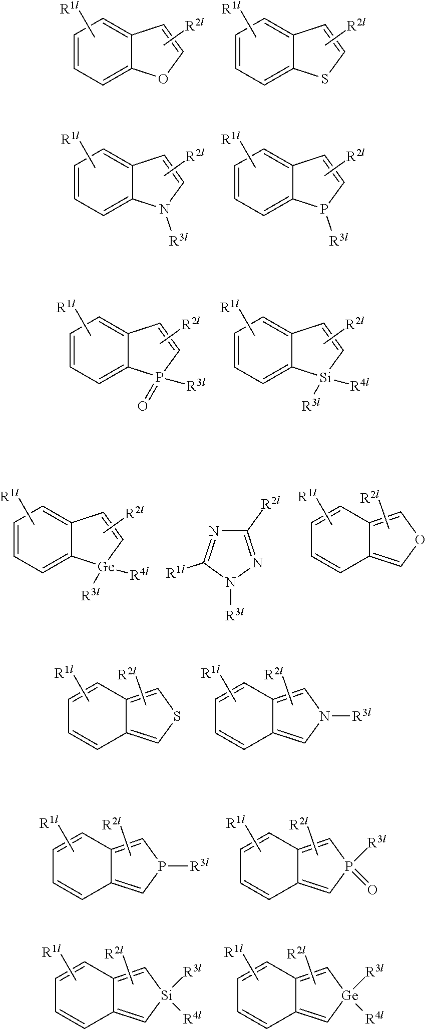 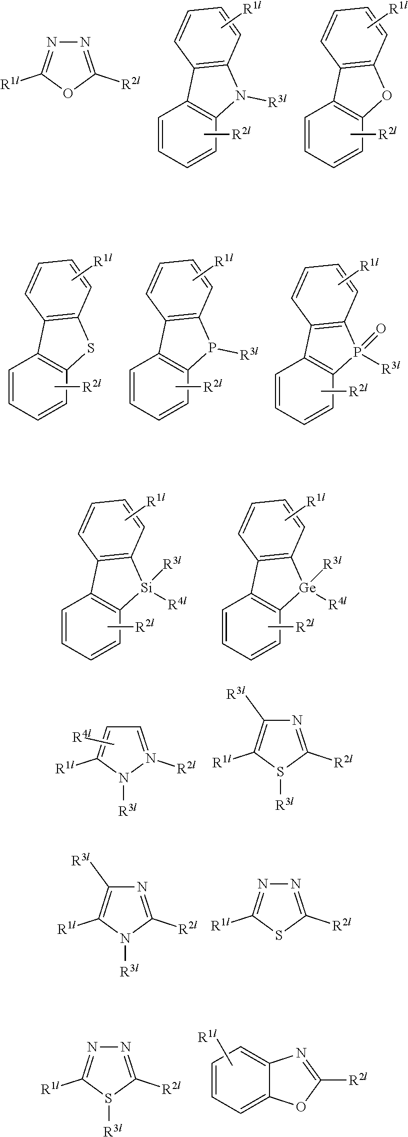 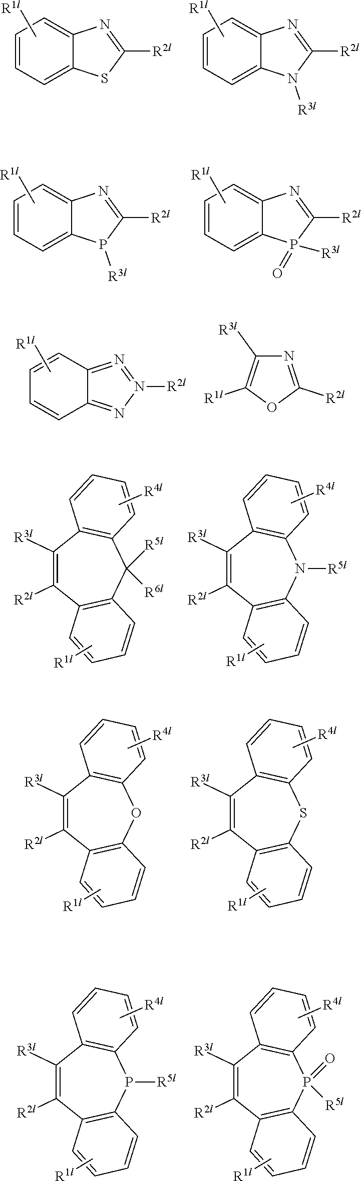 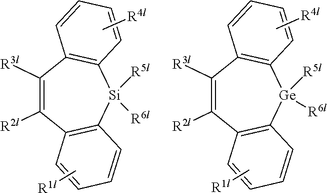 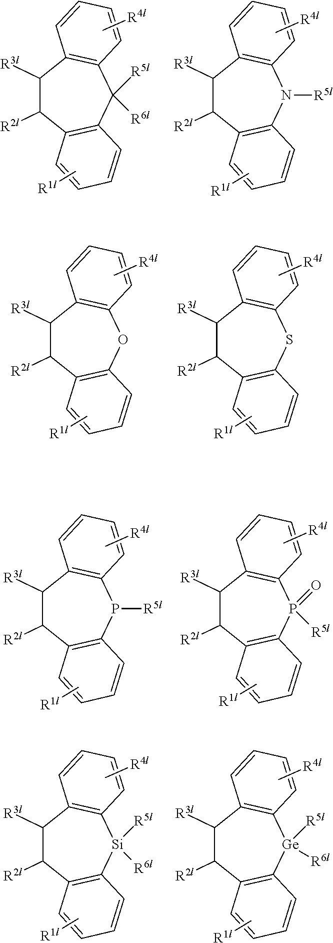 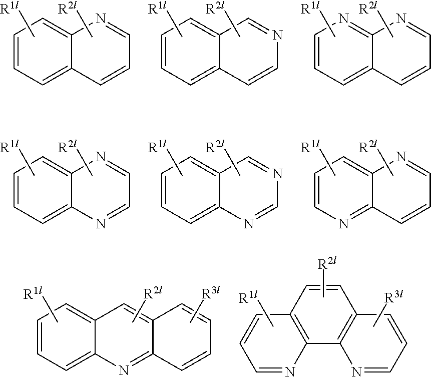 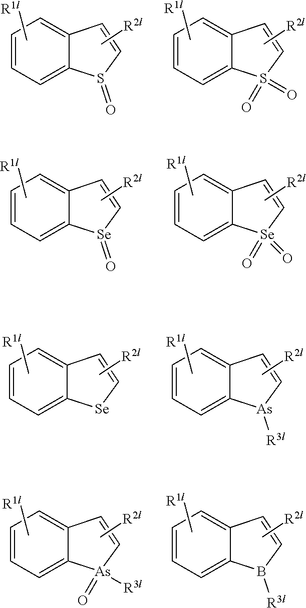 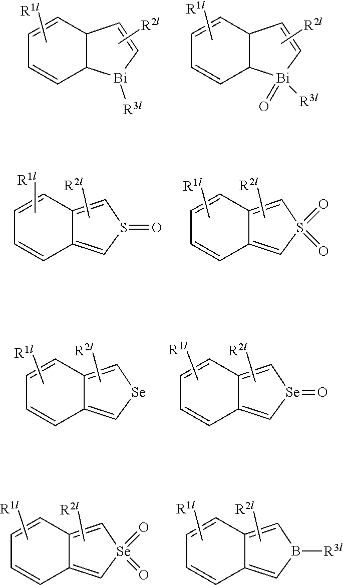 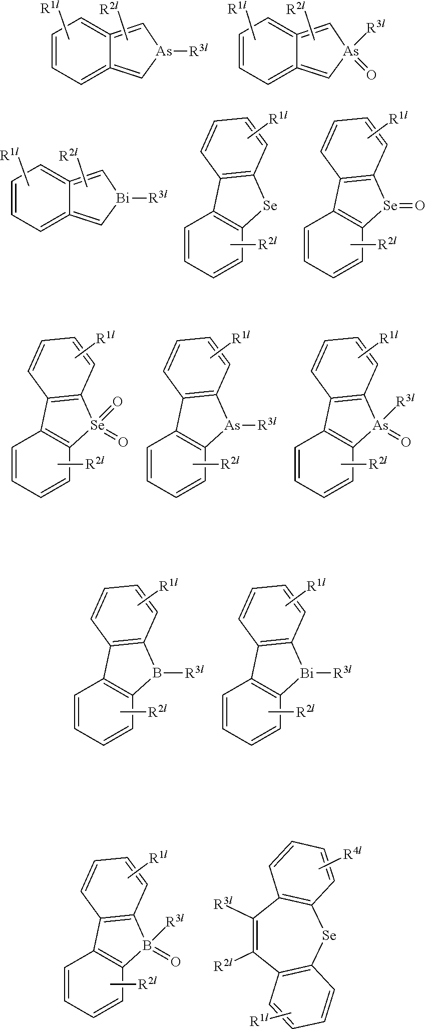 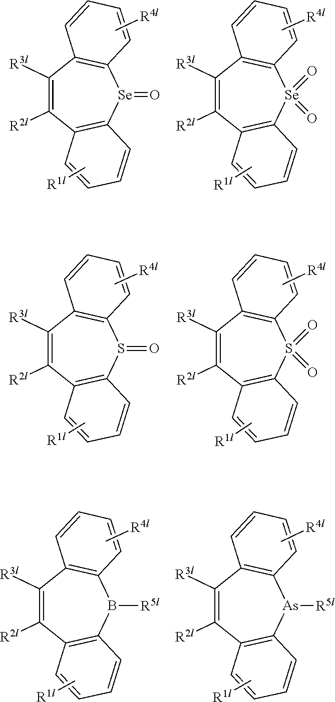 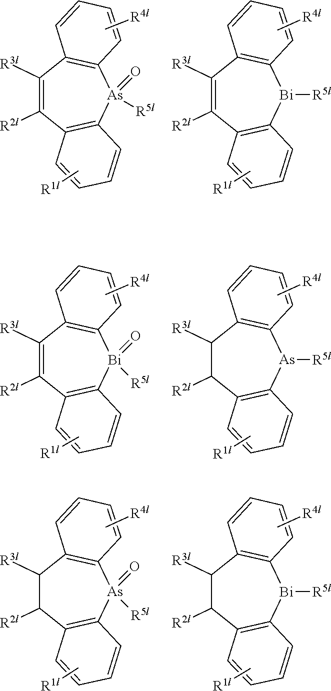 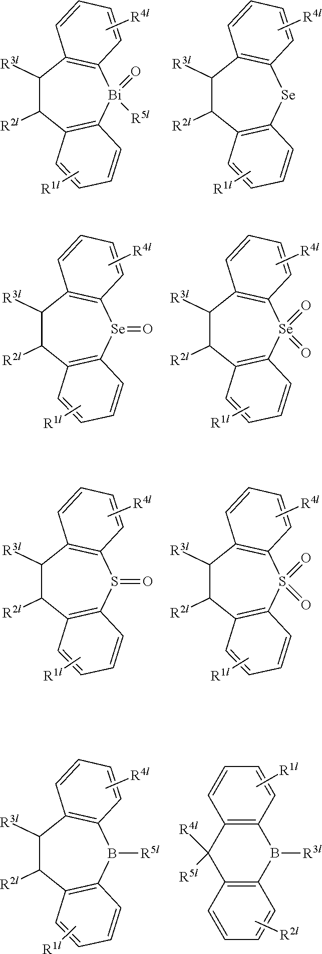 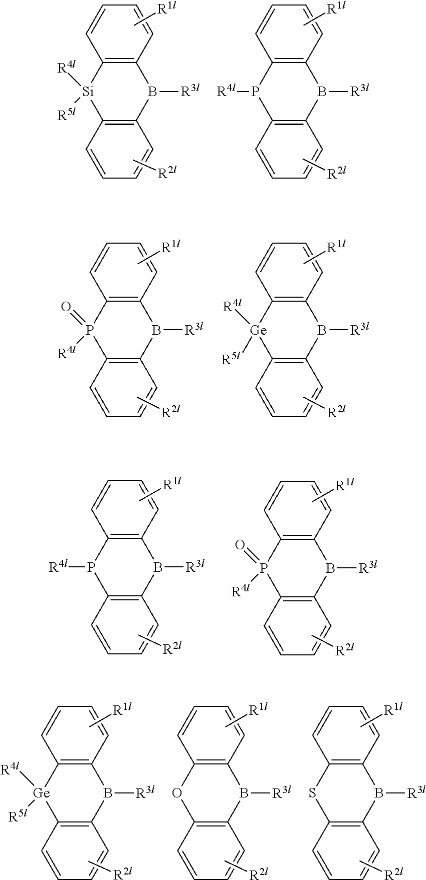 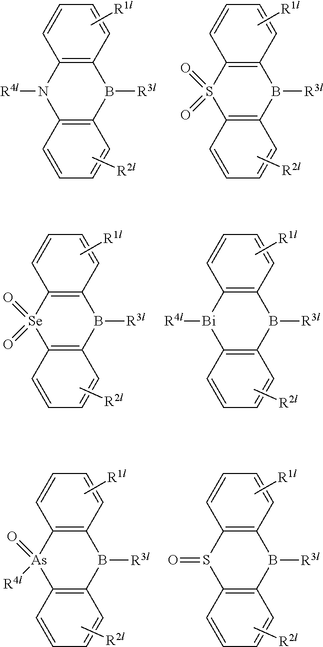 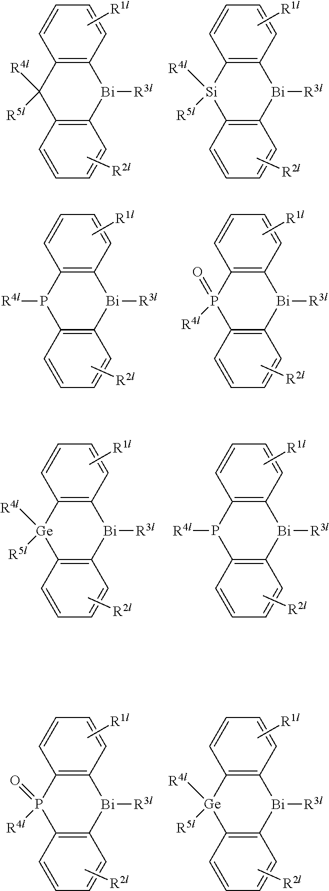 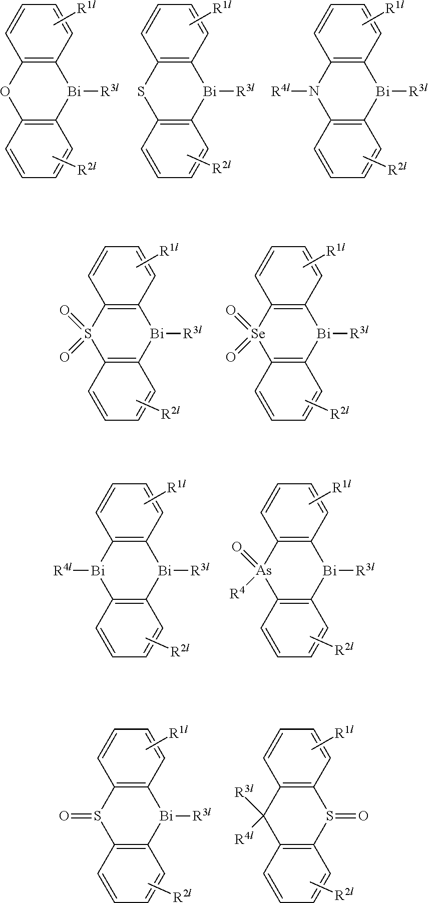 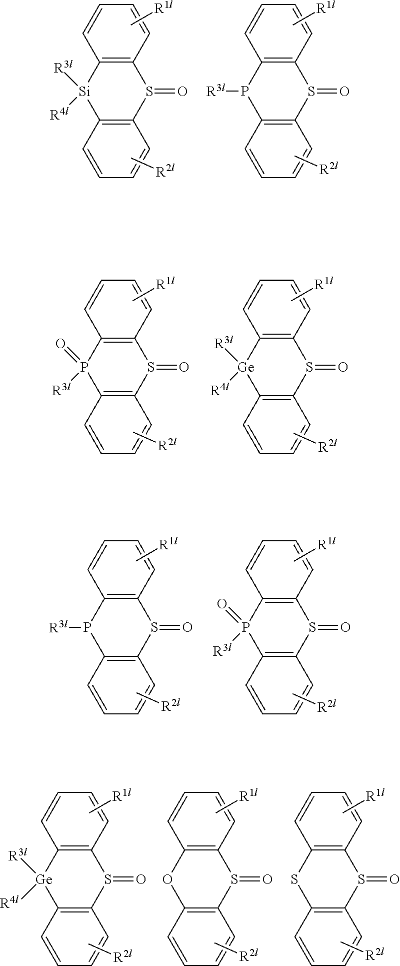 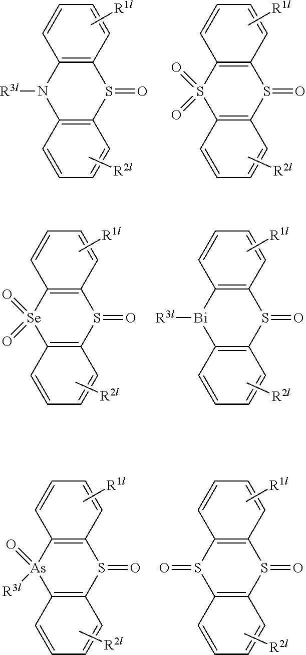 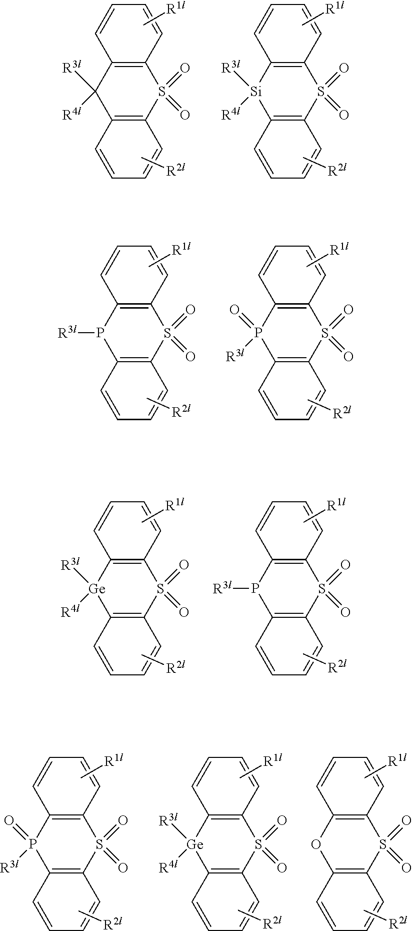 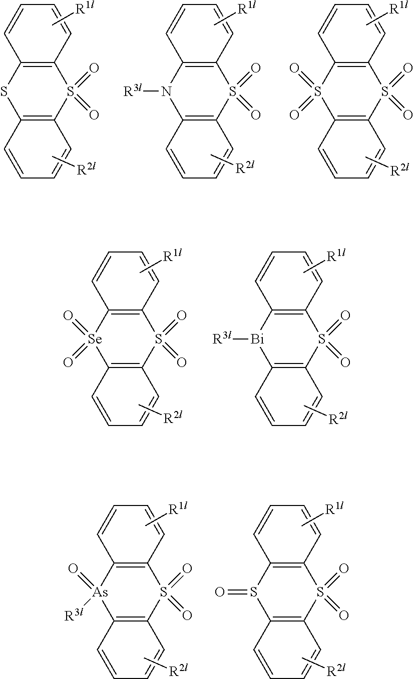 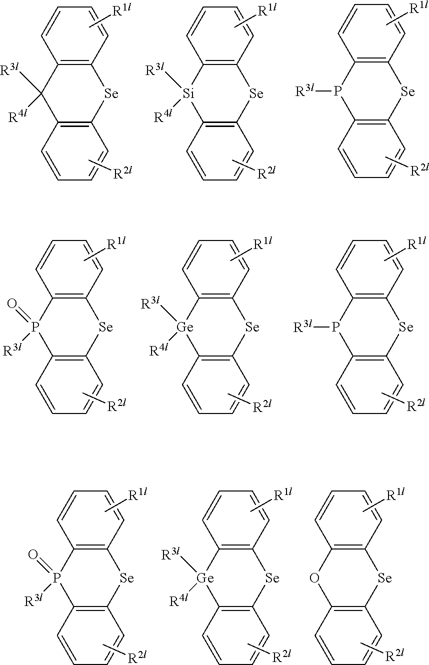 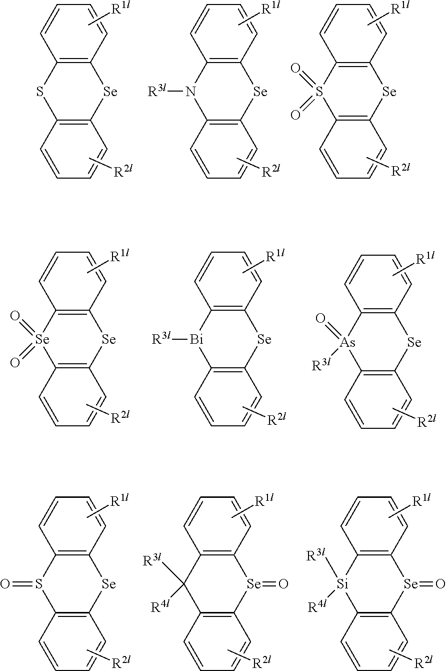 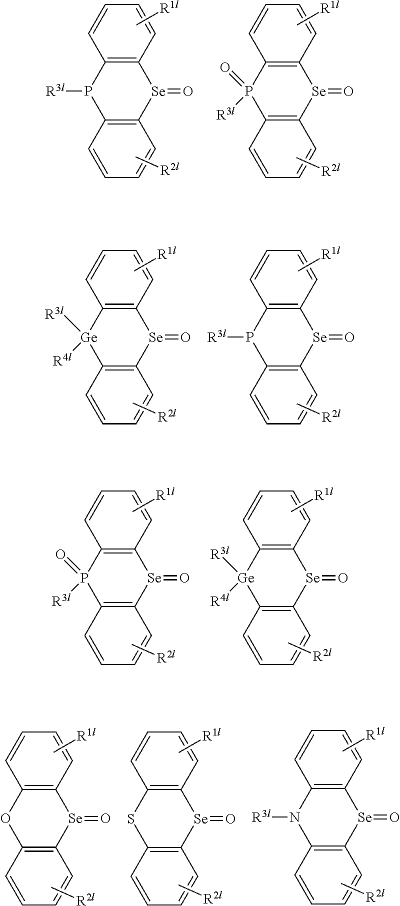 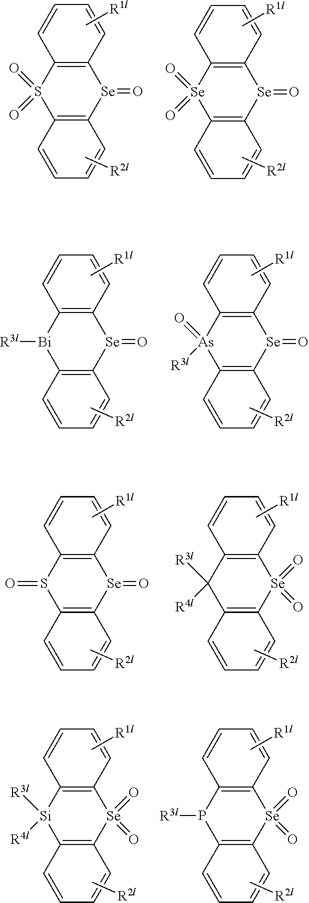 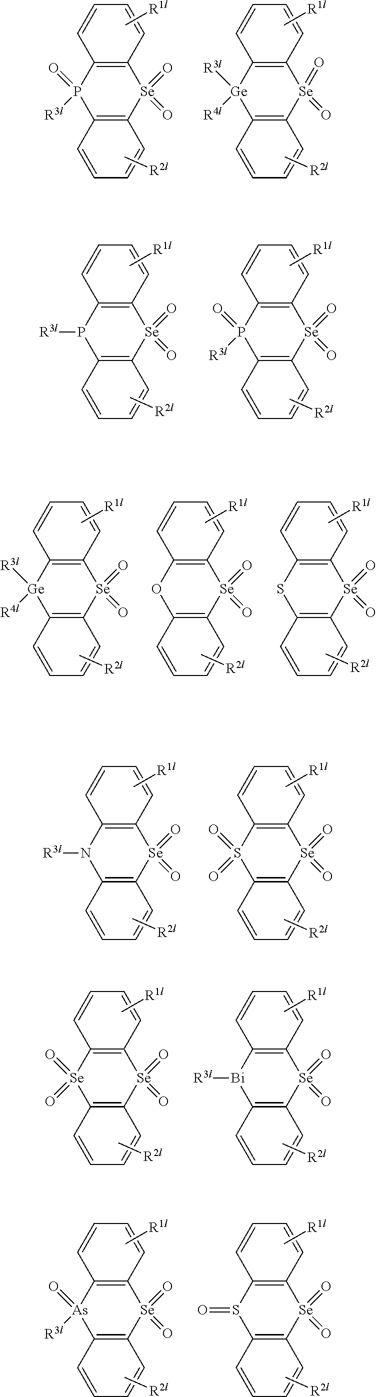 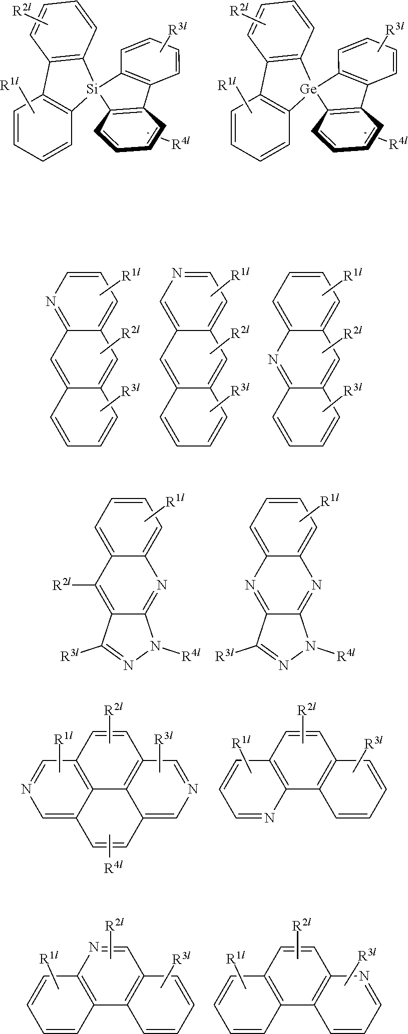 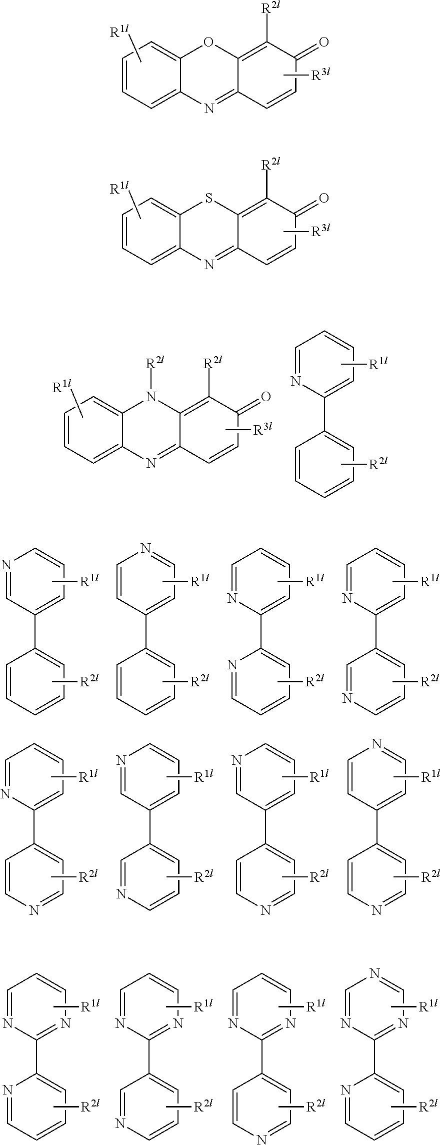 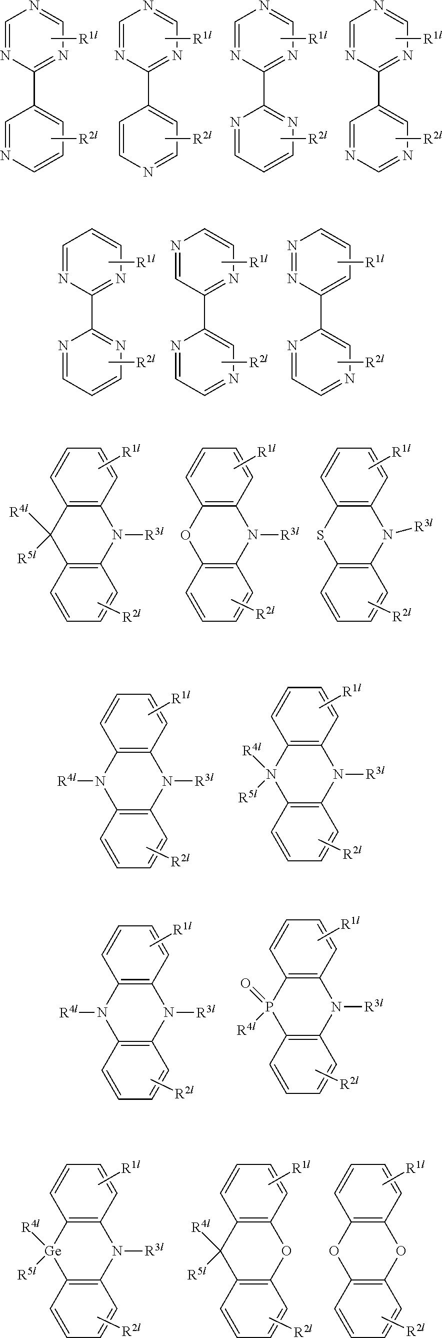 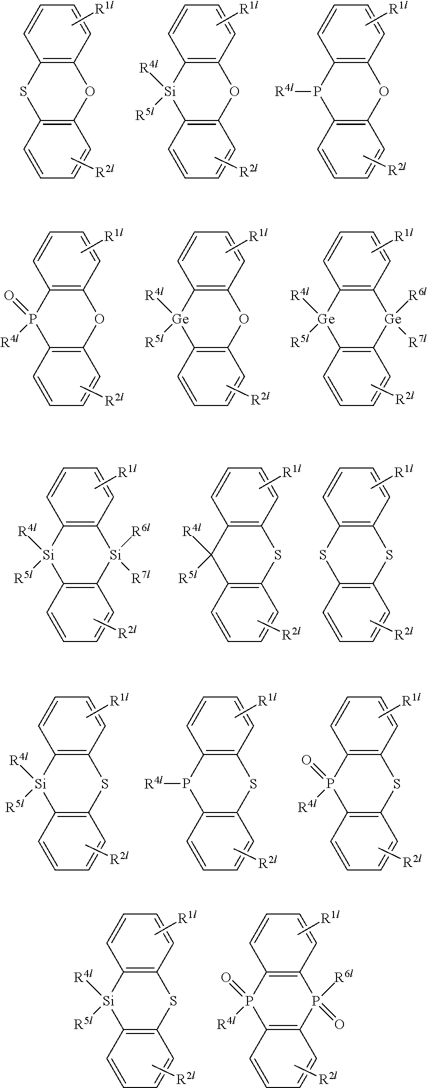 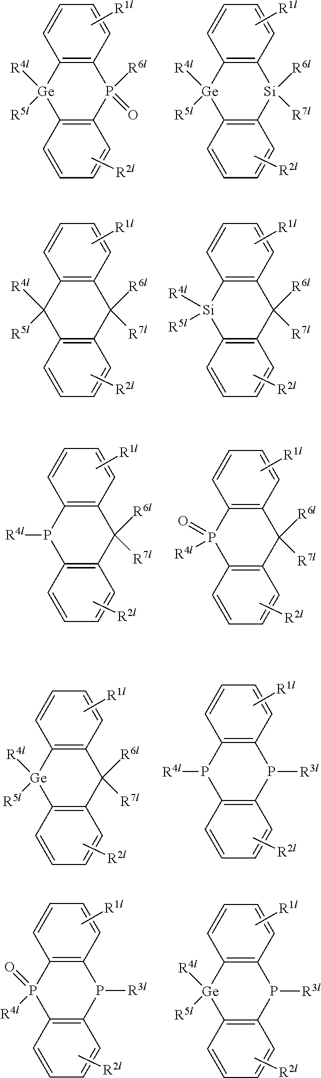 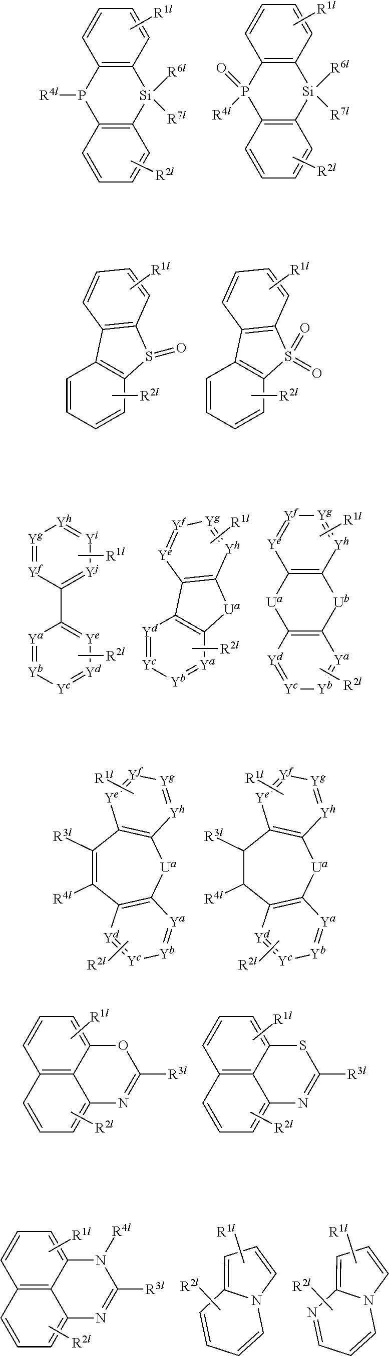 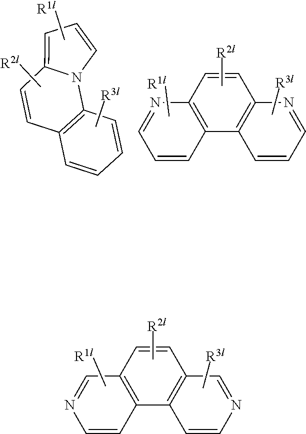
4. Other fluorescent luminophores 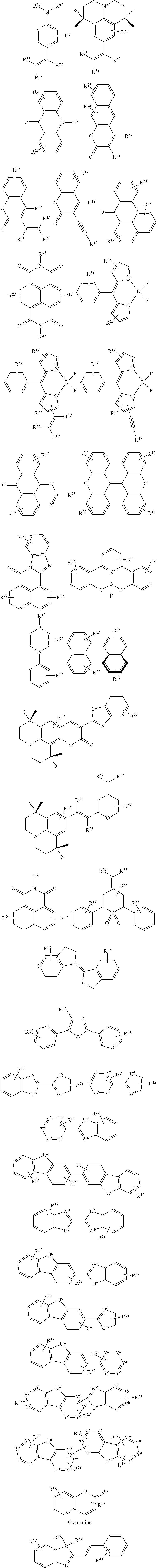
wherein:
each of R^{1l}, R^{2l}, R^{3l}, R^{4l}, R^{5l}, R^{6l}, R^{7l}, and R^{8l}, if present, is a mono-, di-, tri-, or tetra-substitution, valency permitting, and each R^{1l}, R^{2l}, R^{3l}, R^{4l}, R^{5l}, R^{6l}, R^{7l}, and R^{8l} is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof,
each of Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o}, and Y^{p}, if present, is independently C, N or B,
each of U^{a}, U^{b}, and U^{c}, if present, is independently CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³, and
each of W^{a}, W^{b} and W^{c}, if present, is independently CH, CR¹, SiR¹, GeH, GeR¹, N, P, B, Bi, or Bi═O.

26. The compound of claim 16, wherein each of X, Y, and Z, if present, is independently one of the following structures: 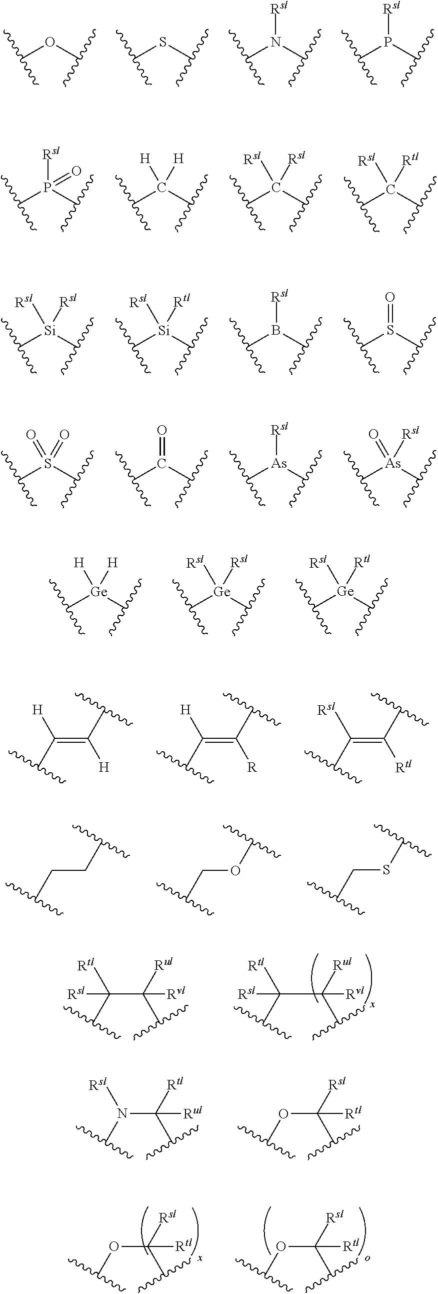 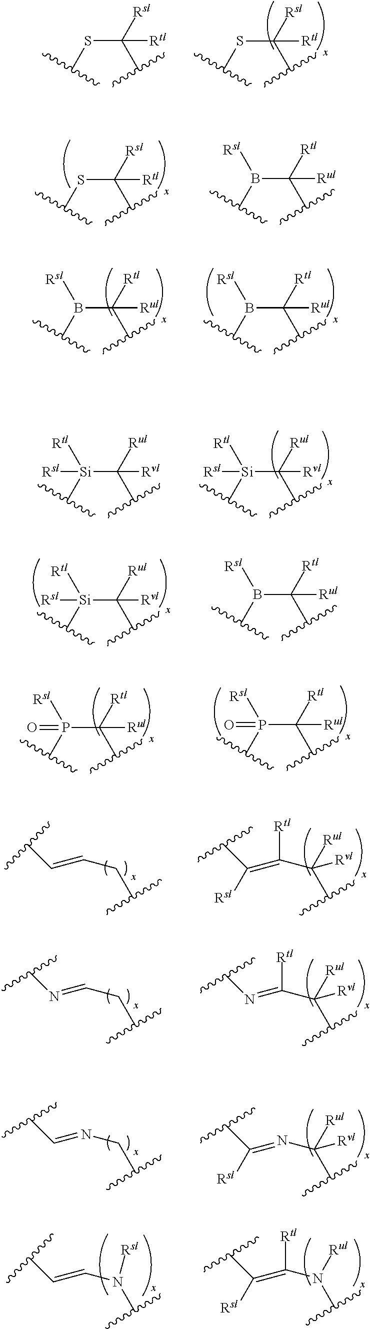 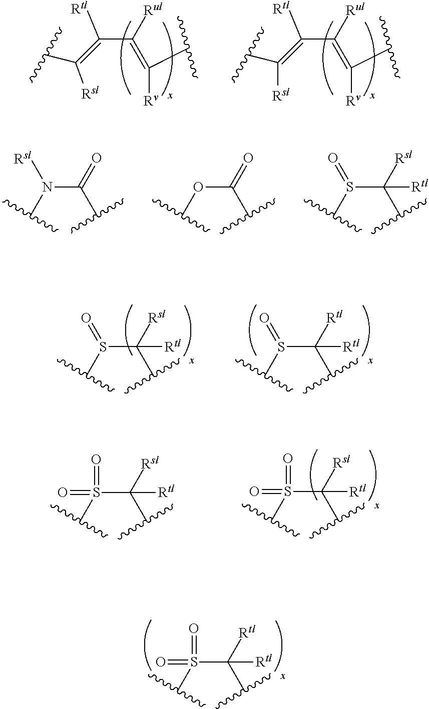
wherein:
x is an integer from 1 to 10, and
each of R^{sl}, R^{tl}, R^{ul}, and R^{vl}, if present, is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

27. The compound of claim 16, wherein the compound is selected from any of Structures Ir-1 to Ir-25, Rh-1 to Rh-25, and Pt-1 to Pt-13 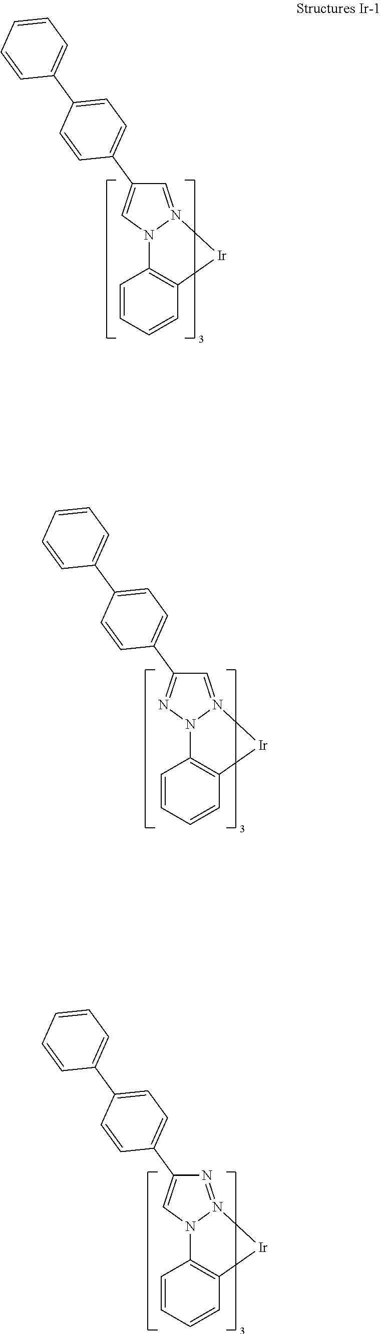 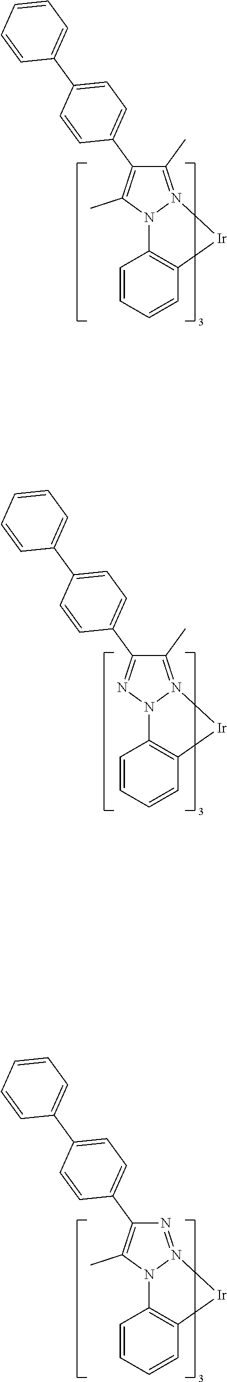 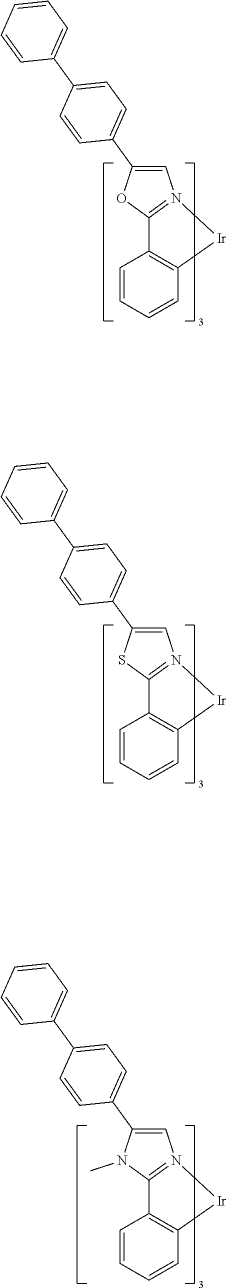 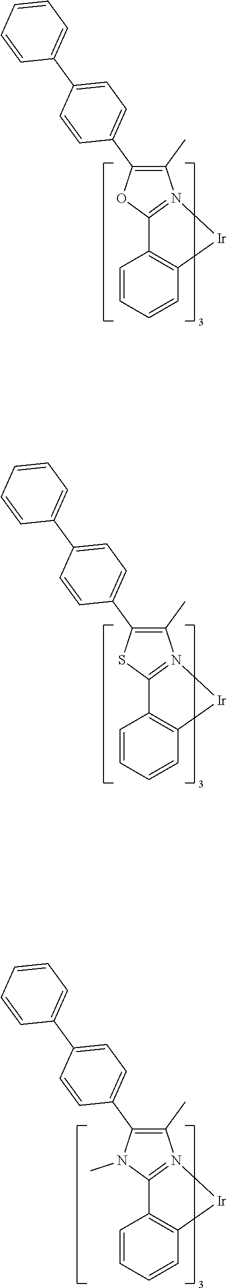 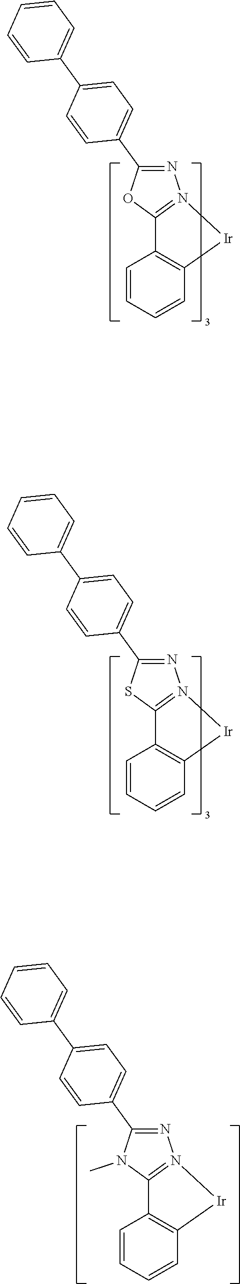 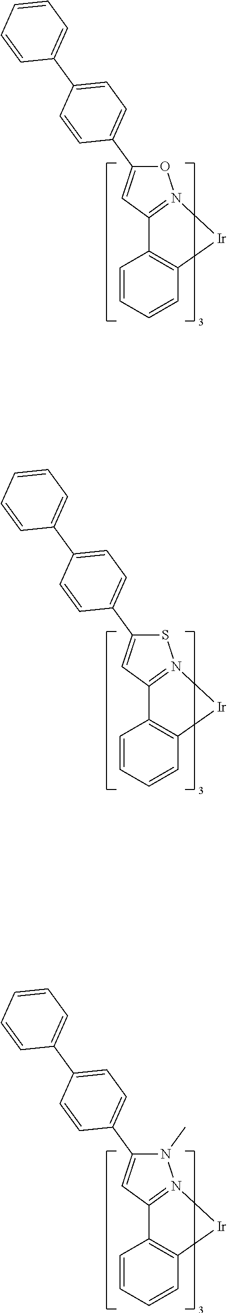 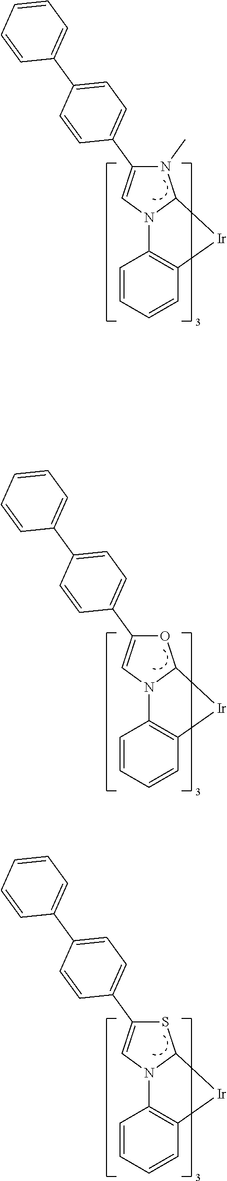 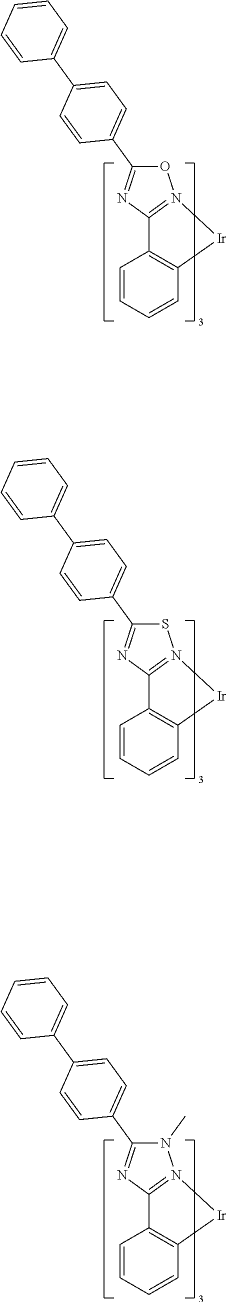 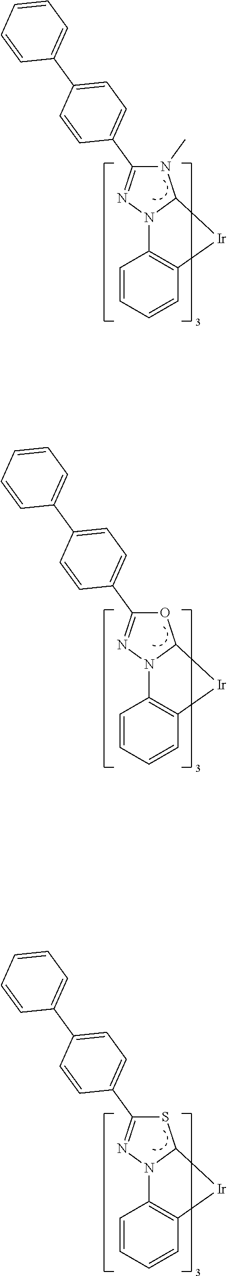 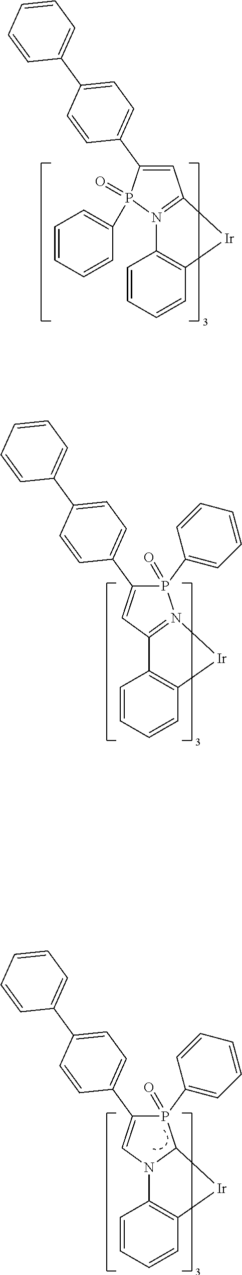 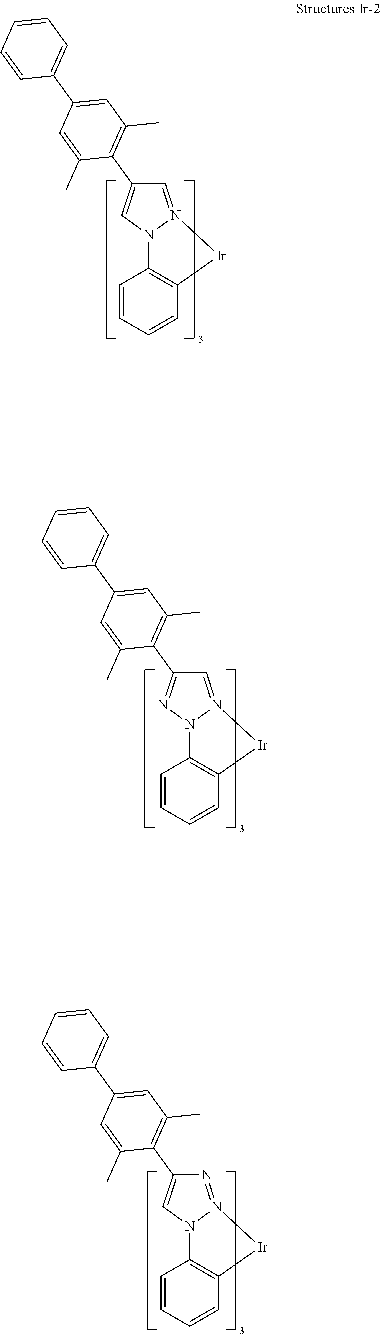 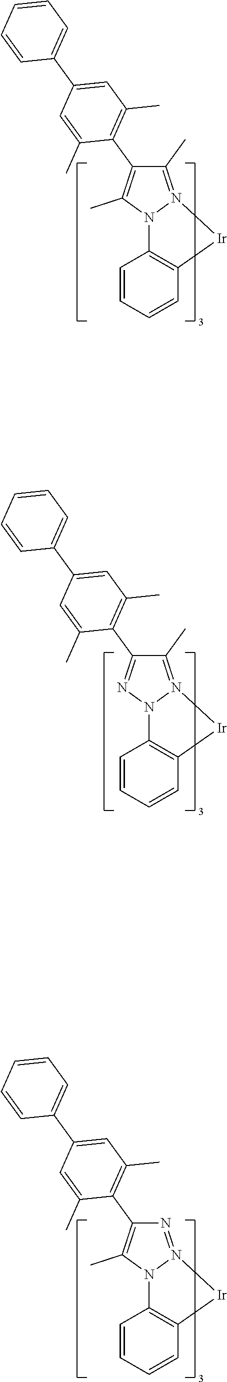 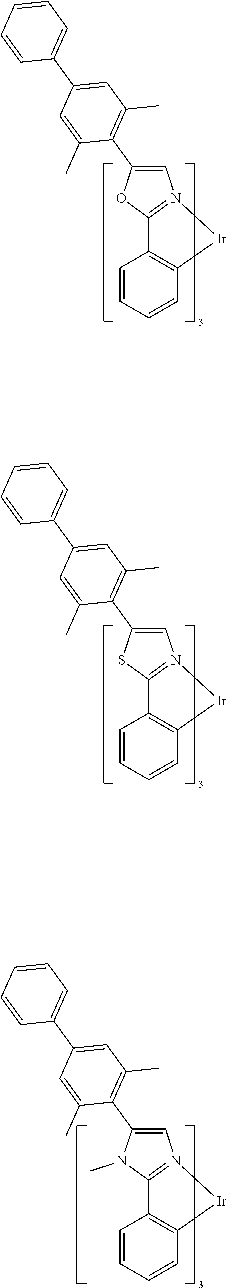 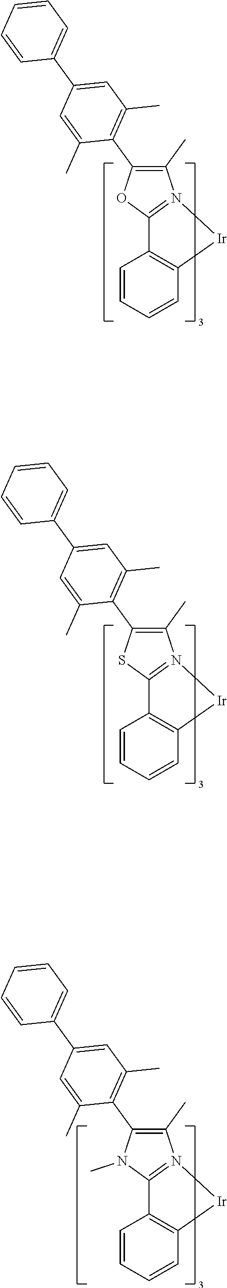 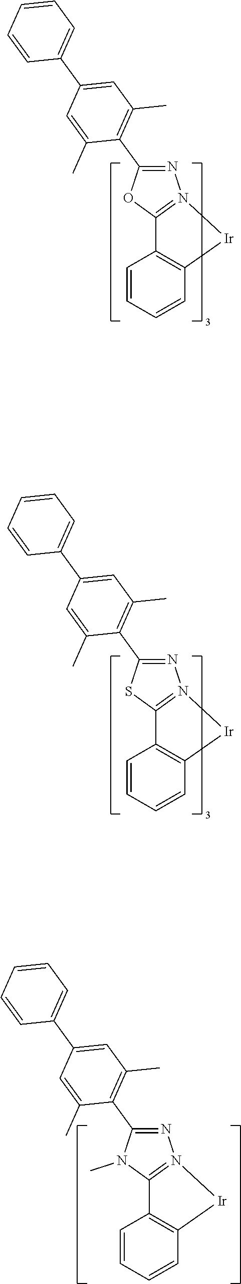 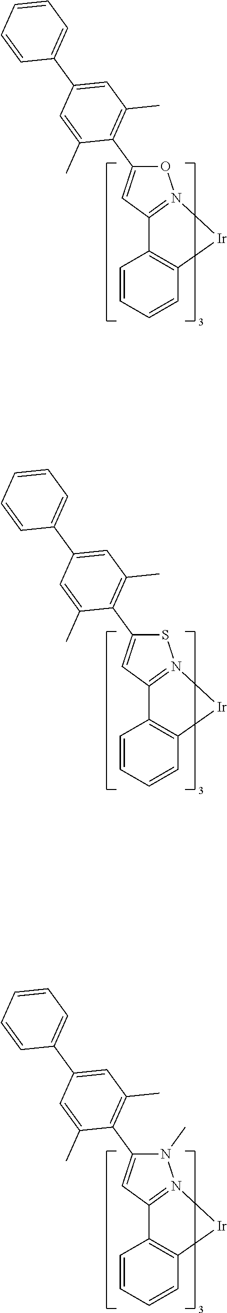 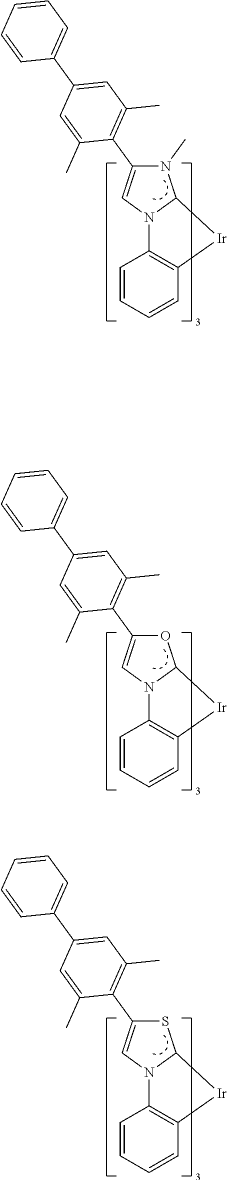 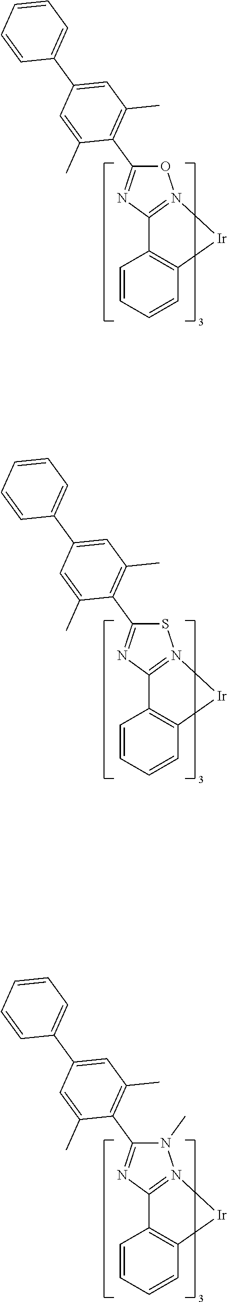 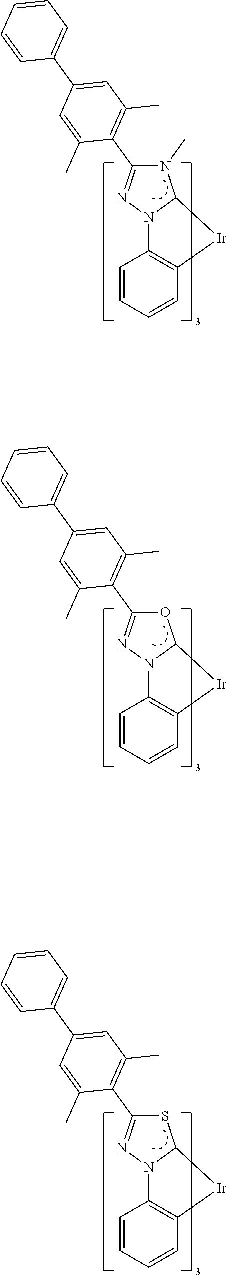 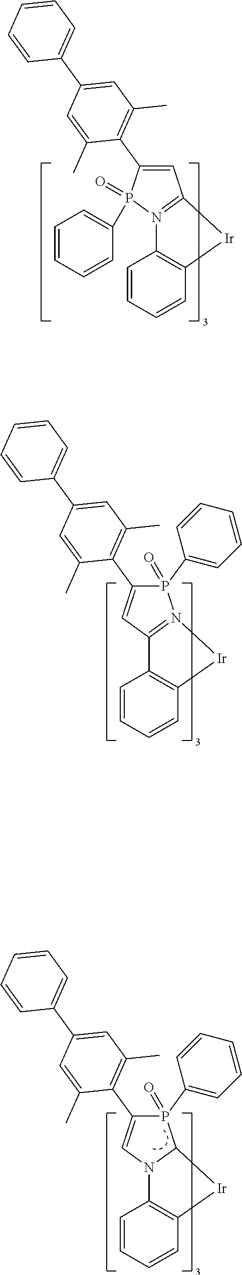 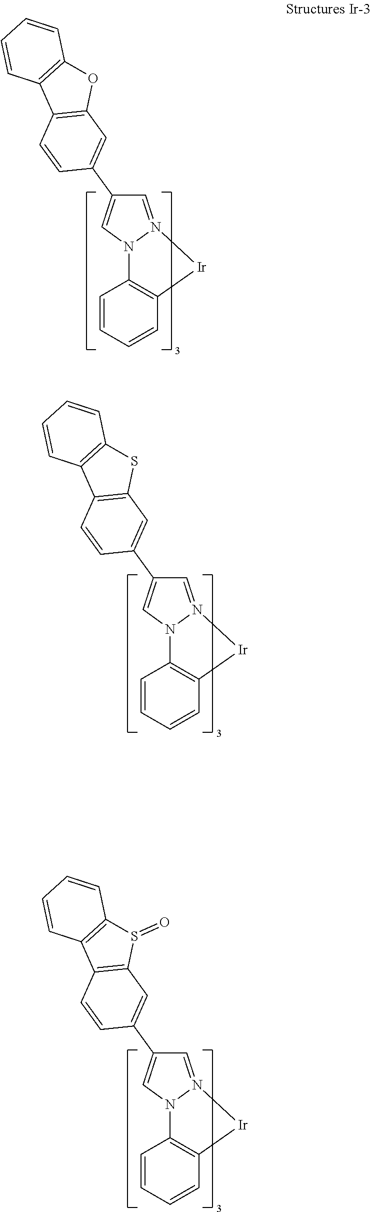 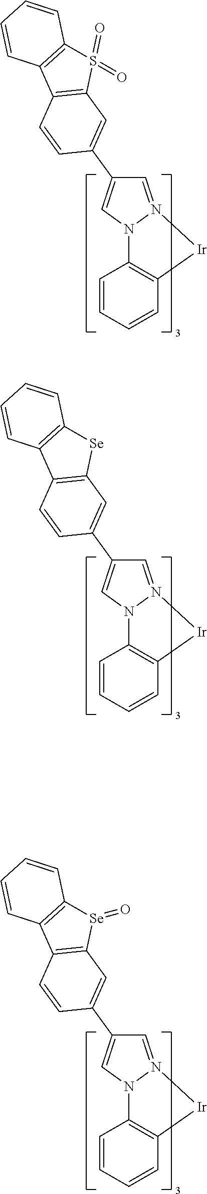 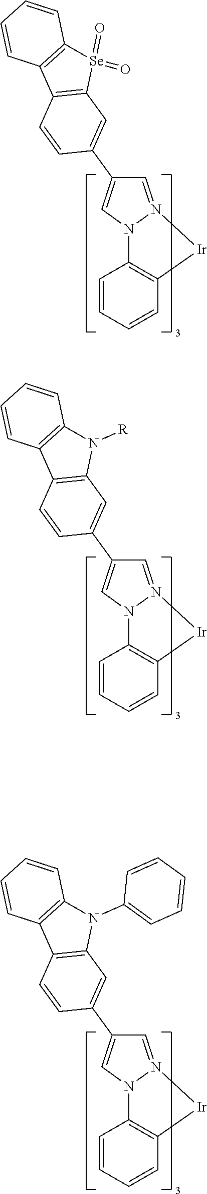 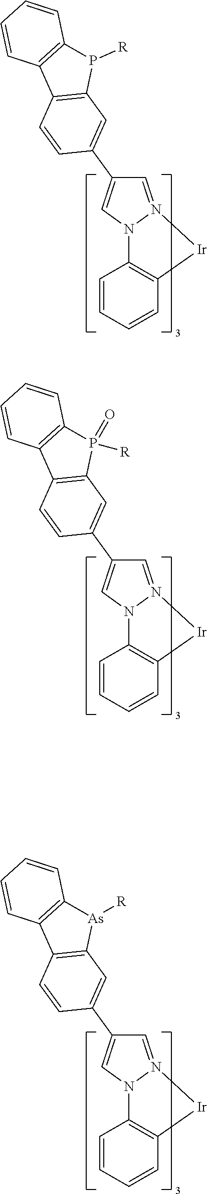 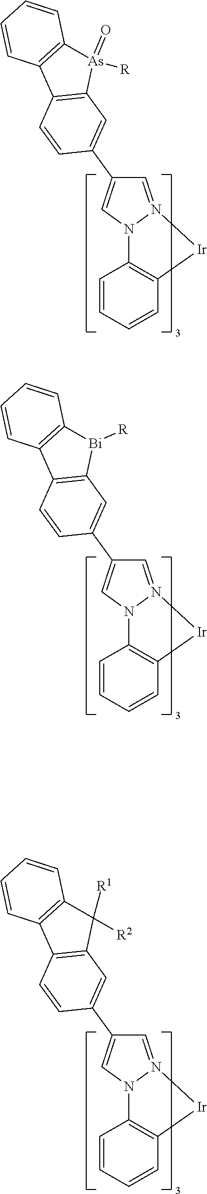 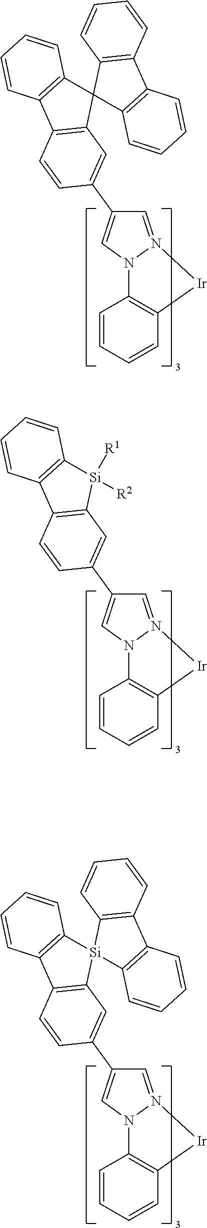 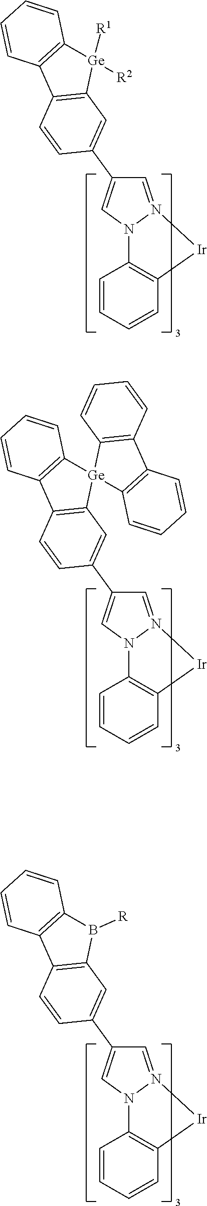 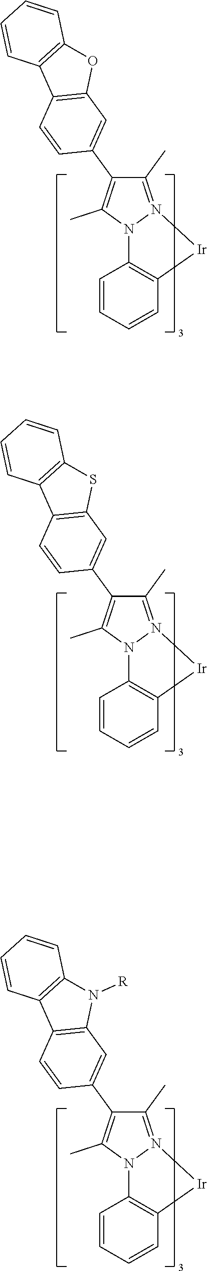 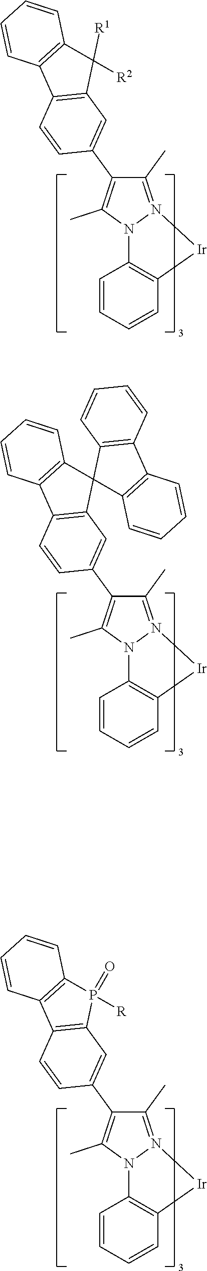 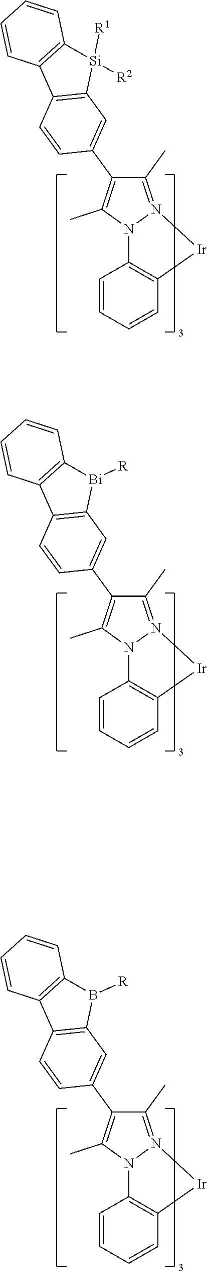 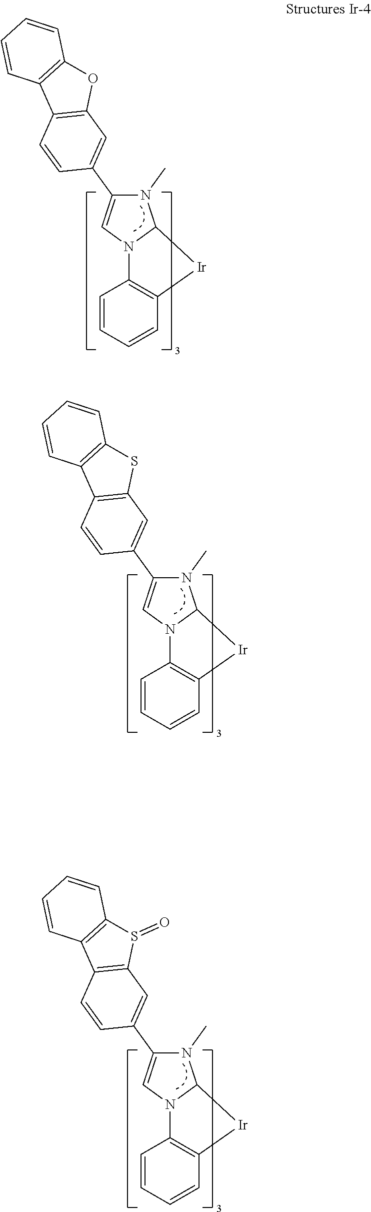 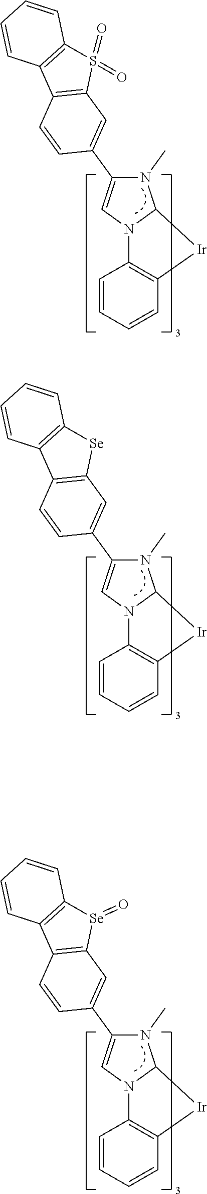 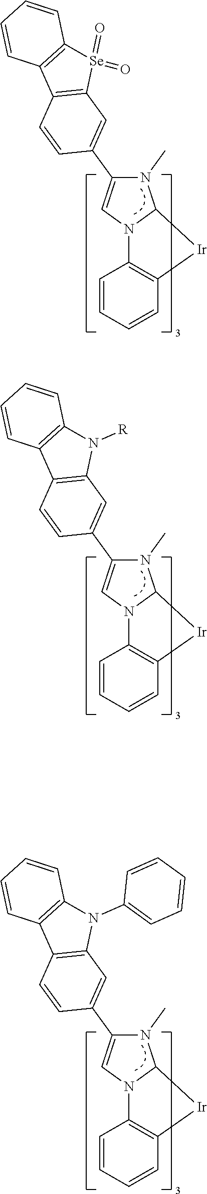 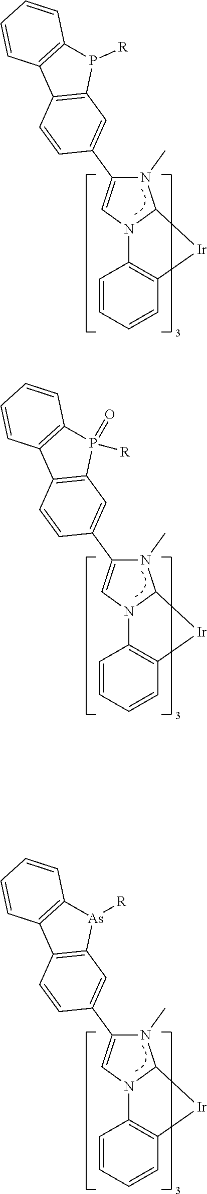 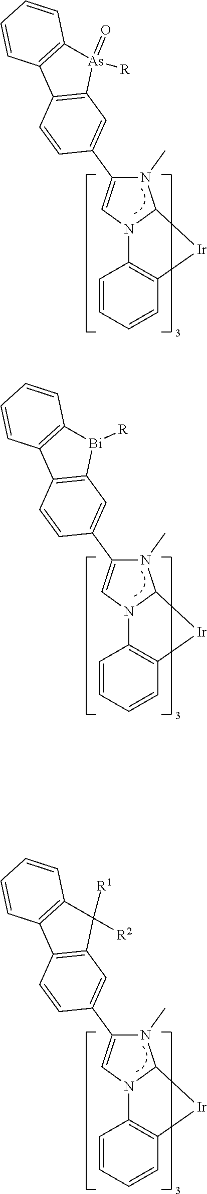 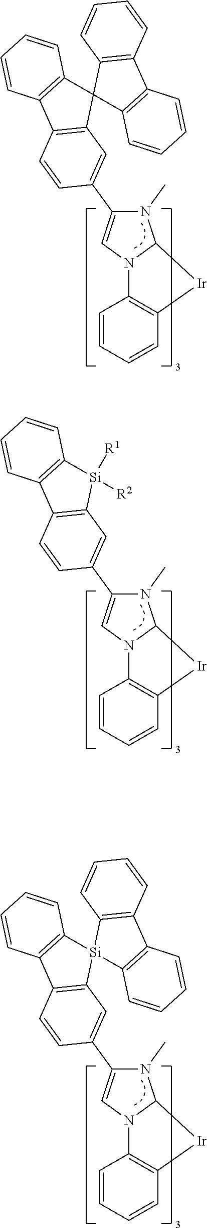 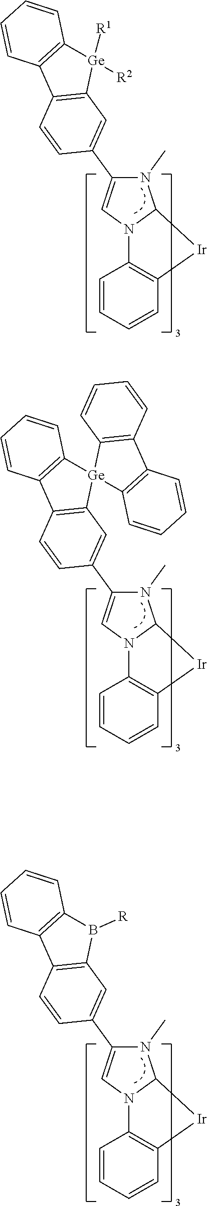 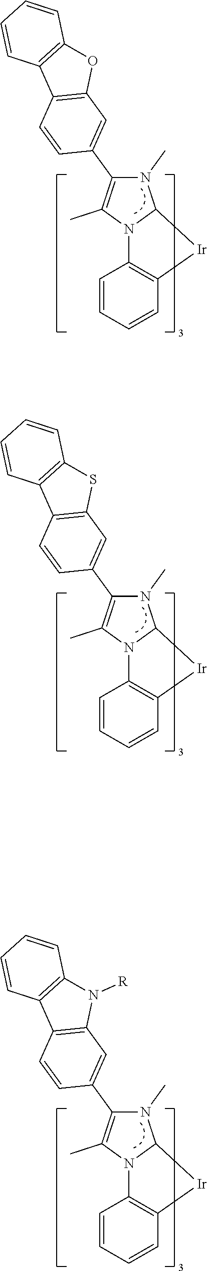 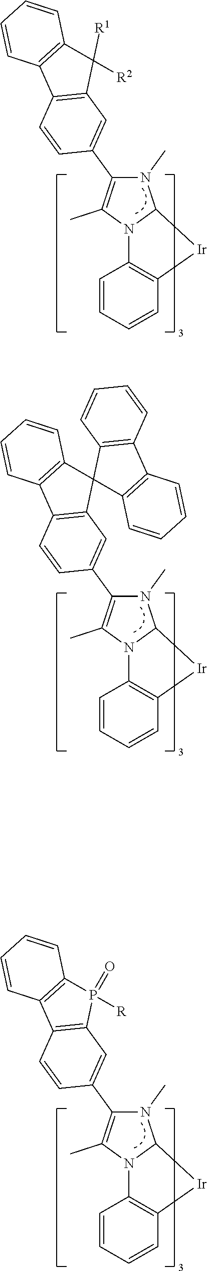 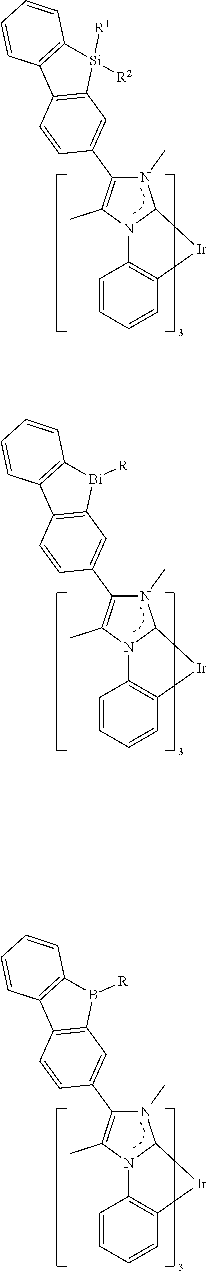 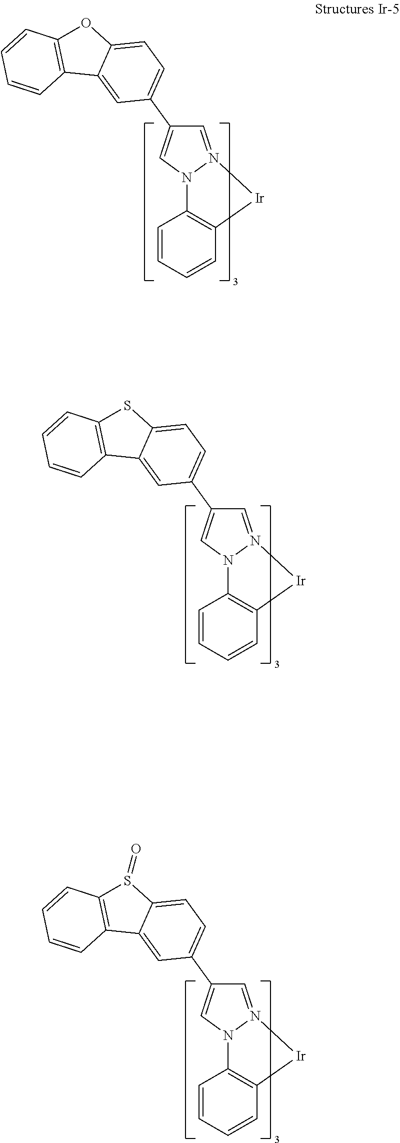 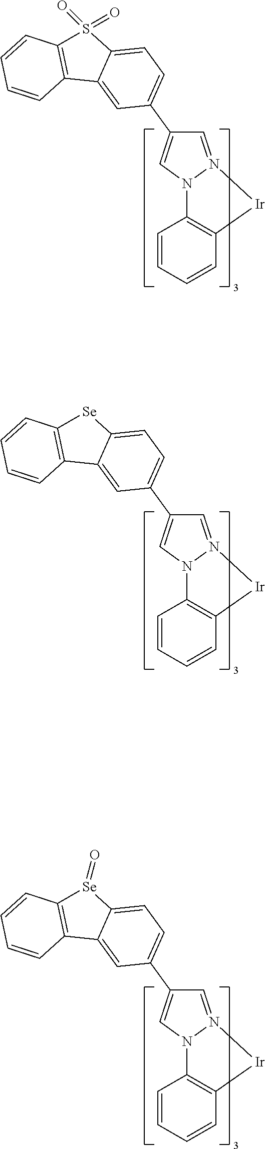 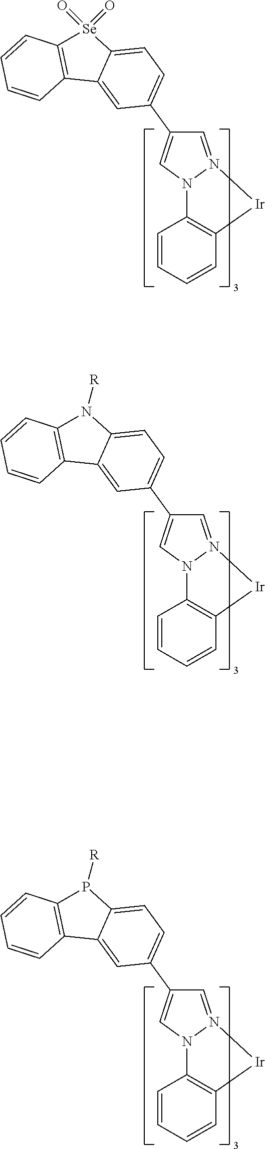 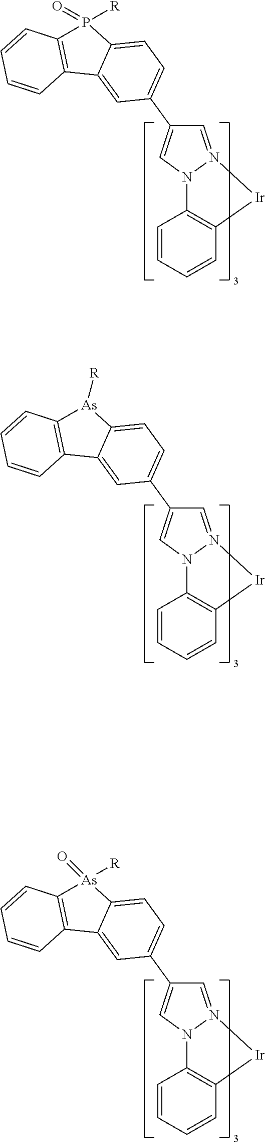 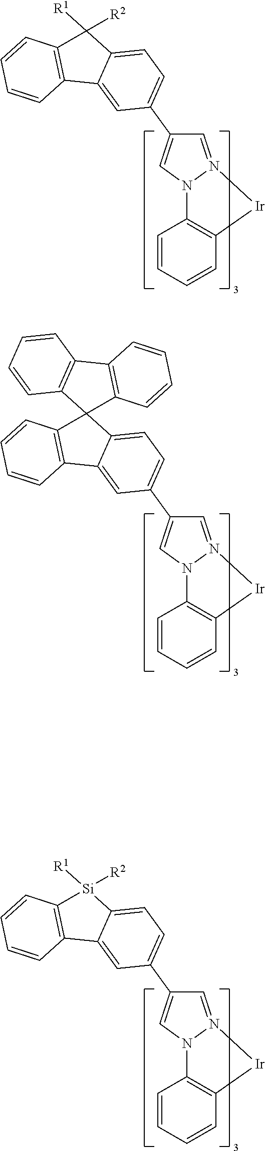 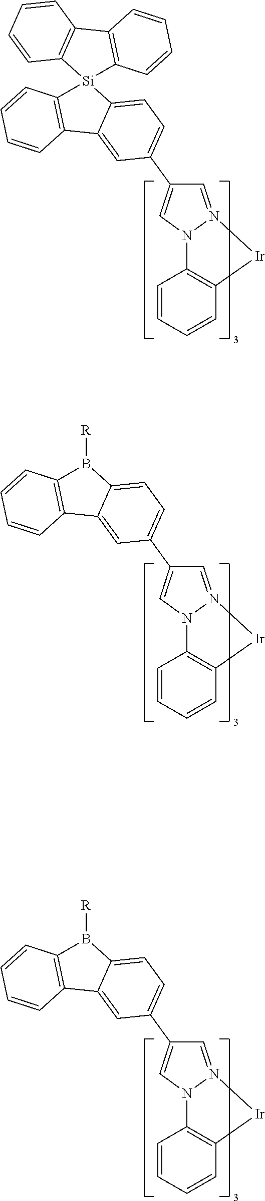 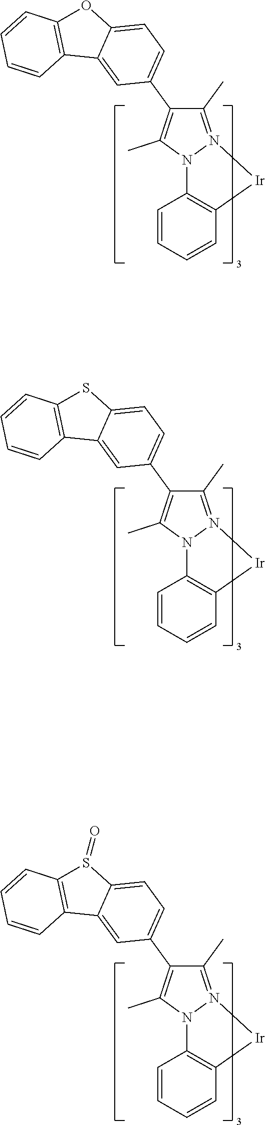 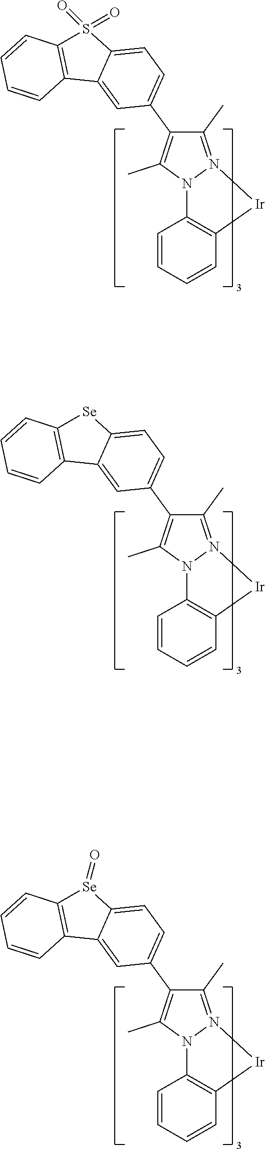 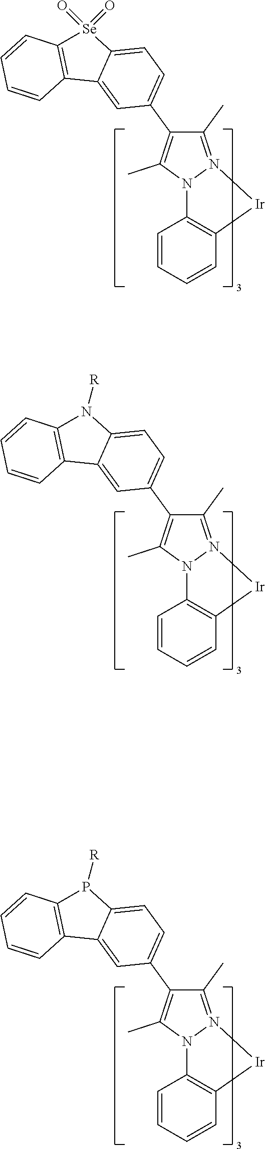 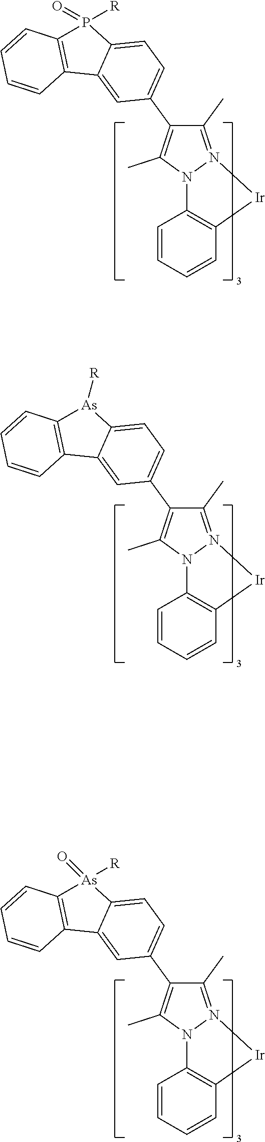 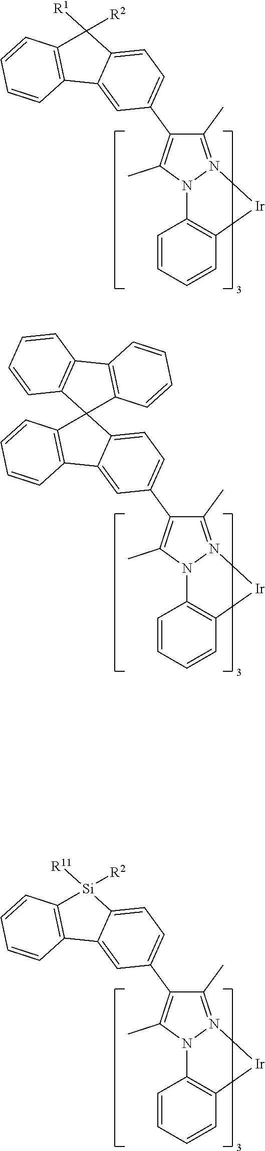 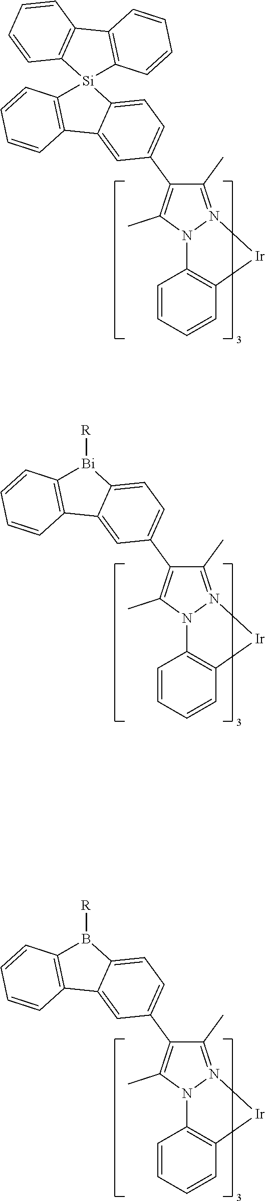 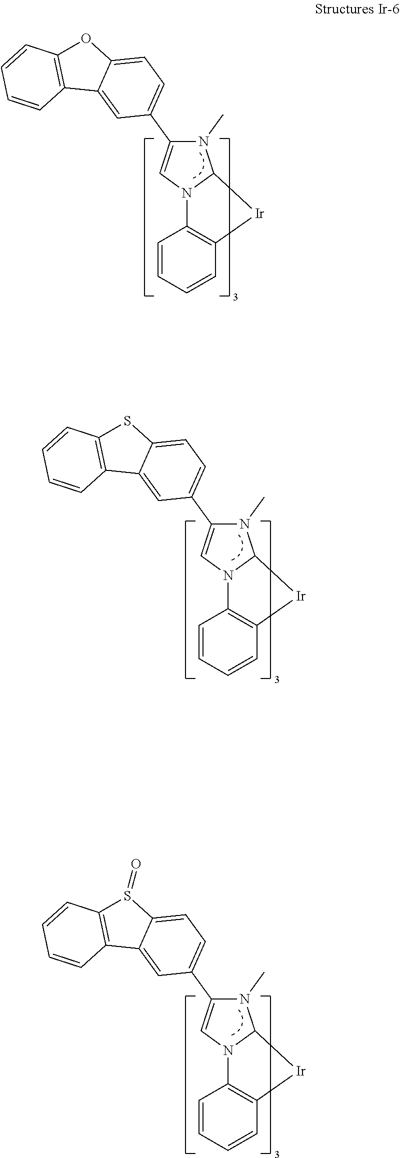 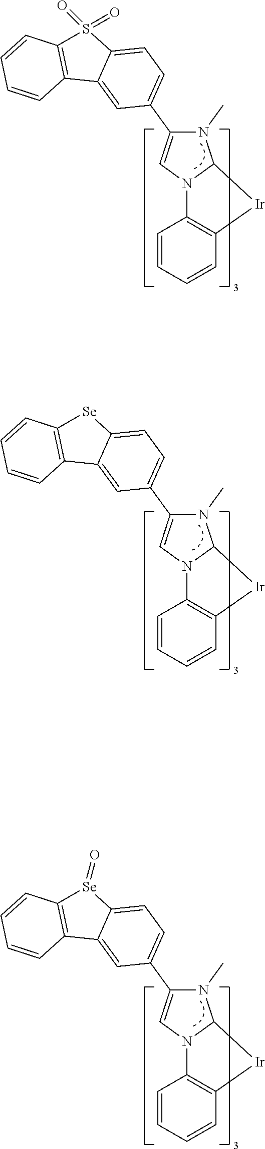 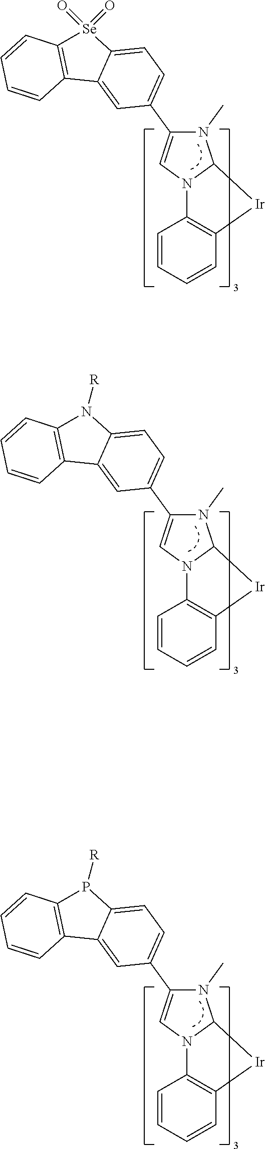 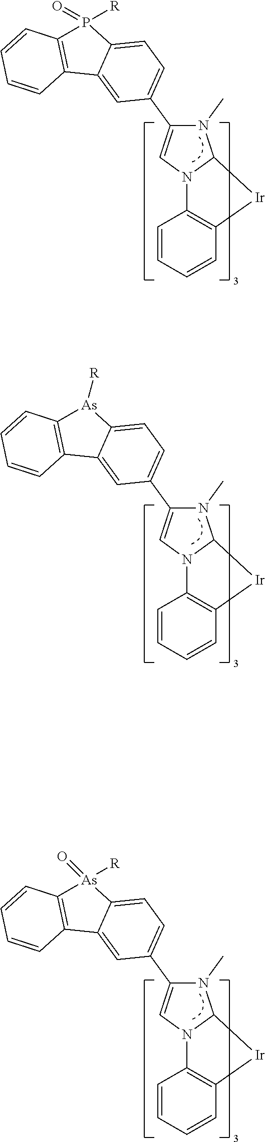 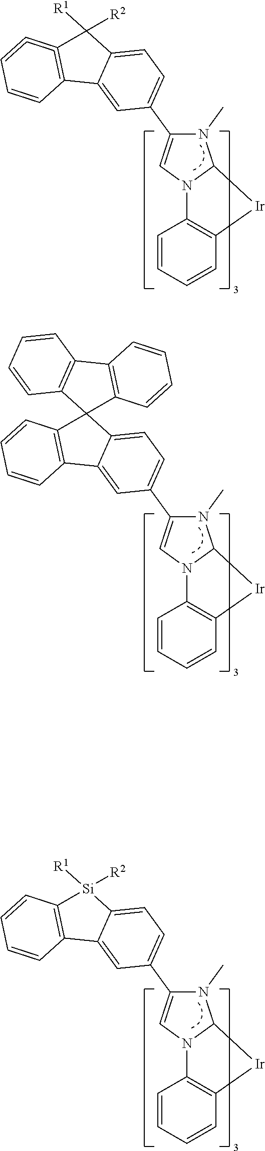 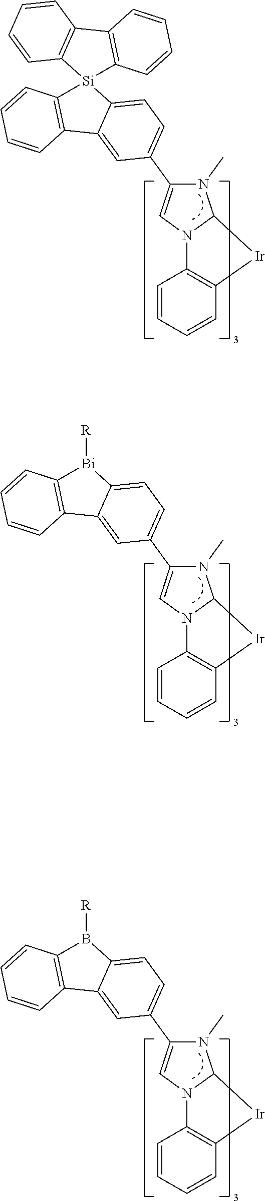 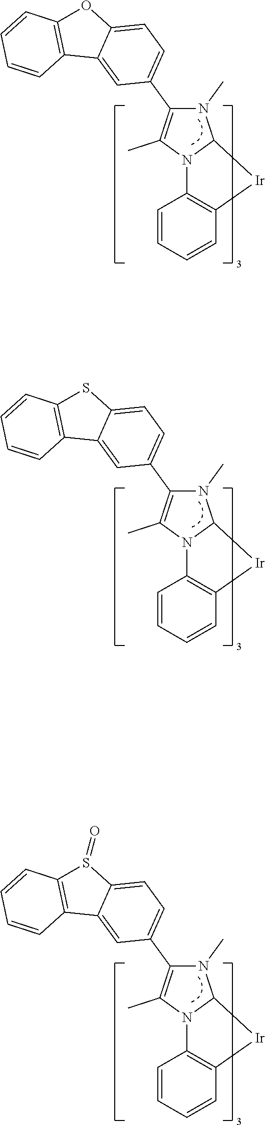 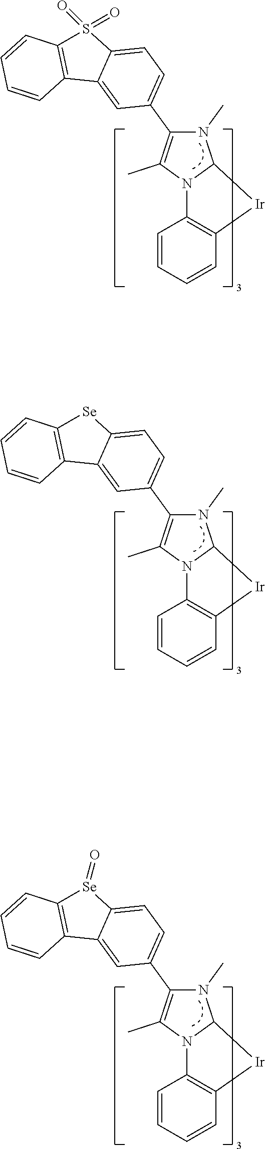 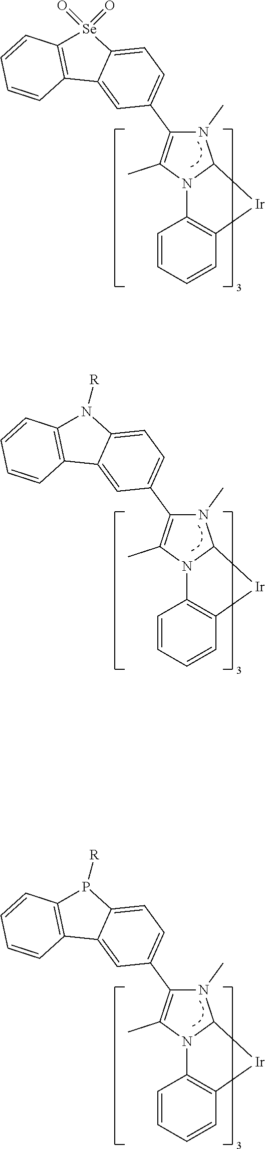 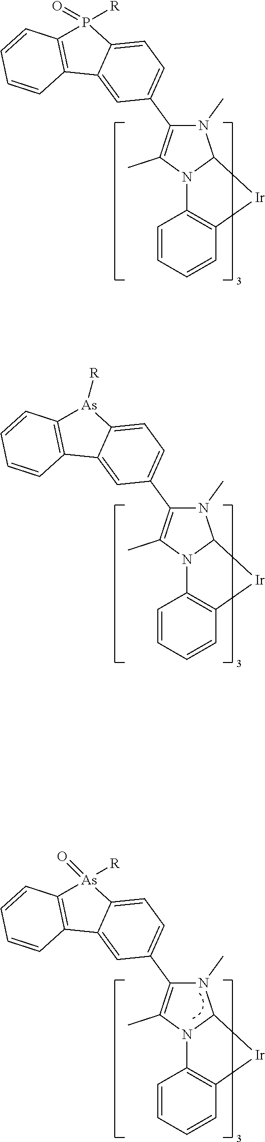 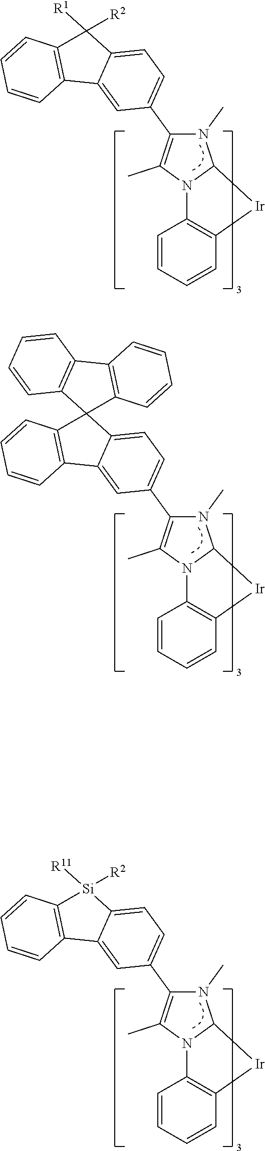 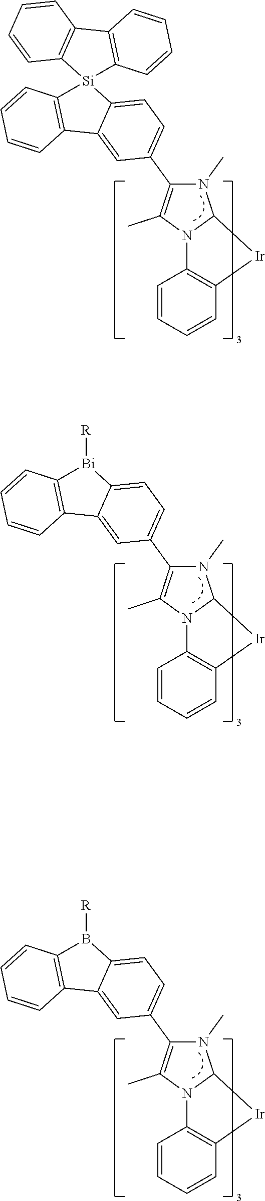 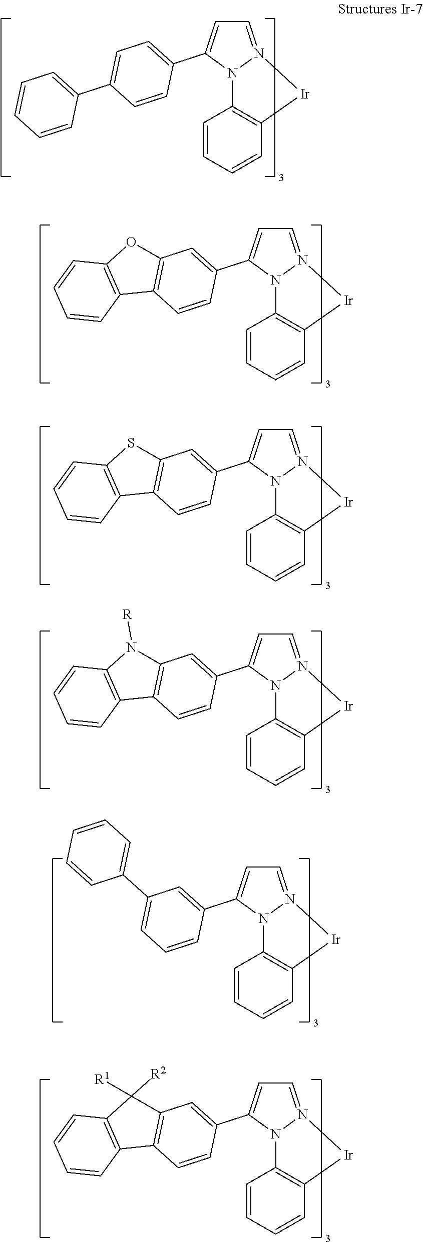 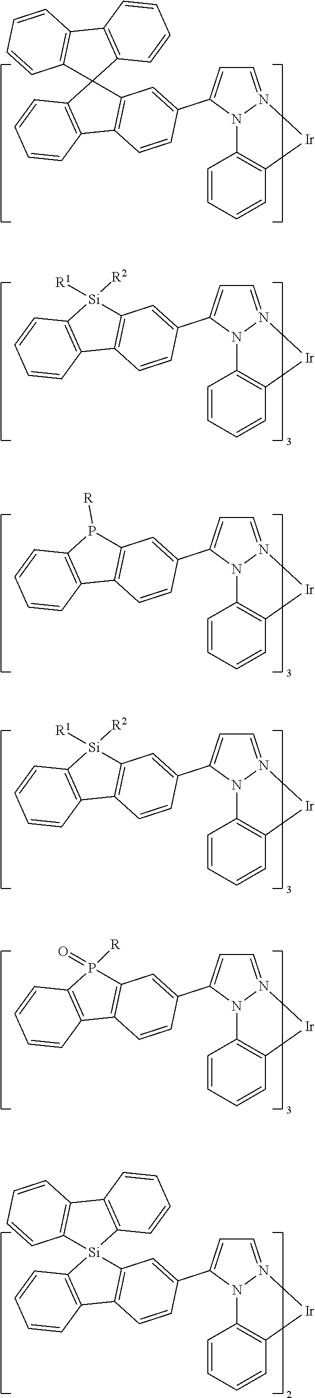 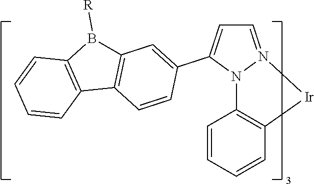 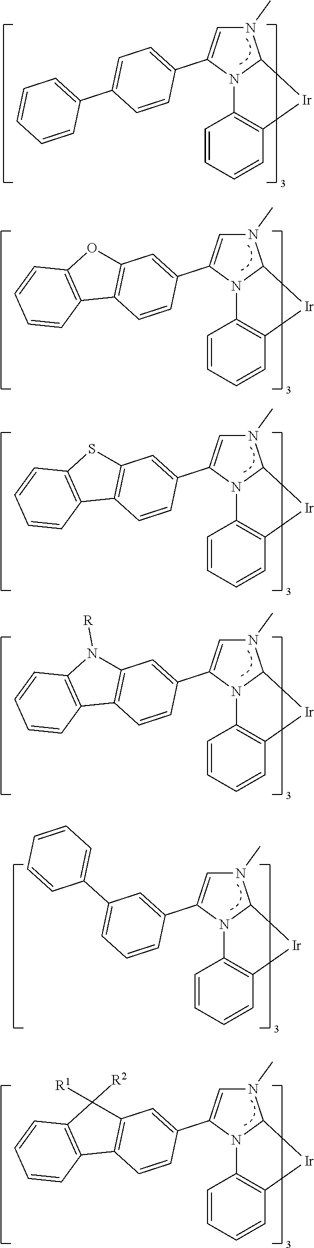 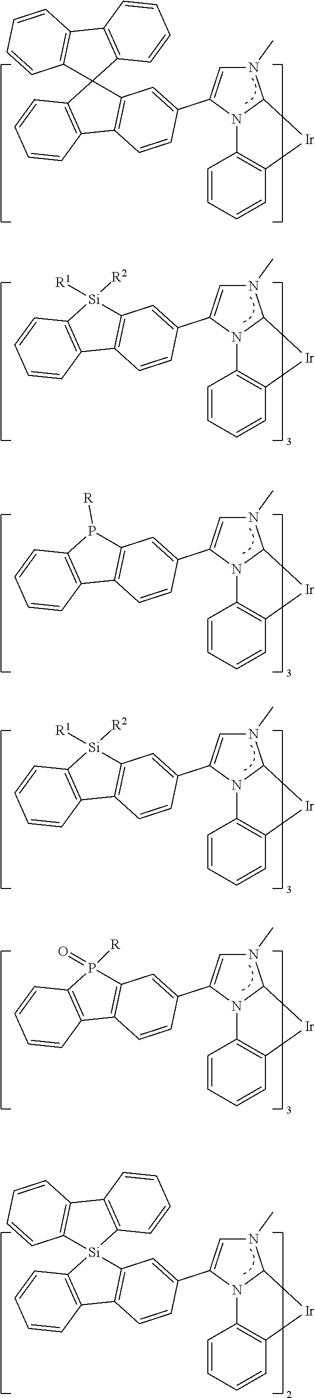 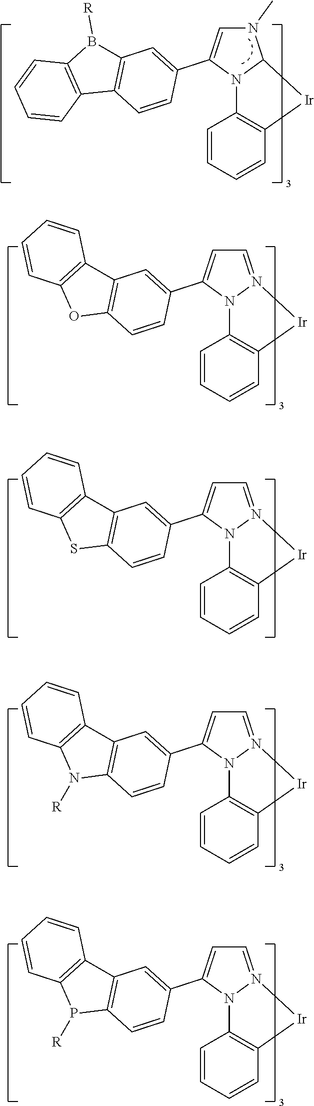 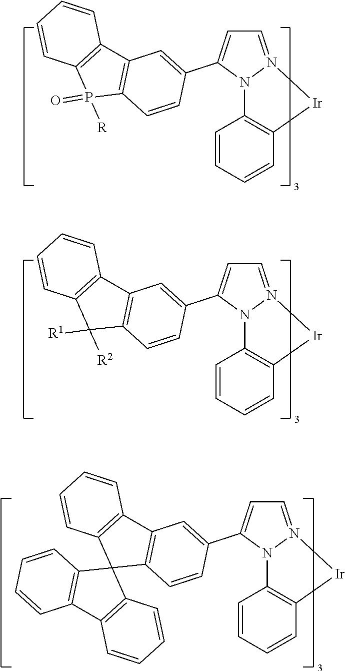 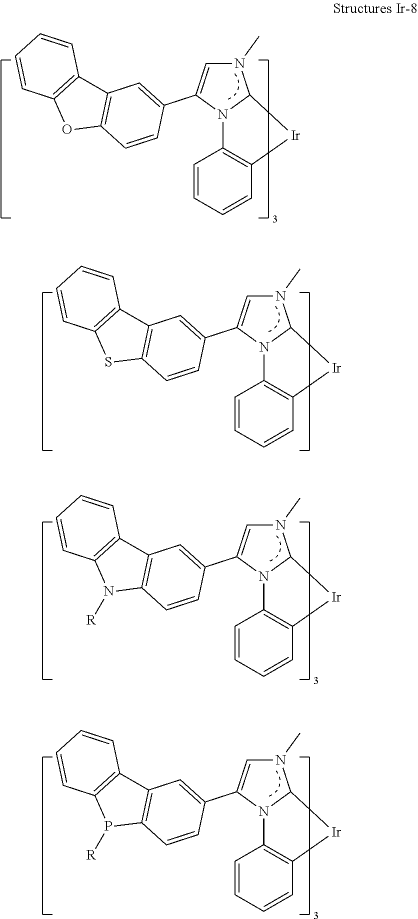 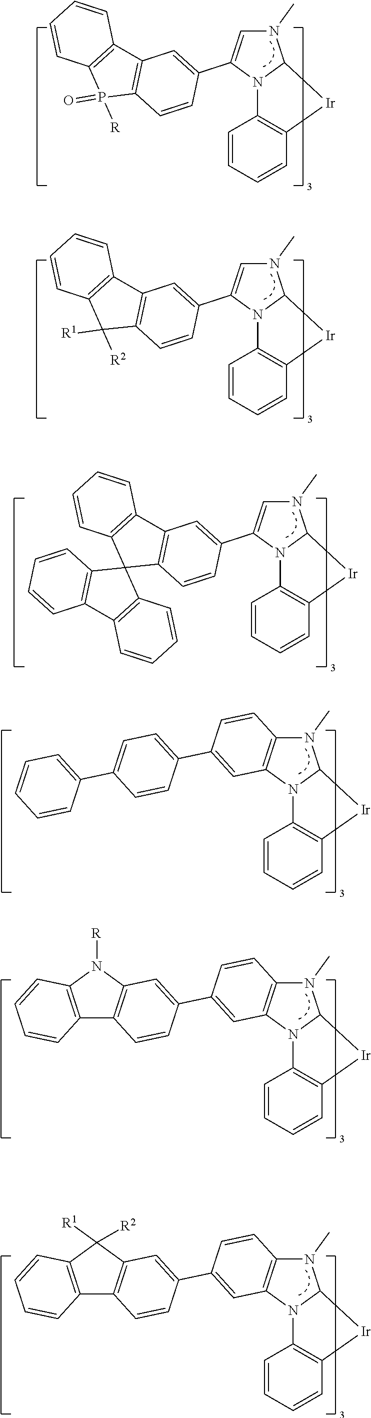 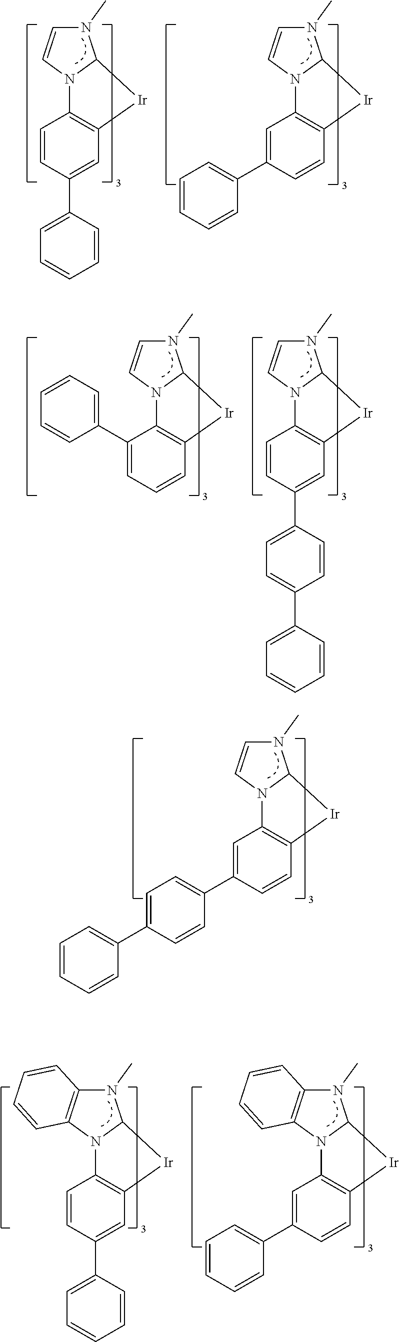 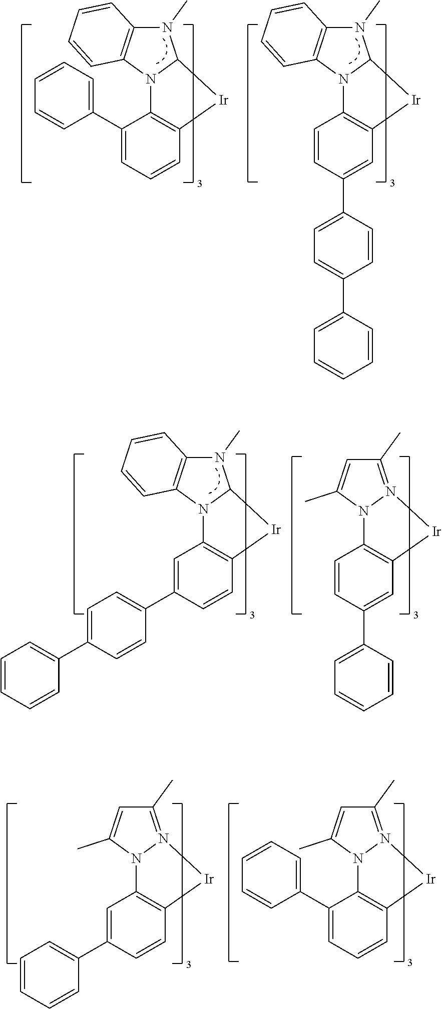 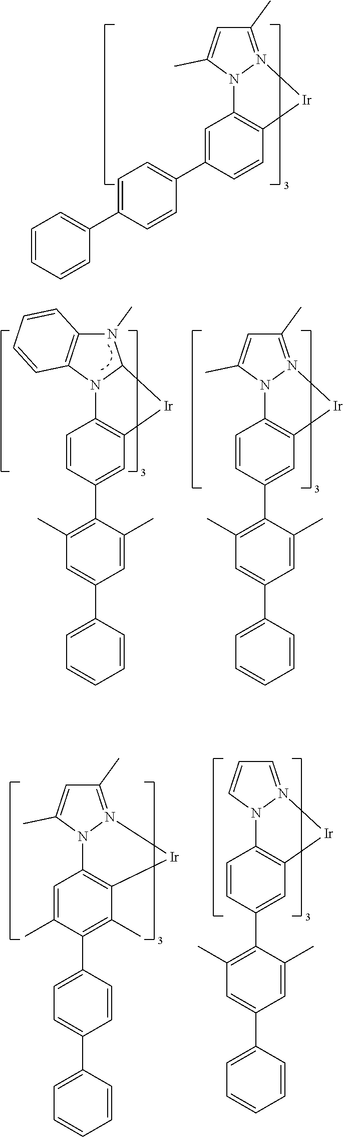 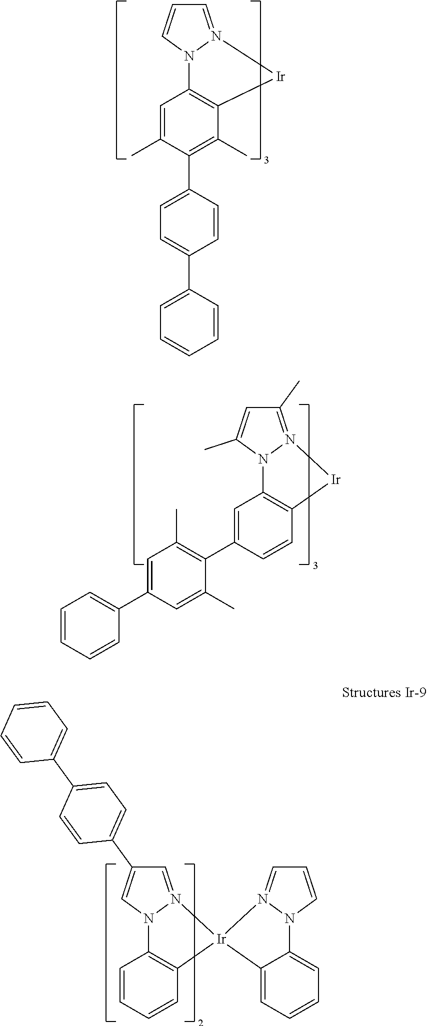 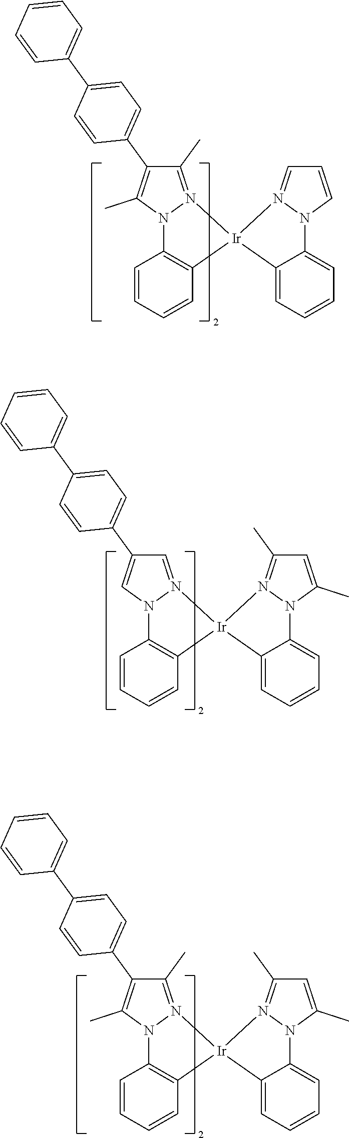 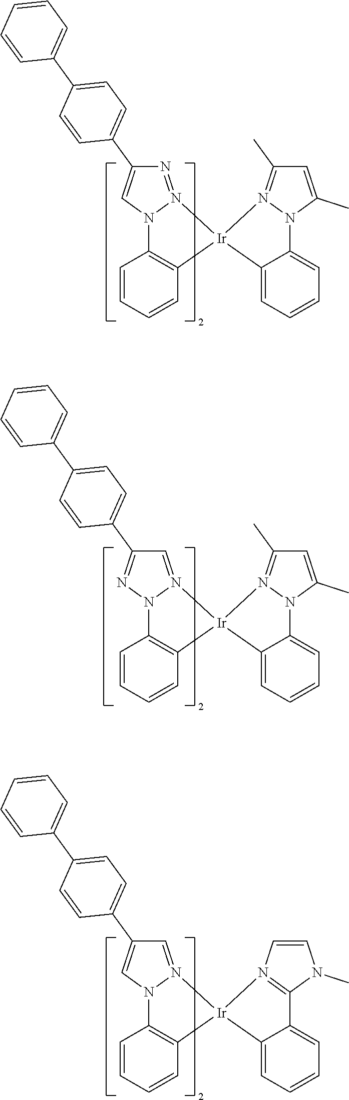 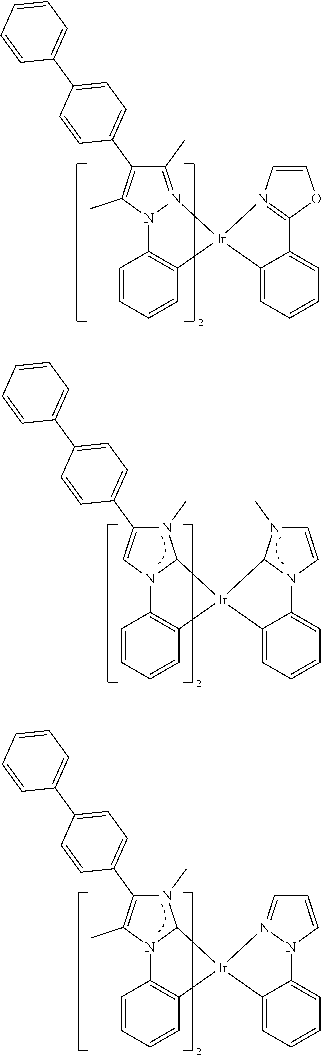 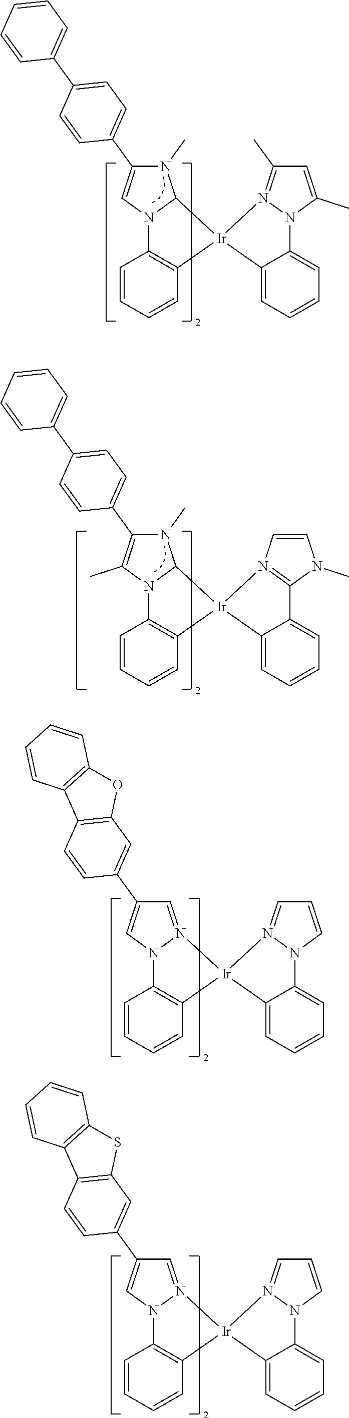 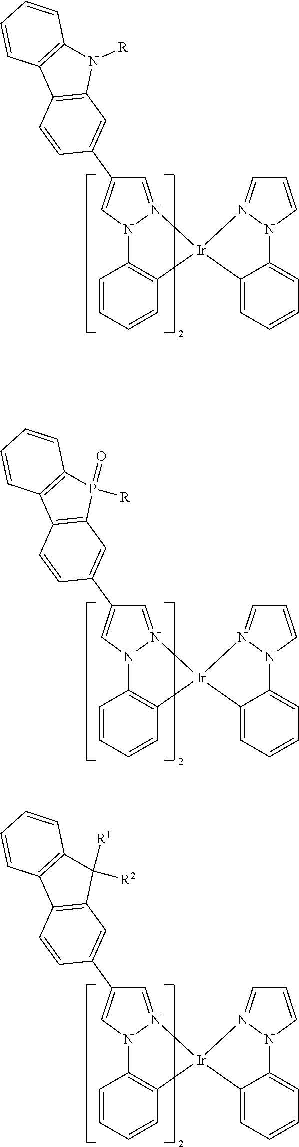 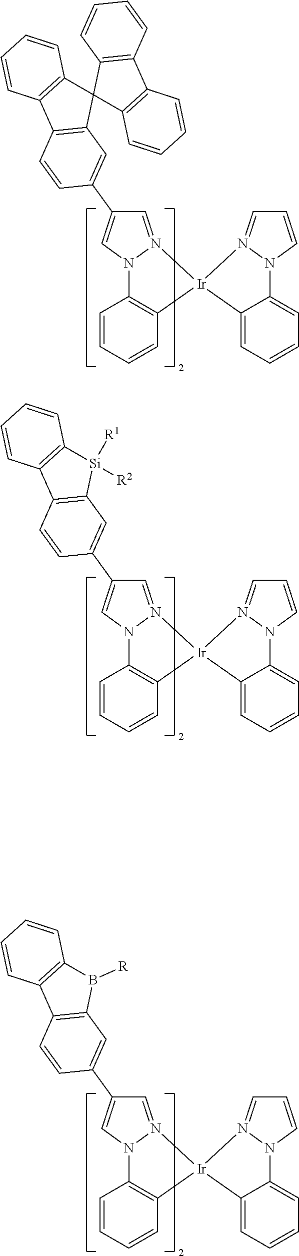 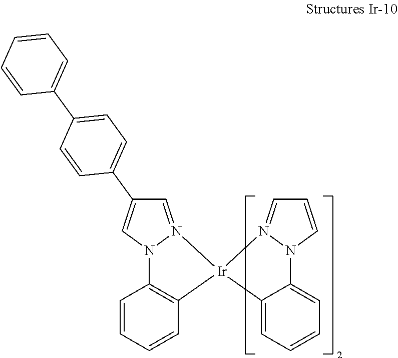 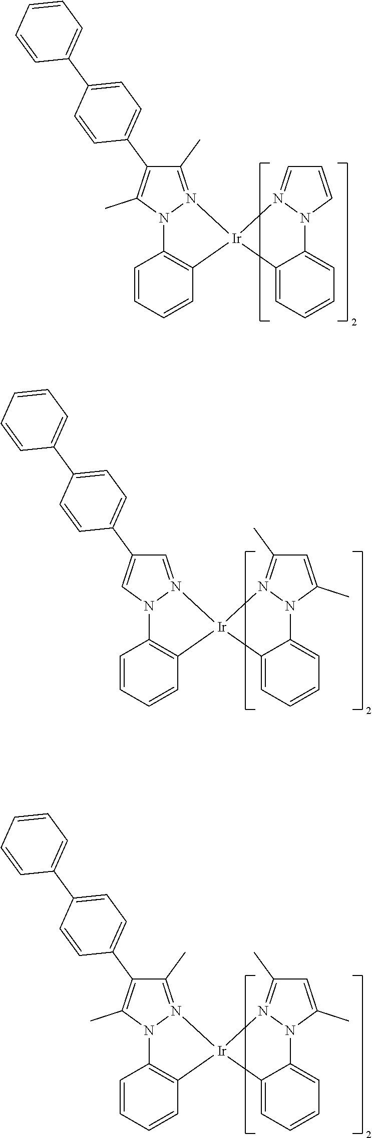 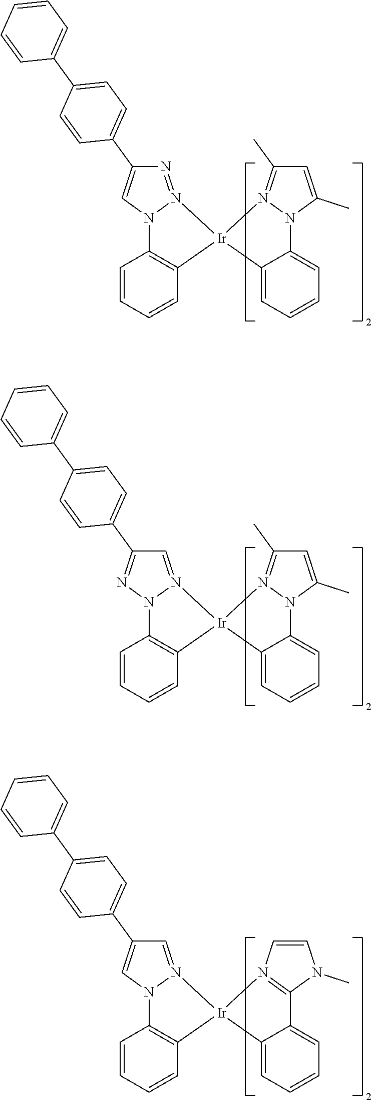 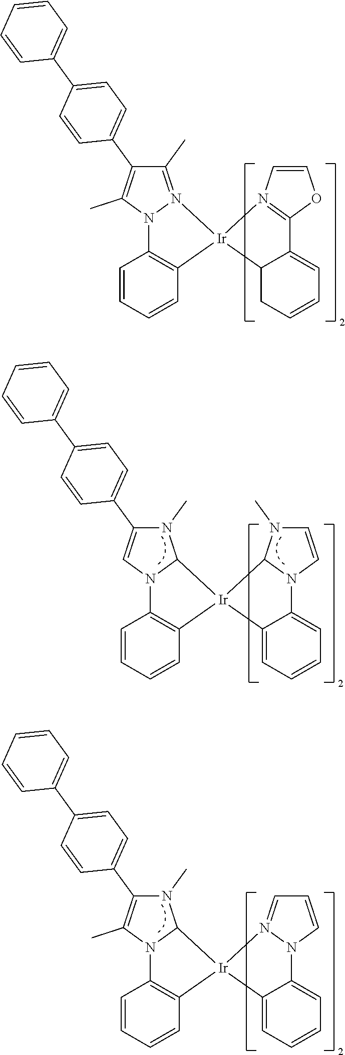 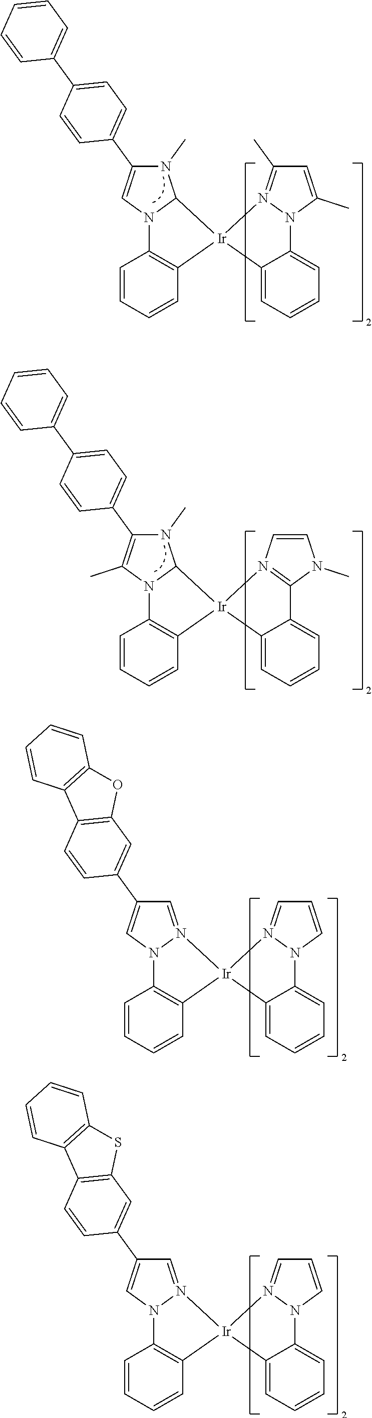 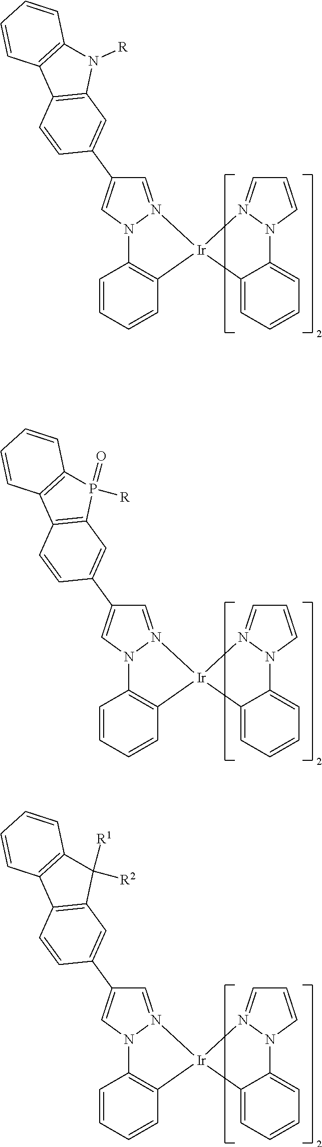 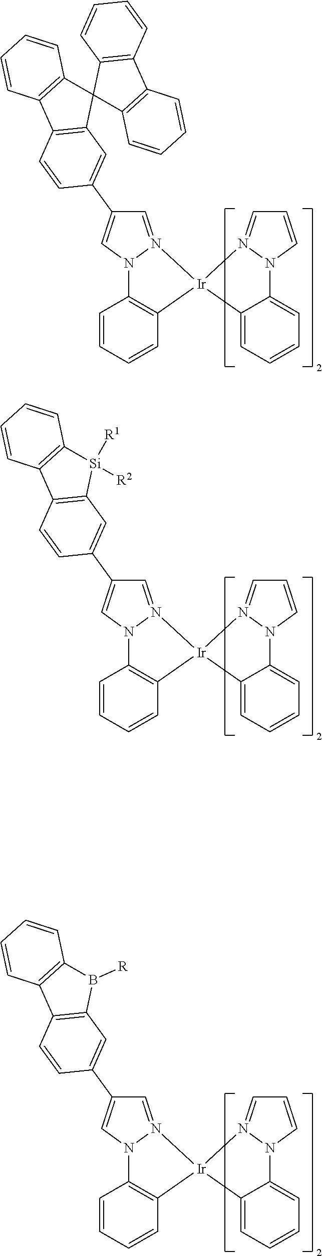 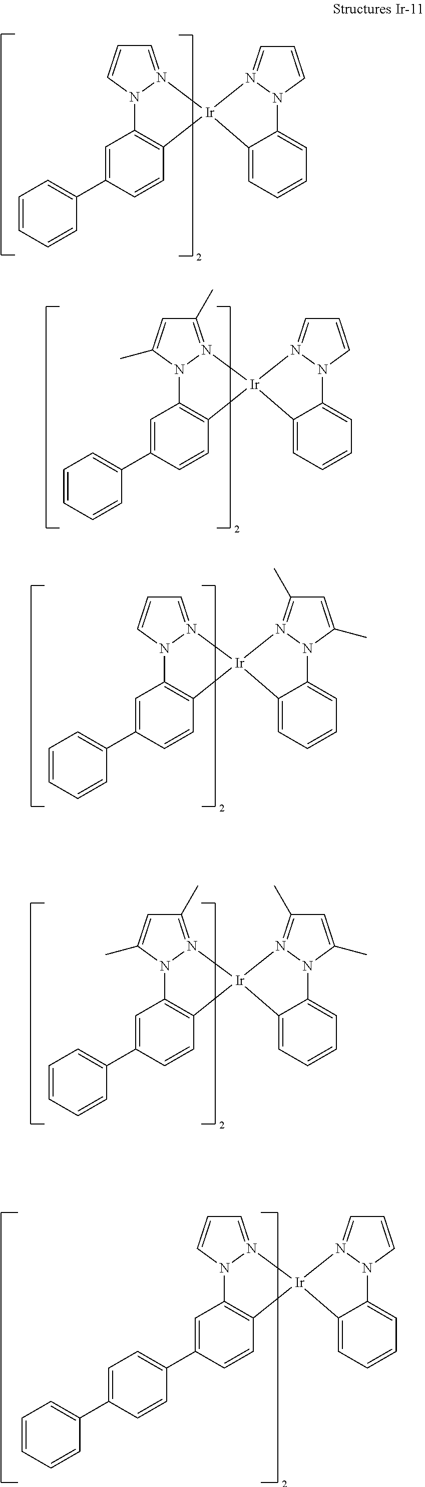 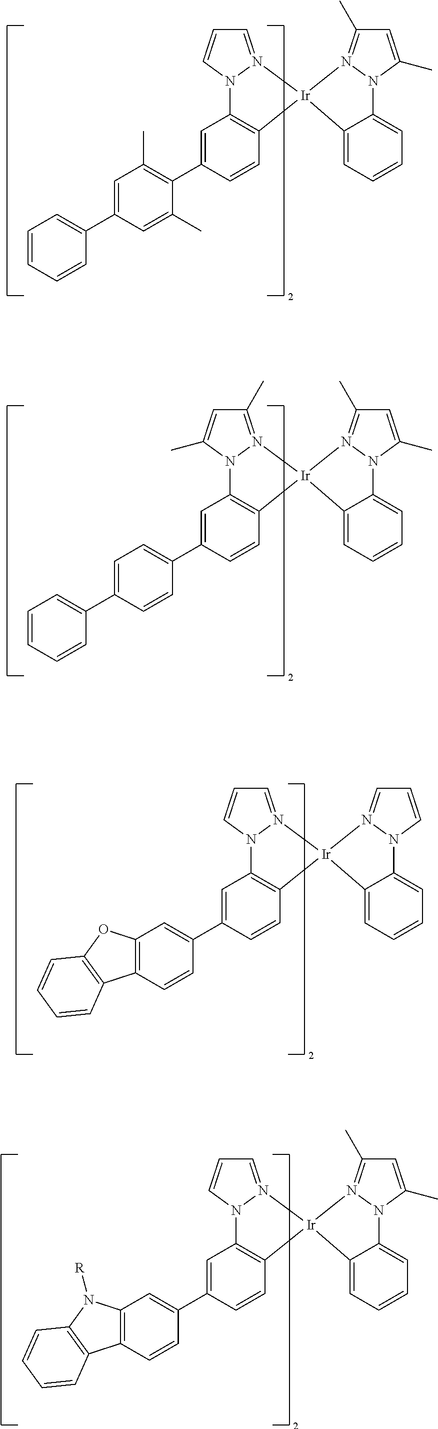 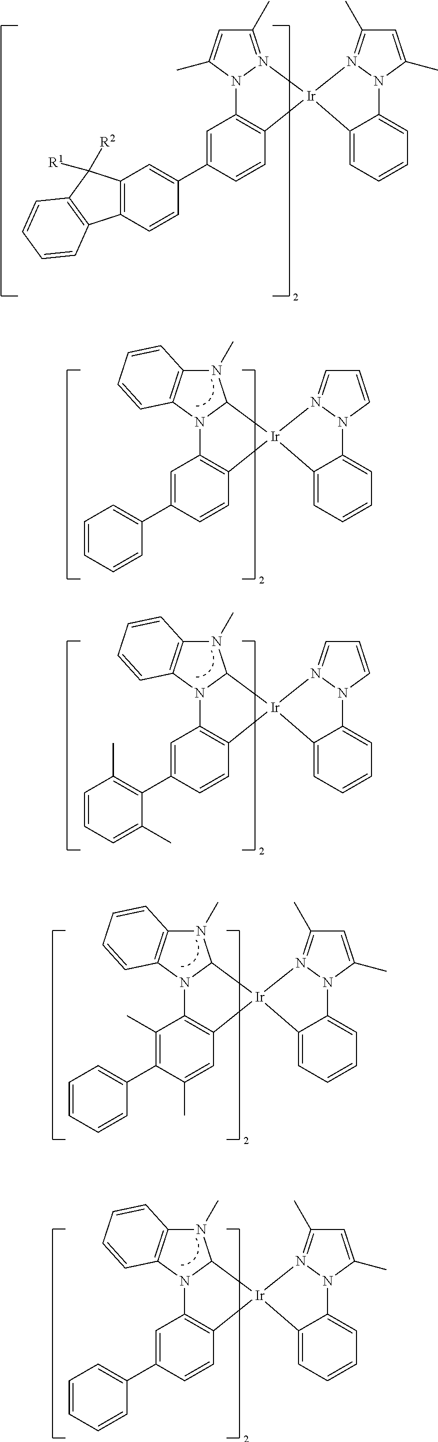 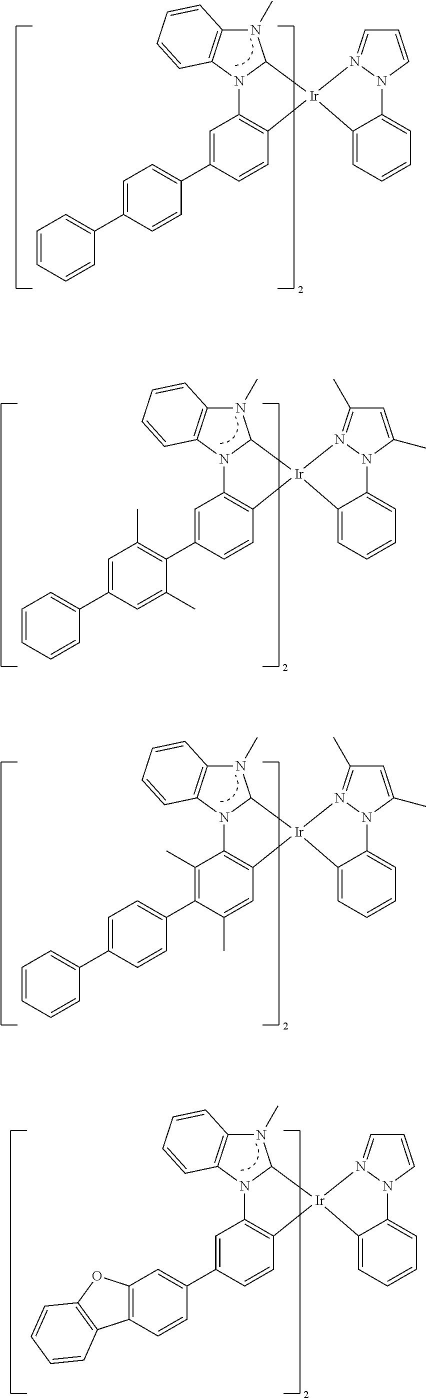 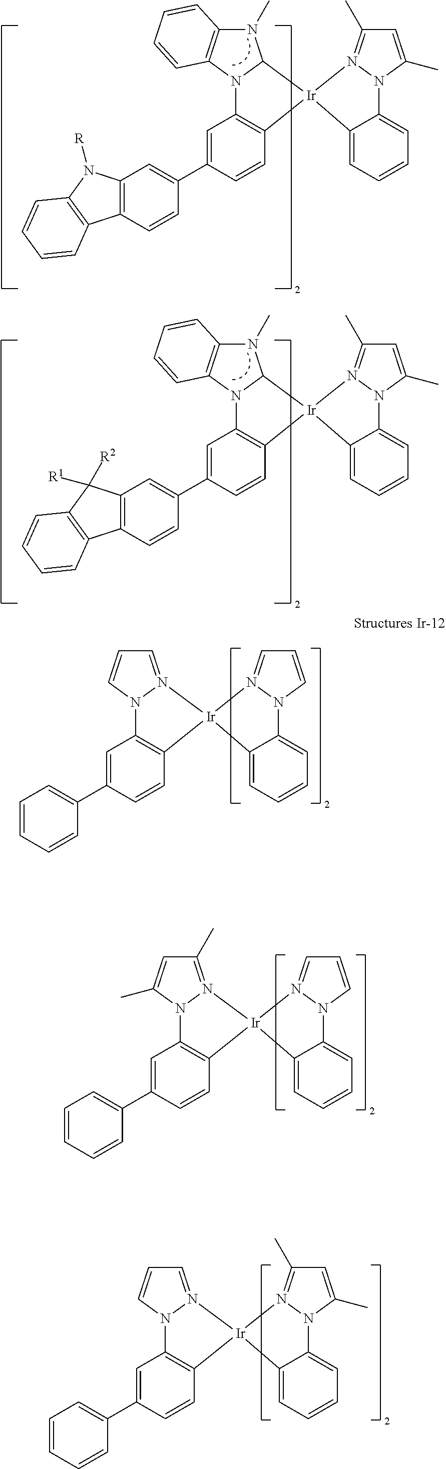 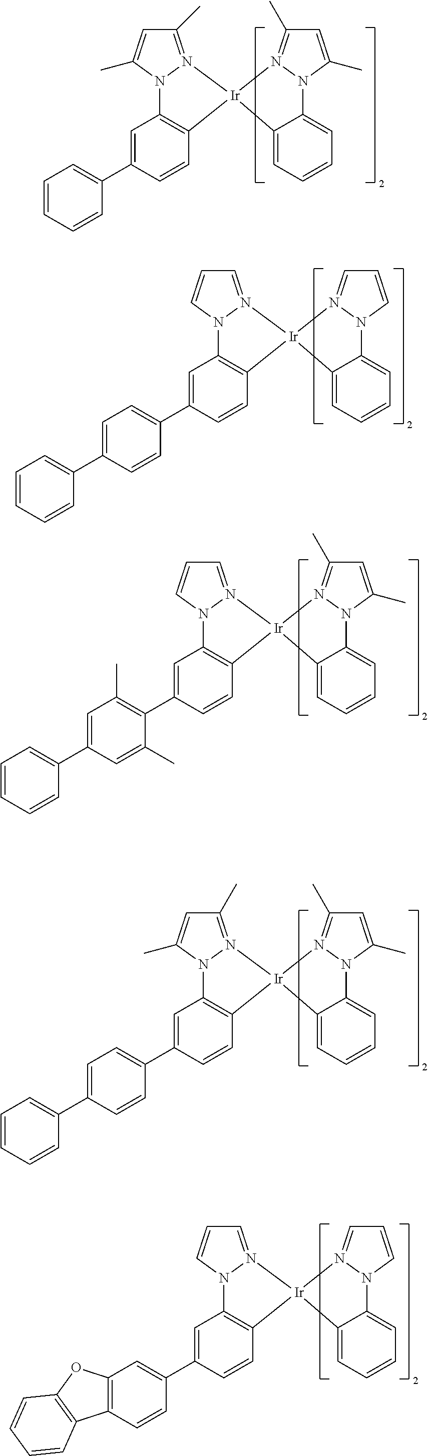 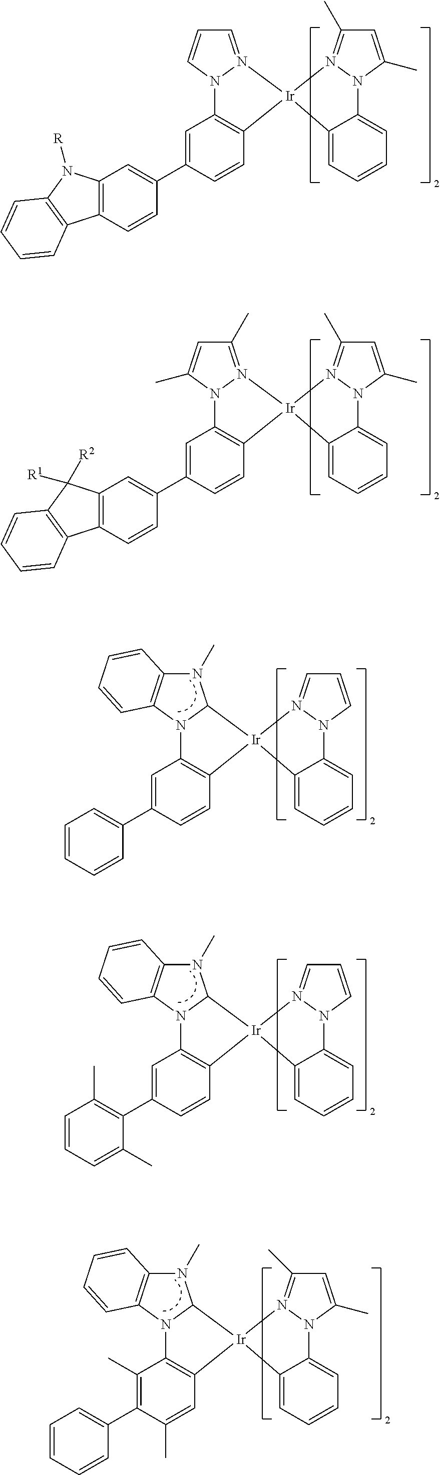 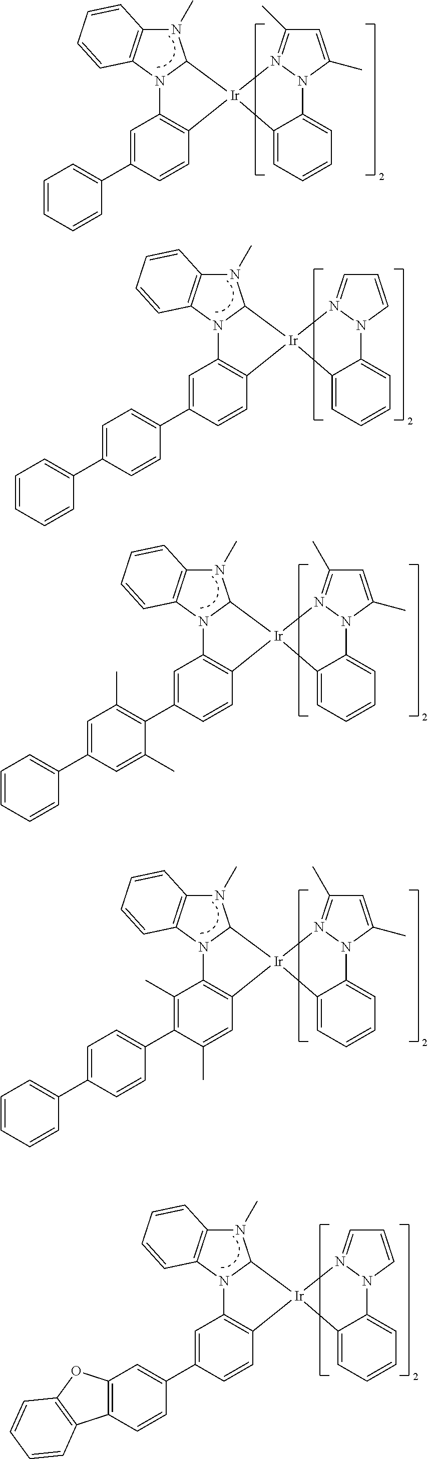 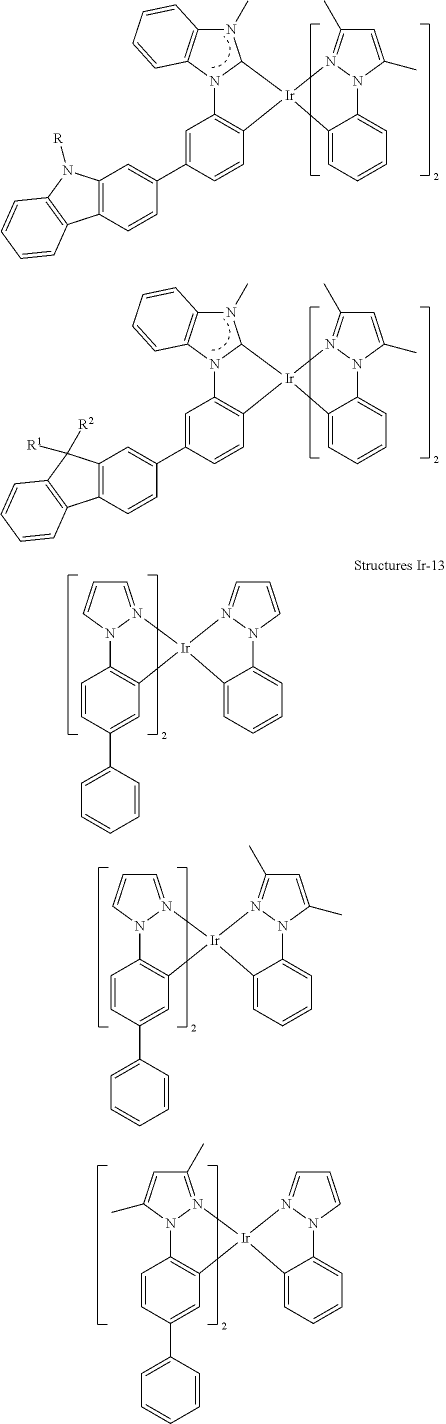 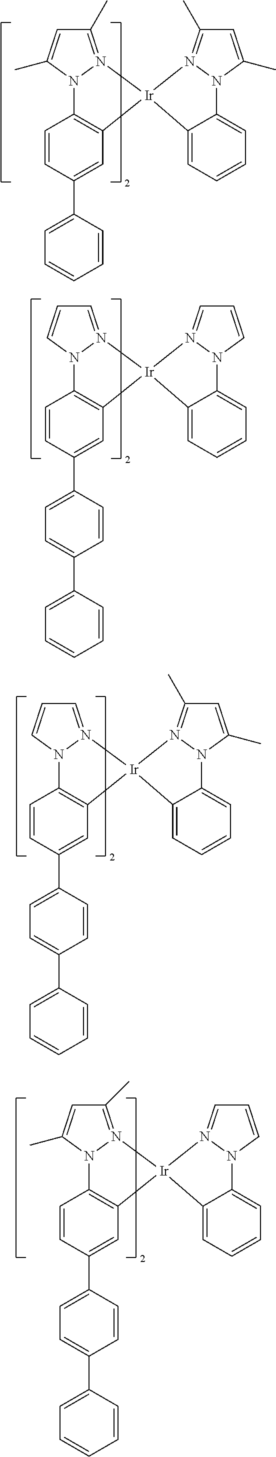 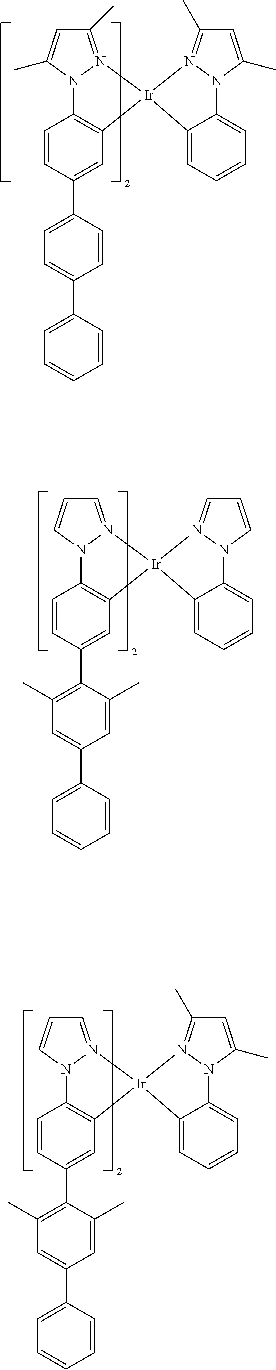 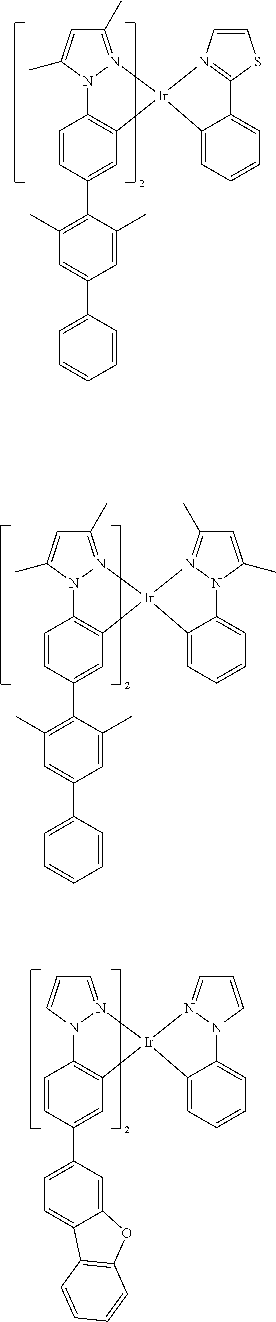 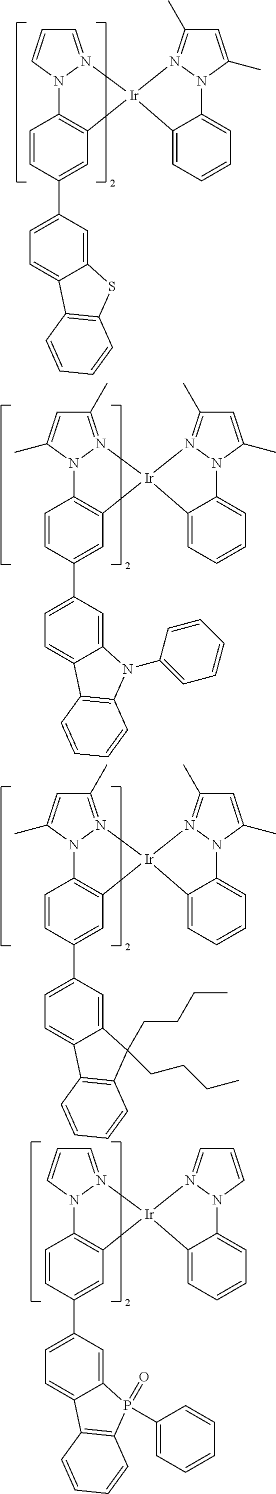 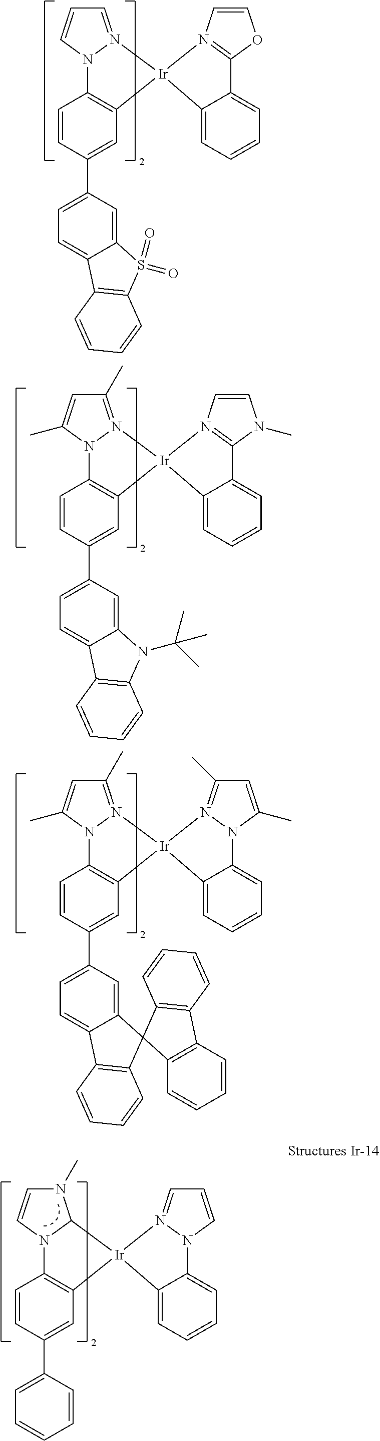 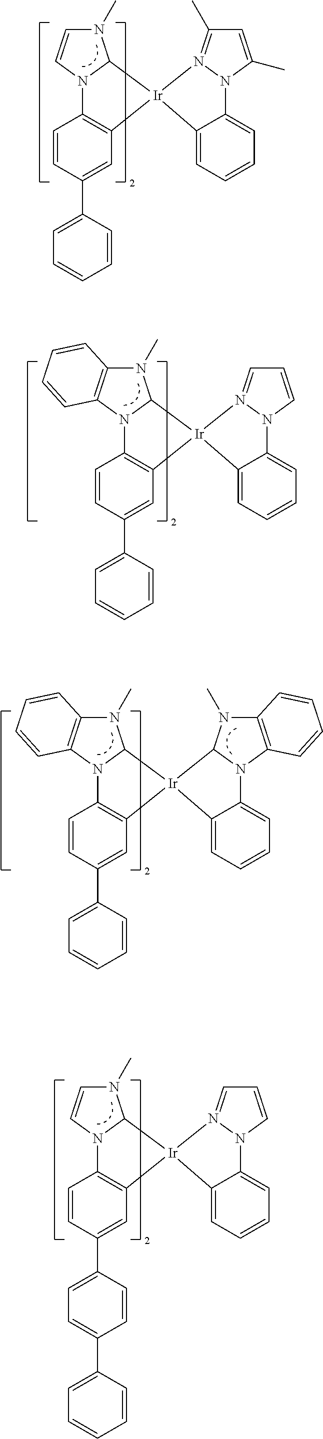 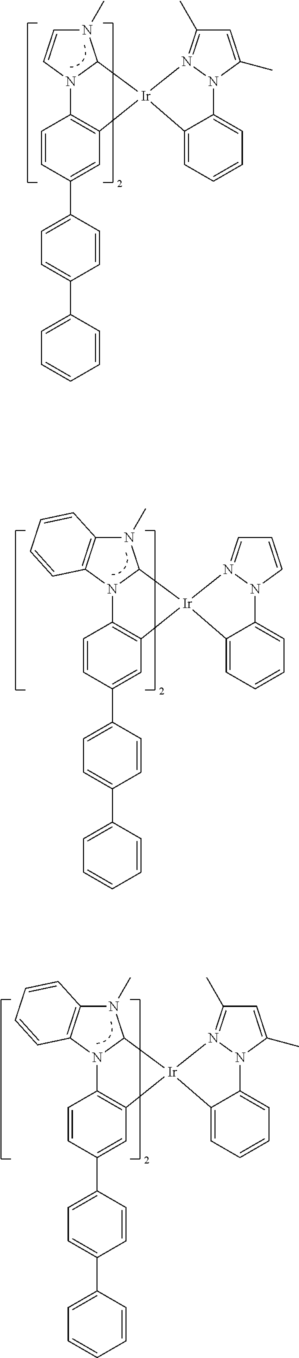 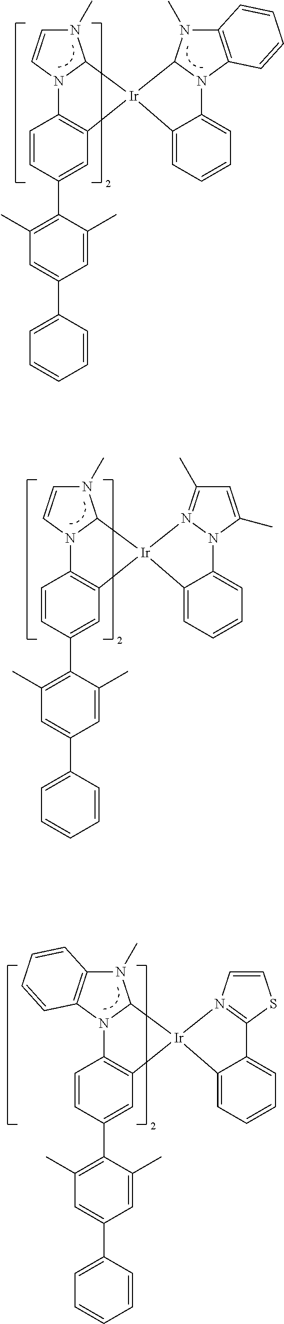 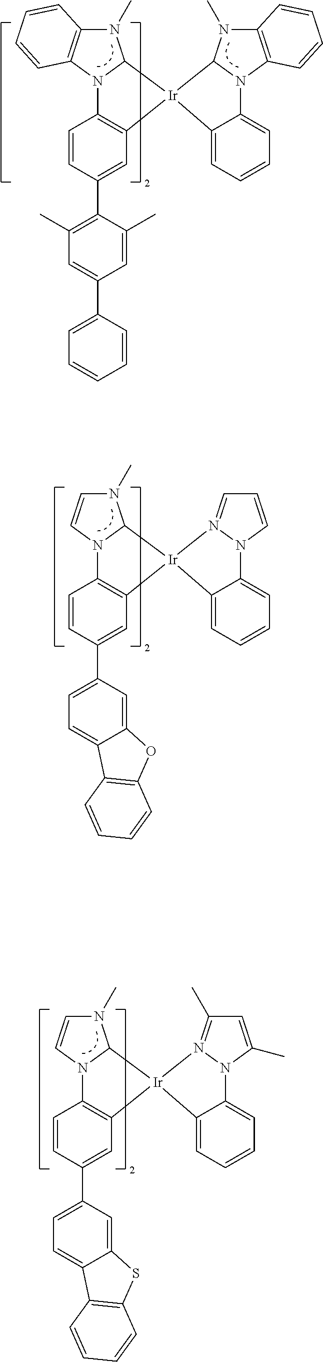 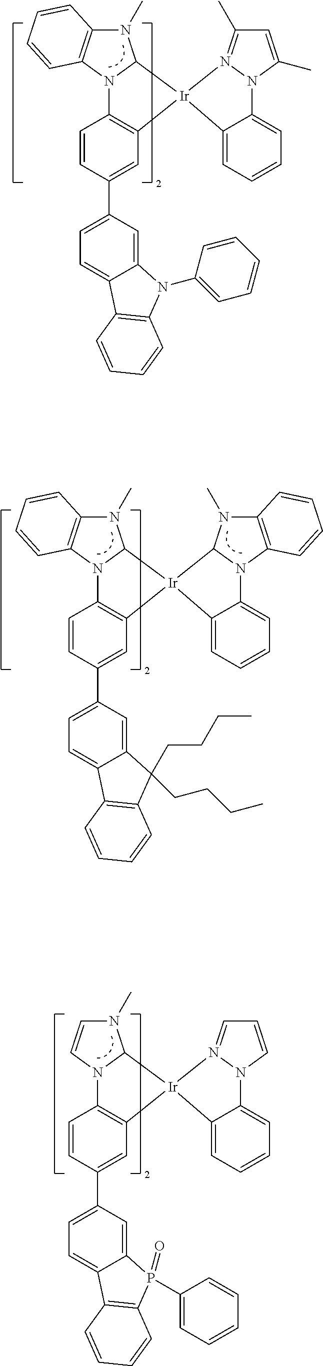 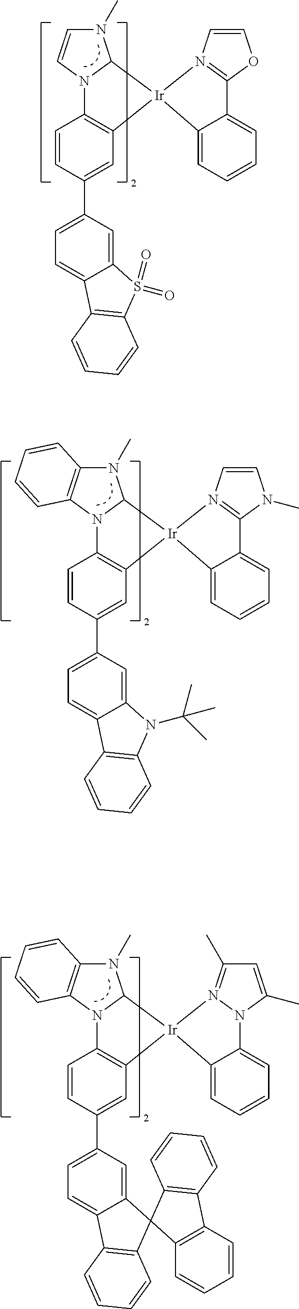 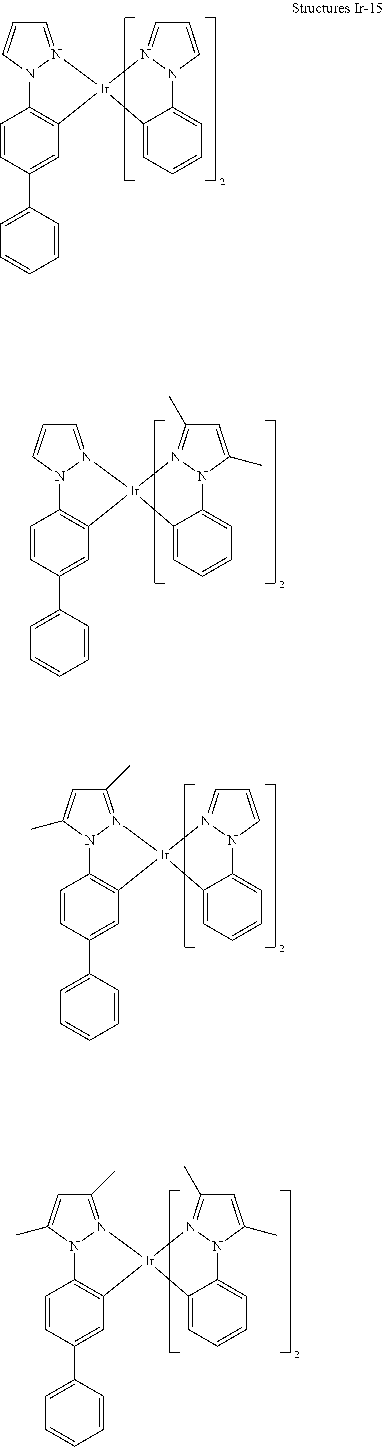 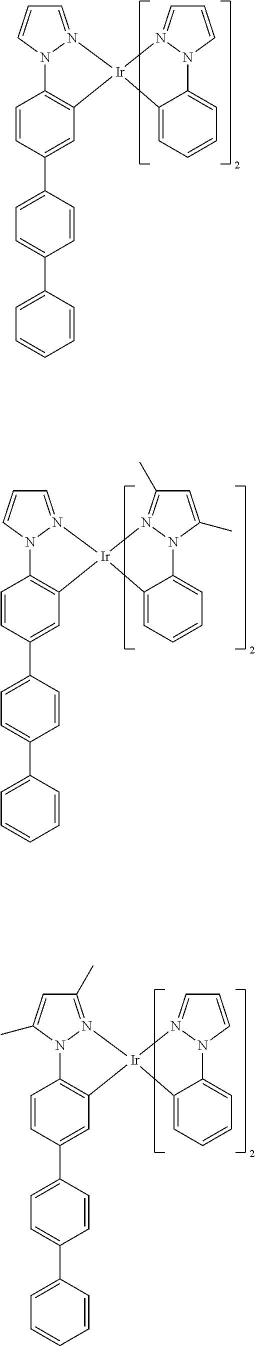 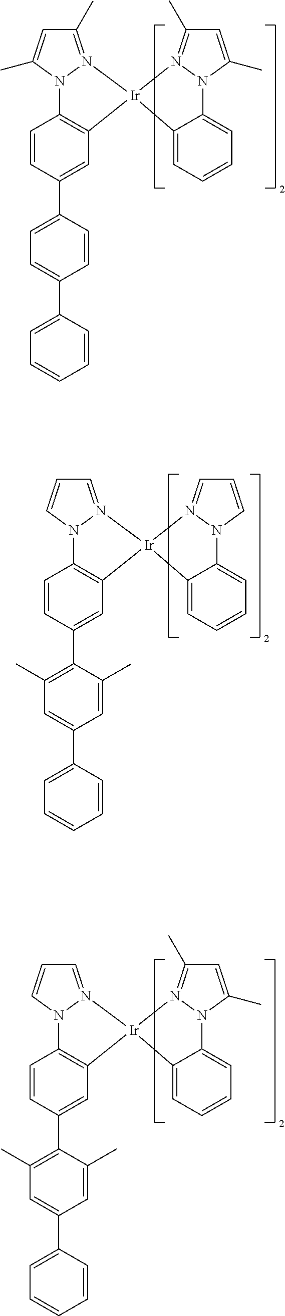 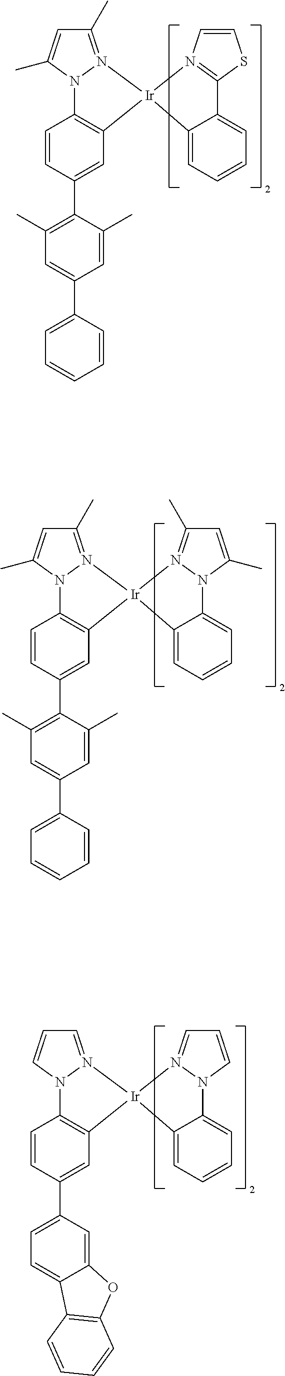 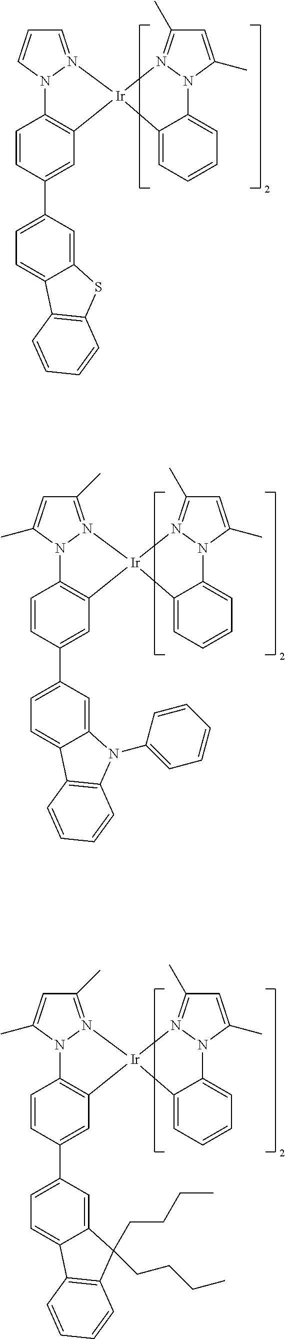 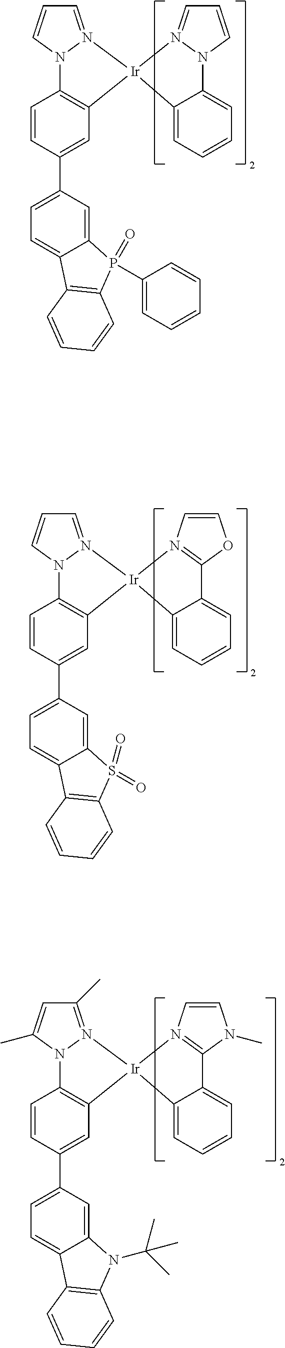 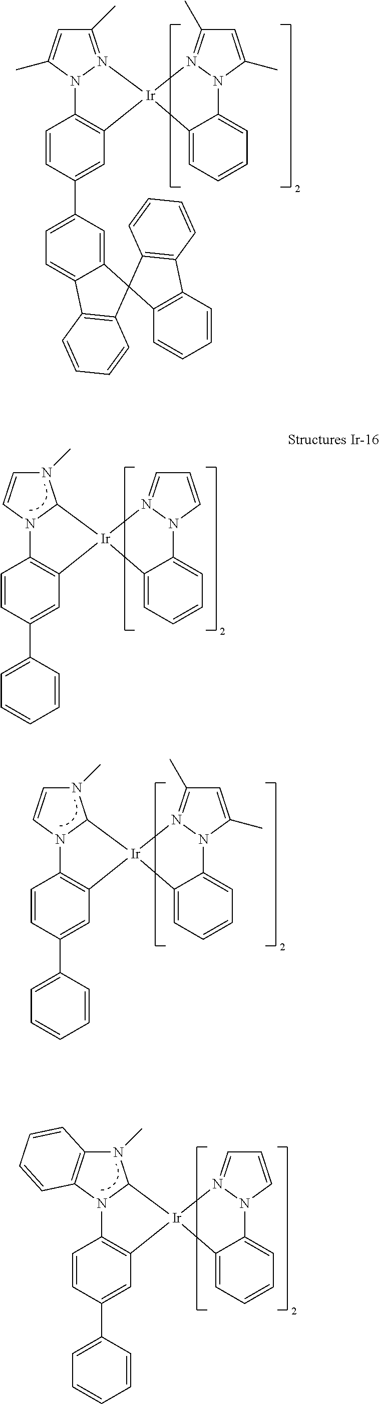 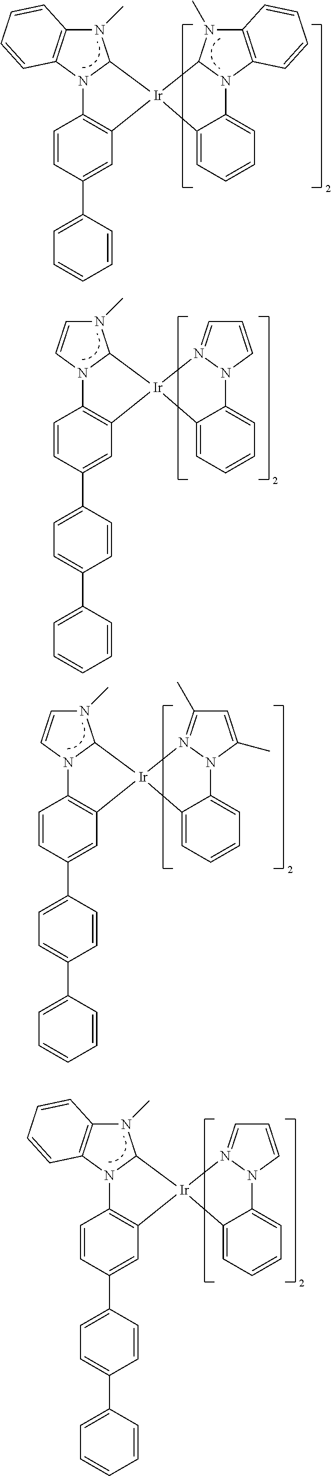 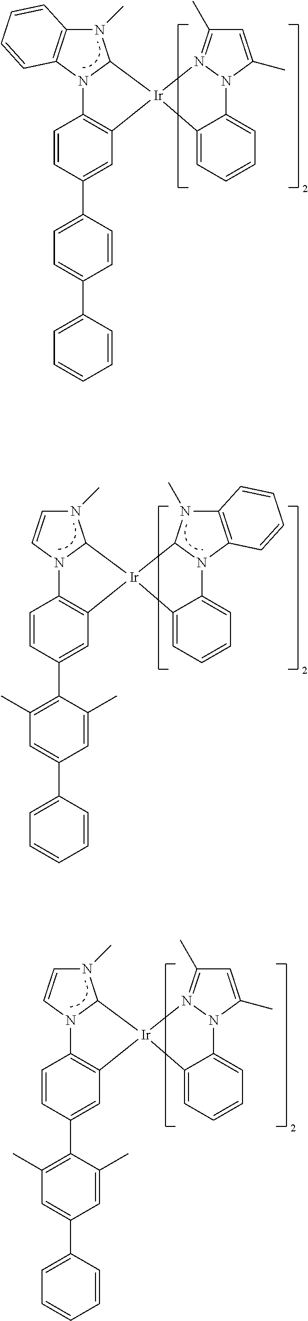 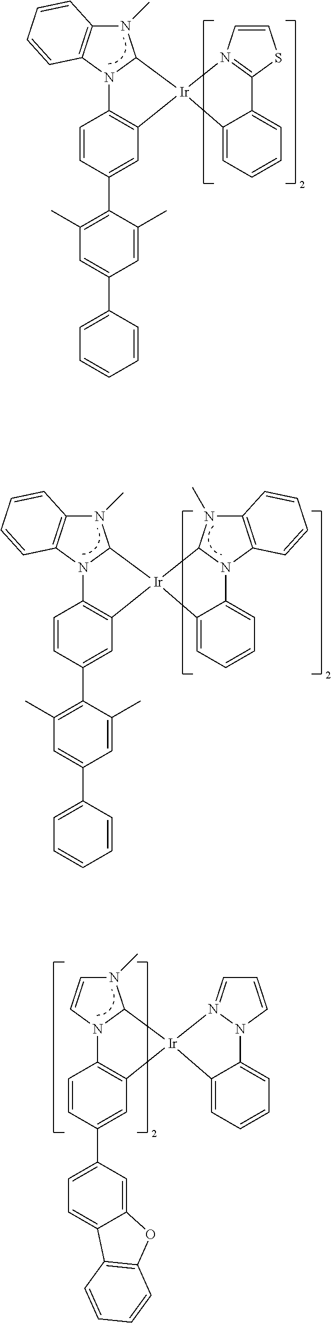 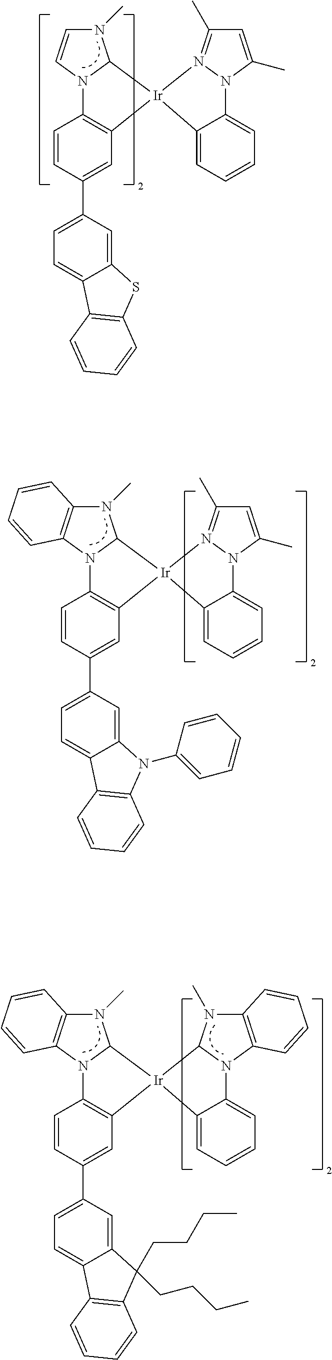 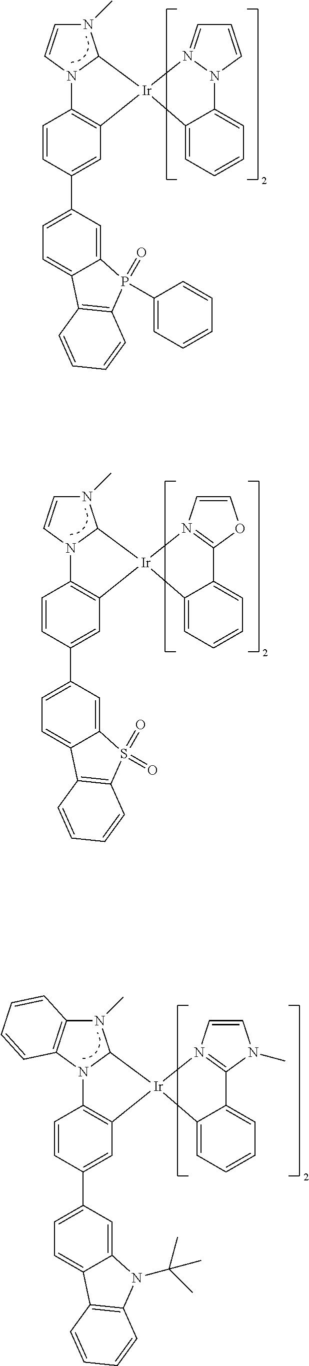 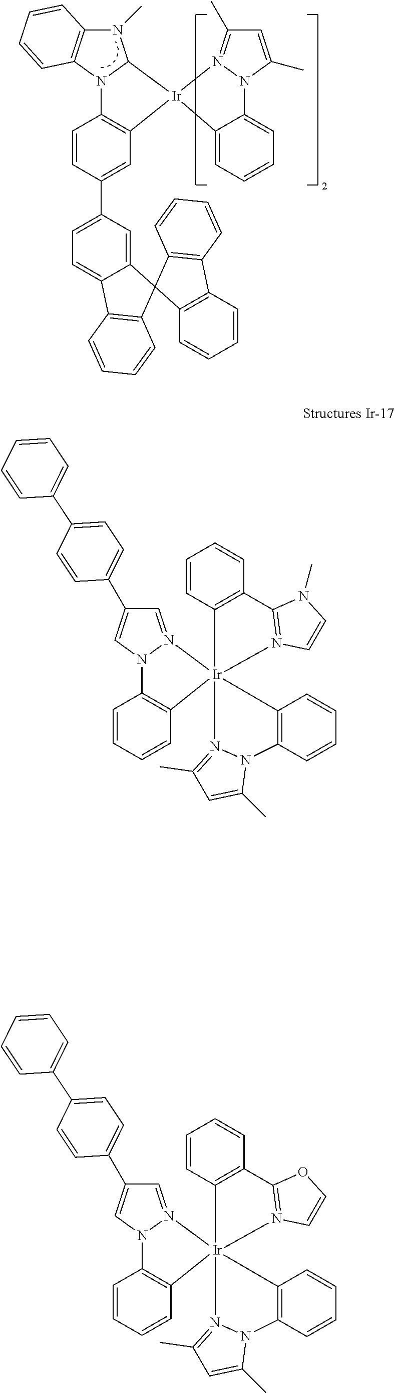 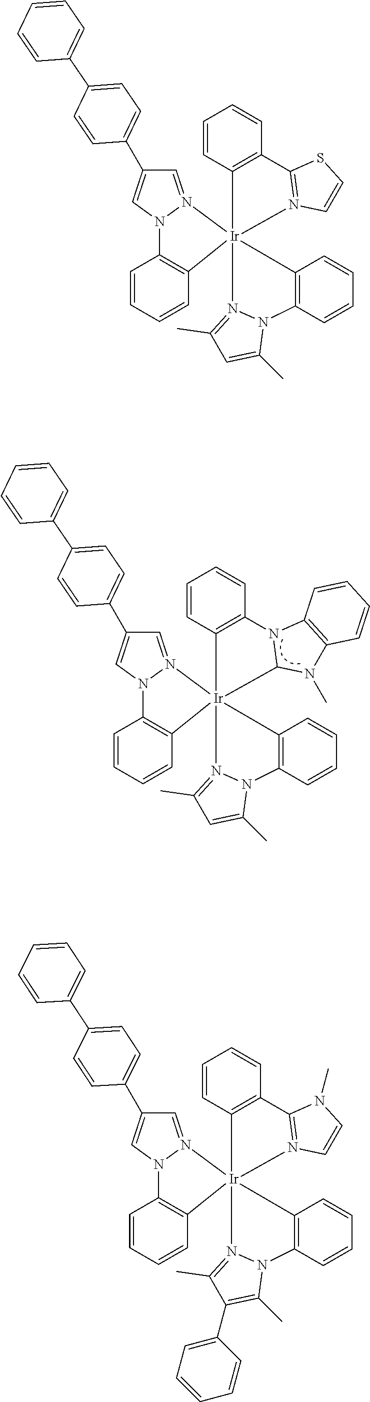 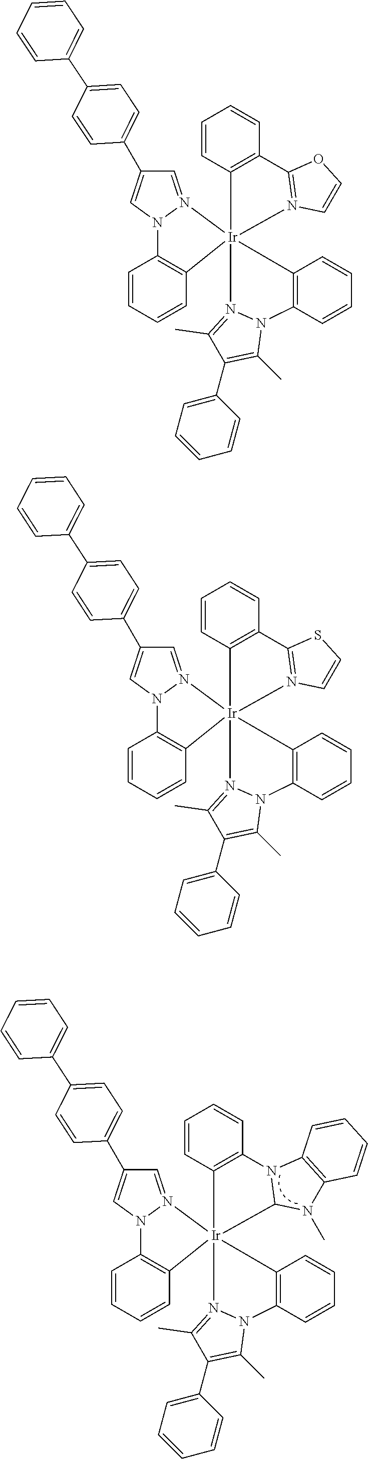 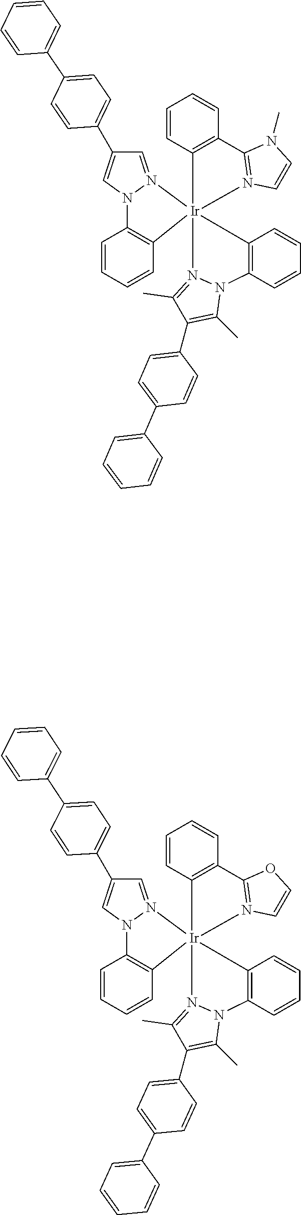 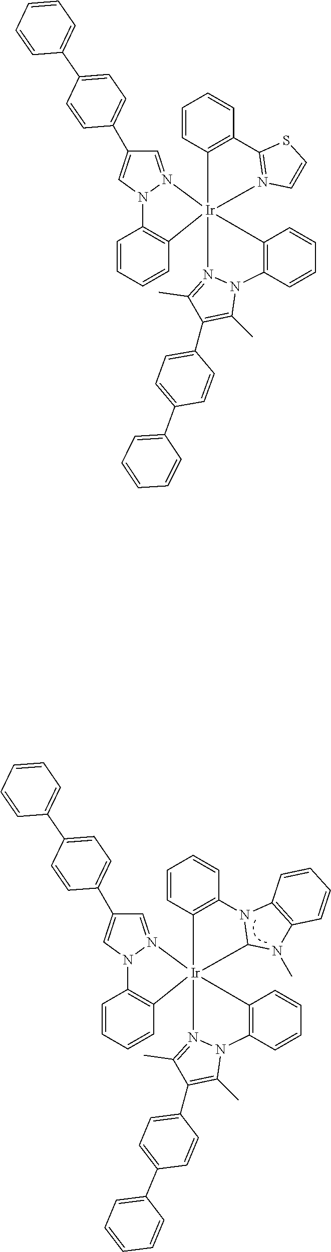 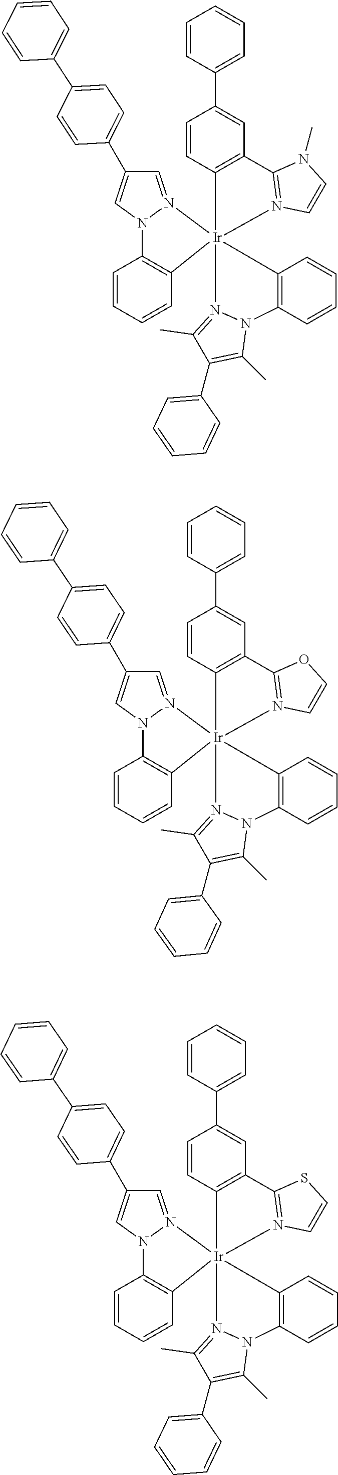 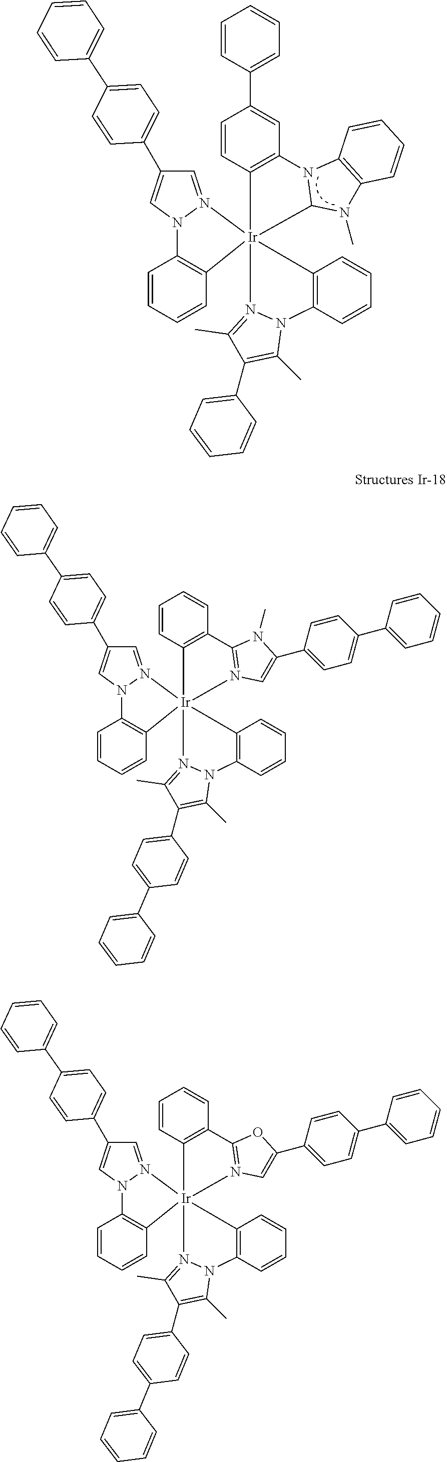 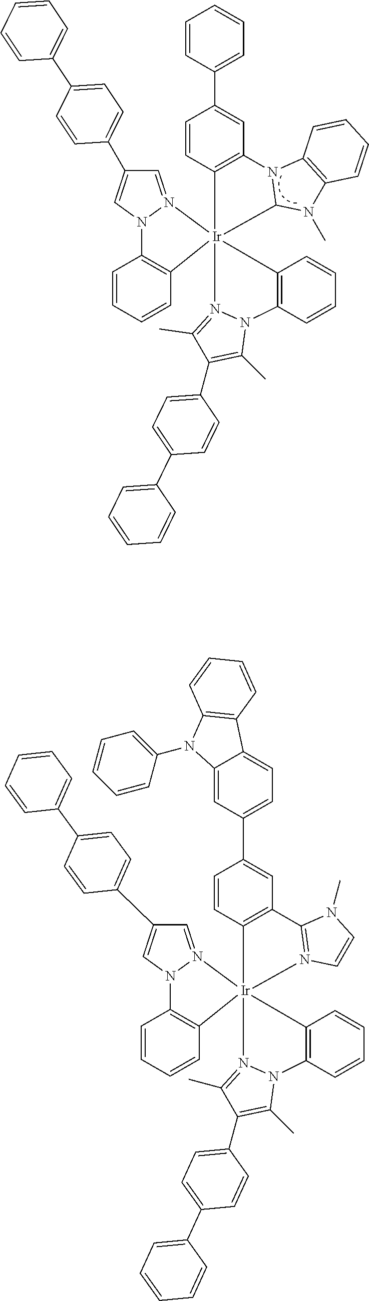 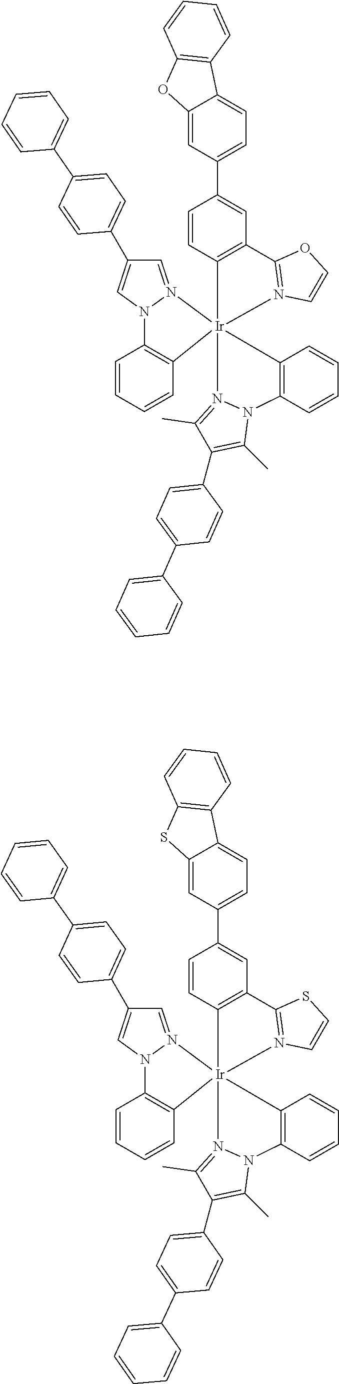 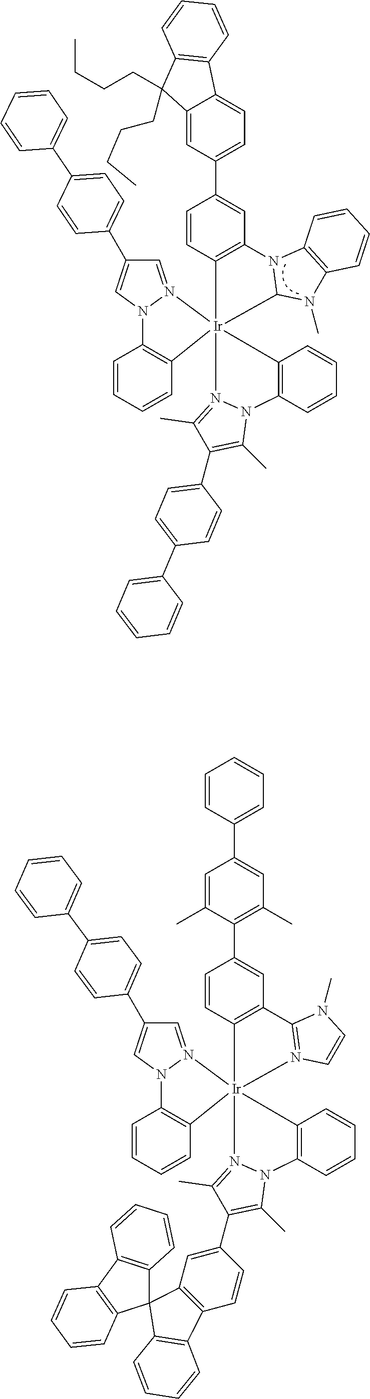 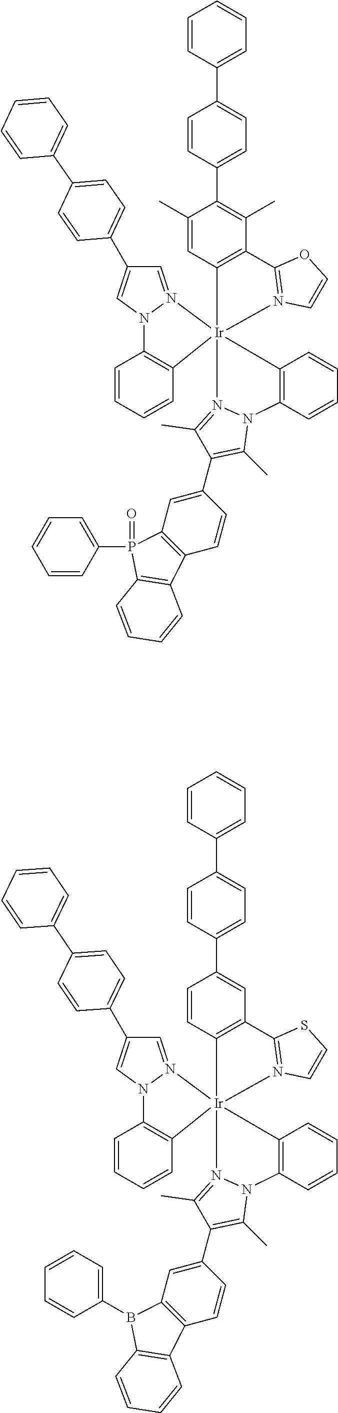 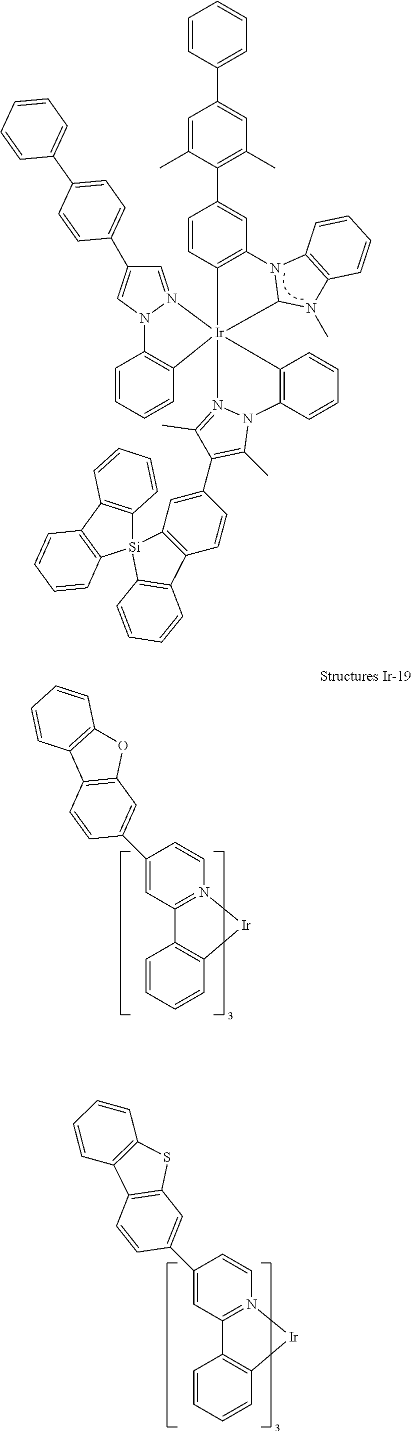 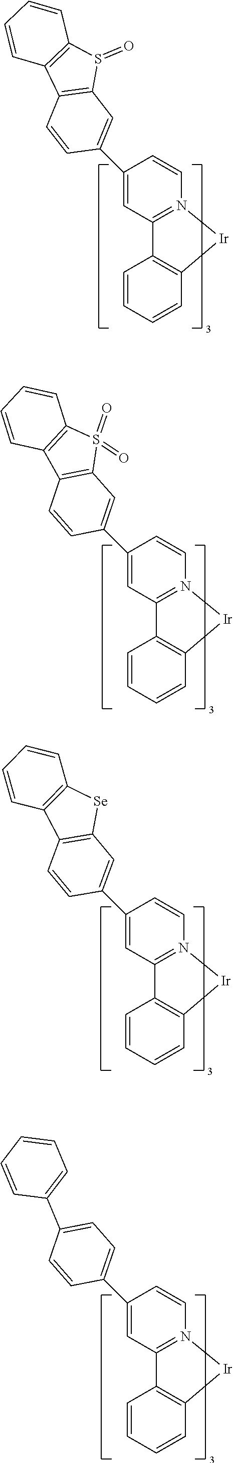 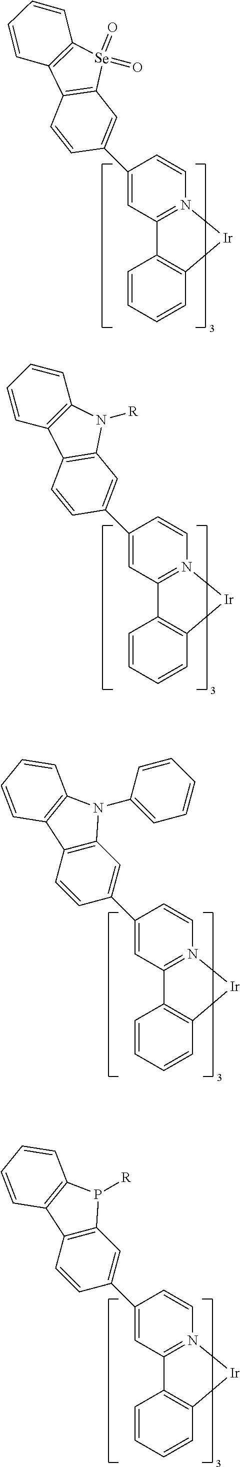 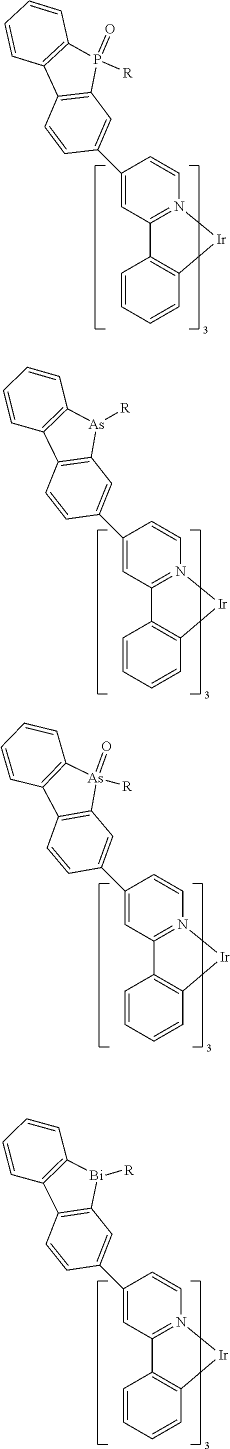 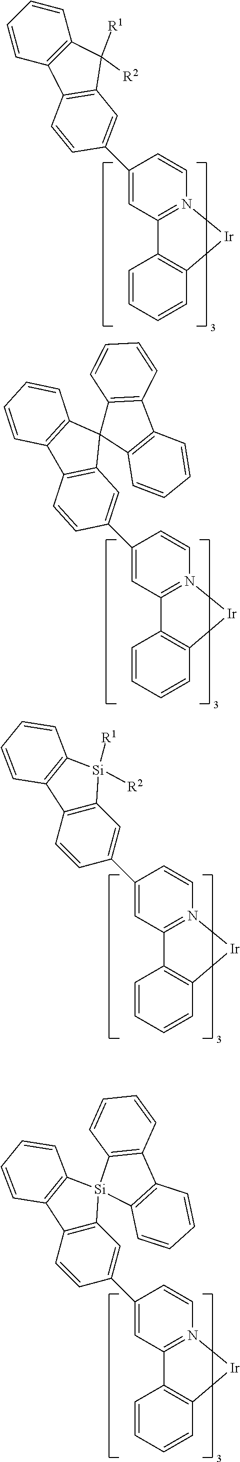 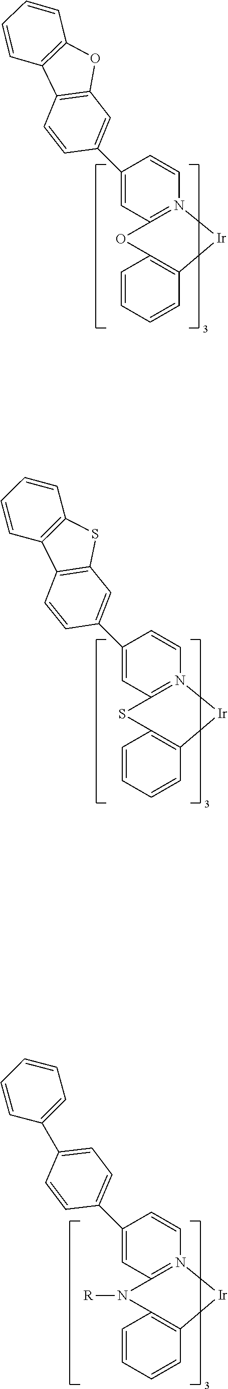 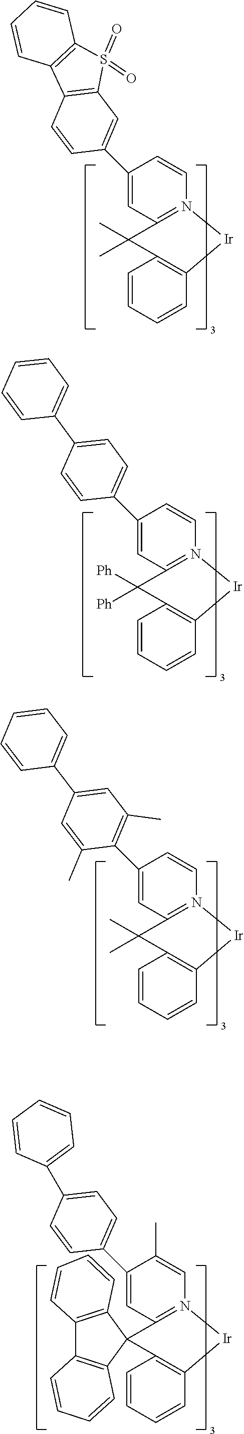 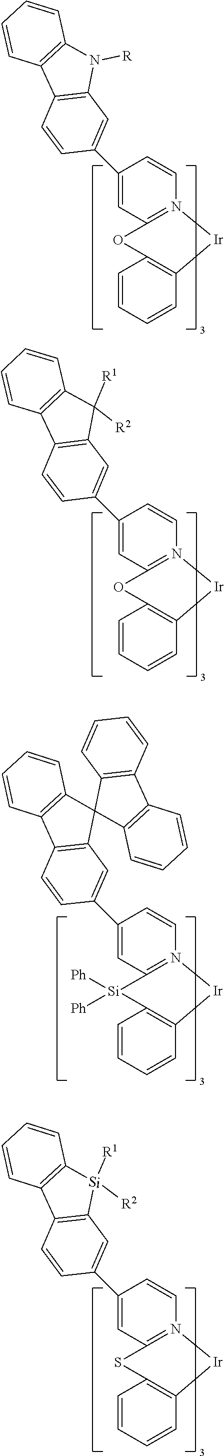 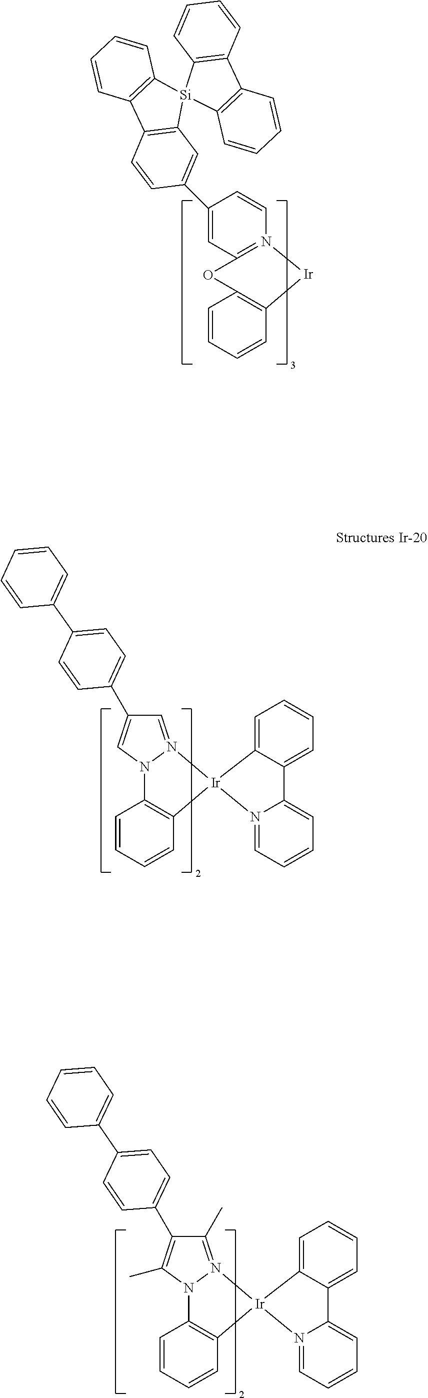 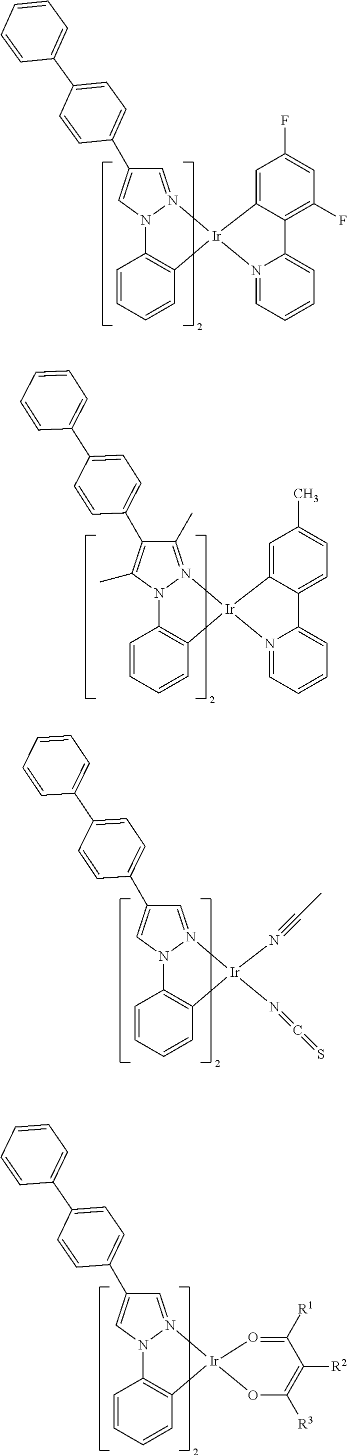 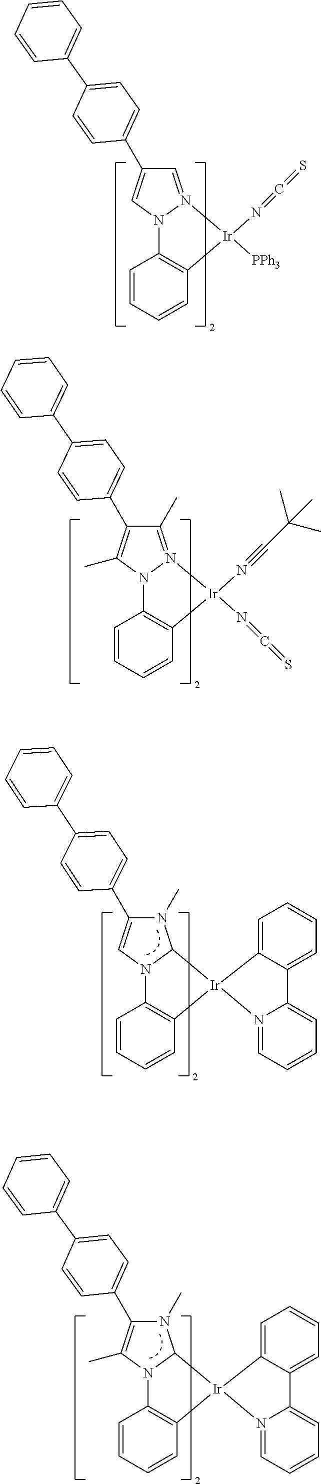 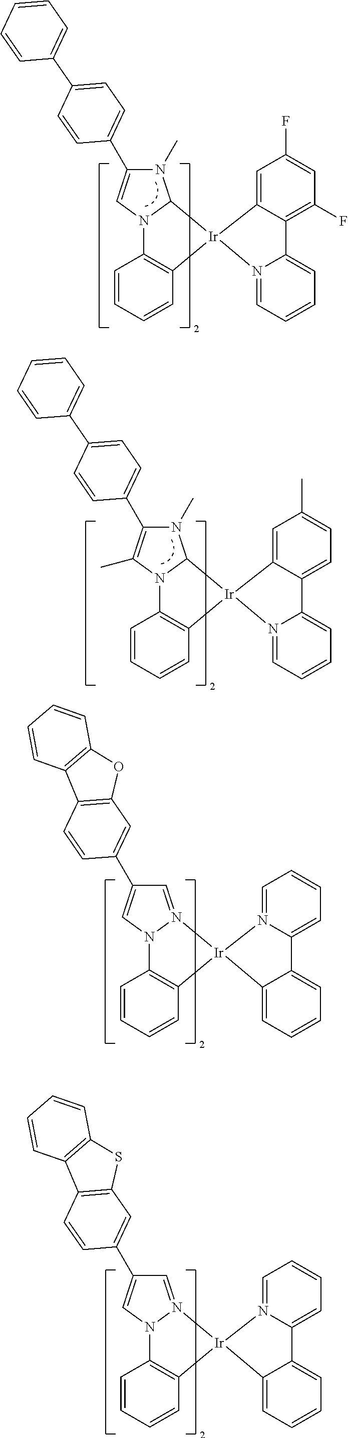 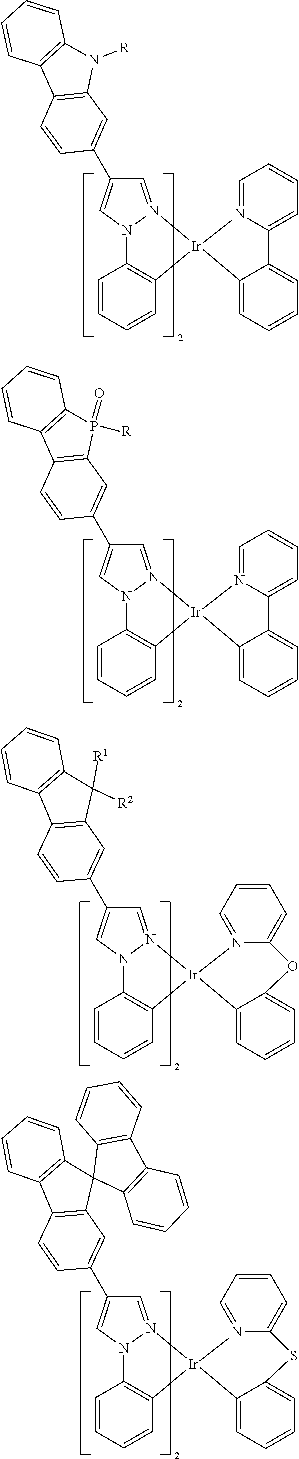 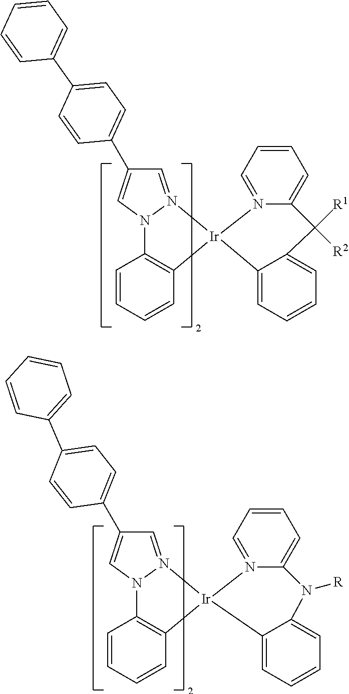 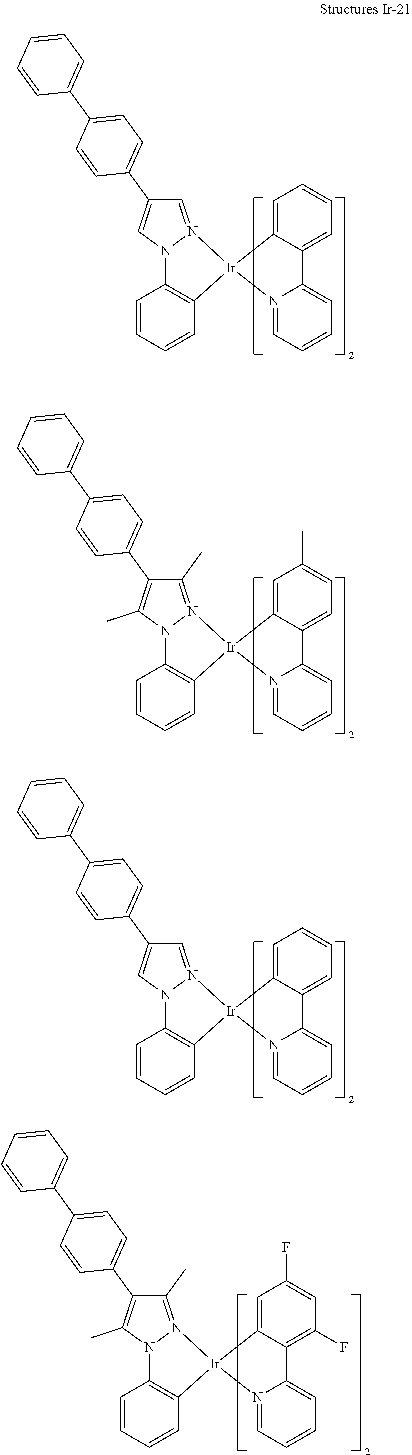 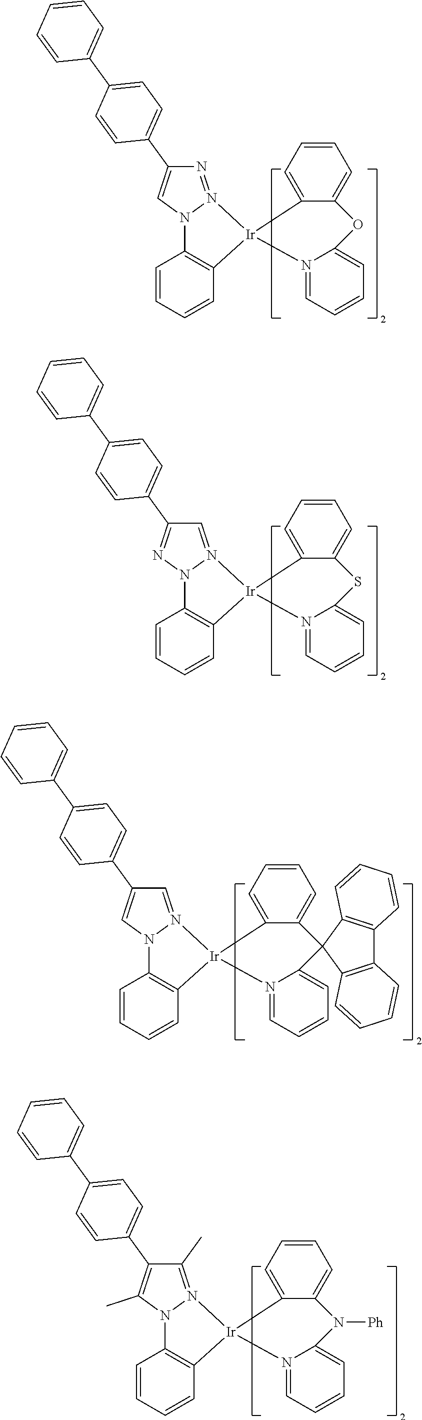 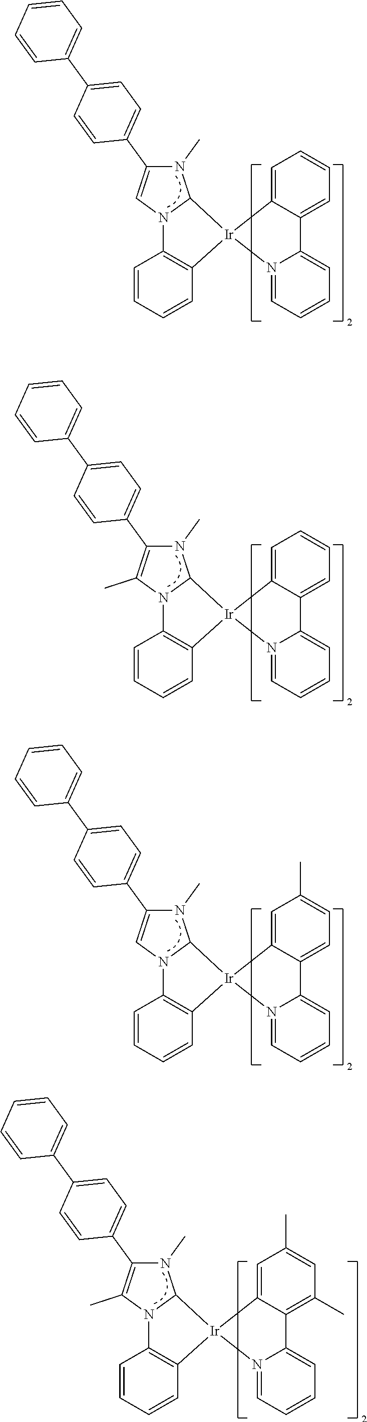 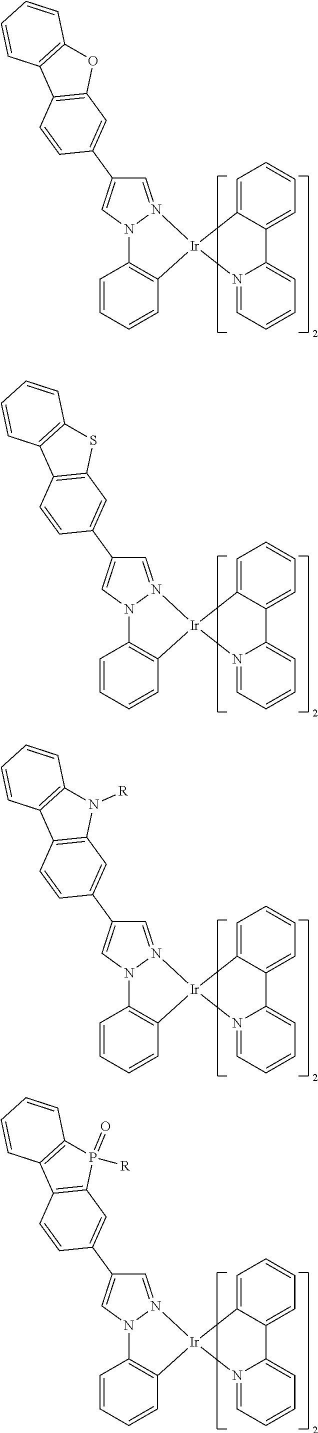 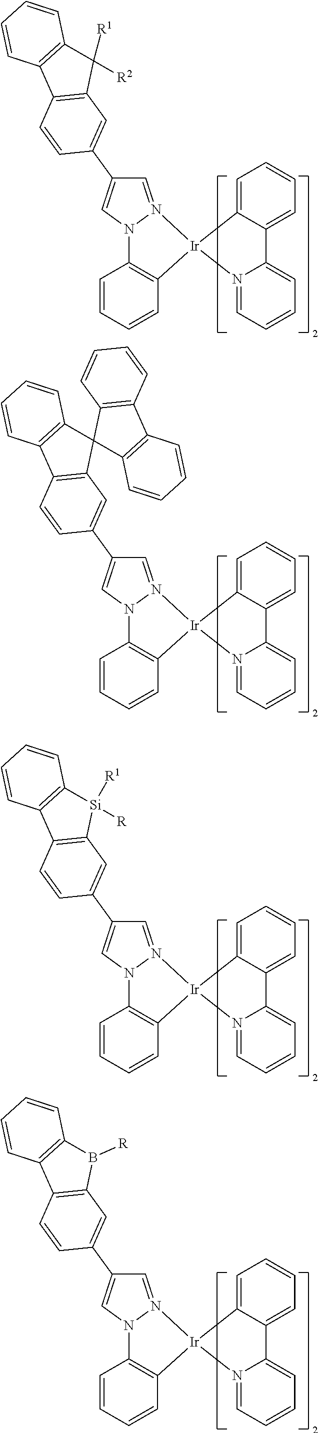 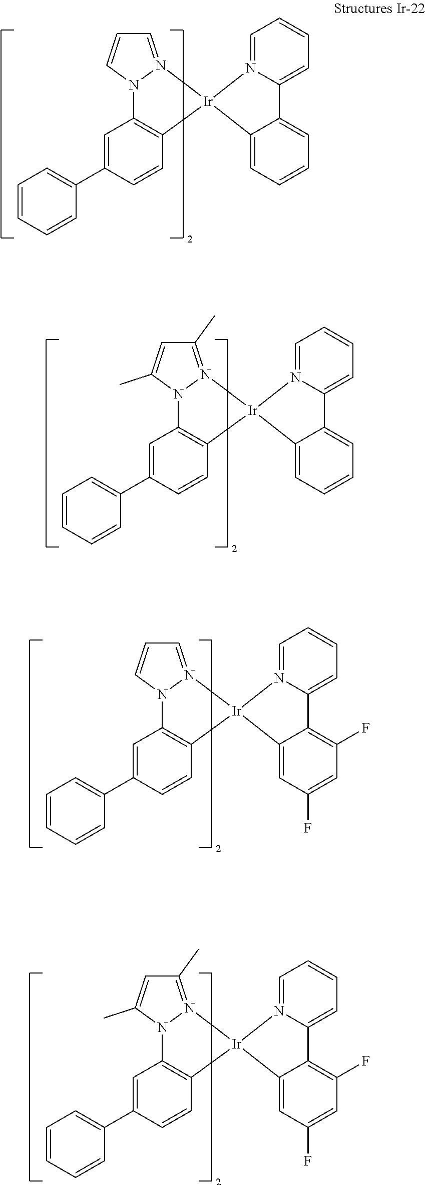 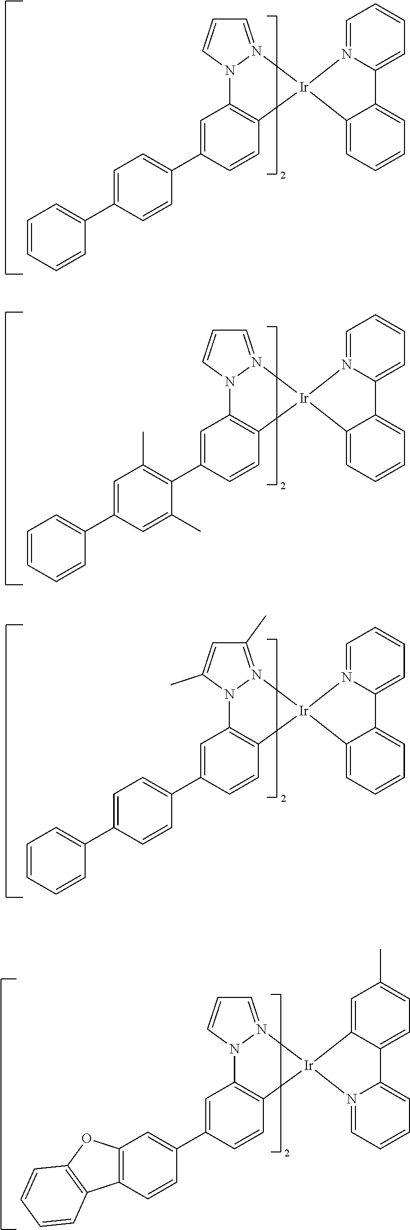 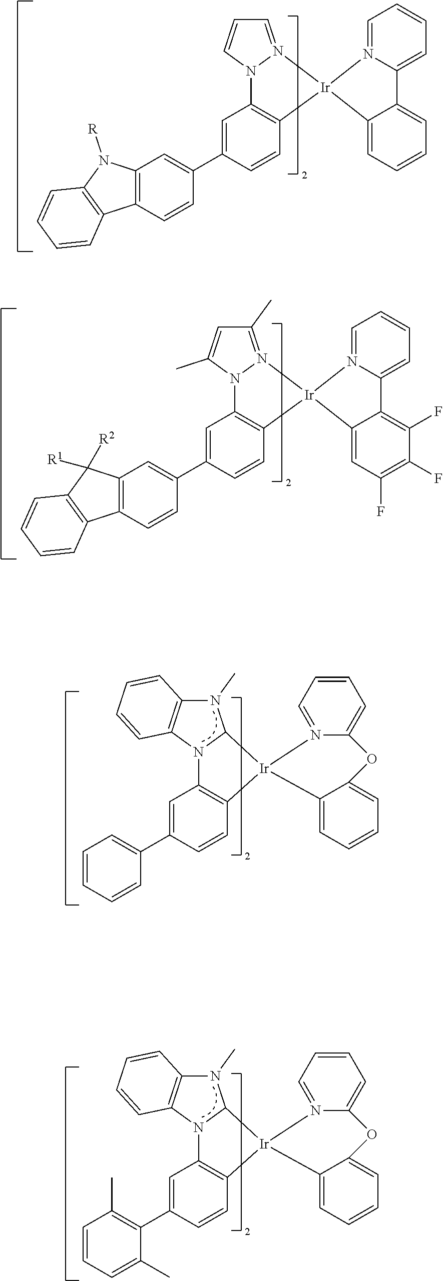 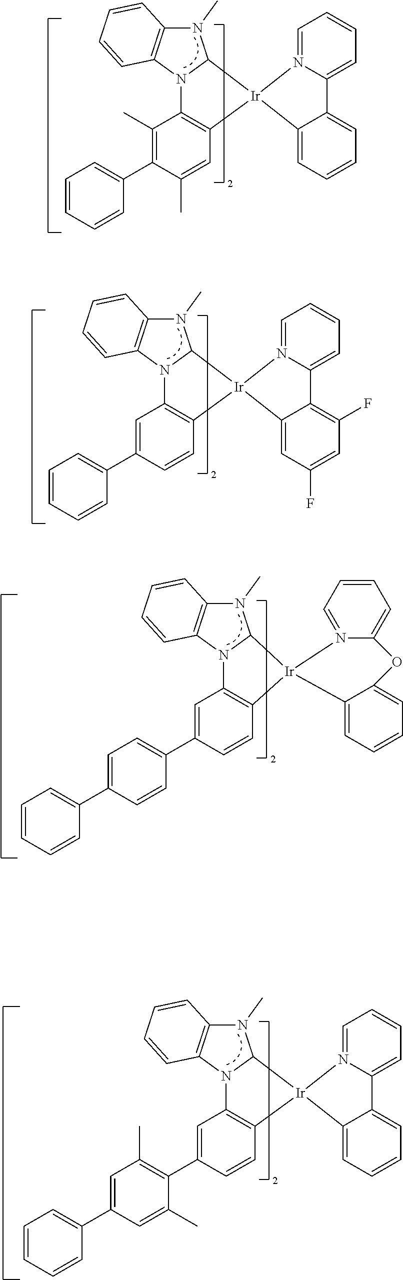 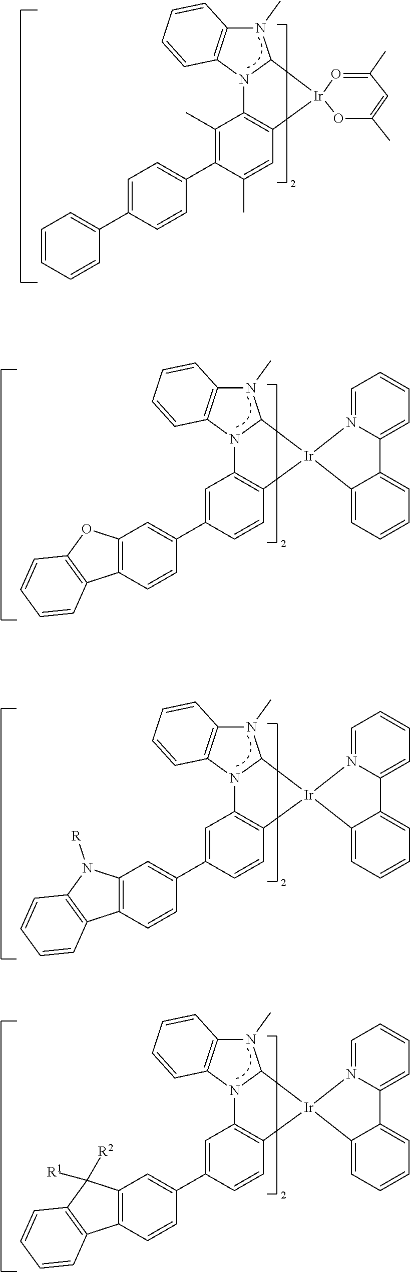 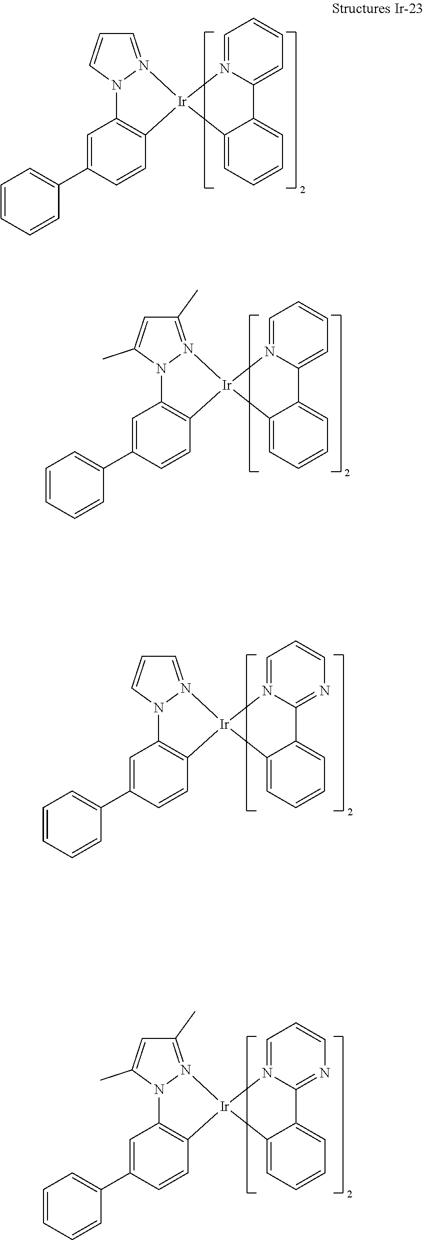 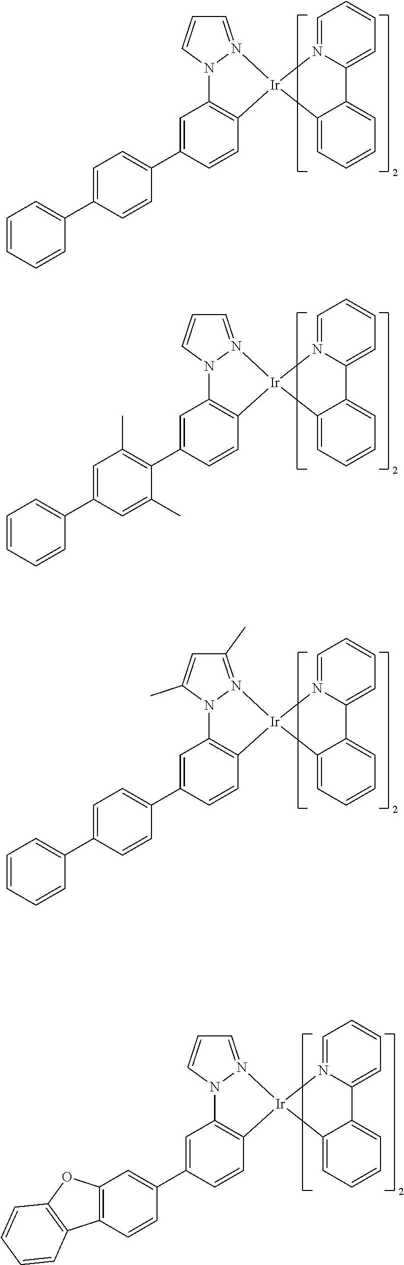 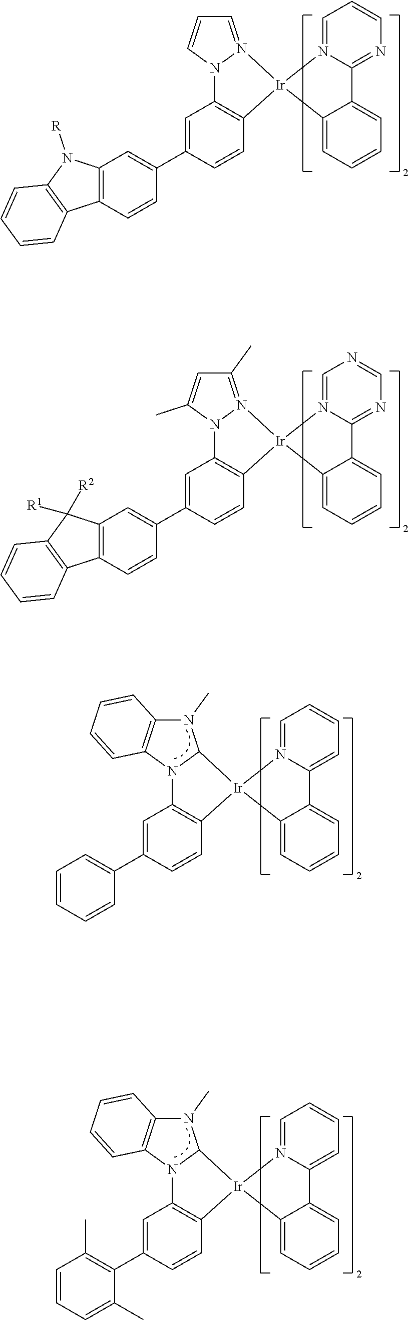 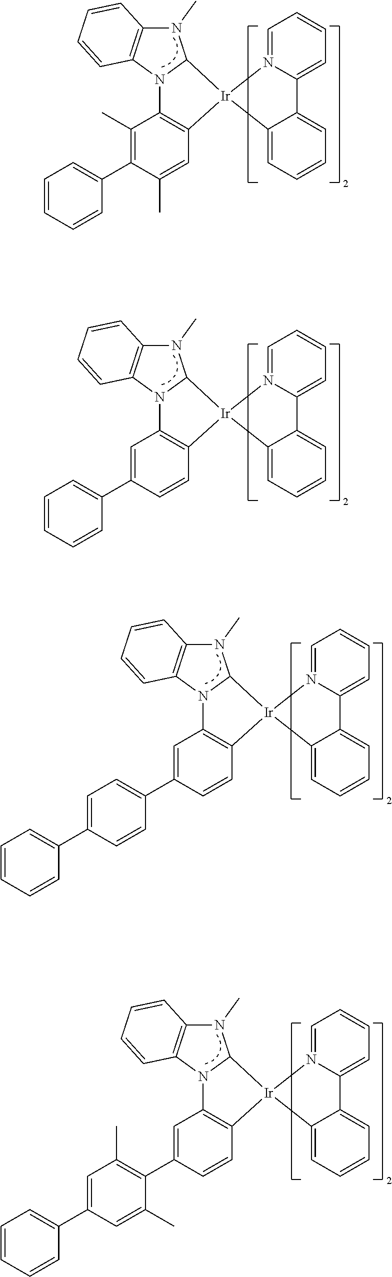 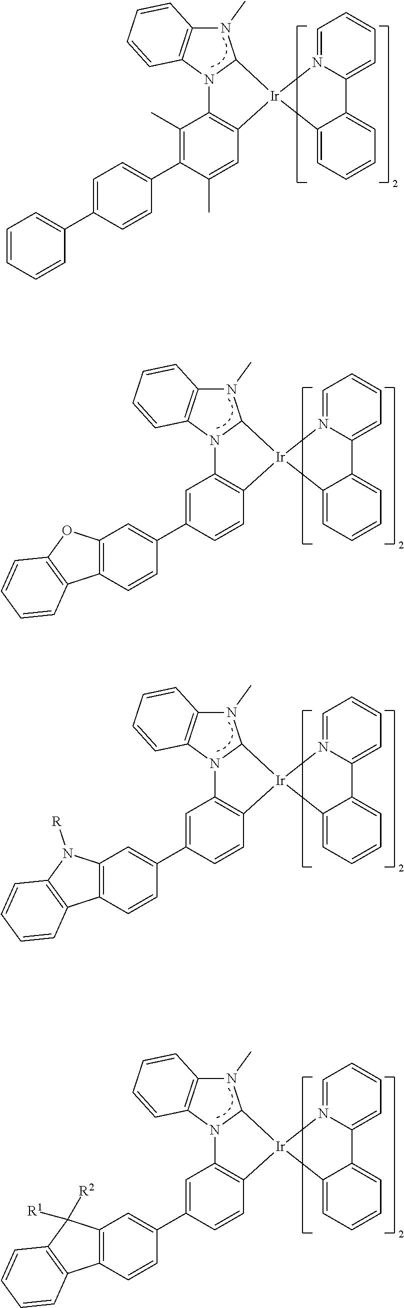 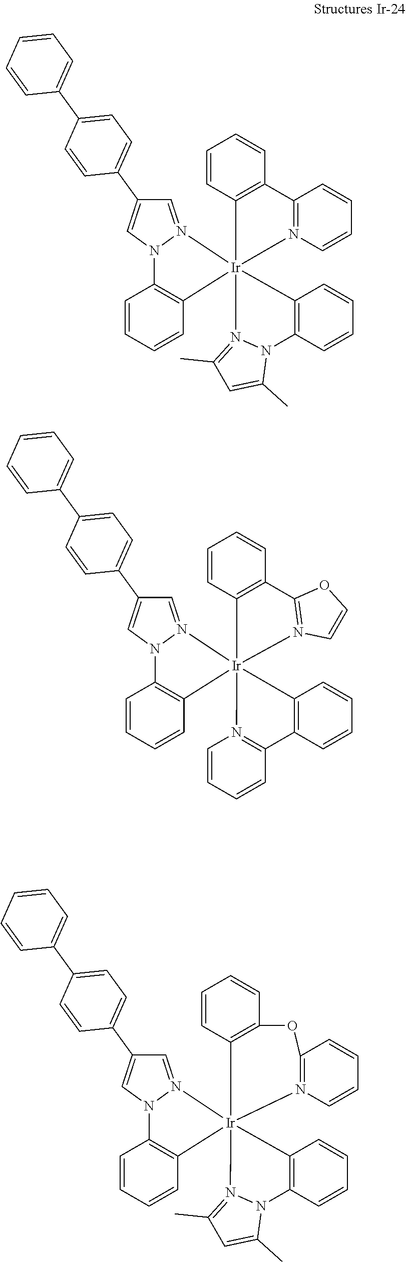 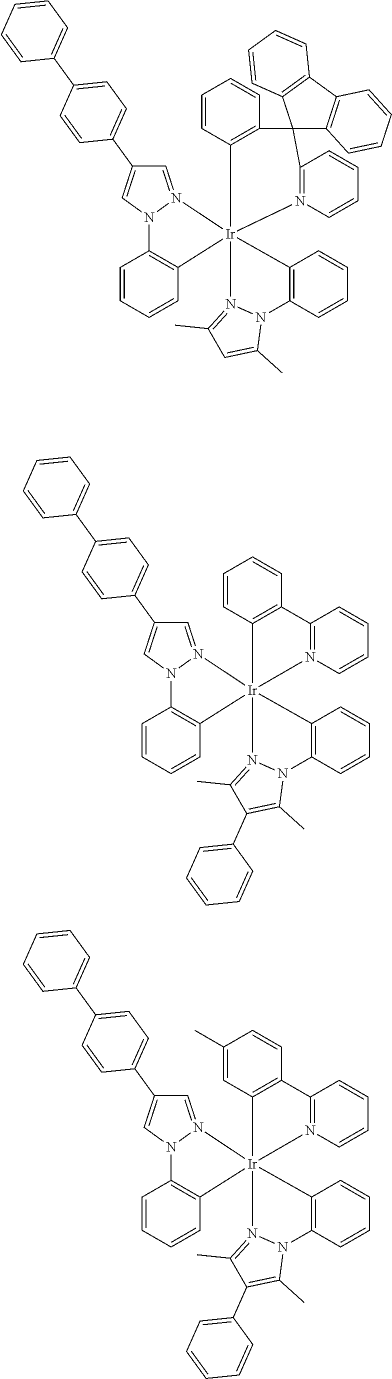 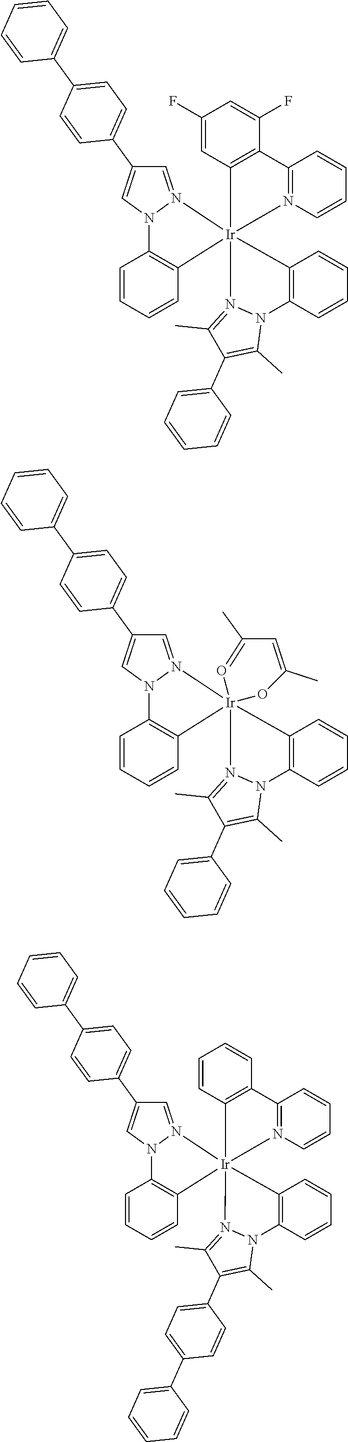 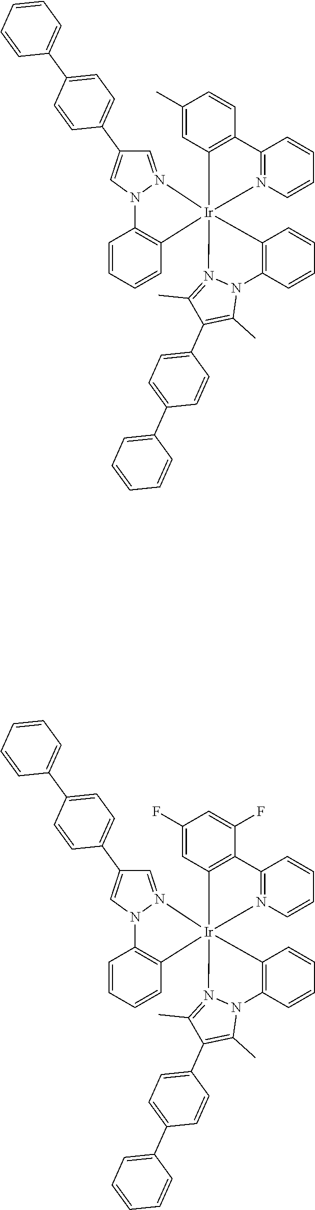 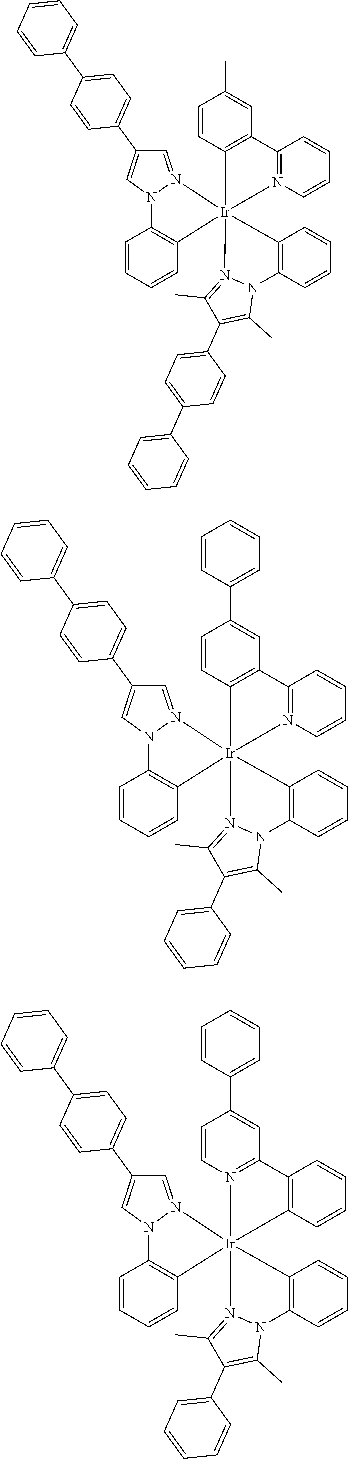 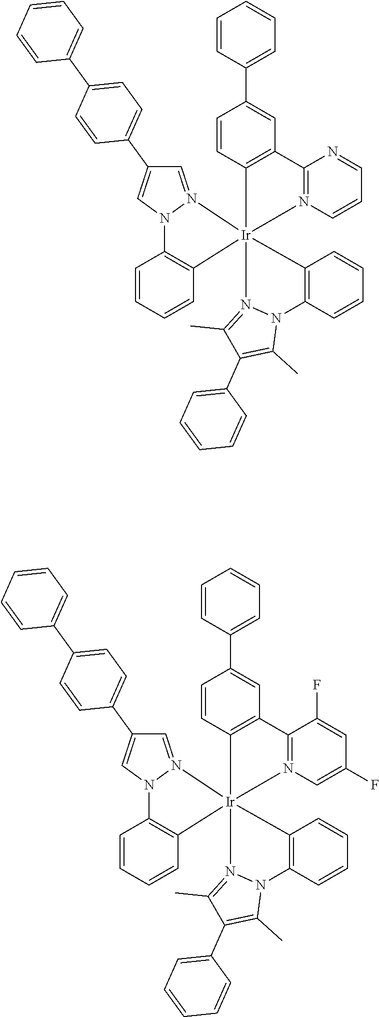 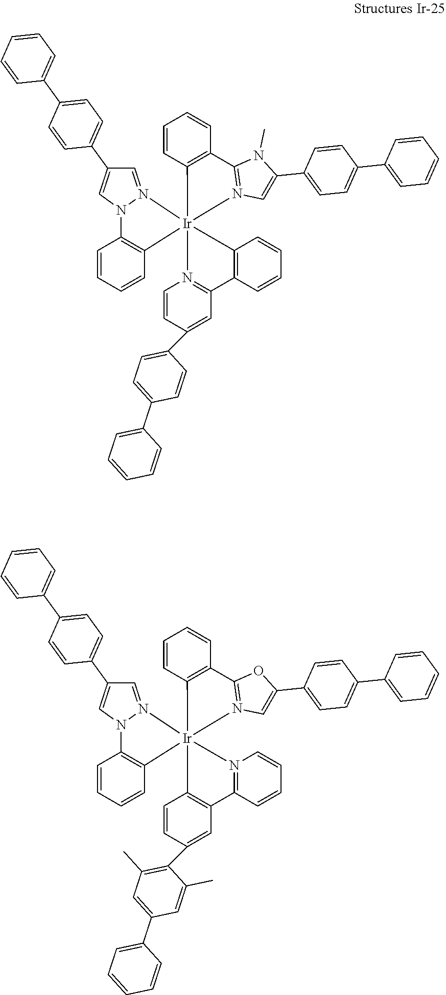 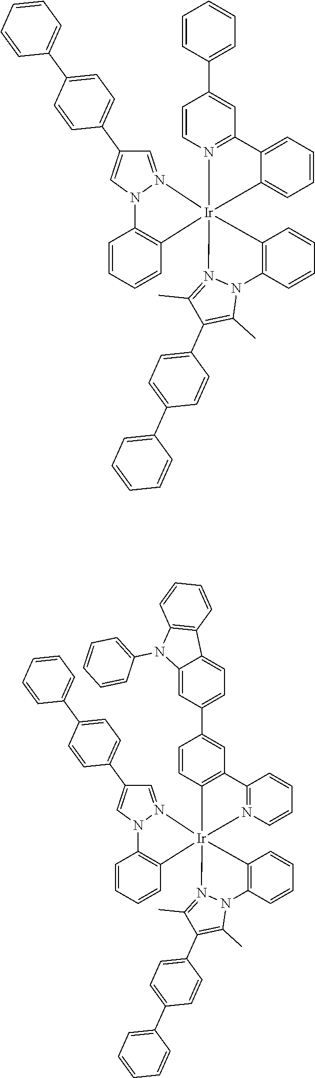 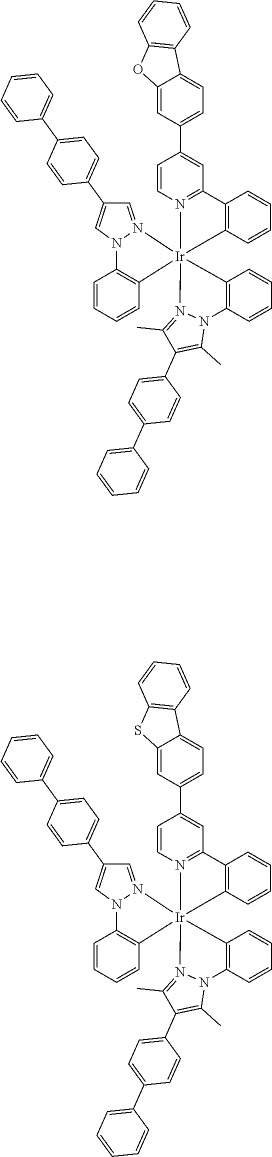 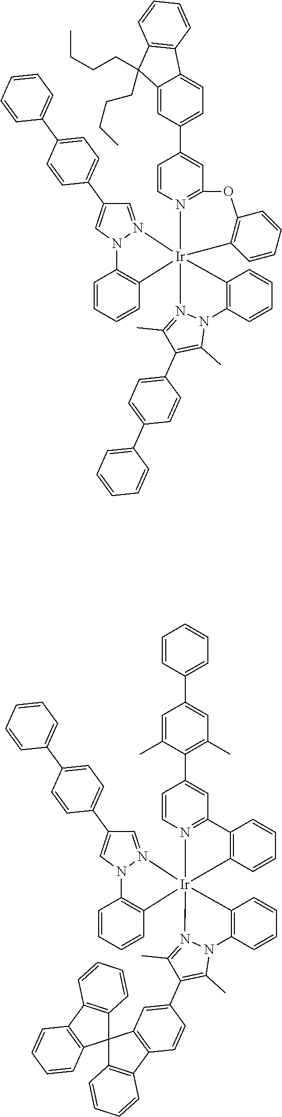 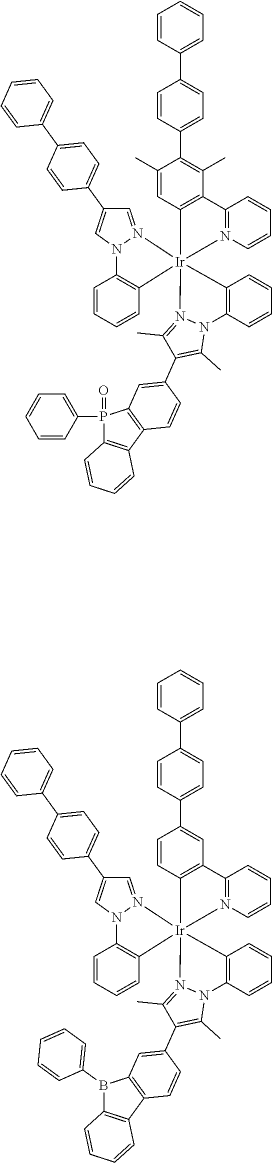 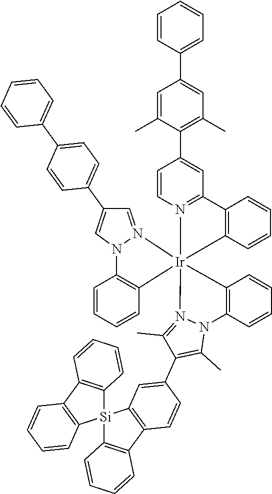 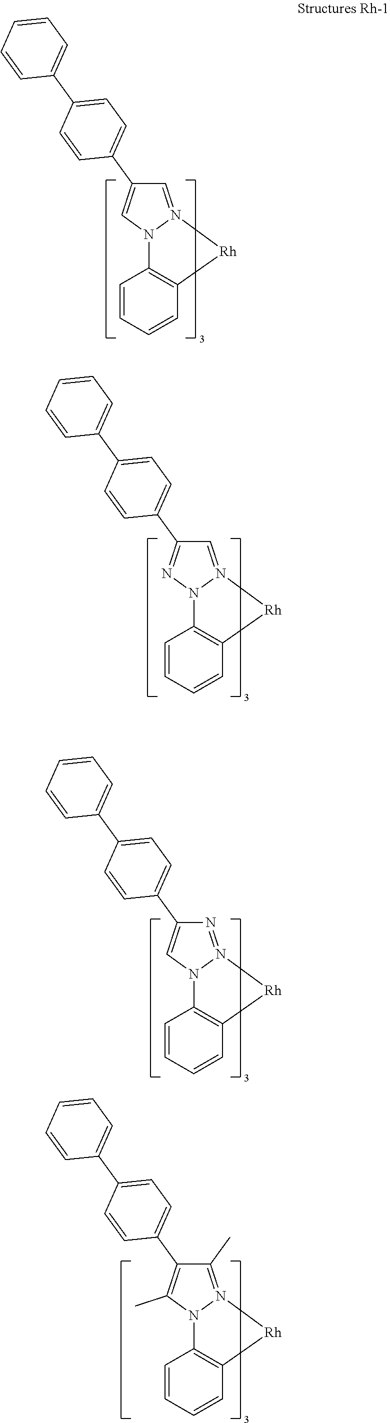 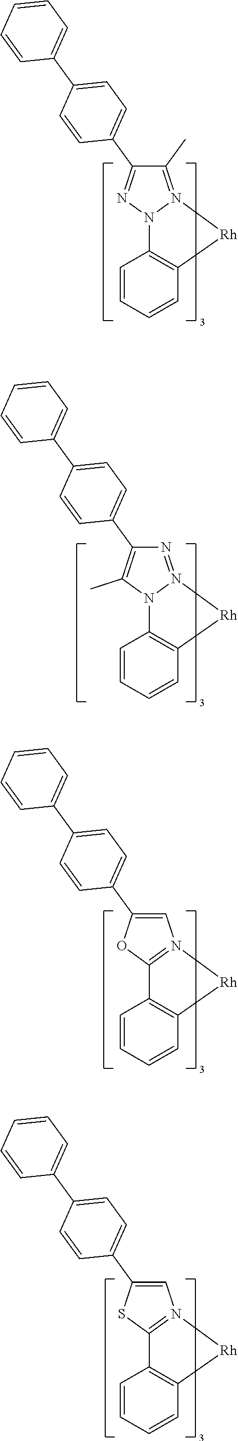 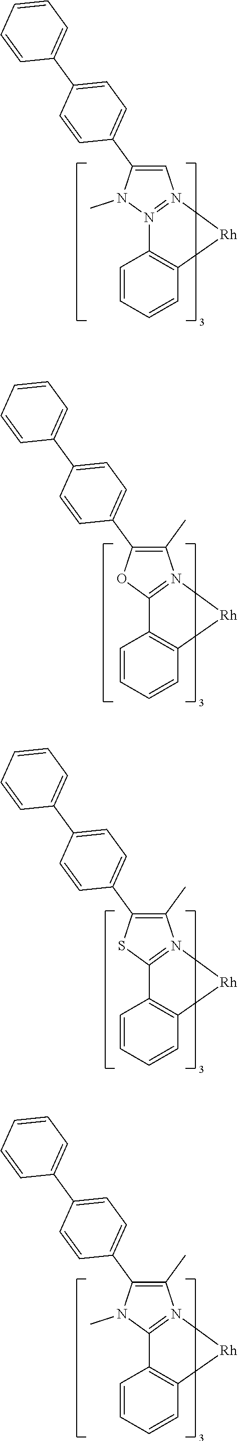 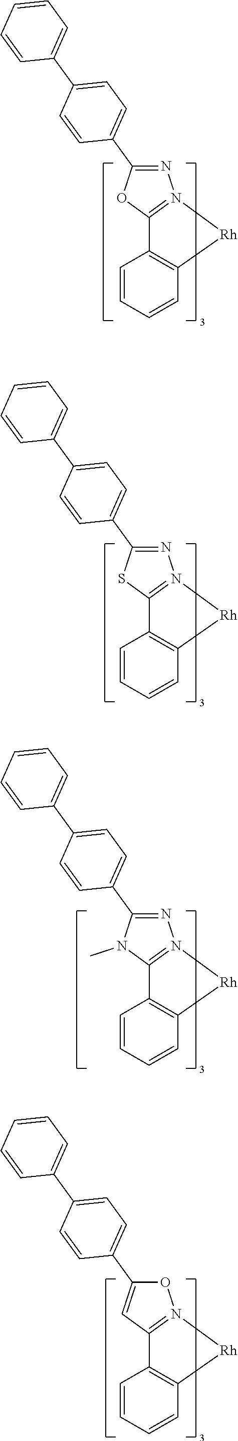 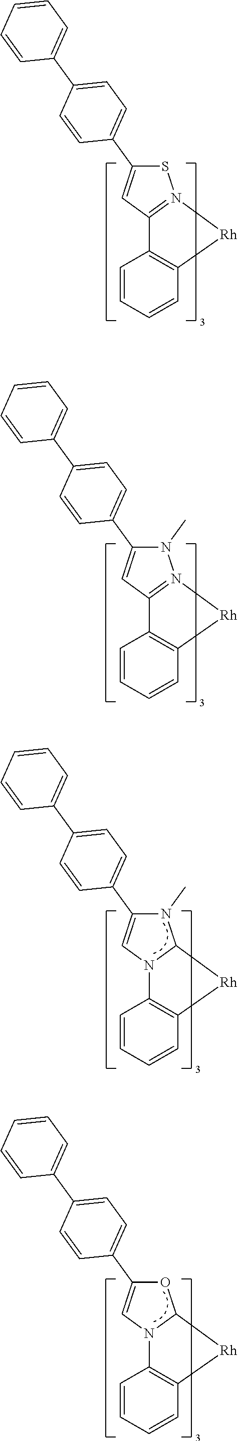 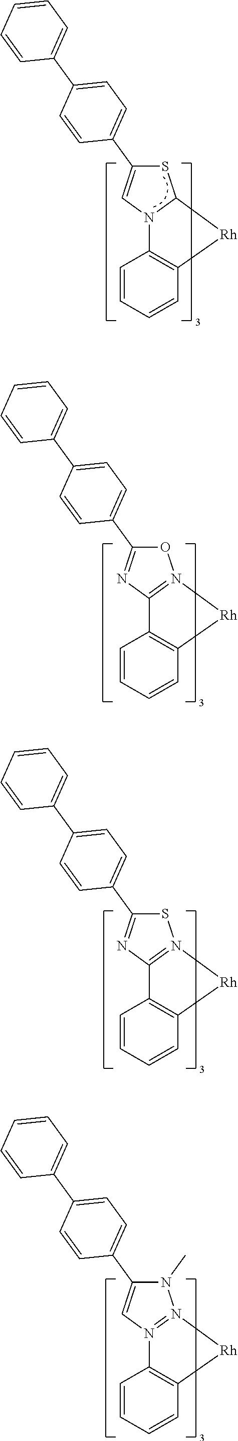 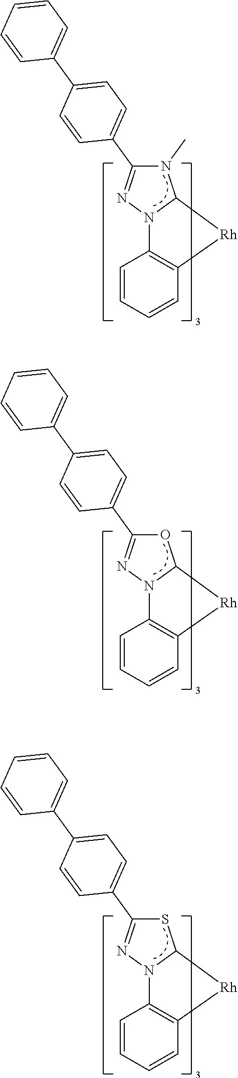 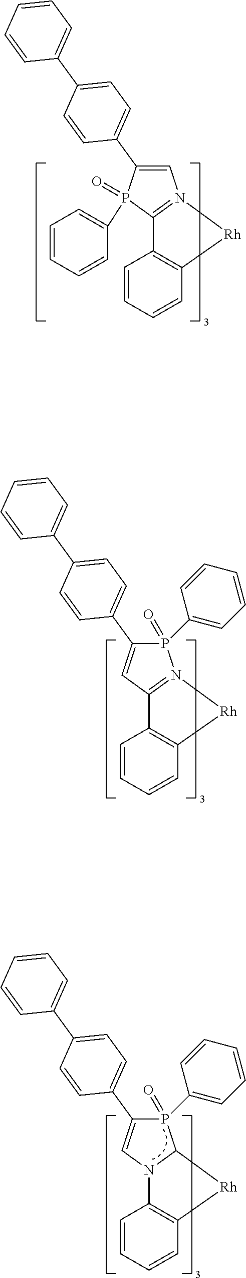 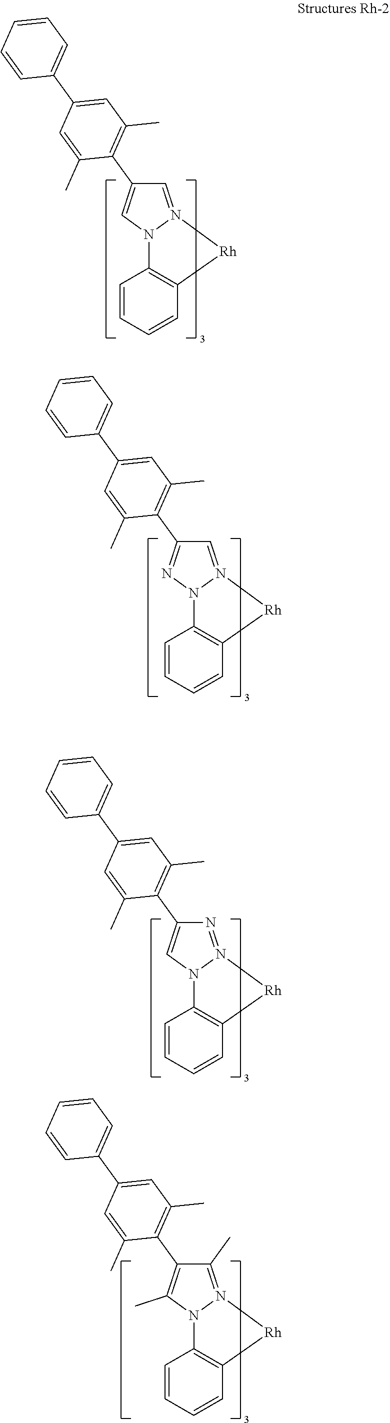 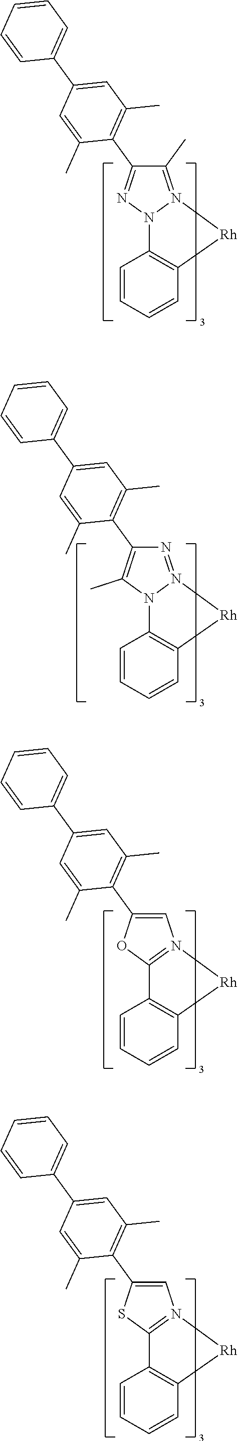 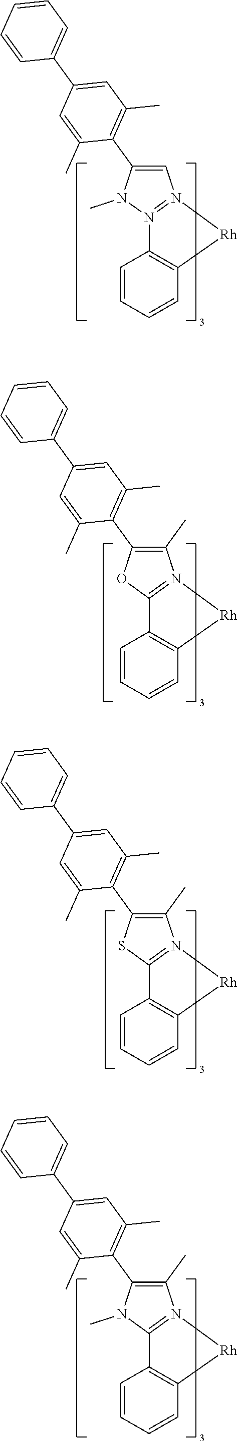 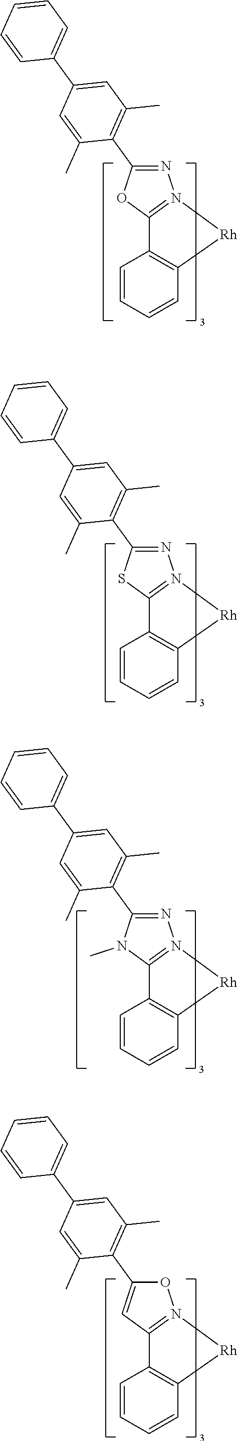 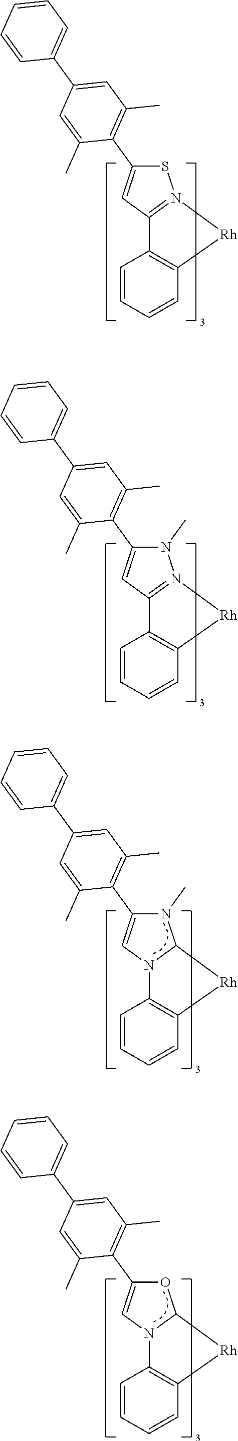 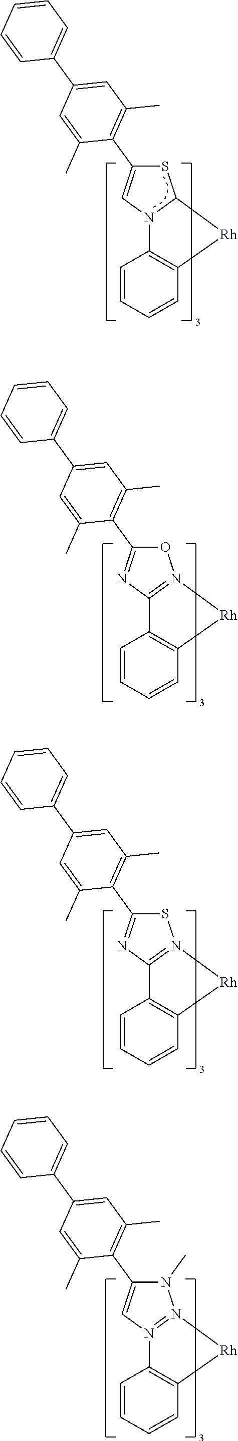 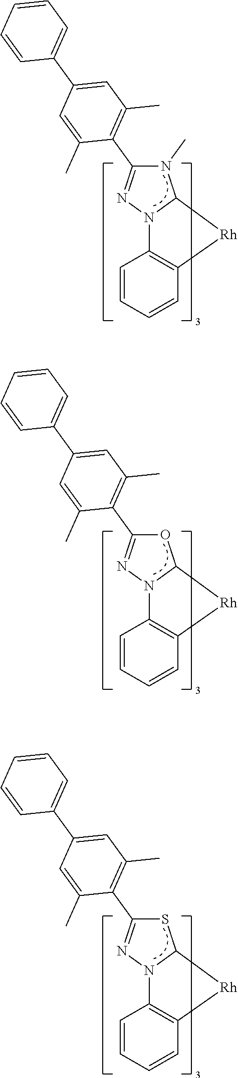 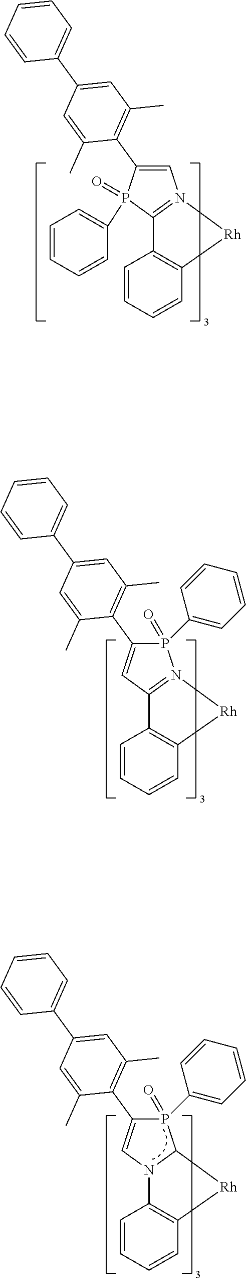 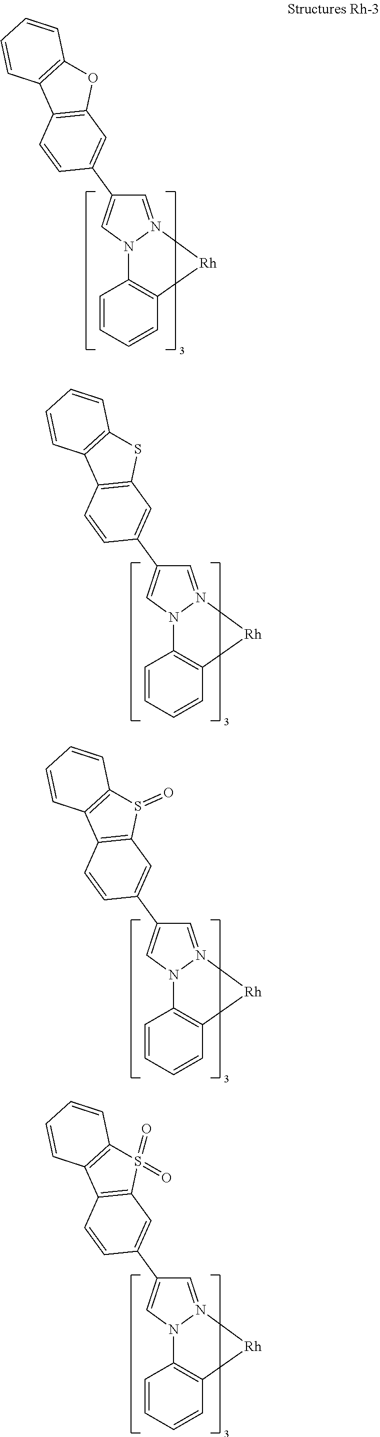 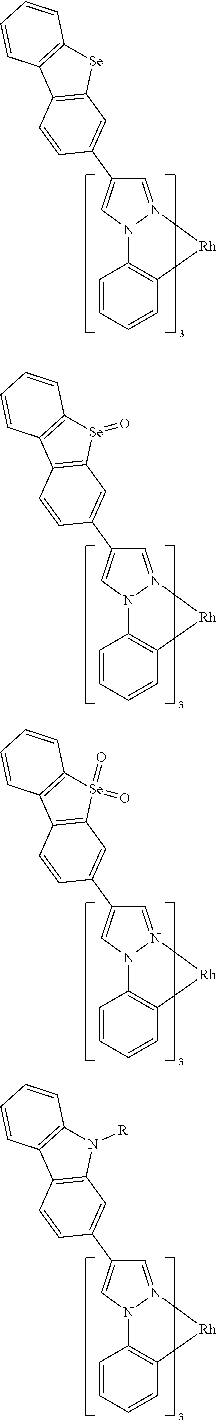 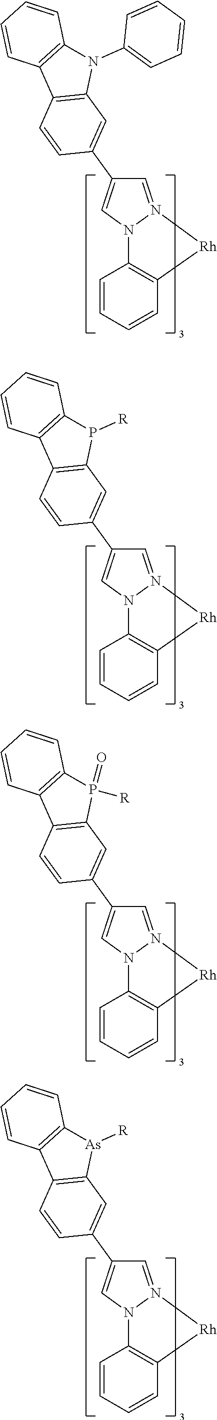 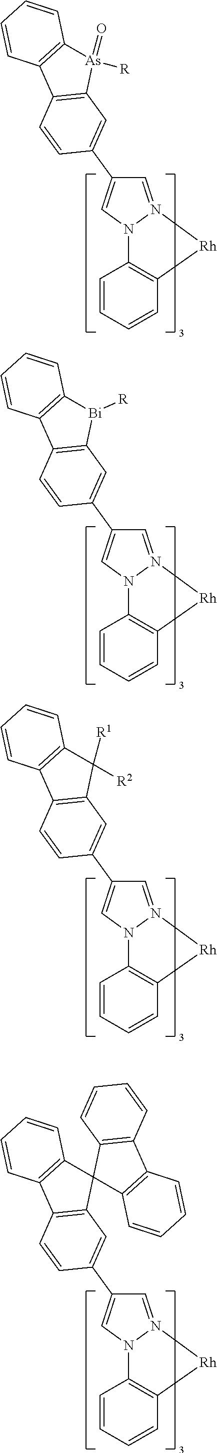 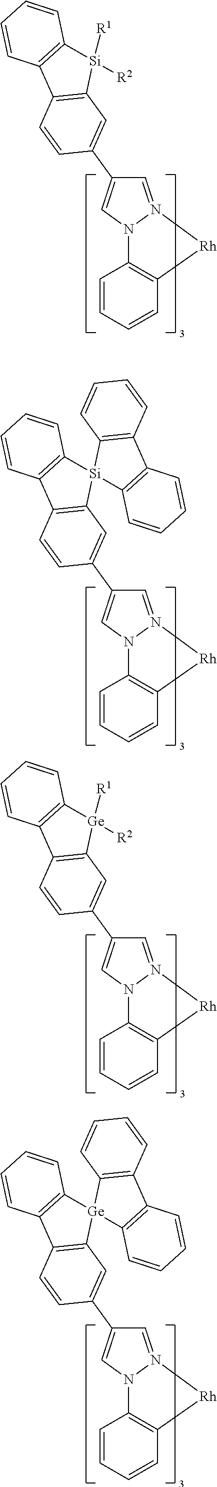 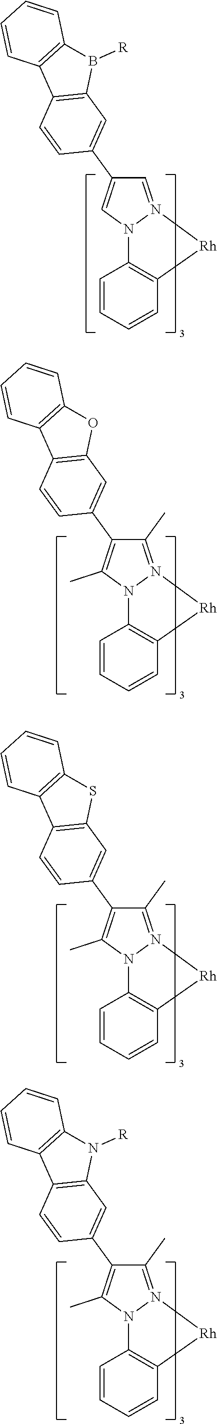 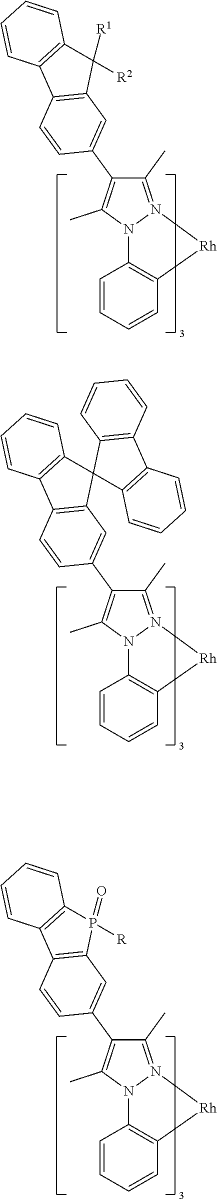 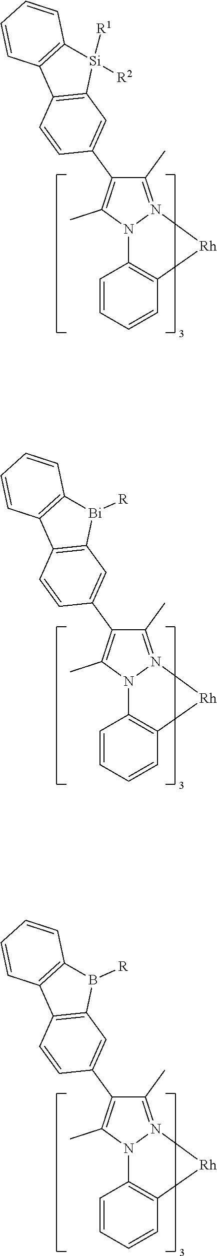 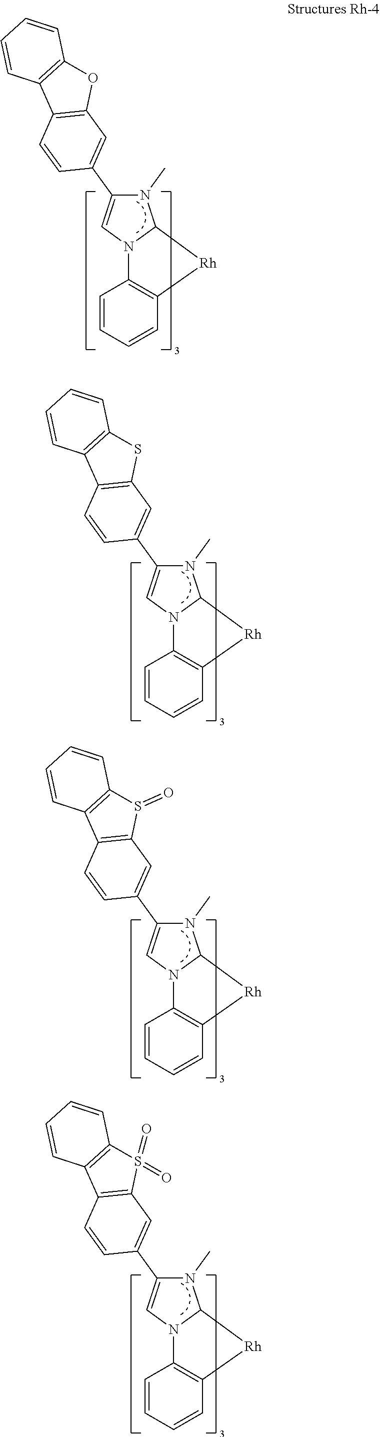 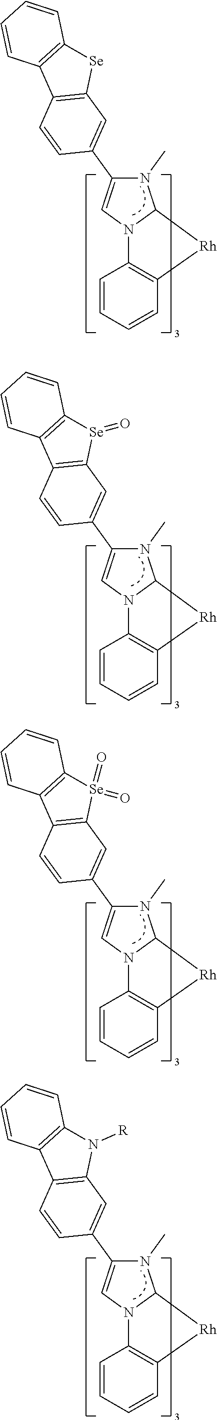 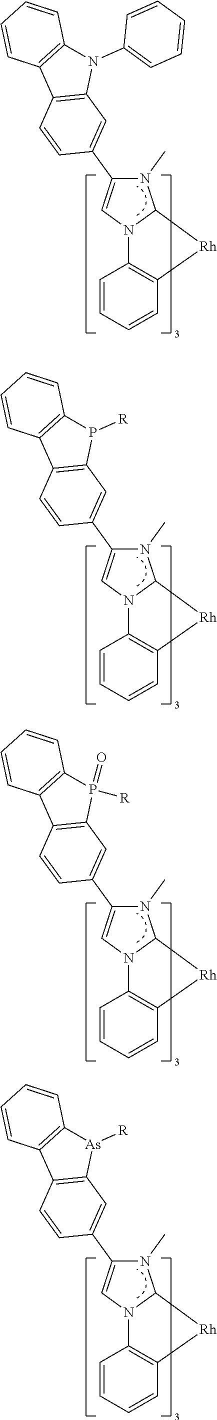 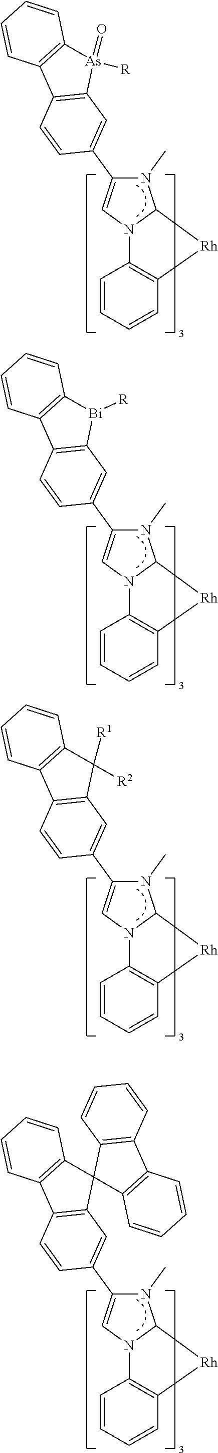 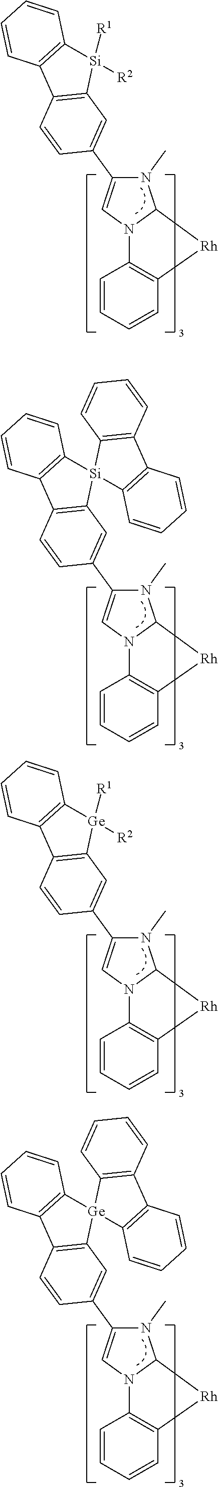 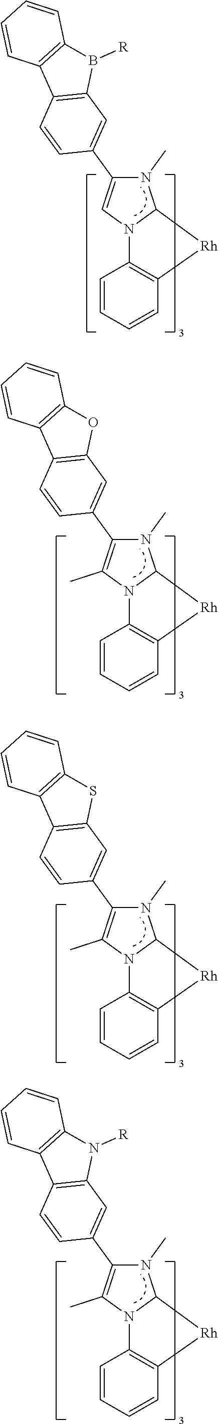 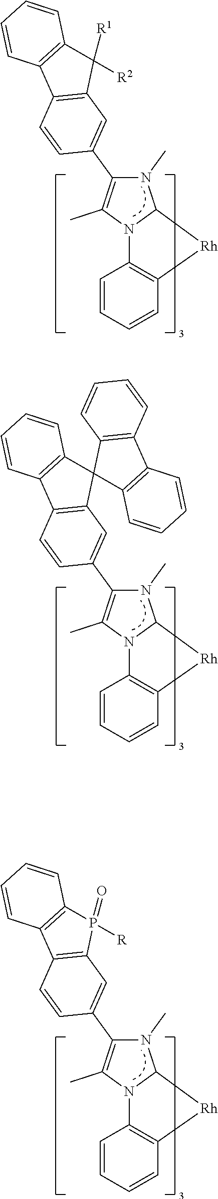 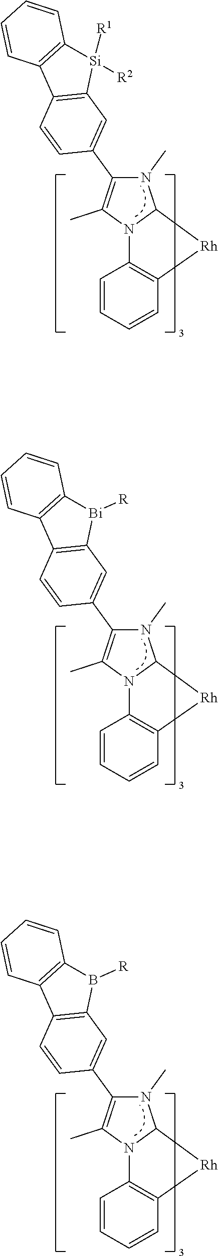 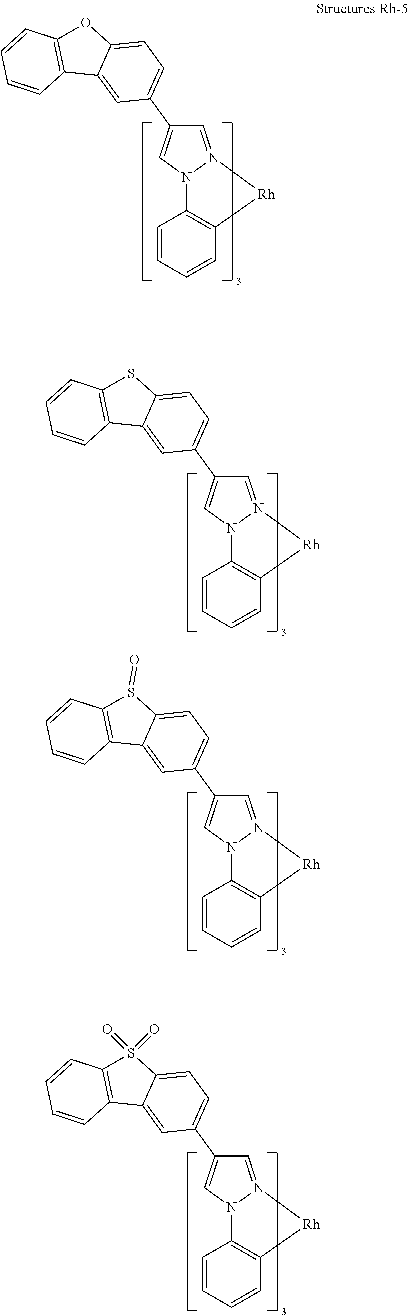 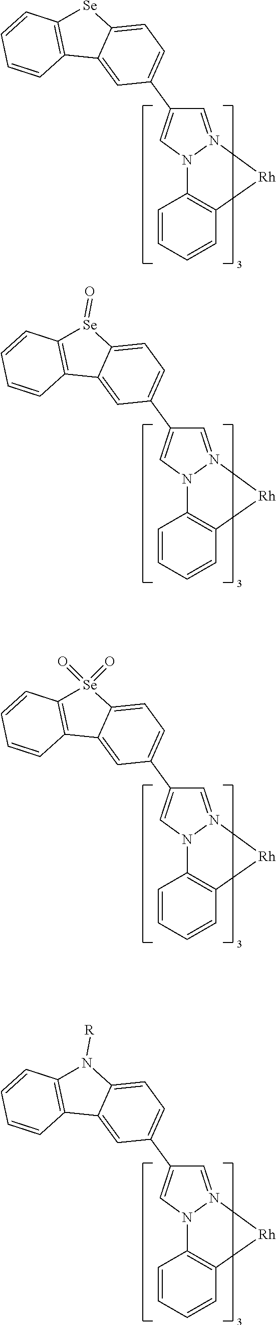 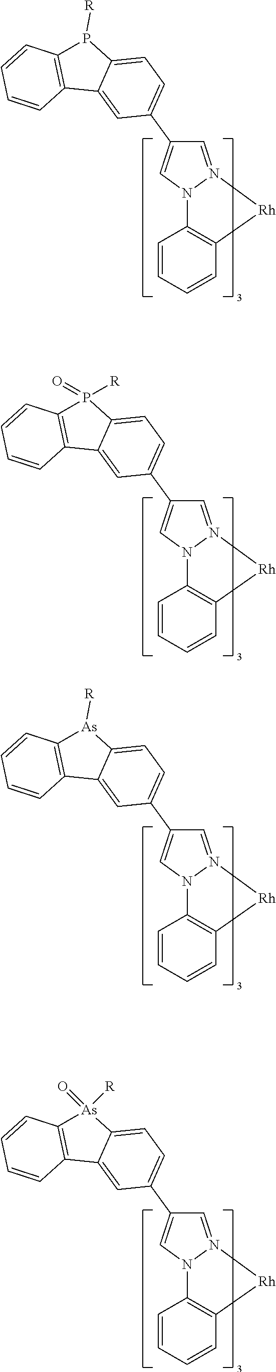 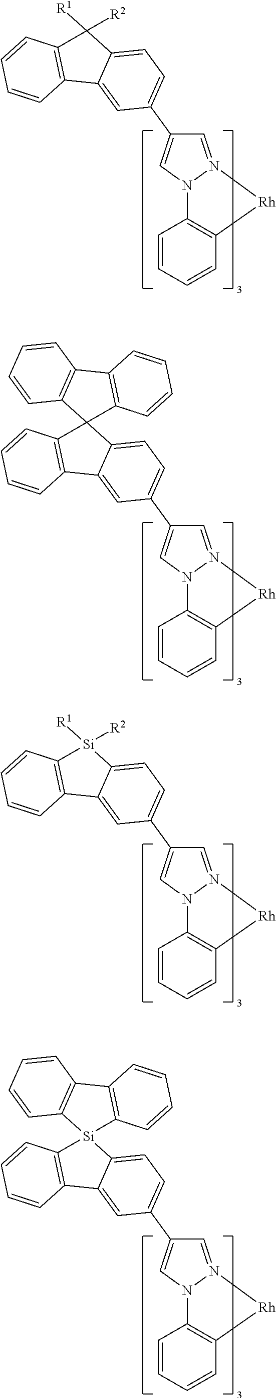 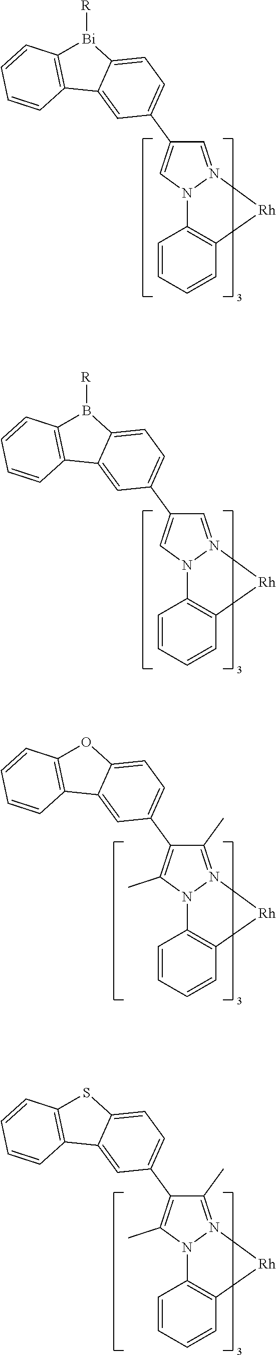 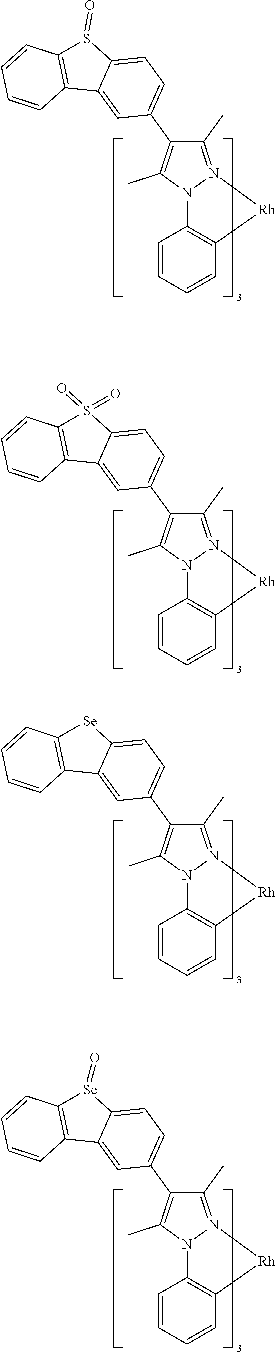 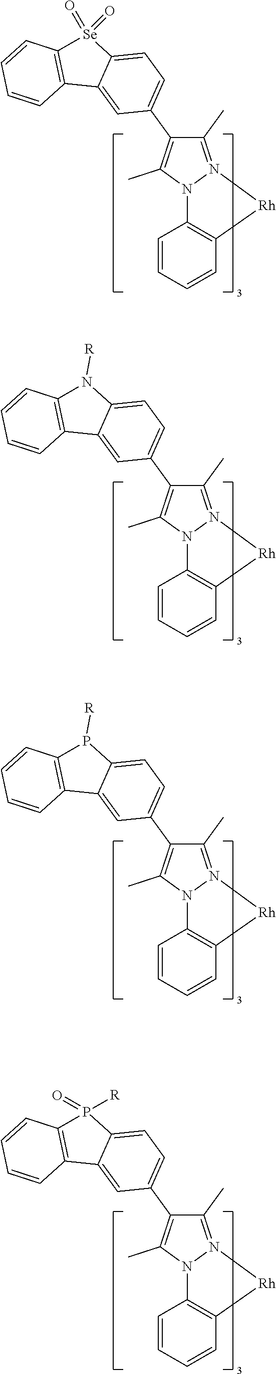 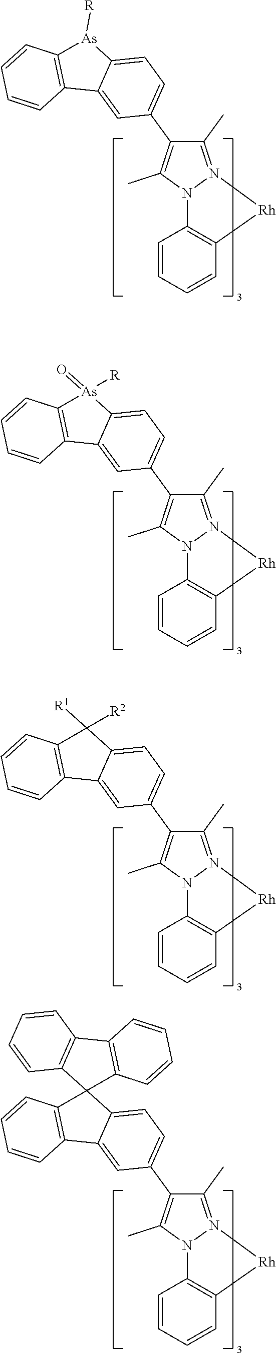 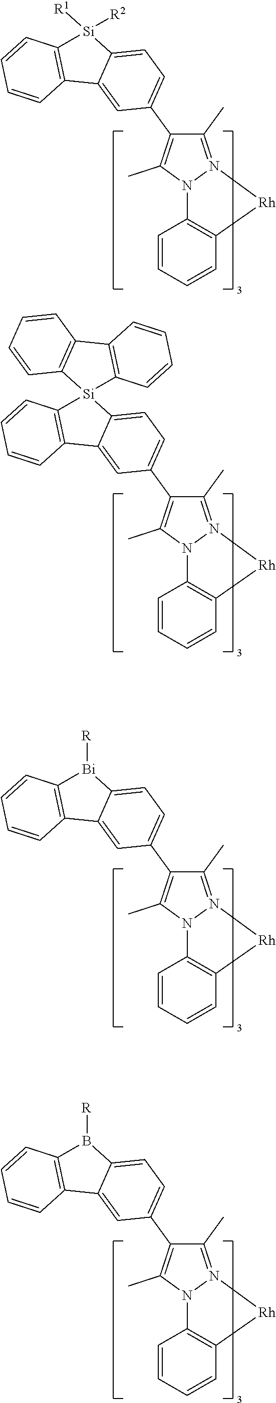 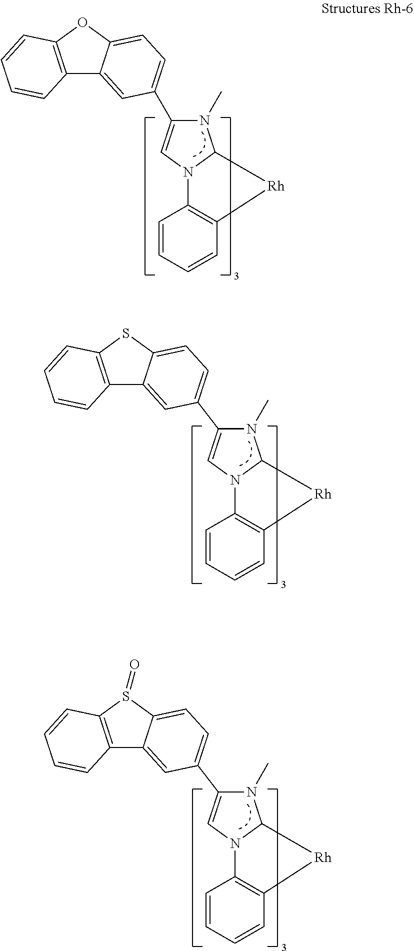 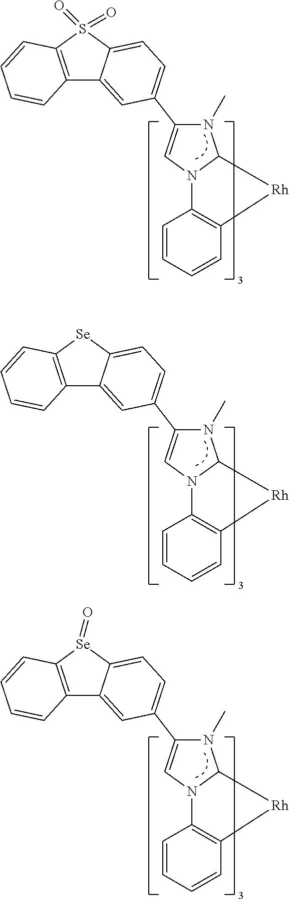 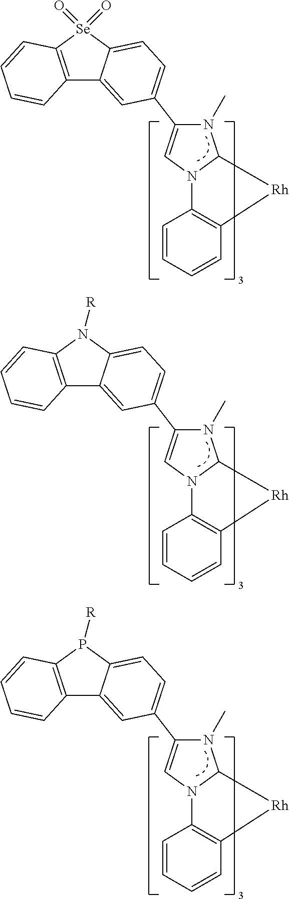 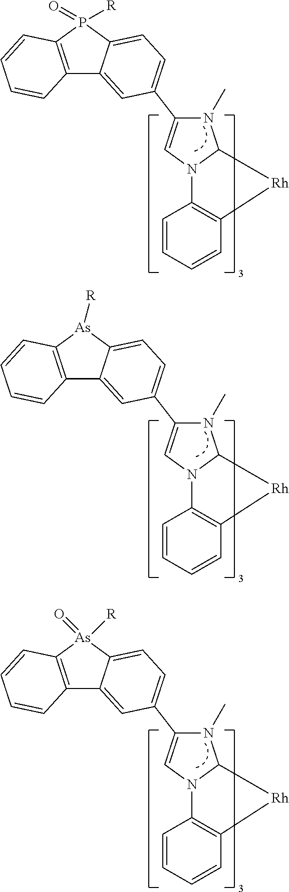 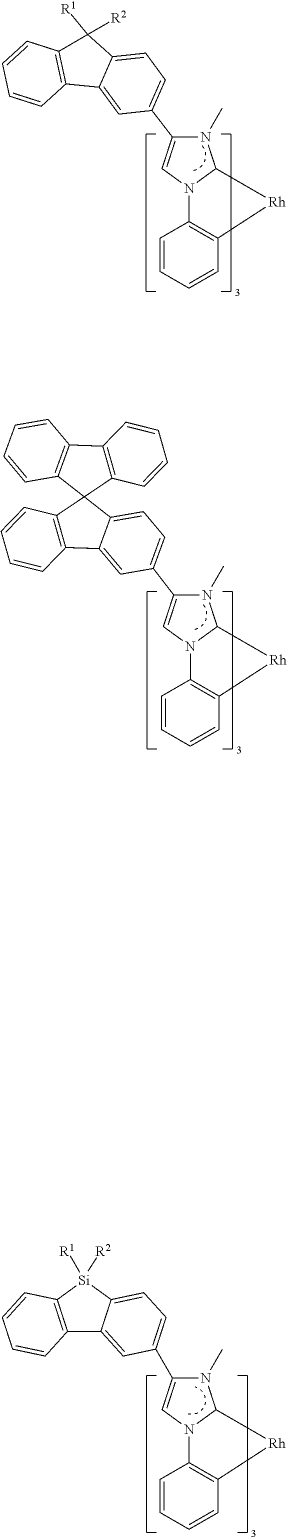 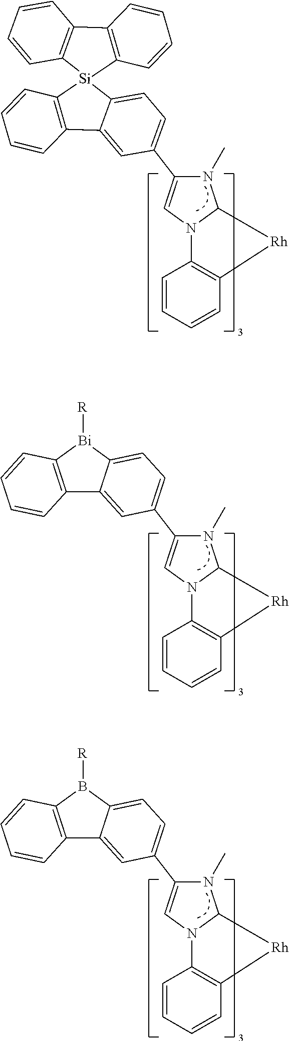 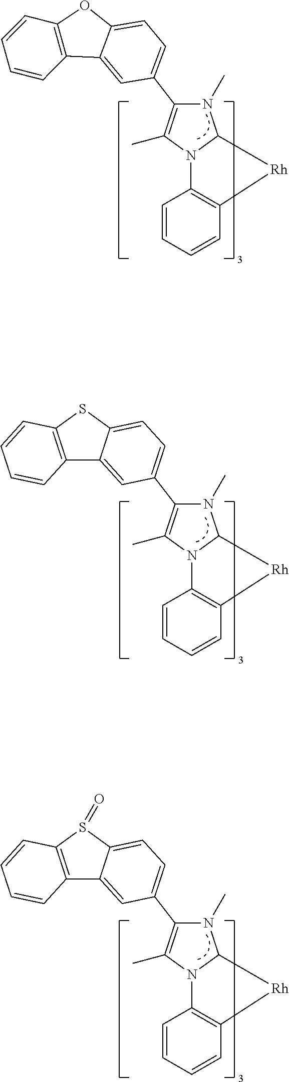 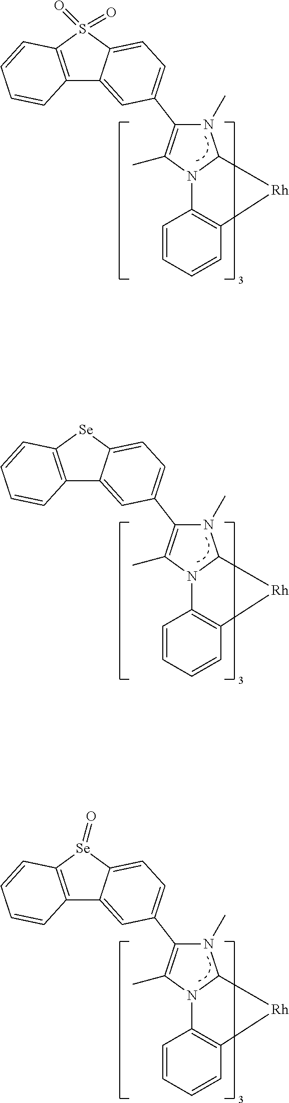 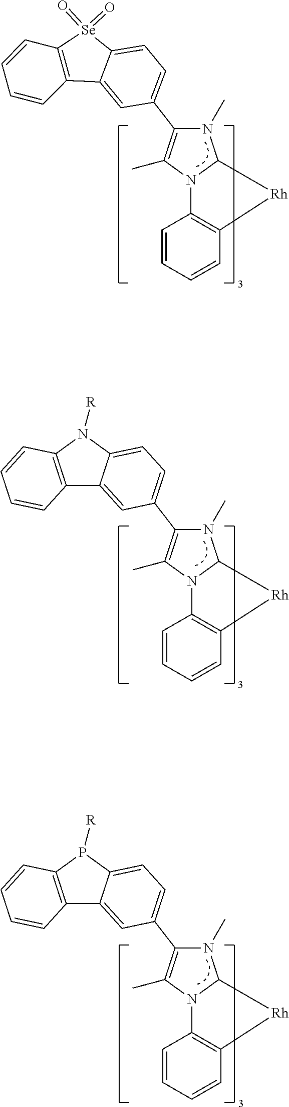 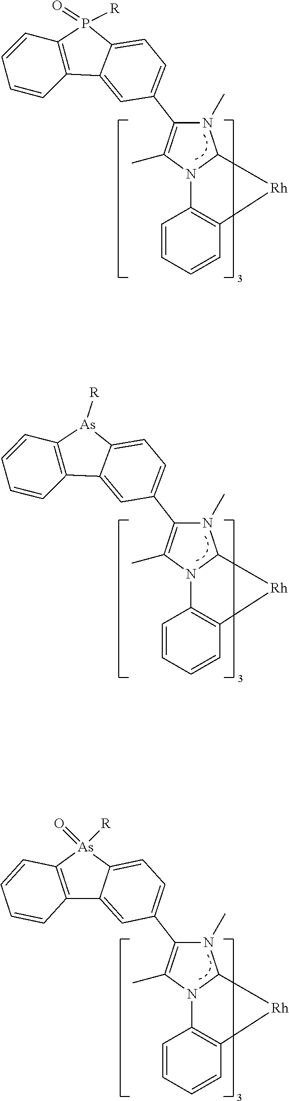 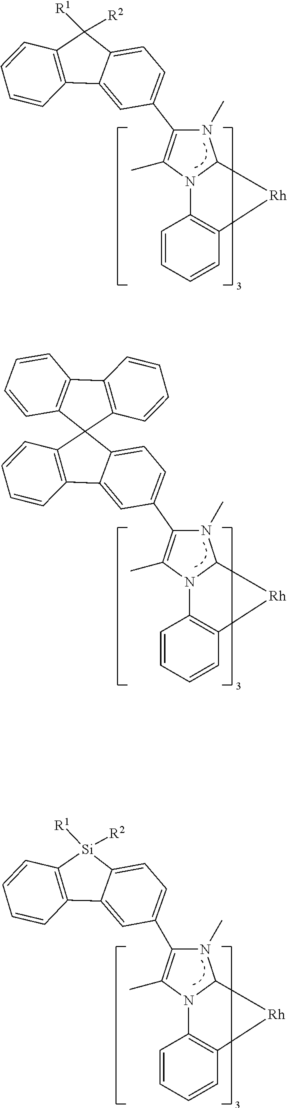 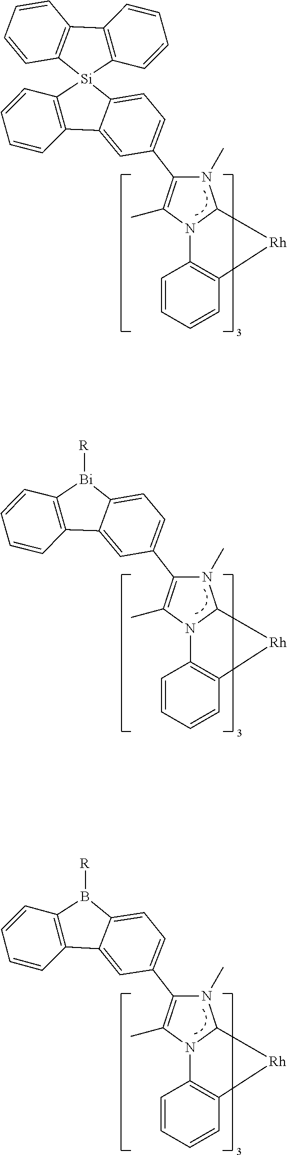 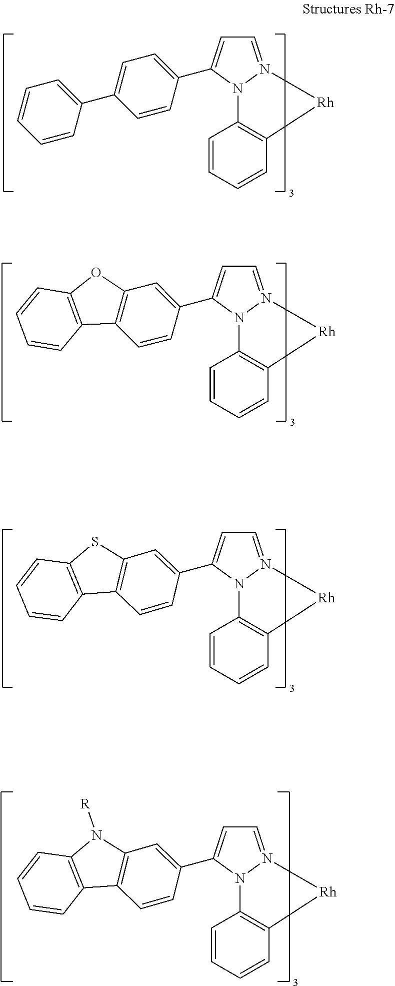 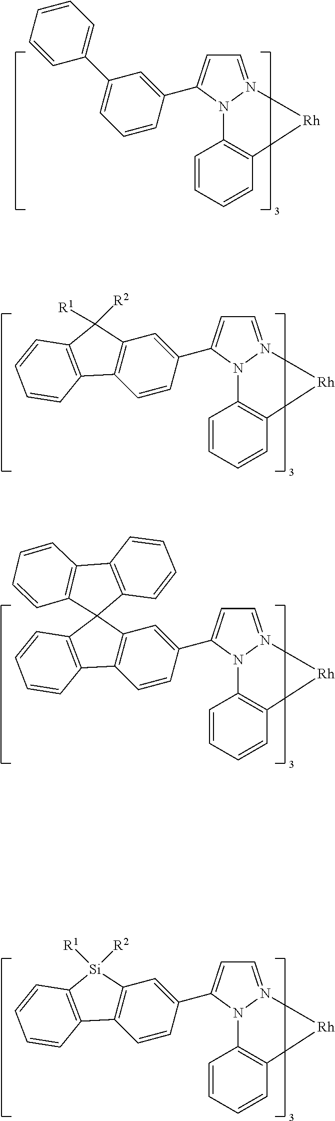 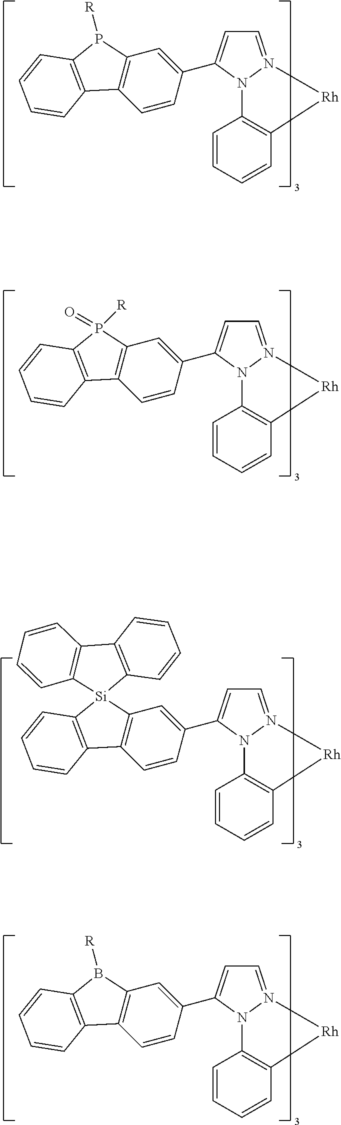 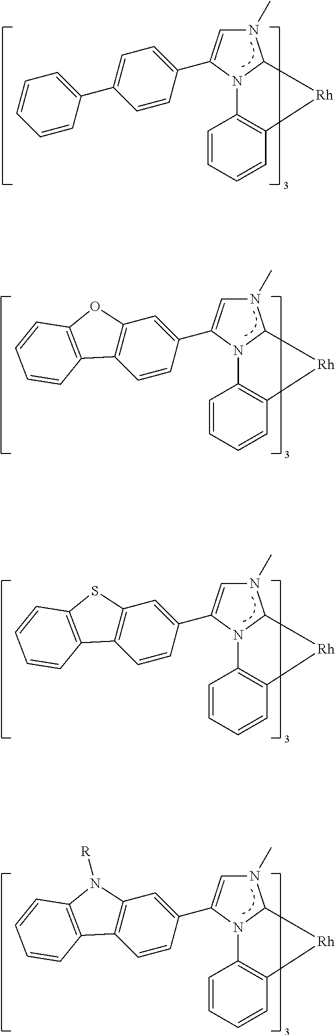 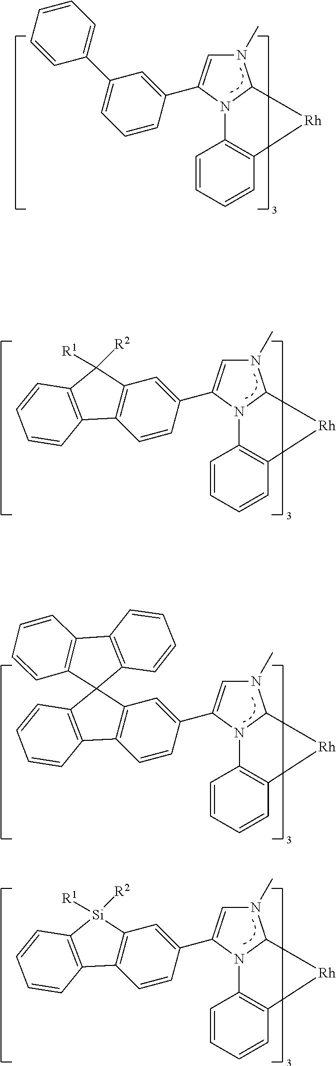 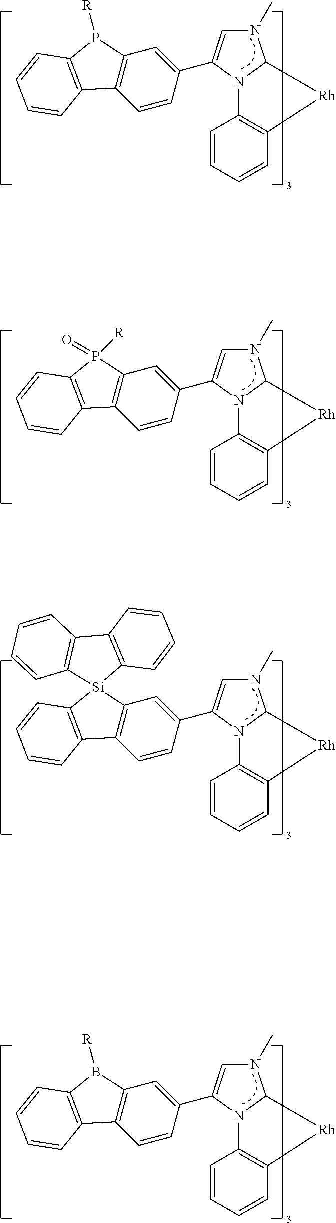 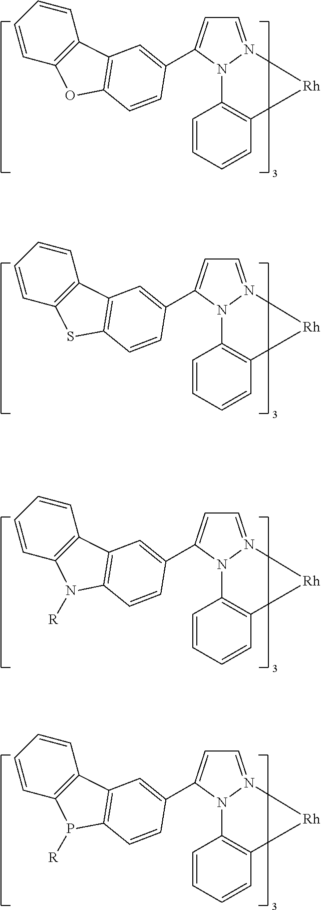 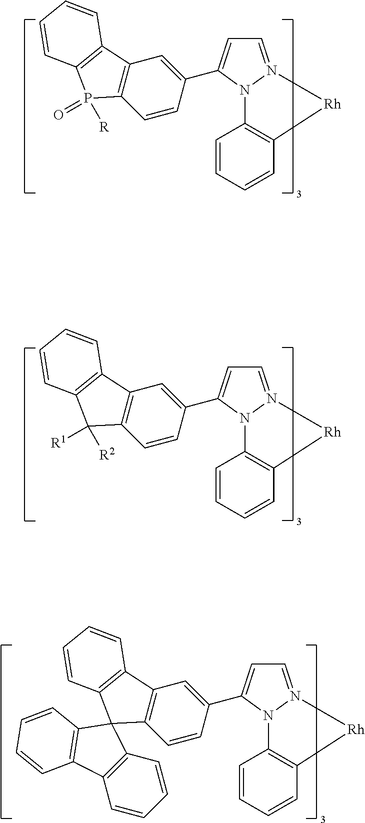 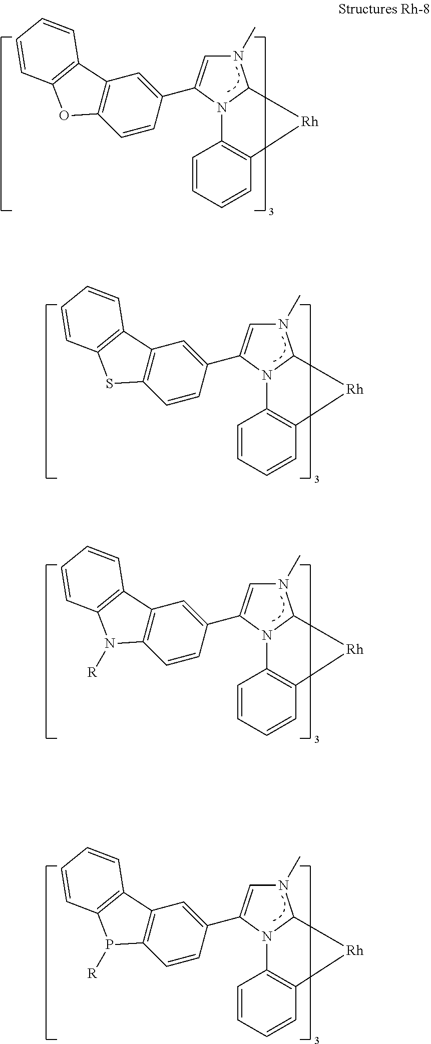 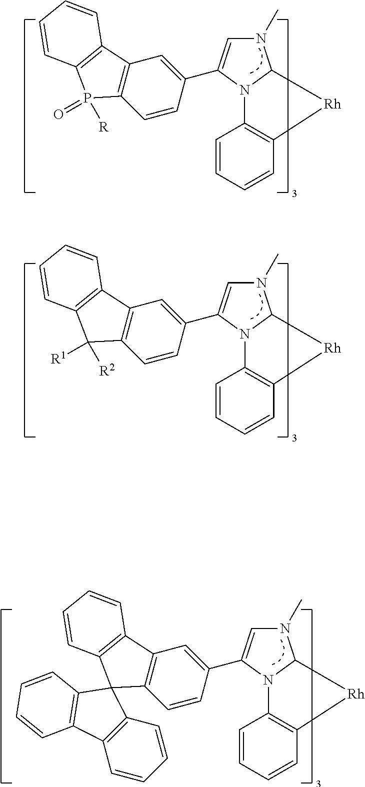 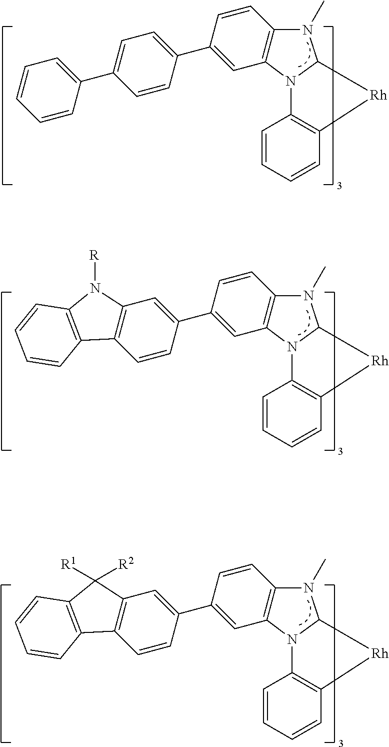 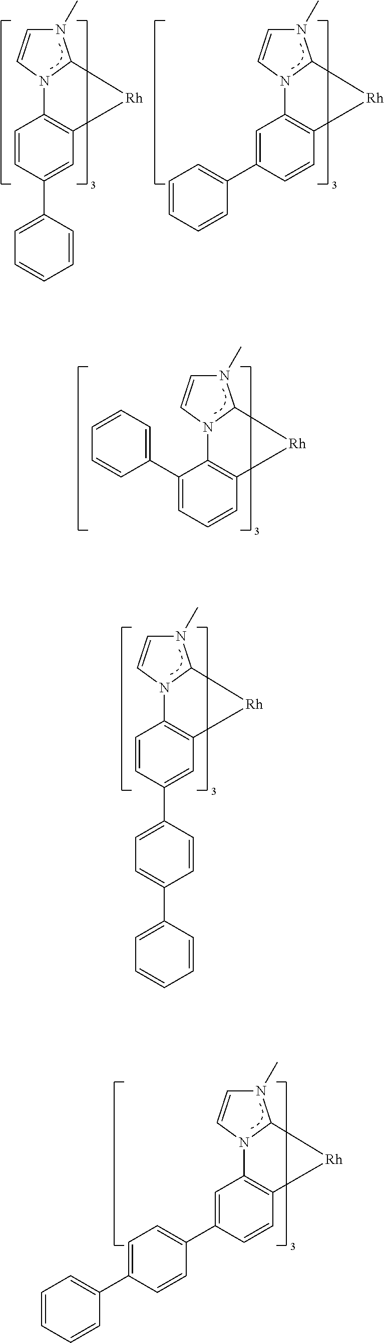 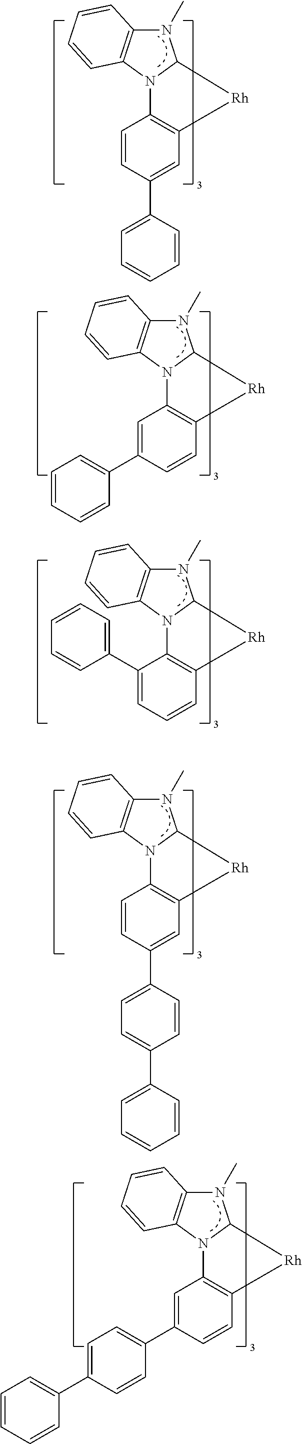 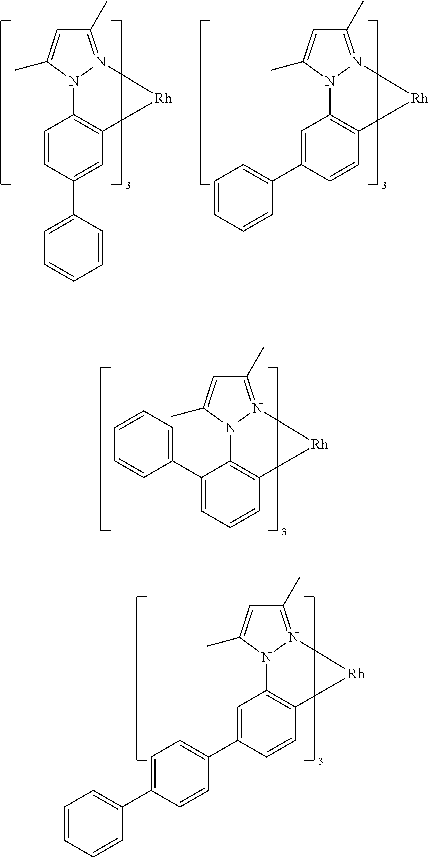 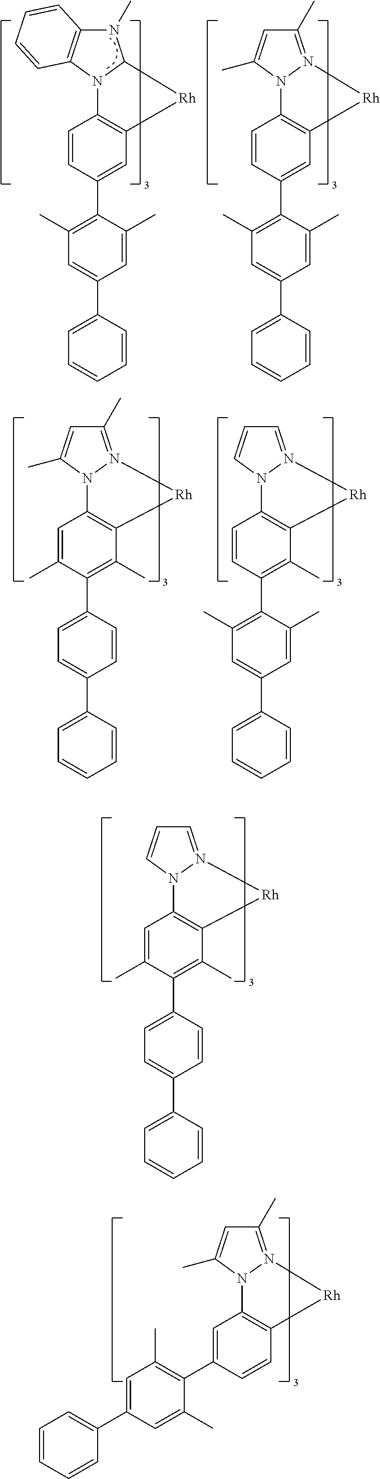 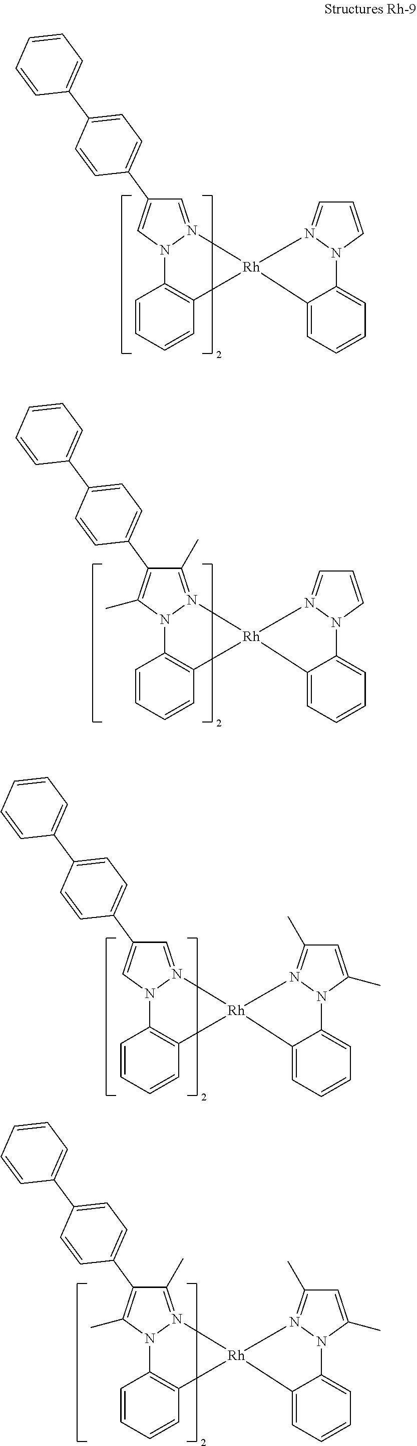 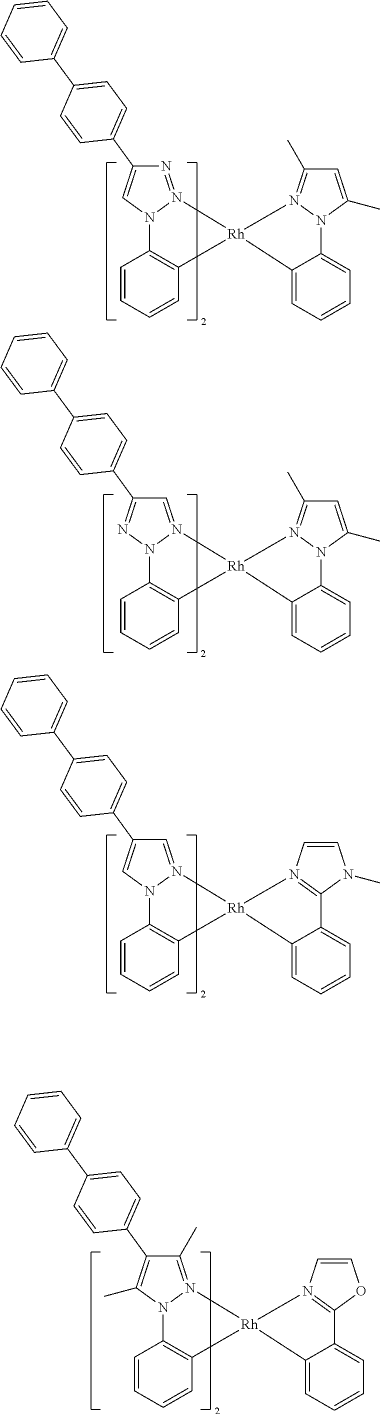 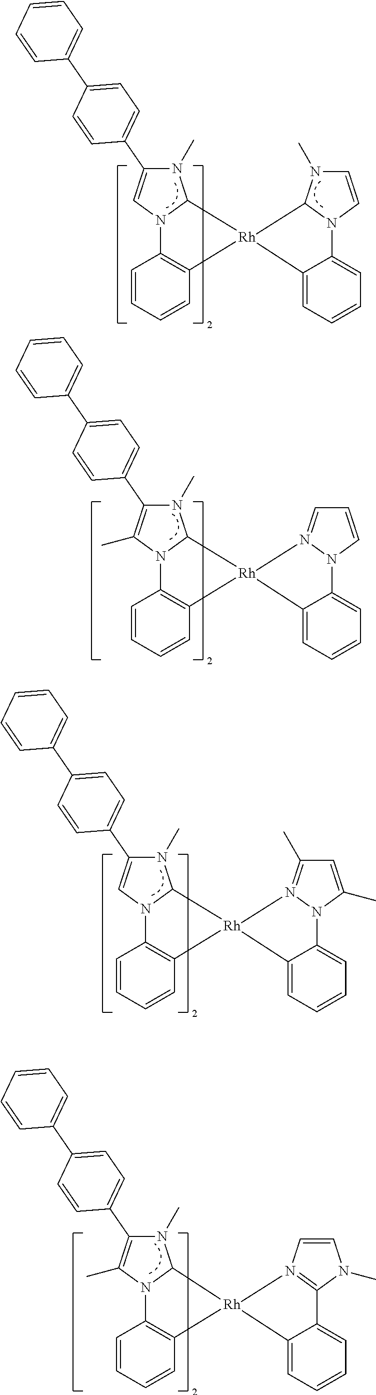 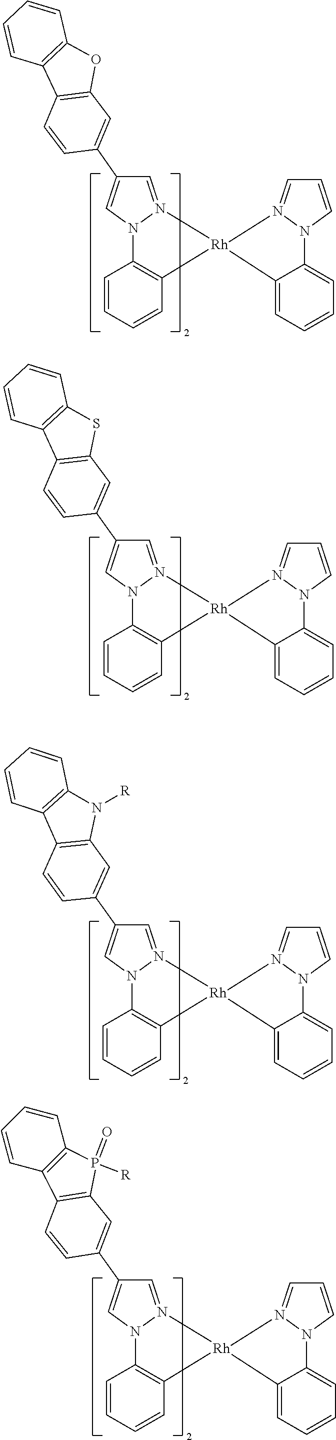 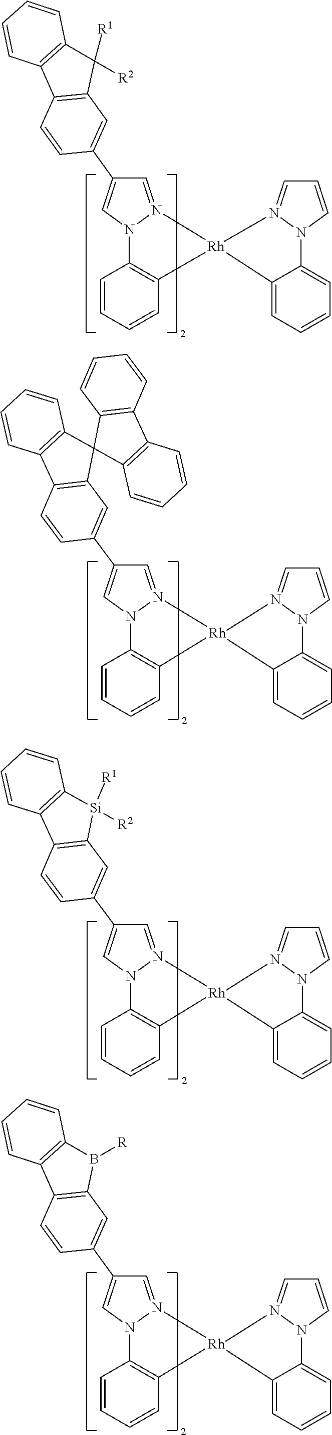 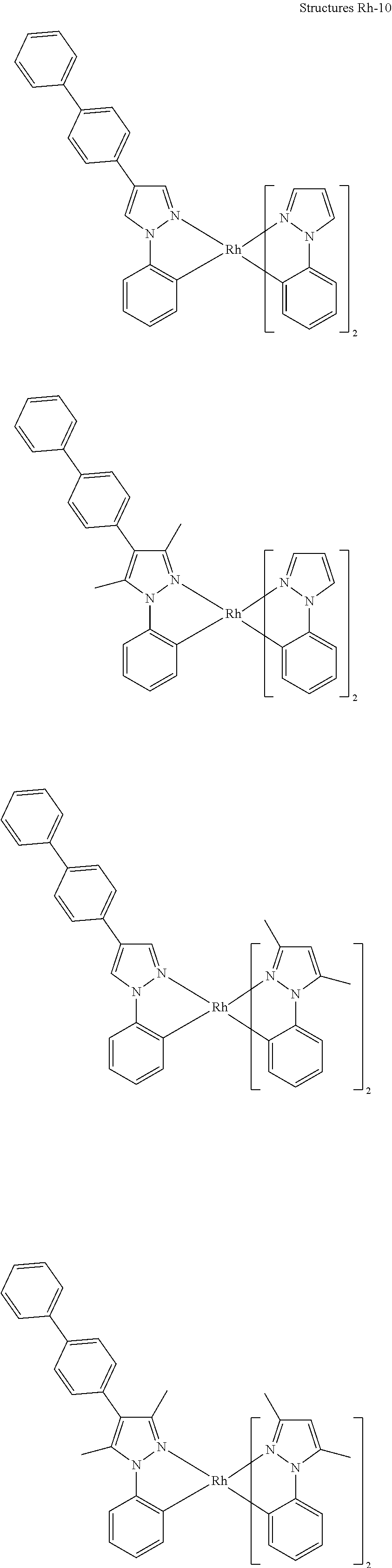 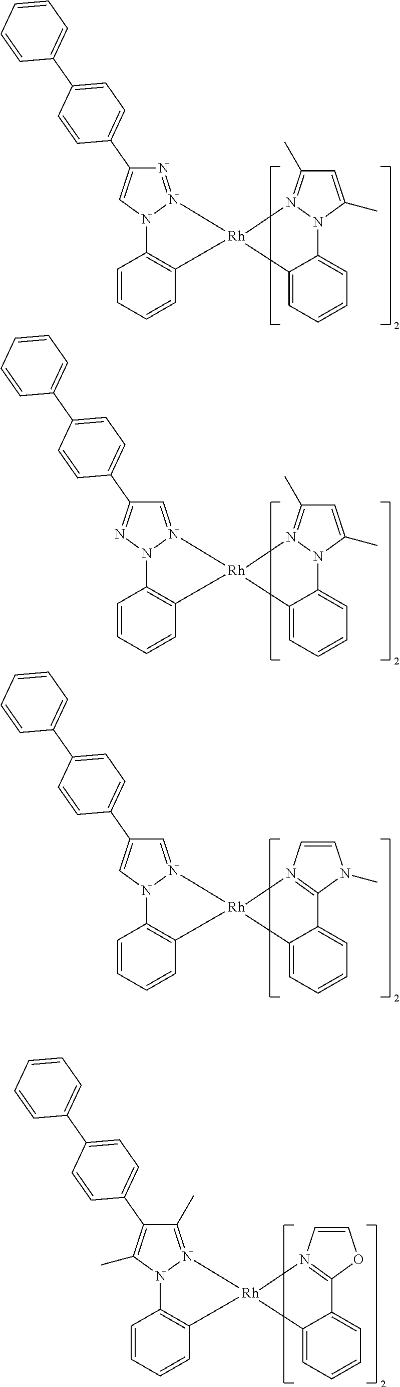 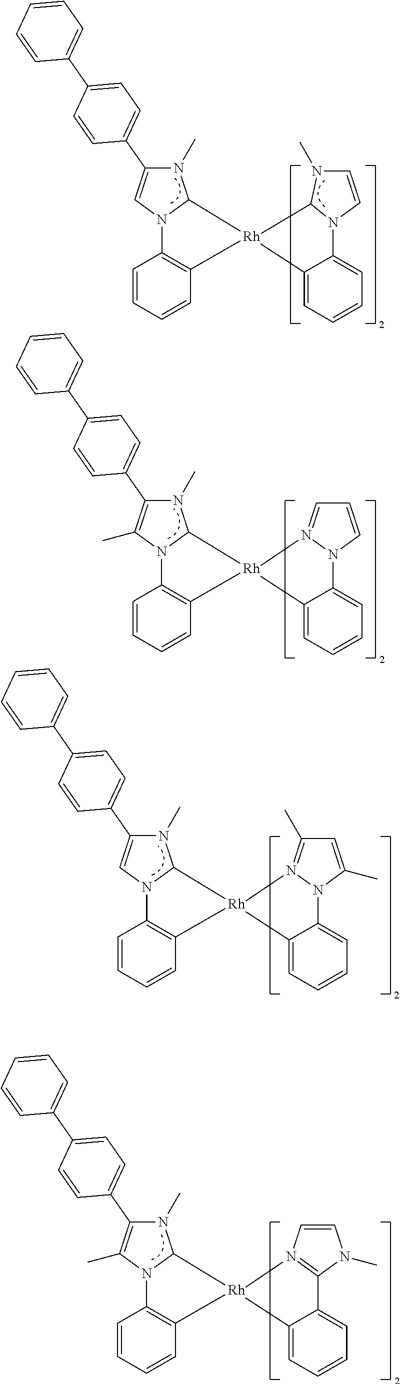 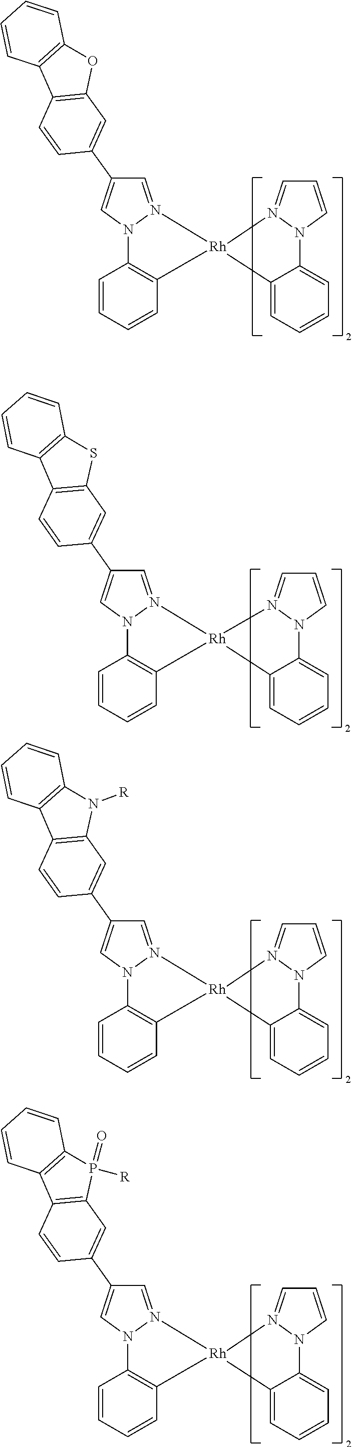 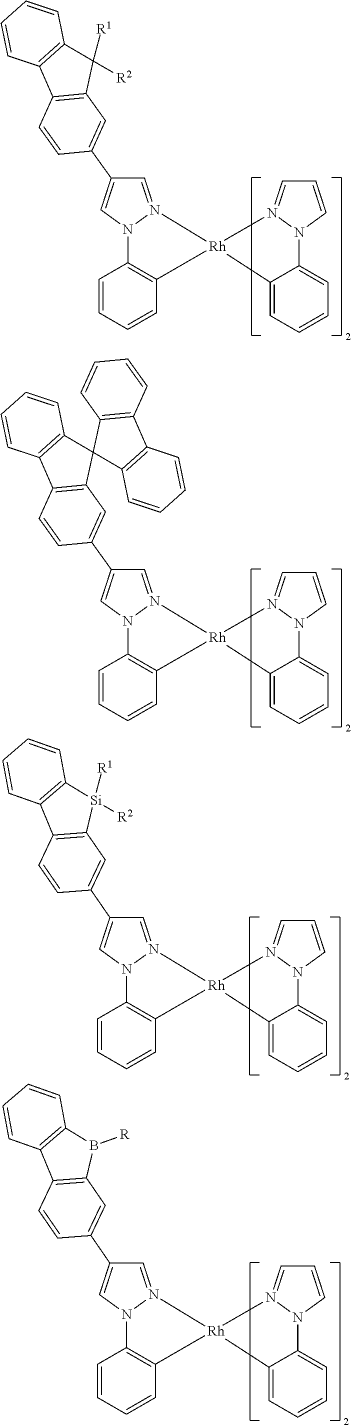 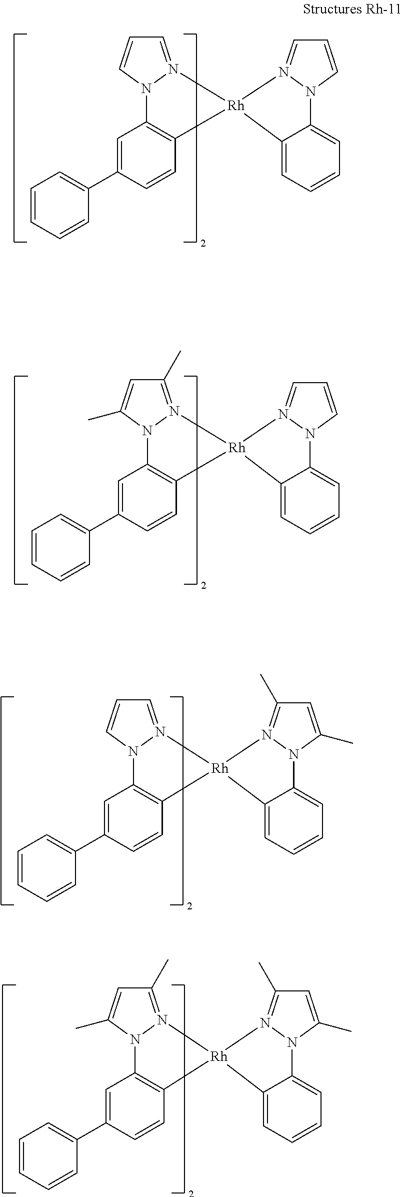 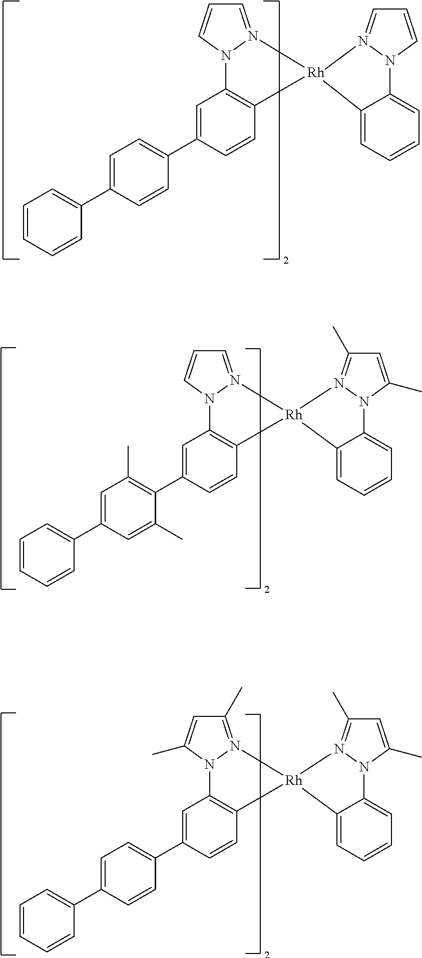 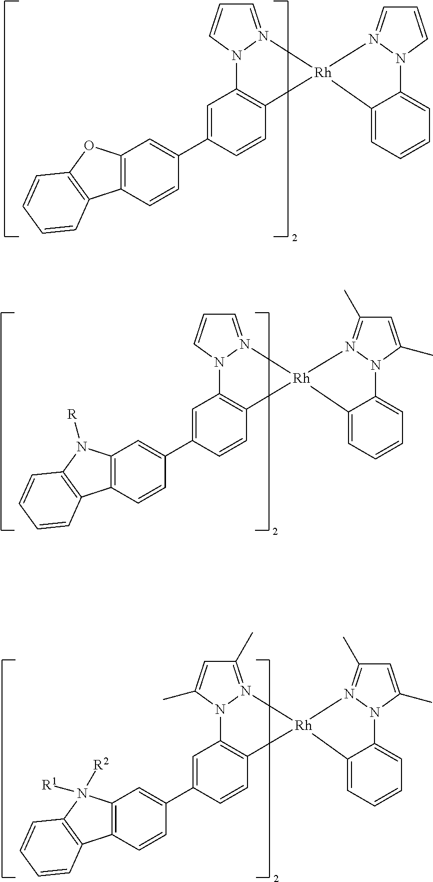 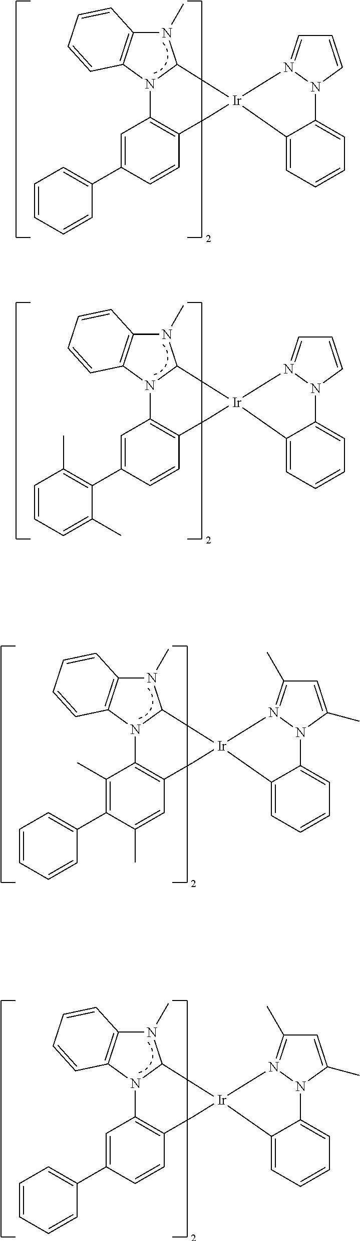 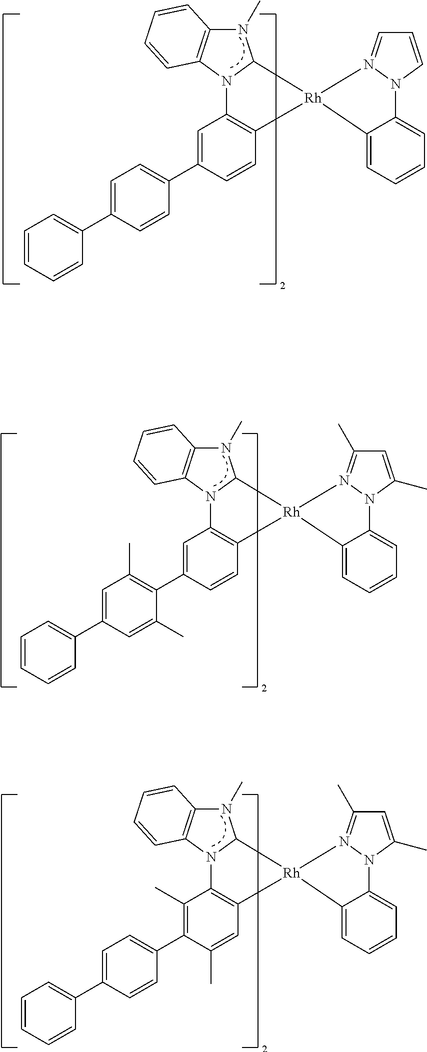 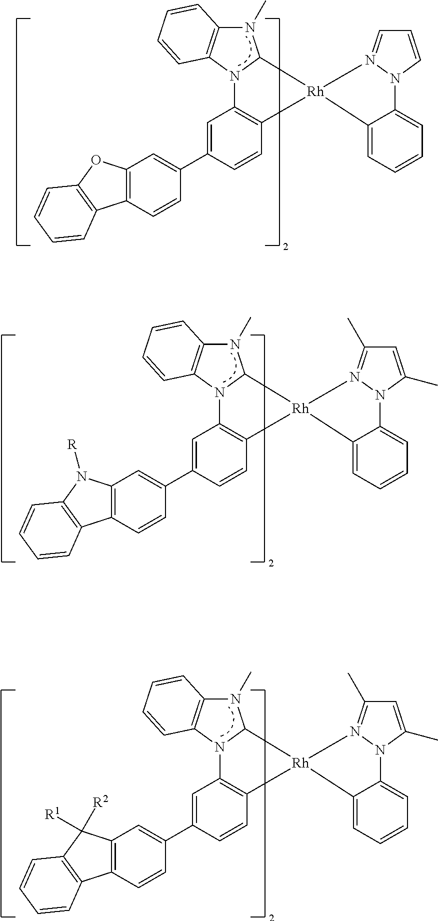 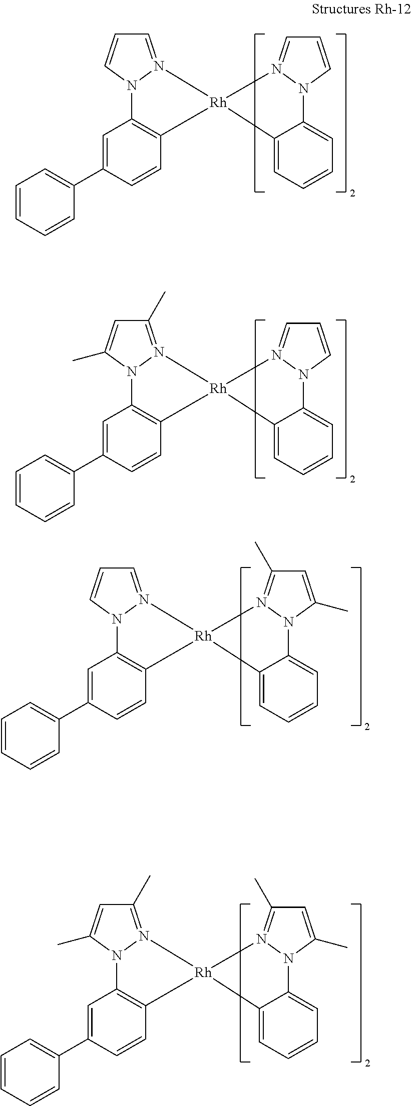 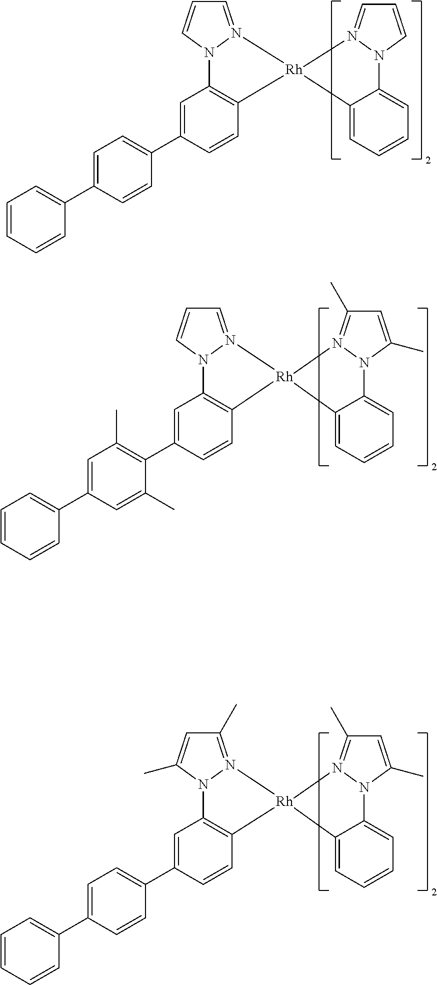 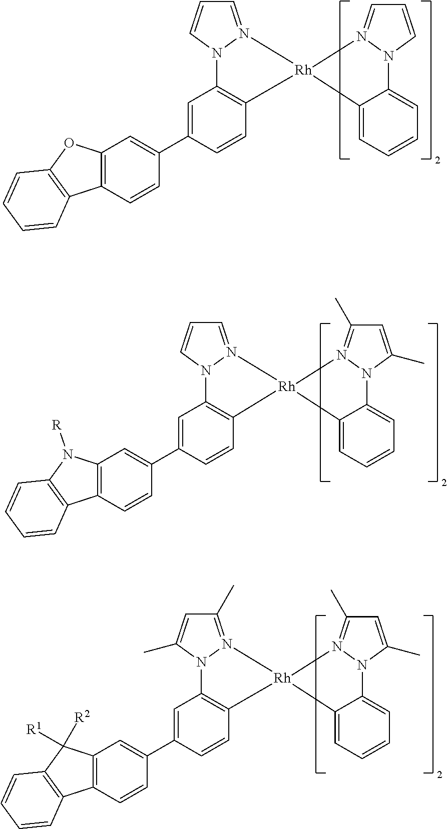 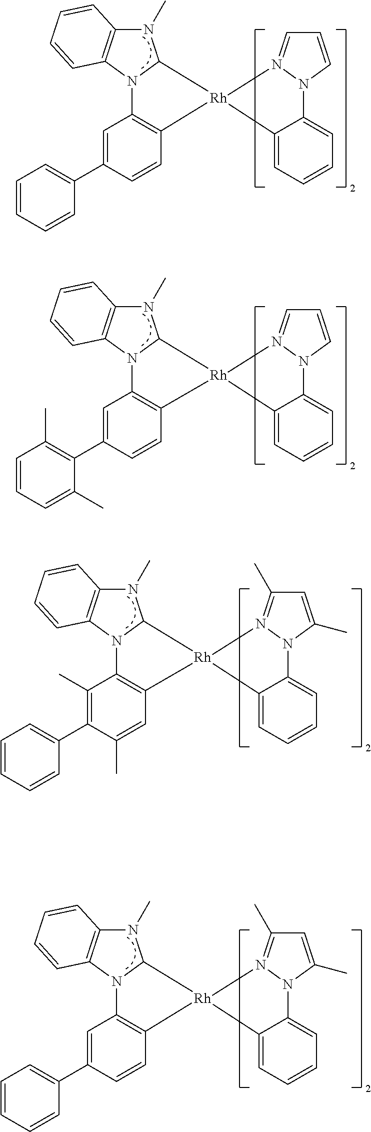 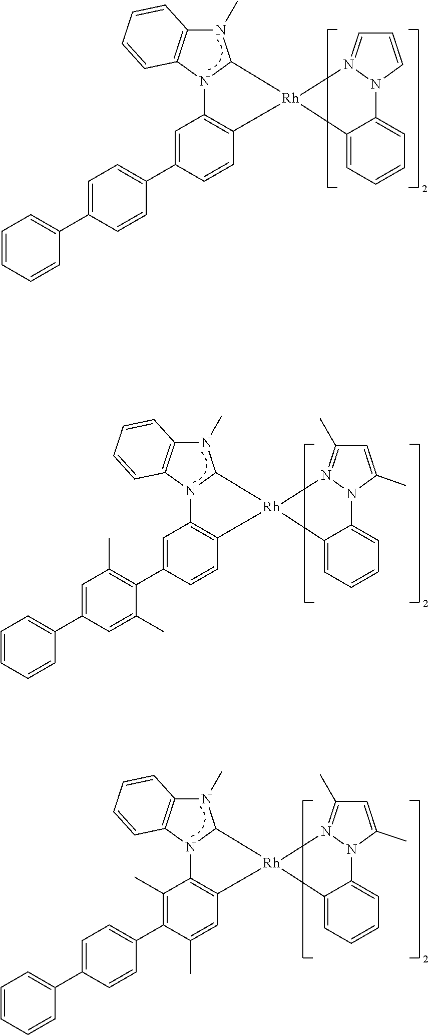 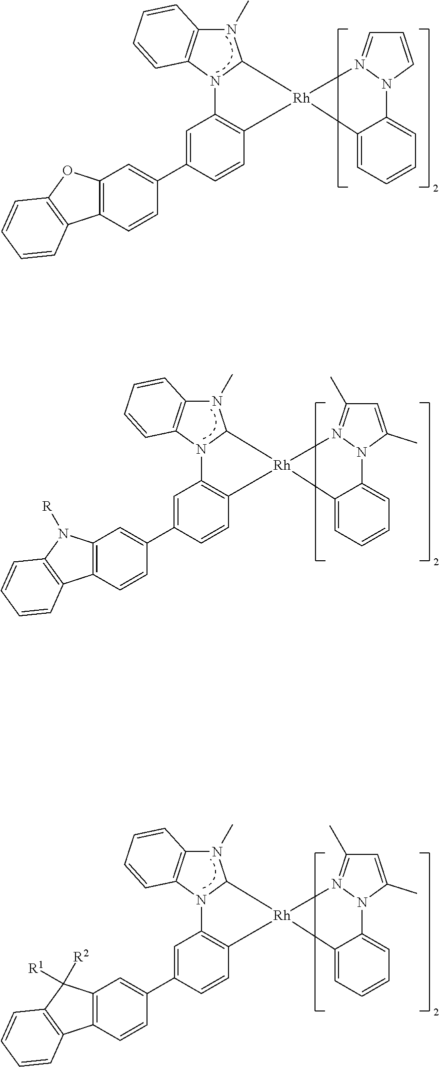 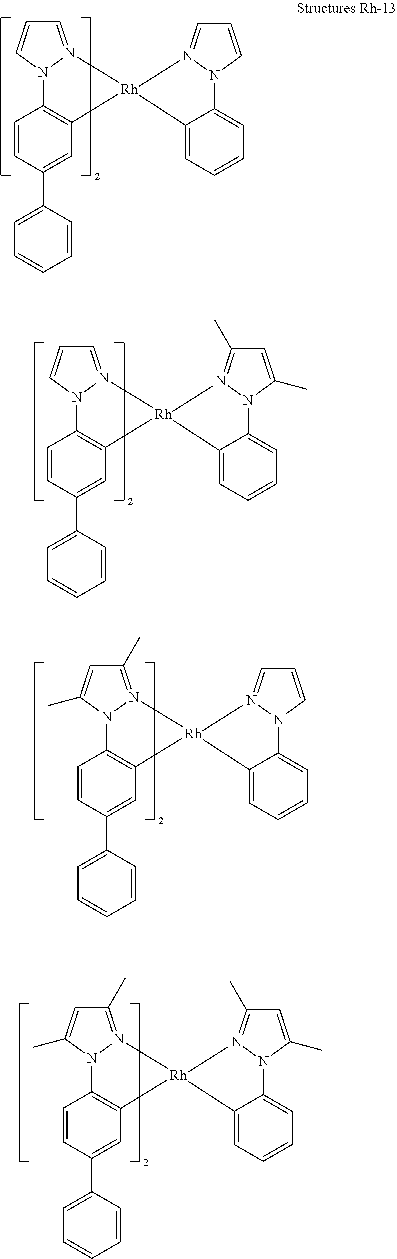 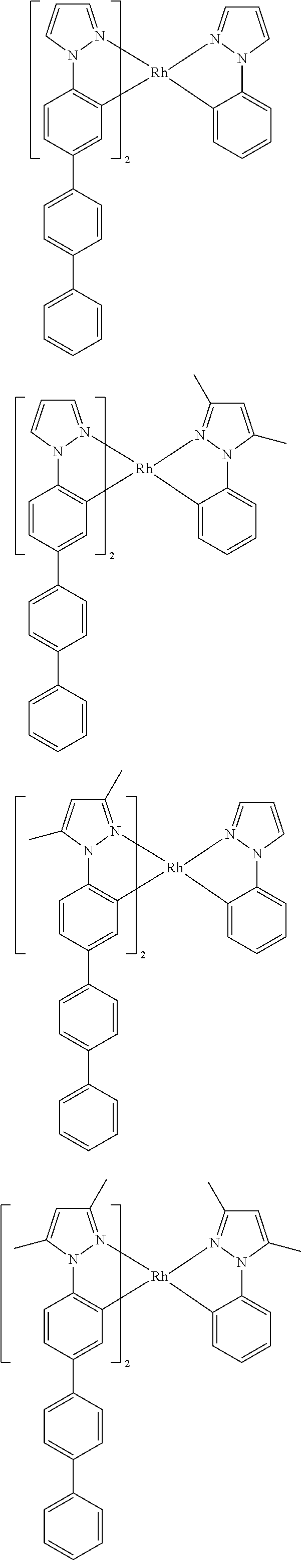 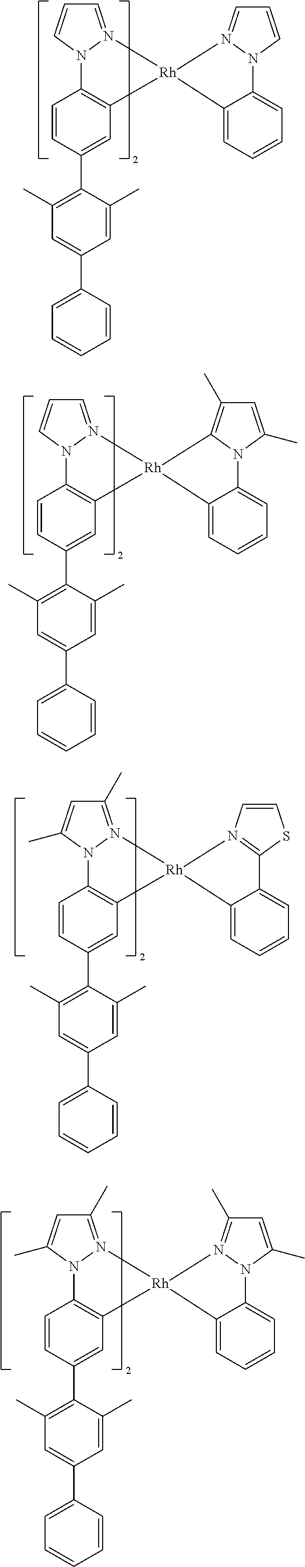 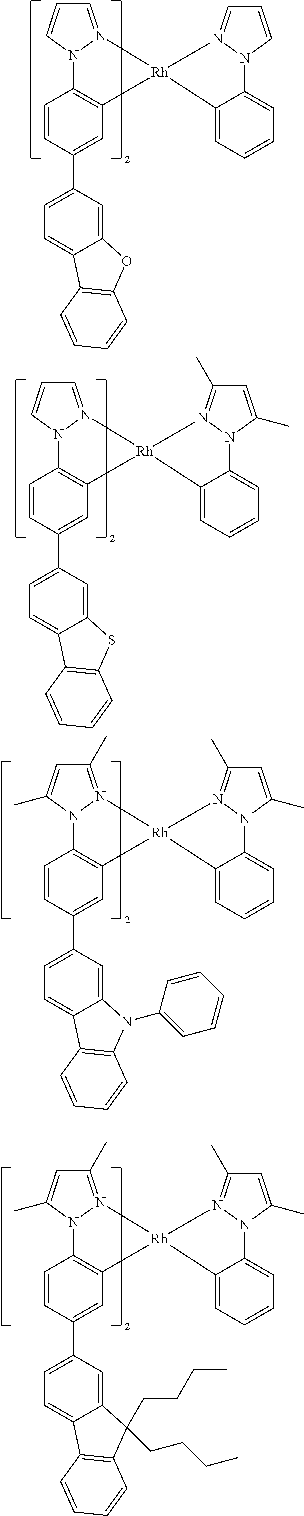 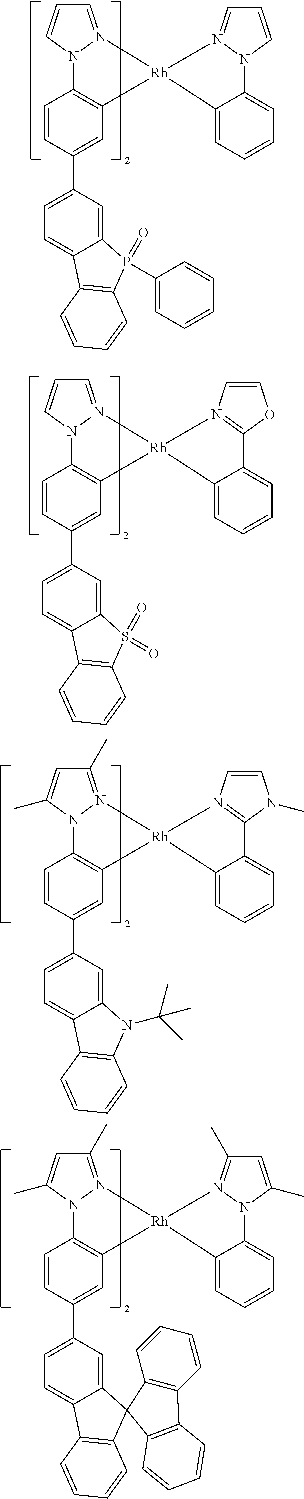 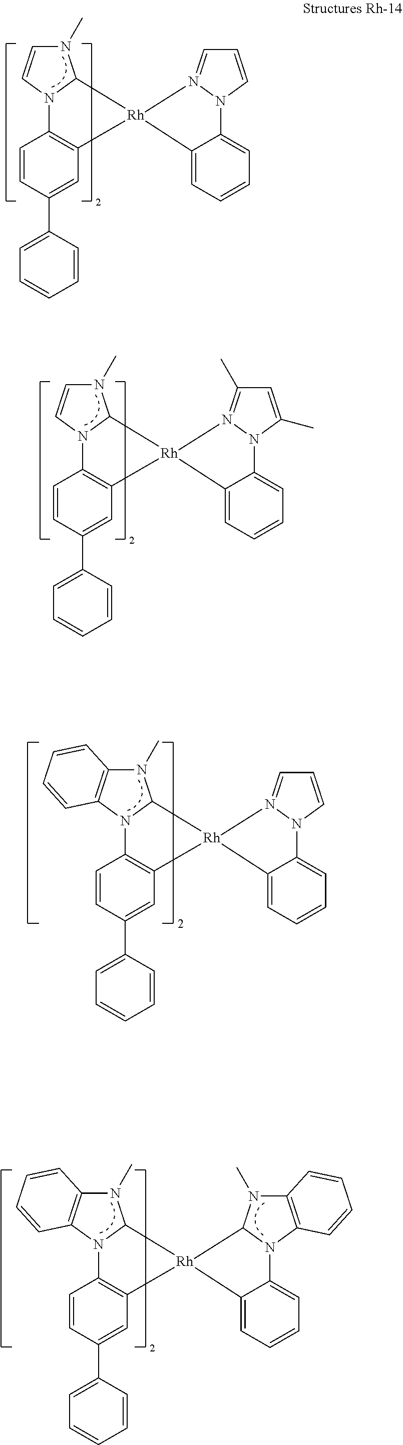 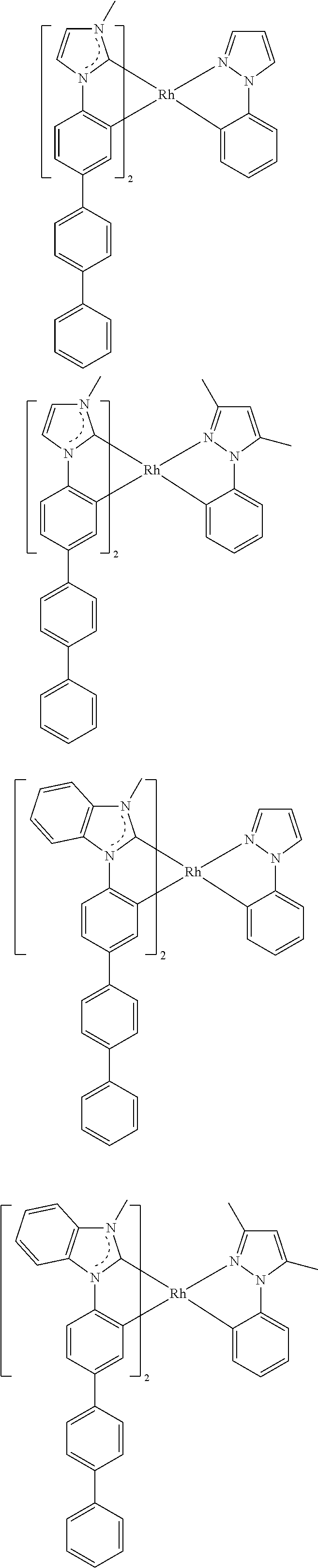 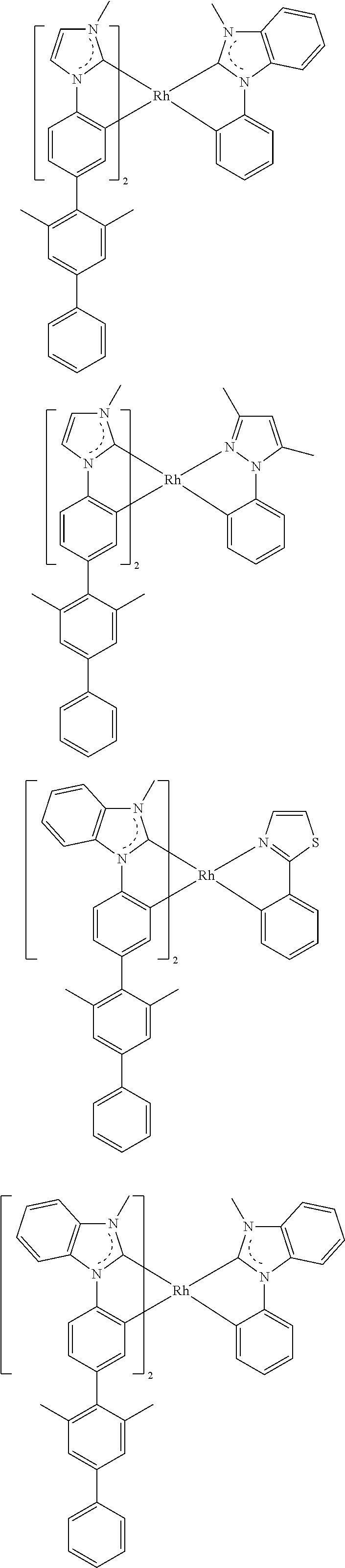 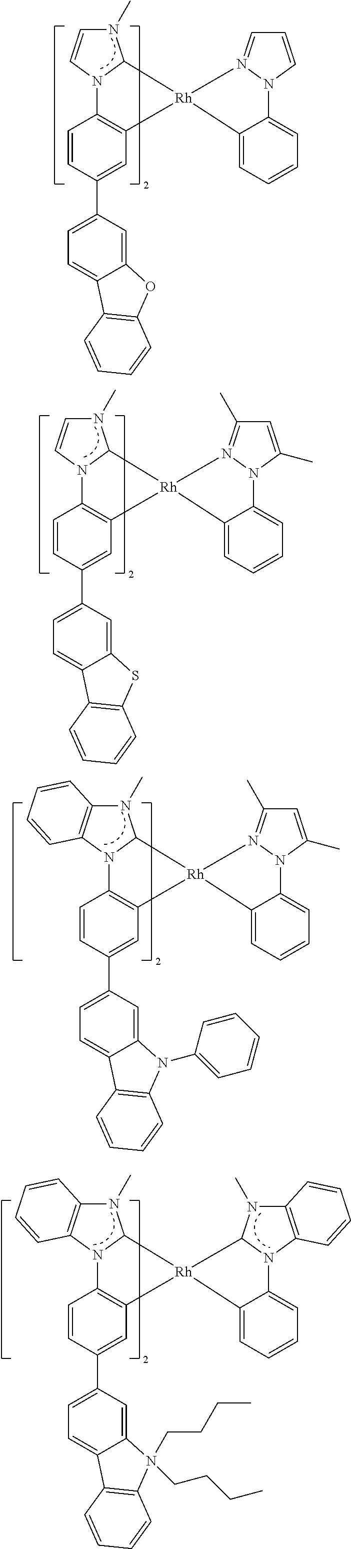 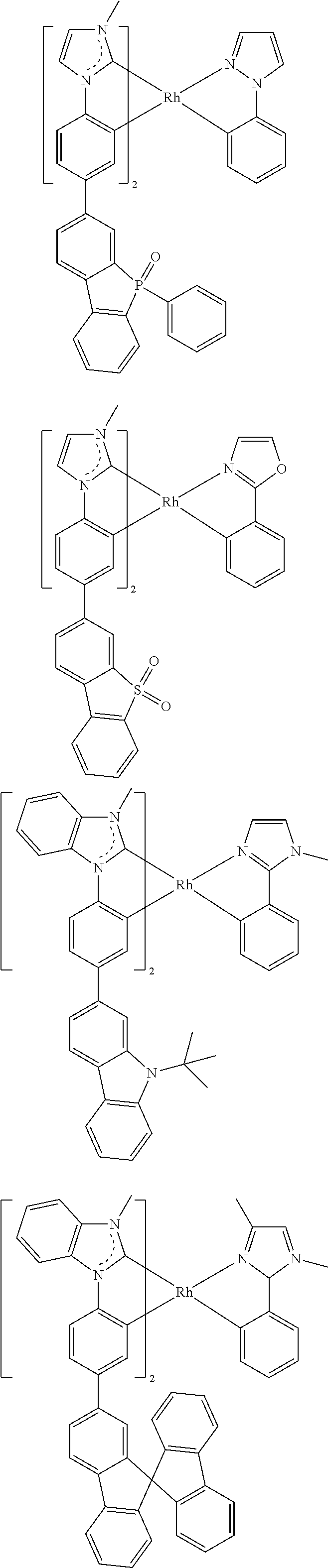 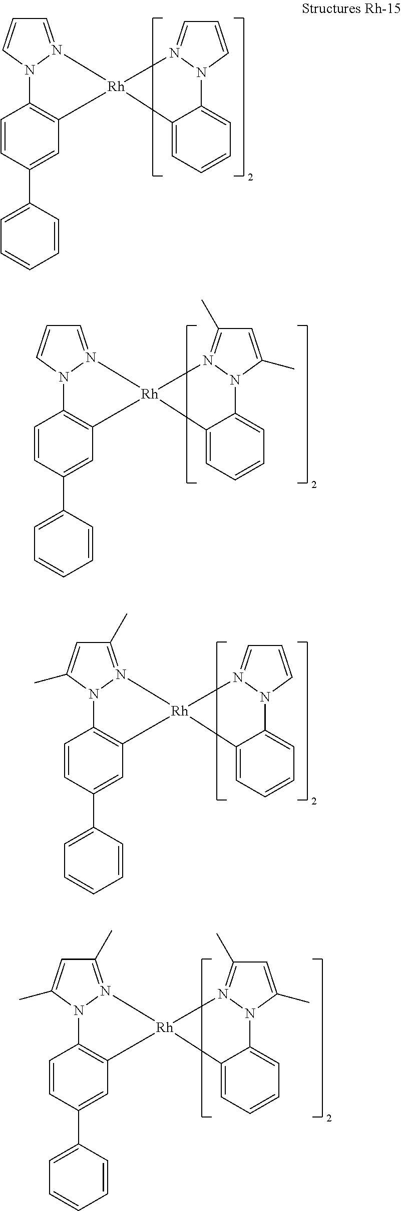 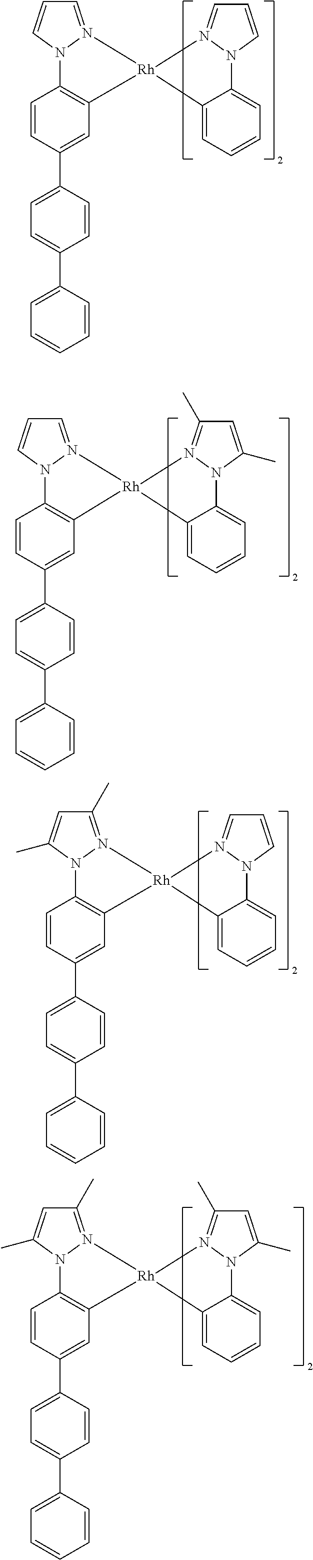 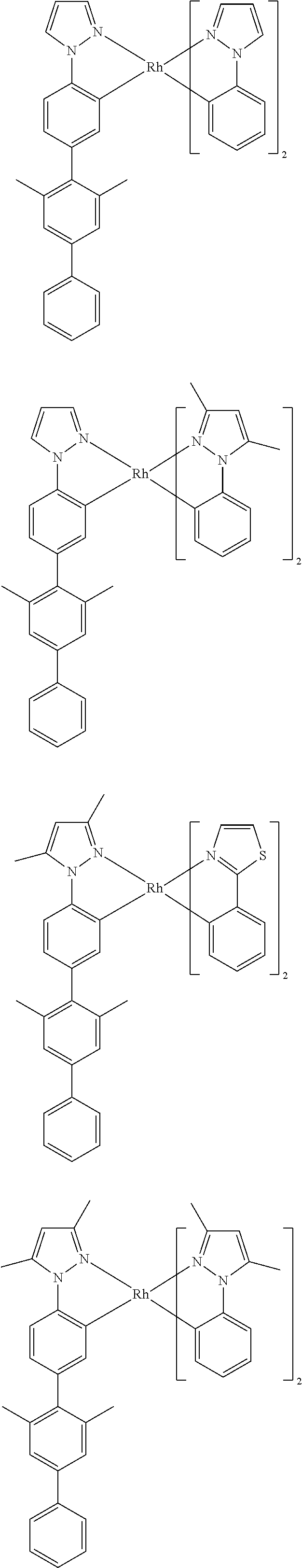 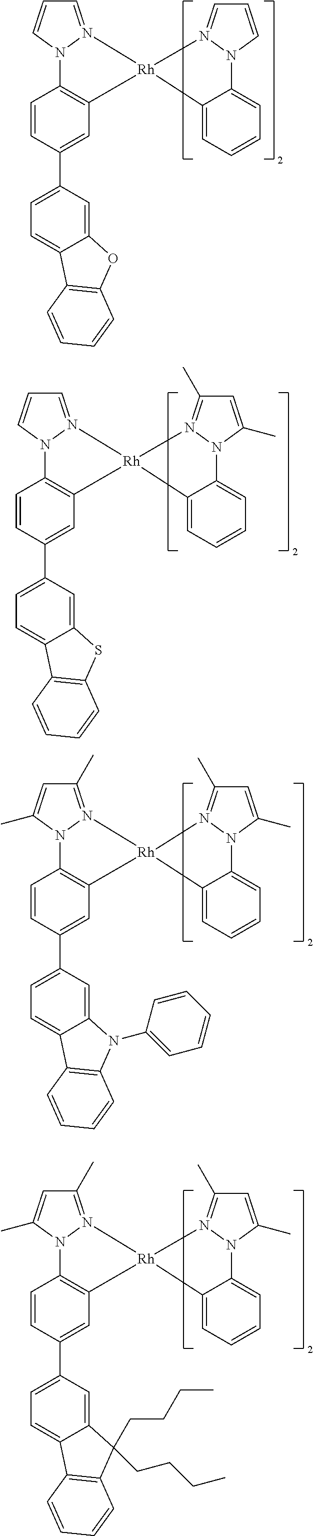 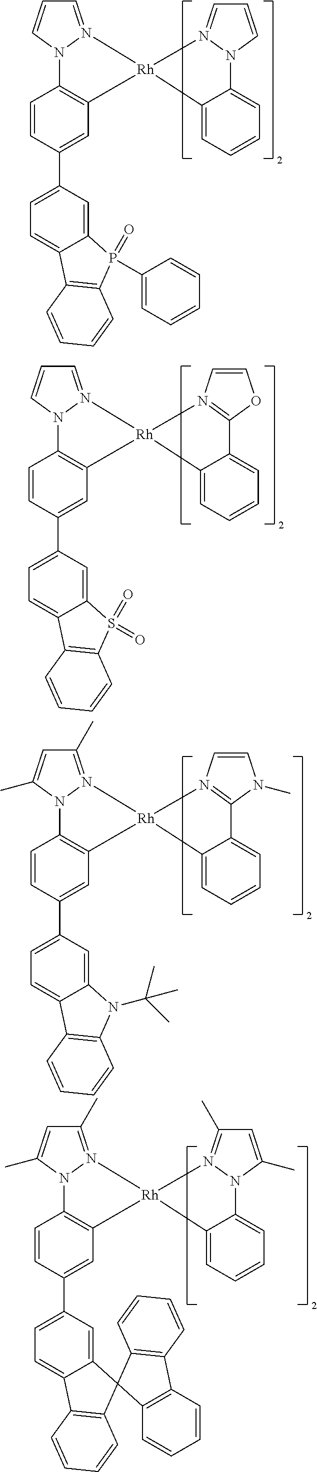 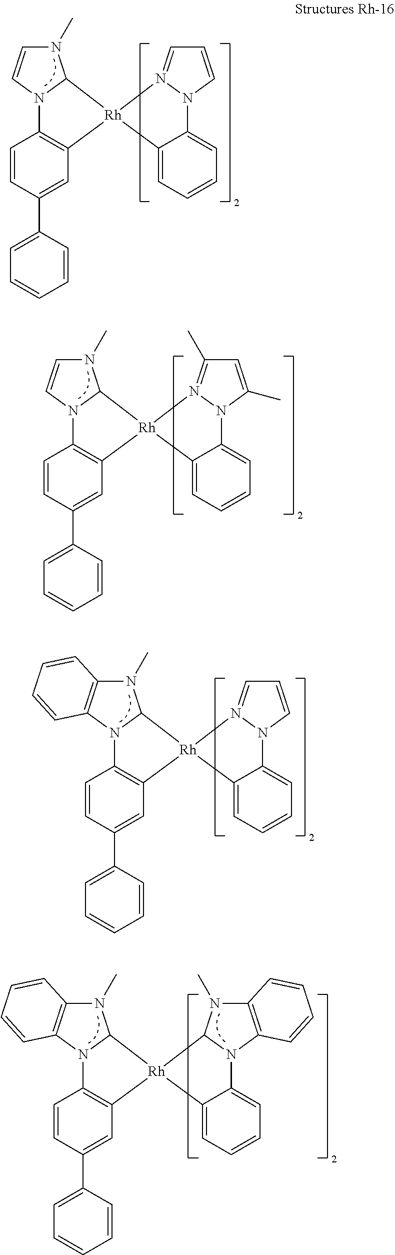 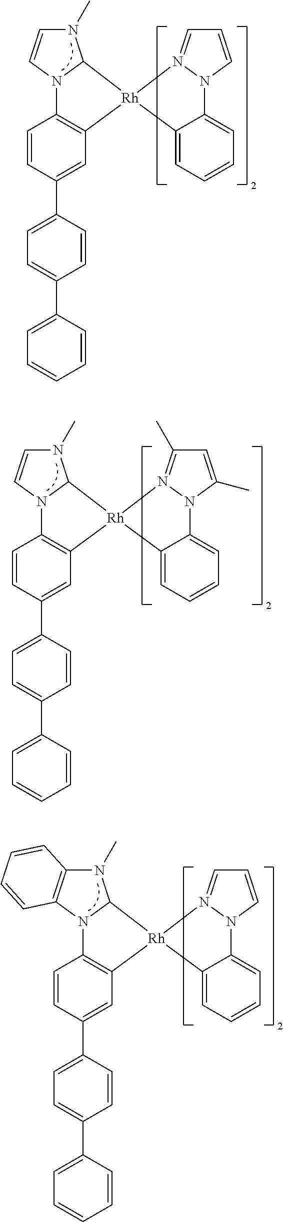 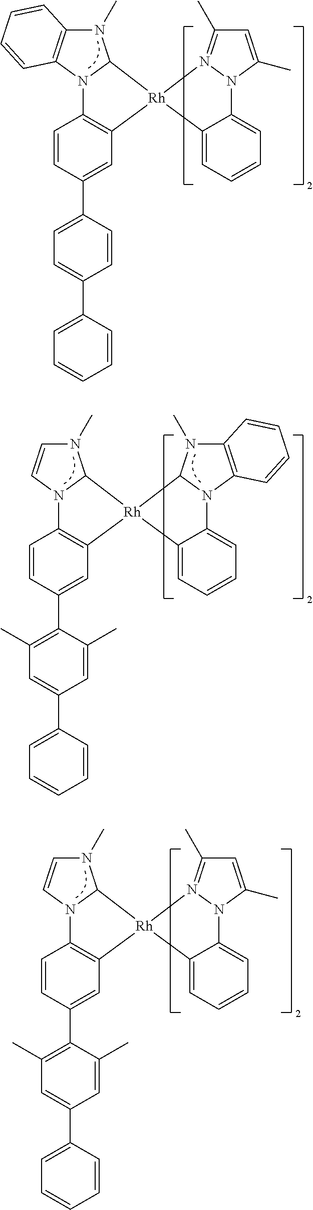 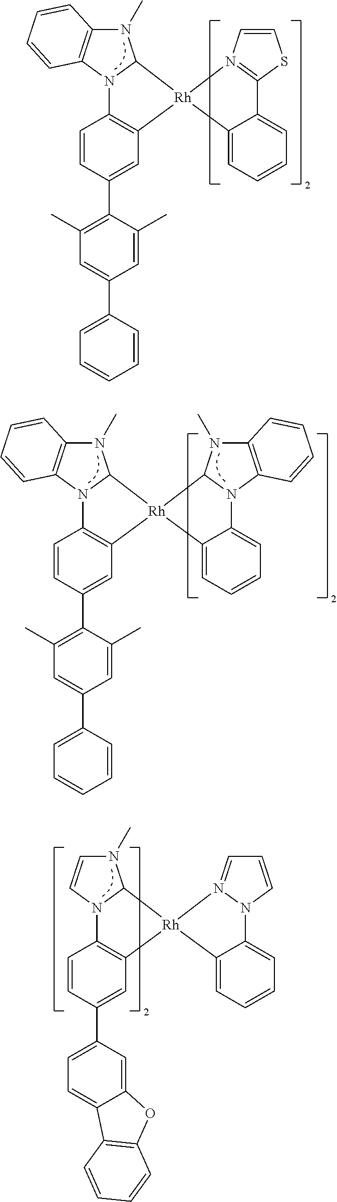 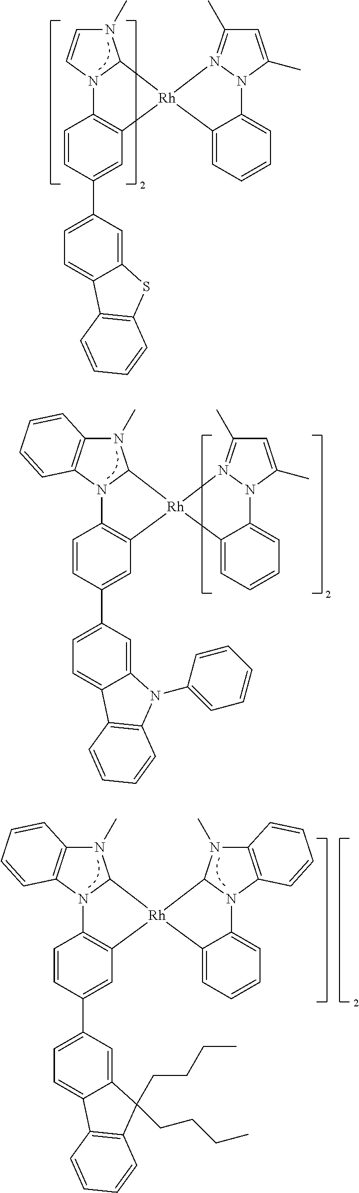 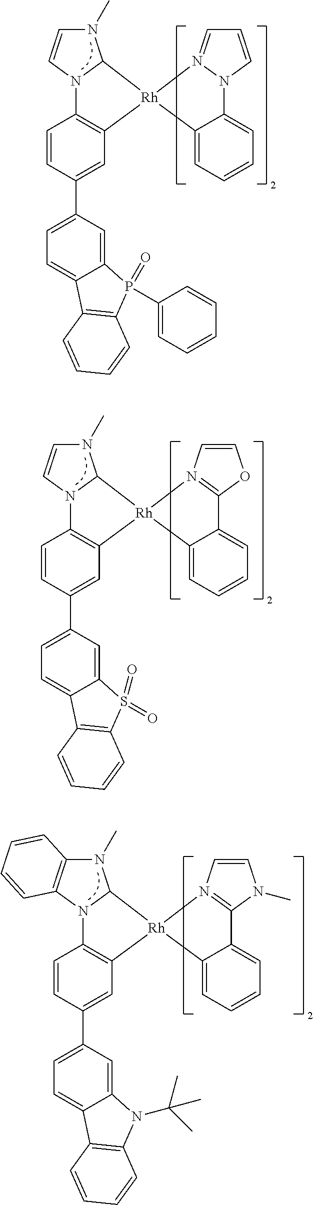 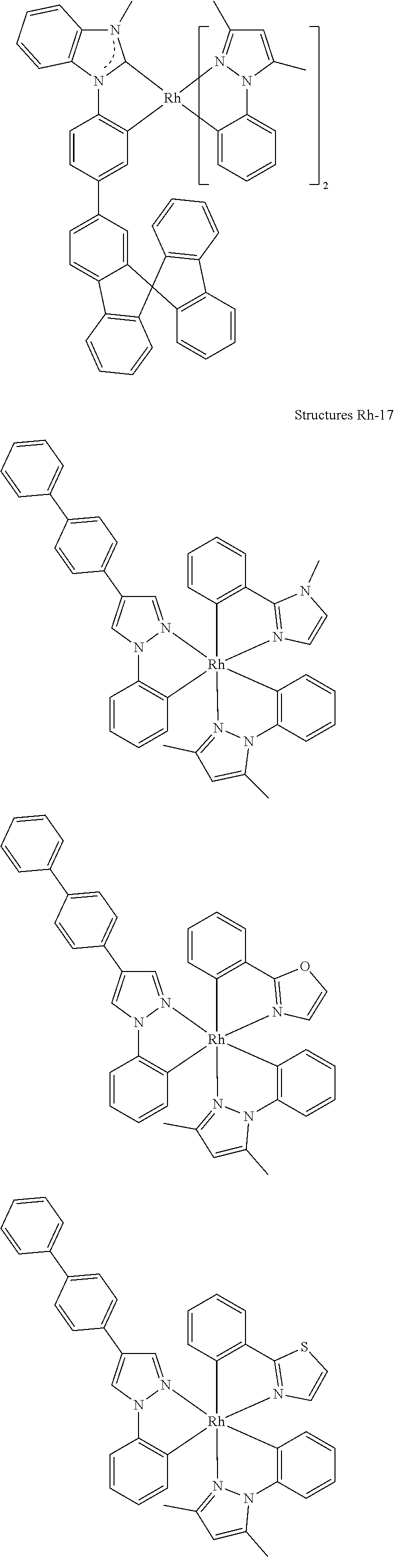 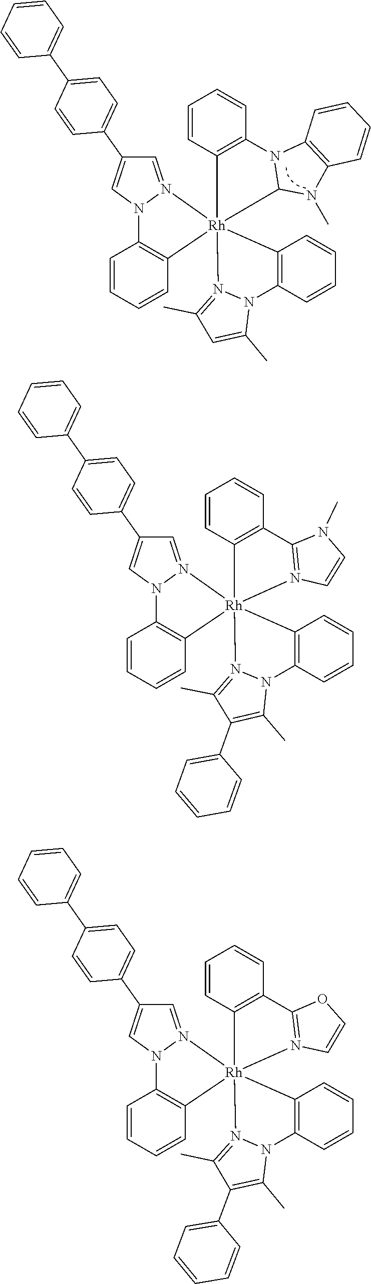 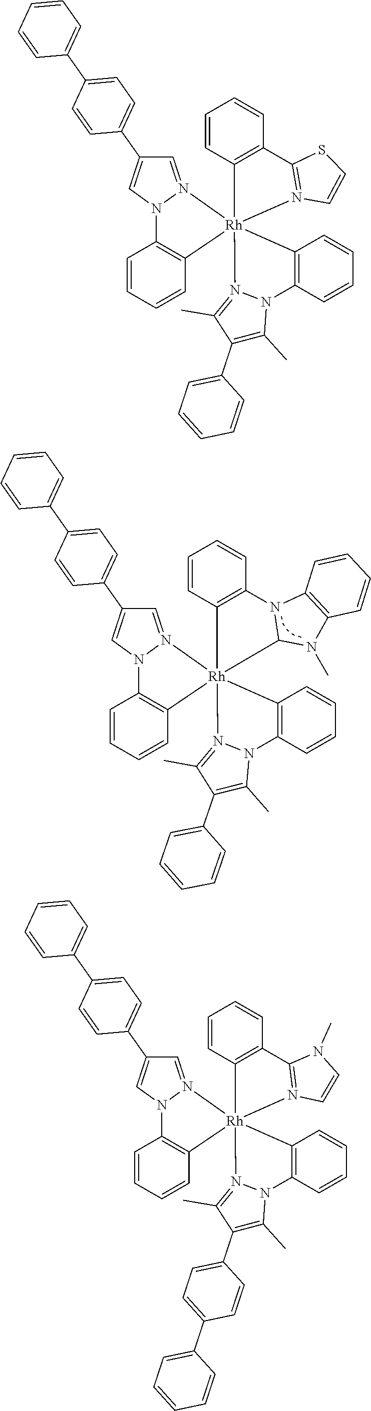 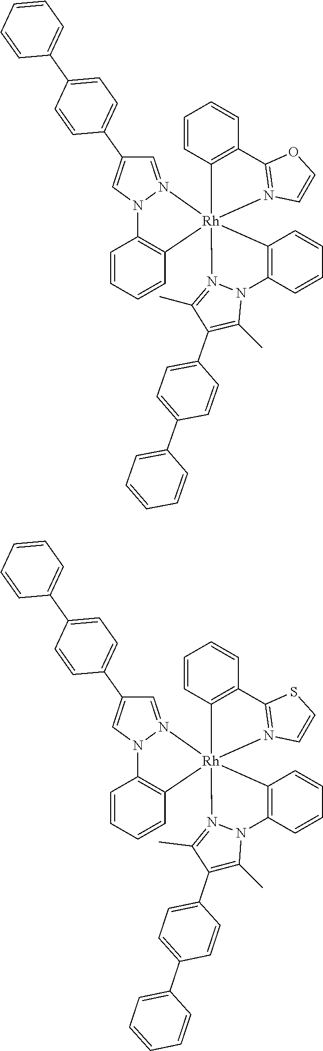 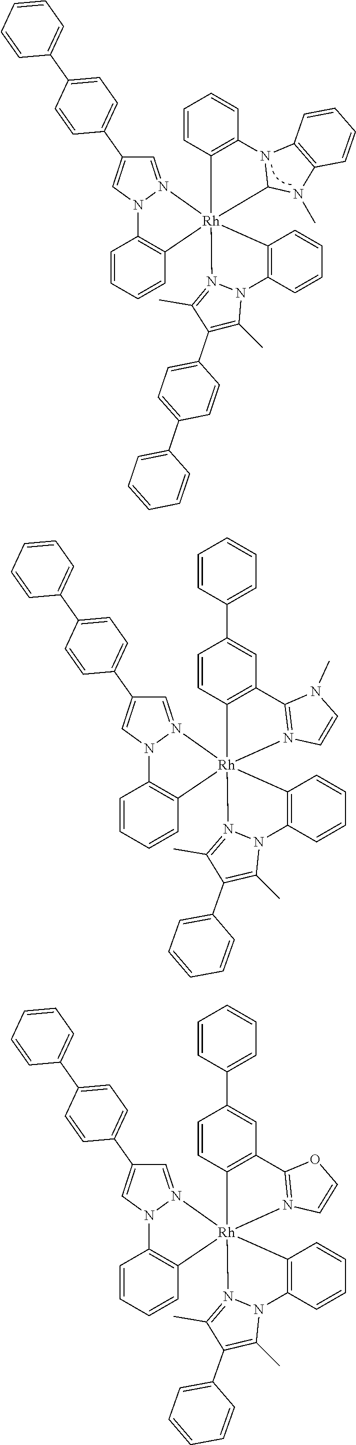 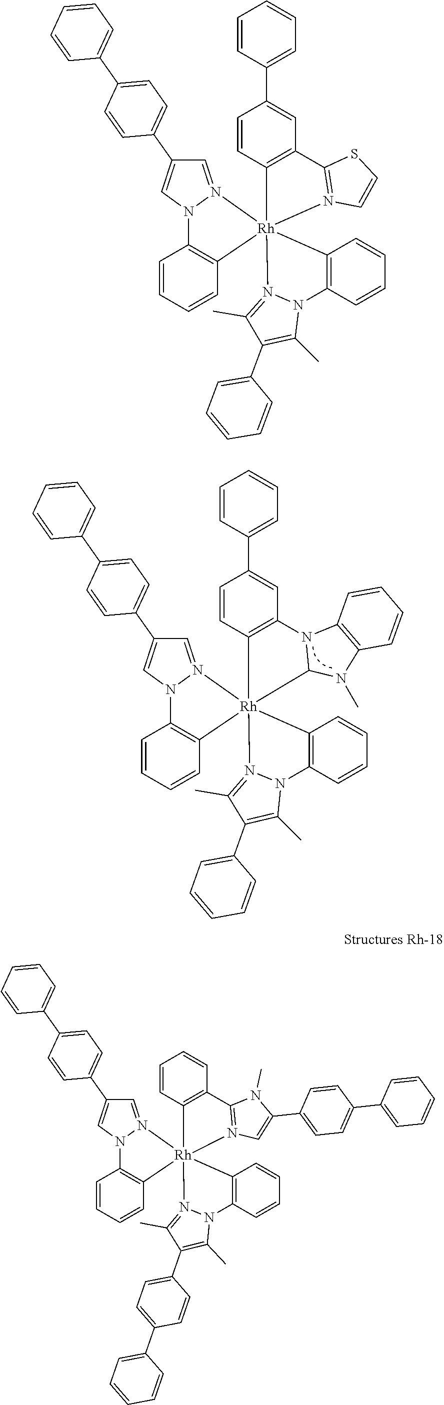 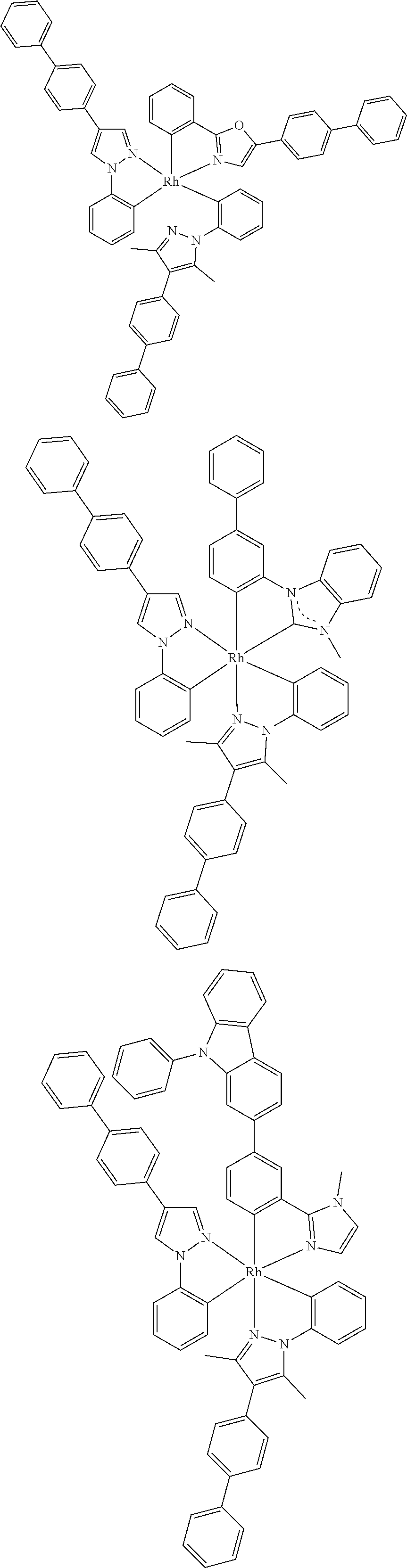 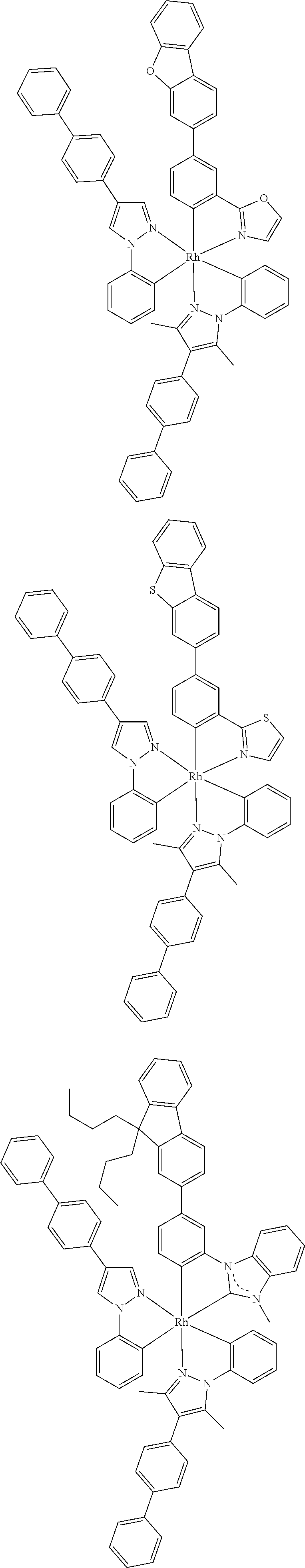 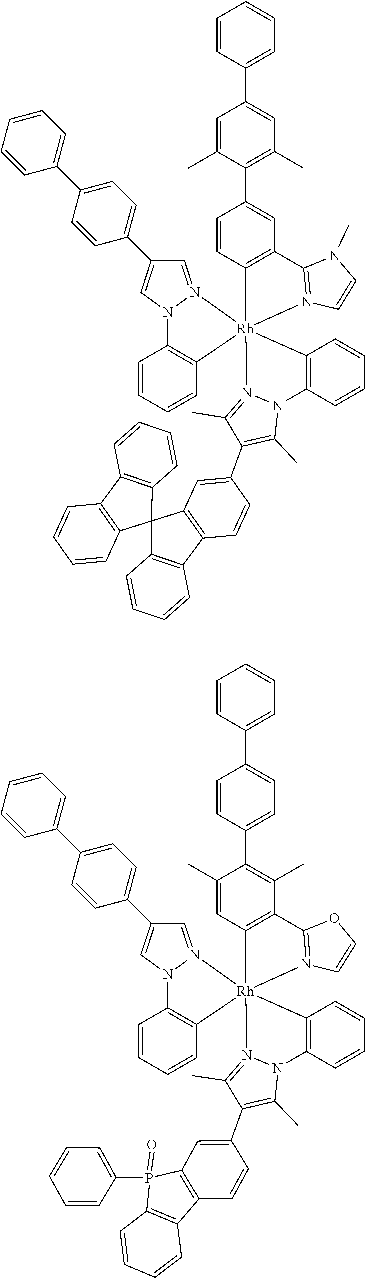 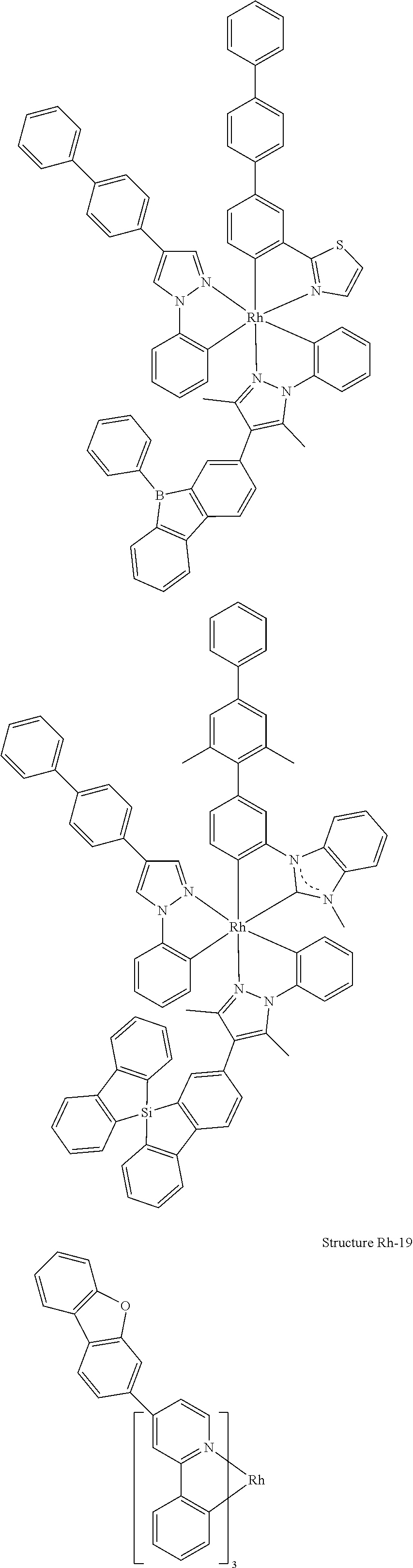 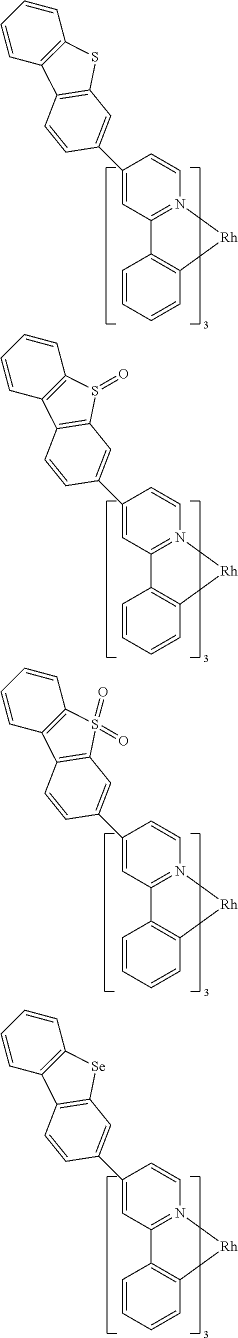 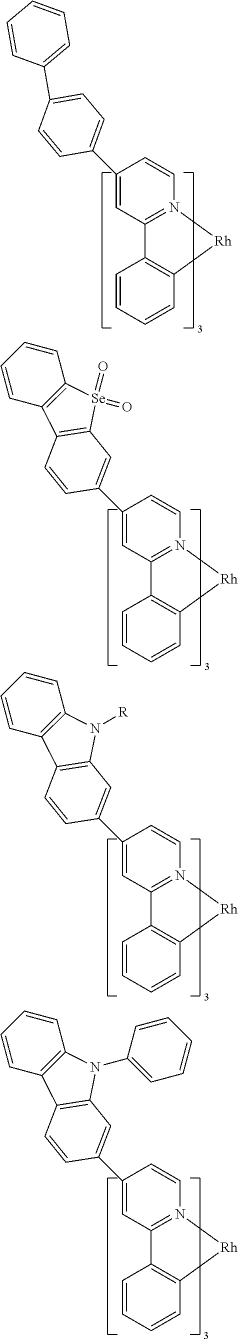 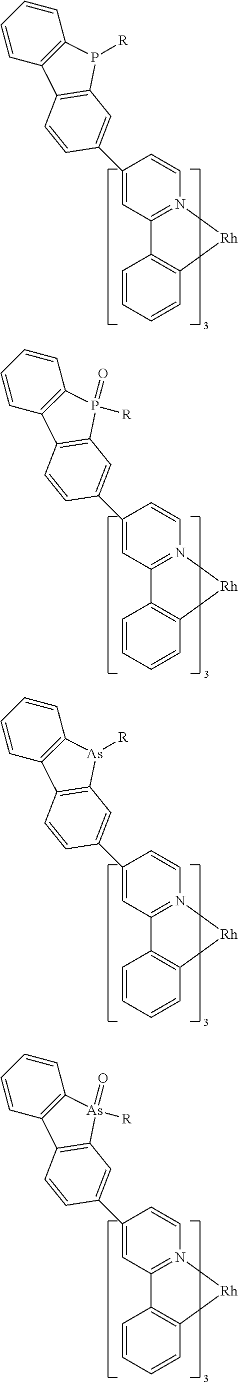 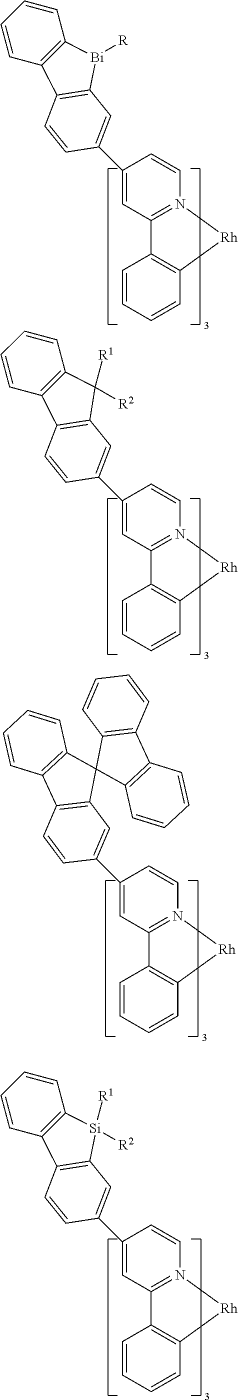 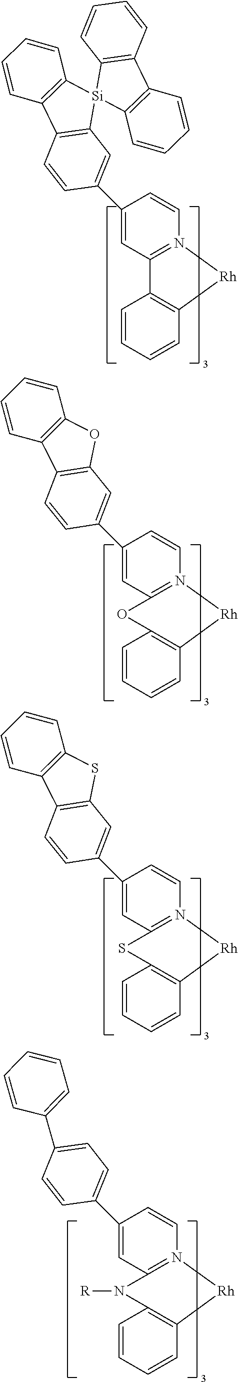 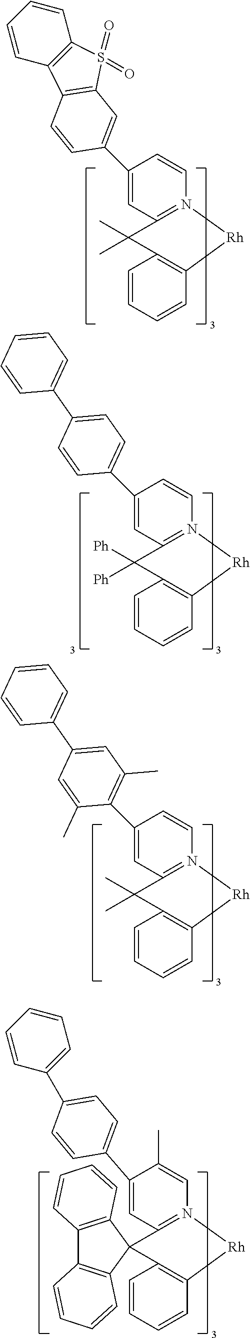 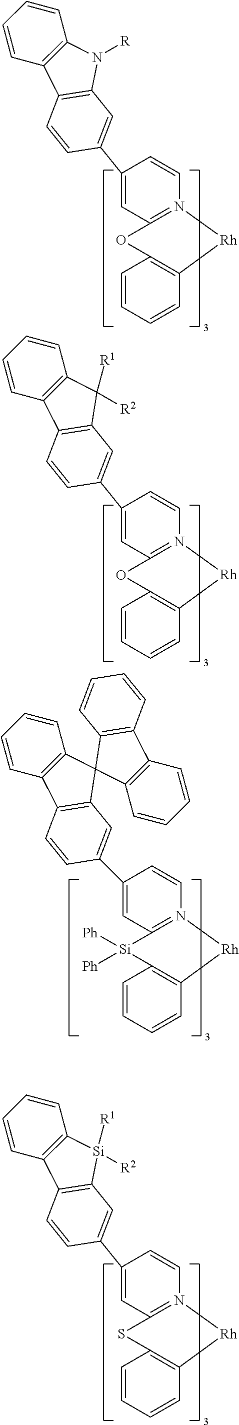 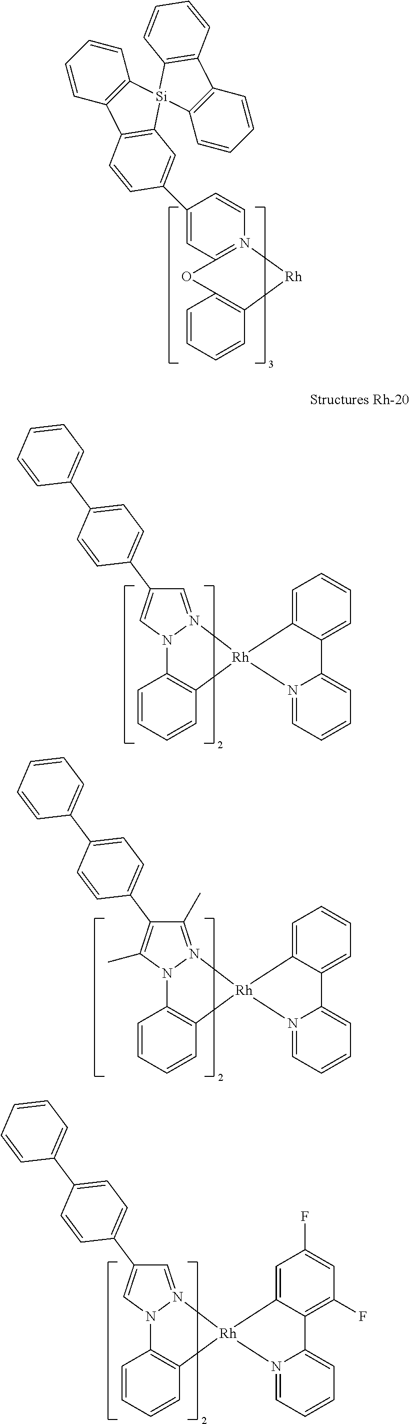 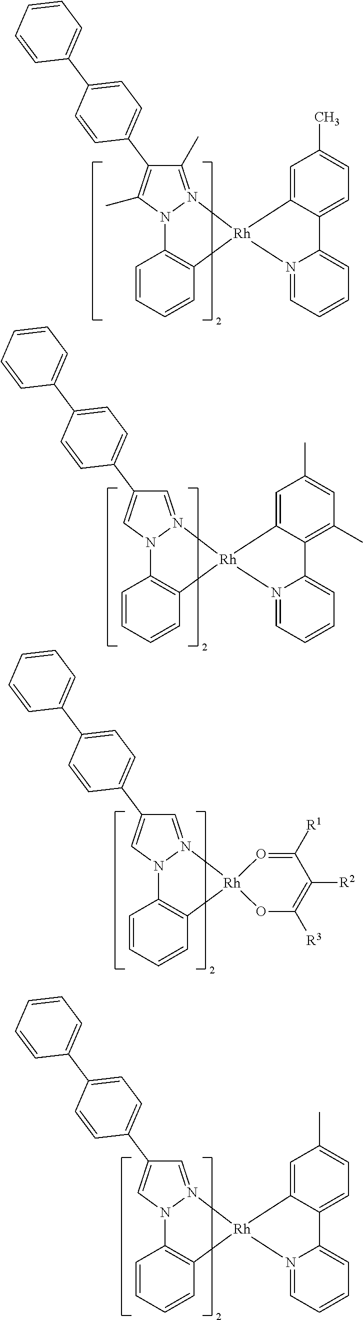 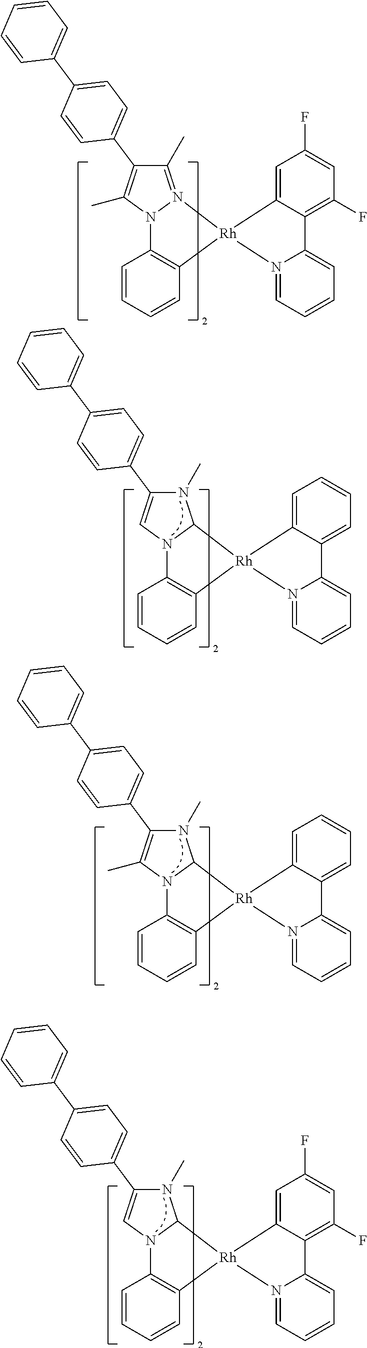 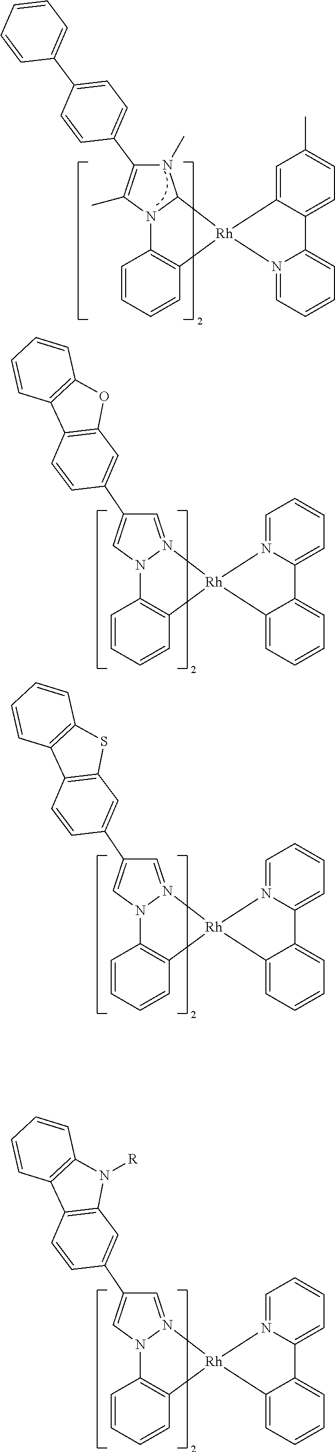 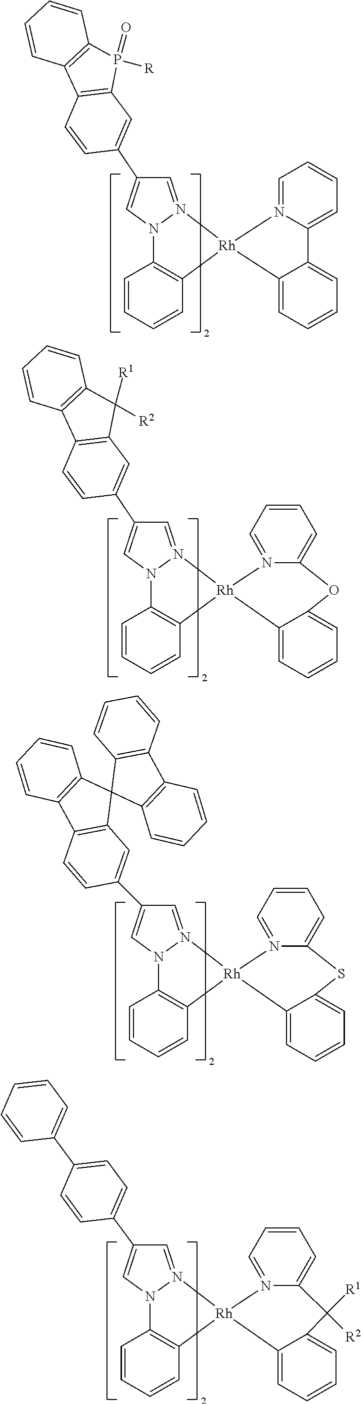 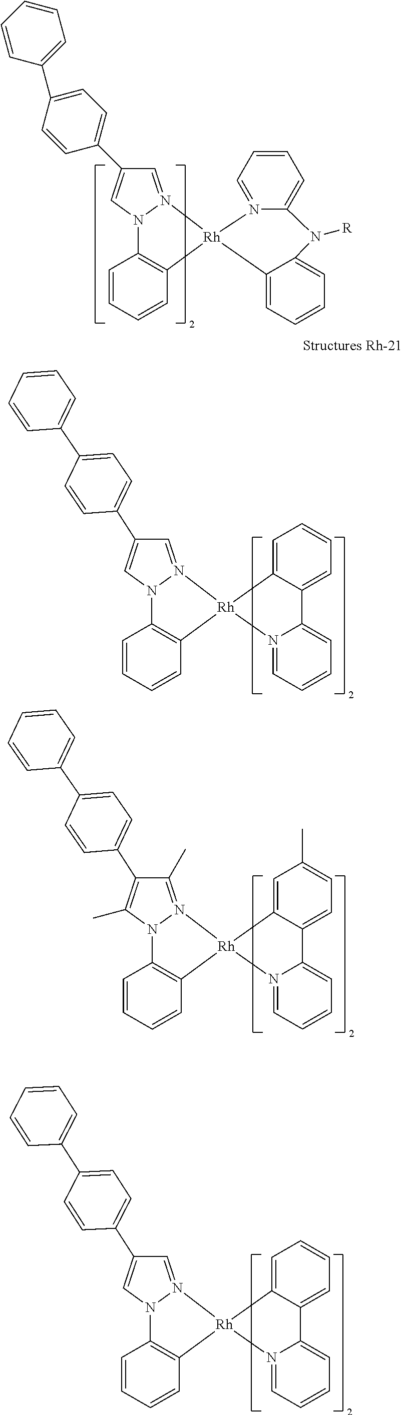 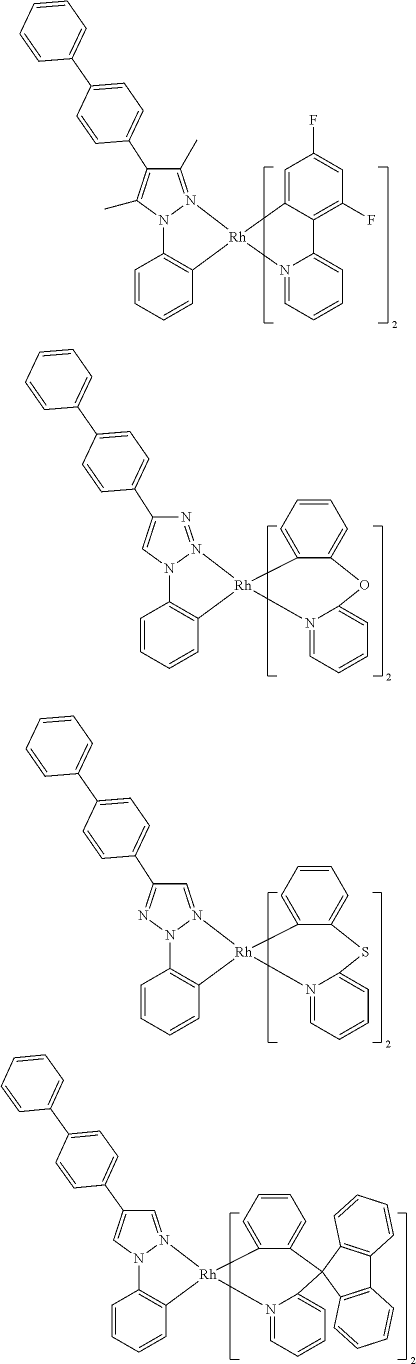 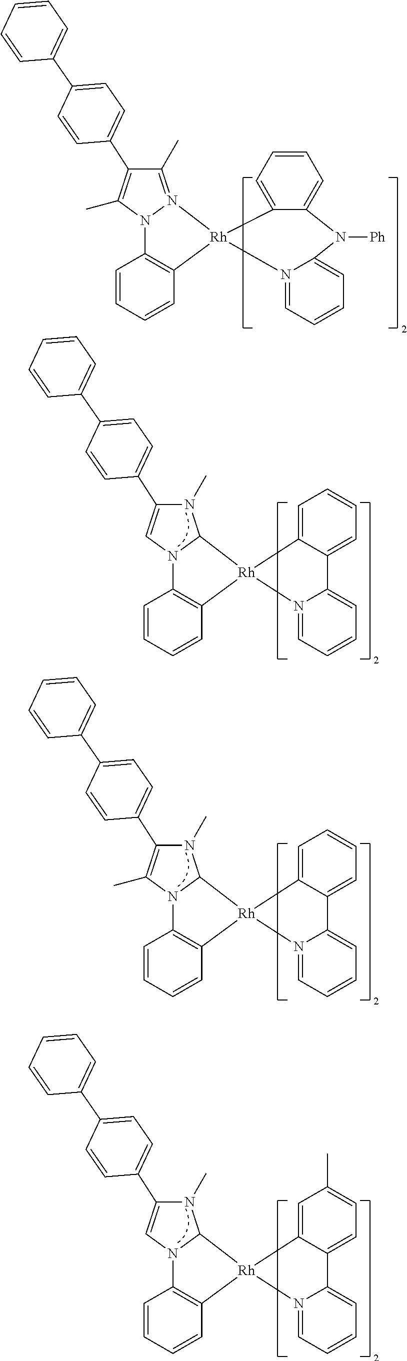 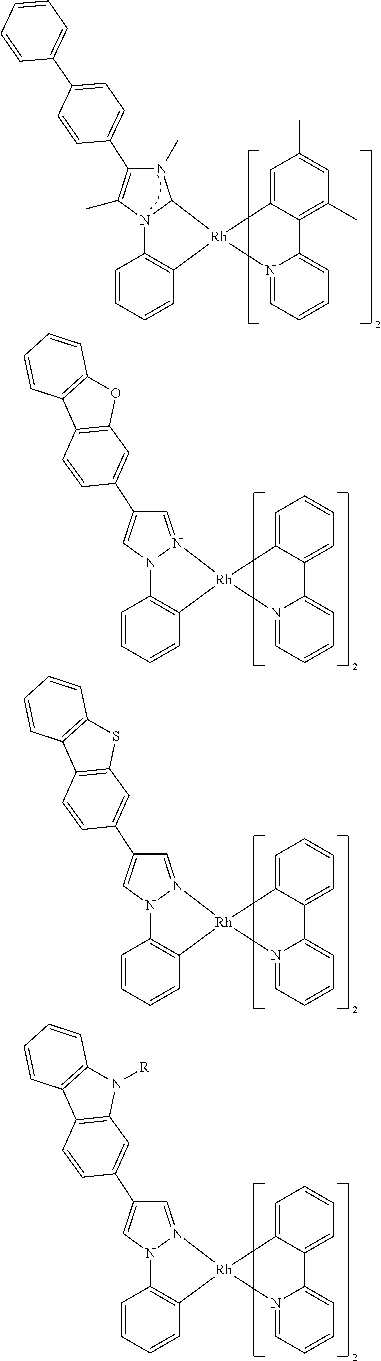 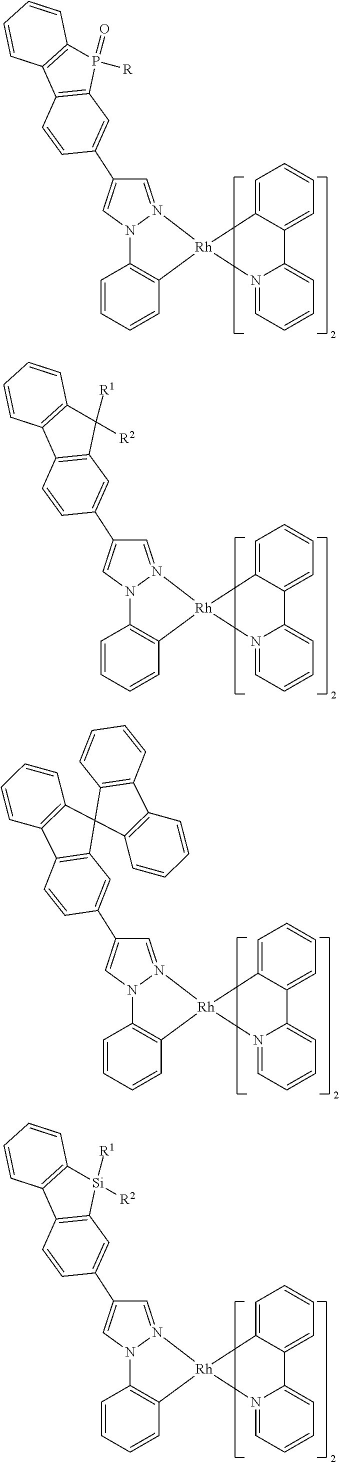 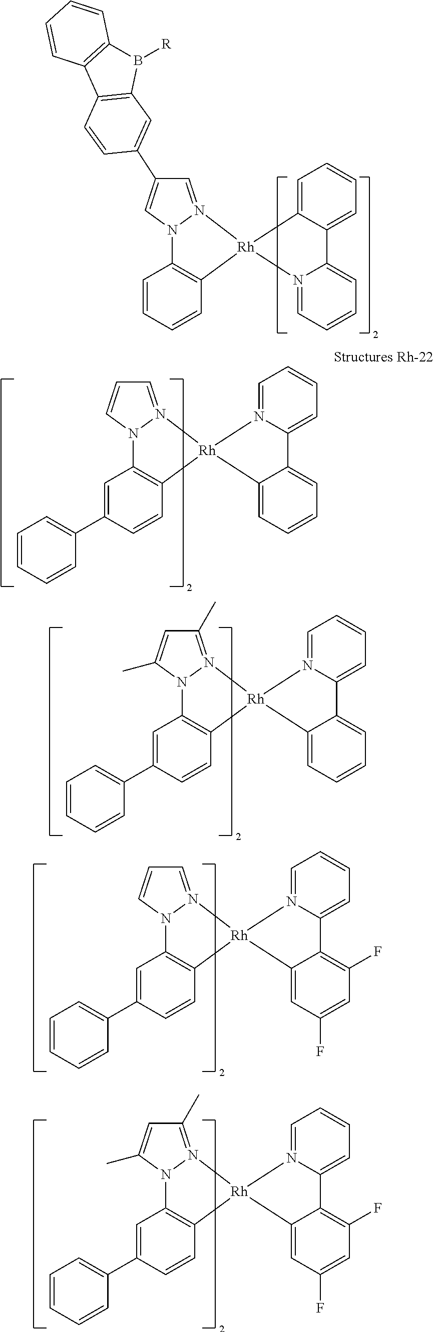 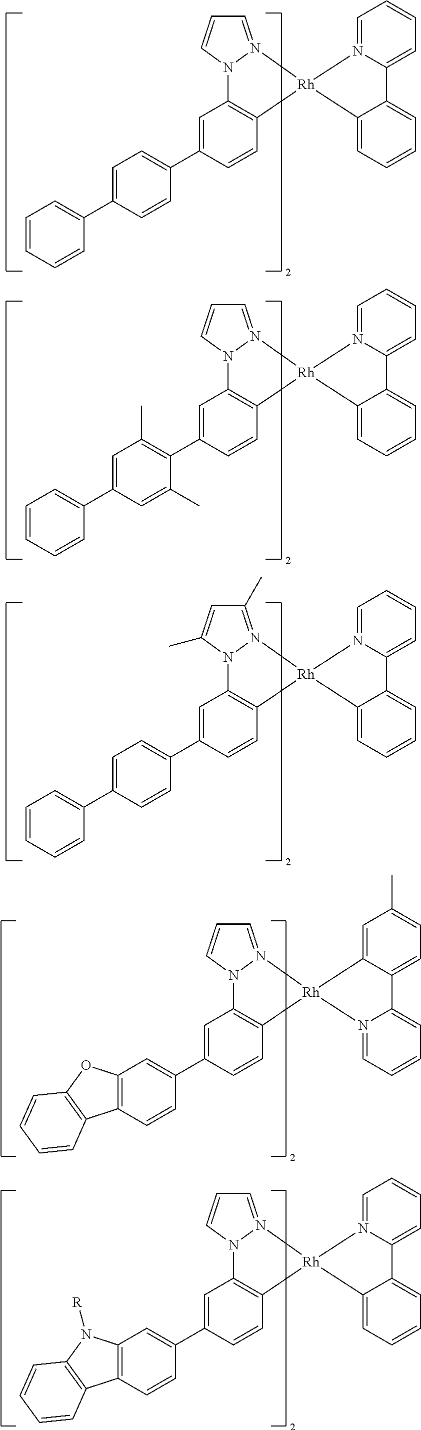 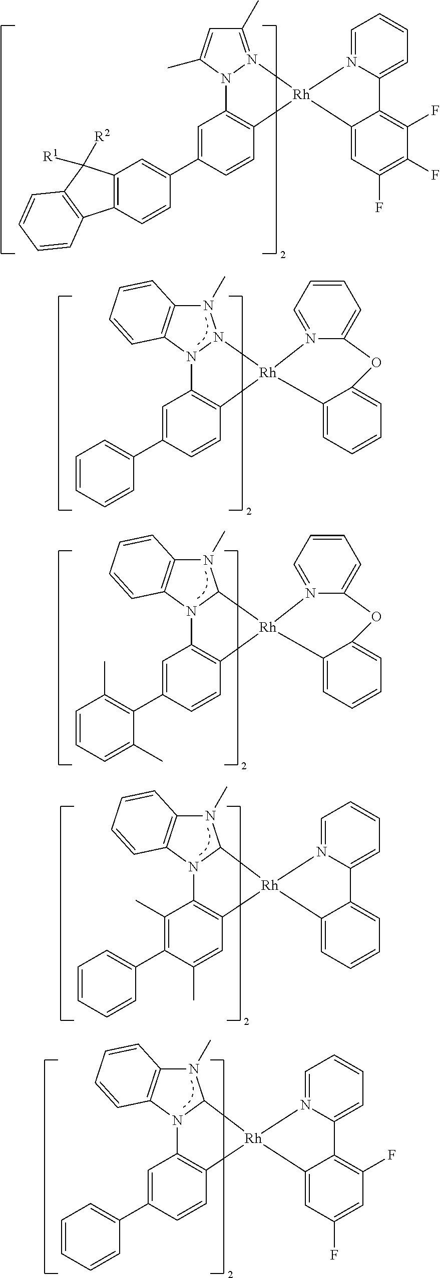 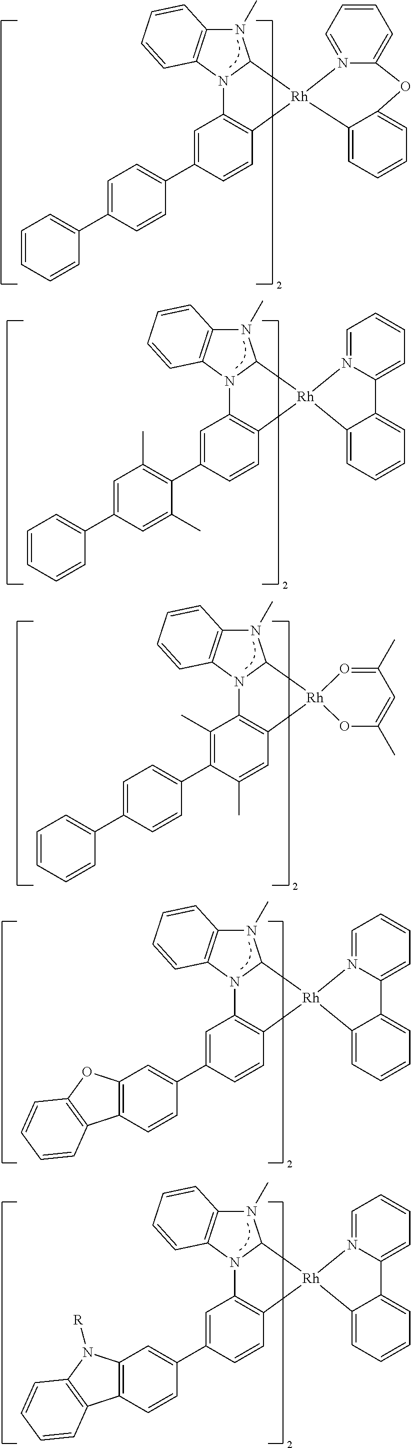 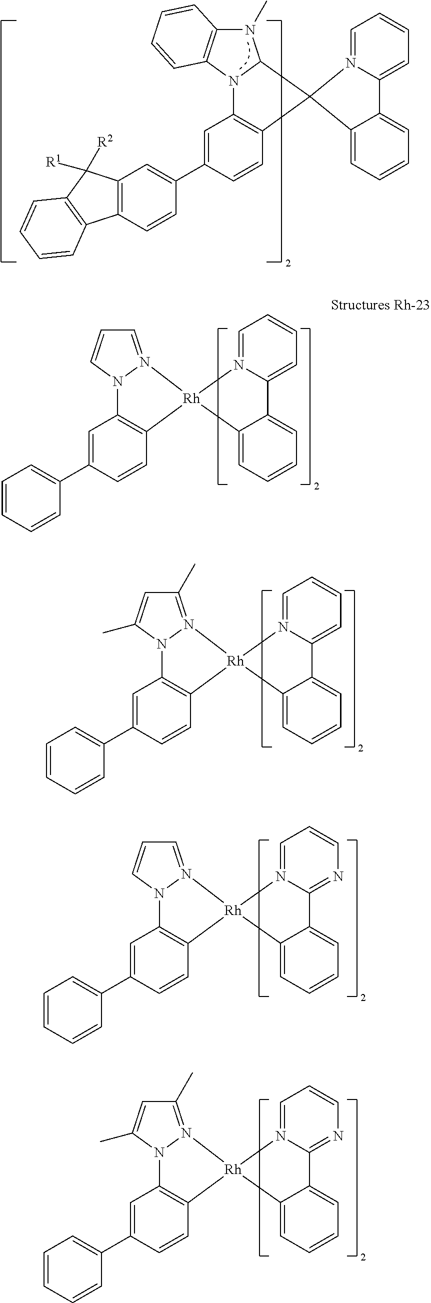 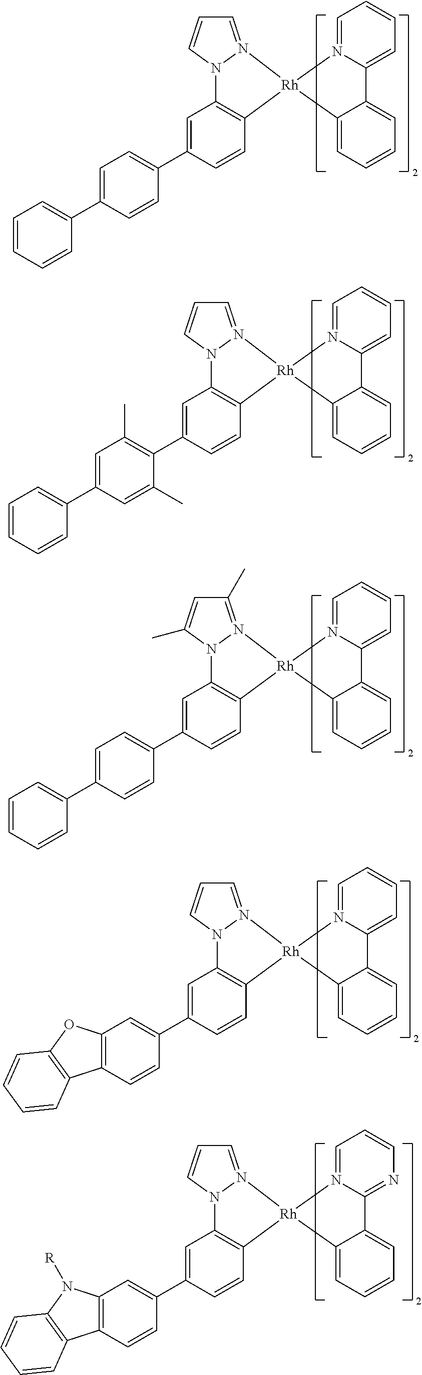 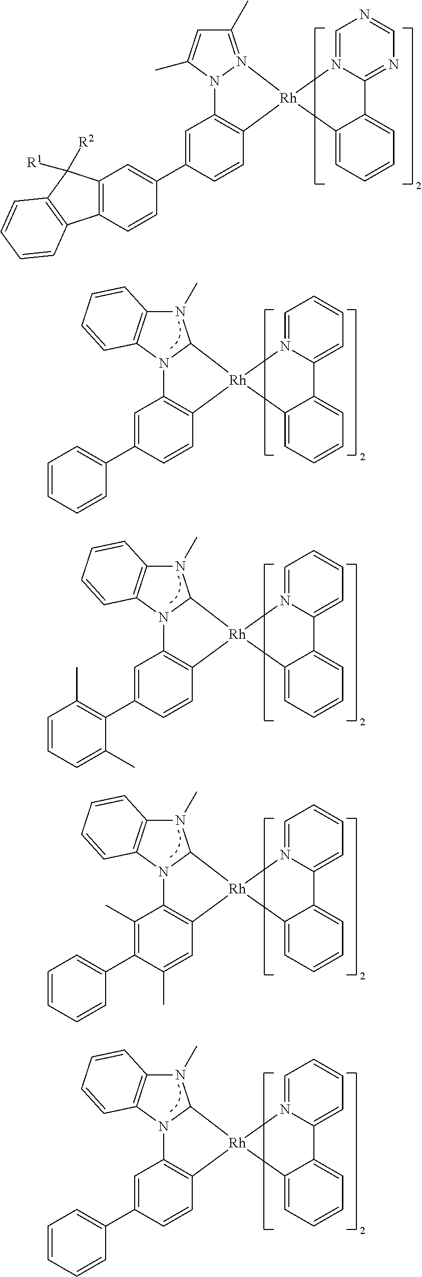 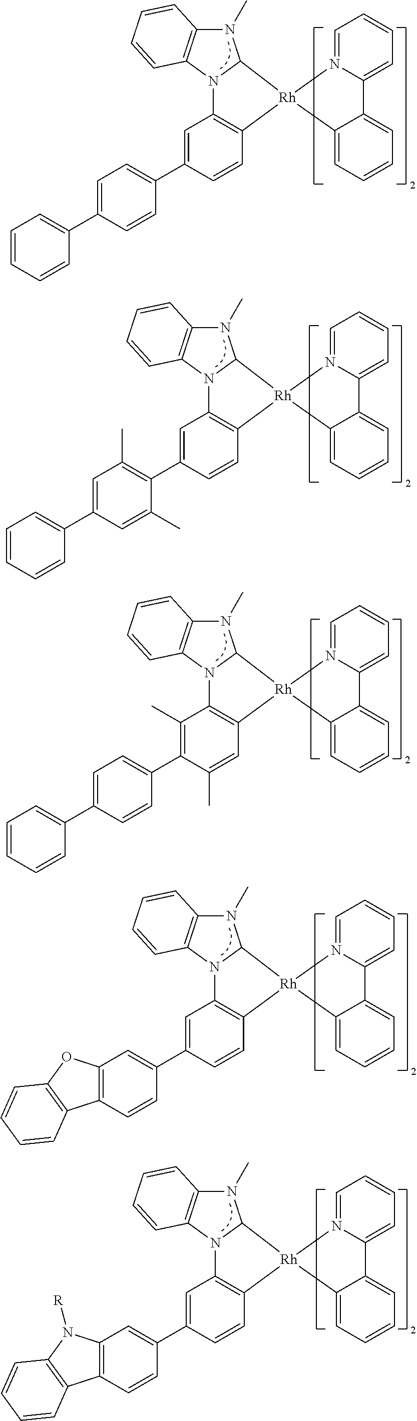 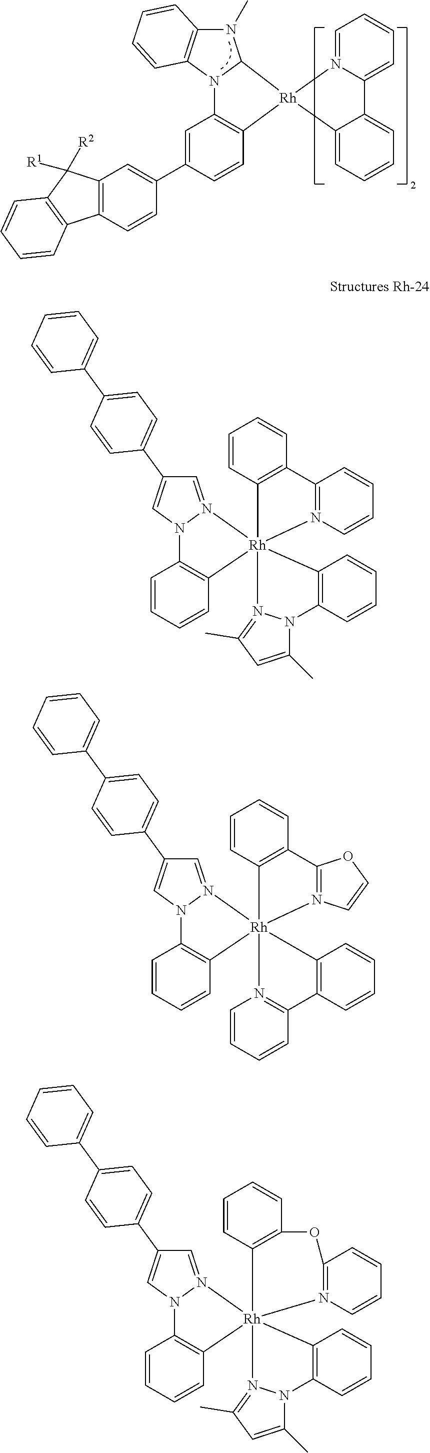 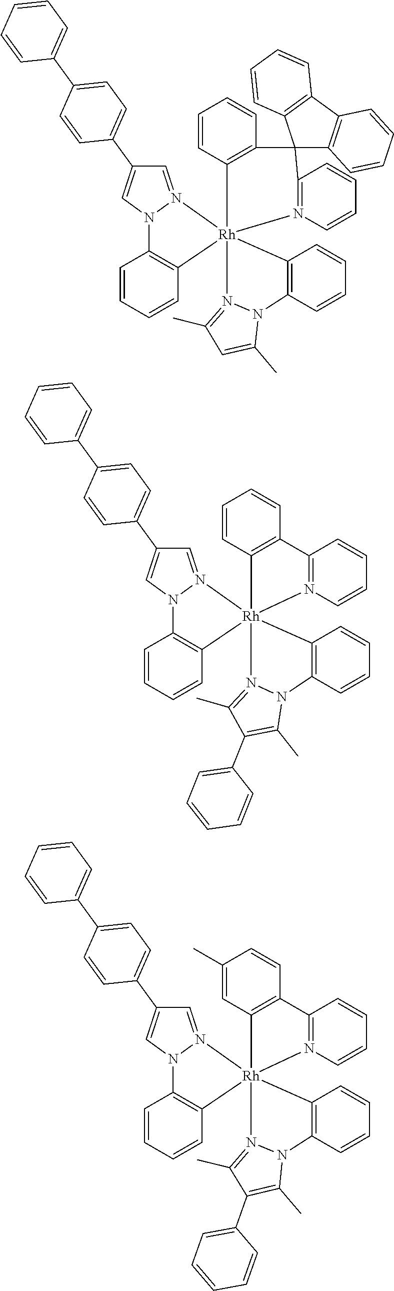 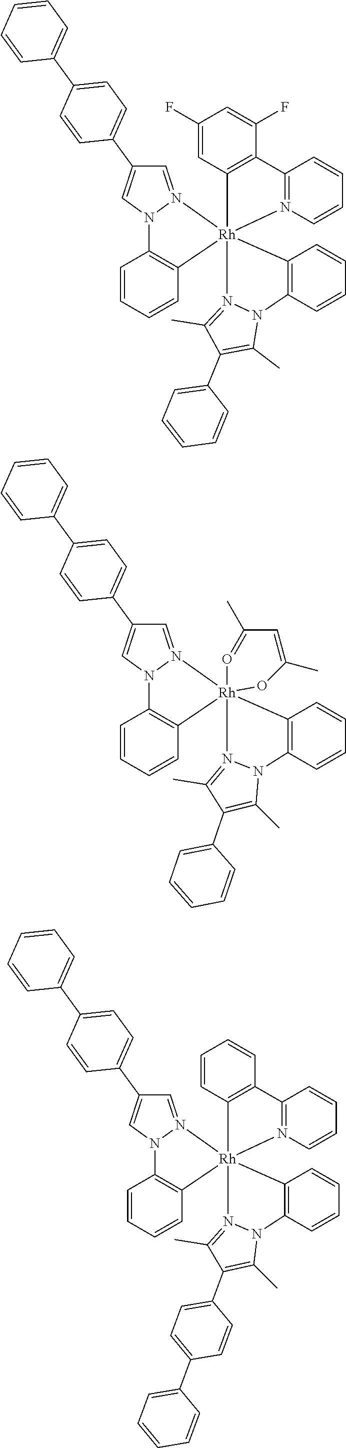 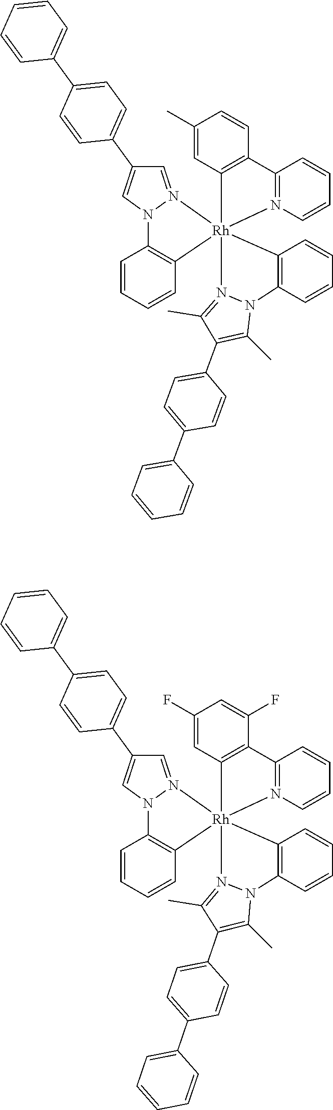 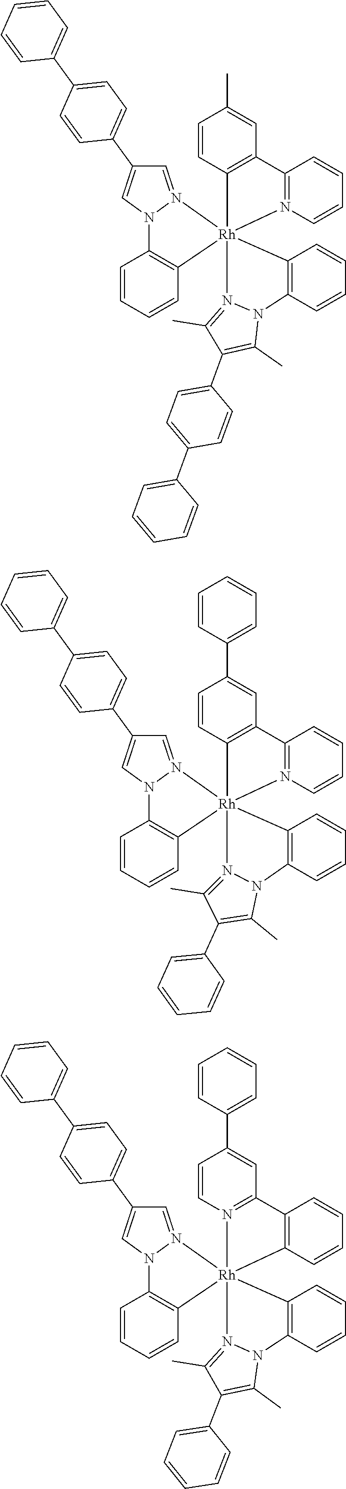 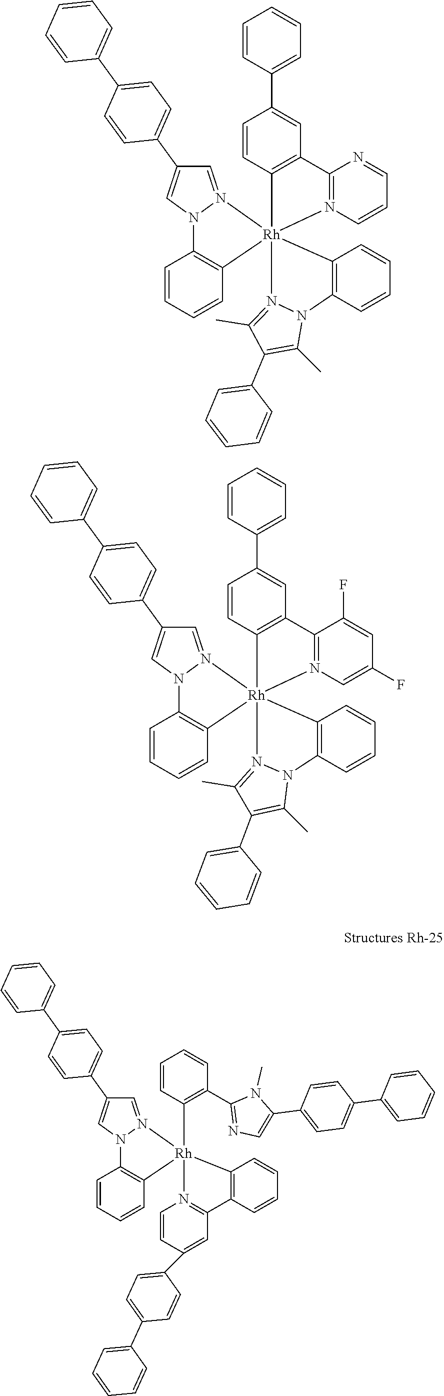 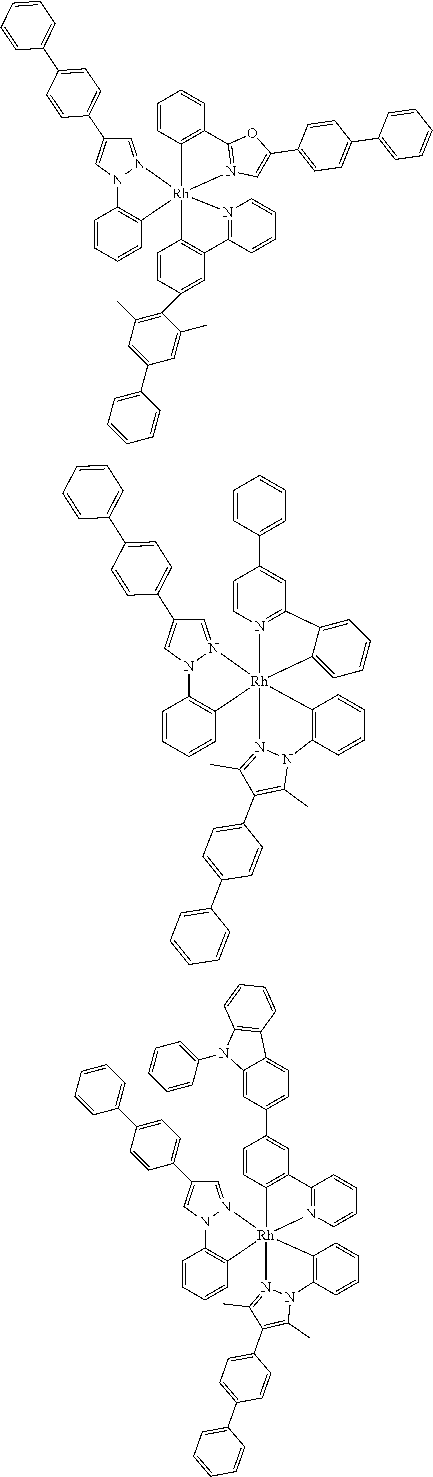 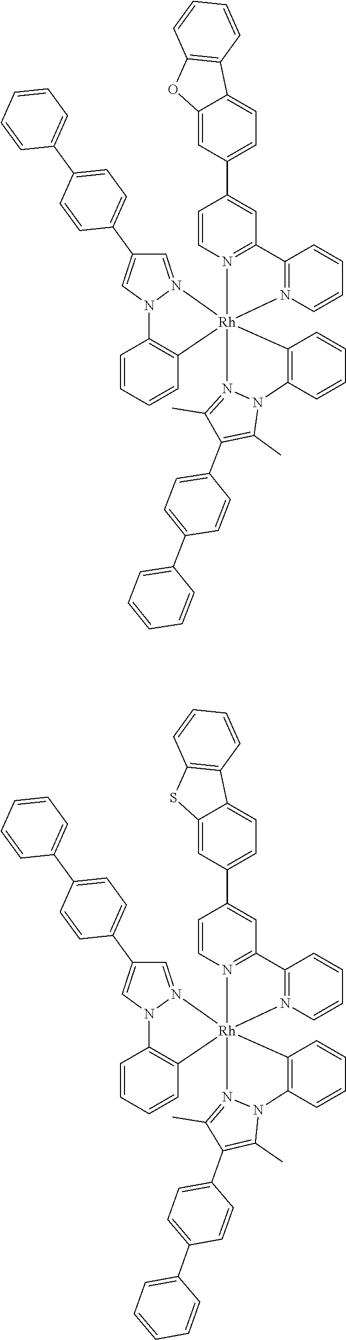 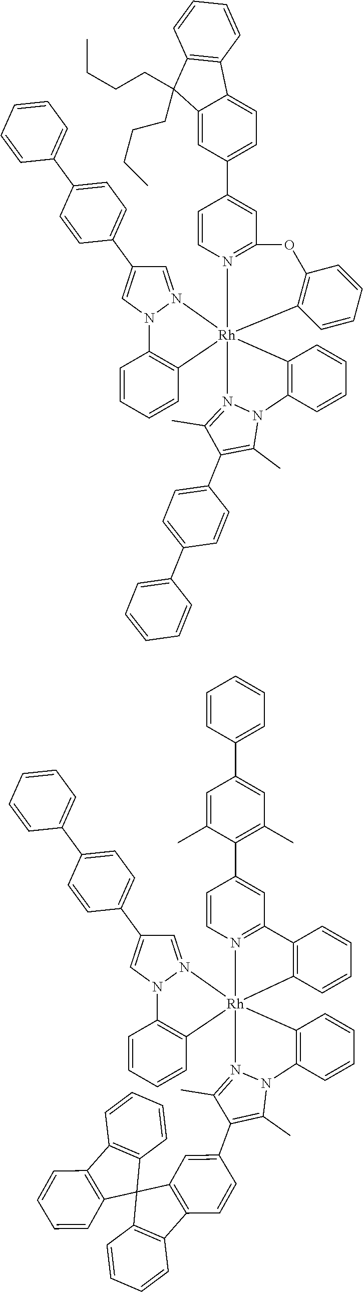 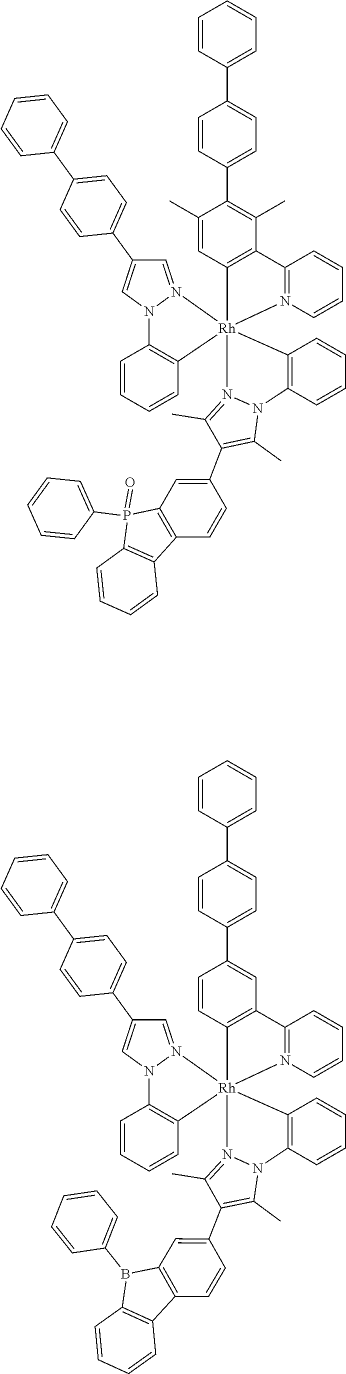 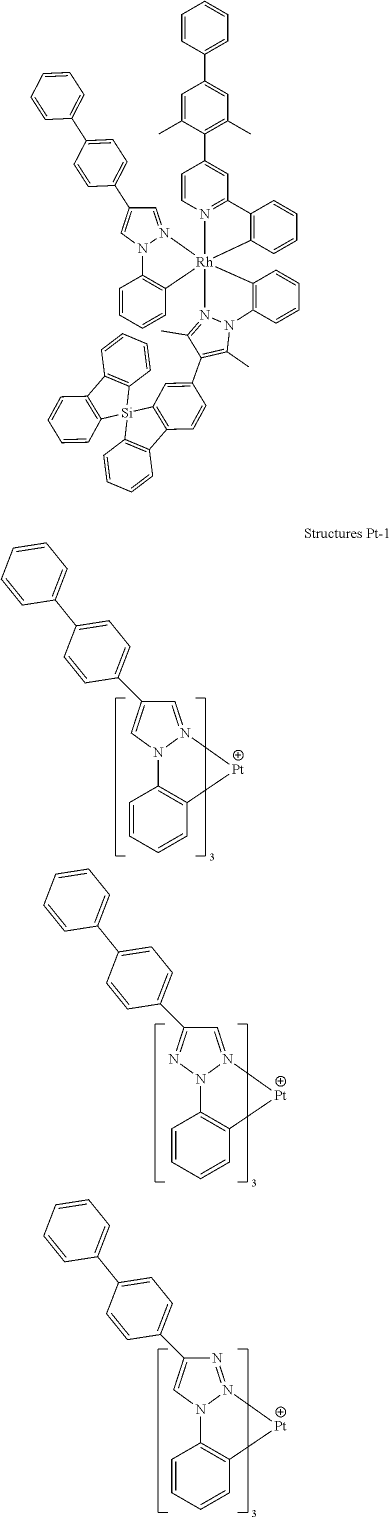 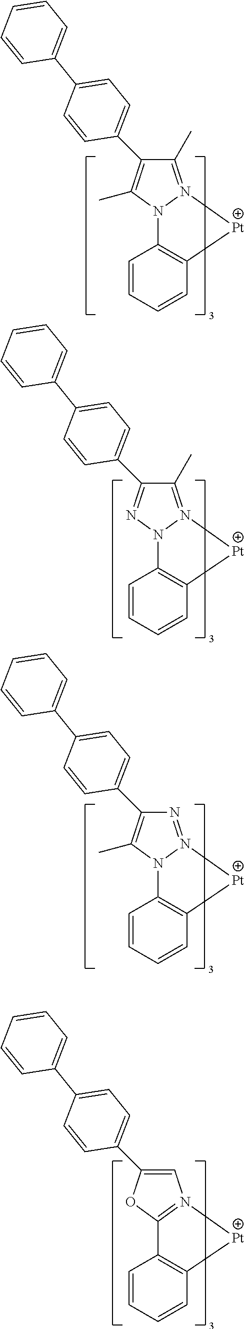 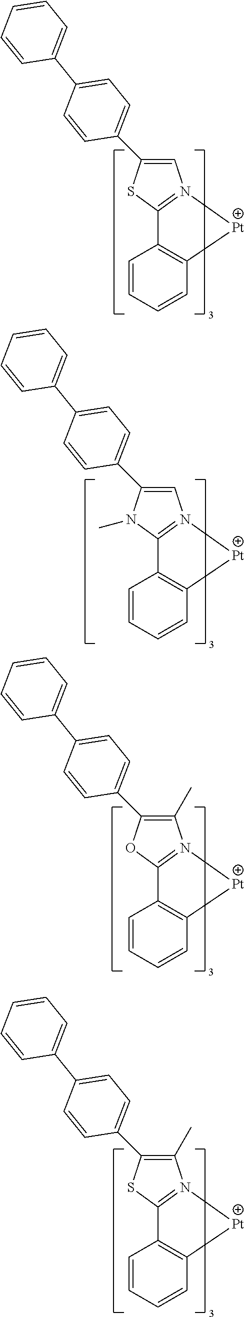 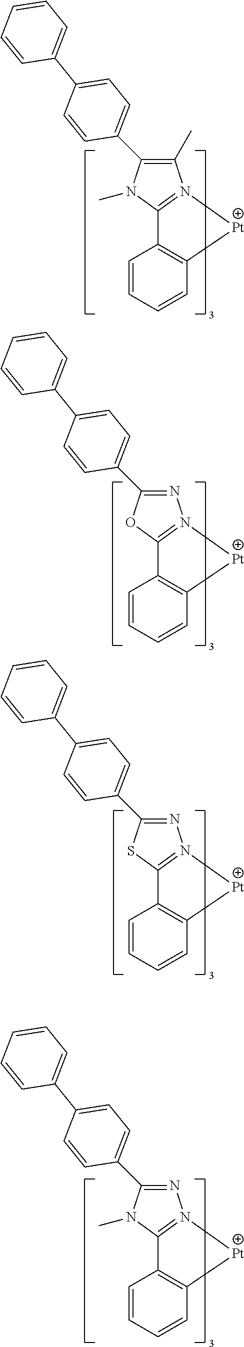 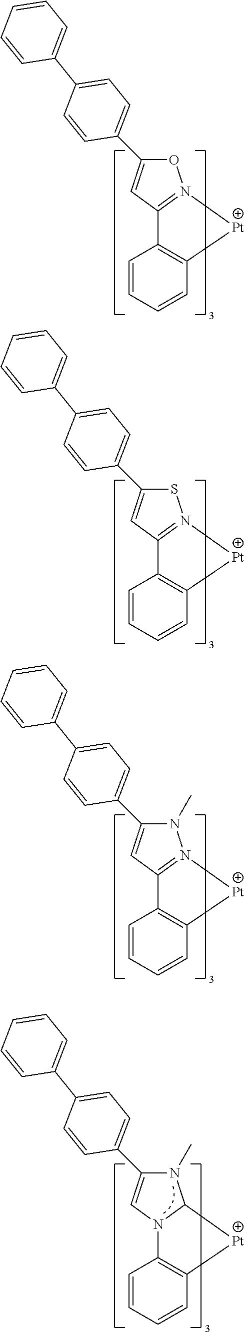 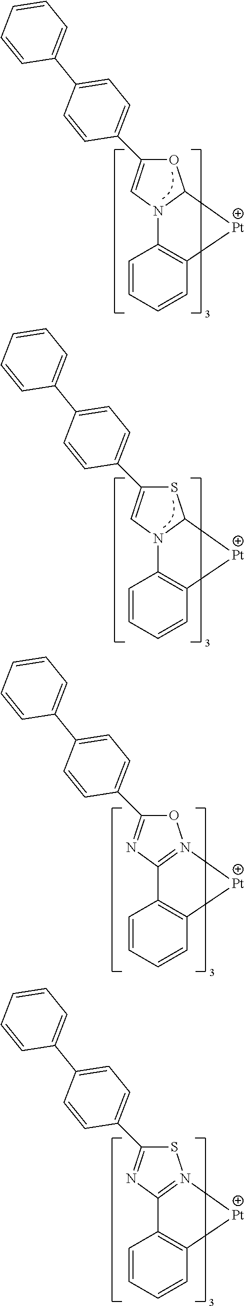 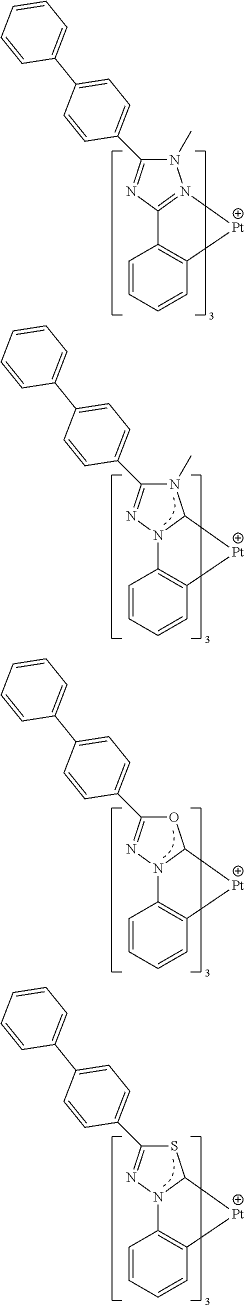 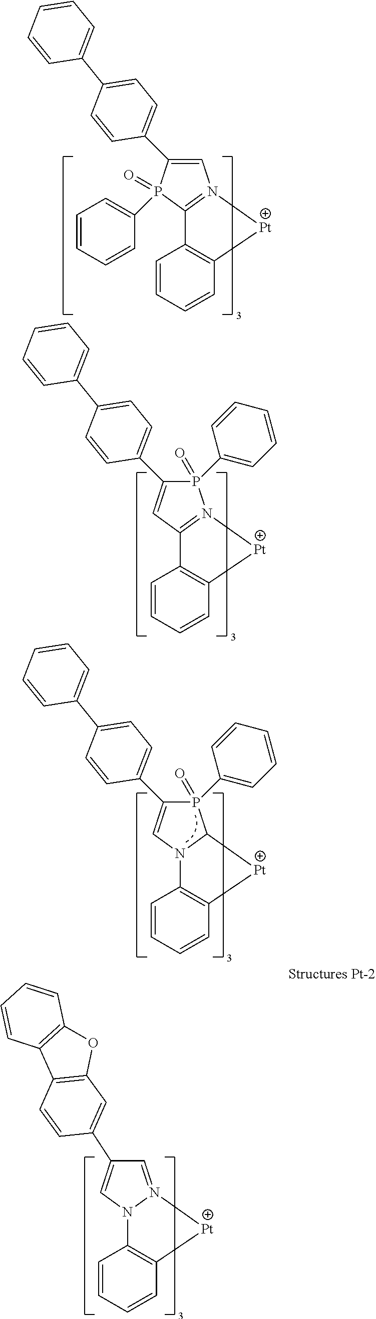 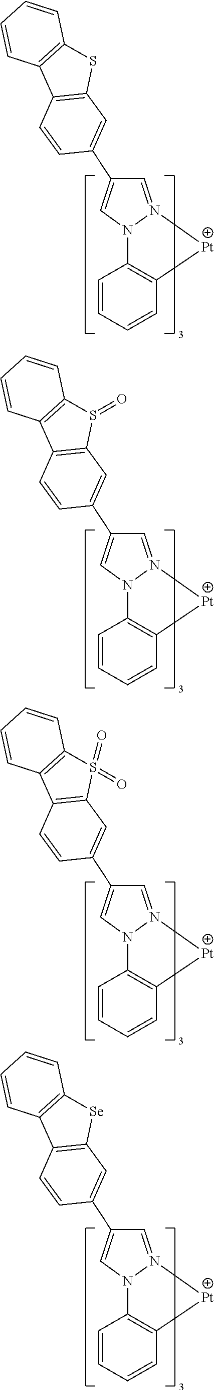 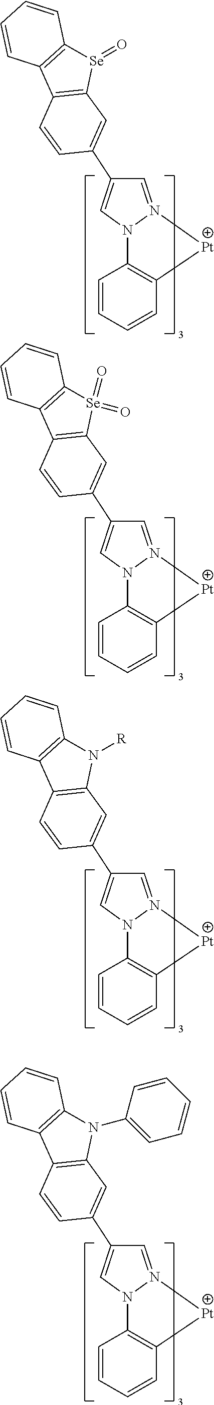 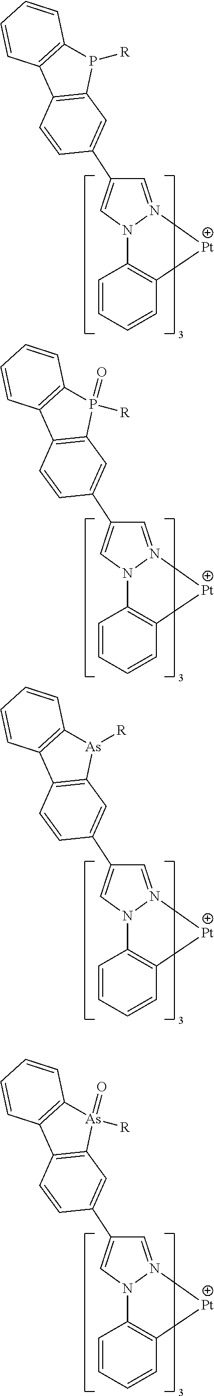 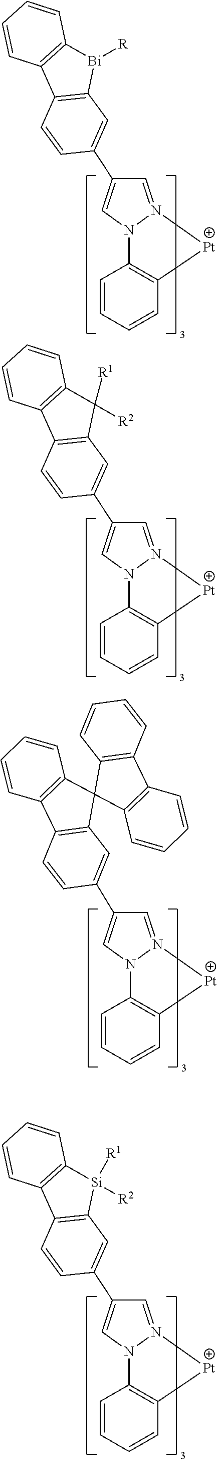 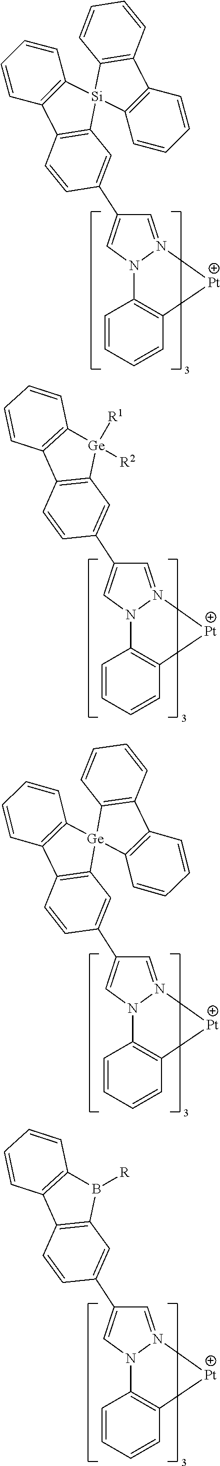 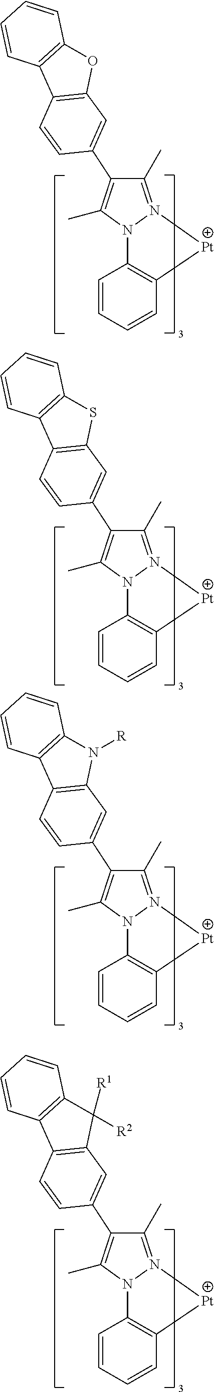 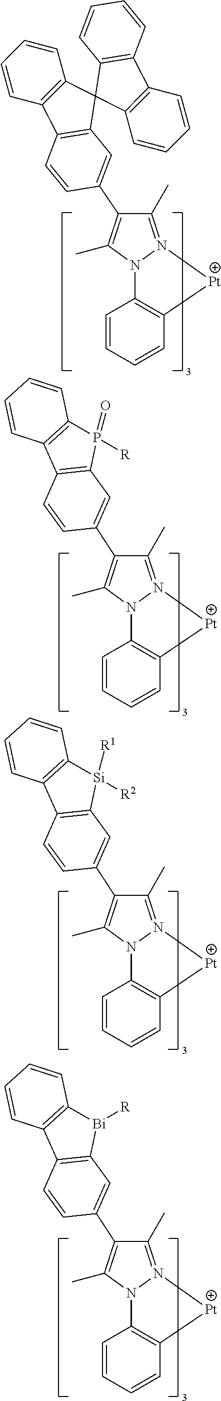 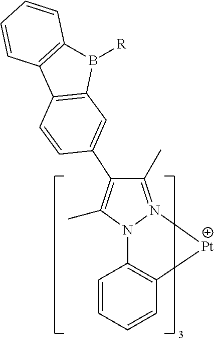 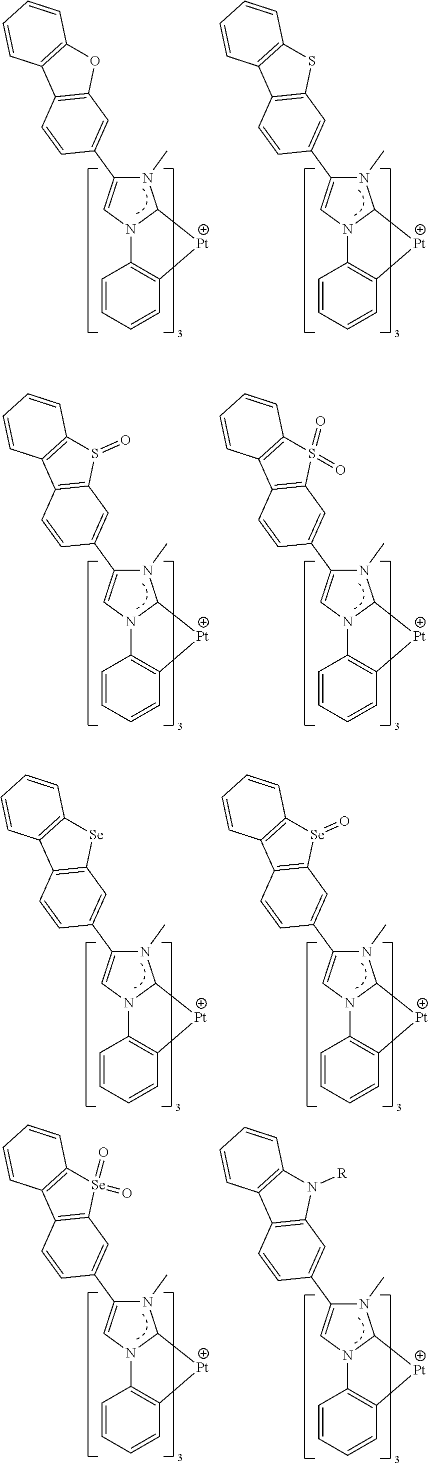 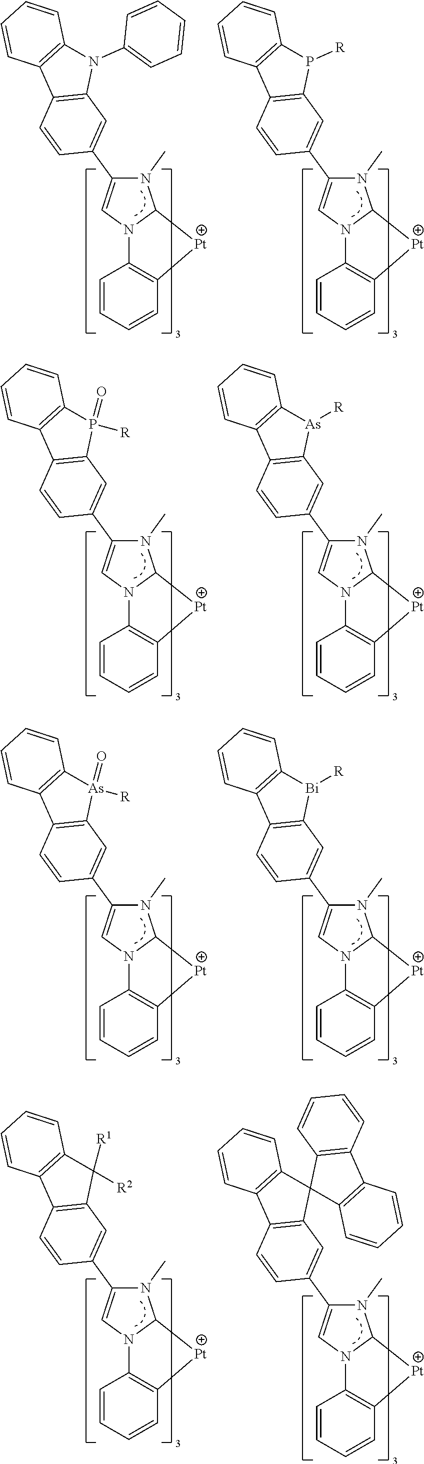 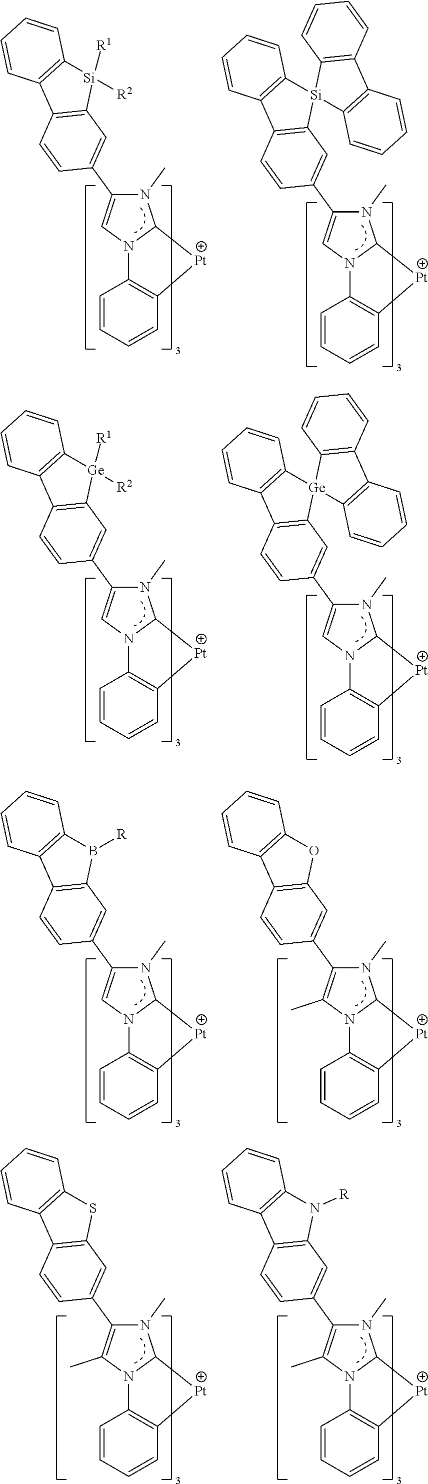 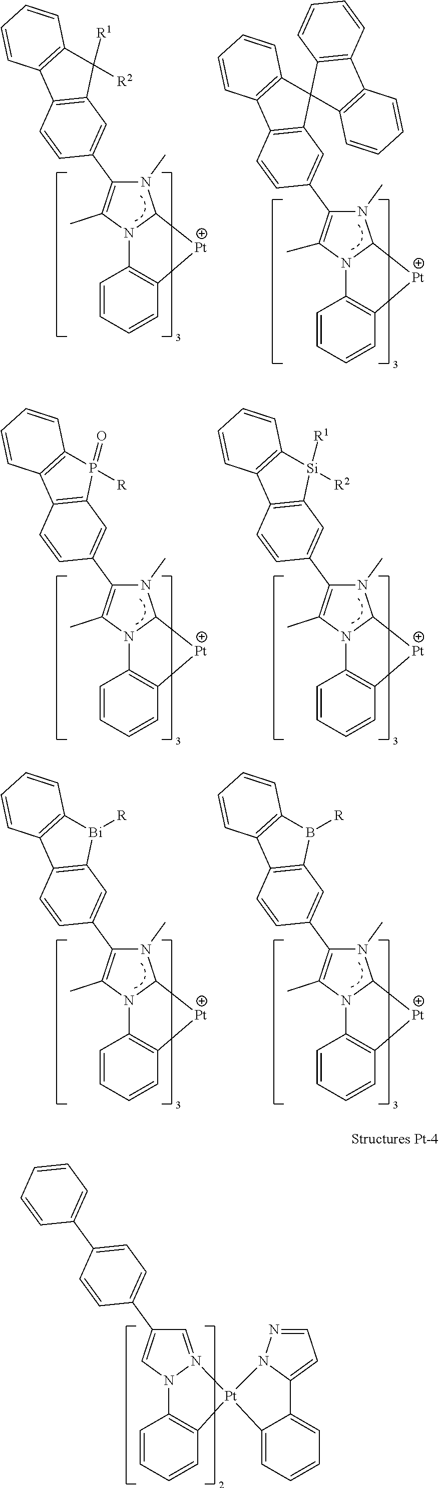 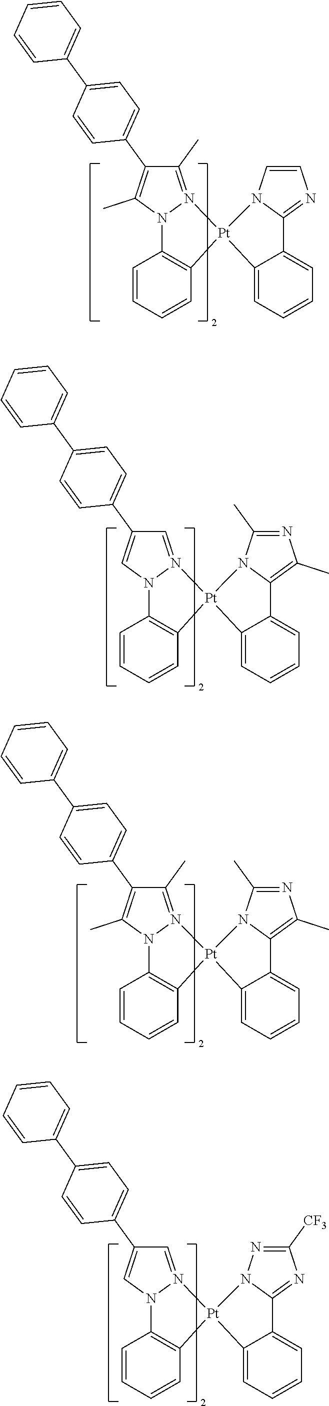 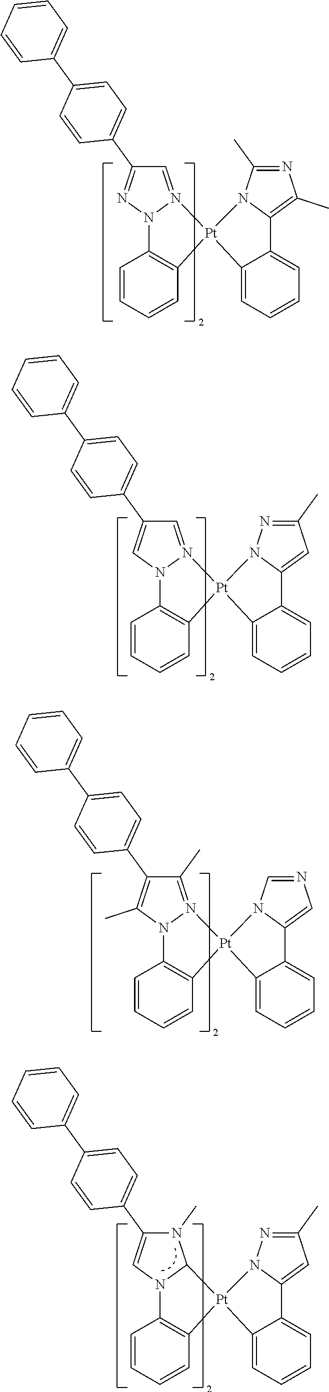 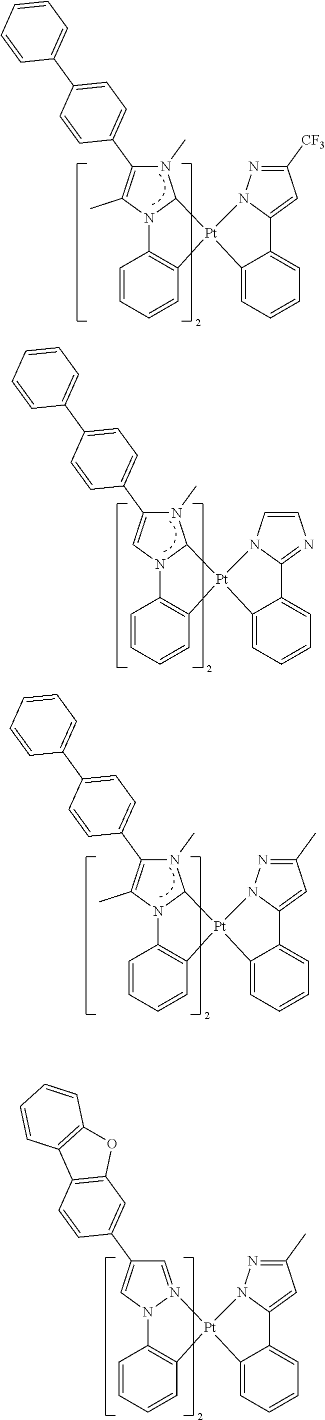 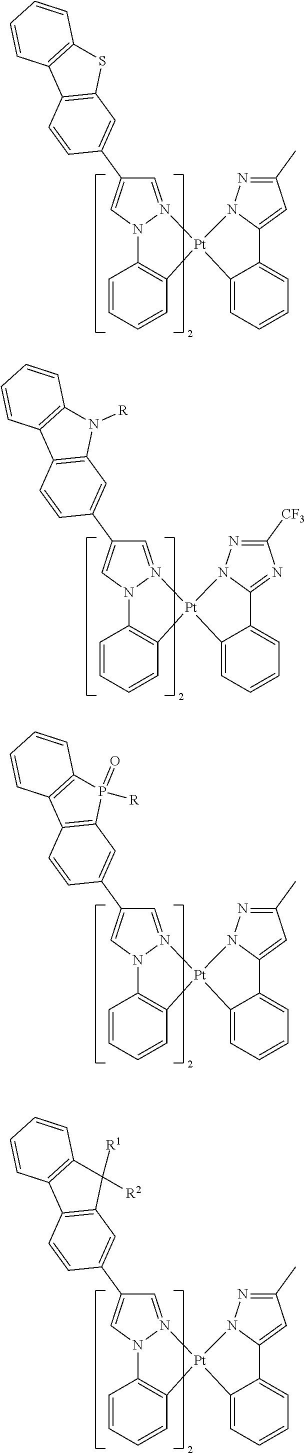 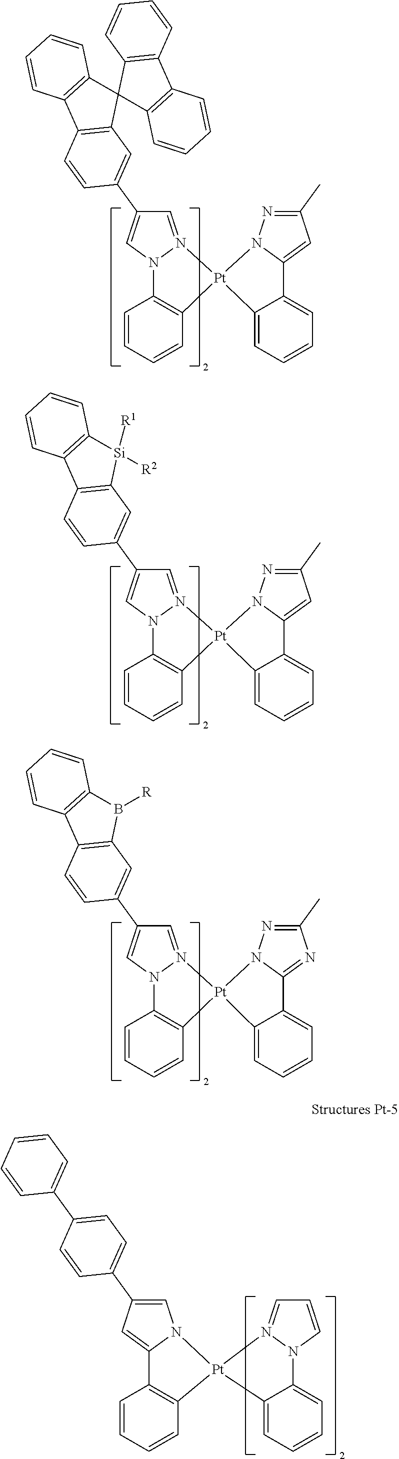 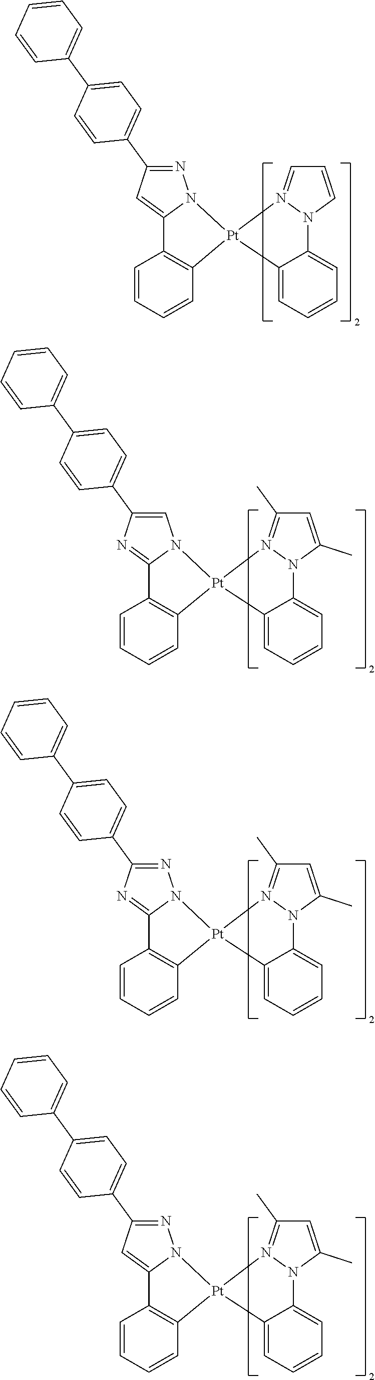 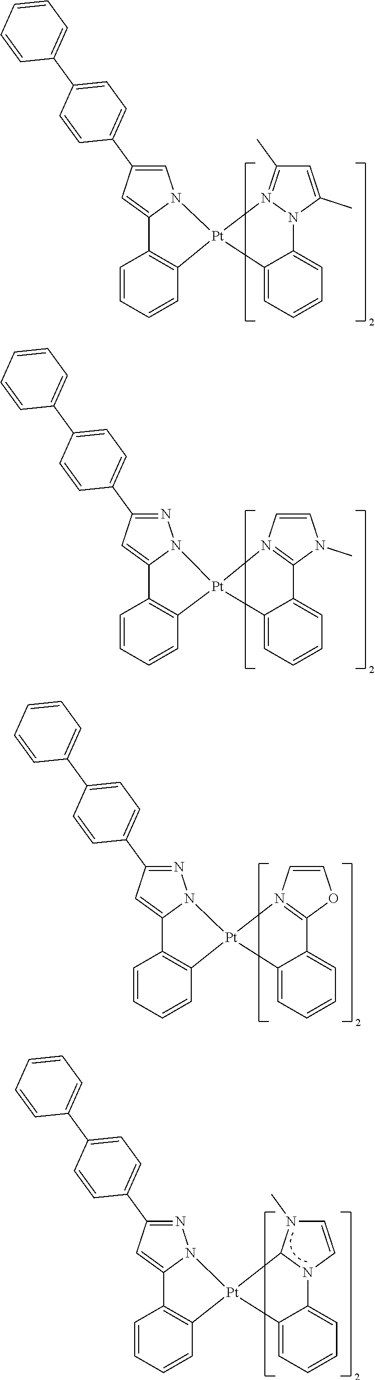 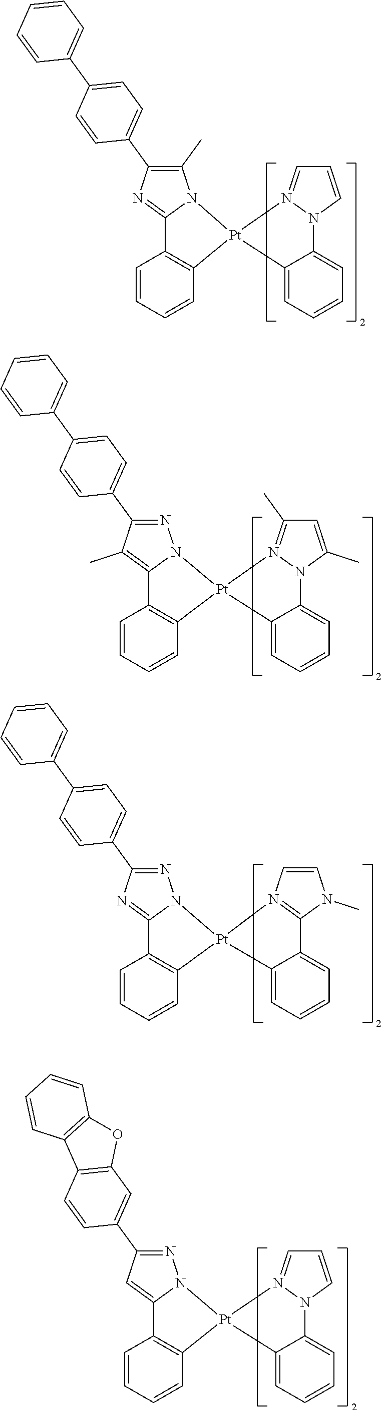 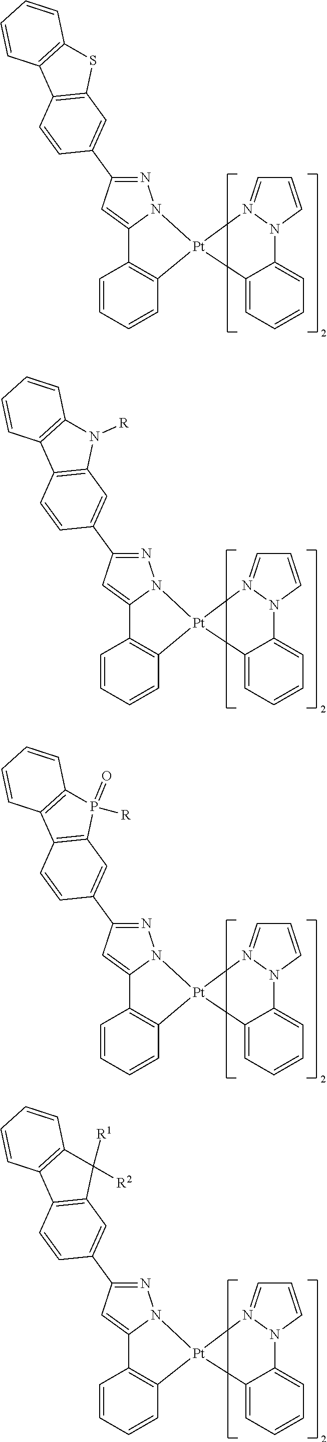 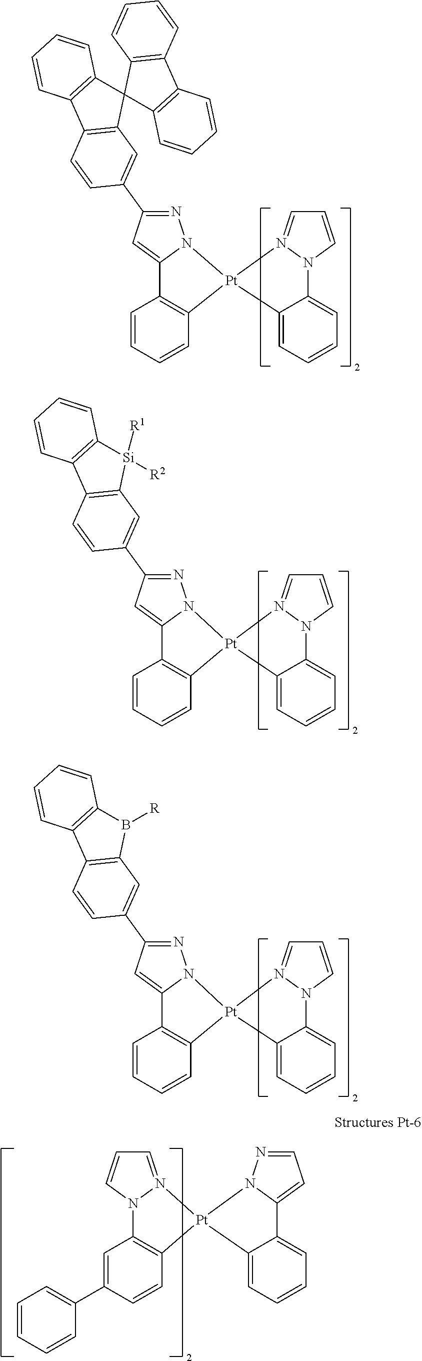 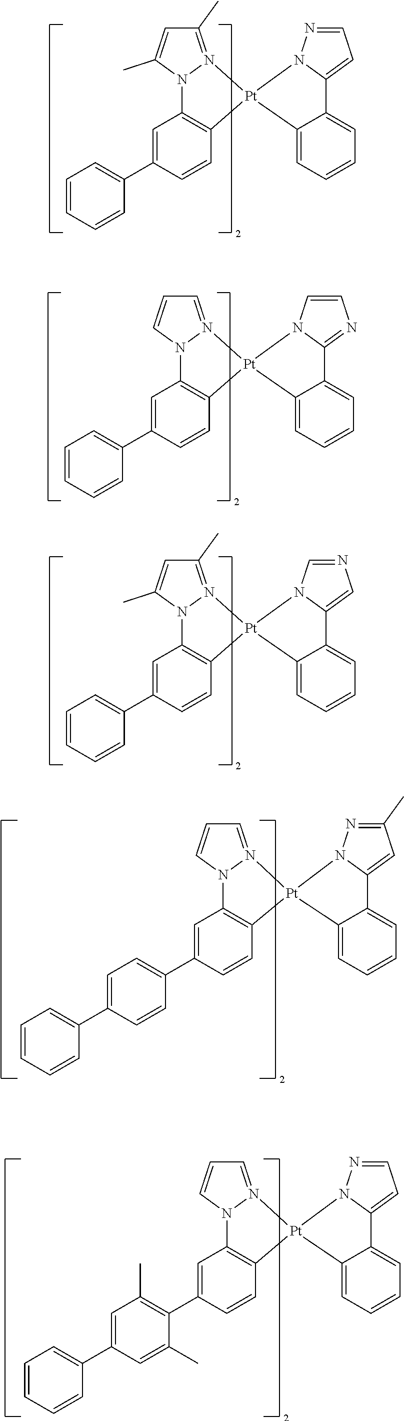 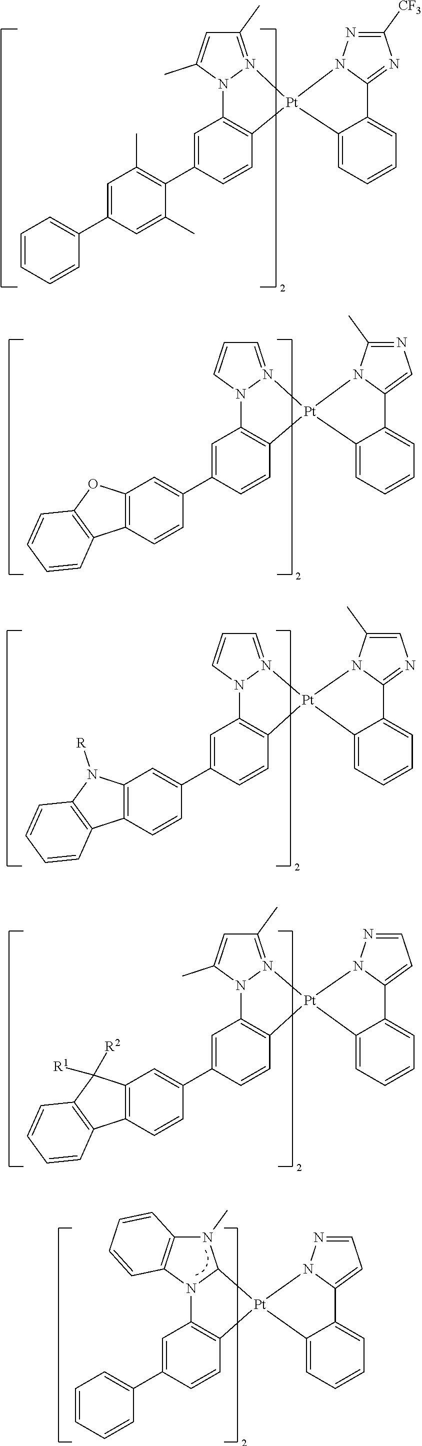 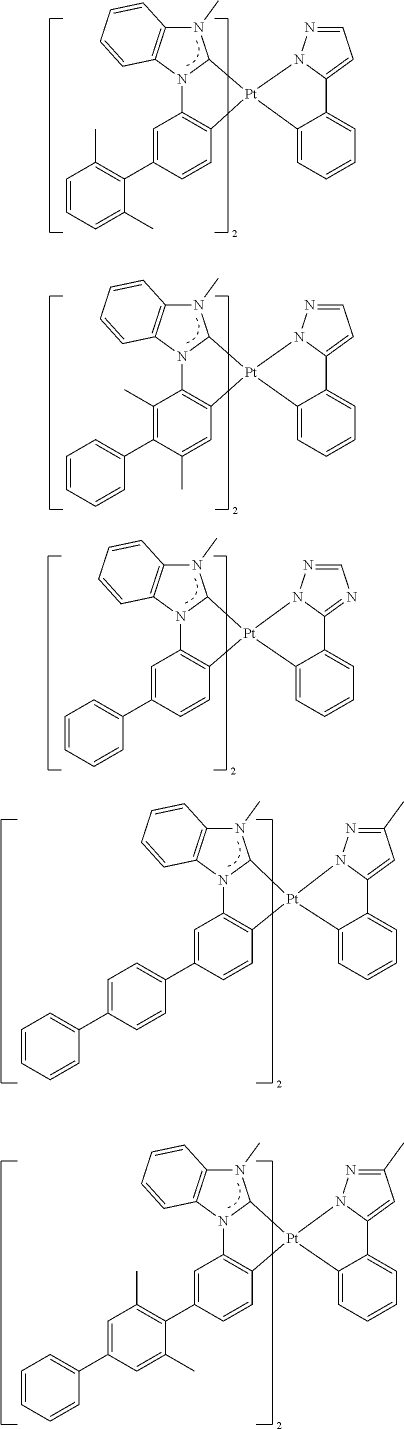 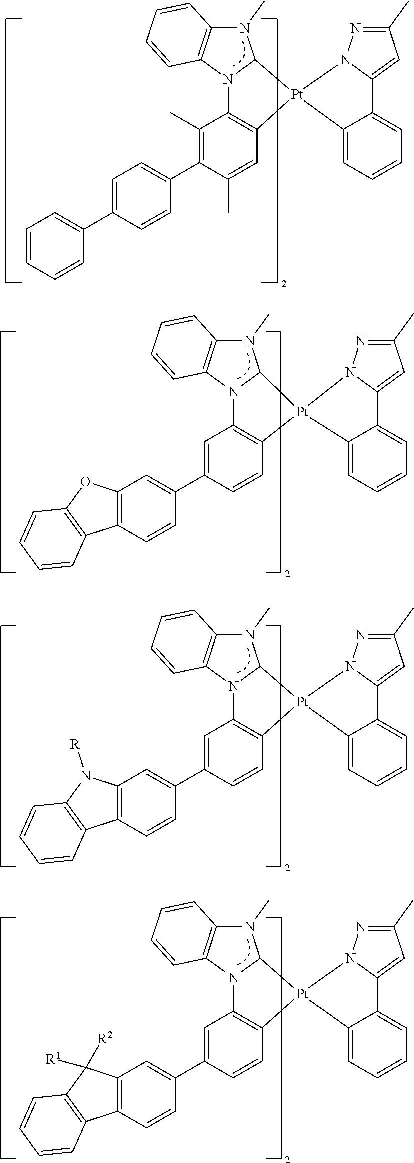 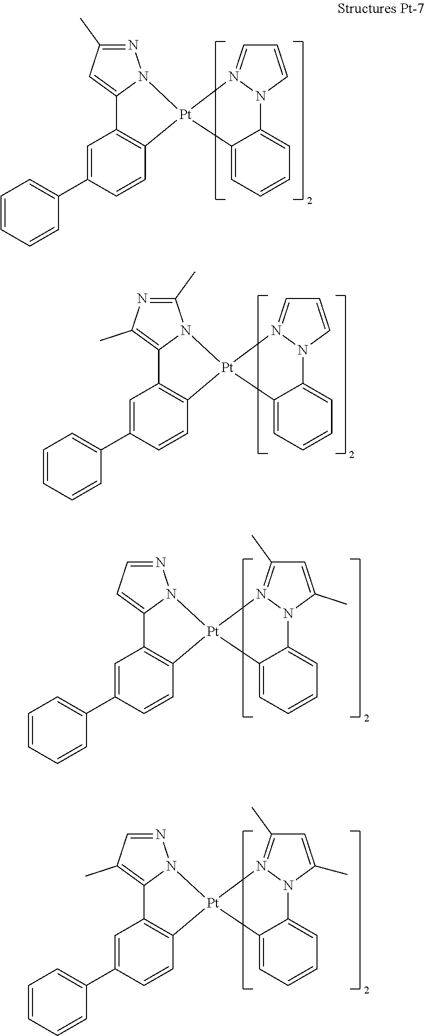 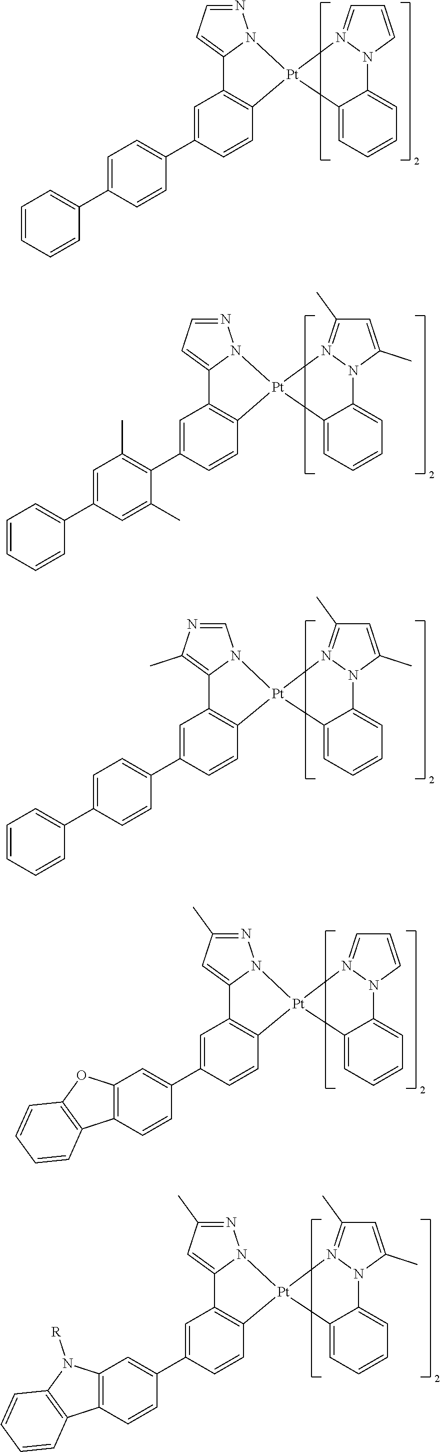 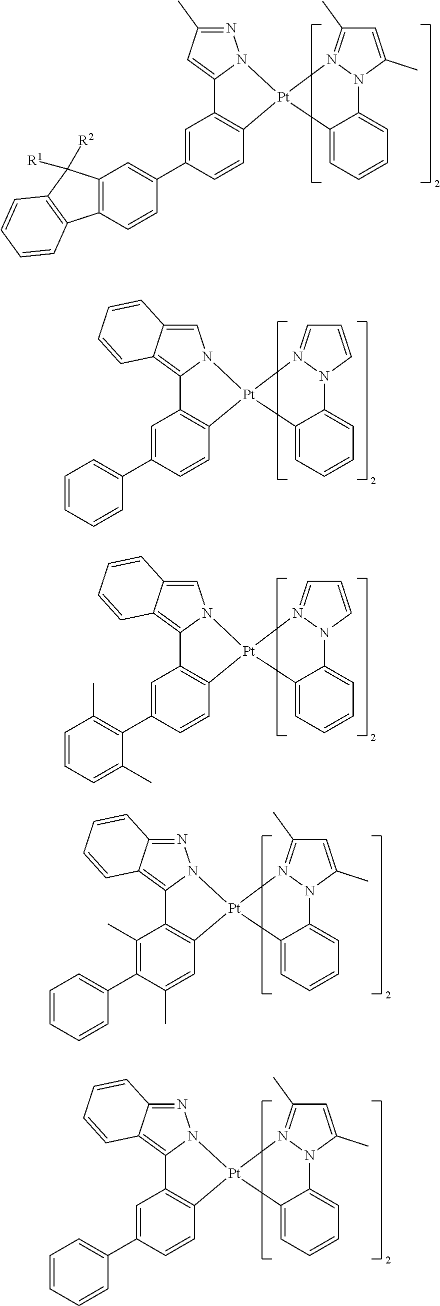 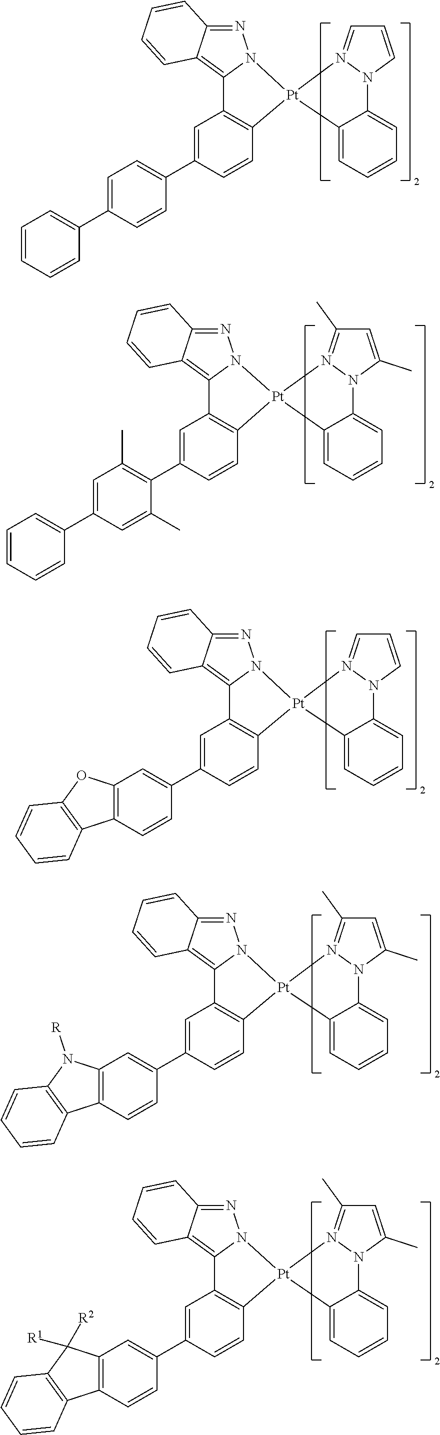 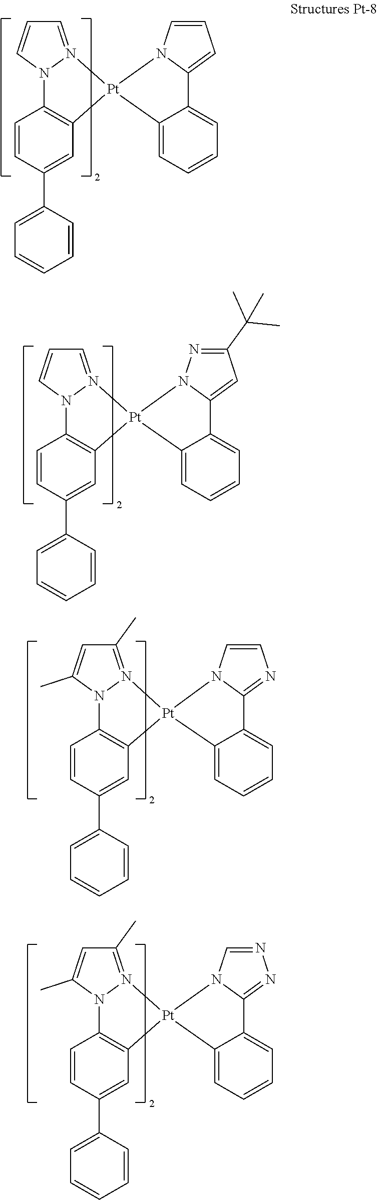 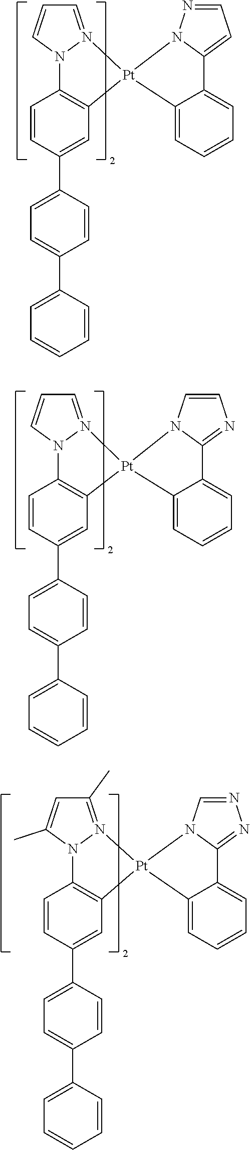 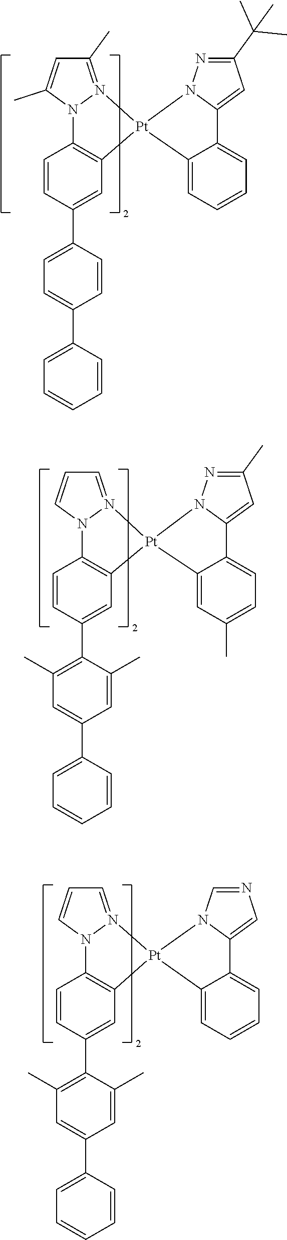 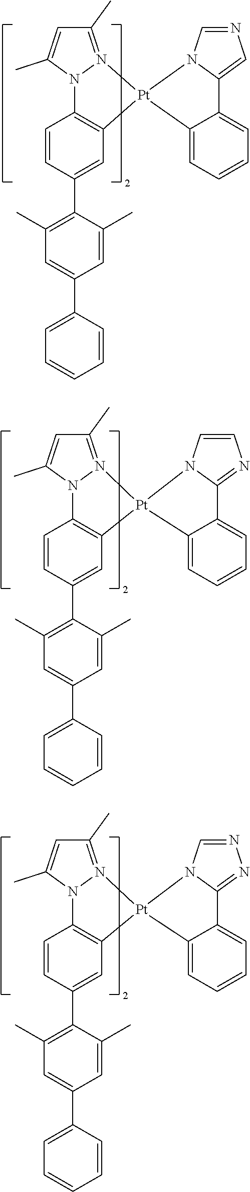 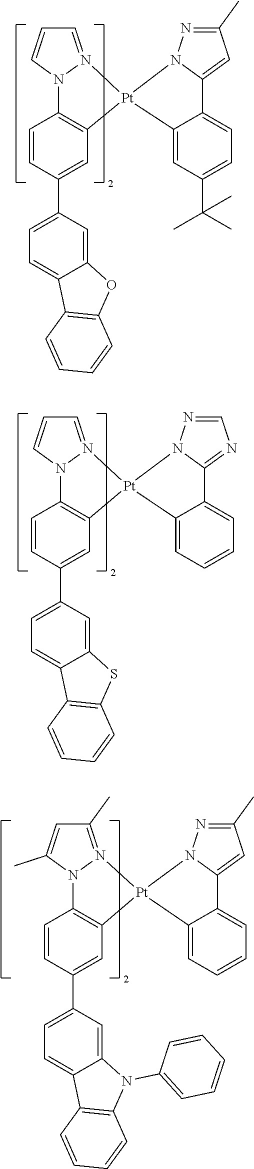 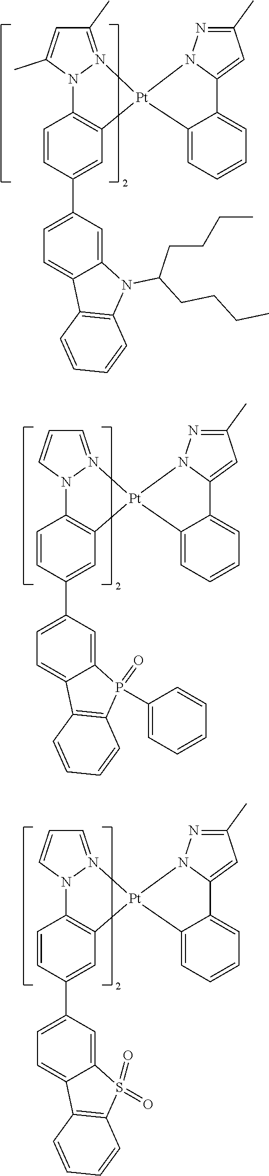 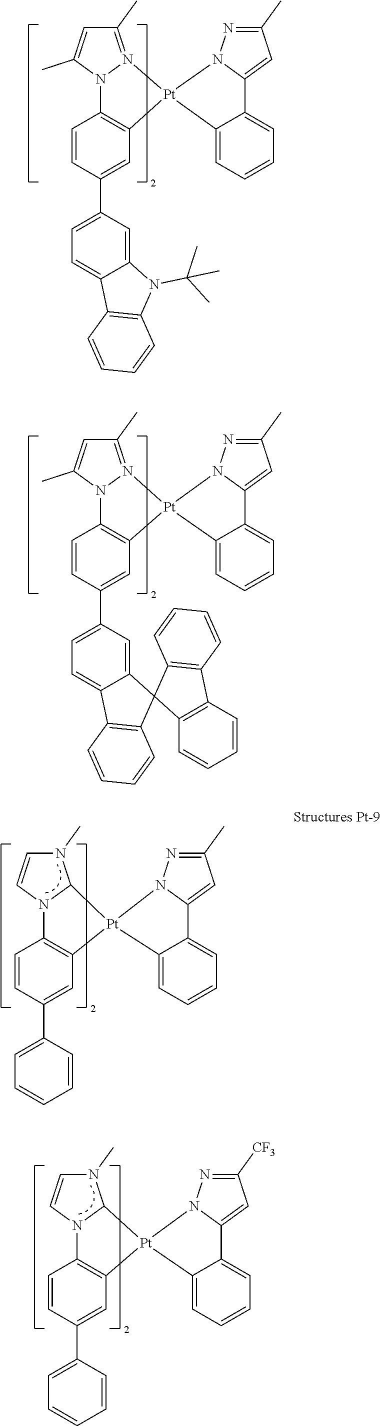 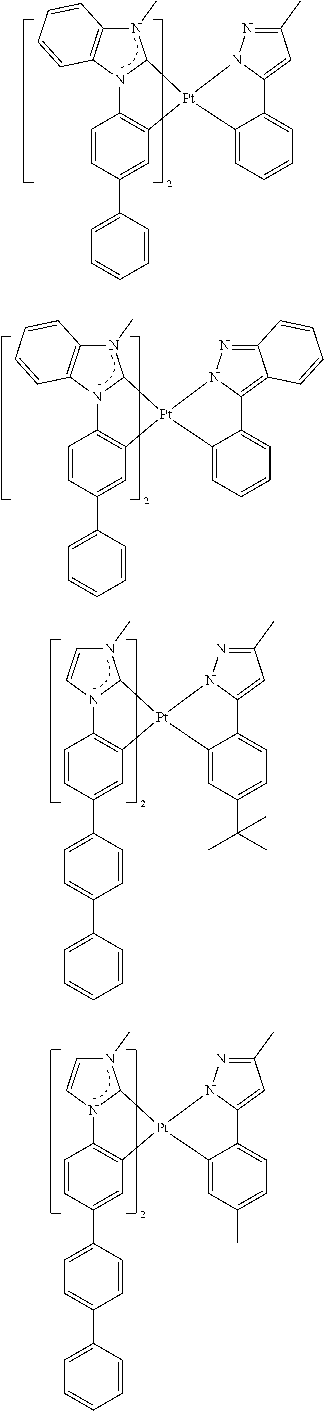 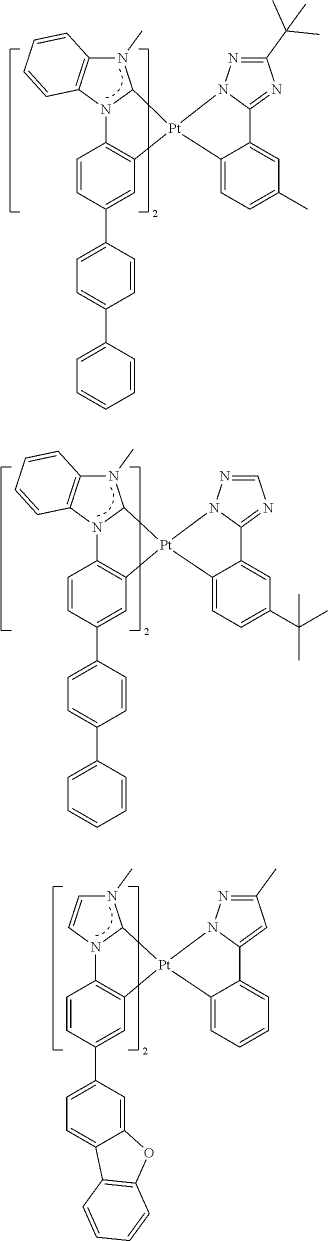 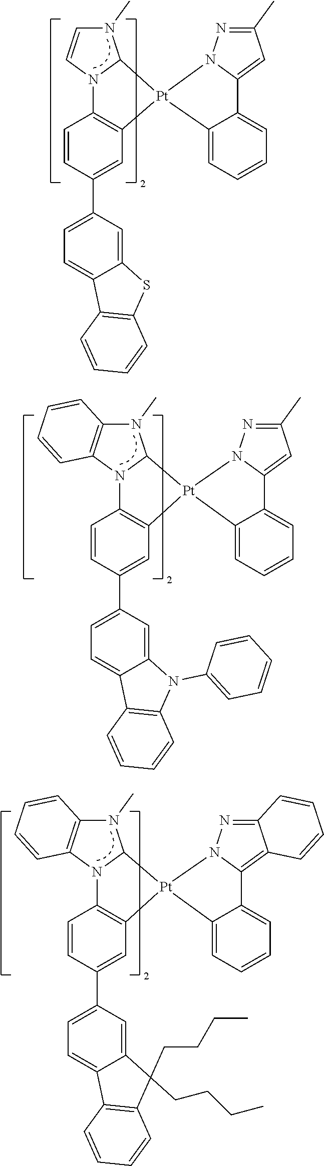 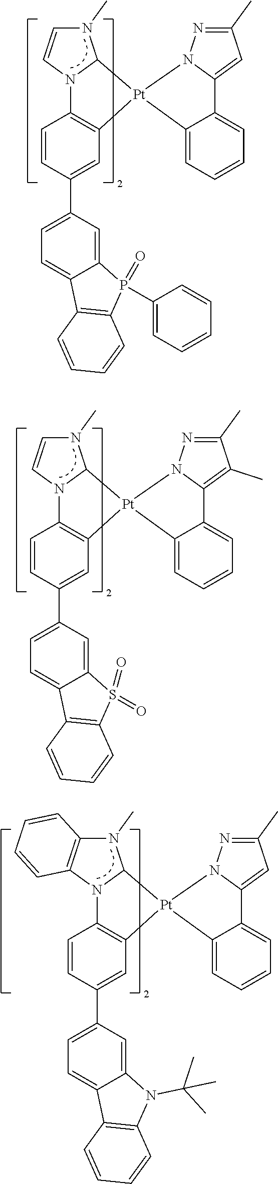 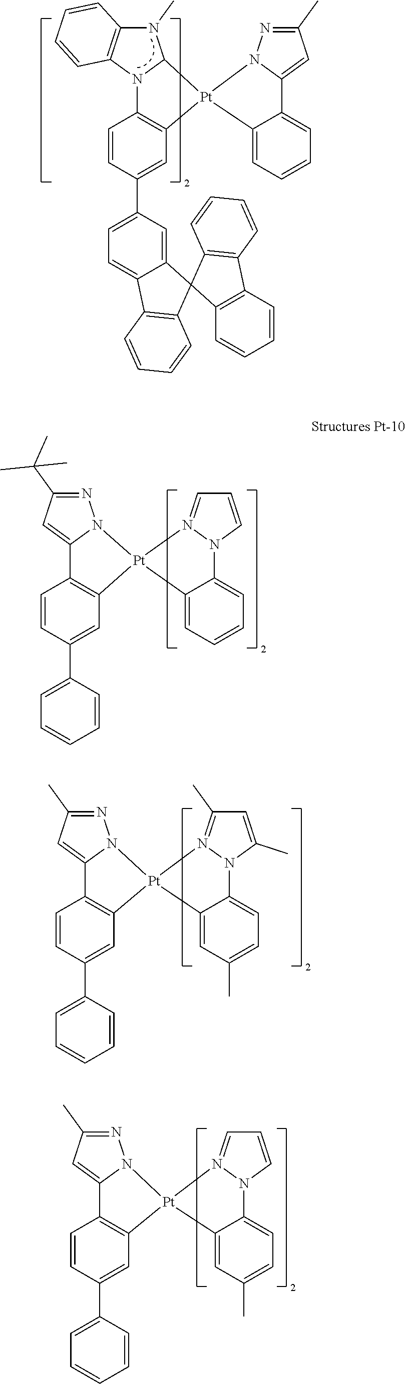 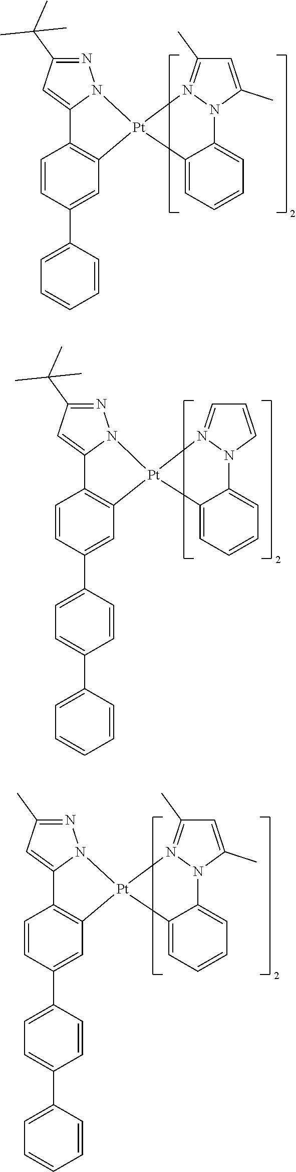 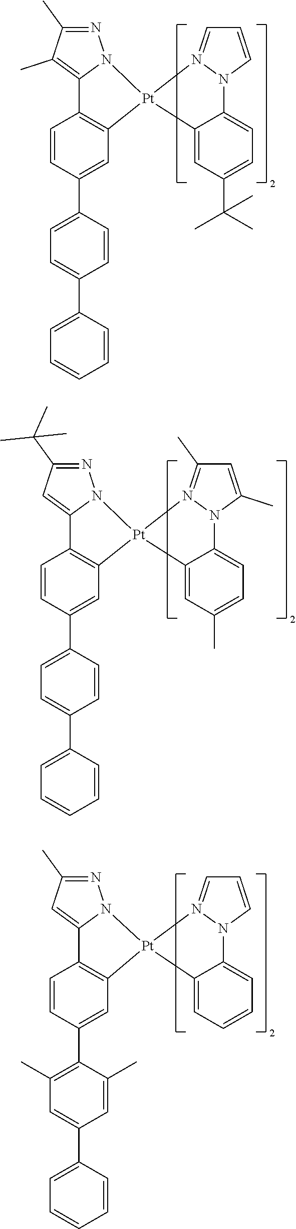 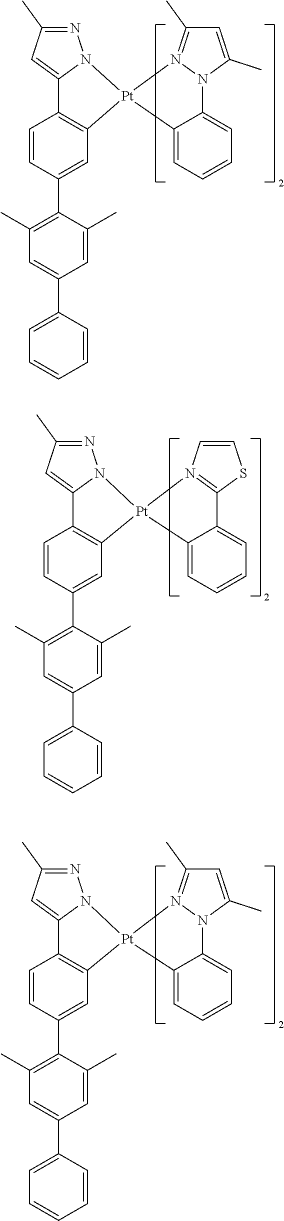 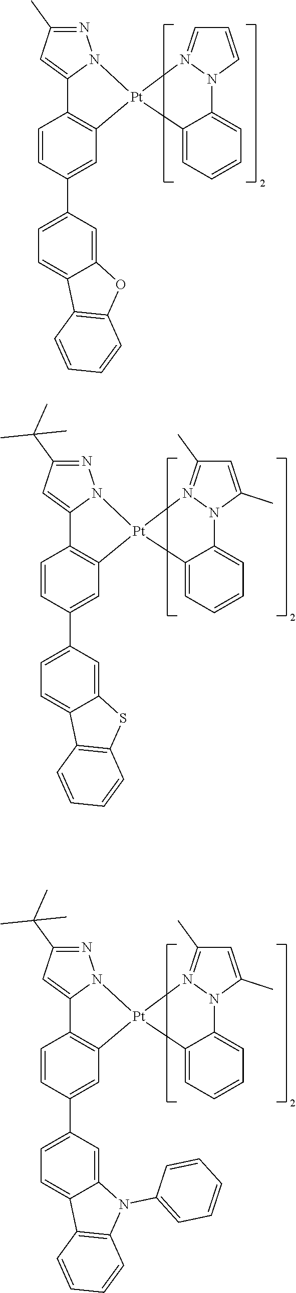 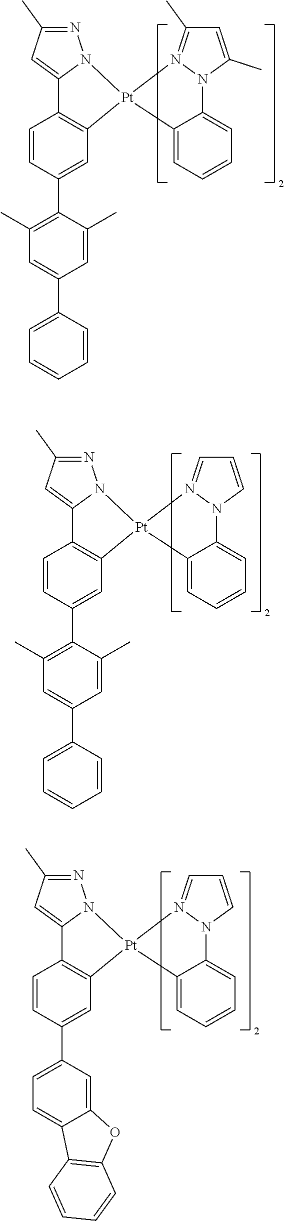 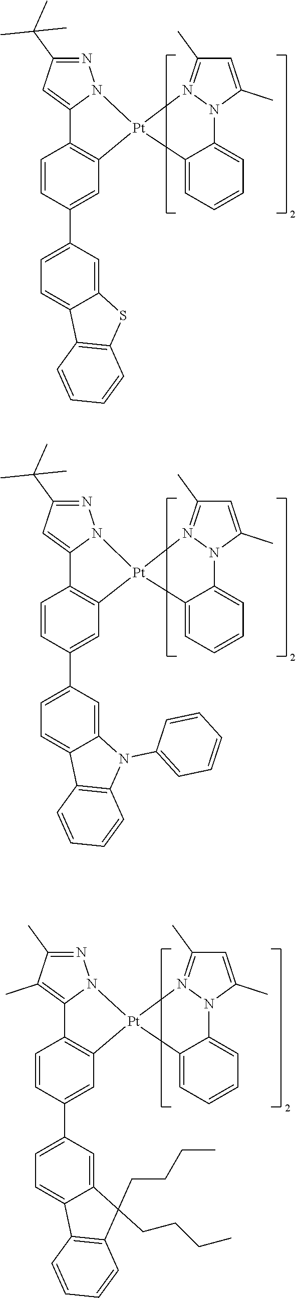 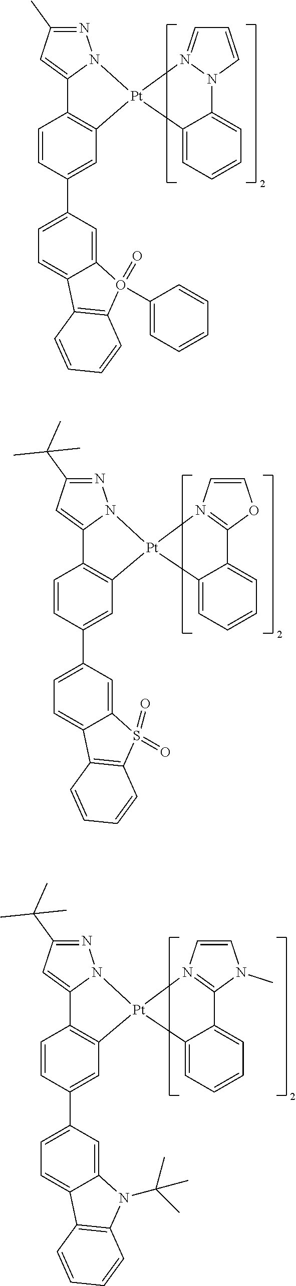 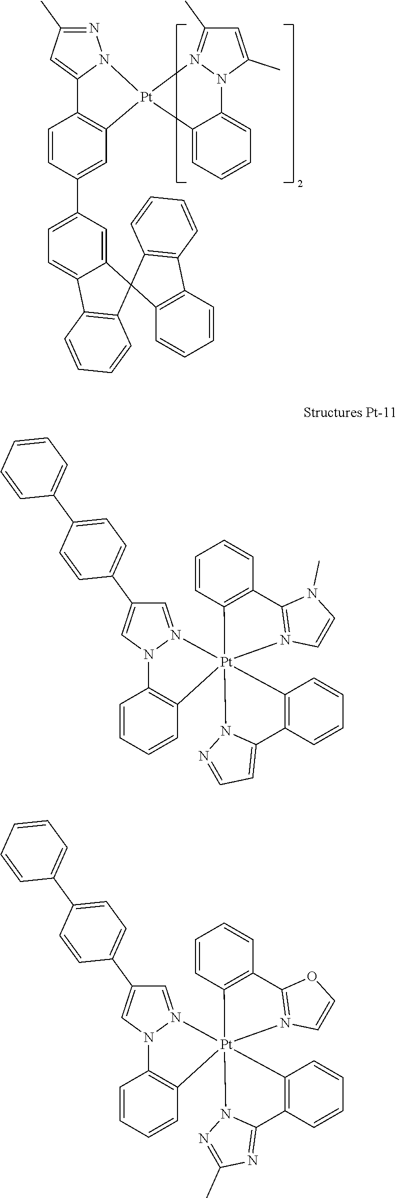 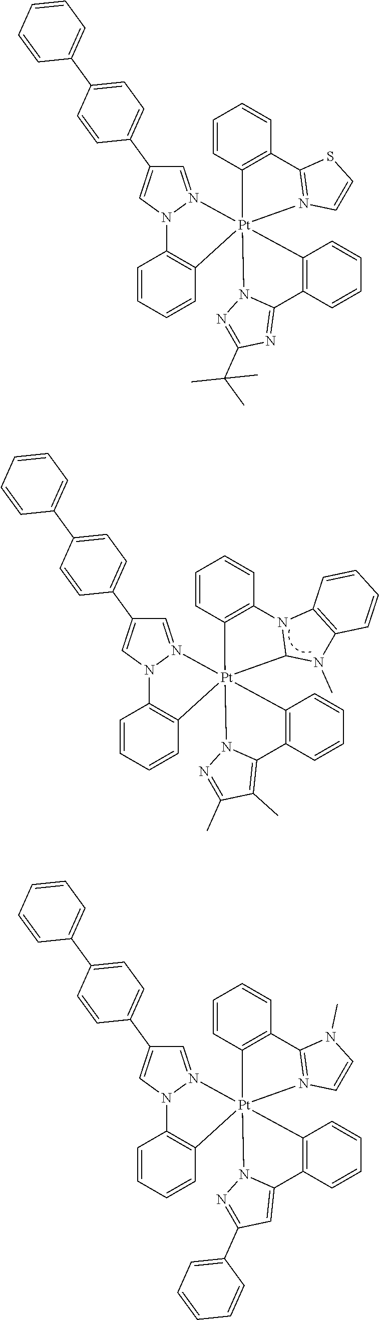 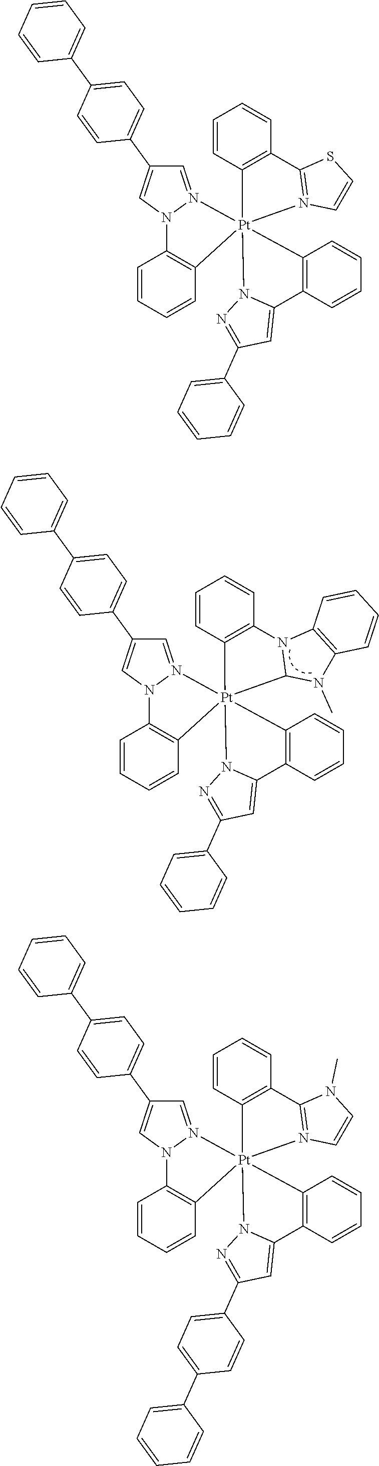 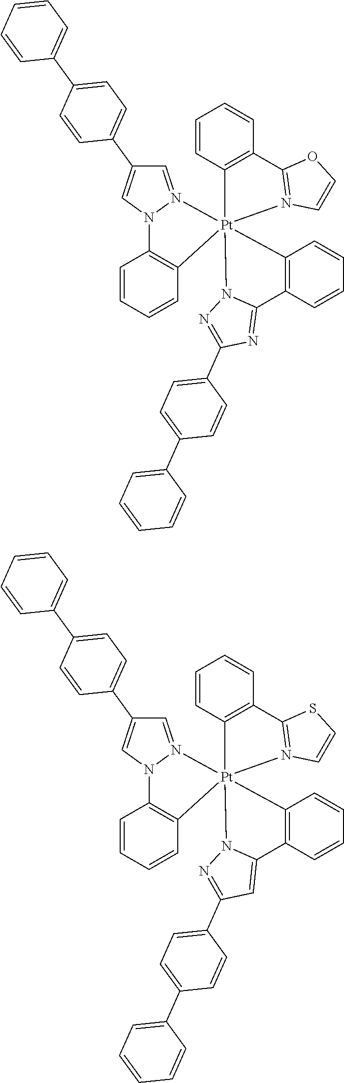 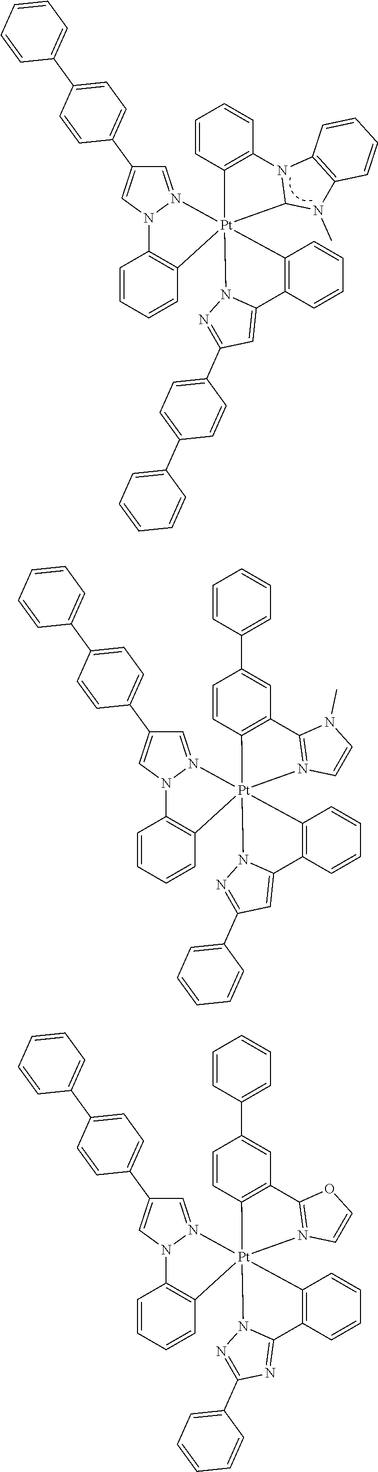 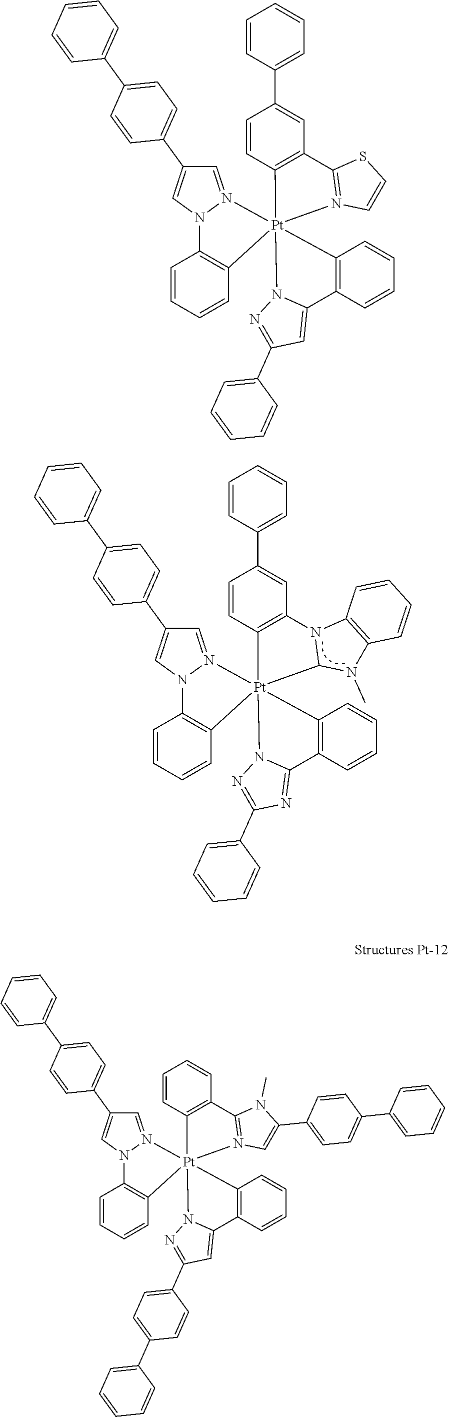 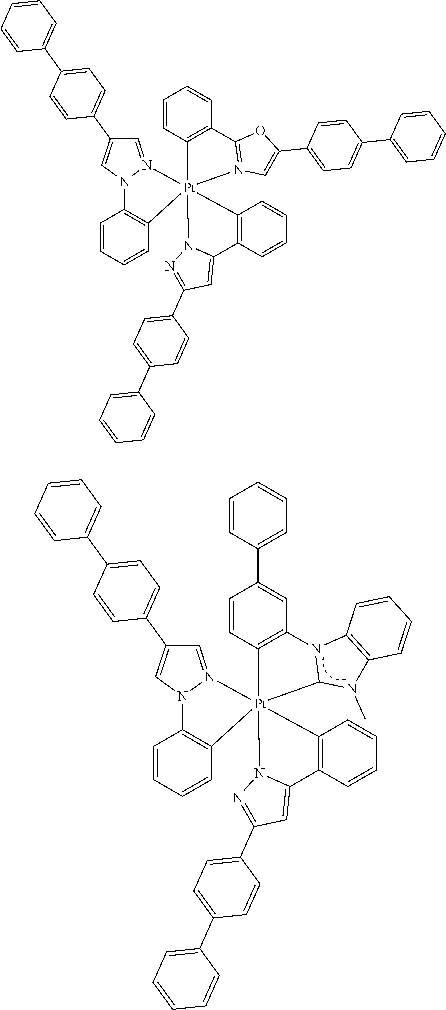 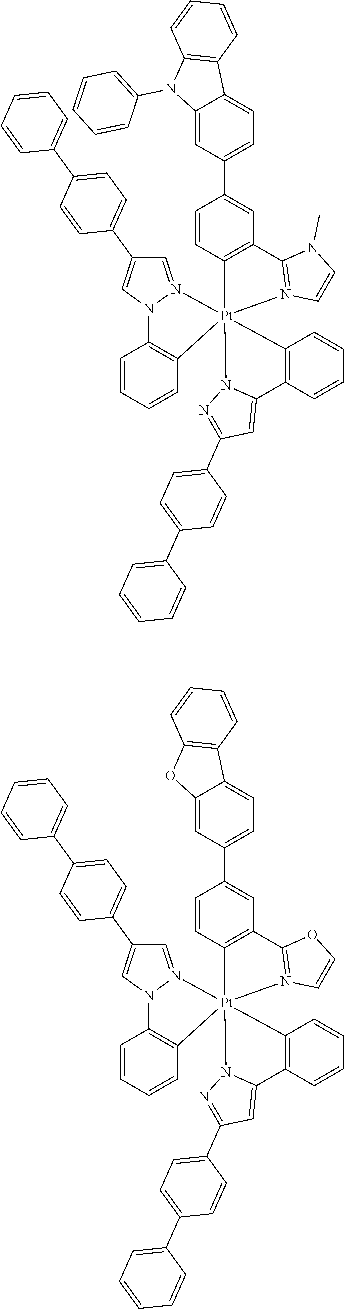 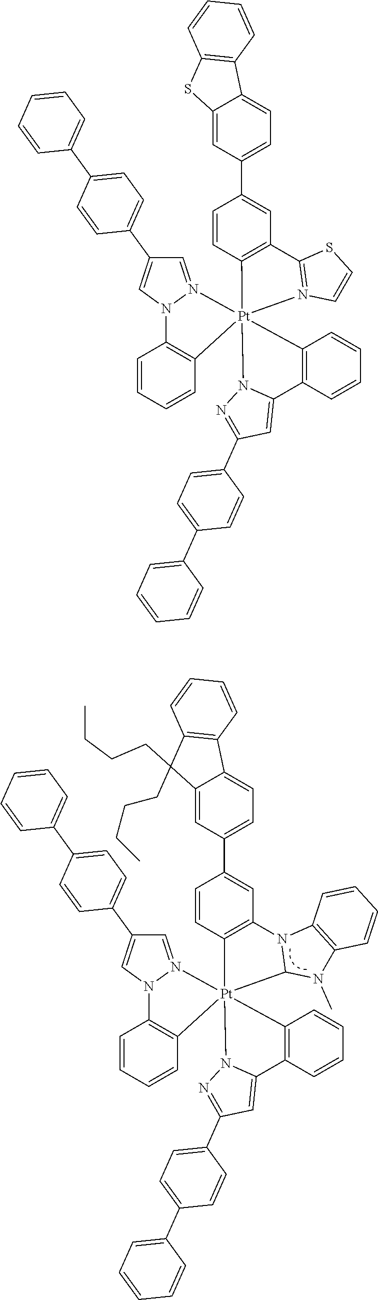 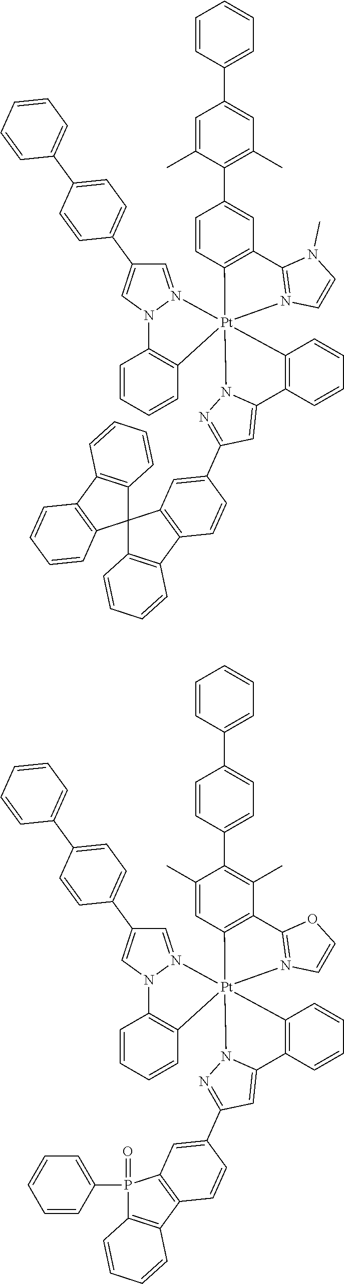 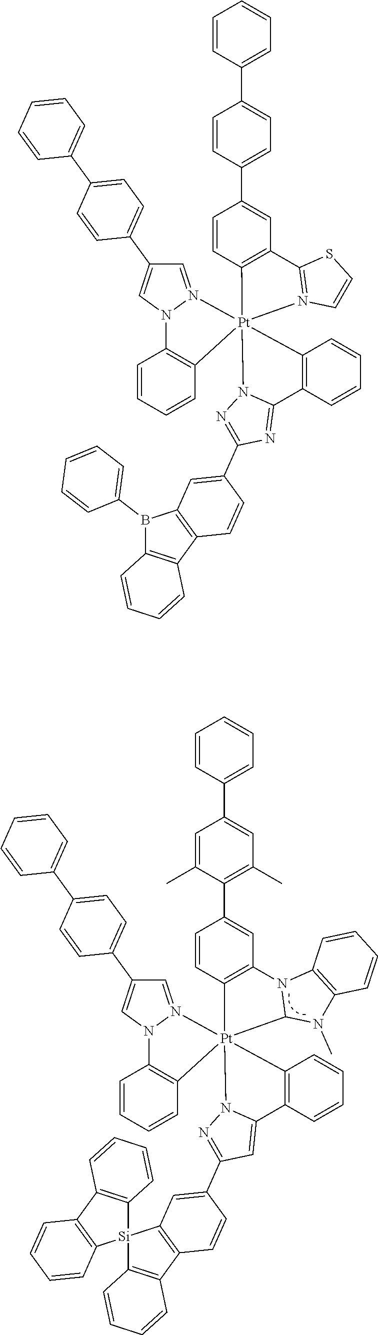 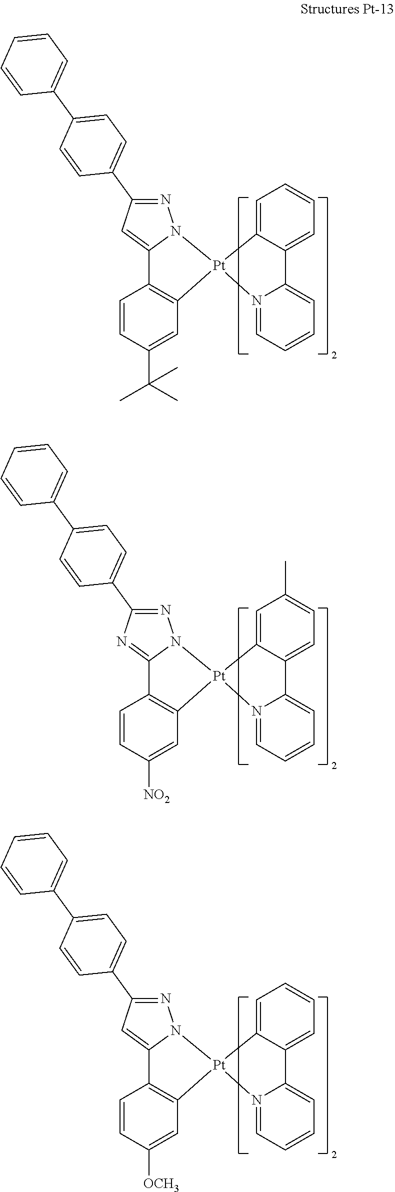 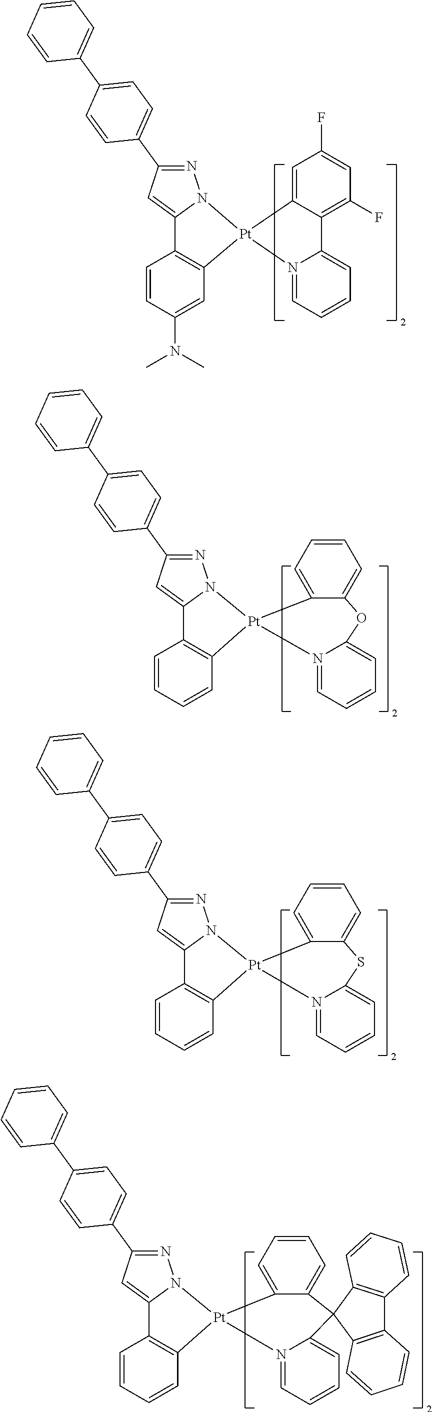 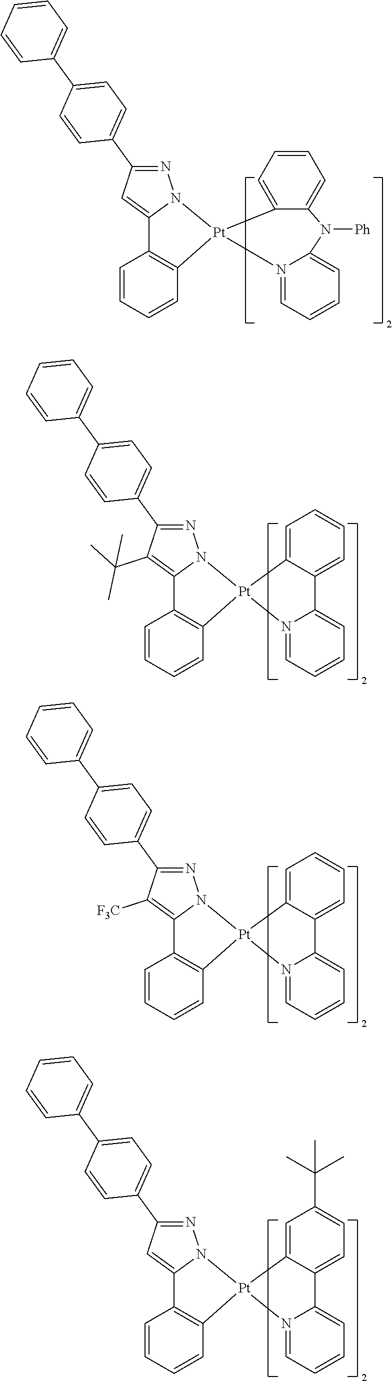 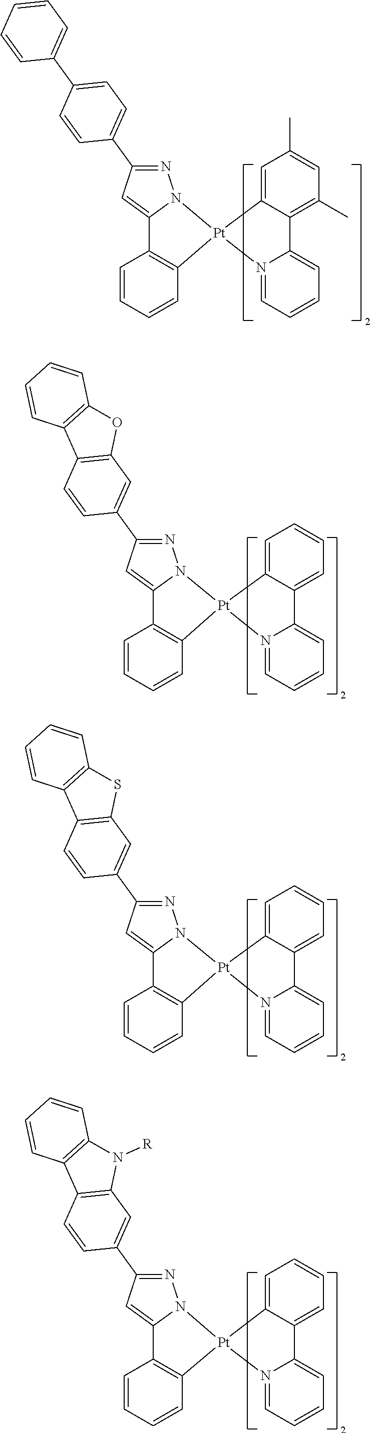 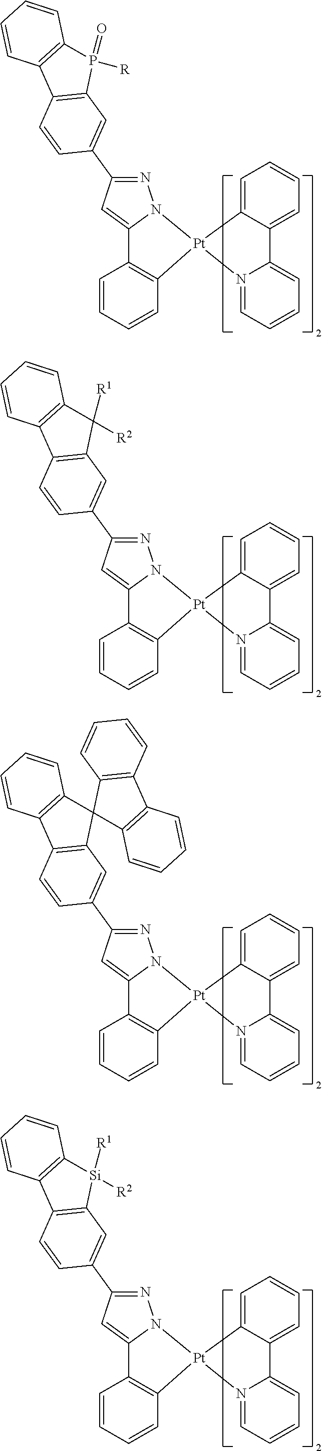 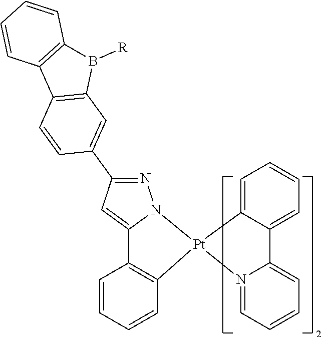
wherein of R, R¹, R², R³, and R⁴ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

28. An emitter comprising the compound of claim 16, wherein the emitter is a delayed fluorescent and phosphorescent emitter.

29. An emitter comprising the compound of claim 16, wherein the emitter is a phosphorescent emitter.

30. An emitter comprising the compound of claim 16, wherein the emitter is a delayed fluorescent emitter.

31. A device comprising a compound of claim 1.

32. The device of claim 31, wherein the compound is selected to have 100% internal quantum efficiency in the device settings.

33. The device of claim 31, wherein the device is an organic light emitting diode.

34. The compound of claim 16, wherein polymeric comprises polyalkylene, polyester, or polyether.

35. The compound of claim 30, wherein polymeric comprises —(CH₂O)ₙ—CH₃, —(CH₂CH₂O)ₙ—CH₃, —[CH₂CH(CH₃)]ₙ—CH₃, —[CH₂CH(COOCH₃)]ₙ—CH₃, —[CH₂CH(COO CH₂CH₃)]ₙ—CH₃, or —[CH₂CH(COO^{t}Bu)]ₙ—CH₃, where n is an integer.
